(19) United States
(12) Patent Application Publication
(10) Pub. No.: US 2022/0416170 A1
(43) Pub. Date: Dec. 29, 2022

(54) ORGANIC ELECTROLUMINESCENT ELEMENT AND ELECTRONIC DEVICE

(71) Applicant: IDEMITSU KOSAN CO.,LTD., Tokyo (JP)

(72) Inventors: Satomi TASAKI, Tokyo (JP); Kazuki NISHIMURA, Tokyo (JP); Yuki NAKANO, Tokyo (JP)

(73) Assignee: IDEMITSU KOSAN CO.,LTD., Tokyo (JP)

(21) Appl. No.: 17/774,074

(22) PCT Filed: Nov. 6, 2020
(86) PCT No.: PCT/JP2020/041599

§ 371 Date: May 3, 2022

(30) Foreign Application Priority Data
Nov. 8, 2019 (JP) 2019-203199

(51) Int. Cl. H01L 51/00

(52) U.S. Cl. CPC H01L 51/0054; H01L 51/0058; H01L 51/0073; H01L 51/0072; H01L 51/0055; H01L 51/005; H01L 51/006; H01L 51/0061; H01L 51/5064

(57) ABSTRACT

An organic electroluminescence device includes an anode, a cathode, an emitting layer between the anode and the cathode, and a first hole transporting layer between the anode and the emitting layer, in which the first hole transporting layer is directly adjacent to the emitting layer, the first hole transporting layer contains a first compound represented by formula (1) below, and the first compound has at least one group represented by formula (11) below.

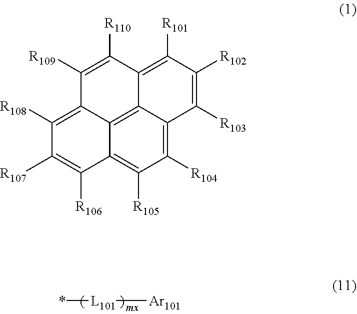

### TECHNICAL FIELD

The present invention relates to an organic electroluminescence device and an electronic device.

### BACKGROUND ART

Organic electroluminescence devices (hereinafter also referred to as “organic EL devices”) are applied to full-color displays, for example, of mobile phones and televisions. When a voltage is applied to an organic EL device, holes are injected into an emitting layer from an anode, and electrons are injected into the emitting layer from a cathode. At the emitting layer, the injected holes and electrons recombine, producing excitons. Singlet excitons constitute 25% of the produced excitons, with triplet excitons constituting 75%, in accordance with the statistical law of electron spins.

To improve the performance of organic EL devices, researchers have conducted various studies on compounds used to make organic EL devices (see, for example, Patent Literatures 1 and 2). Patent Literatures 1 and 2 describe organic electroluminescence devices having a hole transporting layer in which a compound having an amine skeleton is contained.

Examples of performance attributes of an organic EL device include luminance, emission wavelength, chromaticity, luminous efficiency, drive voltage, and lifetime.

### CITATION LIST

### Patent Literatures

Patent Literature 1: WO 2009/145016

Patent Literature 2: WO 2010/061824

Patent Literature 3: WO 2016/133058

### SUMMARY OF THE INVENTION

### Problems to be Solved by the Invention

An object of the invention is to provide an organic electroluminescence device with reduced drive voltage and an electronic device incorporating this organic electroluminescence device.

### Means for Solving the Problems

According to an aspect of the invention, there is provided an organic electroluminescence device including an anode, a cathode, an emitting layer between the anode and the cathode, and a first hole transporting layer between the anode and the emitting layer, in which the first hole transporting layer is directly adjacent to the emitting layer, the first hole transporting layer contains a first compound represented by formula (1) below, and the first compound has at least one group represented by formula (11) below.

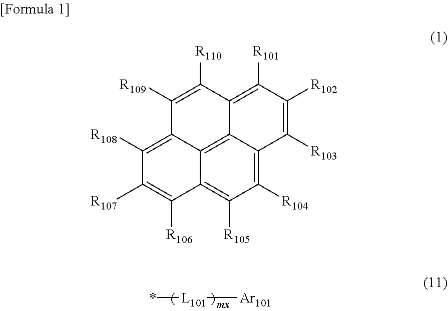

In formula (1),

R₁₀₁ to R₁₁₀ each independently represent: a hydrogen atom; a substituted or unsubstituted alkyl group having 1 to 50 carbon atoms; a substituted or unsubstituted haloalkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a substituted or unsubstituted aralkyl group having 7 to 50 carbon atoms; a group represented by —C(═O)R₈₀₁; a group represented by —COOR₈₀₂; a halogen atom; a cyano group; a nitro group; a substituted or unsubstituted aryl group having 6 to 50 ring carbon atoms; a substituted or unsubstituted heterocyclic group having 5 to 50 ring atoms; or a group represented by formula (11),

at least one of R₁₀₁ to R₁₁₀ is a group represented by formula (11);

when multiple groups represented by formula (11) are present, the multiple groups represented by formula (11) are mutually the same or different;

L₁₀₁ is: a single bond; a substituted or unsubstituted arylene group having 6 to 50 ring carbon atoms; or a substituted or unsubstituted divalent heterocyclic group having 5 to 50 ring atoms;

Ar₁₀₁ is: a substituted or unsubstituted aryl group having 6 to 50 ring carbon atoms; or a substituted or unsubstituted heterocyclic group having 5 to 50 ring atoms;

mx is 0, 1, 2, 3, 4, or 5;

when two or more L₁₀₁s are present, the two or more L₁₀₁s are mutually the same or different;

when two or more Ar₁₀₁s are present, the two or more Ar₁₀₁s are mutually the same or different;

* in formula (11) indicates a position of bonding with a pyrene ring in formula (1);

a substituent for “substituted or unsubstituted” group in the first compound is at least one group selected from the group consisting of: an unsubstituted alkyl group having 1 to 50 carbon atoms; an unsubstituted alkenyl group having 2 to 50 carbon atoms; an unsubstituted alkynyl group having 2 to 50 carbon atoms; an unsubstituted cycloalkyl group having 3 to 50 ring carbon atoms; —Si(R₉₀₁)(R₉₀₂)(R₉₀₃); —O—(R₉₀₄); —S—(R₉₀₅); a halogen atom; a cyano group; a nitro group; an unsubstituted aryl group having 6 to 50 ring carbon atoms; and an unsubstituted heterocyclic group having 5 to 50 ring atoms; in the first compound, represented by formula (1), R₉₀₁, R₉₀₂, R₉₀₃, R₉₀₄, R₉₀₅, R₈₀₁, and R₈₀₂ each independently represent: a hydrogen atom; a substituted or unsubstituted alkyl group having 1 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms; when multiple R₉₀₁s are present, the multiple R₉₀₁s are mutually the same or different;

when multiple R₉₀₂s are present, the multiple R₉₀₂s are mutually the same or different;

when multiple R₉₀₃s are present, the multiple R₉₀₃s are mutually the same or different;

when multiple R₉₀₄s are present, the multiple R₉₀₄s are mutually the same or different;

when multiple R₉₀₅s are present, the multiple R₉₀₅s are mutually the same or different;

when multiple R₈₀₁s are present, the multiple R₈₀₁s are mutually the same or different; and

when multiple R₈₀₂s are present, the multiple R₈₀₂s are mutually the same or different.

According to another aspect of the invention, there is provided an electronic device incorporating the organic electroluminescence device according to the above aspect of the invention.

According to the above aspect of the invention, an organic electroluminescence device with reduced drive voltage can be provided. According to the above aspect of the invention, furthermore, an electronic device incorporating this organic electroluminescence device can be provided.

### BRIEF DESCRIPTION OF DRAWINGS

FIG. 1 is a diagram illustrating an outline of an example of an organic electroluminescence device according to an exemplary embodiment of the invention.

FIG. 2 is a diagram illustrating an outline of an example of an organic electroluminescence device according to an exemplary embodiment of the invention.

FIG. 3 is a diagram illustrating an outline of an example of an organic electroluminescence device according to an exemplary embodiment of the invention.

FIG. 4 is a diagram illustrating an outline of an example of an organic electroluminescence device according to an exemplary embodiment of the invention.

### DESCRIPTION OF EMBODIMENTS

### Definitions

Herein, a hydrogen atom includes isotope having different numbers of neutrons, specifically, protium, deuterium and tritium.

In chemical formulae herein, it is assumed that a hydrogen atom (i.e. protium, deuterium and tritium) is bonded to each of bondable positions that are not annexed with signs “R” or the like or “D” representing a deuterium.

Herein, the ring carbon atoms refer to the number of carbon atoms among atoms forming a ring of a compound (e.g., a monocyclic compound, fused-ring compound, cross-linking compound, carbon ring compound, and heterocyclic compound) in which the atoms are bonded to each other to form the ring. When the ring is substituted by a substituent(s), carbon atom(s) contained in the substituent(s) is not counted in the ring carbon atoms. Unless otherwise specified, the same applies to the “ring carbon atoms” described later. For instance, a benzene ring has 6 ring carbon atoms, a naphthalene ring has 10 ring carbon atoms, a pyridine ring has 5 ring carbon atoms, and a furan ring has 4 ring carbon atoms. Further, for instance, 9,9-diphenylfluorenyl group has 13 ring carbon atoms and 9,9′-spirobifluorenyl group has 25 ring carbon atoms.

When a benzene ring is substituted by a substituent in a form of, for instance, an alkyl group, the number of carbon atoms of the alkyl group is not counted in the number of the ring carbon atoms of the benzene ring. Accordingly, the benzene ring substituted by an alkyl group has 6 ring carbon atoms. When a naphthalene ring is substituted by a substituent in a form of, for instance, an alkyl group, the number of carbon atoms of the alkyl group is not counted in the number of the ring carbon atoms of the naphthalene ring. Accordingly, the naphthalene ring substituted by an alkyl group has 10 ring carbon atoms.

Herein, the ring atoms refer to the number of atoms forming a ring of a compound (e.g., a monocyclic compound, fused-ring compound, cross-linking compound, carbon ring compound, and heterocyclic compound) in which the atoms are bonded to each other to form the ring (e.g., monocyclic ring, fused ring, and ring assembly). Atom(s) not forming the ring (e.g., hydrogen atom(s) for saturating the valence of the atom which forms the ring) and atom(s) in a substituent by which the ring is substituted are not counted as the ring atoms. Unless otherwise specified, the same applies to the “ring atoms” described later. For instance, a pyridine ring has 6 ring atoms, a quinazoline ring has 10 ring atoms, and a furan ring has 5 ring atoms. For instance, the number of hydrogen atom(s) bonded to a pyridine ring or the number of atoms forming a substituent are not counted as the pyridine ring atoms. Accordingly, a pyridine ring bonded to a hydrogen atom(s) or a substituent(s) has 6 ring atoms. For instance, the hydrogen atom(s) bonded to carbon atom(s) of a quinazoline ring or the atoms forming a substituent are not counted as the quinazoline ring atoms. Accordingly, a quinazoline ring bonded to hydrogen atom(s) or a substituent(s) has 10 ring atoms.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group. Herein, “YY” is larger than “XX,” “XX” representing an integer of 1 or more and “YY” representing an integer of 2 or more.

Herein, “XX to YY atoms” in the description of “substituted or unsubstituted ZZ group having XX to YY atoms” represent atoms of an unsubstituted ZZ group and do not include atoms of a substituent(s) of the substituted ZZ group. Herein, “YY” is larger than “XX,” “XX” representing an integer of 1 or more and “YY” representing an integer of 2 or more.

Herein, an unsubstituted ZZ group refers to an “unsubstituted ZZ group” in a “substituted or unsubstituted ZZ group,” and a substituted ZZ group refers to a “substituted ZZ group” in a “substituted or unsubstituted ZZ group.”

Herein, the term “unsubstituted” used in a “substituted or unsubstituted ZZ group” means that a hydrogen atom(s) in the ZZ group is not substituted with a substituent(s). The hydrogen atom(s) in the “unsubstituted ZZ group” is protium, deuterium, or tritium.

Herein, the term “substituted” used in a “substituted or unsubstituted ZZ group” means that at least one hydrogen atom in the ZZ group is substituted with a substituent. Similarly, the term “substituted” used in a “BB group substituted by AA group” means that at least one hydrogen atom in the BB group is substituted with the AA group.

### Substituents Mentioned Herein

Substituents mentioned herein will be described below.

An “unsubstituted aryl group” mentioned herein has, unless otherwise specified herein, 6 to 50, preferably 6 to 30, more preferably 6 to 18 ring carbon atoms.

An “unsubstituted heterocyclic group” mentioned herein has, unless otherwise specified herein, 5 to 50, preferably 5 to 30, more preferably 5 to 18 ring atoms.

An “unsubstituted alkyl group” mentioned herein has, unless otherwise specified herein, 1 to 50, preferably 1 to 20, more preferably 1 to 6 carbon atoms.

An “unsubstituted alkenyl group” mentioned herein has, unless otherwise specified herein, 2 to 50, preferably 2 to 20, more preferably 2 to 6 carbon atoms.

An “unsubstituted alkynyl group” mentioned herein has, unless otherwise specified herein, 2 to 50, preferably 2 to 20, more preferably 2 to 6 carbon atoms.

An “unsubstituted cycloalkyl group” mentioned herein has, unless otherwise specified herein, 3 to 50, preferably 3 to 20, more preferably 3 to 6 ring carbon atoms.

An “unsubstituted arylene group” mentioned herein has, unless otherwise specified herein, 6 to 50, preferably 6 to 30, more preferably 6 to 18 ring carbon atoms.

An “unsubstituted divalent heterocyclic group” mentioned herein has, unless otherwise specified herein, 5 to 50, preferably 5 to 30, more preferably 5 to 18 ring atoms.

An “unsubstituted alkylene group” mentioned herein has, unless otherwise specified herein, 1 to 50, preferably 1 to 20, more preferably 1 to 6 carbon atoms.

### Substituted or Unsubstituted Aryl Group

Specific examples (specific example group G1) of the “substituted or unsubstituted aryl group” mentioned herein include unsubstituted aryl groups (specific example group G1A) below and substituted aryl groups (specific example group G1B) below. (Herein, an unsubstituted aryl group refers to an “unsubstituted aryl group” in a “substituted or unsubstituted aryl group”, and a substituted aryl group refers to a “substituted aryl group” in a “substituted or unsubstituted aryl group.”) A simply termed “aryl group” herein includes both of an “unsubstituted aryl group” and a “substituted aryl group.”

The “substituted aryl group” refers to a group derived by substituting at least one hydrogen atom in an “unsubstituted aryl group” with a substituent. Examples of the “substituted aryl group” include a group derived by substituting at least one hydrogen atom in the “unsubstituted aryl group” in the specific example group G1A below with a substituent, and examples of the substituted aryl group in the specific example group G1B below. It should be noted that the examples of the “unsubstituted aryl group” and the “substituted aryl group” mentioned herein are merely exemplary, and the “substituted aryl group” mentioned herein includes a group derived by further substituting a hydrogen atom bonded to a carbon atom of a skeleton of a “substituted aryl group” in the specific example group G1B below, and a group derived by further substituting a hydrogen atom of a substituent of the “substituted aryl group” in the specific example group G1B below.

### Unsubstituted Aryl Group (Specific Example Group G1A)

phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, benzanthryl group, phenanthryl group, benzophenanthryl group, phenalenyl group, pyrenyl group, chrysenyl group, benzochrysenyl group, triphenylenyl group, benzotriphenylenyl group, tetracenyl group, pentacenyl group, fluorenyl group, 9,9′-spirobifluorenyl group, benzofluorenyl group, dibenzofluorenyl group, fluoranthenyl group, benzofluoranthenyl group, perylenyl group, and a monovalent aryl group derived by removing one hydrogen atom from cyclic structures represented by formulae (TEMP-1) to (TEMP-15) below.

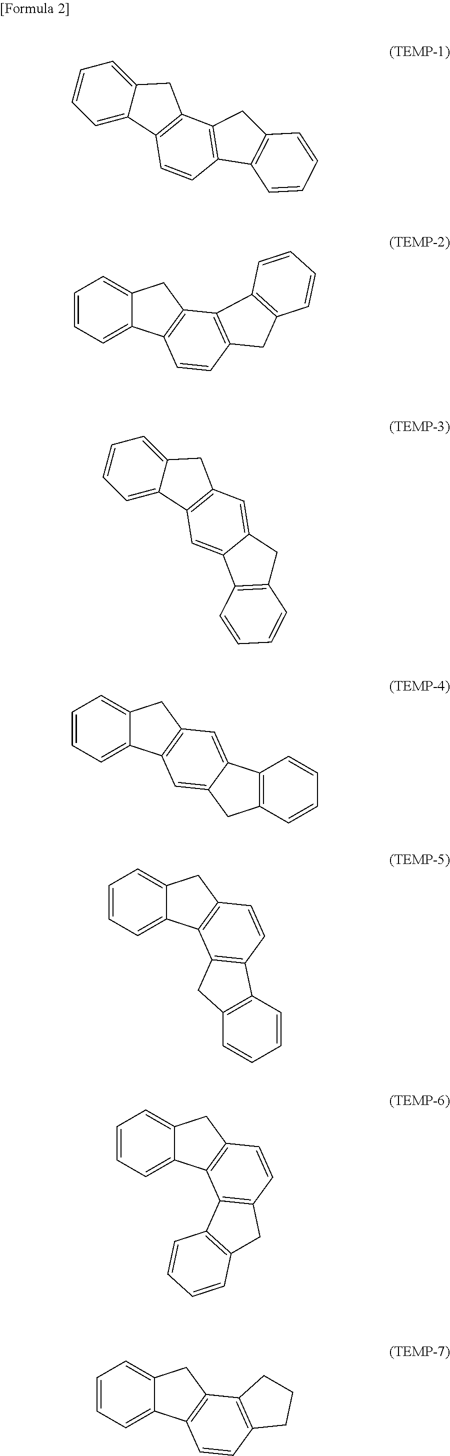

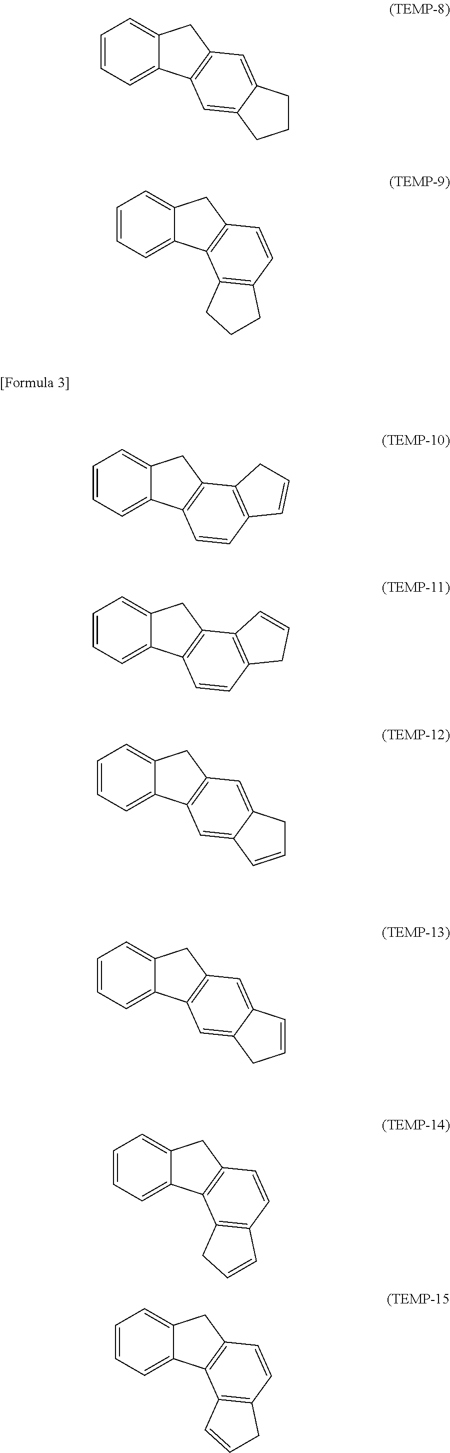

### Substituted Aryl Group (Specific Example Group G1B)

o-tolyl group, m-tolyl group, p-tolyl group, para-xylyl group, meta-xylyl group, ortho-xylyl group, para-isopropylphenyl group, meta-isopropylphenyl group, ortho-isopropylphenyl group, para-t-butylphenyl group, meta-t-butylphenyl group, ortho-t-butylphenyl group, 3,4,5-trimethylphenyl group, 9,9-dimethylfluorenyl group, 9,9-diphenylfluorenyl group, 9,9-bis(4-methylphenyl)fluorenyl group, 9,9-bis(4-isopropylphenyl)fluorenyl group, 9,9-bis(4-t-butylphenyl)fluorenyl group, cyanophenyl group, triphenylsilylphenyl group, trimethylsilylphenyl group, phenylnaphthyl group, naphthylphenyl group, and a group derived by substituting at least one hydrogen atom of a monovalent group derived from one of the cyclic structures represented by formulae (TEMP-1) to (TEMP-15) with a substituent.

### Substituted or Unsubstituted Heterocyclic Group

The “heterocyclic group” mentioned herein refers to a cyclic group having at least one hetero atom in the ring atoms. Specific examples of the hetero atom include a nitrogen atom, oxygen atom, sulfur atom, silicon atom, phosphorus atom, and boron atom.

The “heterocyclic group” mentioned herein is a monocyclic group or a fused-ring group.

The “heterocyclic group” mentioned herein is an aromatic heterocyclic group or a non-aromatic heterocyclic group.

Specific examples (specific example group G2) of the “substituted or unsubstituted heterocyclic group” mentioned herein include unsubstituted heterocyclic groups (specific example group G2A) and substituted heterocyclic groups (specific example group G2B). (Herein, an unsubstituted heterocyclic group refers to an “unsubstituted heterocyclic group” in a “substituted or unsubstituted heterocyclic group,” and a substituted heterocyclic group refers to a “substituted heterocyclic group” in a “substituted or unsubstituted heterocyclic group.”) A simply termed “heterocyclic group” herein includes both of “unsubstituted heterocyclic group” and “substituted heterocyclic group.”

The “substituted heterocyclic group” refers to a group derived by substituting at least one hydrogen atom in an “unsubstituted heterocyclic group” with a substituent. Specific examples of the “substituted heterocyclic group” include a group derived by substituting at least one hydrogen atom in the “unsubstituted heterocyclic group” in the specific example group G2A below with a substituent, and examples of the substituted heterocyclic group in the specific example group G2B below. It should be noted that the examples of the “unsubstituted heterocyclic group” and the “substituted heterocyclic group” mentioned herein are merely exemplary, and the “substituted heterocyclic group” mentioned herein includes a group derived by further substituting a hydrogen atom bonded to a ring atom of a skeleton of a “substituted heterocyclic group” in the specific example group G2B below, and a group derived by further substituting a hydrogen atom of a substituent of the “substituted heterocyclic group” in the specific example group G2B below.

The specific example group G2A includes, for instance, unsubstituted heterocyclic groups including a nitrogen atom (specific example group G2A1) below, unsubstituted heterocyclic groups including an oxygen atom (specific example group G2A2) below, unsubstituted heterocyclic groups including a sulfur atom (specific example group G2A3) below, and monovalent heterocyclic groups (specific example group G2A4) derived by removing a hydrogen atom from cyclic structures represented by formulae (TEMP-16) to (TEMP-33) below.

The specific example group G2B includes, for instance, substituted heterocyclic groups including a nitrogen atom (specific example group G2B1) below, substituted heterocyclic groups including an oxygen atom (specific example group G2B2) below, substituted heterocyclic groups including a sulfur atom (specific example group G2B3) below, and groups derived by substituting at least one hydrogen atom of the monovalent heterocyclic groups (specific example group G2B4) derived from the cyclic structures represented by formulae (TEMP-16) to (TEMP-33) below.

### Unsubstituted Heterocyclic Groups Including Nitrogen Atom (Specific Example Group G2A1)

pyrrolyl group, imidazolyl group, pyrazolyl group, triazolyl group, tetrazolyl group, oxazolyl group, isoxazolyl group, oxadiazolyl group, thiazolyl group, isothiazolyl group, thiadiazolyl group, pyridyl group, pyridazynyl group, pyrimidinyl group, pyrazinyl group, triazinyl group, indolyl group, isoindolyl group, indolizinyl group, quinolizinyl group, quinolyl group, isoquinolyl group, cinnolyl group, phthalazinyl group, quinazolinyl group, quinoxalinyl group, benzimidazolyl group, indazolyl group, phenanthrolinyl group, phenanthridinyl group, acridinyl group, phenazinyl group, carbazolyl group, benzocarbazolyl group, morpholino group, phenoxazinyl group, phenothiazinyl group, azacarbazolyl group, and diazacarbazolyl group.

### Unsubstituted Heterocyclic Groups Including Oxygen Atom (Specific Example Group G2A2)

furyl group, oxazolyl group, isoxazolyl group, oxadiazolyl group, xanthenyl group, benzofuranyl group, isobenzofuranyl group, dibenzofuranyl group, naphthobenzofuranyl group, benzoxazolyl group, benzisoxazolyl group, phenoxazinyl group, morpholino group, dinaphthofuranyl group, azadibenzofuranyl group, diazadibenzofuranyl group, azanaphthobenzofuranyl group, and diazanaphthobenzofuranyl group.

### Unsubstituted Heterocyclic Groups Including Sulfur Atom (Specific Example Group G2A3)

thienyl group, thiazolyl group, isothiazolyl group, thiadiazolyl group, benzothiophenyl group (benzothienyl group), isobenzothiophenyl group (isobenzothienyl group), dibenzothiophenyl group (dibenzothienyl group), naphthobenzothiophenyl group (nahthobenzothienyl group), benzothiazolyl group, benzisothiazolyl group, phenothiazinyl group, dinaphthothiophenyl group (dinaphthothienyl group), azadibenzothiophenyl group (azadibenzothienyl group), diazadibenzothiophenyl group (diazadibenzothienyl group), azanaphthobenzothiophenyl group (azanaphthobenzothienyl group), and diazanaphthobenzothiophenyl group (diazanaphthobenzothienyl group).

### Monovalent Heterocyclic Groups Derived by Removing One Hydrogen Atom from Cyclic Structures Represented by Formulae (TEMP-16) to (TEMP-33) (Specific Example Group G2A4)

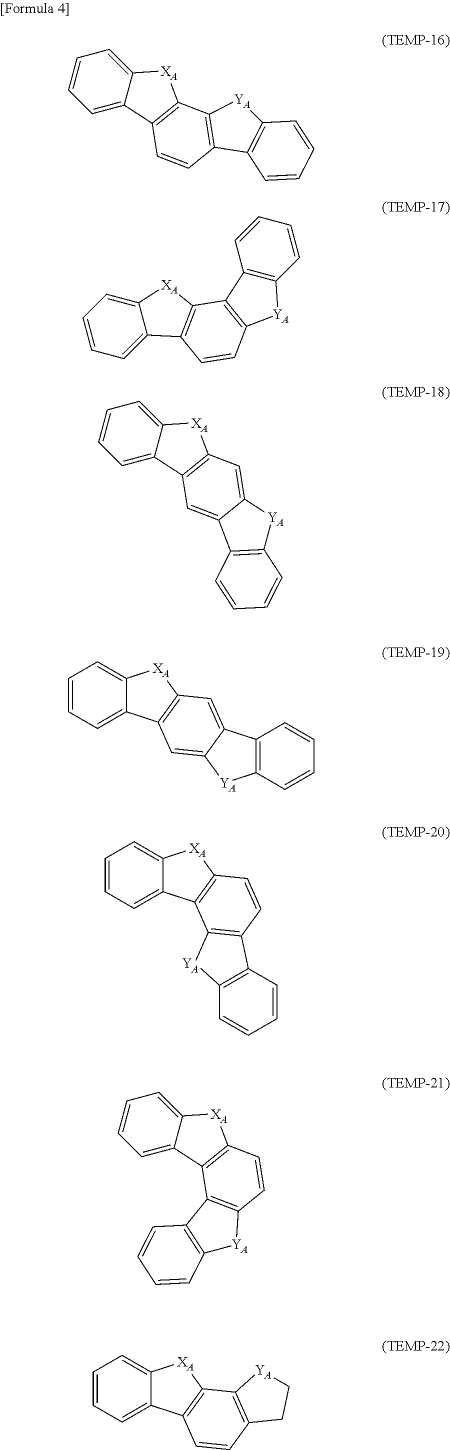

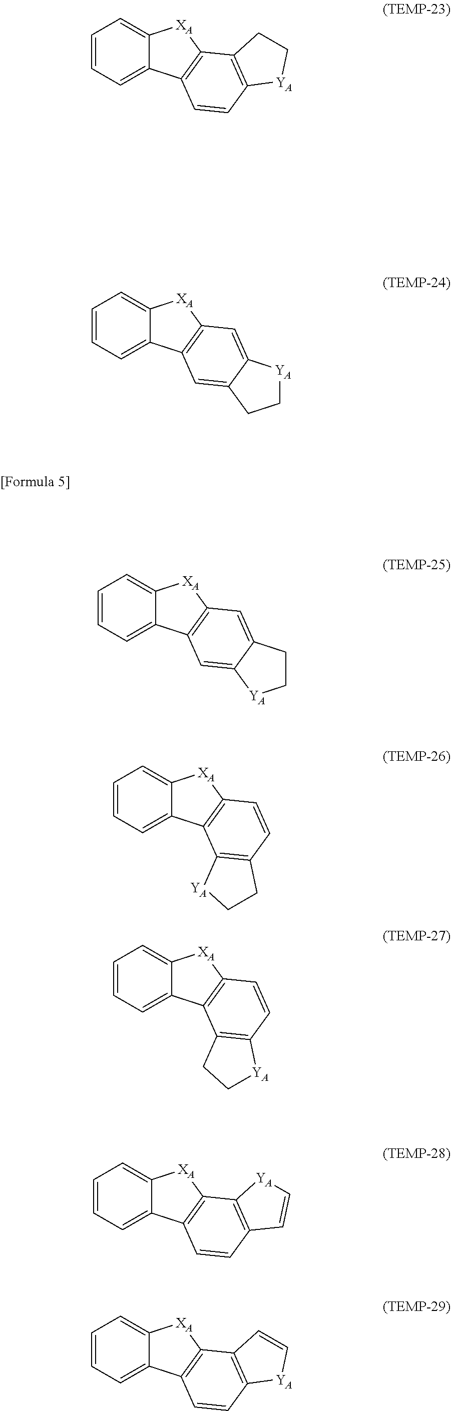

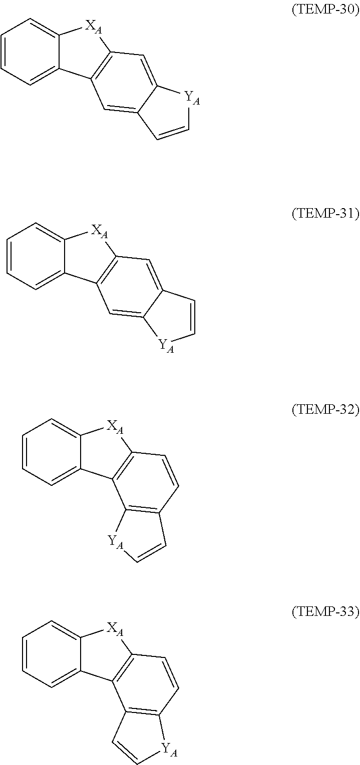

In formulae (TEMP-16) to (TEMP-33), X_{A} and Y_{A} are each independently an oxygen atom, a sulfur atom, NH, or CH₂, with a proviso that at least one of X_{A} or Y_{A} is an oxygen atom, a sulfur atom, or NH.

When at least one of X_{A} or Y_{A} in formulae (TEMP-16) to (TEMP-33) is NH or CH₂, the monovalent heterocyclic groups derived from the cyclic structures represented by formulae (TEMP-16) to (TEMP-33) include a monovalent group derived by removing one hydrogen atom from NH or CH₂.

### Substituted Heterocyclic Groups Including Nitrogen Atom (Specific Example Group G2B1)

(9-phenyl)carbazolyl group, (9-biphenylyl)carbazolyl group, (9-phenyl)phenylcarbazolyl group, (9-naphthyl)carbazolyl group, diphenylcarbazole-9-yl group, phenylcarbazole-9-yl group, methylbenzimidazolyl group, ethylbenzimidazolyl group, phenyltriazinyl group, biphenylyltriazinyl group, diphenyltriazinyl group, phenylquinazolinyl group, and biphenylquinazolinyl group.

### Substituted Heterocyclic Groups Including Oxygen Atom (Specific Example Group G2B2)

phenyldibenzofuranyl group, methyldibenzofuranyl group, t-butyldibenzofuranyl group, and monovalent residue of spiro[9H-xanthene-9,9′-[9H]fluorene].

### Substituted Heterocyclic Groups Including Sulfur Atom (Specific Example Group G2B3)

phenyldibenzothiophenyl group, methyldibenzothiophenyl group, t-butyldibenzothiophenyl group, and monovalent residue of spiro[9H-thioxanthene-9,9′-[9H]fluorene].

### Groups Obtained by Substituting at Least One Hydrogen Atom of Monovalent Heterocyclic Group Derived from Cyclic Structures Represented by Formulae (TEMP-16) to (TEMP-33) with Substituent (Specific Example Group G2B4)

The “at least one hydrogen atom of a monovalent heterocyclic group” means at least one hydrogen atom selected from a hydrogen atom bonded to a ring carbon atom of the monovalent heterocyclic group, a hydrogen atom bonded to a nitrogen atom of at least one of XA or YA in a form of NH, and a hydrogen atom of one of XA and YA in a form of a methylene group (CH2).

### Substituted or Unsubstituted Alkyl Group

Specific examples (specific example group G3) of the “substituted or unsubstituted alkyl group” mentioned herein include unsubstituted alkyl groups (specific example group G3A) and substituted alkyl groups (specific example group G3B) below. (Herein, an unsubstituted alkyl group refers to an “unsubstituted alkyl group” in a “substituted or unsubstituted alkyl group,” and a substituted alkyl group refers to a “substituted alkyl group” in a “substituted or unsubstituted alkyl group.”) A simply termed “alkyl group” herein includes both of “unsubstituted alkyl group” and “substituted alkyl group.”

The “substituted alkyl group” refers to a group derived by substituting at least one hydrogen atom in an “unsubstituted alkyl group” with a substituent. Specific examples of the “substituted alkyl group” include a group derived by substituting at least one hydrogen atom of an “unsubstituted alkyl group” (specific example group G3A) below with a substituent, and examples of the substituted alkyl group (specific example group G3B) below. Herein, the alkyl group for the “unsubstituted alkyl group” refers to a chain alkyl group. Accordingly, the “unsubstituted alkyl group” include linear “unsubstituted alkyl group” and branched “unsubstituted alkyl group.” It should be noted that the examples of the “unsubstituted alkyl group” and the “substituted alkyl group” mentioned herein are merely exemplary, and the “substituted alkyl group” mentioned herein includes a group derived by further substituting a hydrogen atom of a skeleton of the “substituted alkyl group” in the specific example group G3B, and a group derived by further substituting a hydrogen atom of a substituent of the “substituted alkyl group” in the specific example group G3B.

### Unsubstituted Alkyl Group (Specific Example Group G3A)

methyl group, ethyl group, n-propyl group, isopropyl group, n-butyl group, isobutyl group, s-butyl group, and t-butyl group.

### Substituted Alkyl Group (Specific Example Group G3B)

heptafluoropropyl group (including isomer thereof), pentafluoroethyl group, 2,2,2-trifluoroethyl group, and trifluoromethyl group.

### Substituted or Unsubstituted Alkenyl Group

Specific examples (specific example group G4) of the “substituted or unsubstituted alkenyl group” mentioned herein include unsubstituted alkenyl groups (specific example group G4A) and substituted alkenyl groups (specific example group G4B). (Herein, an unsubstituted alkenyl group refers to an “unsubstituted alkenyl group” in a “substituted or unsubstituted alkenyl group,” and a substituted alkenyl group refers to a “substituted alkenyl group” in a “substituted or unsubstituted alkenyl group.”) A simply termed “alkenyl group” herein includes both of “unsubstituted alkenyl group” and “substituted alkenyl group.”

The “substituted alkenyl group” refers to a group derived by substituting at least one hydrogen atom in an “unsubstituted alkenyl group” with a substituent. Specific examples of the “substituted alkenyl group” include an “unsubstituted alkenyl group” (specific example group G4A) substituted by a substituent, and examples of the substituted alkenyl group (specific example group G4B) below. It should be noted that the examples of the “unsubstituted alkenyl group” and the “substituted alkenyl group” mentioned herein are merely exemplary, and the “substituted alkenyl group” mentioned herein includes a group derived by further substituting a hydrogen atom of a skeleton of the “substituted alkenyl group” in the specific example group G4B with a substituent, and a group derived by further substituting a hydrogen atom of a substituent of the “substituted alkenyl group” in the specific example group G4B with a substituent.

### Unsubstituted Alkenyl Group (Specific Example Group G4A)

vinyl group, allyl group, 1-butenyl group, 2-butenyl group, and 3-butenyl group.

### Substituted Alkenyl Group (Specific Example Group G4B)

1,3-butanedienyl group, 1-methylvinyl group, 1-methylallyl group, 1,1-dimethylallyl group, 2-methylallyl group, and 1,2-dimethylallyl group.

### Substituted or Unsubstituted Alkynyl Group

Specific examples (specific example group G5) of the “substituted or unsubstituted alkynyl group” mentioned herein include unsubstituted alkynyl groups (specific example group G5A) below. (Herein, an unsubstituted alkynyl group refers to an “unsubstituted alkynyl group” in a “substituted or unsubstituted alkynyl group.”) A simply termed “alkynyl group” herein includes both of “unsubstituted alkynyl group” and “substituted alkynyl group.”

The “substituted alkynyl group” refers to a group derived by substituting at least one hydrogen atom in an “unsubstituted alkynyl group” with a substituent. Specific examples of the “substituted alkynyl group” include a group derived by substituting at least one hydrogen atom of the “unsubstituted alkynyl group” (specific example group G5A) below with a substituent.

### Unsubstituted Alkynyl Group (Specific Example Group G5A)

ethynyl group.

### Substituted or Unsubstituted Cycloalkyl Group

Specific examples (specific example group G6) of the “substituted or unsubstituted cycloalkyl group” mentioned herein include unsubstituted cycloalkyl groups (specific example group G6A) and substituted cycloalkyl groups (specific example group G6B). (Herein, an unsubstituted cycloalkyl group refers to an “unsubstituted cycloalkyl group” in a “substituted or unsubstituted cycloalkyl group,” and a substituted cycloalkyl group refers to a “substituted cycloalkyl group” in a “substituted or unsubstituted cycloalkyl group.”) A simply termed “cycloalkyl group” herein includes both of “unsubstituted cycloalkyl group” and “substituted cycloalkyl group.”

The “substituted cycloalkyl group” refers to a group derived by substituting at least one hydrogen atom of an “unsubstituted cycloalkyl group” with a substituent. Specific examples of the “substituted cycloalkyl group” include a group derived by substituting at least one hydrogen atom of the “unsubstituted cycloalkyl group” (specific example group G6A) below with a substituent, and examples of the substituted cycloalkyl group (specific example group G6B) below. It should be noted that the examples of the “unsubstituted cycloalkyl group” and the “substituted cycloalkyl group” mentioned herein are merely exemplary, and the “substituted cycloalkyl group” mentioned herein includes a group derived by substituting at least one hydrogen atom bonded to a carbon atom of a skeleton of the “substituted cycloalkyl group” in the specific example group G6B with a substituent, and a group derived by further substituting a hydrogen atom of a substituent of the “substituted cycloalkyl group” in the specific example group G6B with a substituent.

### Unsubstituted Cycloalkyl Group (Specific Example Group G6A)

cyclopropyl group, cyclobutyl group, cyclopentyl group, cyclohexyl group, 1-adamantyl group, 2-adamantyl group, 1-norbornyl group, and 2-norbornyl group.

### Substituted Cycloalkyl Group (Specific Example Group G6B)

4-methylcyclohexyl group.

### Group Represented by —Si(R₉₀₁)(R₉₀₂)(R₉₀₃

Specific examples (specific example group G7) of the group represented herein by —Si(R₉₀₁)(R₉₀₂)(R₉₀₃) include —Si(G1)(G1)(G1), —Si(G1)(G2)(G2), —Si(G1)(G1)(G2), —Si(G2)(G2)(G2), —Si(G3)(G3)(G3), and —Si(G6)(G6)(G6), where:

G1 represents a “substituted or unsubstituted aryl group” in the specific example group G1,

G2 represents a “substituted or unsubstituted heterocyclic group” in the specific example group G2,

G3 represents a “substituted or unsubstituted alkyl group” in the specific example group G3, and

G6 represents a “substituted or unsubstituted cycloalkyl group” in the specific example group G6,

a plurality of G1 in —Si(G1)(G1)(G1) are mutually the same or different,

a plurality of G2 in —Si(G1)(G2)(G2) are mutually the same or different,

a plurality of G1 in —Si(G1)(G1)(G2) are mutually the same or different,

a plurality of G2 in —Si(G2)(G2)(G2) are mutually the same or different,

a plurality of G3 in —Si(G3)(G3)(G3) are mutually the same or different, and

a plurality of G6 in —Si(G6)(G6)(G6) are mutually the same or different.

### Group Represented by —O—(R₉₀₄)

Specific examples (specific example group G8) of a group represented by —O—(R₉₀₄) herein include —O(G1), —O(G2), —O(G3), and —O(G6), where:

G1 represents a “substituted or unsubstituted aryl group” in the specific example group G1,

G2 represents a “substituted or unsubstituted heterocyclic group” in the specific example group G2,

G3 represents a “substituted or unsubstituted alkyl group” in the specific example group G3, and

G6 represents a “substituted or unsubstituted cycloalkyl group” in the specific example group G6.

### Group Represented by —S—(R₉₀₅)

Specific examples (specific example group G9) of a group represented herein by —S—(R₉₀₅) include —S(G1), —S(G2), —S(G3), and —S(G6), where:

G1 represents a “substituted or unsubstituted aryl group” in the specific example group G1,

G2 represents a “substituted or unsubstituted heterocyclic group” in the specific example group G2,

G3 represents a “substituted or unsubstituted alkyl group” in the specific example group G3, and

G6 represents a “substituted or unsubstituted cycloalkyl group” in the specific example group G6.

Group Represented by —N(R₉₀₆)(R₉₀₇)

Specific examples (specific example group G10) of a group represented herein by —N(R₉₀₆)(R₉₀₇) include —N(G1)(G1), —N(G2)(G2), —N(G1)(G2), —N(G3)(G3), and —N(G6)(G6), where:

G1 represents a “substituted or unsubstituted aryl group” in the specific example group G1,

G2 represents a “substituted or unsubstituted heterocyclic group” in the specific example group G2,

G3 represents a “substituted or unsubstituted alkyl group” in the specific example group G3,

G6 represents a “substituted or unsubstituted cycloalkyl group” in the specific example group G6,

a plurality of G1 in —N(G1)(G1) are mutually the same or different,

a plurality of G2 in —N(G2)(G2) are mutually the same or different,

a plurality of G3 in —N(G3)(G3) are mutually the same or different, and

a plurality of G6 in —N(G6)(G6) are mutually the same or different.

### Halogen Atom

Specific examples (specific example group G11) of “halogen atom” mentioned herein include a fluorine atom, chlorine atom, bromine atom, and iodine atom.

### Substituted or Unsubstituted Fluoroalkyl Group

The “substituted or unsubstituted fluoroalkyl group” mentioned herein refers to a group derived by substituting at least one hydrogen atom bonded to at least one of carbon atoms forming an alkyl group in the “substituted or unsubstituted alkyl group” with a fluorine atom, and also includes a group (perfluoro group) derived by substituting all of hydrogen atoms bonded to carbon atoms forming the alkyl group in the “substituted or unsubstituted alkyl group” with fluorine atoms. An “unsubstituted fluoroalkyl group” has, unless otherwise specified herein, 1 to 50, preferably 1 to 30, more preferably 1 to 18 carbon atoms. The “substituted fluoroalkyl group” refers to a group derived by substituting at least one hydrogen atom in a “fluoroalkyl group” with a substituent. It should be noted that the examples of the “substituted fluoroalkyl group” mentioned herein include a group derived by further substituting at least one hydrogen atom bonded to a carbon atom of an alkyl chain of a “substituted fluoroalkyl group” with a substituent, and a group derived by further substituting at least one hydrogen atom of a substituent of the “substituted fluoroalkyl group” with a substituent. Specific examples of the “substituted fluoroalkyl group” include a group derived by substituting at least one hydrogen atom of the “alkyl group” (specific example group G3) with a fluorine atom.

### Substituted or Unsubstituted Haloalkyl Group

The “substituted or unsubstituted haloalkyl group” mentioned herein refers to a group derived by substituting at least one hydrogen atom bonded to carbon atoms forming the alkyl group in the “substituted or unsubstituted alkyl group” with a halogen atom, and also includes a group derived by substituting all hydrogen atoms bonded to carbon atoms forming the alkyl group in the “substituted or unsubstituted alkyl group” with halogen atoms. An “unsubstituted haloalkyl group” has, unless otherwise specified herein, 1 to 50, preferably 1 to 30, more preferably 1 to 18 carbon atoms. The “substituted haloalkyl group” refers to a group derived by substituting at least one hydrogen atom in a “haloalkyl group” with a substituent. It should be noted that the examples of the “substituted haloalkyl group” mentioned herein include a group derived by further substituting at least one hydrogen atom bonded to a carbon atom of an alkyl chain of a “substituted haloalkyl group” with a substituent, and a group derived by further substituting at least one hydrogen atom of a substituent of the “substituted haloalkyl group” with a substituent. Specific examples of the “unsubstituted haloalkyl group” include a group derived by substituting at least one hydrogen atom of the “alkyl group” (specific example group G3) with a halogen atom. The haloalkyl group is sometimes referred to as a halogenated alkyl group.

### Substituted or Unsubstituted Alkoxy Group

Specific examples of a “substituted or unsubstituted alkoxy group” mentioned herein include a group represented by —O(G3), G3 being the “substituted or unsubstituted alkyl group” in the specific example group G3. An “unsubstituted alkoxy group” has, unless otherwise specified herein, 1 to 50, preferably 1 to 30, more preferably 1 to 18 carbon atoms.

### Substituted or Unsubstituted Alkylthio Group

Specific examples of a “substituted or unsubstituted alkylthio group” mentioned herein include a group represented by —S(G3), G3 being the “substituted or unsubstituted alkyl group” in the specific example group G3. An “unsubstituted alkylthio group” has, unless otherwise specified herein, 1 to 50, preferably 1 to 30, more preferably 1 to 18 carbon atoms.

### Substituted or Unsubstituted Aryloxy Group

Specific examples of a “substituted or unsubstituted aryloxy group” mentioned herein include a group represented by —O(G1), G1 being the “substituted or unsubstituted aryl group” in the specific example group G1. An “unsubstituted aryloxy group” has, unless otherwise specified herein, 6 to 50, preferably 6 to 30, more preferably 6 to 18 ring carbon atoms.

### Substituted or Unsubstituted Arylthio Group

Specific examples of a “substituted or unsubstituted arylthio group” mentioned herein include a group represented by —S(G1), G1 being the “substituted or unsubstituted aryl group” in the specific example group G1. An “unsubstituted arylthio group” has, unless otherwise specified herein, 6 to 50, preferably 6 to 30, more preferably 6 to 18 ring carbon atoms.

### Substituted or Unsubstituted Trialkylsilyl Group

Specific examples of a “trialkylsilyl group” mentioned herein include a group represented by —Si(G3)(G3)(G3), G3 being the “substituted or unsubstituted alkyl group” in the specific example group G3. The plurality of G3 in —Si(G3)(G3)(G3) are mutually the same or different. Each of the alkyl groups in the “trialkylsilyl group” has, unless otherwise specified herein, 1 to 50, preferably 1 to 20, more preferably 1 to 6 carbon atoms.

### Substituted or Unsubstituted Aralkyl Group

Specific examples of a “substituted or unsubstituted aralkyl group” mentioned herein include a group represented by (G3)-(G1), G3 being the “substituted or unsubstituted alkyl group” in the specific example group G3, G1 being the “substituted or unsubstituted aryl group” in the specific example group G1. Accordingly, the “aralkyl group” is a group derived by substituting a hydrogen atom of the “alkyl group” with a substituent in a form of the “aryl group,” which is an example of the “substituted alkyl group.” An “unsubstituted aralkyl group,” which is an “unsubstituted alkyl group” substituted by an “unsubstituted aryl group,” has, unless otherwise specified herein, 7 to 50 carbon atoms, preferably 7 to 30 carbon atoms, more preferably 7 to 18 carbon atoms.

Specific examples of the “substituted or unsubstituted aralkyl group” include a benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, and 2-β-naphthylisopropyl group.

Preferable examples of the substituted or unsubstituted aryl group mentioned herein include, unless otherwise specified herein, a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, phenanthryl group, pyrenyl group, chrysenyl group, triphenylenyl group, fluorenyl group, 9,9′-spirobifluorenyl group, 9,9-dimethylfluorenyl group, and 9,9-diphenylfluorenyl group.

Preferable examples of the substituted or unsubstituted heterocyclic group mentioned herein include, unless otherwise specified herein, a pyridyl group, pyrimidinyl group, triazinyl group, quinolyl group, isoquinolyl group, quinazolinyl group, benzimidazolyl group, phenanthrolinyl group, carbazolyl group (1-carbazolyl group, 2-carbazolyl group, 3-carbazolyl group, 4-carbazolyl group, or 9-carbazolyl group), benzocarbazolyl group, azacarbazolyl group, diazacarbazolyl group, dibenzofuranyl group, naphthobenzofuranyl group, azadibenzofuranyl group, diazadibenzofuranyl group, dibenzothiophenyl group, naphthobenzothiophenyl group, azadibenzothiophenyl group, diazadibenzothiophenyl group, (9-phenyl)carbazolyl group ((9-phenyl)carbazole-1-yl group, (9-phenyl)carbazole-2-yl group, (9-phenyl)carbazole-3-yl group, or (9-phenyl)carbazole-4-yl group), (9-biphenylyl)carbazolyl group, (9-phenyl)phenylcarbazolyl group, diphenylcarbazole-9-yl group, phenylcarbazole-9-yl group, phenyltriazinyl group, biphenylyltriazinyl group, diphenyltriazinyl group, phenyldibenzofuranyl group, and phenyldibenzothiophenyl group.

The carbazolyl group mentioned herein is, unless otherwise specified herein, specifically a group represented by one of formulae below.

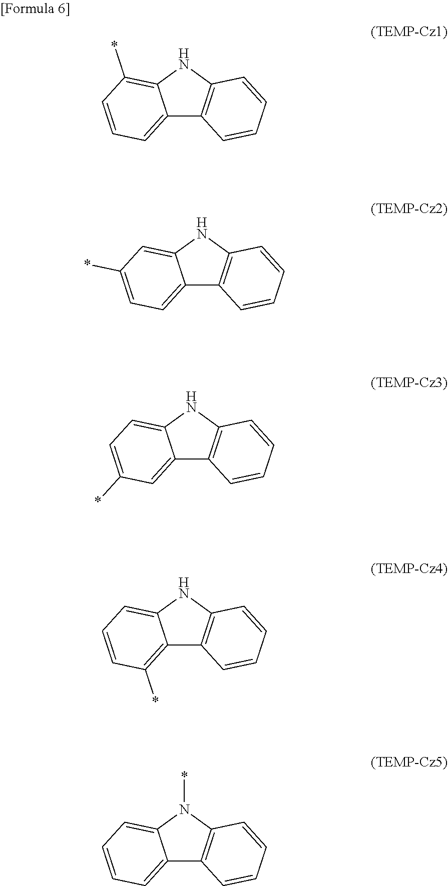 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

The (9-phenyl)carbazolyl group mentioned herein is, unless otherwise specified herein, specifically a group represented by one of formulae below.

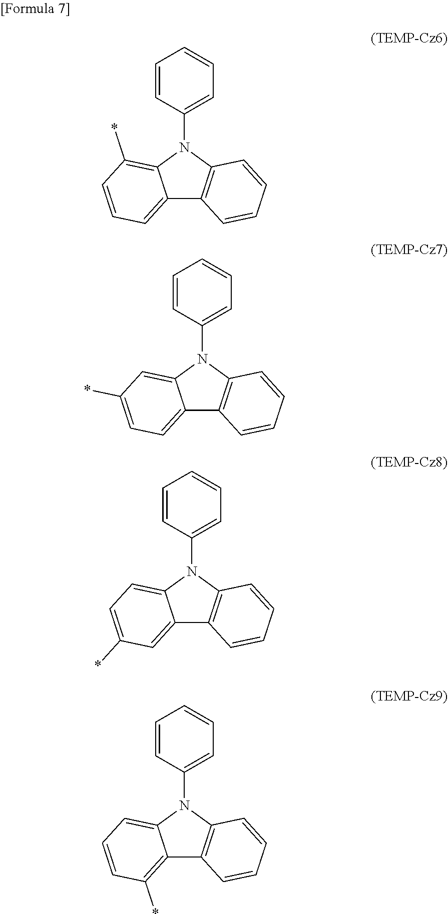

In formulae (TEMP-Cz1) to (TEMP-Cz9), * represents a bonding position.

The dibenzofuranyl group and dibenzothiophenyl group mentioned herein are, unless otherwise specified herein, each specifically represented by one of formulae below.

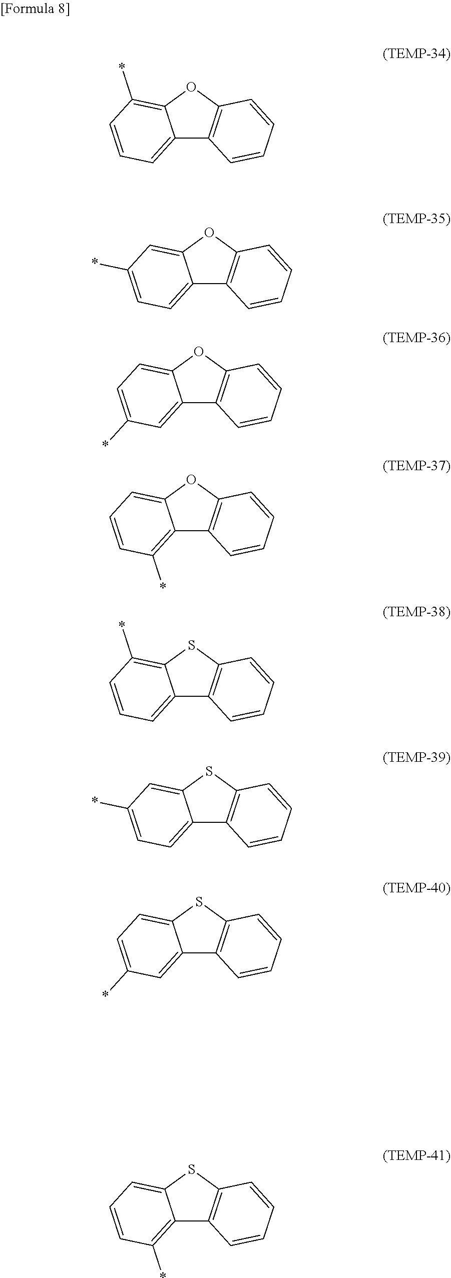

In formulae (TEMP-34) to (TEMP-41), * represents a bonding position.

Preferable examples of the substituted or unsubstituted alkyl group mentioned herein include, unless otherwise specified herein, a methyl group, ethyl group, propyl group, isopropyl group, n-butyl group, isobutyl group, and t-butyl group.

### Substituted or Unsubstituted Arylene Group

The “substituted or unsubstituted arylene group” mentioned herein is, unless otherwise specified herein, a divalent group derived by removing one hydrogen atom on an aryl ring of the “substituted or unsubstituted aryl group.” Specific examples of the “substituted or unsubstituted arylene group” (specific example group G12) include a divalent group derived by removing one hydrogen atom on an aryl ring of the “substituted or unsubstituted aryl group” in the specific example group G1.

### Substituted or Unsubstituted Divalent Heterocyclic Group

The “substituted or unsubstituted divalent heterocyclic group” mentioned herein is, unless otherwise specified herein, a divalent group derived by removing one hydrogen atom on a heterocycle of the “substituted or unsubstituted heterocyclic group.” Specific examples of the “substituted or unsubstituted divalent heterocyclic group” (specific example group G13) include a divalent group derived by removing one hydrogen atom on a heterocyclic ring of the “substituted or unsubstituted heterocyclic group” in the specific example group G2.

### Substituted or Unsubstituted Alkylene Group

The “substituted or unsubstituted alkylene group” mentioned herein is, unless otherwise specified herein, a divalent group derived by removing one hydrogen atom on an alkyl chain of the “substituted or unsubstituted alkyl group.” Specific examples of the “substituted or unsubstituted alkylene group” (specific example group G14) include a divalent group derived by removing one hydrogen atom on an alkyl chain of the “substituted or unsubstituted alkyl group” in the specific example group G3.

The substituted or unsubstituted arylene group mentioned herein is, unless otherwise specified herein, preferably any one of groups represented by formulae (TEMP-42) to (TEMP-68) below.

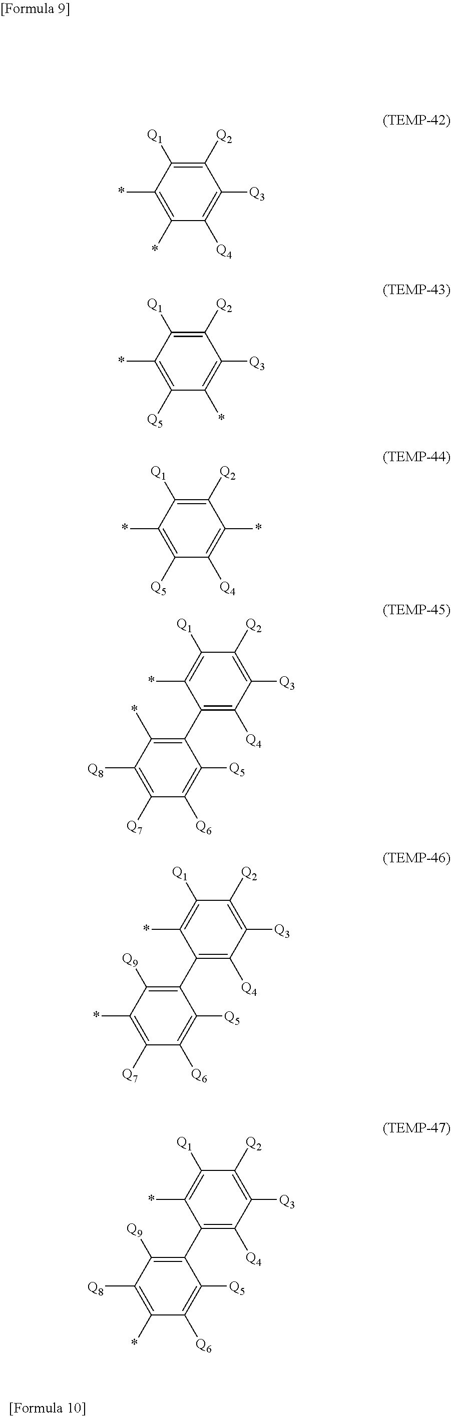

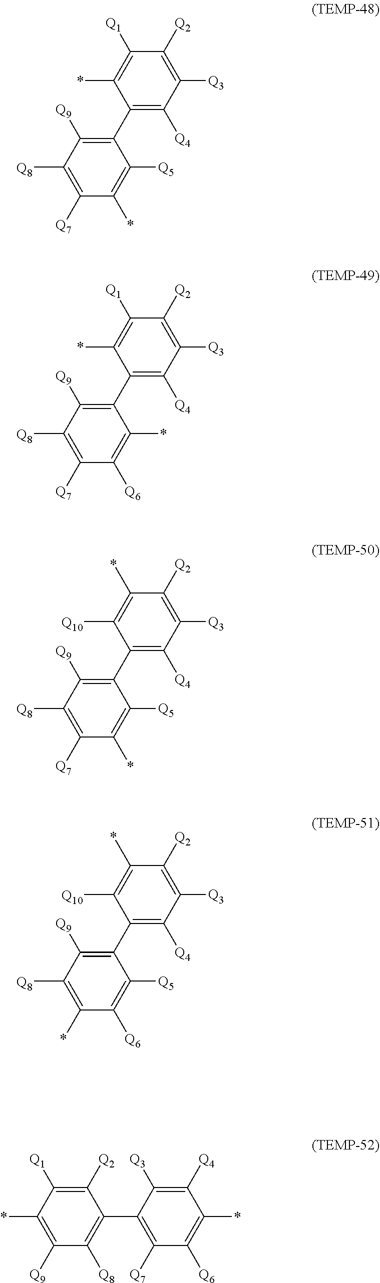

In formulae (TEMP-42) to (TEMP-52), Q₁ to Q₁₀ are each independently a hydrogen atom or a substituent.

In formulae (TEMP-42) to (TEMP-52), * represents a bonding position.

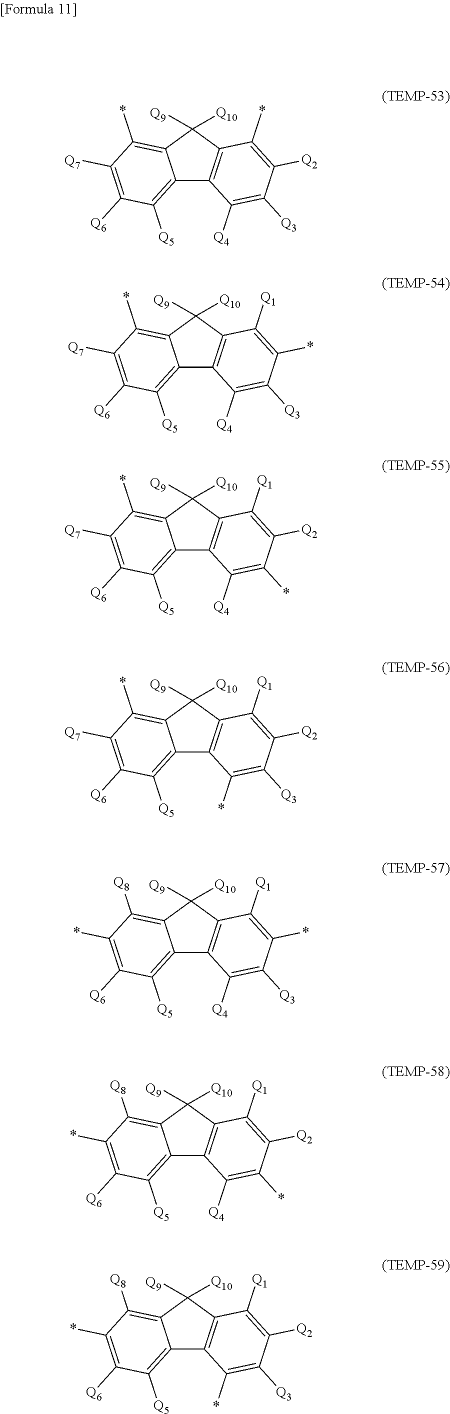

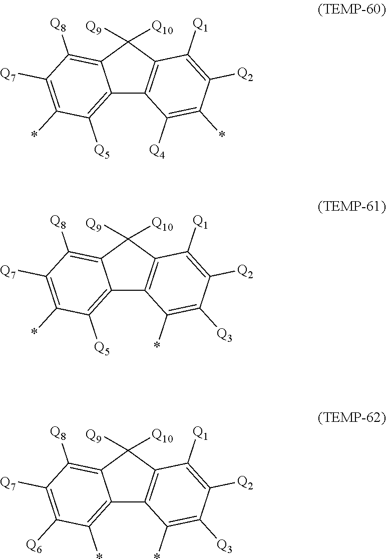

In formulae (TEMP-53) to (TEMP-62), Q₁ to Q₁₀ are each independently a hydrogen atom or a substituent.

In formulae, Q₉ and Q₁₀ may be mutually bonded through a single bond to form a ring.

In formulae (TEMP-53) to (TEMP-62), * represents a bonding position.

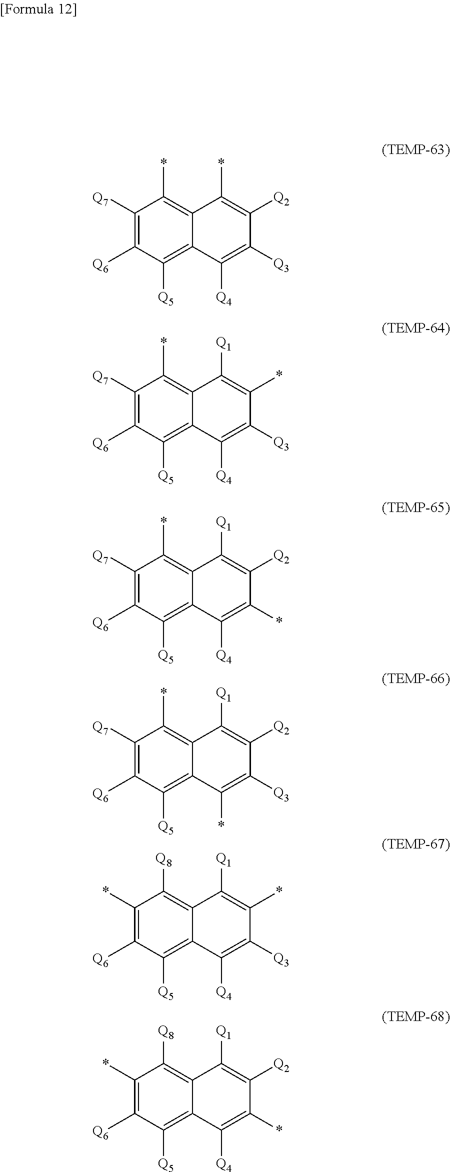

In formulae (TEMP-63) to (TEMP-68), Q₁ to Q₈ are each independently a hydrogen atom or a substituent.

In formulae (TEMP-63) to (TEMP-68), * represents a bonding position.

The substituted or unsubstituted divalent heterocyclic group mentioned herein is, unless otherwise specified herein, preferably a group represented by any one of formulae (TEMP-69) to (TEMP-102) below.

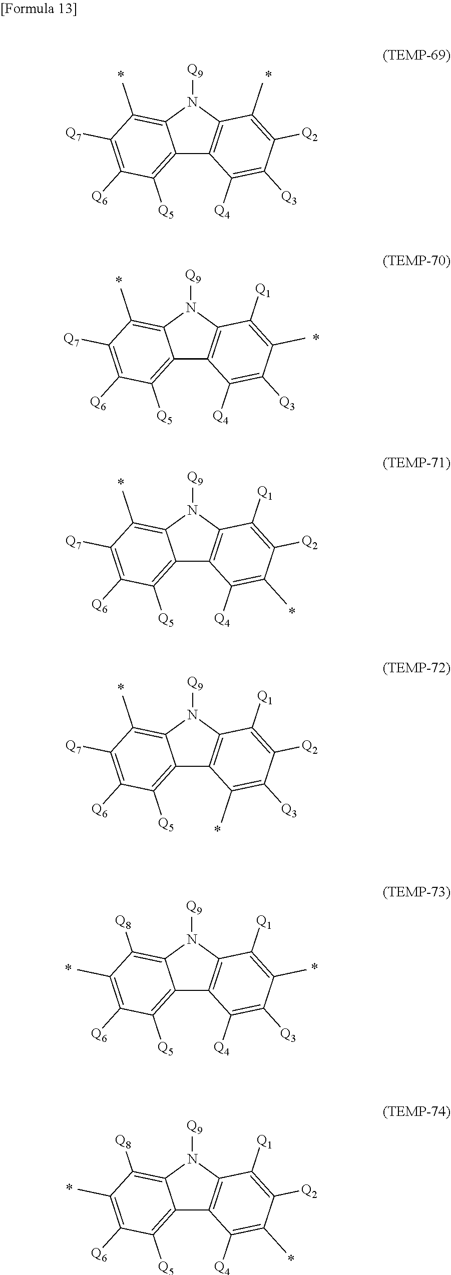

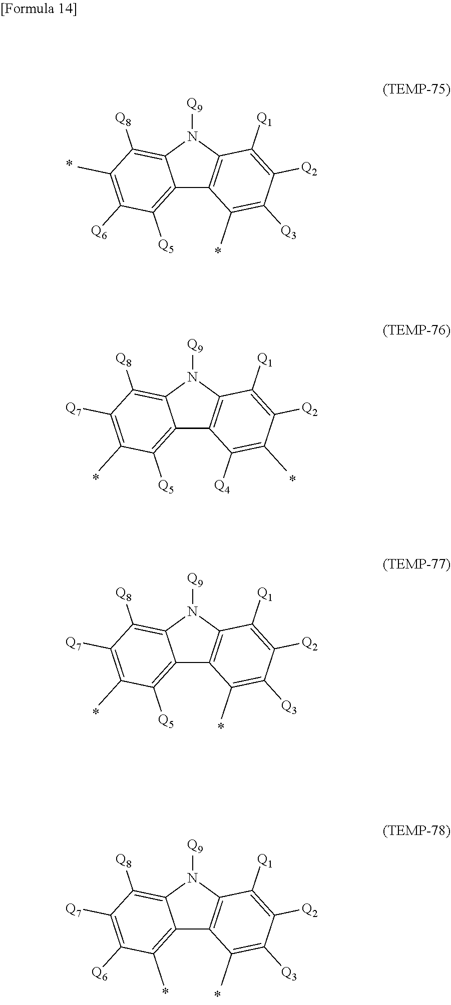

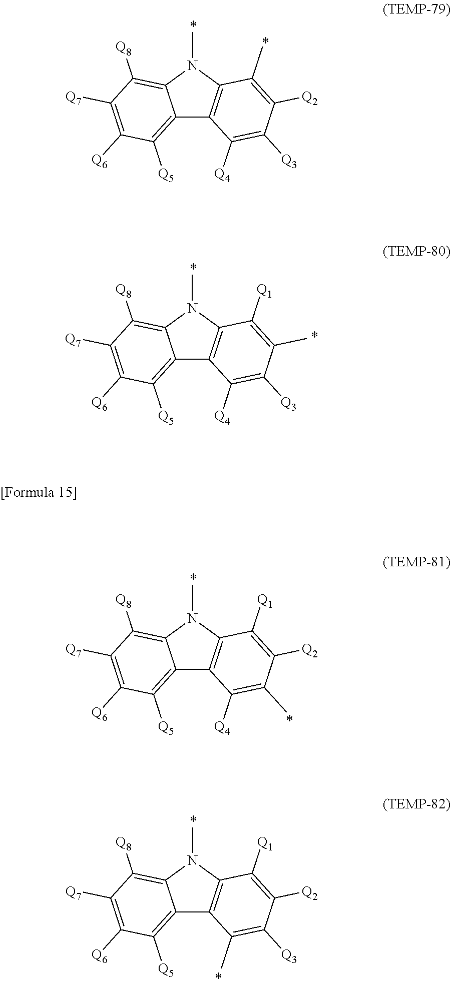

In formulae (TEMP-69) to (TEMP-82), Q₁ to Q₉ are each independently a hydrogen atom or a substituent.

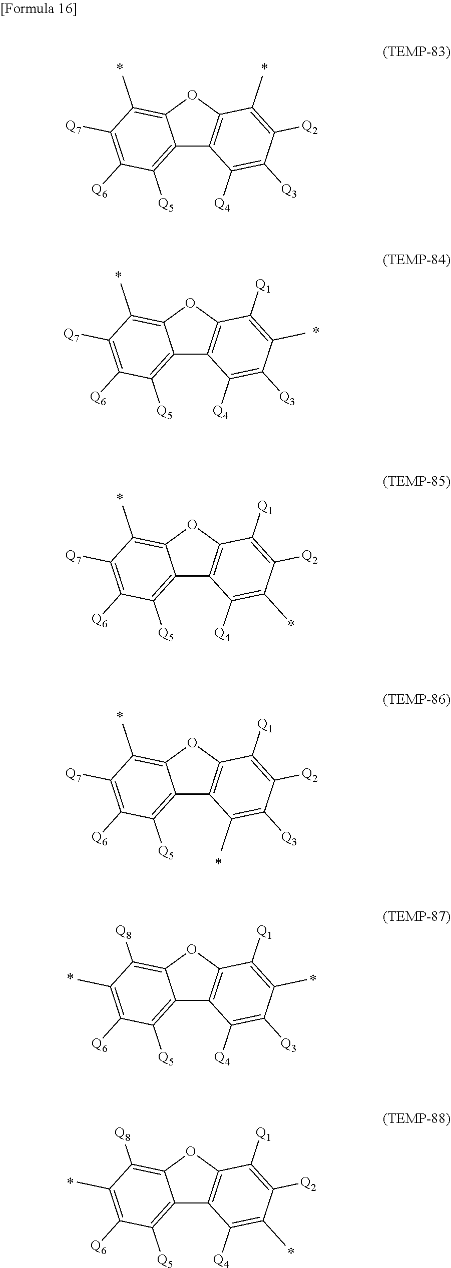

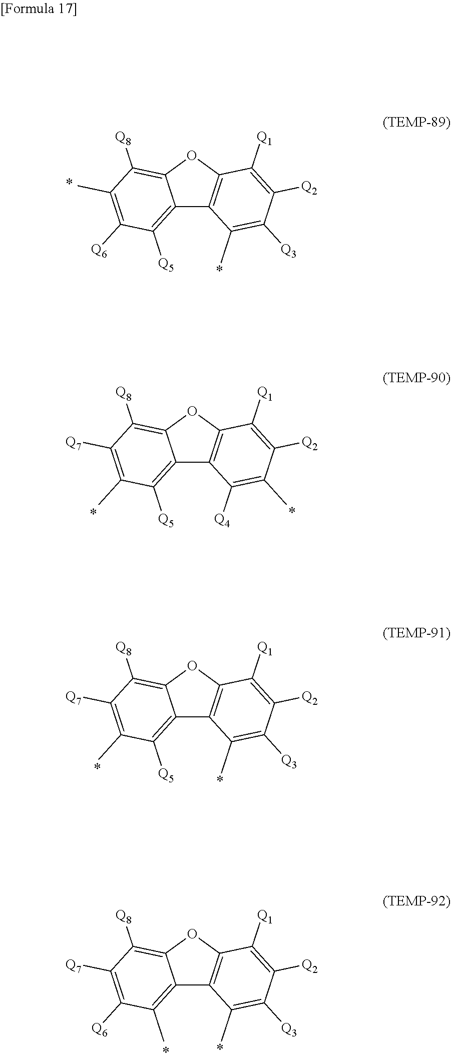

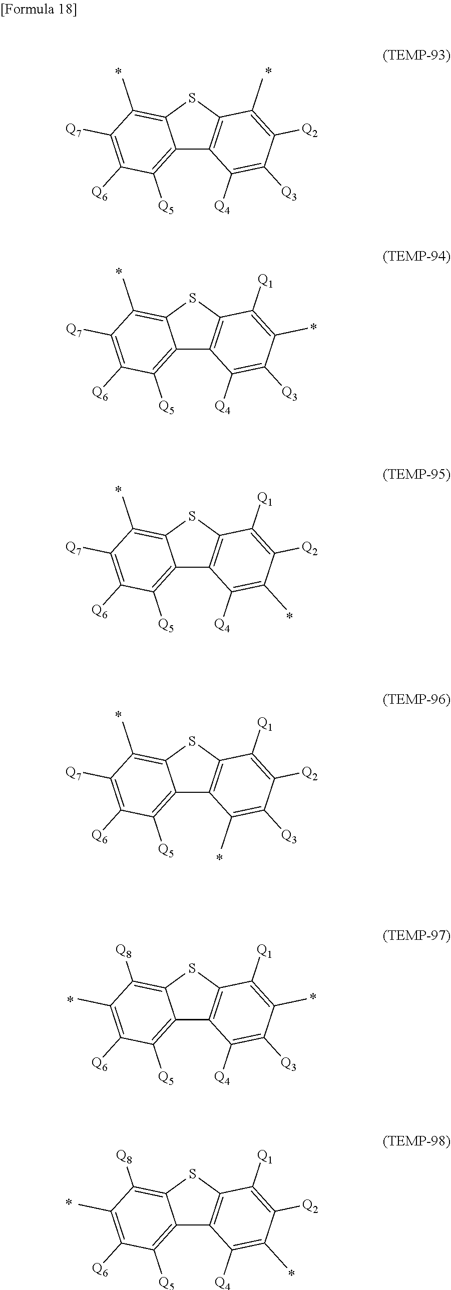

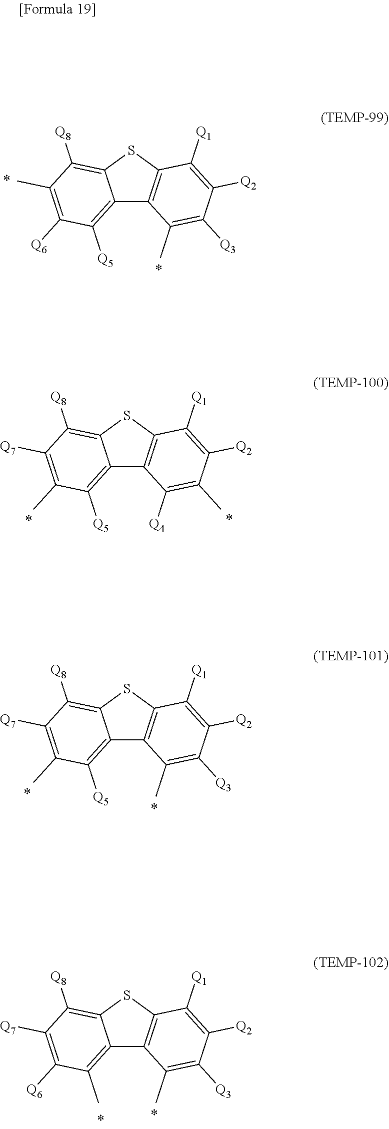

In formulae (TEMP-83) to (TEMP-102), Q₁ to Q₈ are each independently a hydrogen atom or a substituent.

The substituent mentioned herein has been described above.

### Instance of “Bonded to Form Ring”

Instances where “at least one combination of adjacent two or more (of . . . ) are mutually bonded to form a substituted or unsubstituted monocyclic ring, mutually bonded to form a substituted or unsubstituted fused ring, or not mutually bonded” mentioned herein refer to instances where “at least one combination of adjacent two or more (of . . . ) are mutually bonded to form a substituted or unsubstituted monocyclic ring, “at least one combination of adjacent two or more (of . . . ) are mutually bonded to form a substituted or unsubstituted fused ring,” and “at least one combination of adjacent two or more (of . . . ) are not mutually bonded.”

Instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (these instances will be sometimes collectively referred to as an instance of “bonded to form a ring” hereinafter) will be described below. An anthracene compound having a basic skeleton in a form of an anthracene ring and represented by formula (TEMP-103) below will be used as an example for the description.

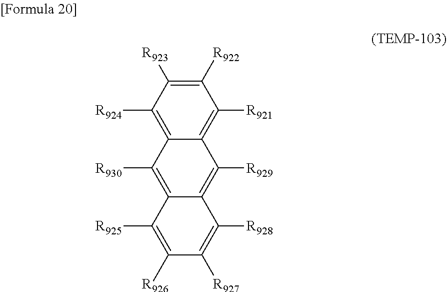

For instance, when “at least one combination of adjacent two or more of R₉₂₁ to R₉₃₀ are mutually bonded to form a ring,” the combination of adjacent ones of R₉₂₁ to R₉₃₀ (i.e. the combination at issue) is a combination of R₉₂₁ and R₉₂₂, a combination of R₉₂₂ and R₉₂₃, a combination of R₉₂₃ and R₉₂₄, a combination of R₉₂₄ and R₉₃₀, a combination of R₉₃₀ and R₉₂₅, a combination of R₉₂₅ and R₉₂₆, a combination of R₉₂₆ and R₉₂₇, a combination of R₉₂₇ and R₉₂₈, a combination of R₉₂₈ and R₉₂₉, or a combination of R₉₂₉ and R₉₂₁.

The term “at least one combination” means that two or more of the above combinations of adjacent two or more of R₉₂₁ to R₉₃₀ may simultaneously form rings. For instance, when R₉₂₁ and R₉₂₂ are mutually bonded to form a ring Q_{A} and R₉₂₅ and R₉₂₆ are simultaneously mutually bonded to form a ring Q_{B}, the anthracene compound represented by formula (TEMP-103) is represented by formula (TEMP-104) below.

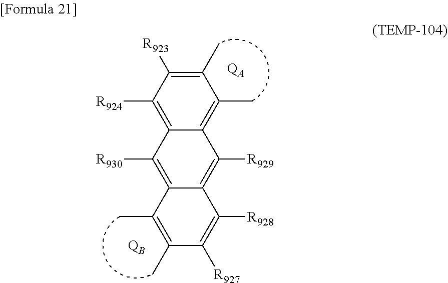

The instance where the “combination of adjacent two or more” form a ring means not only an instance where the “two” adjacent components are bonded but also an instance where adjacent “three or more” are bonded. For instance, R₉₂₁ and R₉₂₂ are mutually bonded to form a ring Q_{A} and R₉₂₂ and R₉₂₃ are mutually bonded to form a ring Q_{C}, and mutually adjacent three components (R₉₂₁, R₉₂₂ and R₉₂₃) are mutually bonded to form a ring fused to the anthracene basic skeleton. In this case, the anthracene compound represented by formula (TEMP-103) is represented by formula (TEMP-105) below. In formula (TEMP-105) below, the ring Q_{A} and the ring Q_{C} share R₉₂₂.

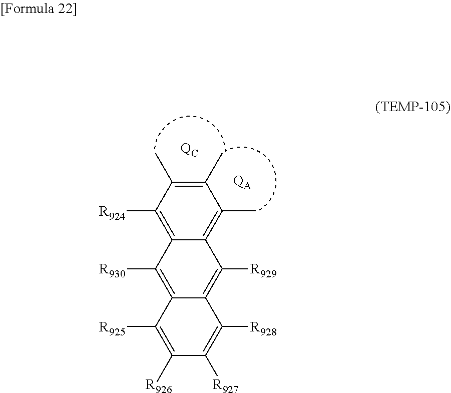

The formed “monocyclic ring” or “fused ring” may be, in terms of the formed ring in itself, a saturated ring or an unsaturated ring. When the “combination of adjacent two” form a “monocyclic ring” or a “fused ring,” the “monocyclic ring” or “fused ring” may be a saturated ring or an unsaturated ring. For instance, the ring Q_{A} and the ring Q_{B} formed in formula (TEMP-104) are each independently a “monocyclic ring” or a “fused ring.” Further, the ring Q_{A} and the ring Q_{C} formed in formula (TEMP-105) are each a “fused ring.” The ring Q_{A} and the ring Q_{C} in formula (TEMP-105) are fused to form a fused ring. When the ring Q_{A} in formula (TEMP-104) is a benzene ring, the ring Q_{A} is a monocyclic ring. When the ring Q_{A} in formula (TEMP-104) is a naphthalene ring, the ring Q_{A} is a fused ring.

The “unsaturated ring” represents an aromatic hydrocarbon ring or an aromatic heterocycle. The “saturated ring” represents an aliphatic hydrocarbon ring or a non-aromatic heterocycle.

Specific examples of the aromatic hydrocarbon ring include a ring formed by terminating a bond of a group in the specific example of the specific example group G1 with a hydrogen atom.

Specific examples of the aromatic heterocycle include a ring formed by terminating a bond of an aromatic heterocyclic group in the specific example of the specific example group G2 with a hydrogen atom.

Specific examples of the aliphatic hydrocarbon ring include a ring formed by terminating a bond of a group in the specific example of the specific example group G6 with a hydrogen atom.

The phrase “to form a ring” herein means that a ring is formed only by a plurality of atoms of a basic skeleton, or by a combination of a plurality of atoms of the basic skeleton and one or more optional atoms. For instance, the ring Q_{A} formed by mutually bonding R₉₂₁ and R₉₂₂ shown in formula (TEMP-104) is a ring formed by a carbon atom of the anthracene skeleton bonded to R₉₂₁, a carbon atom of the anthracene skeleton bonded to R₉₂₂, and one or more optional atoms. Specifically, when the ring Q_{A} is a monocyclic unsaturated ring formed by R₉₂₁ and R₉₂₂, the ring formed by a carbon atom of the anthracene skeleton bonded to R₉₂₁, a carbon atom of the anthracene skeleton bonded to R₉₂₂, and four carbon atoms is a benzene ring.

The “optional atom” is, unless otherwise specified herein, preferably at least one atom selected from the group consisting of a carbon atom, nitrogen atom, oxygen atom, and sulfur atom. A bond of the optional atom (e.g. a carbon atom and a nitrogen atom) not forming a ring may be terminated by a hydrogen atom or the like or may be substituted by an “optional substituent” described later. When the ring includes an optional element other than carbon atom, the resultant ring is a heterocycle.

The number of “one or more optional atoms” forming the monocyclic ring or fused ring is, unless otherwise specified herein, preferably in a range from 2 to 15, more preferably in a range from 3 to 12, further preferably in a range from 3 to 5.

Unless otherwise specified herein, the ring, which may be a “monocyclic ring” or “fused ring,” is preferably a “monocyclic ring.”

Unless otherwise specified herein, the ring, which may be a “saturated ring” or “unsaturated ring,” is preferably an “unsaturated ring.”

Unless otherwise specified herein, the “monocyclic ring” is preferably a benzene ring.

Unless otherwise specified herein, the “unsaturated ring” is preferably a benzene ring.

When “at least one combination of adjacent two or more” (of . . . ) are “mutually bonded to form a substituted or unsubstituted monocyclic ring” or “mutually bonded to form a substituted or unsubstituted fused ring,” unless otherwise specified herein, at least one combination of adjacent two or more of components are preferably mutually bonded to form a substituted or unsubstituted “unsaturated ring” formed of a plurality of atoms of the basic skeleton, and 1 to 15 atoms of at least one element selected from the group consisting of carbon, nitrogen, oxygen and sulfur.

When the “monocyclic ring” or the “fused ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”.

When the “saturated ring” or the “unsaturated ring” has a substituent, the substituent is the substituent described in later-described “optional substituent.” When the “monocyclic ring” or the “fused ring” has a substituent, specific examples of the substituent are the substituents described in the above under the subtitle “Substituent Mentioned Herein.”

The above is the description for the instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (sometimes referred to as an instance of “bonded to form a ring”).

### Substituent for Substituted or Unsubstituted Group

In an exemplary embodiment herein, a substituent for the substituted or unsubstituted group (sometimes referred to as an “optional substituent” hereinafter) is, for instance, a group selected from the group consisting of an unsubstituted alkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, an unsubstituted aryl group having 6 to 50 ring carbon atoms, and an unsubstituted heterocyclic group having 5 to 50 ring atoms.

R₉₀₁ to R₉₀₇ each independently represent a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms.

When two or more R₉₀₁ are present, the two or more R₉₀₁ are mutually the same or different,

when two or more R₉₀₂ are present, the two or more R₉₀₂ are mutually the same or different,

when two or more R₉₀₃ are present, the two or more R₉₀₃ are mutually the same or different,

when two or more R₉₀₄ are present, the two or more R₉₀₄ are mutually the same or different,

when two or more R₉₀₅ are present, the two or more R₉₀₅ are mutually the same or different,

when two or more R₉₀₆ are present, the two or more R₉₀₆ are mutually the same or different, and

when two or more R₉₀₇ are present, the two or more R₉₀₇ are mutually the same or different.

In an exemplary embodiment, a substituent for the substituted or unsubstituted group is selected from the group consisting of an alkyl group having 1 to 50 carbon atoms, an aryl group having 6 to 50 ring carbon atoms, and a heterocyclic group having 5 to 50 ring atoms.

In an exemplary embodiment, a substituent for the substituted or unsubstituted group is selected from the group consisting of an alkyl group having 1 to 18 carbon atoms, an aryl group having 6 to 18 ring carbon atoms, and a heterocyclic group having 5 to 18 ring atoms.

Specific examples of the above optional substituent are the same as the specific examples of the substituent described in the above under the subtitle “Substituent Mentioned Herein.”

Unless otherwise specified herein, adjacent ones of the optional substituents may form a “saturated ring” or an “unsaturated ring,” preferably a substituted or unsubstituted saturated five-membered ring, a substituted or unsubstituted saturated six-membered ring, a substituted or unsubstituted unsaturated five-membered ring, or a substituted or unsubstituted unsaturated six-membered ring, more preferably a benzene ring.

Unless otherwise specified herein, the optional substituent may further include a substituent. Examples of the substituent for the optional substituent are the same as the examples of the optional substituent.

Herein, numerical ranges represented by “AA to BB” represent a range whose lower limit is the value (AA) recited before “to” and whose upper limit is the value (BB) recited after “to.”

### First Exemplary Embodiment

### Organic Electroluminescence Device

An organic electroluminescence device according to a first exemplary embodiment includes an anode, a cathode, an emitting layer between the anode and the cathode, and a first hole transporting layer between the anode and the emitting layer, in which the first hole transporting layer is directly adjacent to the emitting layer, the first hole transporting layer contains a first compound represented by formula (1) below, and the first compound has at least one group represented by formula (11) below.

### Emission Wavelength of Organic EL Device

Preferably, the organic electroluminescence device according to this exemplary embodiment emits light with a maximum peak wavelength in a range from 430 nm to 480 nm when driven.

The measurement of the maximum peak wavelength of the light emitted by the driven organic EL device is done as follows. A voltage is applied to the organic EL device to a current density of 10 mA/cm², and the spectral radiance spectrum in this state is measured with CS-2000 spectroradiometer (Konica Minolta Holdings). In the spectral radiance spectrum obtained, the peak wavelength of the emission spectrum at which the luminous intensity peaks is measured, and defined as the maximum peak wavelength (unit: nm).

The organic EL device according to this exemplary embodiment may have one or more organic layers besides the emitting layer and the first hole transporting layer. The organic layer(s) can be, for example, at least any layer selected from the group consisting of a hole injecting layer, a hole transporting layer, an emitting layer, an electron injecting layer, an electron transporting layer, a hole blocking layer, and an electron blocking layer.

The organic EL device according to this exemplary embodiment may consist of the emitting layer and the first hole transporting layer as organic layers, but alternatively, the device may further have, for example, at least any layer selected from the group consisting of a hole injecting layer, a hole transporting layer, an electron injecting layer, an electron transporting layer, a hole blocking layer, an electron blocking layer, etc.

### Electron Transporting Layer

Preferably, the organic EL device according to this exemplary embodiment has an electron transporting layer between the cathode and the emitting layer.

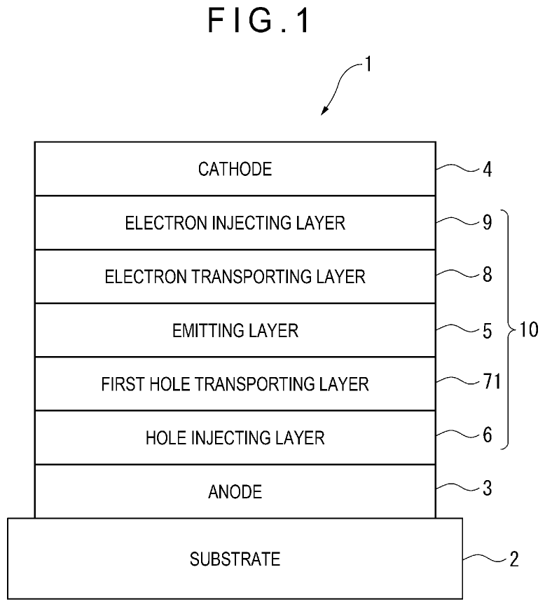

FIG. 1 illustrates an outline of an example of an organic EL device according to this exemplary embodiment.

The organic EL device 1 includes a light-transmissive substrate 2, an anode 3, a cathode 4, and an organic layer 10 between the anode 3 and the cathode 4. The organic layer 10 is formed by a hole injecting layer 6, a first hole transporting layer 71, an emitting layer 5, an electron transporting layer 8, and an electron injecting layer 9 stacked in this order on the anode 3.

### First Hole Transporting Layer

The first hole transporting layer is directly adjacent to the emitting layer. The first hole transporting layer contains a first compound represented by formula (1) below.

Preferably, the thickness of the first hole transporting layer is 15 nm or less.

Preferably, the thickness of the first hole transporting layer is 2 nm or more.

More preferably, the thickness of the first hole transporting layer is in a range from 2 nm to 10 nm, even more preferably in a range from 2 nm to 5 nm.

### First Compound

The first compound is a compound represented by formula (1) below. The first compound has at least one group represented by formula (11) below.

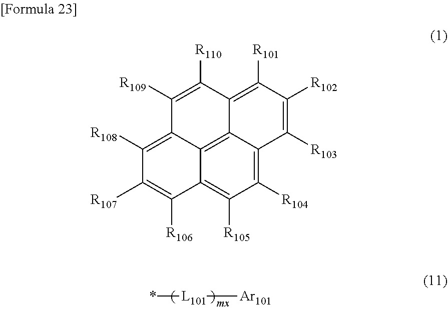

In formula (1),

R₁₀₁ to R₁₁₀ each independently represent: a hydrogen atom; a substituted or unsubstituted alkyl group having 1 to 50 carbon atoms; a substituted or unsubstituted haloalkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a substituted or unsubstituted aralkyl group having 7 to 50 carbon atoms; a group represented by —C(═O)R₈₀₁; a group represented by —COOR₈₀₂; a halogen atom; a cyano group; a nitro group; a substituted or unsubstituted aryl group having 6 to 50 ring carbon atoms; a substituted or unsubstituted heterocyclic group having 5 to 50 ring atoms; or a group represented by formula (11);

at least one of R₁₀₁ to R₁₁₀ is a group represented by formula (11);

when multiple groups represented by formula (11) are present, the multiple groups represented by formula (11) are mutually the same or different;

L₁₀₁ is: a single bond; a substituted or unsubstituted arylene group having 6 to 50 ring carbon atoms; or a substituted or unsubstituted divalent heterocyclic group having 5 to 50 ring atoms;

Ar₁₀₁ is: a substituted or unsubstituted aryl group having 6 to 50 ring carbon atoms; or a substituted or unsubstituted heterocyclic group having 5 to 50 ring atoms;

mx is 0, 1, 2, 3, 4, or 5;

when two or more L₁₀₁s are present, the two or more L₁₀₁s are mutually the same or different;

when two or more Ar₁₀₁s are present, the two or more Ar₁₀₁s are mutually the same or different; and

* in formula (11) indicates the position of bonding with the pyrene ring in formula (1).

A substituent for “substituted or unsubstituted” group in the first compound is at least any one selected from the group consisting of: an unsubstituted alkyl group having 1 to 50 carbon atoms; an unsubstituted alkenyl group having 2 to 50 carbon atoms; an unsubstituted alkynyl group having 2 to 50 carbon atoms; an unsubstituted cycloalkyl group having 3 to 50 ring carbon atoms; —Si(R₉₀₁)(R₉₀₂)(R₉₀₃); —O—(R₉₀₄); —S—(R₉₀₅); a halogen atom; a cyano group; a nitro group; an unsubstituted aryl group having 6 to 50 ring carbon atoms; and an unsubstituted heterocyclic group having 5 to 50 ring atoms.

In the first compound, represented by formula (1), R₉₀₁, R₉₀₂, R₉₀₃, R₉₀₄, R₉₀₅, R₉₀₅, R₉₀₇, R₈₀₁, and R₈₀₂ each independently represent: a hydrogen atom; a substituted or unsubstituted alkyl group having 1 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms; when multiple R₉₀₁s are present, the multiple R₉₀₁s are mutually the same or different;

when multiple R₉₀₂s are present, the multiple R₉₀₂s are mutually the same or different;

when multiple R₉₀₃s are present, the multiple R₉₀₃s are mutually the same or different;

when multiple R₉₀₄s are present, the multiple R₉₀₄s are mutually the same or different;

when multiple R₉₀₅s are present, the multiple R₉₀₅s are mutually the same or different;

when multiple R₉₀₆s are present, the multiple R₉₀₆s are mutually the same or different;

when multiple R₉₀₇s are present, the multiple R₉₀₇s are mutually the same or different;

when multiple R₈₀₁s are present, the multiple R₈₀₁s are mutually the same or different; and when multiple R₈₀₂s are present, the multiple R₈₀₂s are mutually the same or different.

Preferably, any heterocyclic group in the first compound is a group containing at least any of an oxygen or sulfur atom.

Preferably, the group represented by formula (11) is a group represented by formula (111) below.

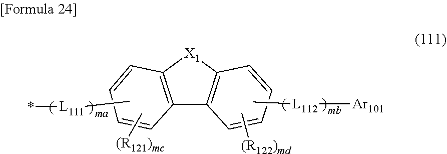

In formula (111),

X₁ is CR₁₂₃R₁₂₄, an oxygen atom, a sulfur atom, or NR₁₂₅;

L₁₁₁ and L₁₁₂ each independently represent: a single bond; a substituted or unsubstituted arylene group having 6 to 50 ring carbon atoms; or a substituted or unsubstituted divalent heterocyclic group having 5 to 50 ring atoms;

ma is 0, 1, 2, 3, or 4;

mb is 0, 1, 2, 3, or 4;

ma+mb is 0, 1, 2, 3, or 4;

Ar₁₀₁ represents the same as Ar₁₀₁ in formula (11);

R₁₂₁, R₁₂₂, R₁₂₃, R₁₂₄, and R₁₂₅ each independently represent: a hydrogen atom; a substituted or unsubstituted alkyl group having 1 to 50 carbon atoms; a substituted or unsubstituted haloalkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a substituted or unsubstituted aralkyl group having 7 to 50 carbon atoms; a group represented by —C(═O)R₈₀₁; a group represented by —COOR₈₀₂; a halogen atom; a cyano group; a nitro group; a substituted or unsubstituted aryl group having 6 to 50 ring carbon atoms; or a substituted or unsubstituted heterocyclic group having 5 to 50 ring atoms;

mc is 3;

the three R₁₂₁s are mutually the same or different;

md is 3; and

the three R₁₂₂s are mutually the same or different.

Among positions *1 to *8 of carbon atoms in a cyclic structure represented by formula (111a) below in a group represented by formula (111), L₁₁₁ is bonded to one of the positions *1 to *4, R₁₂₁ is bonded to each of three positions of the rest of *1 to *4, L₁₁₂ is bonded to one of the positions *5 to *8, and R₁₂₂ is bonded to each of three positions of the rest of *5 to *8.

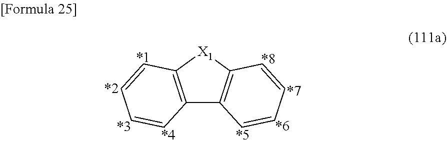

For instance, in a group represented by formula (111), when L₁₁₁ is bonded to a carbon atom at a position *2 in the cyclic structure represented by formula (111a) and L₁₁₂ is bonded to a carbon atom at a position *7 in the cyclic structure represented by formula (111a), the group represented by formula (111) is represented by formula (111b) below.

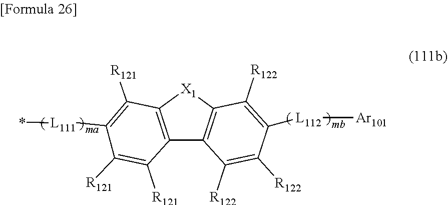

In formula (111b),

X₁, L₁₁₁, L₁₁₂, ma, mb, Ar₁₀₁, R₁₂₁, R₁₂₂, R₁₂₃, R₁₂₄, and R₁₂₅ each independently represent the same as X₁, L₁₁₁, L₁₁₂, ma, mb, Ar₁₀₁, R₁₂₁, R₁₂₂, R₁₂₃, R₁₂₄, and R₁₂₅ in formula (111);

the multiple R₁₂₁s are mutually the same or different; and

the multiple R₁₂₂s are mutually the same or different.

In the organic EL device according to this exemplary embodiment, it is preferred that the group represented by formula (111) be a group represented by formula (111b).

In the organic EL device according to this exemplary embodiment, it is preferred that ma be 0, 1, or 2 and mb be 0, 1, or 2.

In the organic EL device according to this exemplary embodiment, it is preferred that ma be 0 or 1 and mb be 0 or 1.

If, in a group represented by formula (111), ma is 0 and if mb is 1, the group represented by formula (111) is represented by formula (111c) below.

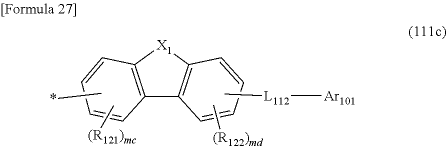

In formula (111c), X₁, L₁₁₂, mc, md, Ar₁₀₁, R₁₂₁, and R₁₂₂ each independently represent the same as X₁, L₁₁₂, mc, md, Ar₁₀₁, R₁₂₁, and R₁₂₂ in formula (111).

In the organic EL device according to this exemplary embodiment, it is preferred that Ar₁₀₁ be a substituted or unsubstituted aryl group having 6 to 50 ring carbon atoms.

In the organic EL device according to this exemplary embodiment, it is preferred that Ar₁₀₁ be a substituted or unsubstituted phenyl, substituted or unsubstituted naphthyl, substituted or unsubstituted biphenyl, substituted or unsubstituted terphenyl, substituted or unsubstituted pyrenyl, substituted or unsubstituted phenanthryl, or substituted or unsubstituted fluorenyl group.

In the organic EL device according to this exemplary embodiment, it is also preferred that Ar₁₀₁ be a group represented by formula (12), (13), or (14) below.

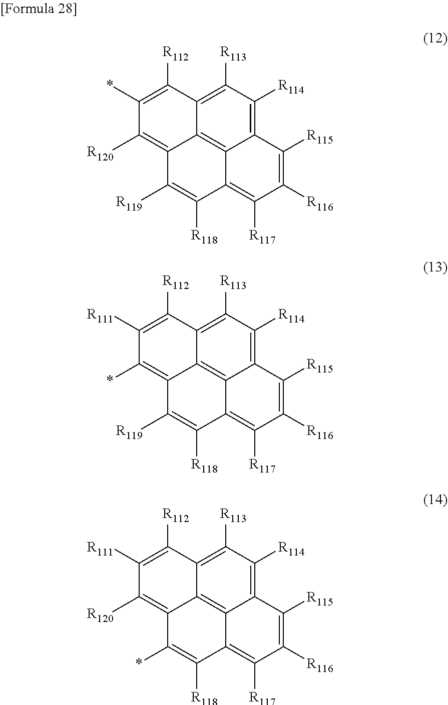

In formulae (12), (13), and (14),

R₁₁₁ to R₁₂₀ each independently represent: a hydrogen atom; a substituted or unsubstituted alkyl group having 1 to 50 carbon atoms; a substituted or unsubstituted haloalkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); group represented by —N(R₉₀₆)(R₉₀₇); a substituted or unsubstituted aralkyl group having 7 to 50 carbon atoms; a group represented by —C(═O)R₁₂₄; a group represented by —COOR₁₂₅; a halogen atom; a cyano group; a nitro group; a substituted or unsubstituted aryl group having 6 to 50 ring carbon atoms; or a substituted or unsubstituted heterocyclic group having 5 to 50 ring atoms; and

* in formulae (12), (13), and (14) indicates the position of bonding with L₁₀₁ in formula (11) or that with L₁₁₂ in formula (111), (111 b), or (111c).

It is also preferred that R₁₂₄ and R₁₂₅ in formulae (12), (13), and (14) each independently represent the same as R₈₀₁ and R₈₀₂ in the foregoing.

Preferably, the first compound is represented by formula (101) below.

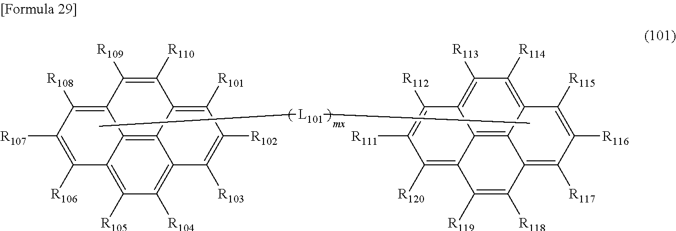

In formula (101),

R₁₀₁ to R₁₂₀ each independently represent: a hydrogen atom; a substituted or unsubstituted alkyl group having 1 to 50 carbon atoms; a substituted or unsubstituted haloalkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a substituted or unsubstituted aralkyl group having 7 to 50 carbon atoms; a group represented by —C(═O)R₈₀₁; a group represented by —COOR₈₀₂; a halogen atom; a cyano group; a nitro group; a substituted or unsubstituted aryl group having 6 to 50 ring carbon atoms; or a substituted or unsubstituted heterocyclic group having 5 to 50 ring atoms;

one of R₁₀₁ to R₁₁₀ indicates a position of bonding with L₁₀₁, and one of R₁₁₁ to R₁₂₀ indicates a position of bonding with L₁₀₁;

L₁₀₁ is: a single bond; a substituted or unsubstituted arylene group having 6 to 50 ring carbon atoms; or a substituted or unsubstituted divalent heterocyclic group having 5 to 50 ring atoms;

mx is 0, 1, 2, 3, 4, or 5; and

when two or more L₁₀₁s are present, the two or more L₁₀₁s are mutually the same or different.

If, in formula (101), R₁₀₃ is a position of bonding with L₁₀₁ and if R₁₂₀ is a position of bonding with L₁₀₁, the compounds represented by formula (101) are represented by formula (101A) below.

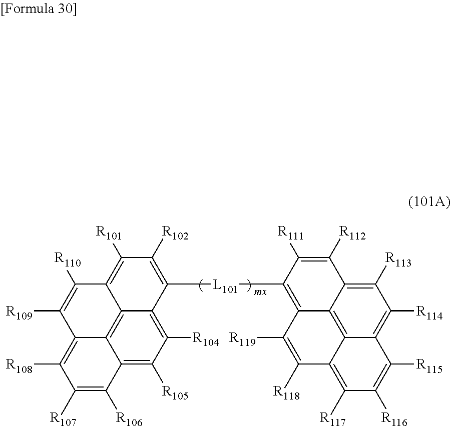

In formula (101A), R₁₀₁, R₁₀₂, R₁₀₄ to R₁₁₉, L₁₀₁, and mx represent the same as R₁₀₁, R₁₀₂, R₁₀₄ to R₁₁₉, L₁₀₁, and mx, respectively, in formula (101).

In the organic EL device according to this exemplary embodiment, it is preferred that L₁₀₁ be a single bond or a substituted or unsubstituted arylene group having 6 to 50 ring carbon atoms.

In the organic EL device according to this exemplary embodiment, it is preferred that the first compound be represented by formula (102) below.

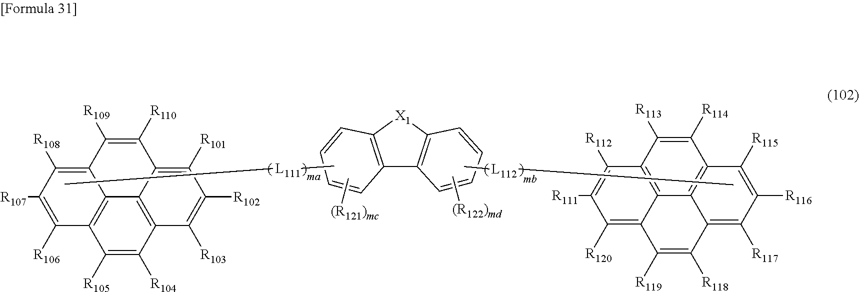

In formula (102),

R₁₀₁ to R₁₂₀ each independently represent the same as R₁₀₁ to R₁₂₀ in formula (101);

one of R₁₀₁ to R₁₁₀ indicates a position of bonding with L₁₁₁, and one of R₁₁₁ to R₁₂₀ indicates a position of bonding with L₁₁₂;

X₁ is CR₁₂₃R₁₂₄, an oxygen atom, a sulfur atom, or NR₁₂₅;

L₁₁₁ and L₁₁₂ each independently represent: a single bond; a substituted or unsubstituted arylene group having 6 to 50 ring carbon atoms; or a substituted or unsubstituted divalent heterocyclic group having 5 to 50 ring atoms;

ma is 0, 1, 2, 3, or 4;

mb is 0, 1, 2, 3, or 4;

ma+mb is 0, 1, 2, 3, or 4;

R₁₂₁, R₁₂₂, R₁₂₃, R₁₂₄, and R₁₂₅ each independently represent: a hydrogen atom; a substituted or unsubstituted alkyl group having 1 to 50 carbon atoms; a substituted or unsubstituted haloalkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a substituted or unsubstituted aralkyl group having 7 to 50 carbon atoms; a group represented by —C(═O)R₈₀₁; a group represented by —COOR₈₀₂; a halogen atom; a cyano group; a nitro group; a substituted or unsubstituted aryl group having 6 to 50 ring carbon atoms; or a substituted or unsubstituted heterocyclic group having 5 to 50 ring atoms;

mc is 3;

the three R₁₂₁s are mutually the same or different;

md is 3; and

the three R₁₂₂s are mutually the same or different.

In the compounds represented by formula (102), it is preferred that ma be 0, 1, or 2 and mb be 0,1, or 2.

In the compounds represented by formula (102), it is preferred that ma be 0 or 1 and mb be 0 or 1.

In the organic EL device according to this exemplary embodiment, it is preferred that two or more of R₁₀₁ to R₁₁₀ be groups represented by formula (11).

In the organic EL device according to this exemplary embodiment, it is preferred that two or more of R₁₀₁ to R₁₁₀ be groups represented by formula (11) and Ar₁₀₁ be a substituted or unsubstituted aryl group having 6 to 50 ring carbon atoms.

In the organic EL device according to this exemplary embodiment, it is preferred that Ar₁₀₁ be not a substituted or unsubstituted pyrenyl group; L₁₀₁ be not a substituted or unsubstituted pyrenylene group; and any substituted or unsubstituted aryl group having 6 to 50 ring carbon atoms as any of R₁₀₁ to R₁₁₀ not being the group represented by formula (11) be not a substituted or unsubstituted pyrenyl group.

In the organic EL device according to this exemplary embodiment, it is preferred that R₁₀₁ to R₁₁₀ not being the group represented by formula (11) each independently represent: a hydrogen atom; a substituted or unsubstituted alkyl group having 1 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms.

In the organic EL device according to this exemplary embodiment, it is preferred that: R₁₀₁ to R₁₁₀ not being the group represented by formula (11) each independently represent: a hydrogen atom; a substituted or unsubstituted alkyl group having 1 to 50 carbon atoms; or a substituted or unsubstituted cycloalkyl group having 3 to 50 ring carbon atoms.

In the organic EL device according to this exemplary embodiment, it is preferred that R₁₀₁ to R₁₁₀ not being the group represented by formula (11) be hydrogen atoms.

In the organic EL device according to this exemplary embodiment, it is preferred that X₁ be CR₁₂₃R₁₂₄. For example, if X₁ is CR₁₂₃R₁₂₄, the group represented by formula (111) is represented by formula (111d) below.

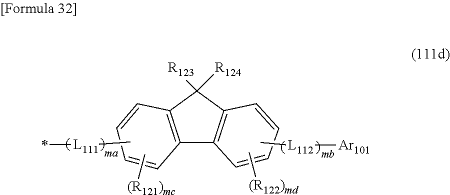

In formula (111d), L₁₁₁, L₁₁₂, ma, mb, ma+mb, Ar₁₀₁, R₁₂₁, R₁₂₂, R₁₂₃, R₁₂₄, R₁₂₅, mc, and md are each as defined in formula (111).

In the organic EL device according to this exemplary embodiment, it is preferred that R₁₂₃ and R₁₂₄ be not bonded together.

In the organic EL device according to this exemplary embodiment, it is preferred that at least one of L₁₁₁ or L₁₁₂ is: a substituted or unsubstituted arylene group having 6 to 50 ring carbon atoms; or a substituted or unsubstituted divalent heterocyclic group having 5 to 50 ring atoms.

In the first compound, examples of the substituent for “substituted or unsubstituted” group does not include a substituted or unsubstituted pyrenyl group.

In an exemplary embodiment, the first compound is a compound having only one pyrene ring in its molecule (also referred to as a monopyrene compound).

In an exemplary embodiment, the first compound is a compound having only two pyrene rings in its molecule (also referred to as a bispyrene compound).

In the first compound, it is preferred that all groups described as “substituted or unsubstituted” be “unsubstituted” groups.

Preferably, the first hole transporting layer contains no compound having an amino group.

Preferably, the first hole transporting layer contains no compound containing nitrogen and boron atoms.

In the organic EL device according to this exemplary embodiment, it is preferred that the content ratio of the first compound in the first hole transporting layer be 90% by mass or more, more preferably 99% by mass or more.

In the organic EL device according to this exemplary embodiment, it is even more preferred that the first hole transporting layer consists of the first compound.

In the organic EL device according to this exemplary embodiment, it is preferred that the first hole transporting layer does not emit light with a maximum peak wavelength in a range from 430 nm to 480 nm when the device is driven.

### Production Method of First Compound

The first compound can be produced by methods known in the related art. Alternatively, the first compound can be produced based on a method known in the related art by selecting known alternative reaction(s) and materials according to the final product.

### Specific Examples of First Compounds

Specific examples of first compounds include, for instance, the following compounds, although the invention is not limited to these specific examples of first compounds.

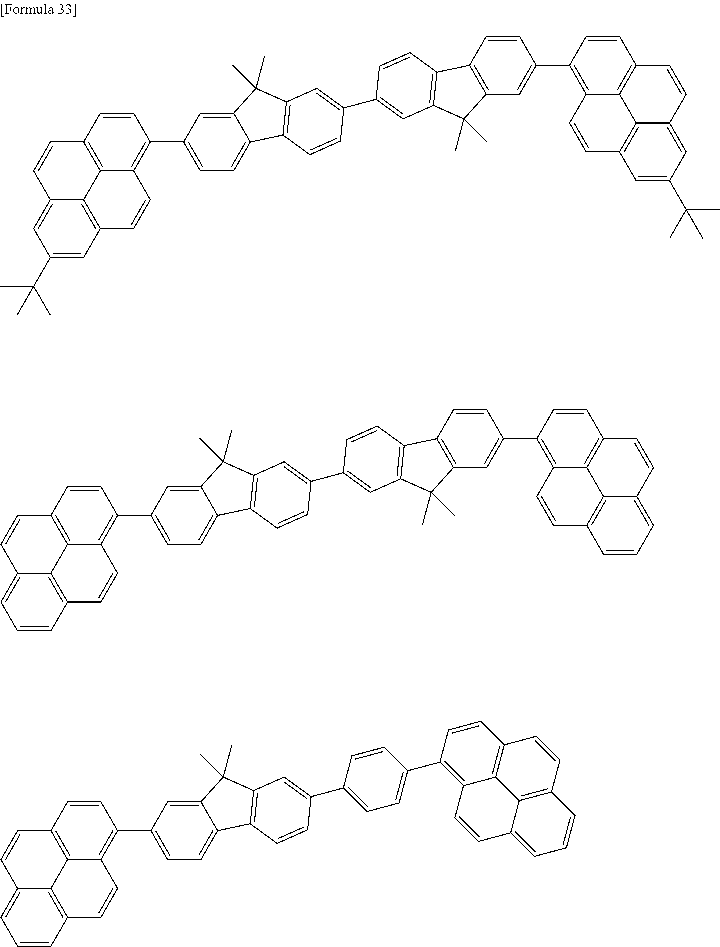

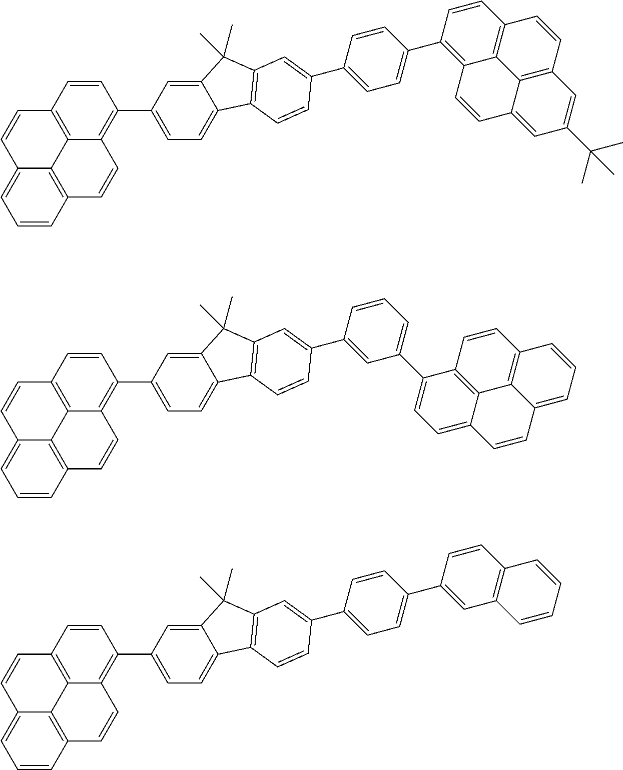

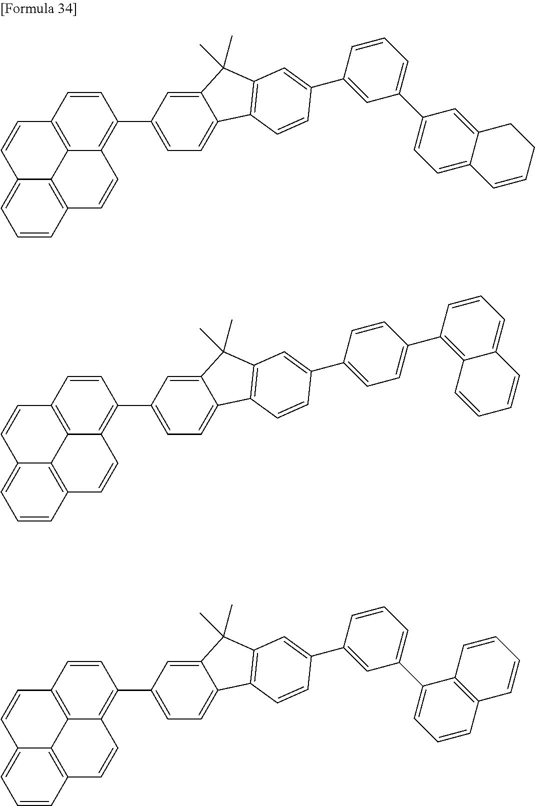

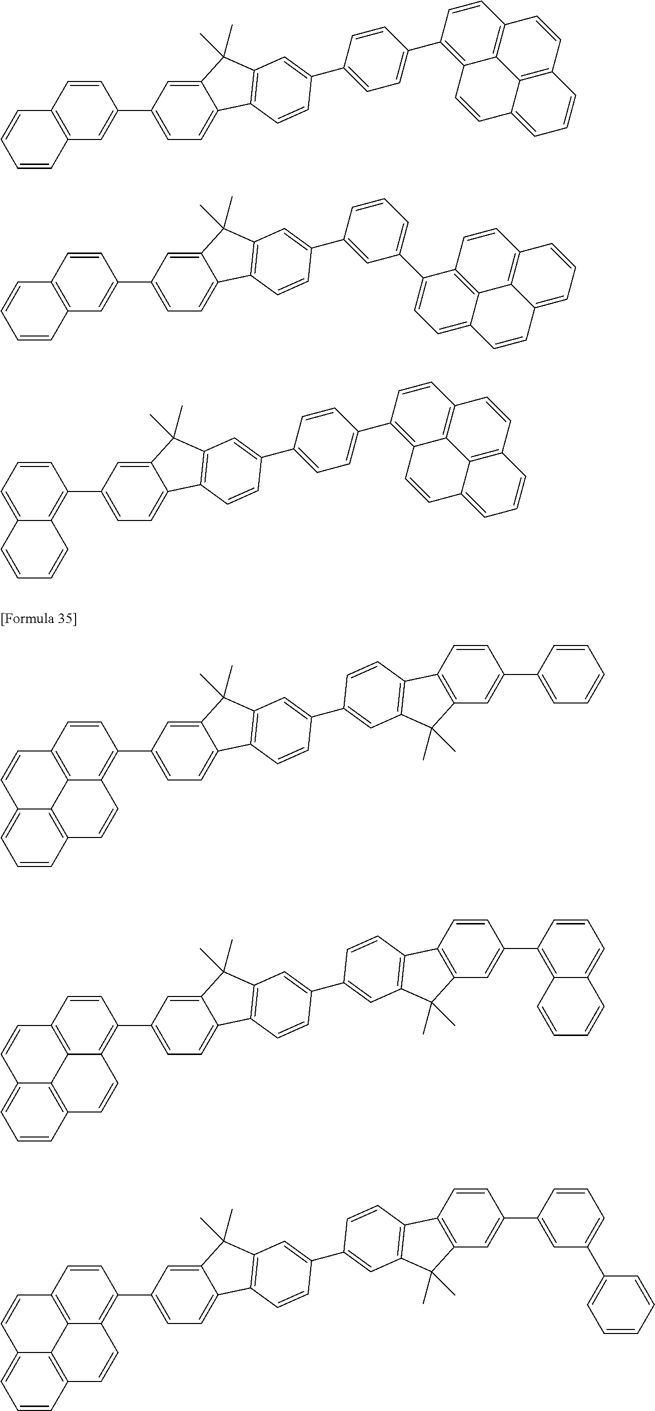

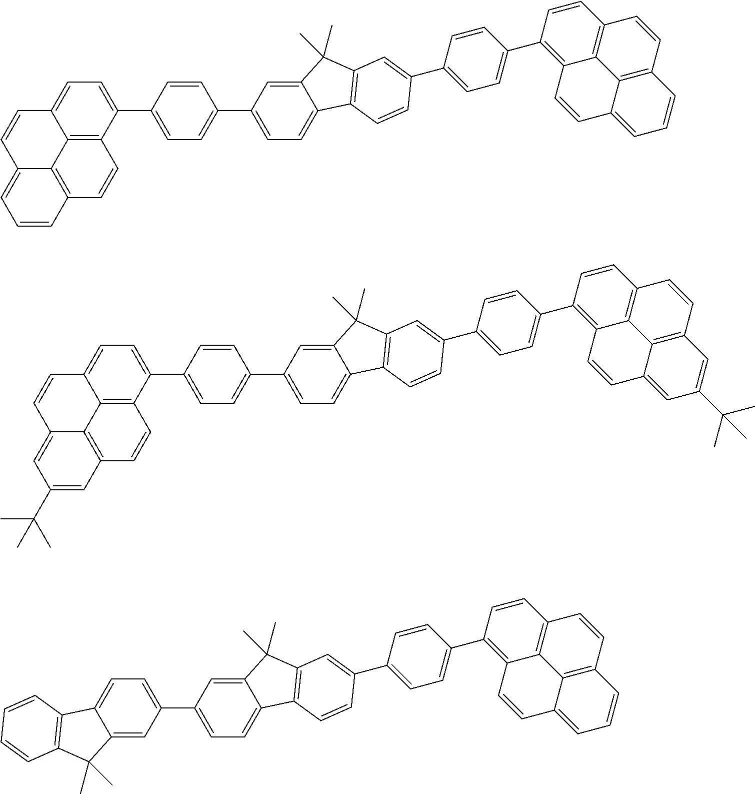

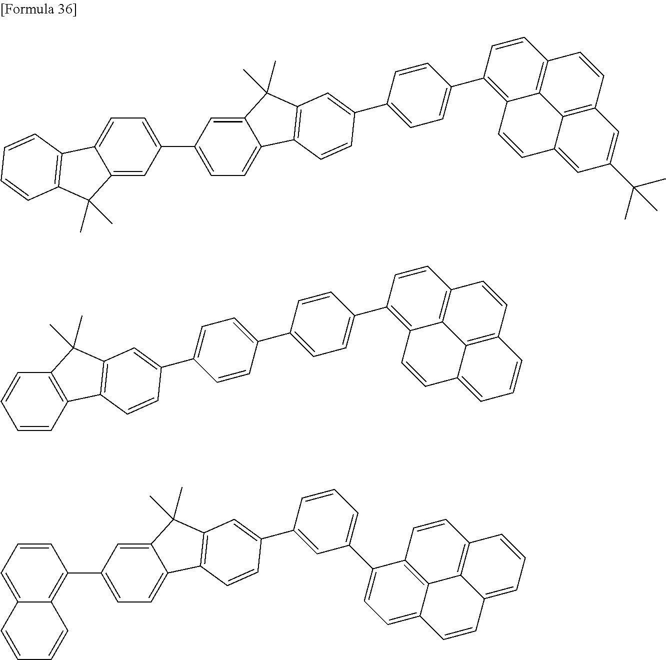

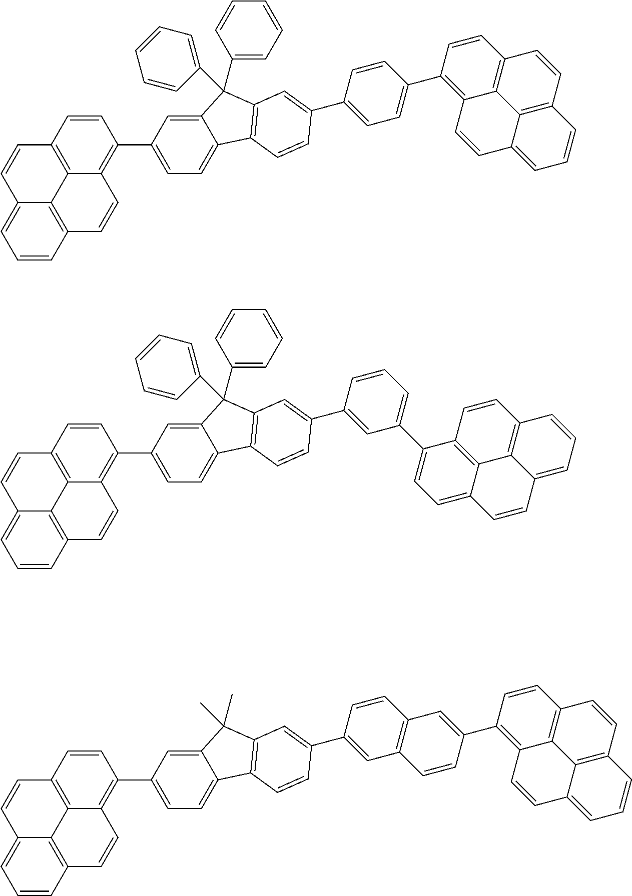

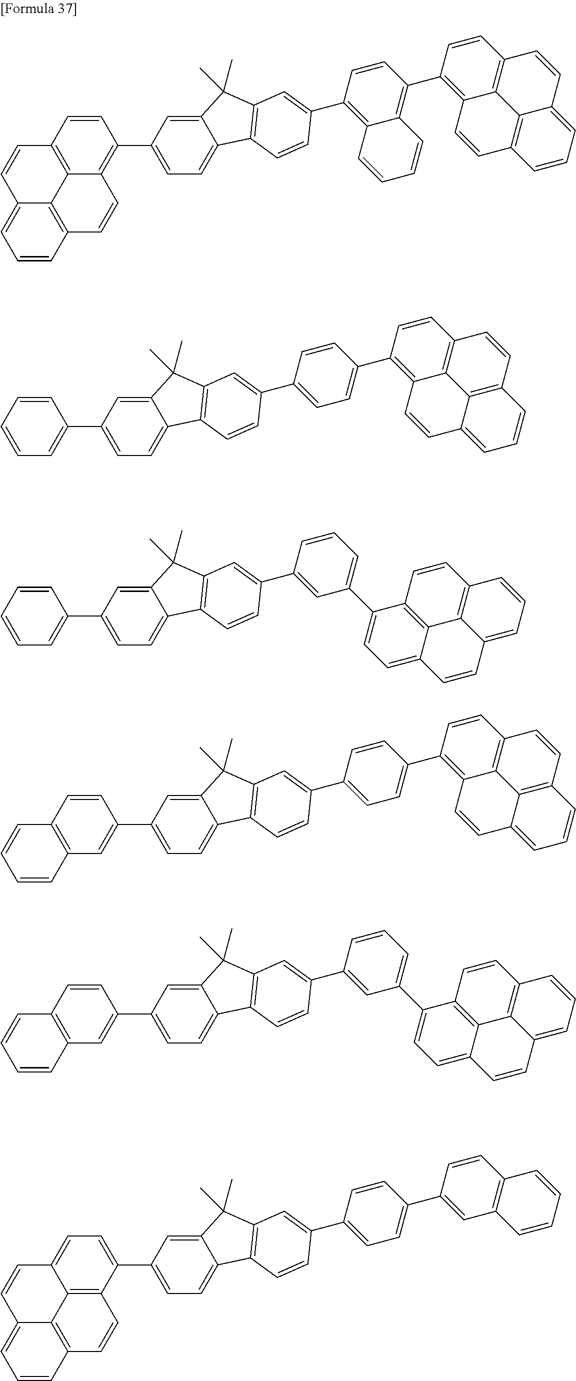

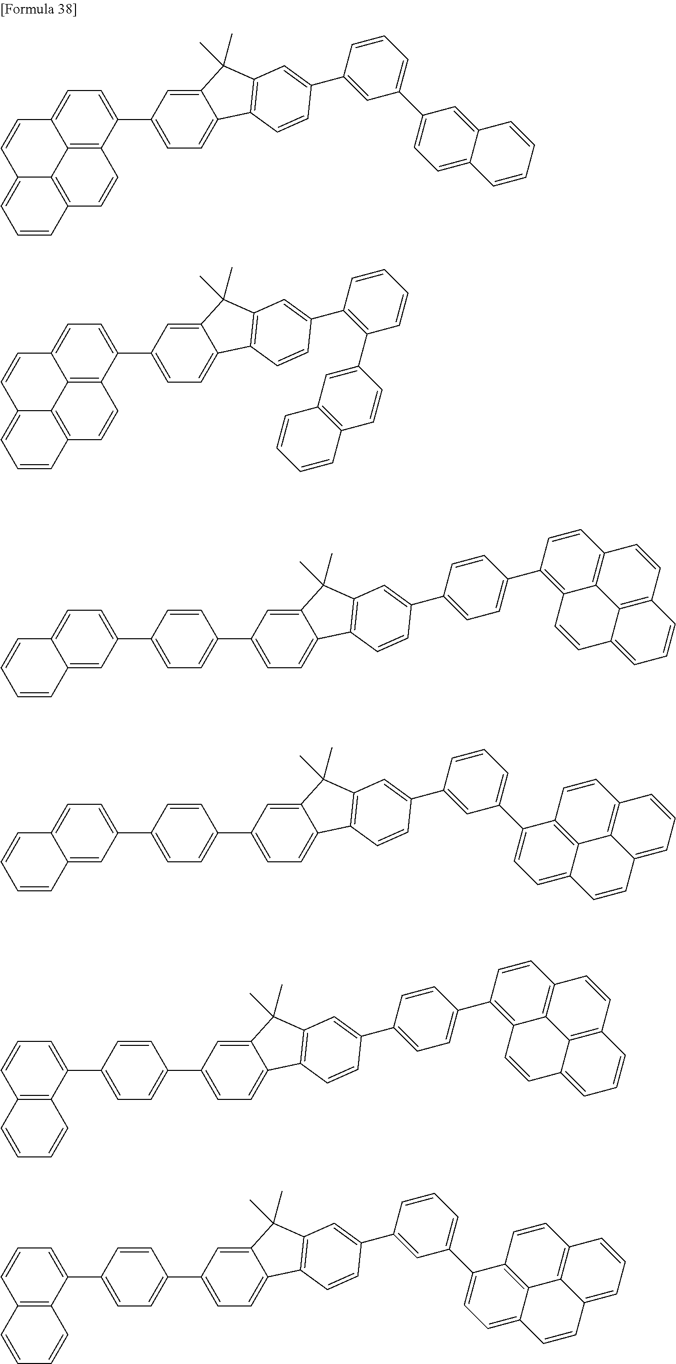

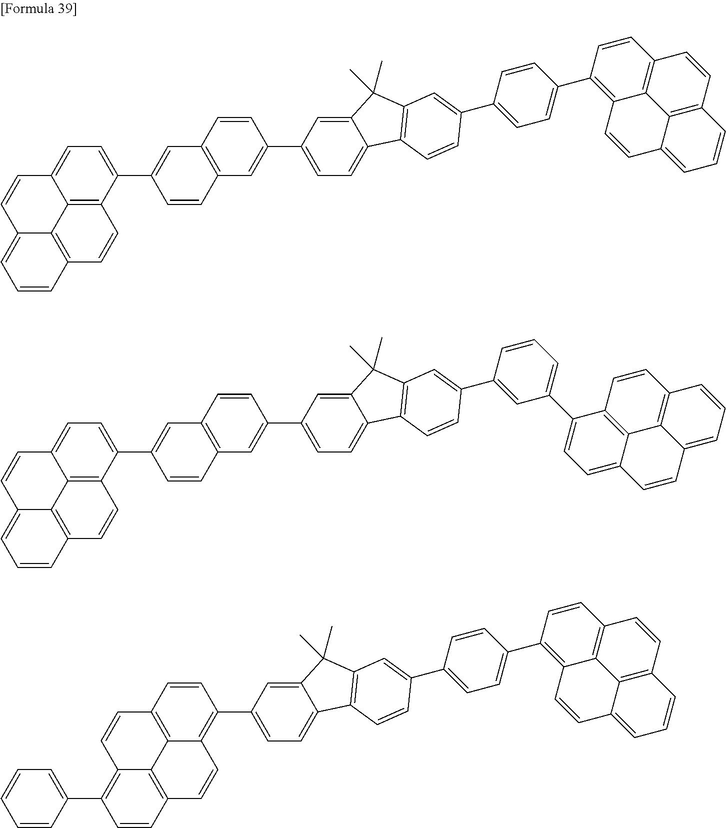

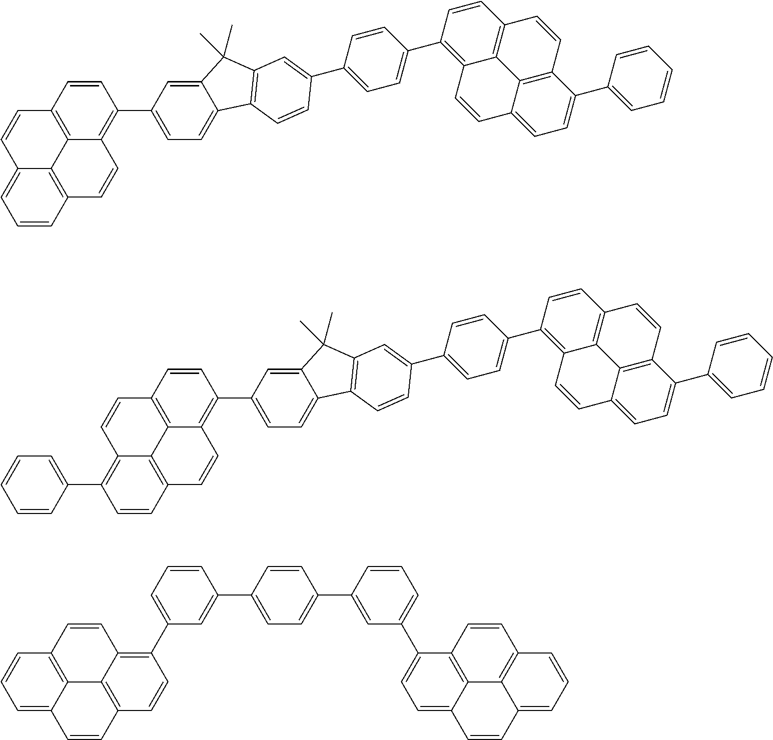

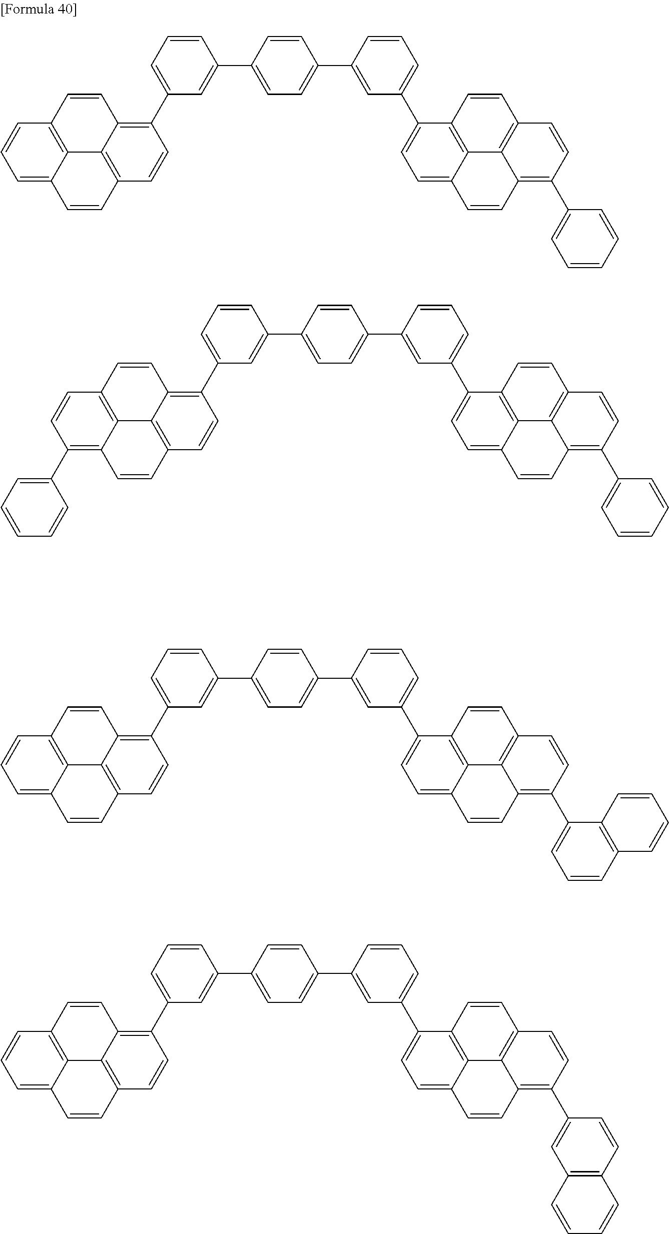

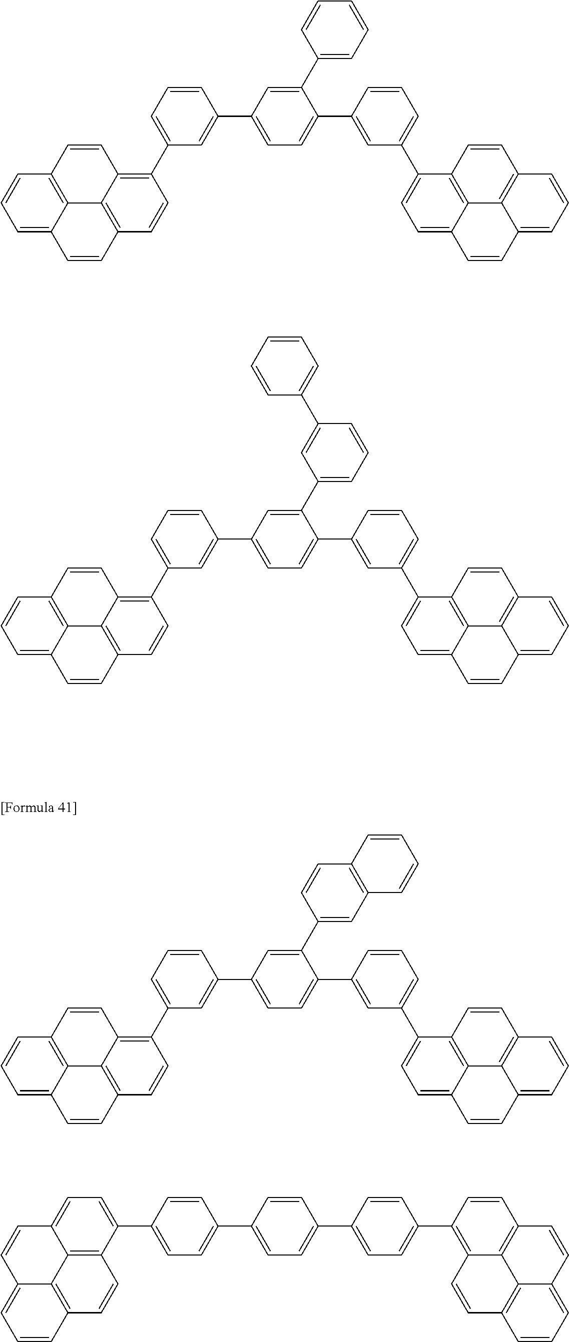

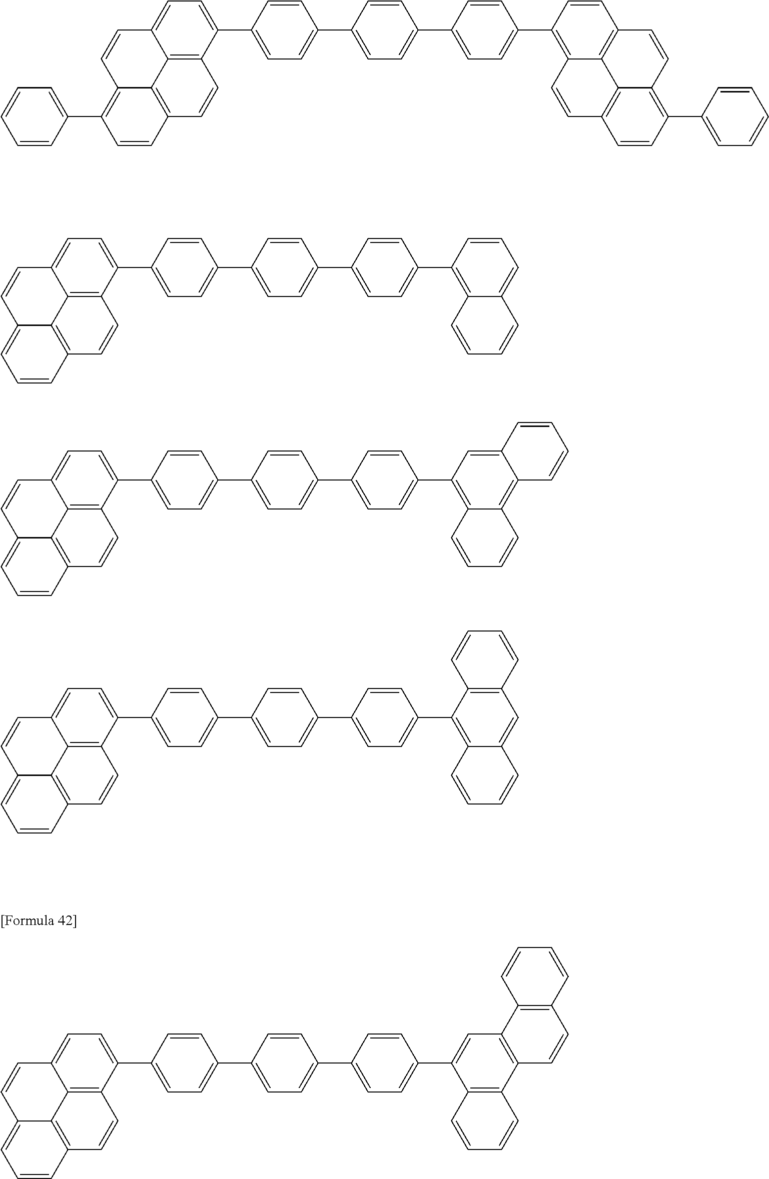

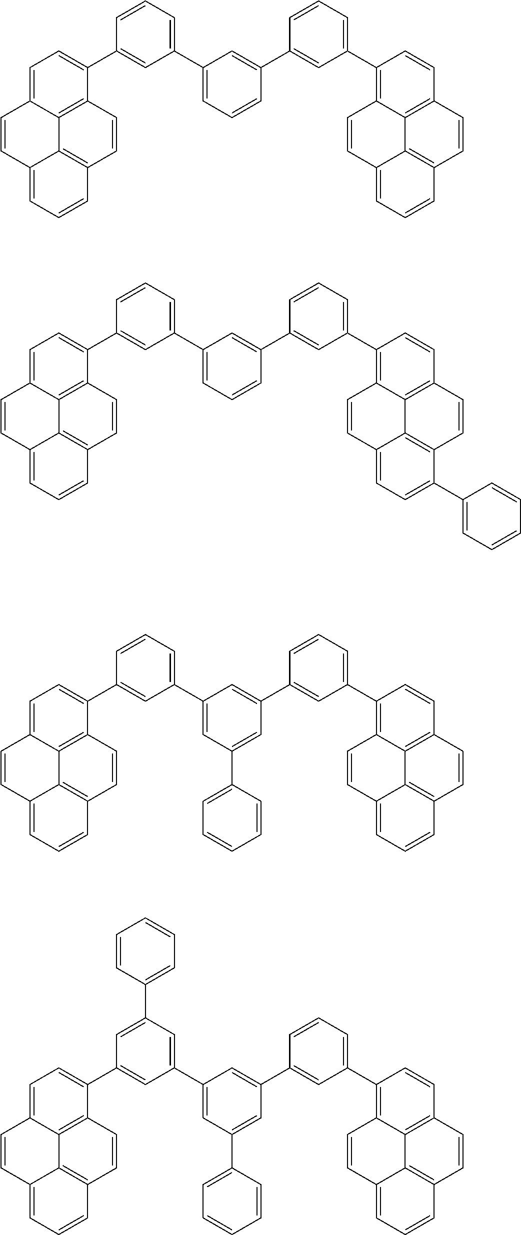

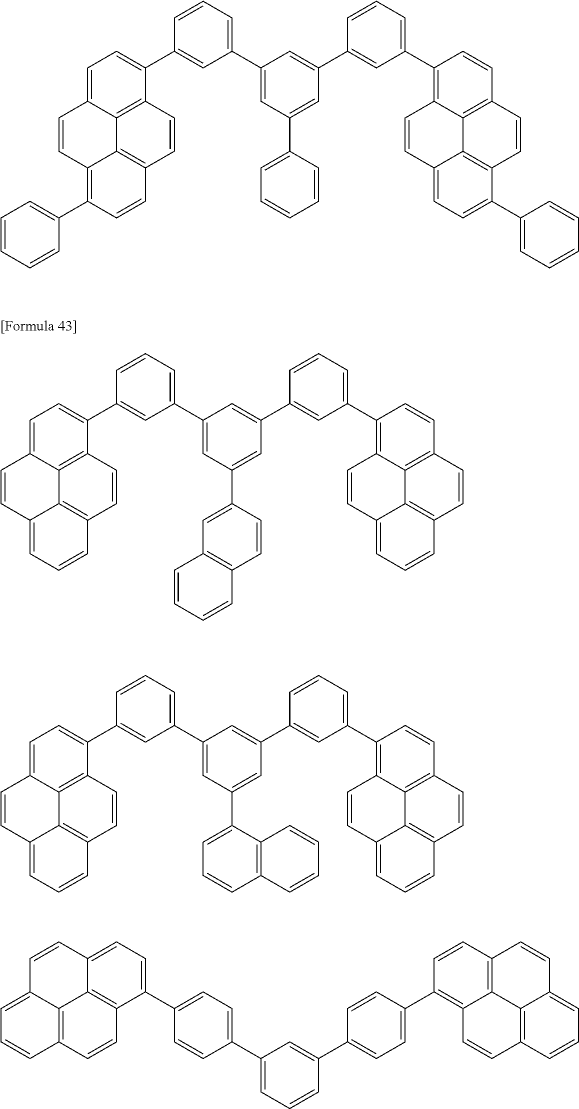

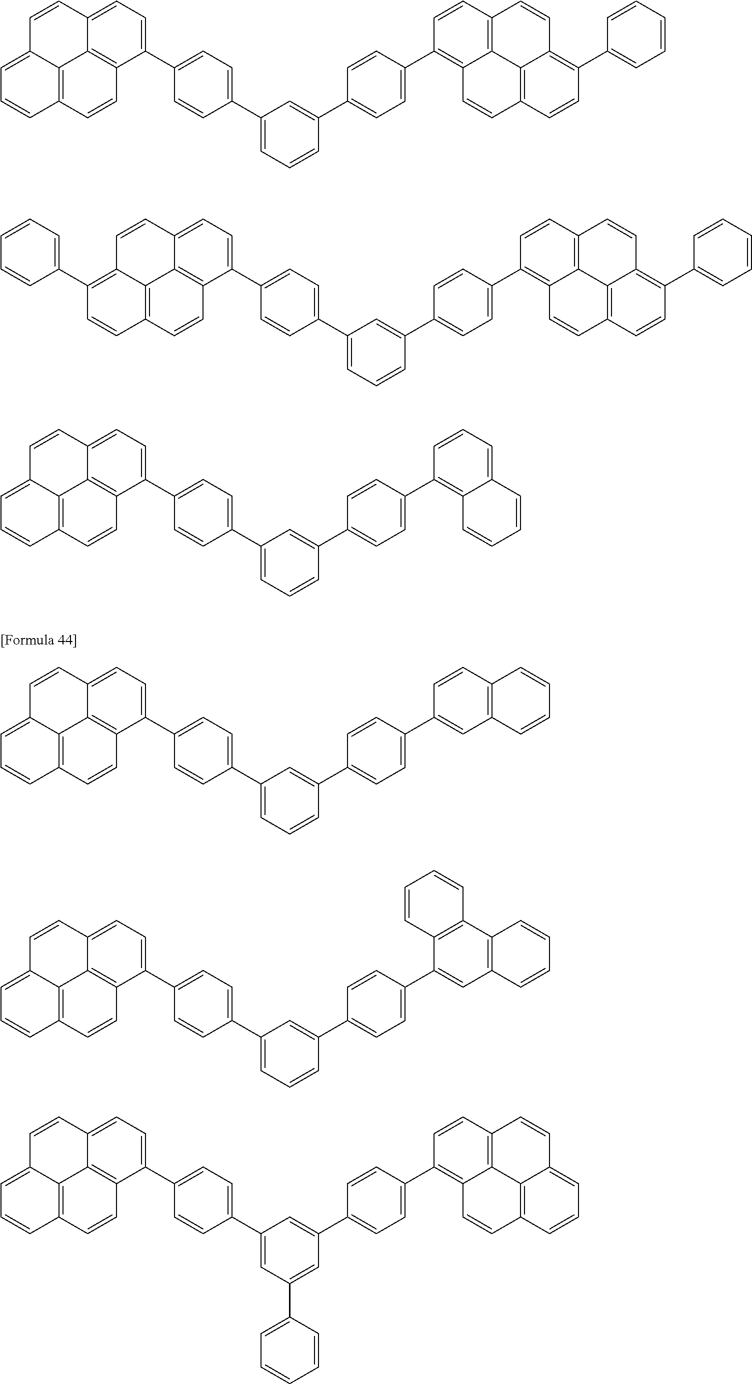

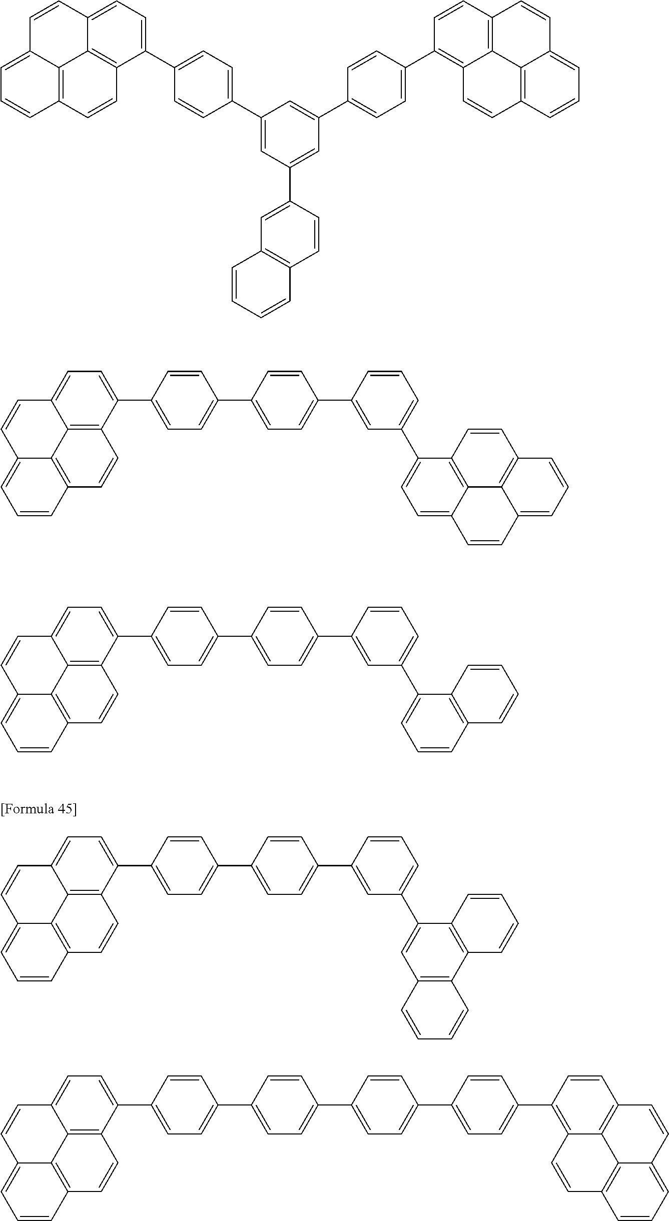

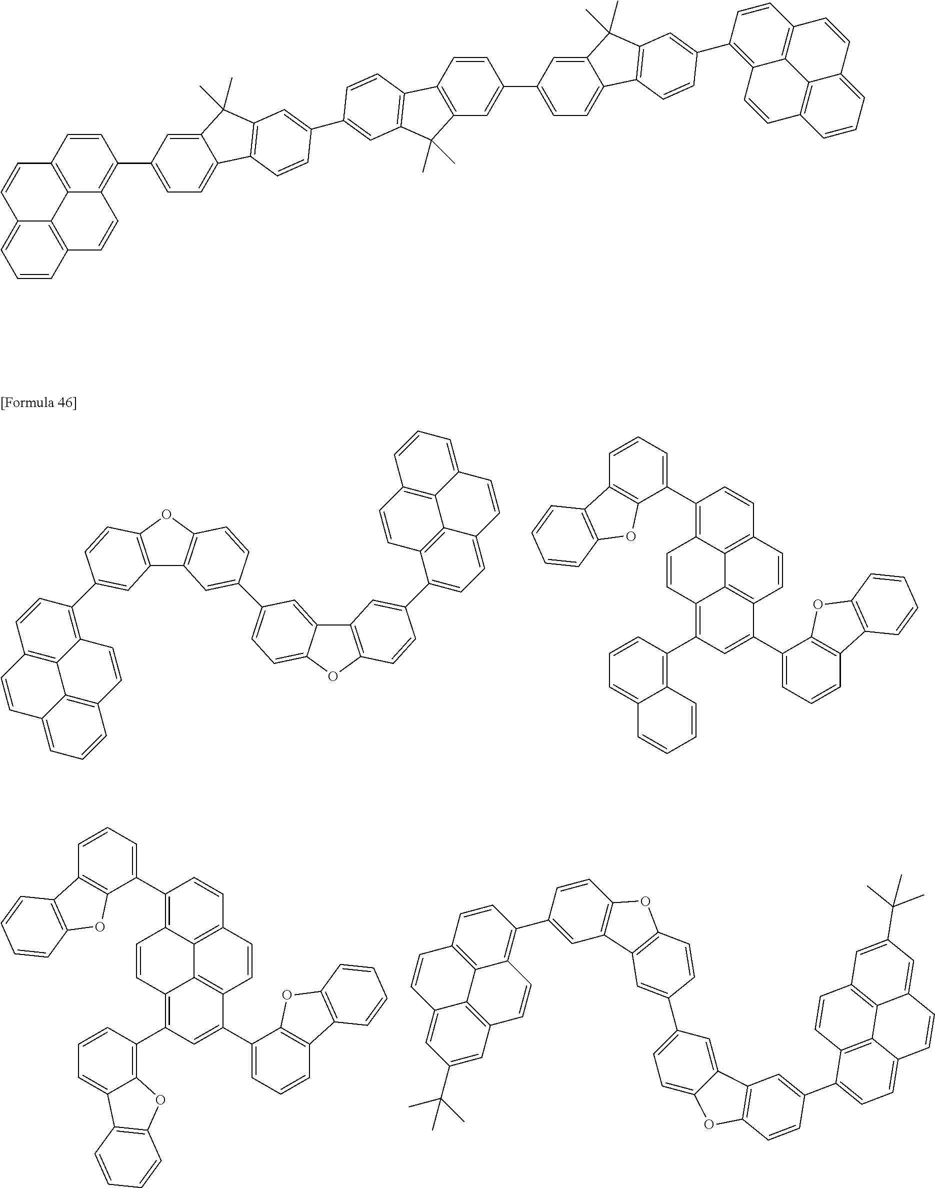

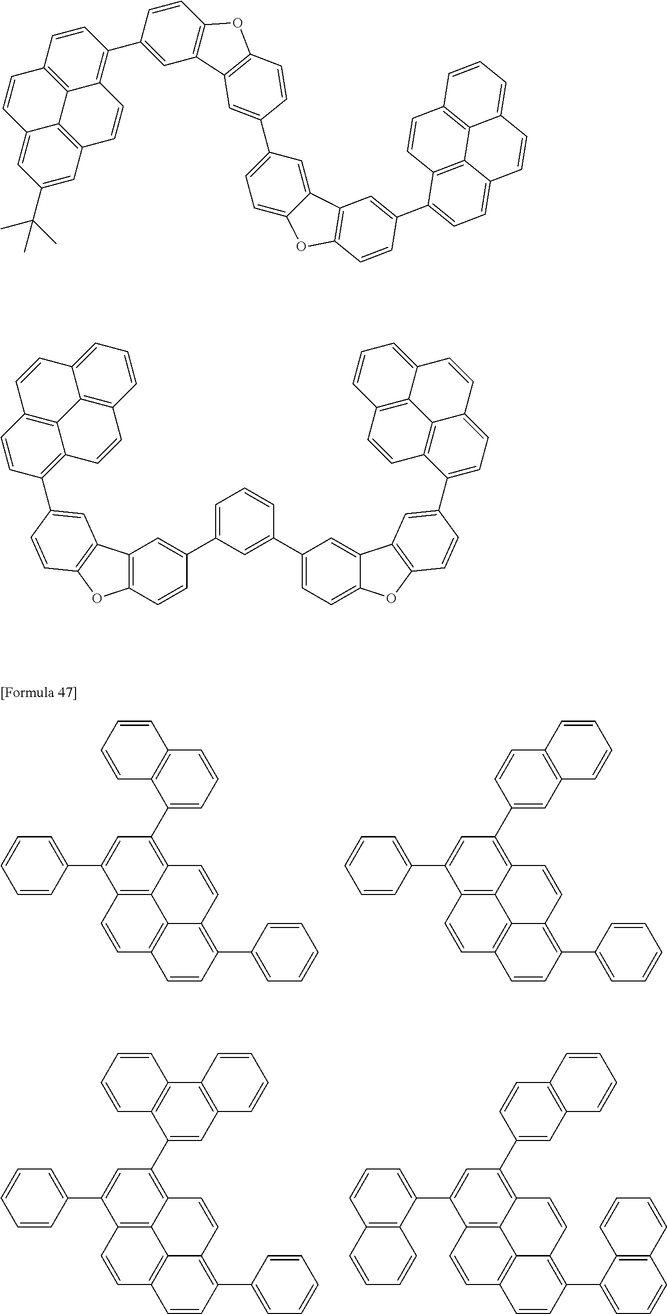

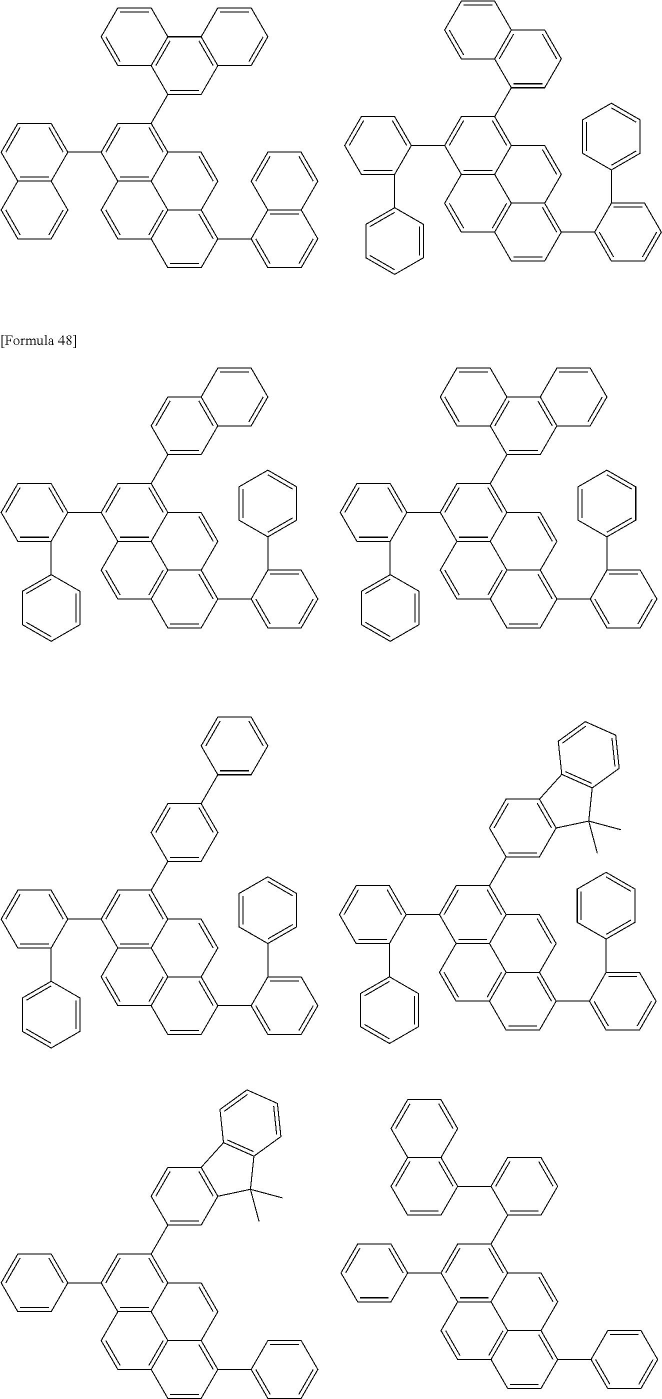

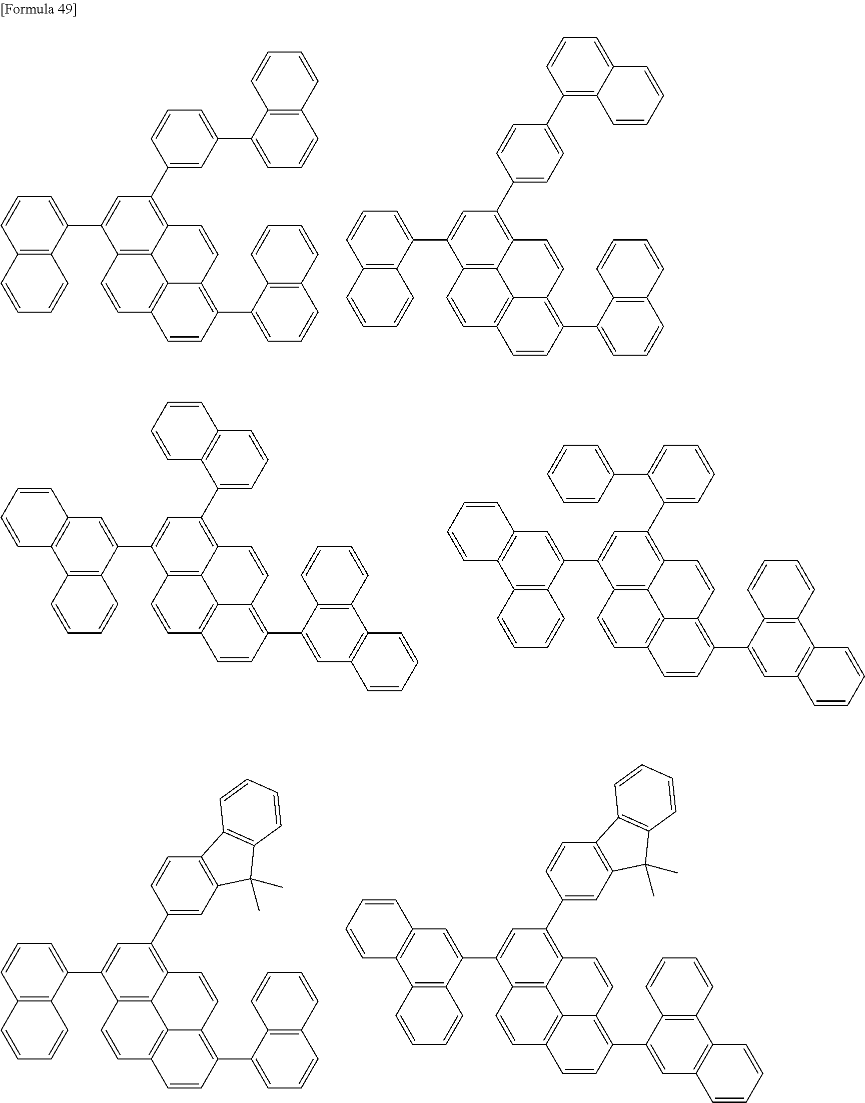

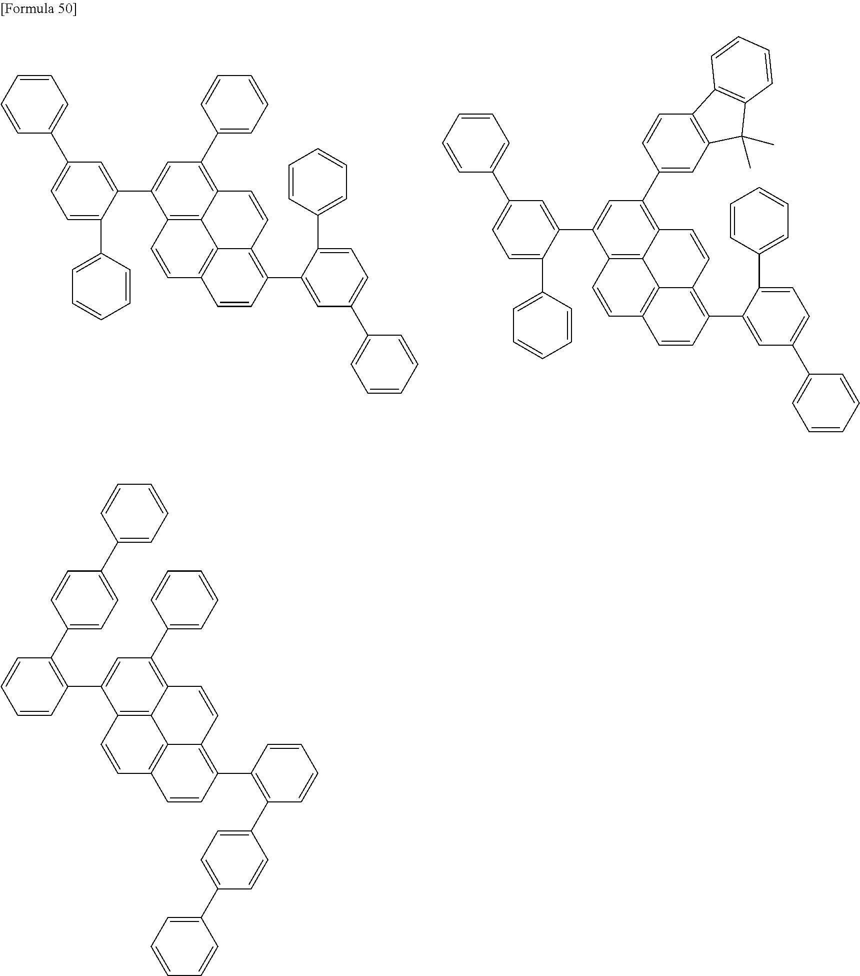

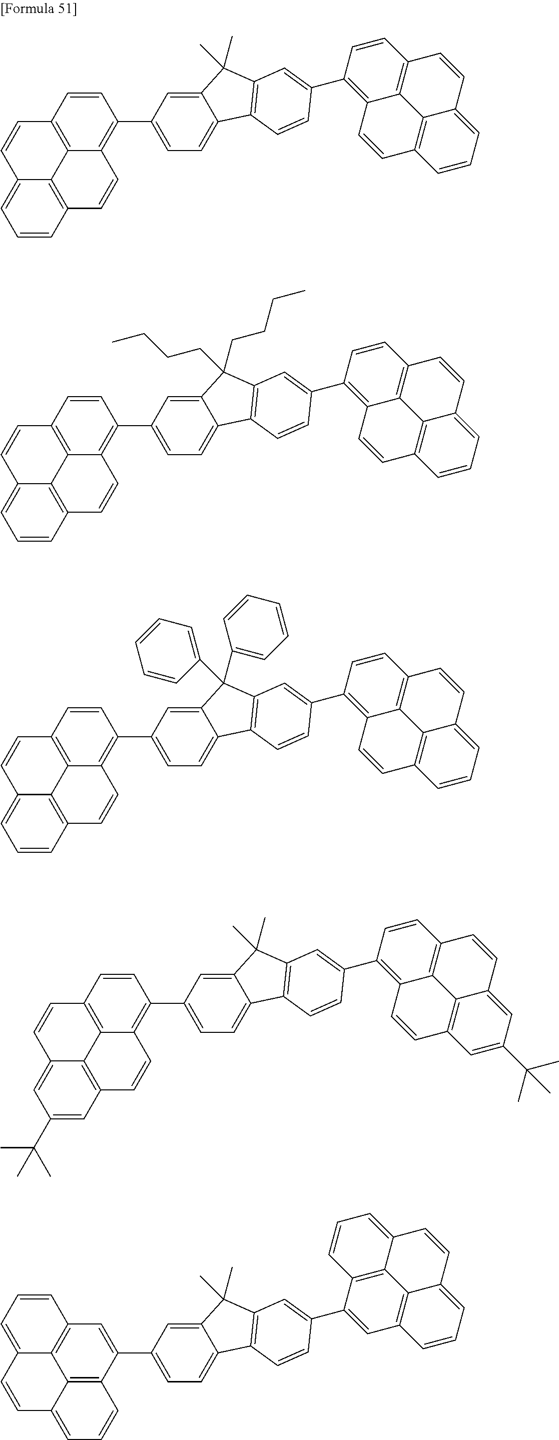

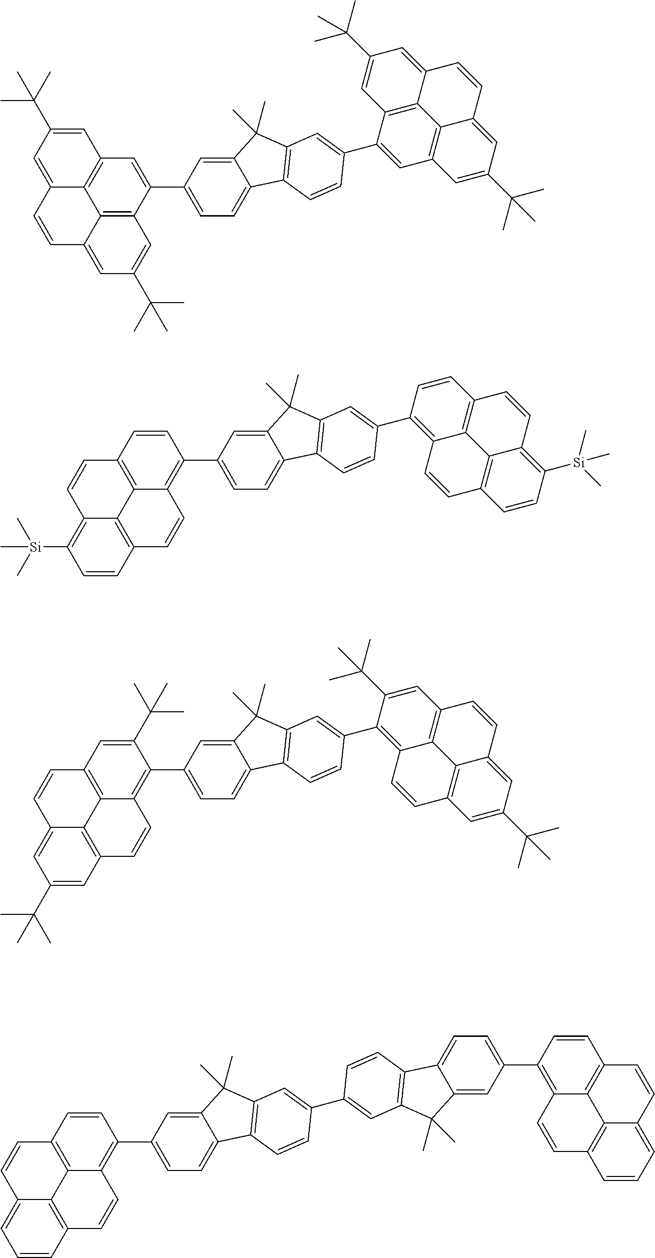

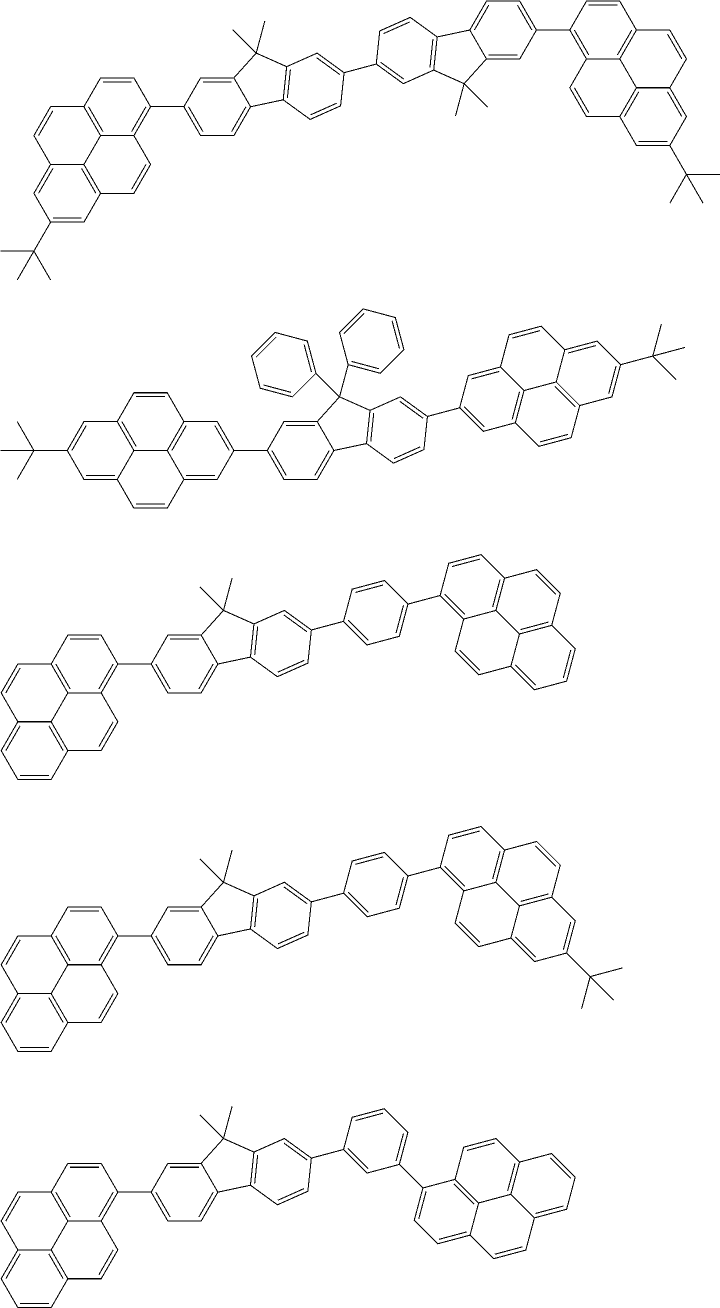

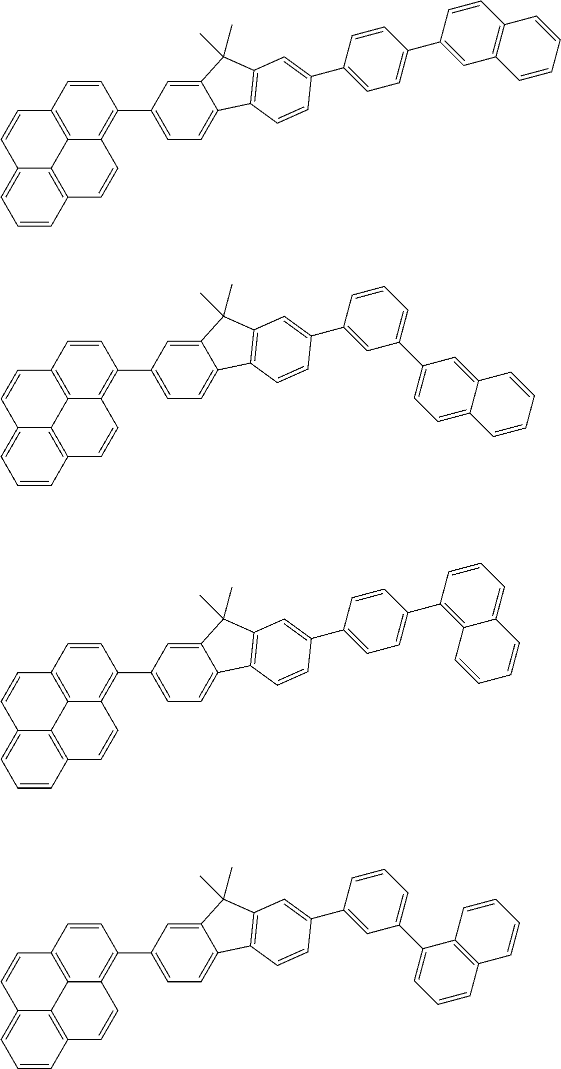

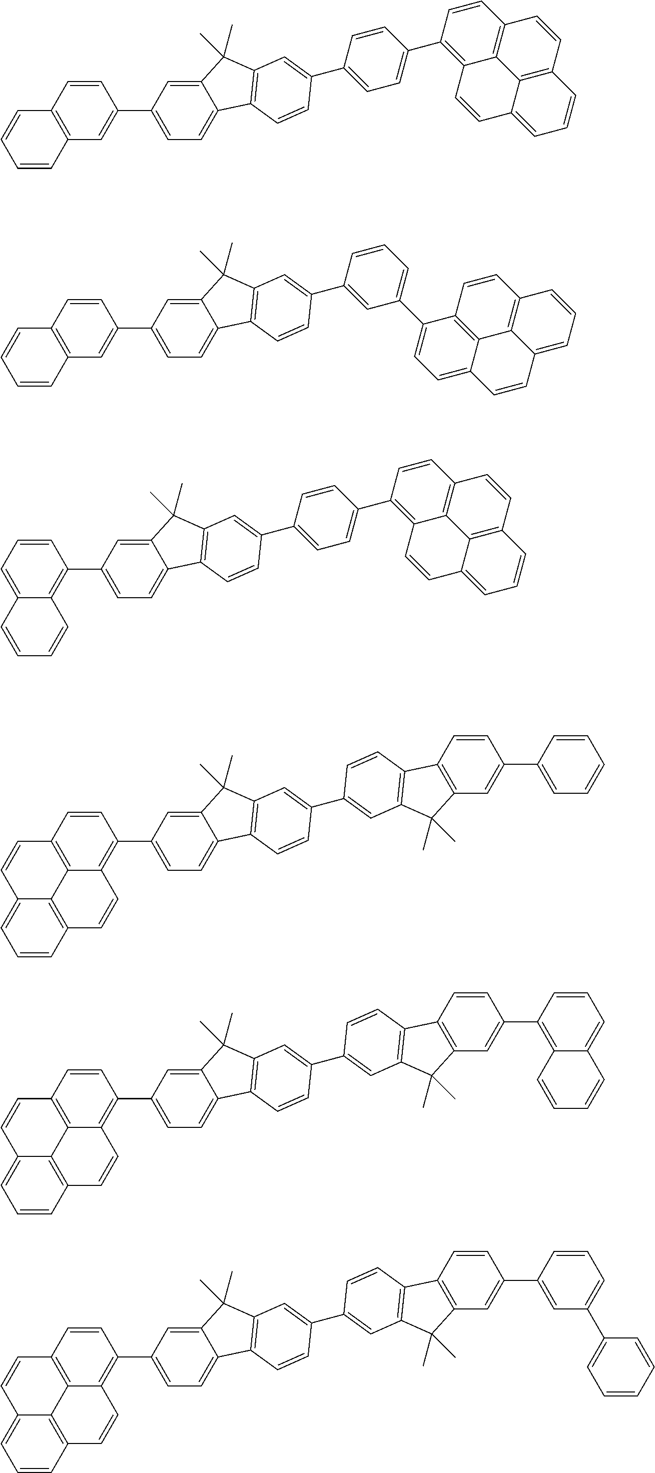

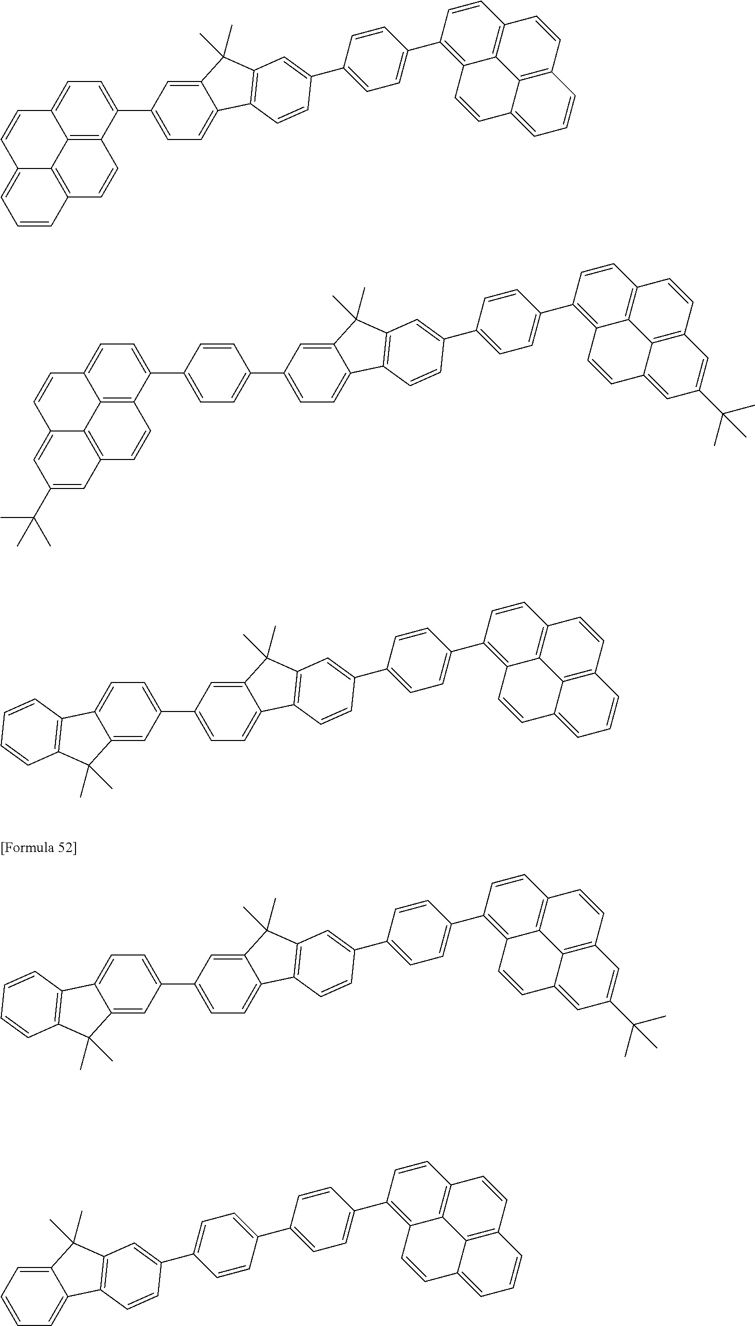

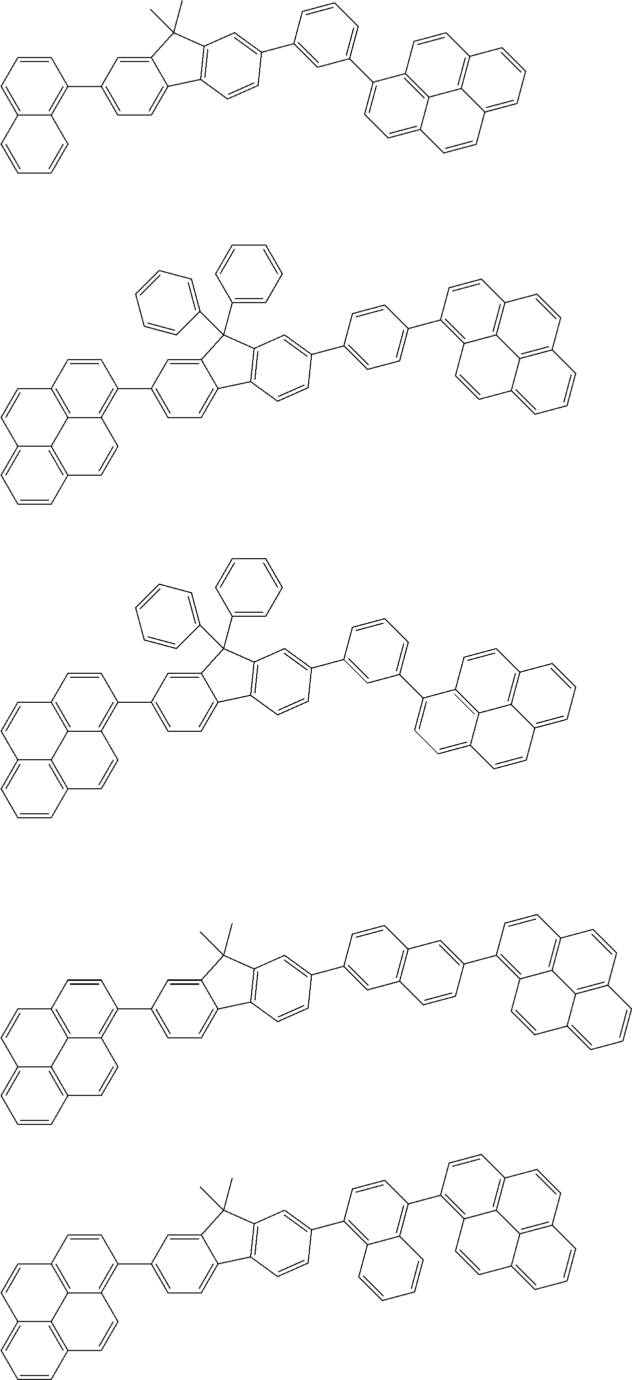

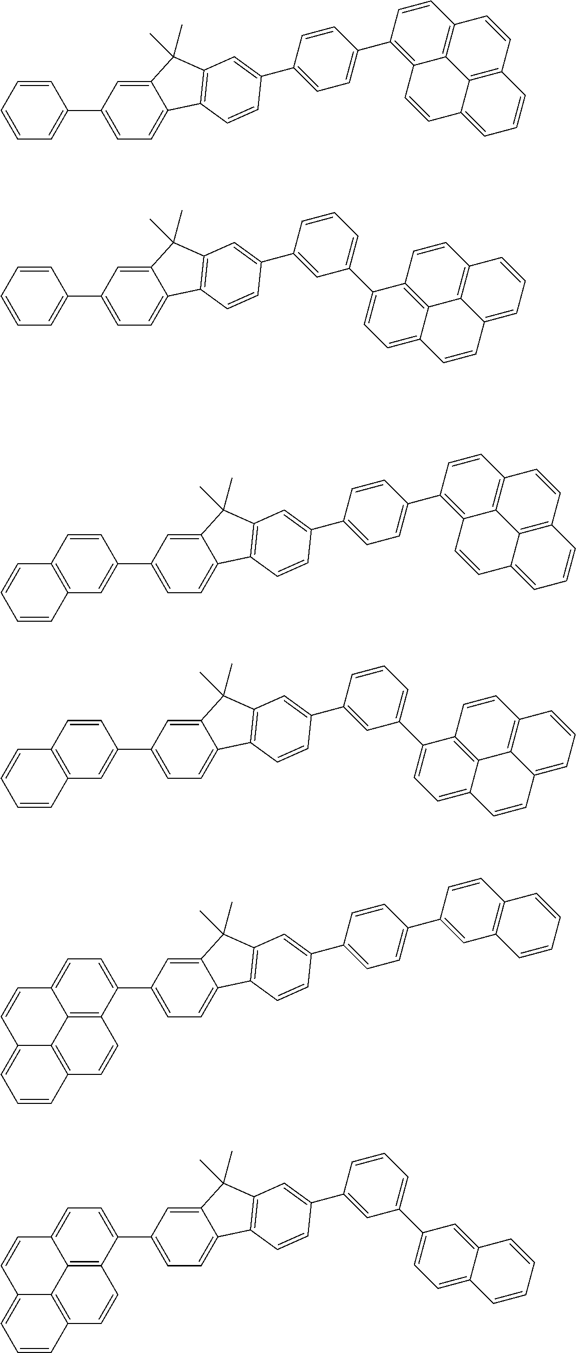

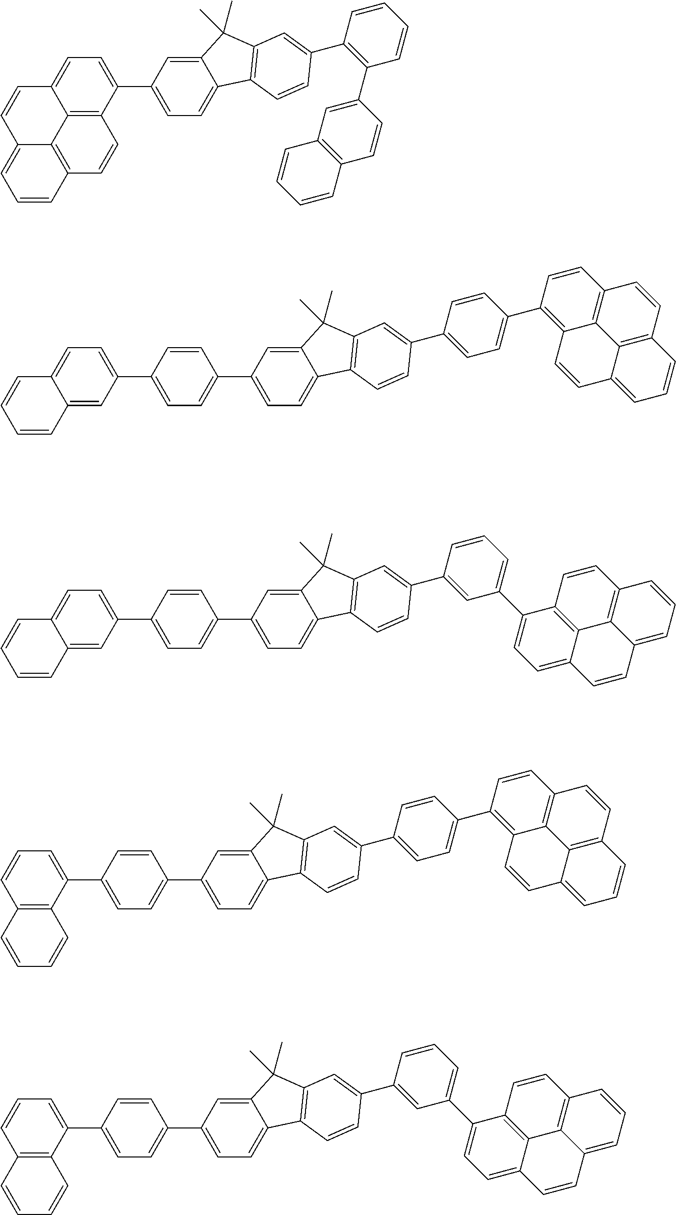

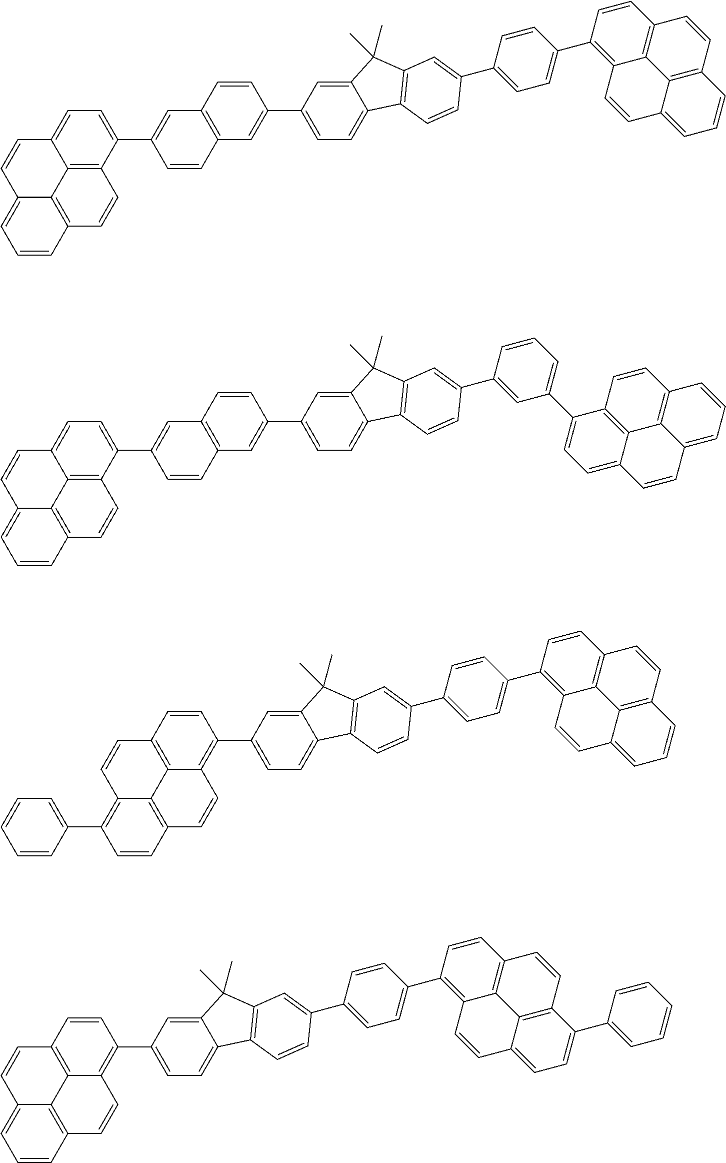

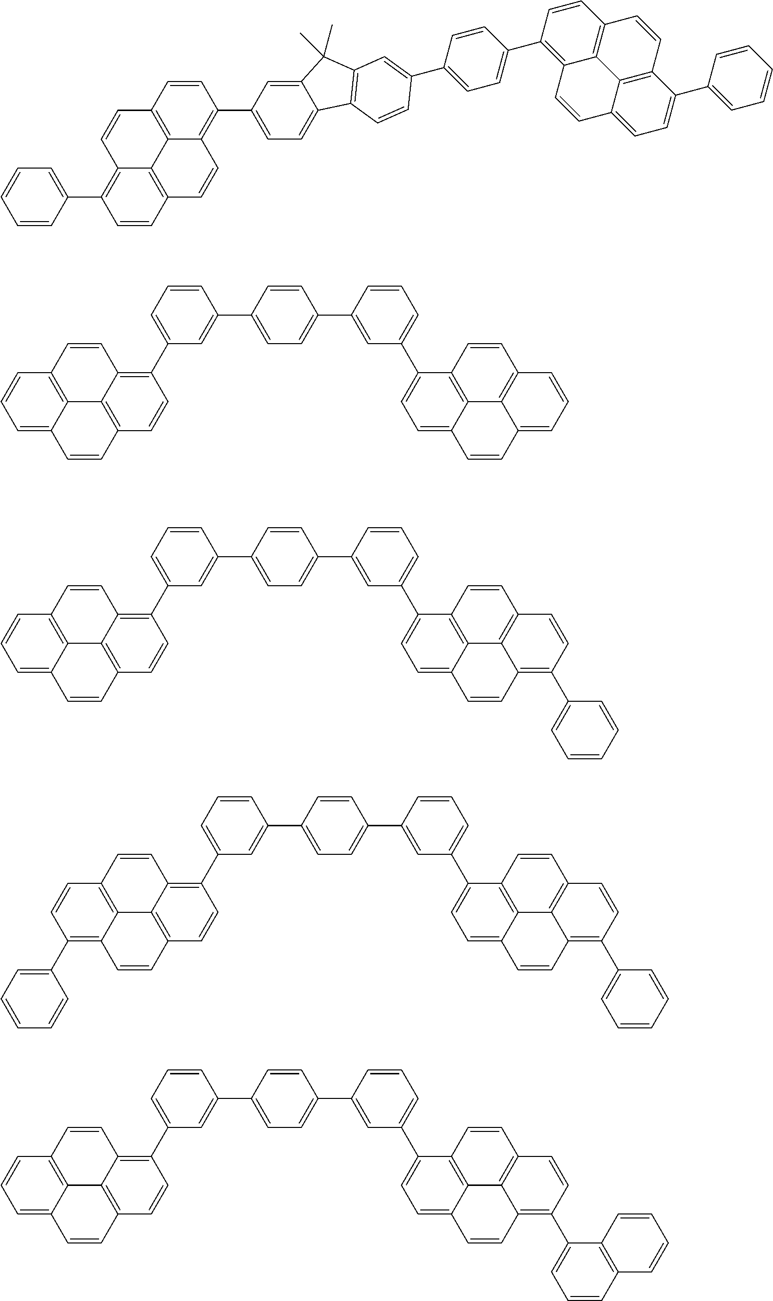

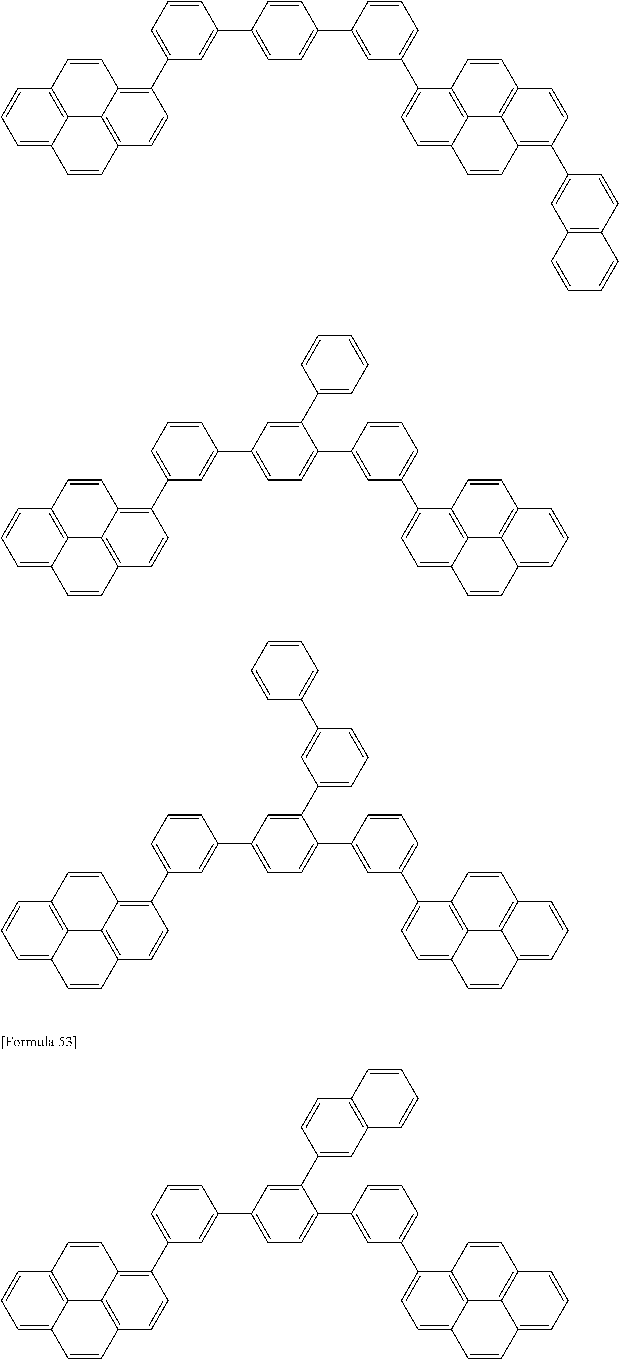

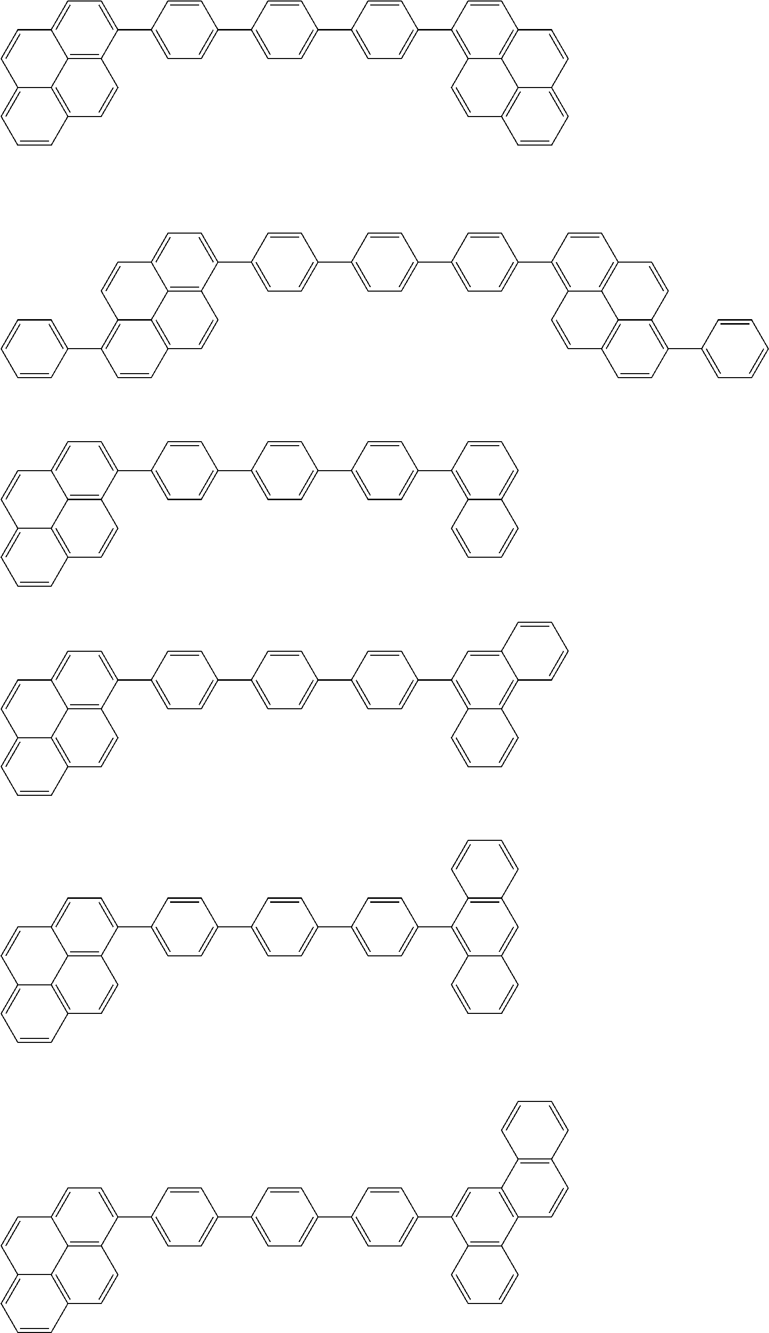

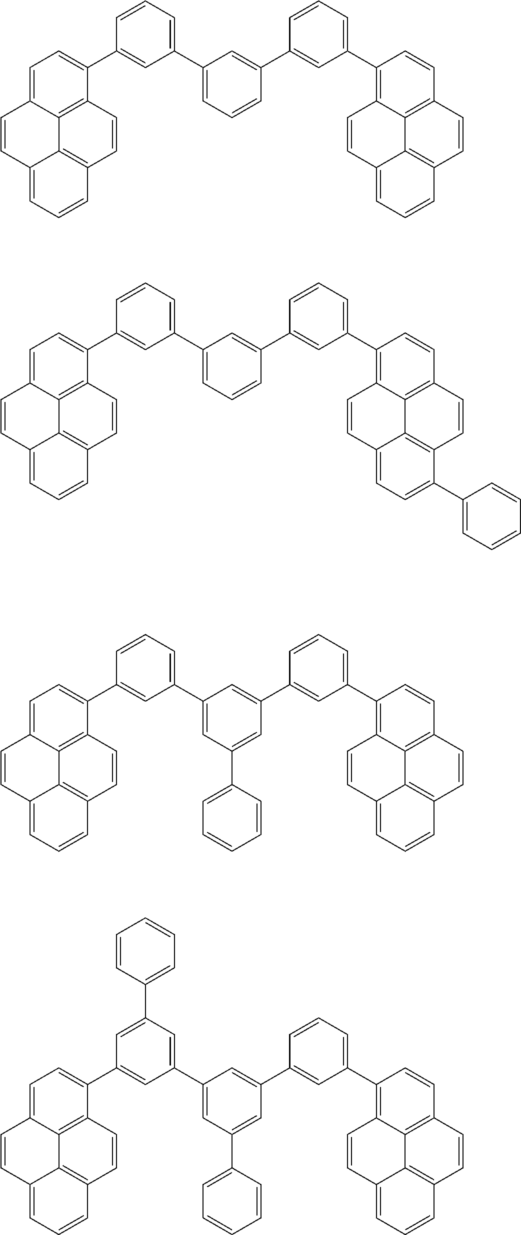

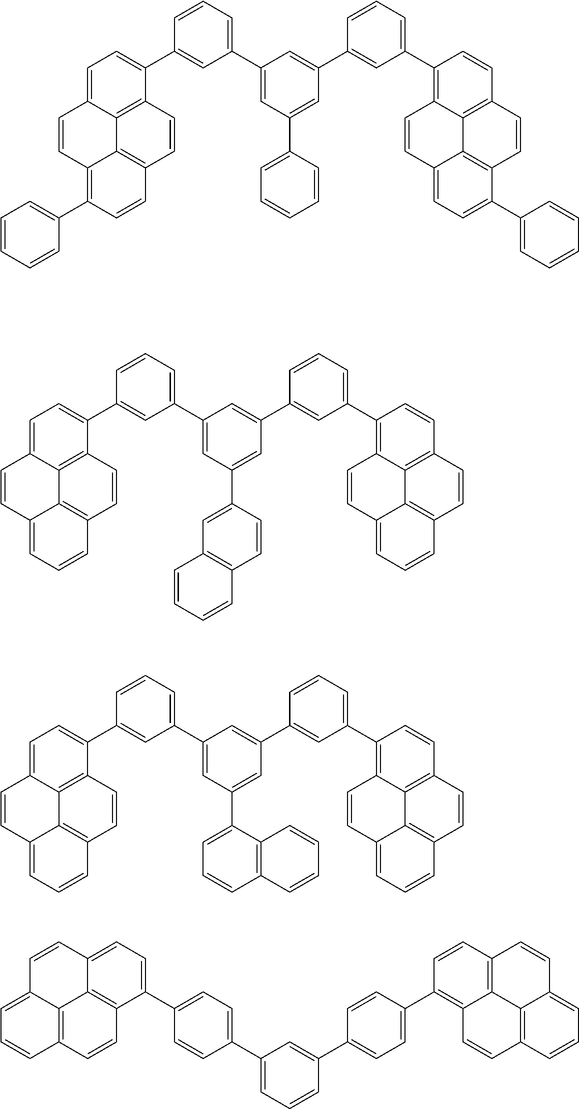

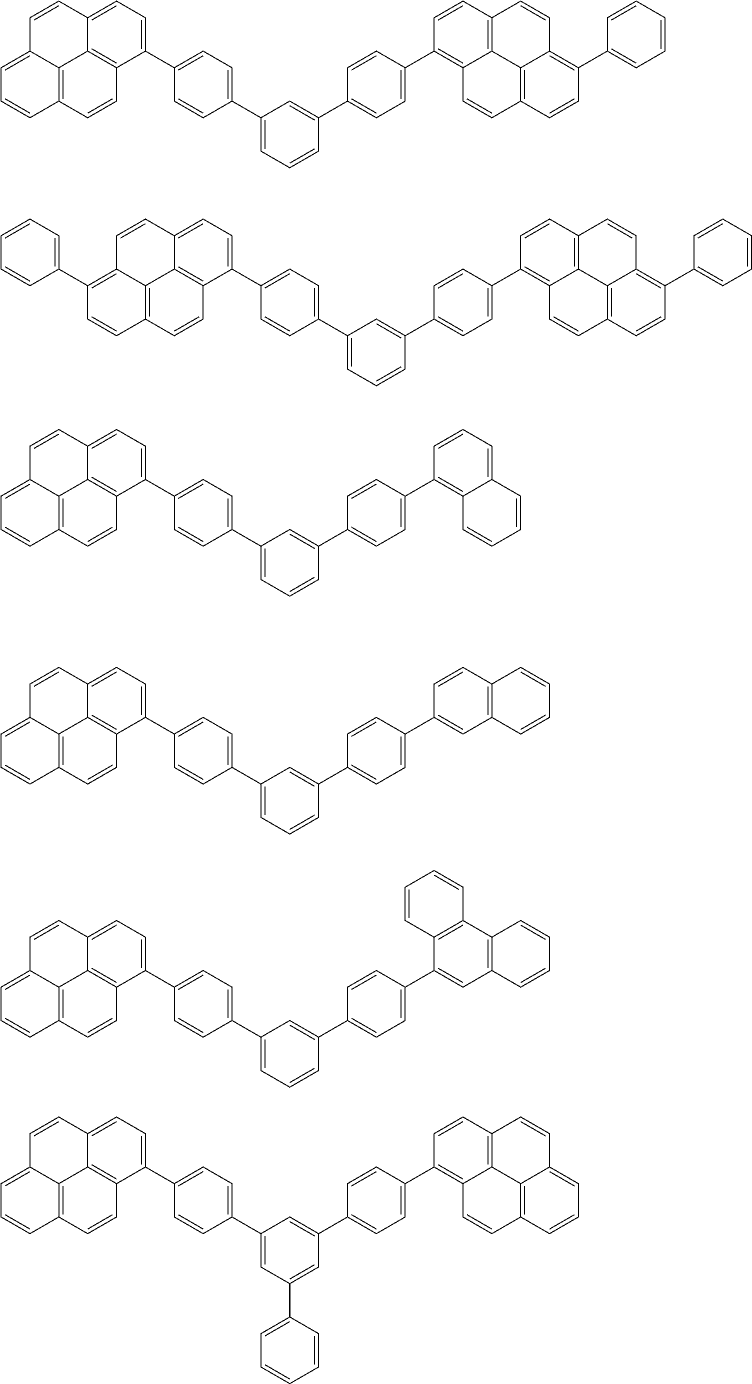

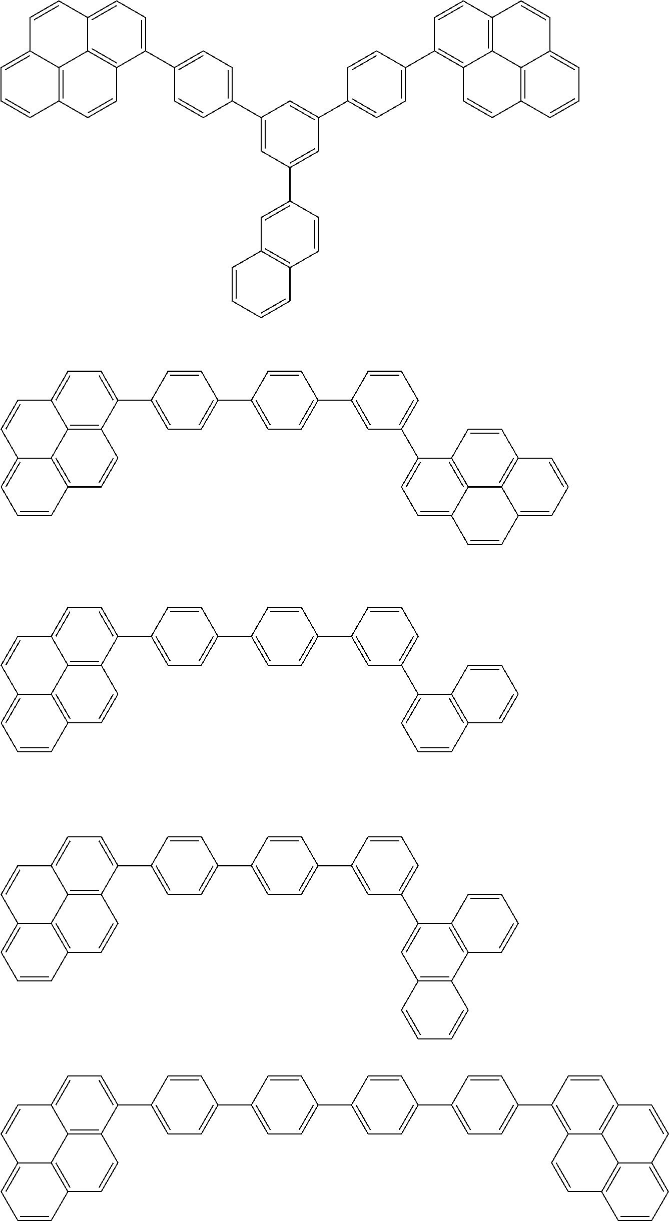

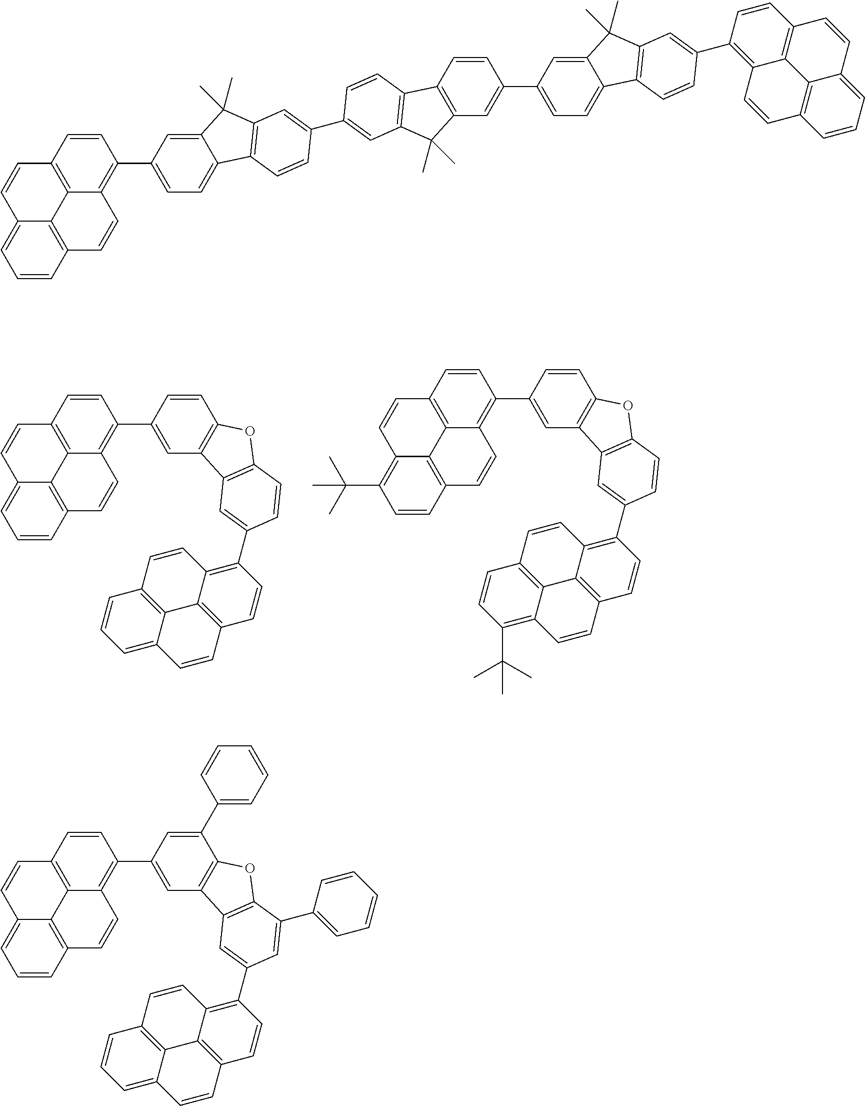

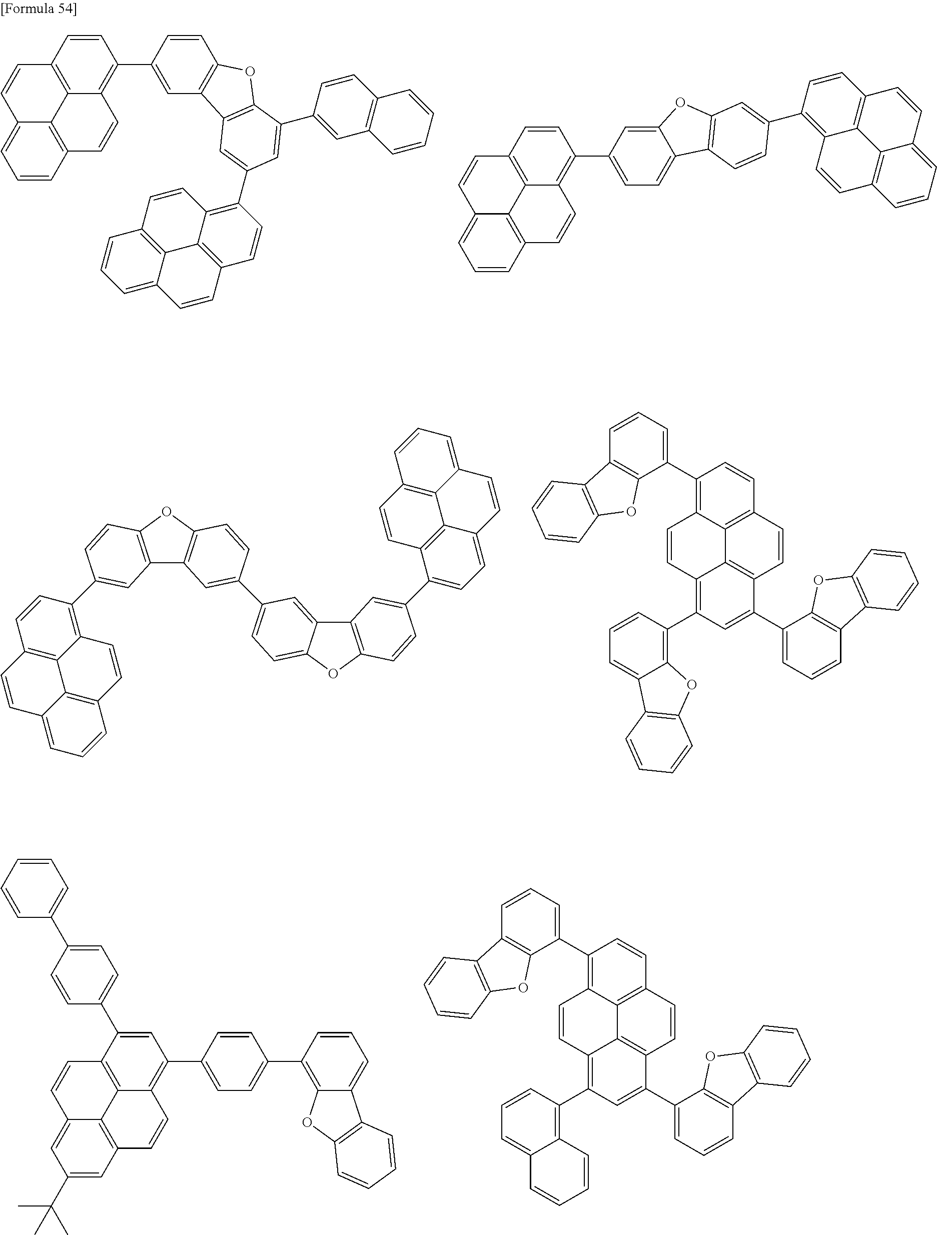

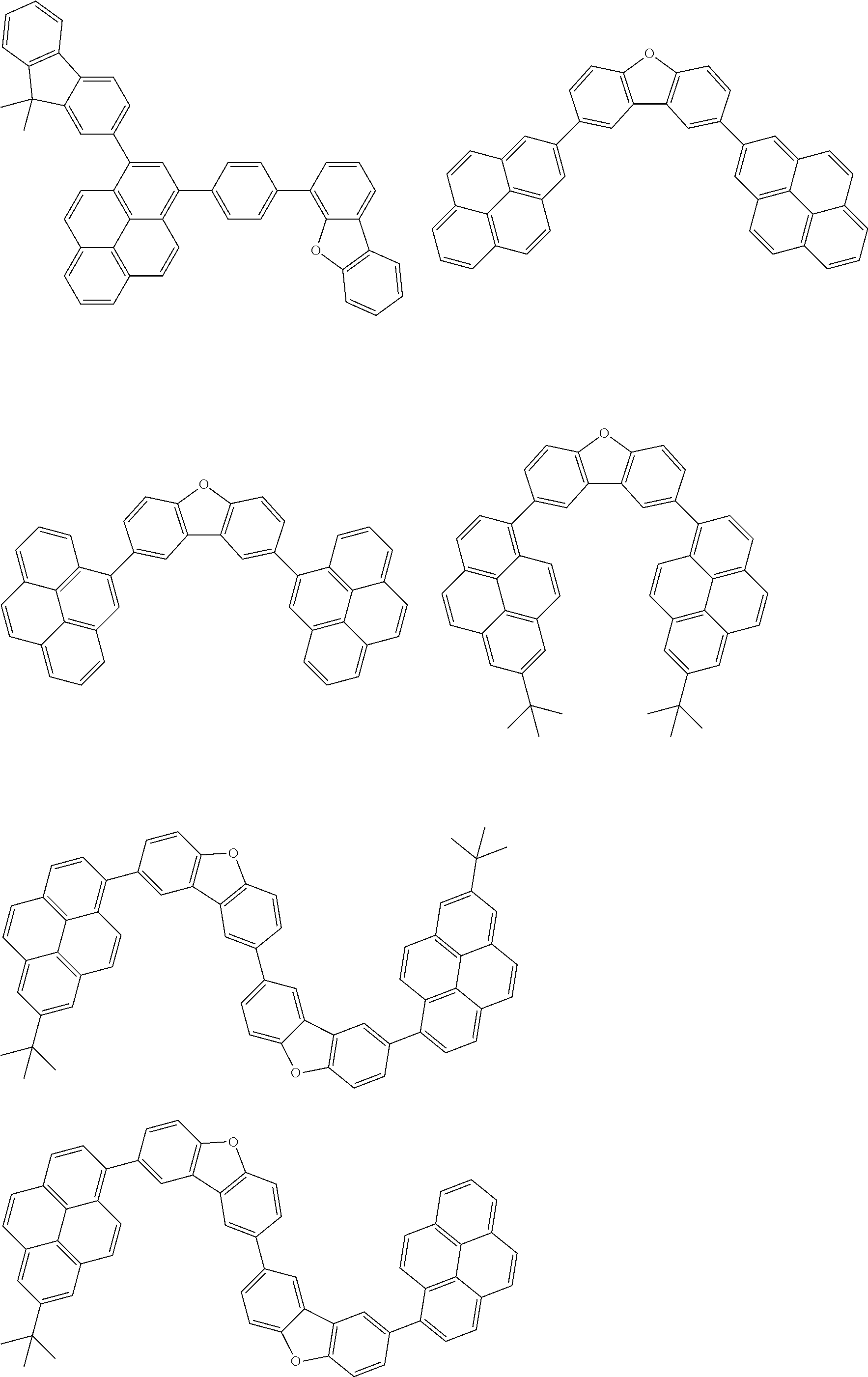

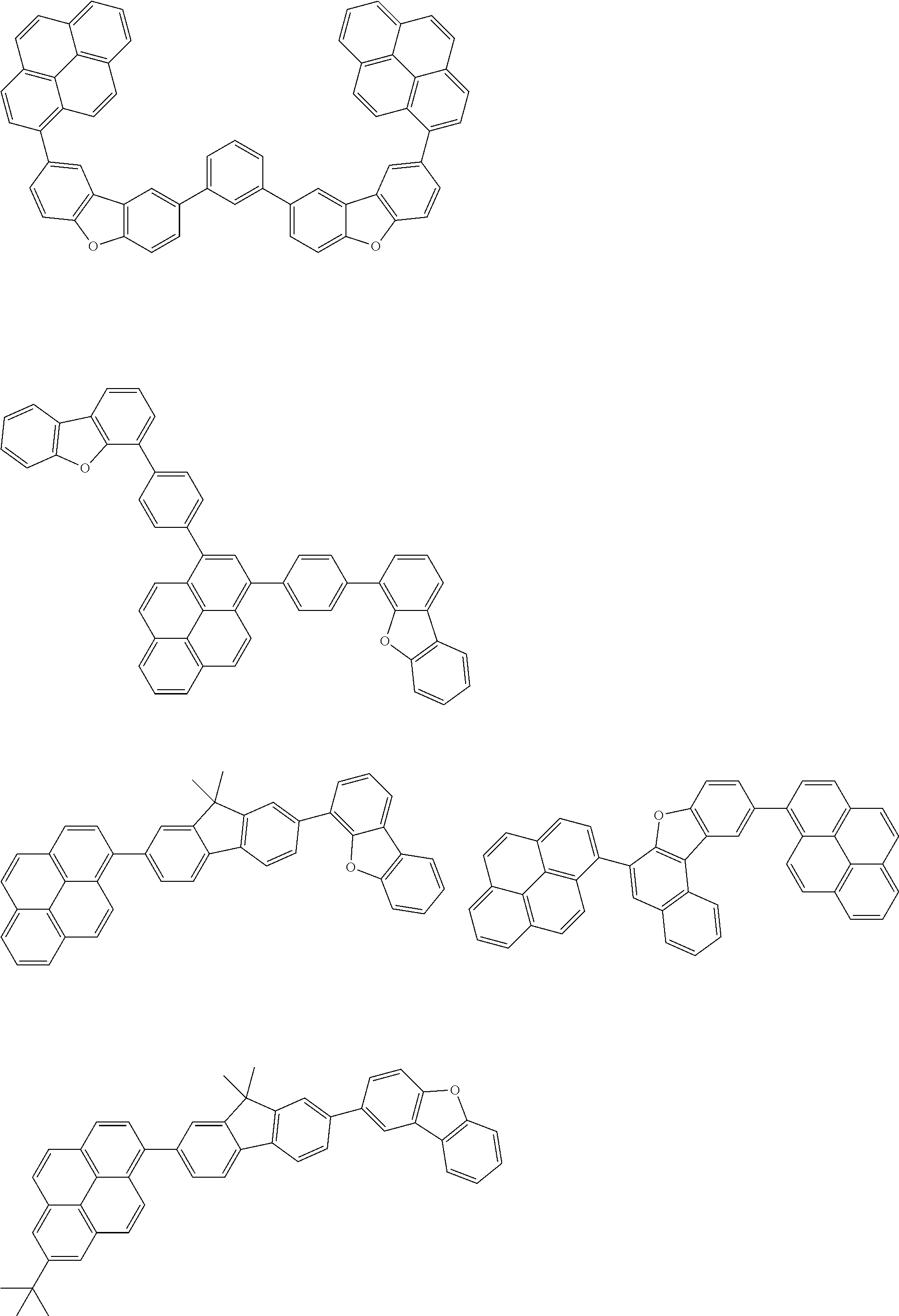

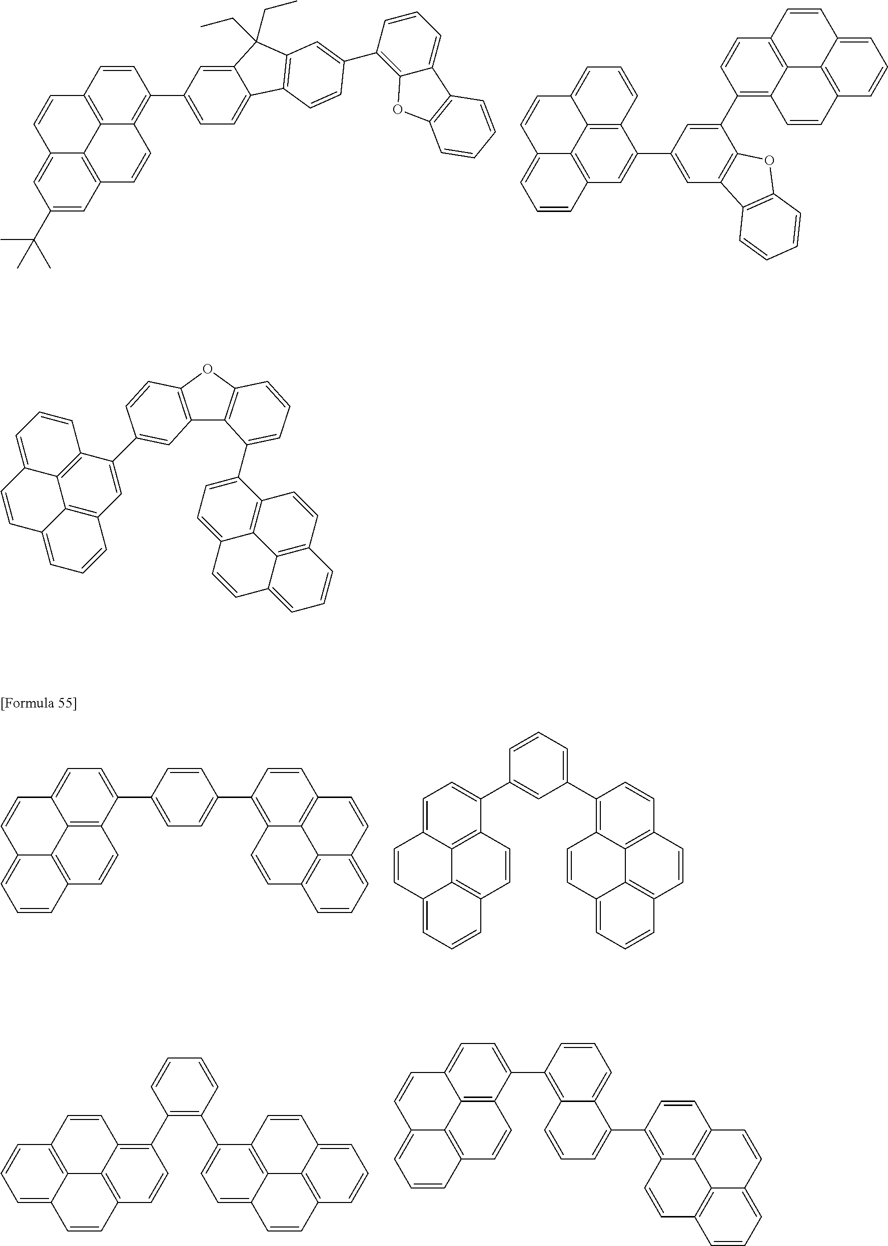

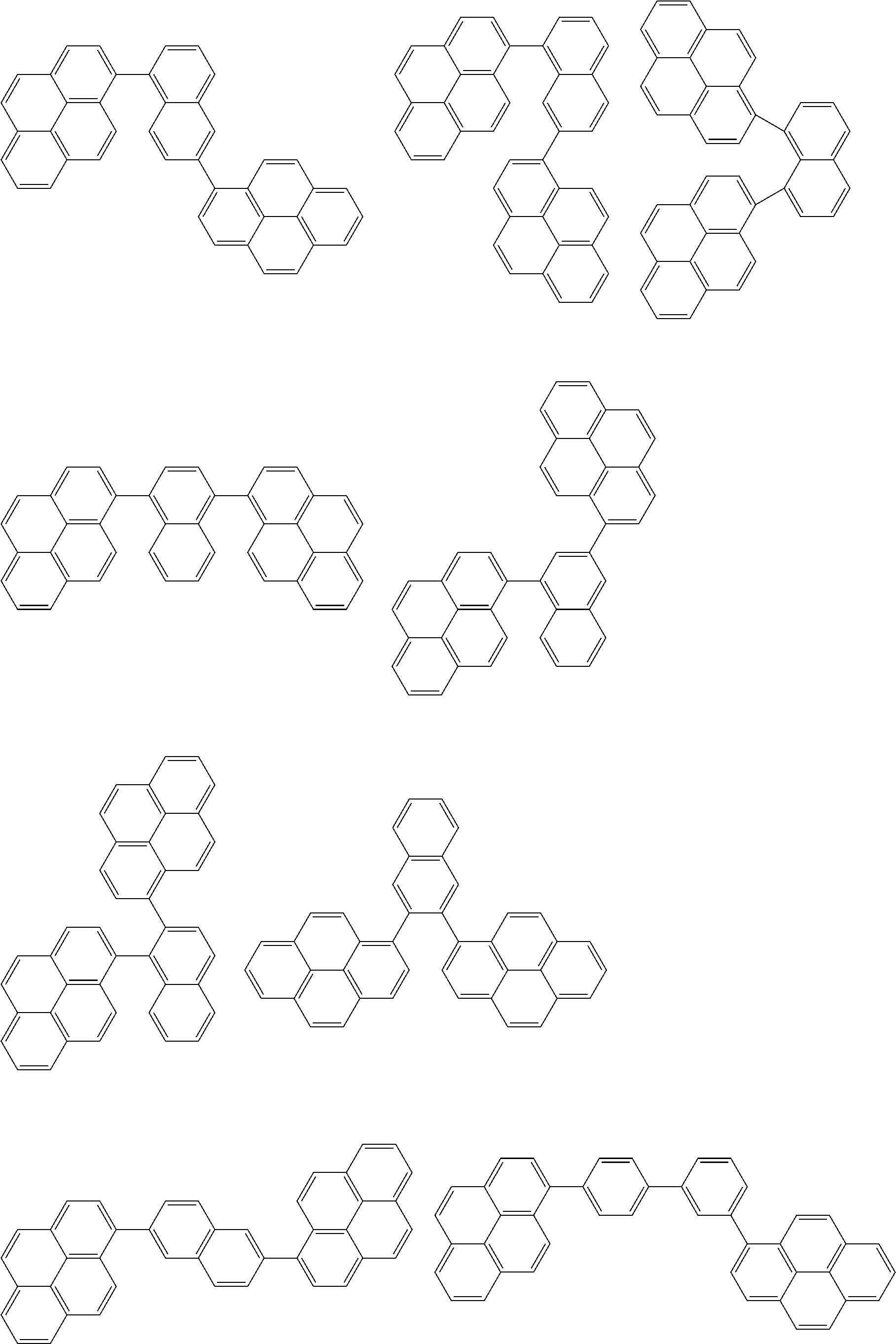

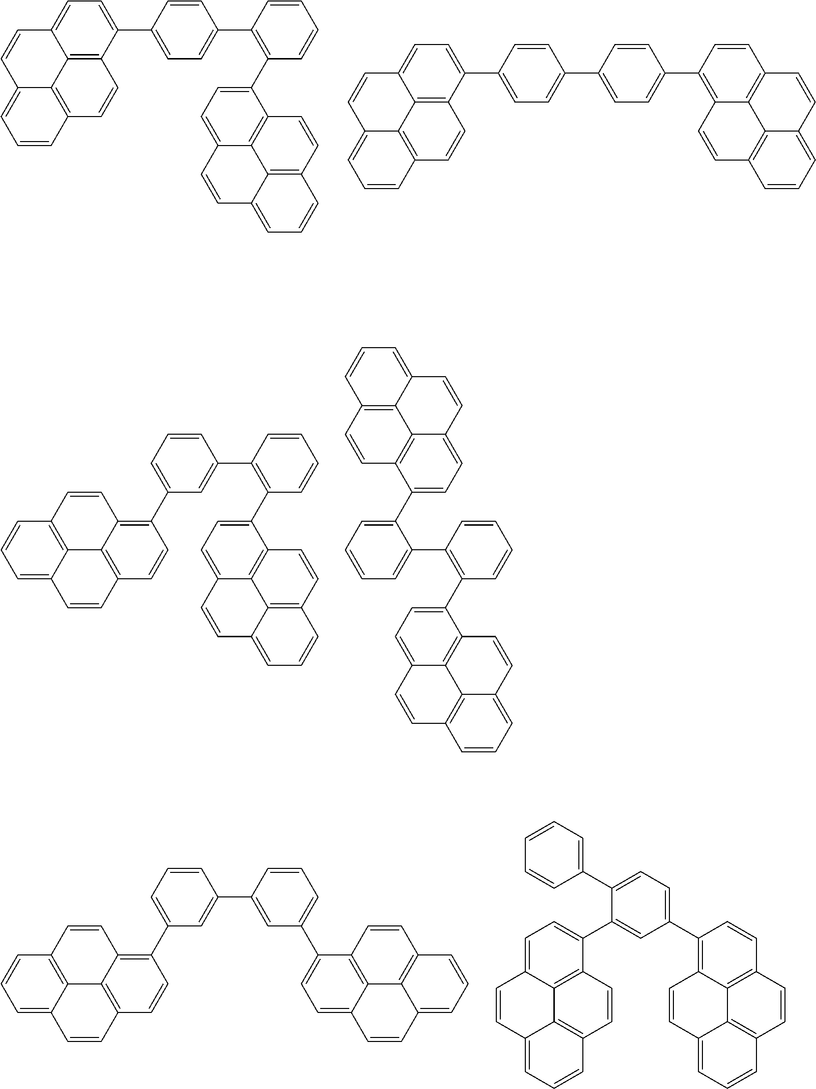

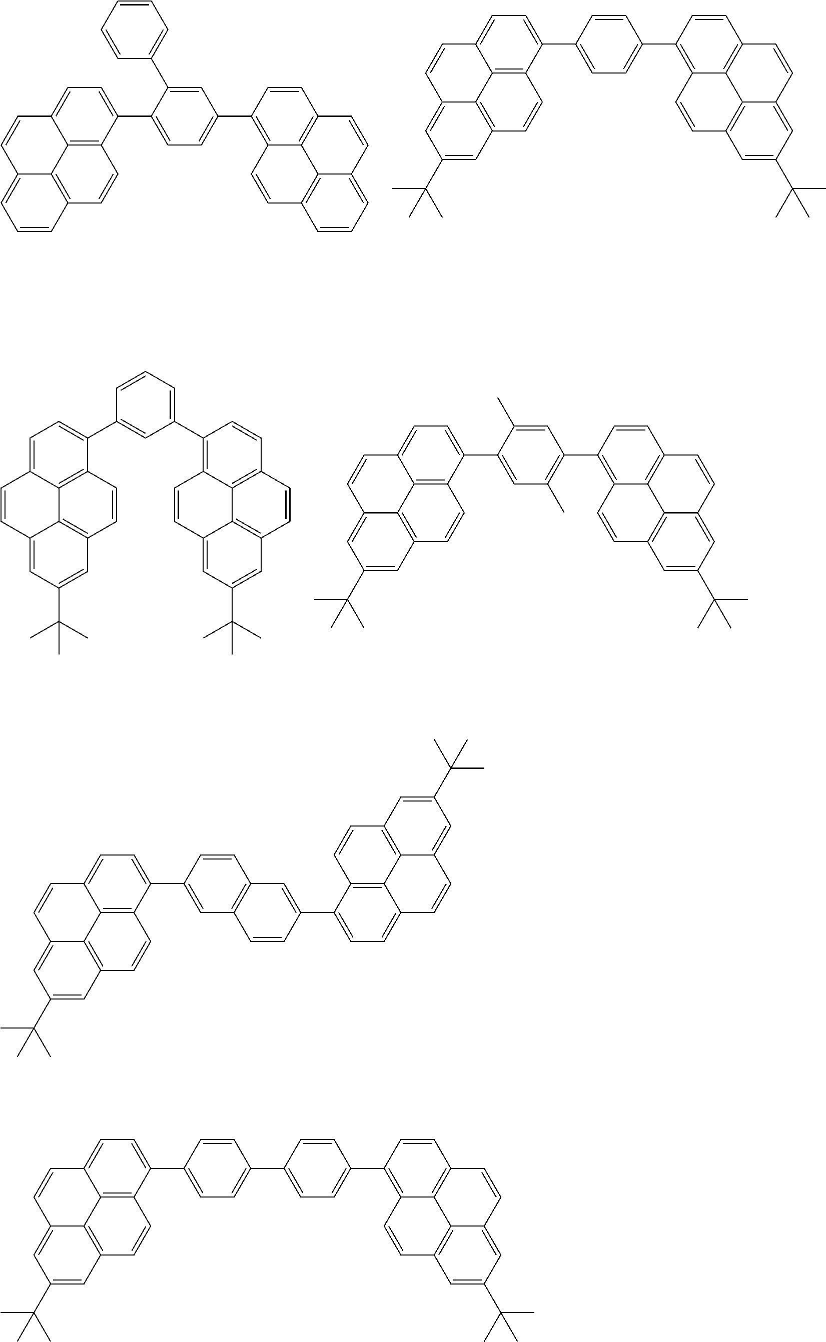

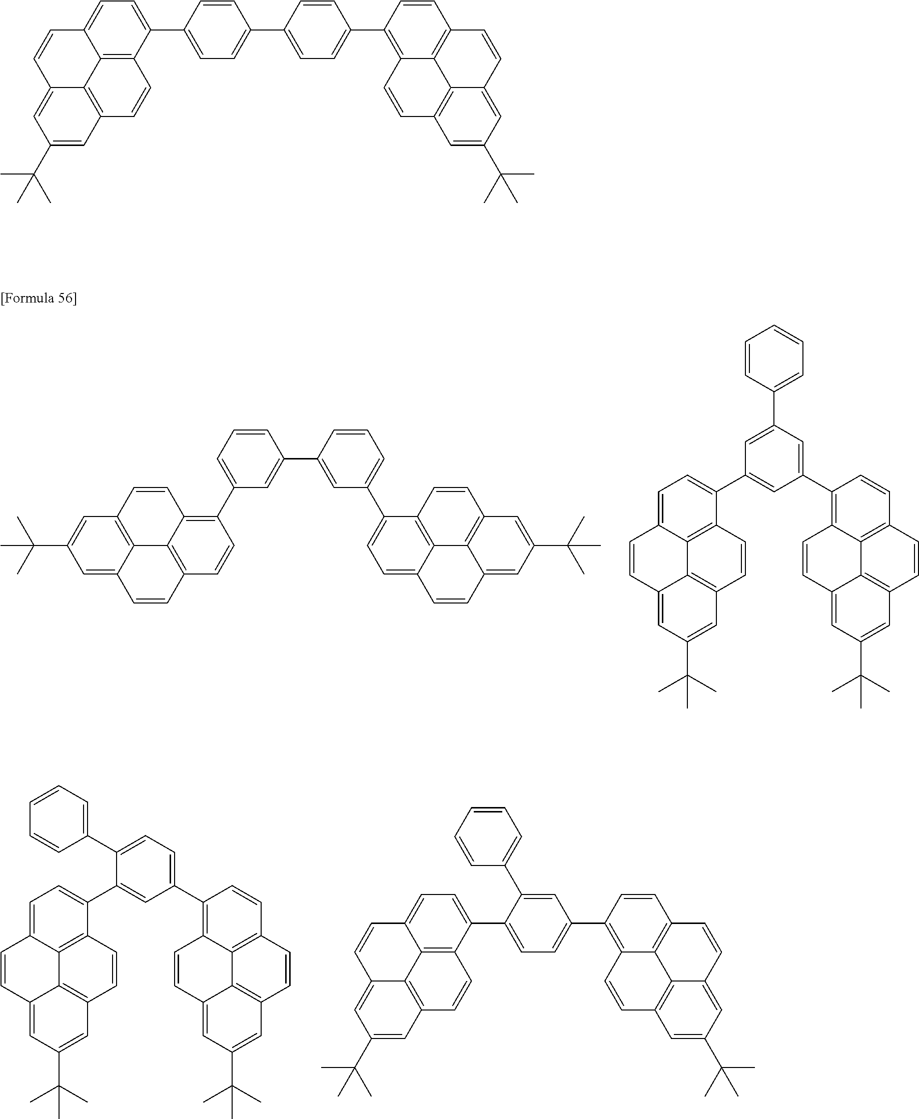

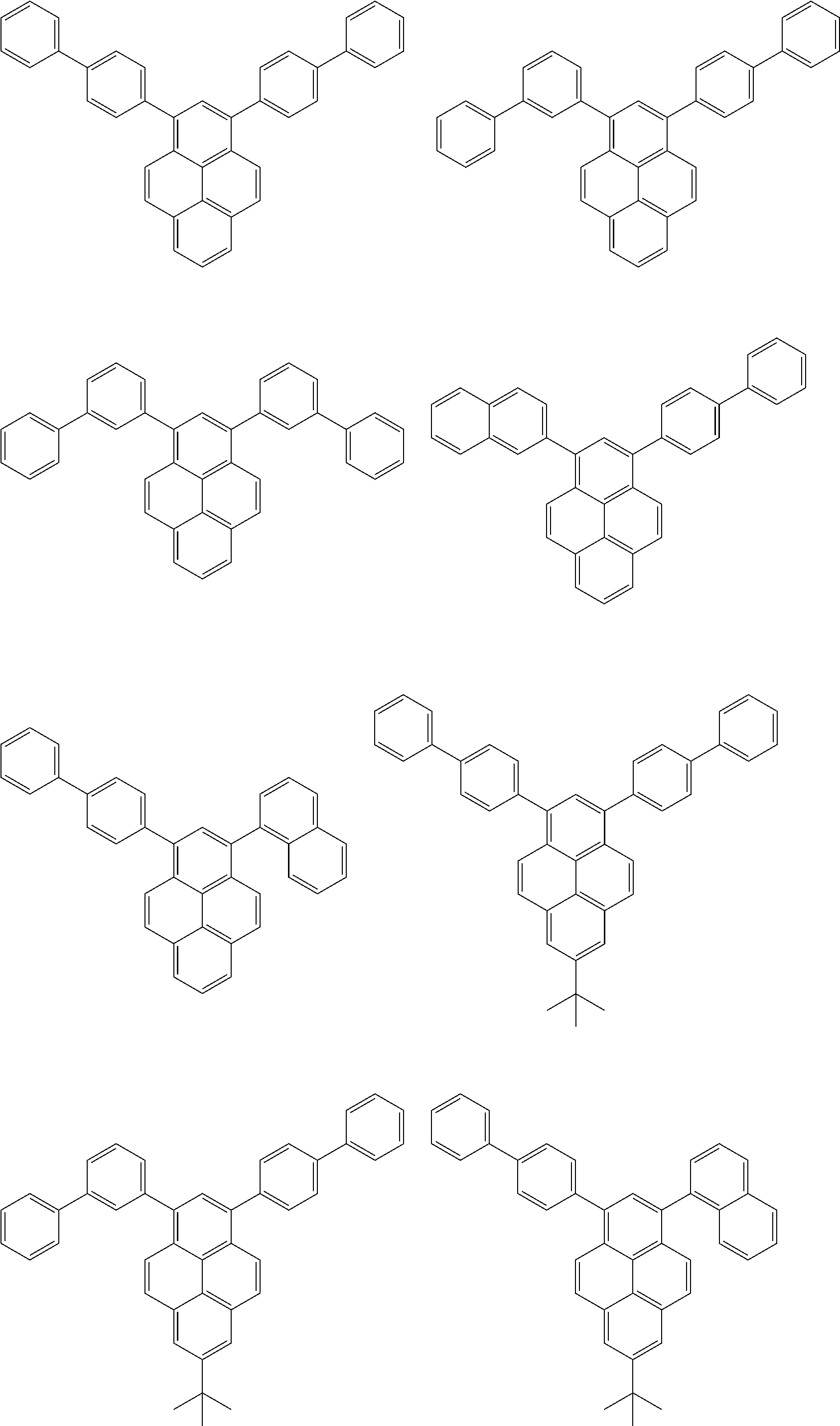

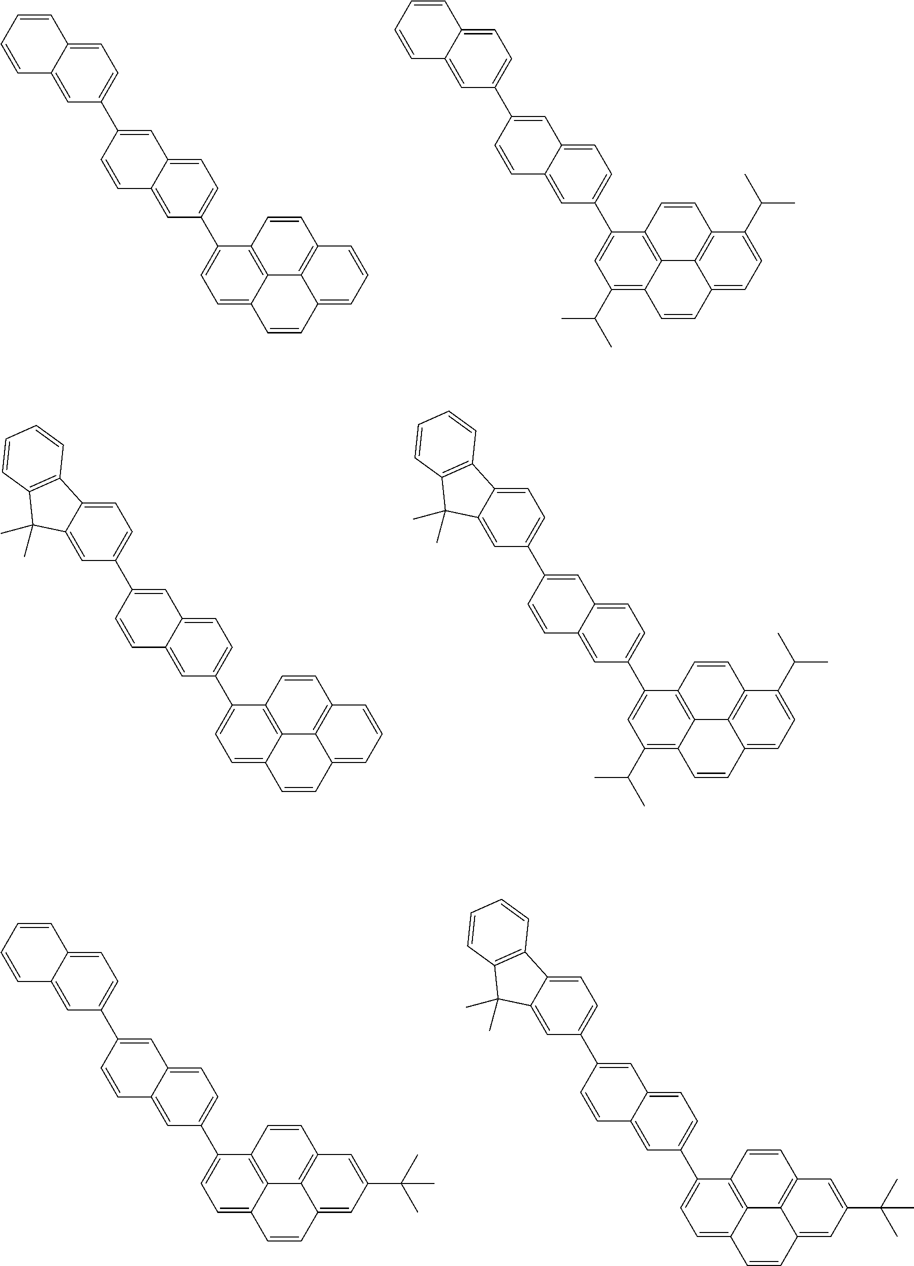

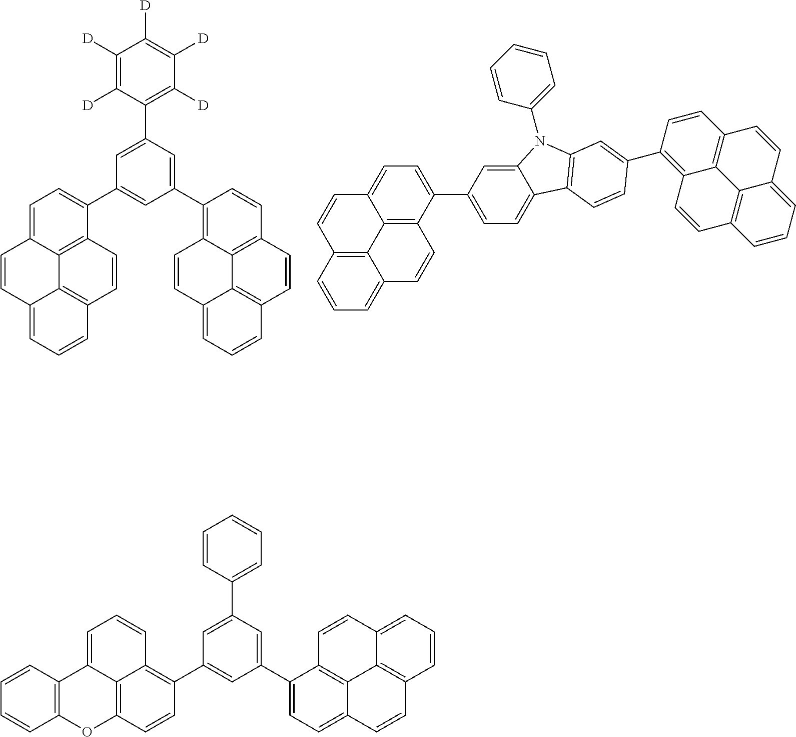

### Emitting Layer

In the organic EL device according to this exemplary embodiment, it is preferred that the emitting layer contain second compound(s) that fluoresces.

If the emitting layer of the organic EL device according to this exemplary embodiment contains second compound(s) and a third compound, it is preferred that the third compound be a host material (also referred to as a matrix material), and it is preferred that the second compound(s) be dopant material(s) (also referred to as guest material(s), emitter(s), or luminescent material(s)).

As mentioned herein, a “host material” is, for example, a material that constitutes “50% by mass or more of the layer.” This means the emitting layer contains, for example, a third compound represented by formula (1) above or by formula (2) below at 50% by mass or more of its total mass. Alternatively, a “host material” may constitute, for example, 60% by mass or more of the layer, 70% by mass or more of the layer, 80% by mass or more of the layer, 90% by mass or more of the layer, or 95% by mass or more of the layer.

In the organic EL device according to this exemplary embodiment, it is also preferred that the emitting layer contain a pyrene derivative, more preferably a pyrene derivative as a host material.

In the organic EL device according to this exemplary embodiment, it is also preferred that the emitting layer contain an anthracene derivative, more preferably an anthracene derivative as a host material.

Preferably, the emitting layer contains no phosphorescent material as a dopant material.

Preferably, furthermore, the emitting layer contains no heavy metal complex and no phosphorescent rare earth metal complex. In this context, examples of heavy metal complexes include, for instance, iridium complexes, osmium complexes, and platinum complexes.

It is also preferred that the emitting layer contain no metal complex.

### Multiple Emitting Layers

An emitting layer of an organic EL device according to an exemplary embodiment may be composed of multiple emitting layers.

An emitting layer of an organic EL device according to an exemplary embodiment includes, for example, a first emitting layer and a second emitting layer between the first emitting layer and the cathode. In this case, the organic EL device includes a first hole transporting layer, a first emitting layer, and a second emitting layer in this order from the anode, and the first hole transporting layer and the first emitting layer are in direct contact. Preferably, the first emitting layer is in direct contact with the second emitting layer.

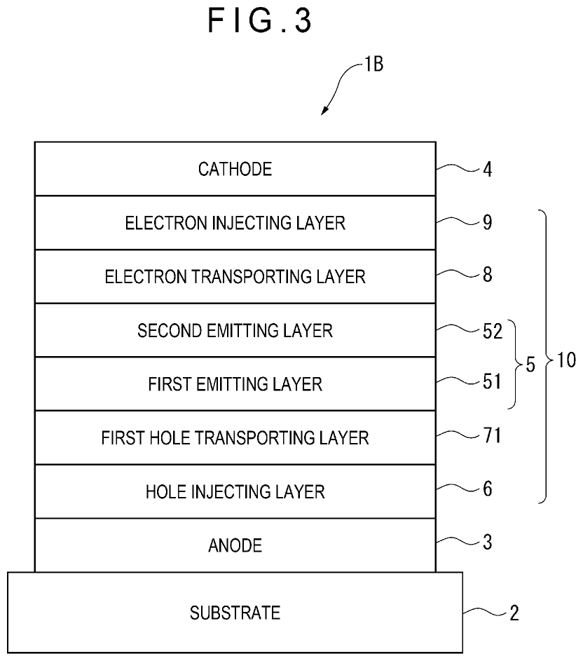

FIG. 3 illustrates an outline of another example of an organic EL device according to this exemplary embodiment.

The organic EL device 1B includes a light-transmissive substrate 2, an anode 3, a cathode 4, and an organic layer 10 between the anode 3 and the cathode 4. The organic layer 10 is formed by a hole injecting layer 6, a first hole transporting layer 71, an emitting layer 5, an electron transporting layer 8, and an electron injecting layer 9 stacked in this order on the anode 3, and the emitting layer 5 includes a first emitting layer 51 and a second emitting layer 52.

Preferably, the first and second emitting layers each independently further contain a fluorescent compound.

Preferably, the fluorescent compounds contained in the first and second emitting layers are compounds that exhibit light emission with a maximum peak wavelength in a range from 430 nm to 480 nm.

It is also preferred that the first emitting layer contain second compound(s) that fluoresces and a third compound. In that case, it is preferred that the third compound, in the first emitting layer, be a host material (also referred to as a matrix material), and it is preferred that the second compound(s) be dopant material(s) (also referred to as guest material(s), emitter(s), or luminescent material(s)).

It is also preferred that the second emitting layer contain fourth compound(s) that fluoresces and a fifth compound. In that case, it is preferred that the fifth compound, in the second emitting layer, be a host material (also referred to as a matrix material), and it is preferred that the fourth compound(s) be dopant material(s) (also referred to as guest material(s), emitter(s), or luminescent material(s)). The fourth compound(s) that fluoresces, in the second emitting layer, can be one(s) like the aforementioned second compound(s). The second compound(s) that fluoresces, in the first emitting layer, and the fourth compound(s) that fluoresces, in the second emitting layer, are mutually the same or different. The fifth compound, in the second emitting layer, can be one like the aforementioned third compound. The third compound, in the first emitting layer, and the fifth compound, in the second emitting layer, are mutually different.

Preferably, the first emitting layer contains a pyrene derivative, more preferably a pyrene derivative as a host material.

Preferably, the second emitting layer contains an anthracene derivative, more preferably an anthracene derivative as a host material.

More preferably, the first emitting layer contains a pyrene derivative as a host material, and the second emitting layer contains an anthracene derivative as a host material at the same time.

Preferably, the first and second emitting layers contain no phosphorescent material as a dopant material.

Preferably, furthermore, the first and second emitting layers contain no heavy metal complex and no phosphorescent rare earth metal complex. In this context, examples of heavy metal complexes include, for instance, iridium complexes, osmium complexes, and platinum complexes.

It is also preferred that the first and second emitting layers contain no metal complex.

### Second and Fourth Compounds

The second compound(s) and the fourth compound(s) each independently represent one or more compounds selected from the group consisting of a compound represented by formula (3) below, a compound represented by formula (4) below, a compound represented by formula (5) below, a compound represented by formula (6) below, a compound represented by formula (7) below, a compound represented by formula (8) below, a compound represented by formula (9) below, and a compound represented by formula (10) below.

### Compounds Represented by Formula (3)

The following describes the compounds represented by formula (3).

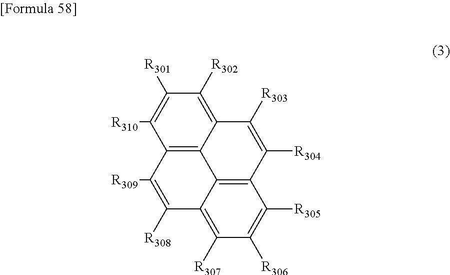

In formula (3),

at least one combination of adjacent two or more of R₃₀₁ to R₃₁₀ are: bonded together to form a substituted or unsubstituted monocyclic ring; bonded together to form a substituted or unsubstituted fused ring; or not bound together;

at least one of R₃₀₁ to R₃₁₀ is a monovalent group represented by formula (31) below; and

R₃₀₁ to R₃₁₀ forming neither the monocyclic ring nor the fused ring and not being the monovalent group represented by formula (31) each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

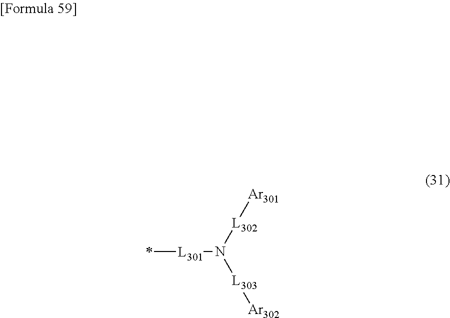

In formula (31),

Ar₃₀₁ and Ar₃₀₂ each independently represent: a substituted or unsubstituted aryl group having 6 to 50 ring carbon atoms; or a substituted or unsubstituted heterocyclic group having 5 to 50 ring atoms;

L₃₀₁ to L₃₀₃ each independently represent: a single bond; a substituted or unsubstituted arylene group having 6 to 30 ring carbon atoms; or a substituted or unsubstituted divalent heterocyclic group having 5 to 30 ring atoms; and

* indicates the position of bonding with the pyrene ring in formula (3).

In a second compound, R₉₀₁, R₉₀₂, R₉₀₃, R₉₀₄, R₉₀₅, R₉₀₆, and R₉₀₇ each independently represent: a hydrogen atom; a substituted or unsubstituted alkyl group having 1 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms;

a substituted or unsubstituted alkyl group having 1 to 50 carbon atoms; or a substituted or unsubstituted aryl group having 6 to 50 ring carbon atoms;

when multiple R₉₀₁s are present, the multiple R₉₀₁s are mutually the same or different;

when multiple R₉₀₂s are present, the multiple R₉₀₂s are mutually the same or different;

when multiple R₉₀₃s are present, the multiple R₉₀₃s are mutually the same or different;

when multiple R₉₀₄s are present, the multiple R₉₀₄s are mutually the same or different;

when multiple R₉₀₅s are present, the multiple R₉₀₅s are mutually the same or different;

when multiple R₉₀₆s are present, the multiple R₉₀₆s are mutually the same or different; and

when multiple R₉₀₇s are present, the multiple R₉₀₇s are mutually the same or different.

In formula (3), it is preferred that two of R₃₀₁ to R₃₁₀ be groups represented by formula (31).

In an exemplary embodiment, the compounds represented by formula (3) are the compounds represented by formula (33) below.

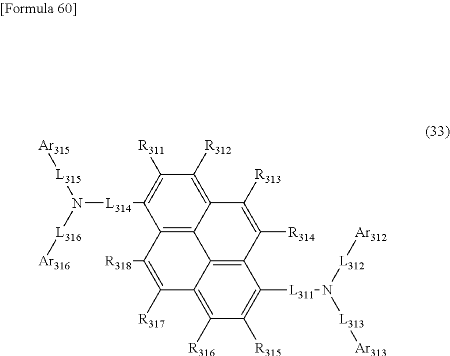

In formula (33),

R₃₁₁ to R₃₁₆ each independently represent the same as when R₃₀₁ to R₃₁₀ in formula (3) are not monovalent groups represented by formula (31);

L₃₁₁ to L₃₁₆ each independently represent: a single bond; a substituted or unsubstituted arylene group having 6 to 30 ring carbon atoms; or a substituted or unsubstituted divalent heterocyclic group having 5 to 30 ring atoms; and

Ar₃₁₂, Ar₃₁₃, Ar₃₁₇, and Ar₃₁₆ each independently represent: a substituted or unsubstituted aryl group having 6 to 50 ring carbon atoms; or a substituted or unsubstituted heterocyclic group having 5 to 50 ring atoms.

In formula (31), it is preferred that L₃₀₁ be a single bond, and it is preferred that L₃₀₂ and L₃₀₃ be single bonds.

In an exemplary embodiment, the compounds represented by formula (3) are represented by formula (34) or (35) below.

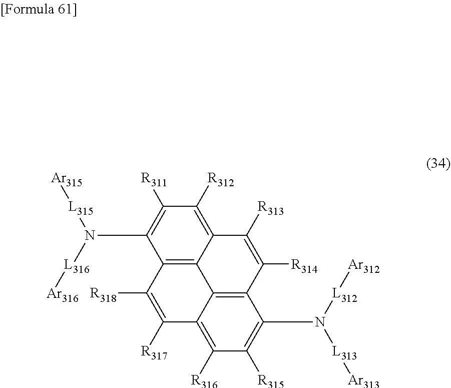

In formula (34),

R₃₁₁ to R₃₁₈ each independently represent the same as when R₃₀₁ to R₃₁₀ in formula (3) are not monovalent groups represented by formula (31);

L₃₁₂, L₃₁₃, L₃₁₅, and L₃₁₆ each independently represent the same as L₃₁₂, L₃₁₃, L₃₁₅, and L₃₁₆ in formula (33); and

Ar₃₁₂, Ar₃₁₃, Ar₃₁₅, and Ar₃₁₆ each independently represent the same as Ar₃₁₂, Ar₃₁₃, Ar₃₁₅, and Ar₃₁₆ in formula (33).

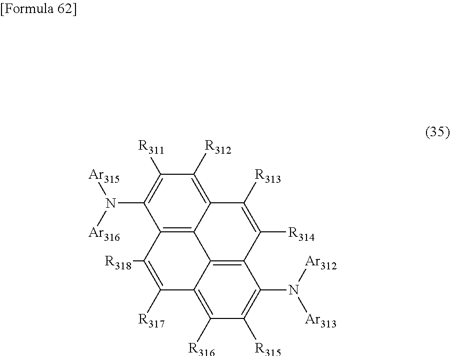

In formula (35),

R₃₁₁ to R₃₁₈ each independently represent the same as when R₃₀₁ to R₃₁₀ in formula (3) are not monovalent groups represented by formula (31); and

Ar₃₁₂, Ar₃₁₃, Ar₃₁s, and Ar₃₁₆ each independently represent the same as Ar₃₁₂, Ar₃₁₃, Ar₃₁s, and Ar₃₁₆ in formula (33).

In formula (31), it is preferred that at least one of Ar₃₀₁ or Ar₃₀₂ be a group represented by formula (36) below.

In formulae (33) to (35), it is preferred that at least one of Ar₃₁₂ or Ar₃₁₃ be a group represented by formula (36) below.

In formulae (33) to (35), it is preferred that at least one of Ar₃₁₅ or Ar₃₁₆ be a group represented by formula (36) below.

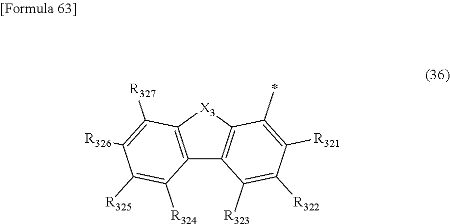

In formula (36),

X₃ denotes an oxygen or sulfur atom;

at least one combination of adjacent two or more of R₃₂₁ to R₃₂₇ are: bonded together to form a substituted or unsubstituted monocyclic ring; bonded together to form a substituted or unsubstituted fused ring; or not bonded together;

R₃₂₁ to R₃₂₇ not forming the monocyclic ring and not forming the fused ring each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms; and

* indicates the position of bonding with L₃₀₂, L₃₀₃, L₃₁₂, L₃₁₃, L₃₁₅, or L₃₁₆.

Preferably, X₃ is an oxygen atom.

Preferably, at least one of R₃₂₁ to R₃₂₇ is: a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms.

In formula (31), it is preferred that Ar₃₀₁ be a group represented by formula (36) and that Ar₃₀₂ be a substituted or unsubstituted aryl group having 6 to 50 ring carbon atoms.

In formulae (33) to (35), it is preferred that Ar₃₁₂ be a group represented by formula (36) and that Ar₃₁₃ be a substituted or unsubstituted aryl group having 6 to 50 ring carbon atoms.

In formulae (33) to (35), it is preferred that Ar₃₁₅ be a group represented by formula (36) and that Ar₃₁₆ be a substituted or unsubstituted aryl group having 6 to 50 ring carbon atoms.

In an exemplary embodiment, the compounds represented by formula (3) are represented by formula (37) below.

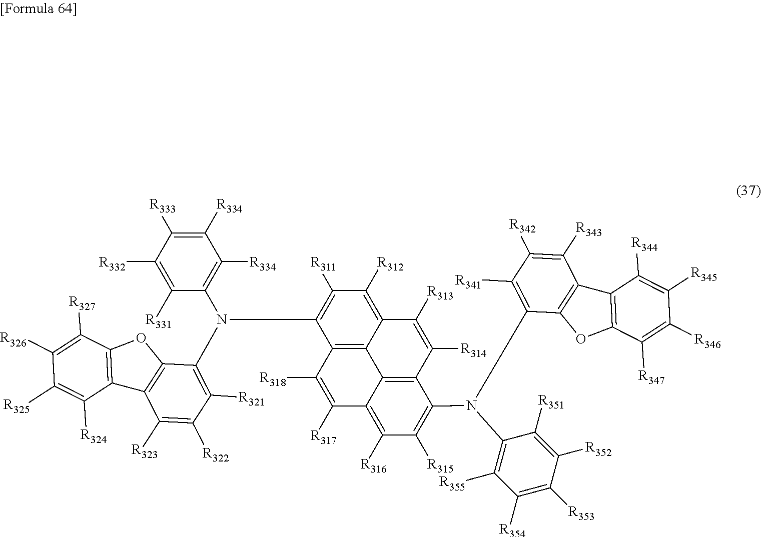

In formula (37),

R₃₁₁ to R₃₁₈ each independently represent the same when R₃₀₁ to R₃₁₀ in formula (3) are not monovalent groups represented by formula (31);

at least one combination of adjacent two or more of R₃₂₁ to R₃₂₇ are: bonded together to form a substituted or unsubstituted monocyclic ring; bonded together to form a substituted or unsubstituted fused ring; or not bonded together;

at least one combination of adjacent two or more of R₃₄₁ to R₃₄₇ are: bonded together to form a substituted or unsubstituted monocyclic ring; bonded together to form a substituted or unsubstituted fused ring; or not bonded together; and

R₃₂₁ to R₃₂₇ and R₃₄₁ to R₃₄₇ not forming the monocyclic ring and not forming the fused ring each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms; and

R₃₃₁ to R₃₃₅ and R₃₅₁ to R₃₅₅ each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

Specific examples of compounds represented by formula (3) include, for instance, the following compounds.

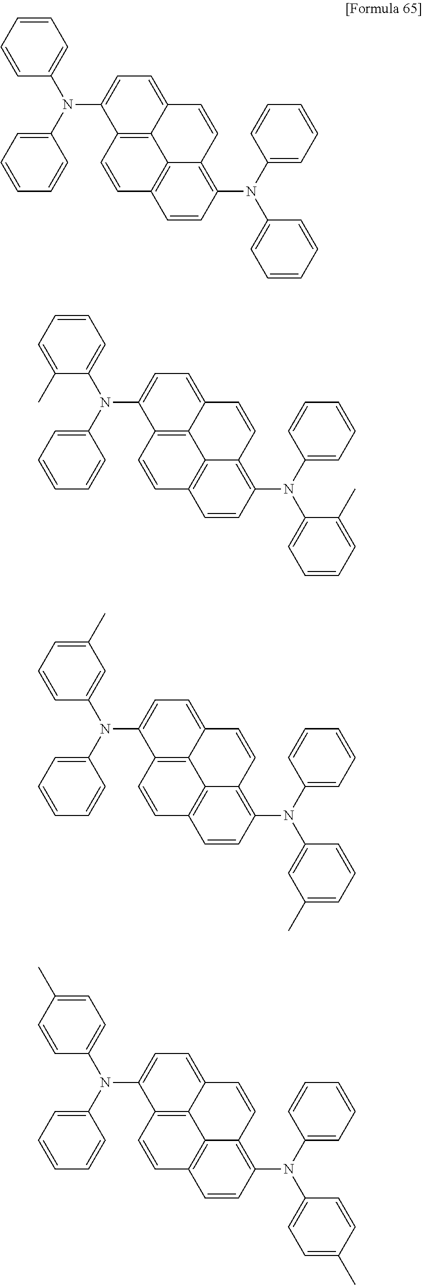 [SMILES: c1ccc(N(c2ccccc2)c2ccc3ccc4c(N(c5ccccc5)c5ccccc5)ccc5ccc2c3c54)cc1 ; Cc1ccccc1N(c1ccccc1)c1ccc2ccc3c(N(c4ccccc4)c4ccccc4C)ccc4ccc1c2c43 ; Cc1cccc(N(c2ccccc2)c2ccc3ccc4c(N(c5ccccc5)c5cccc(C)c5)ccc5ccc2c3c54)c1 ; Cc1ccc(N(c2ccccc2)c2ccc3ccc4c(N(c5ccccc5)c5ccc(C)cc5)ccc5ccc2c3c54)cc1]

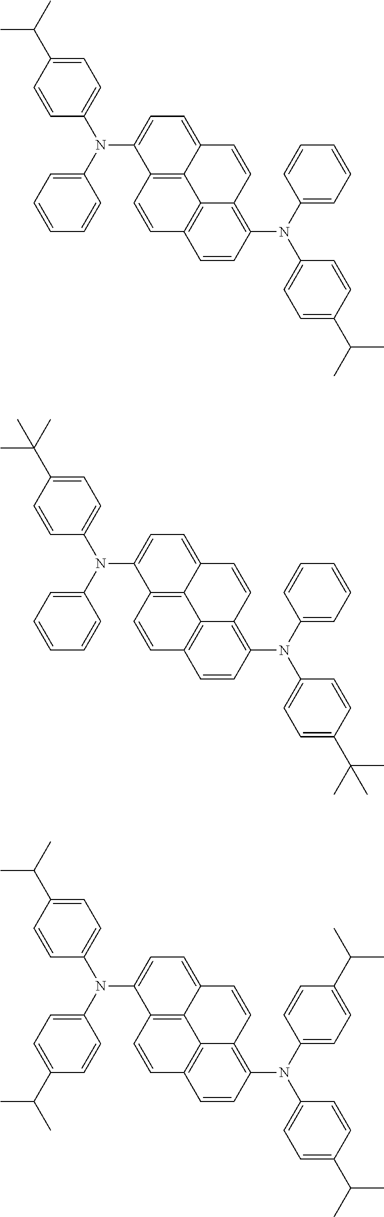

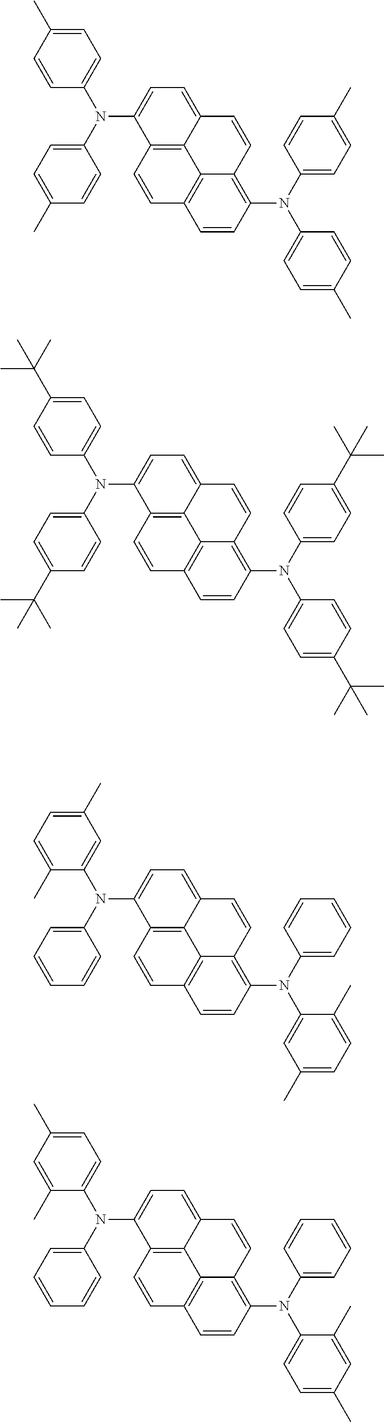

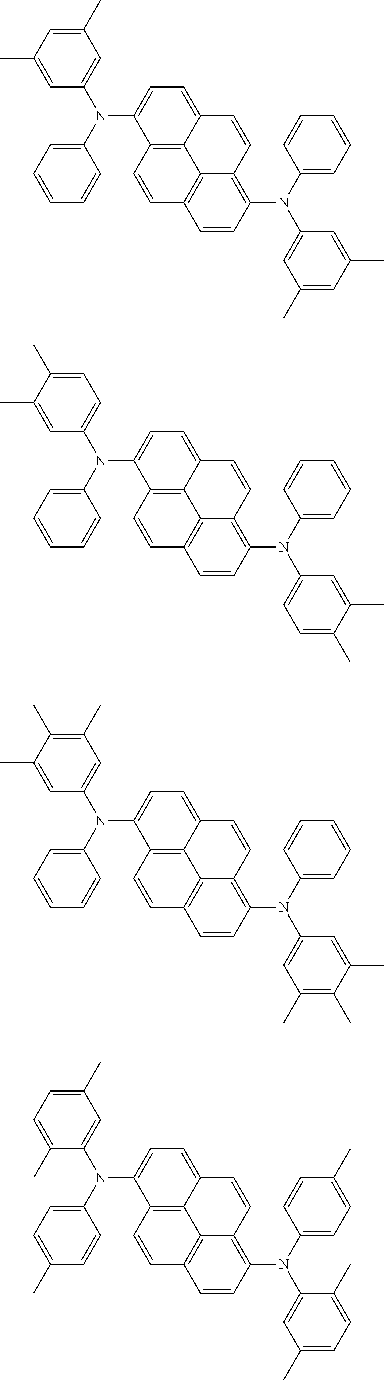

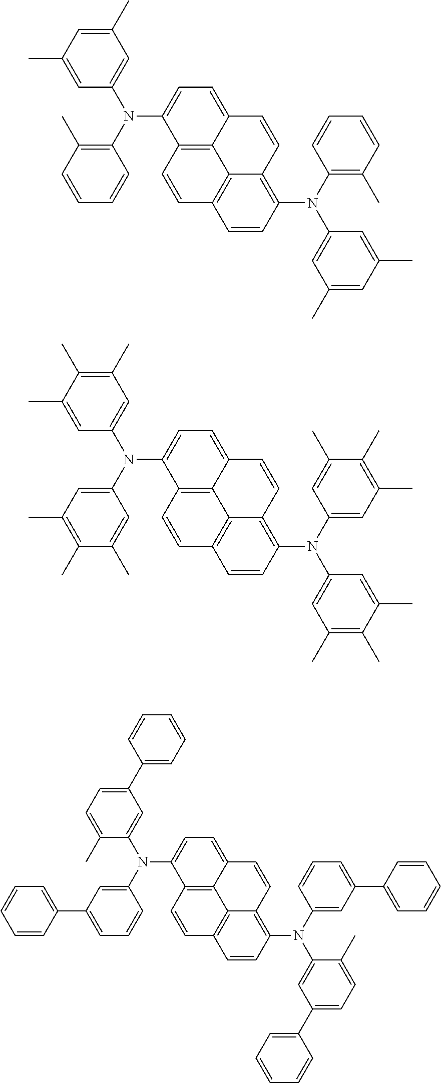

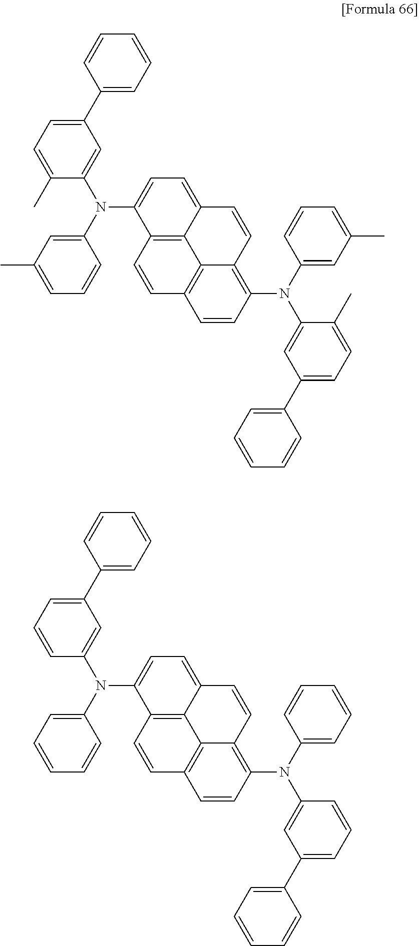

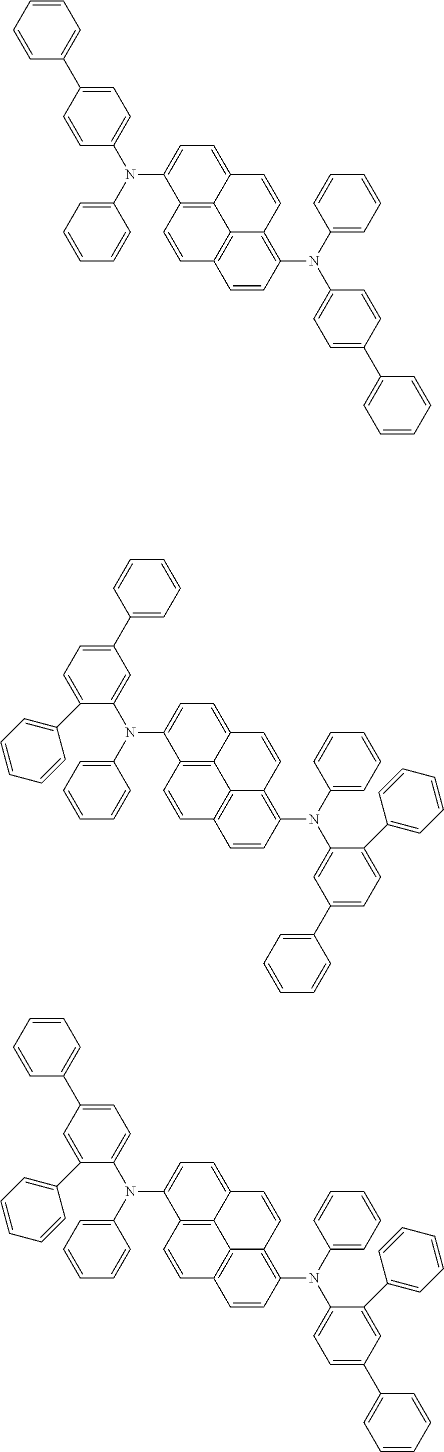 [SMILES: c1ccc(-c2ccc(N(c3ccccc3)c3ccc4ccc5c(N(c6ccccc6)c6ccc(-c7ccccc7)cc6)ccc6ccc3c4c65)cc2)cc1 ; c1ccc(-c2ccc(-c3ccccc3)c(N(c3ccccc3)c3ccc4ccc5c(N(c6ccccc6)c6cc(-c7ccccc7)ccc6-c6ccccc6)ccc6ccc3c4c65)c2)cc1 ; c1ccc(-c2ccc(N(c3ccccc3)c3ccc4ccc5c(N(c6ccccc6)c6ccc(-c7ccccc7)cc6-c6ccccc6)ccc6ccc3c4c65)c(-c3ccccc3)c2)cc1]

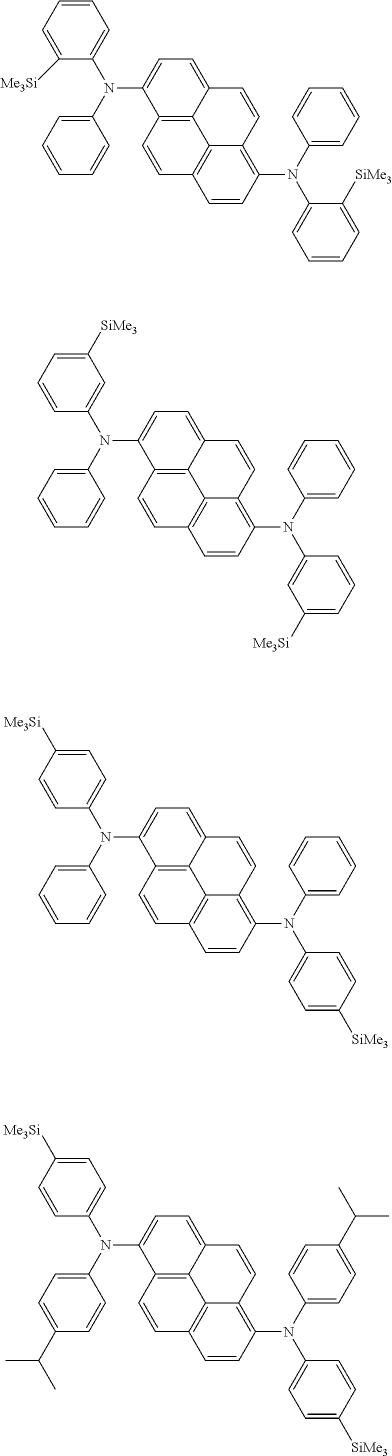 [SMILES: C[Si](C)(C)c1ccccc1N(c1ccccc1)c1ccc2ccc3c(N(c4ccccc4)c4ccccc4[Si](C)(C)C)ccc4ccc1c2c43 ; C[Si](C)(C)c1cccc(N(c2ccccc2)c2ccc3ccc4c(N(c5ccccc5)c5cccc([Si](C)(C)C)c5)ccc5ccc2c3c54)c1 ; C[Si](C)(C)c1ccc(N(c2ccccc2)c2ccc3ccc4c(N(c5ccccc5)c5ccc([Si](C)(C)C)cc5)ccc5ccc2c3c54)cc1 ; CC(C)c1ccc(N(c2ccc([Si](C)(C)C)cc2)c2ccc3ccc4c(N(c5ccc(C(C)C)cc5)c5ccc([Si](C)(C)C)cc5)ccc5ccc2c3c54)cc1]

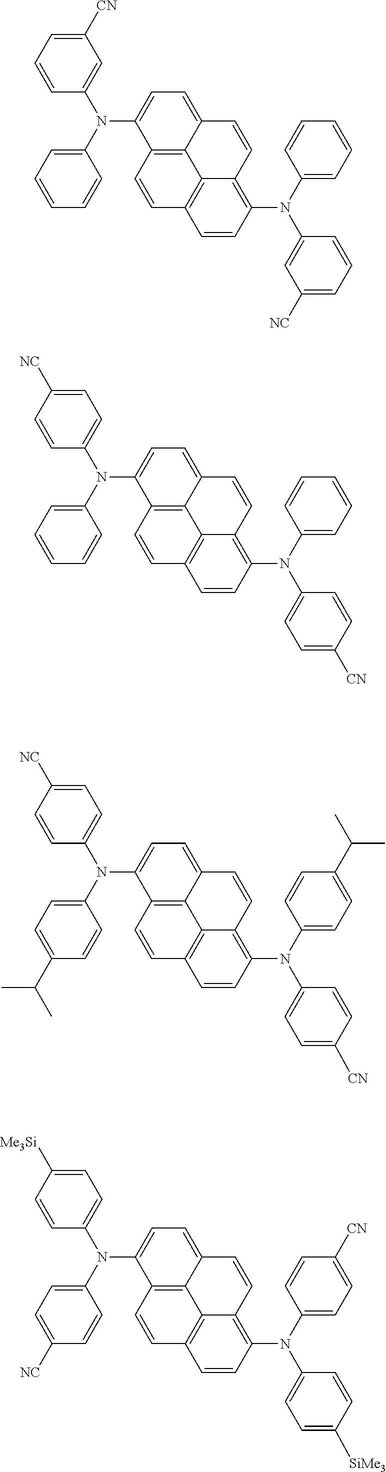 [SMILES: N#Cc1cccc(N(c2ccccc2)c2ccc3ccc4c(N(c5ccccc5)c5cccc(C#N)c5)ccc5ccc2c3c54)c1 ; N#Cc1ccc(N(c2ccccc2)c2ccc3ccc4c(N(c5ccccc5)c5ccc(C#N)cc5)ccc5ccc2c3c54)cc1 ; CC(C)c1ccc(N(c2ccc(C#N)cc2)c2ccc3ccc4c(N(c5ccc(C#N)cc5)c5ccc(C(C)C)cc5)ccc5ccc2c3c54)cc1 ; C[Si](C)(C)c1ccc(N(c2ccc(C#N)cc2)c2ccc3ccc4c(N(c5ccc(C#N)cc5)c5ccc([Si](C)(C)C)cc5)ccc5ccc2c3c54)cc1]

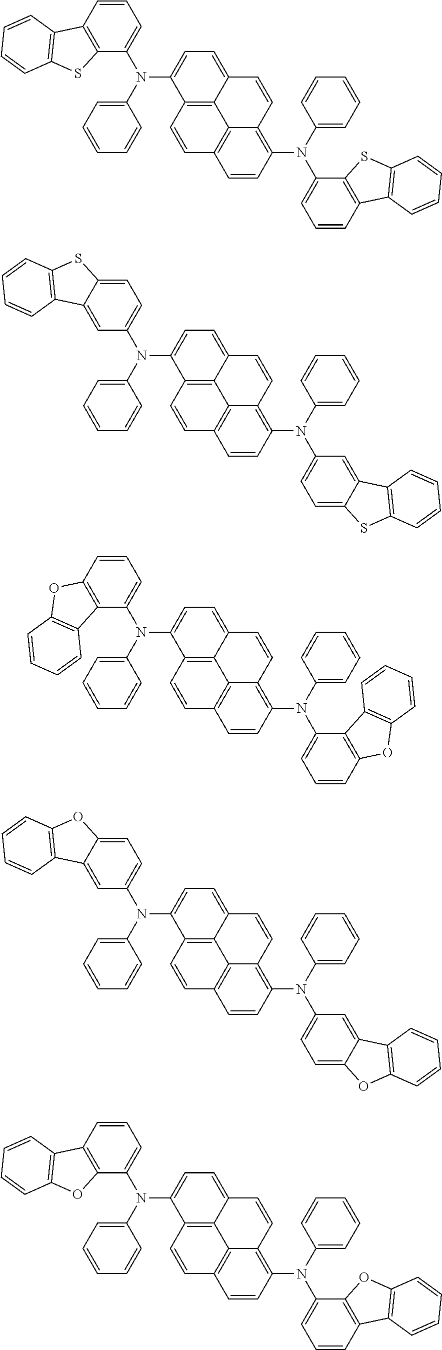 [SMILES: c1ccc(N(c2ccc3ccc4c(N(c5ccccc5)c5cccc6c5sc5ccccc56)ccc5ccc2c3c54)c2cccc3c2sc2ccccc23)cc1 ; c1ccc(N(c2ccc3sc4ccccc4c3c2)c2ccc3ccc4c(N(c5ccccc5)c5ccc6sc7ccccc7c6c5)ccc5ccc2c3c54)cc1 ; c1ccc(N(c2ccc3ccc4c(N(c5ccccc5)c5cccc6oc7ccccc7c56)ccc5ccc2c3c54)c2cccc3oc4ccccc4c23)cc1 ; c1ccc(N(c2ccc3oc4ccccc4c3c2)c2ccc3ccc4c(N(c5ccccc5)c5ccc6oc7ccccc7c6c5)ccc5ccc2c3c54)cc1 ; c1ccc(N(c2ccc3ccc4c(N(c5ccccc5)c5cccc6c5oc5ccccc56)ccc5ccc2c3c54)c2cccc3c2oc2ccccc23)cc1]

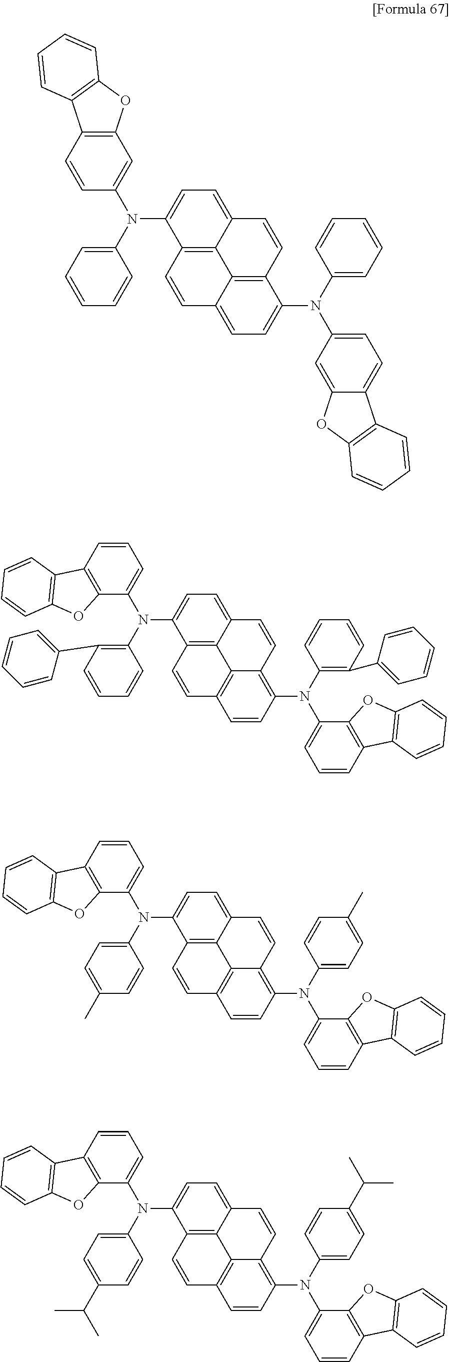 [SMILES: c1ccc(N(c2ccc3c(c2)oc2ccccc23)c2ccc3ccc4c(N(c5ccccc5)c5ccc6c(c5)oc5ccccc56)ccc5ccc2c3c54)cc1 ; c1ccc(-c2ccccc2N(c2ccc3ccc4c(N(c5ccccc5-c5ccccc5)c5cccc6c5oc5ccccc56)ccc5ccc2c3c54)c2cccc3c2oc2ccccc23)cc1 ; Cc1ccc(N(c2ccc3ccc4c(N(c5ccc(C)cc5)c5cccc6c5oc5ccccc56)ccc5ccc2c3c54)c2cccc3c2oc2ccccc23)cc1 ; CC(C)c1ccc(N(c2ccc3ccc4c(N(c5ccc(C(C)C)cc5)c5cccc6c5oc5ccccc56)ccc5ccc2c3c54)c2cccc3c2oc2ccccc23)cc1]

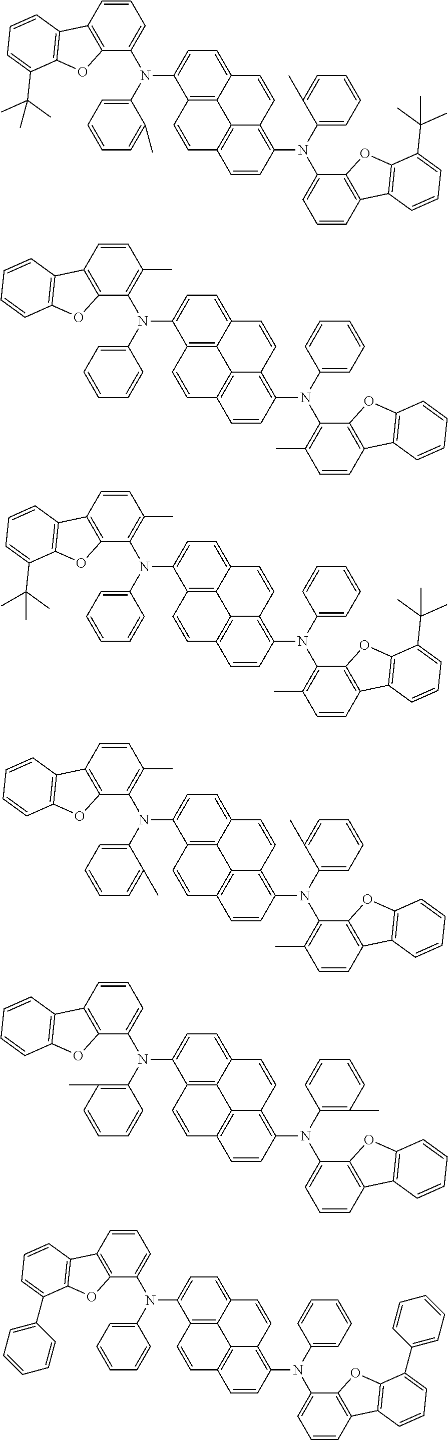

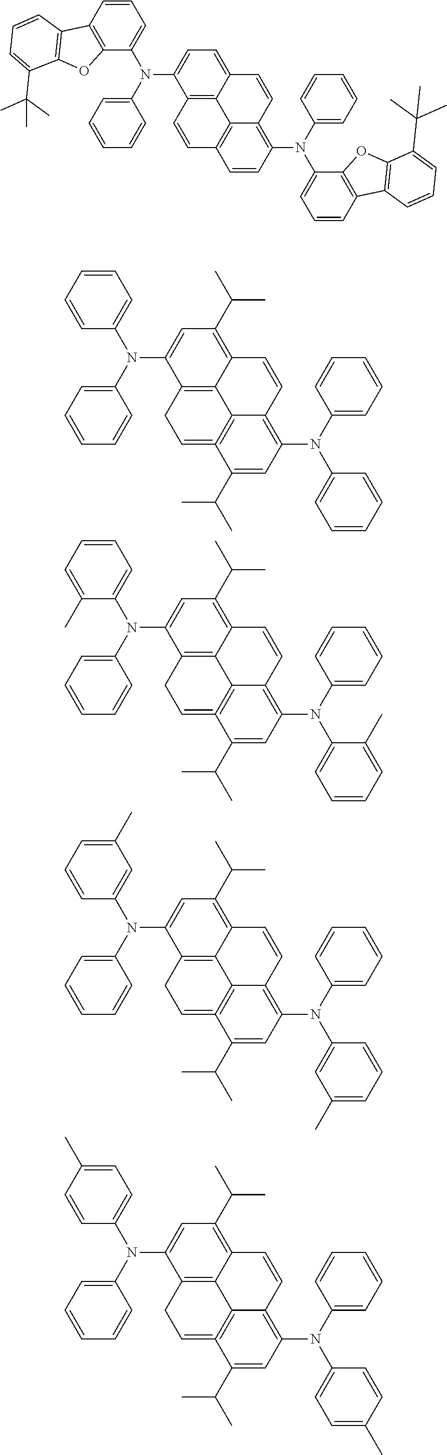

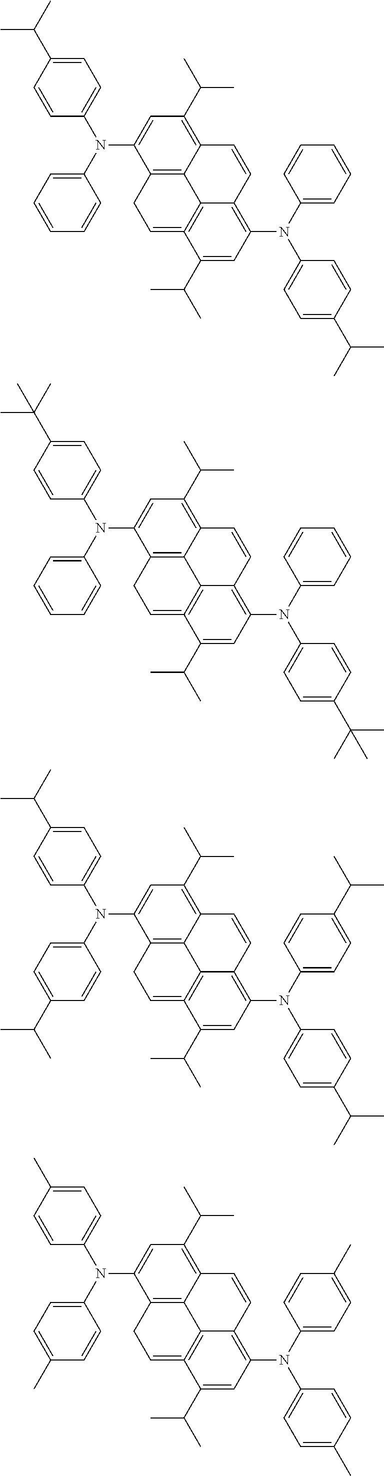

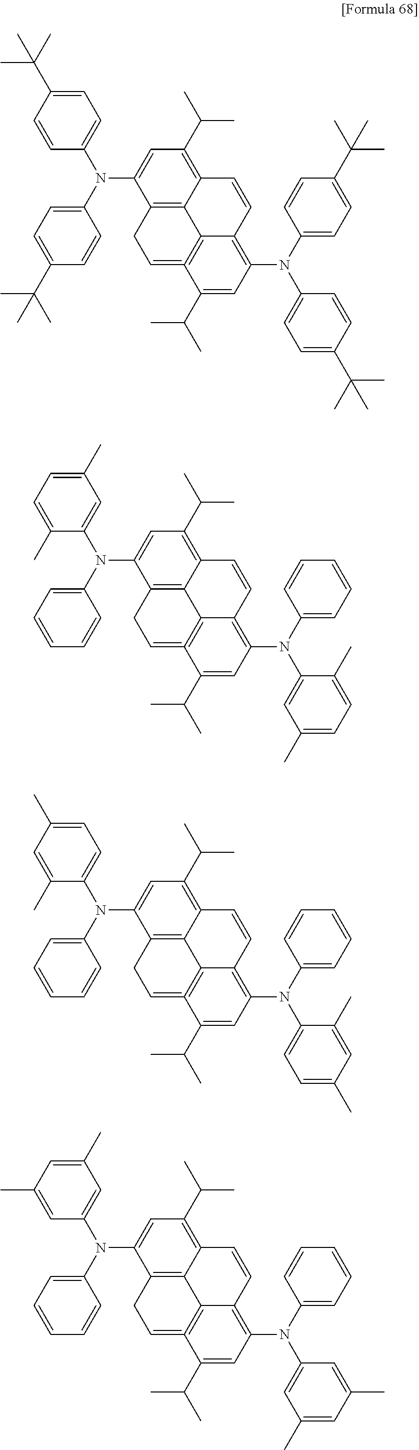

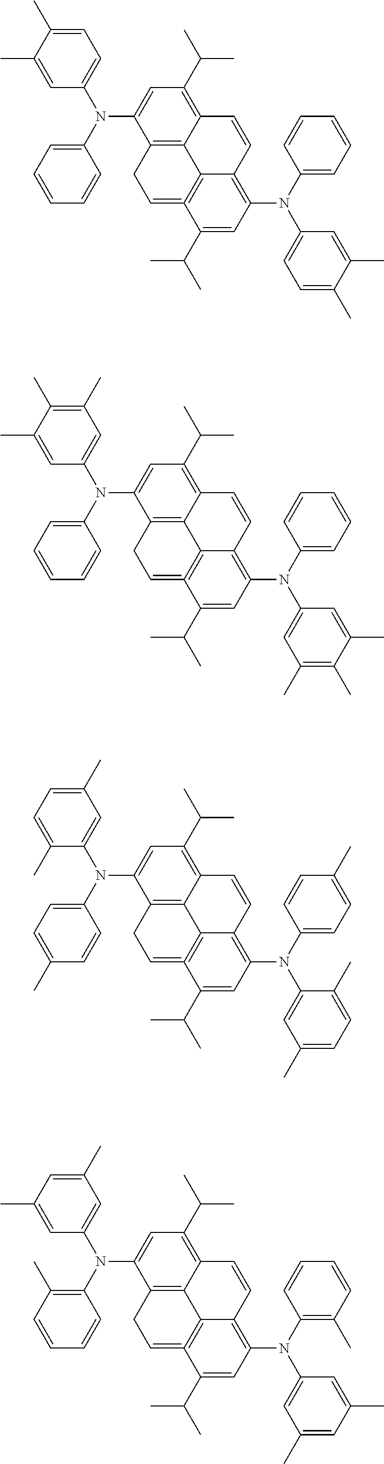

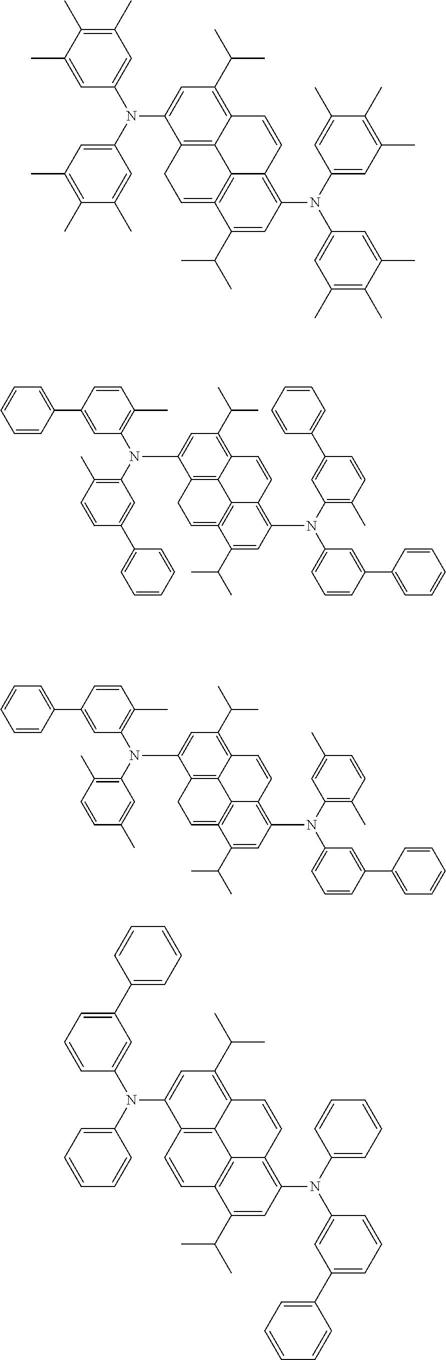

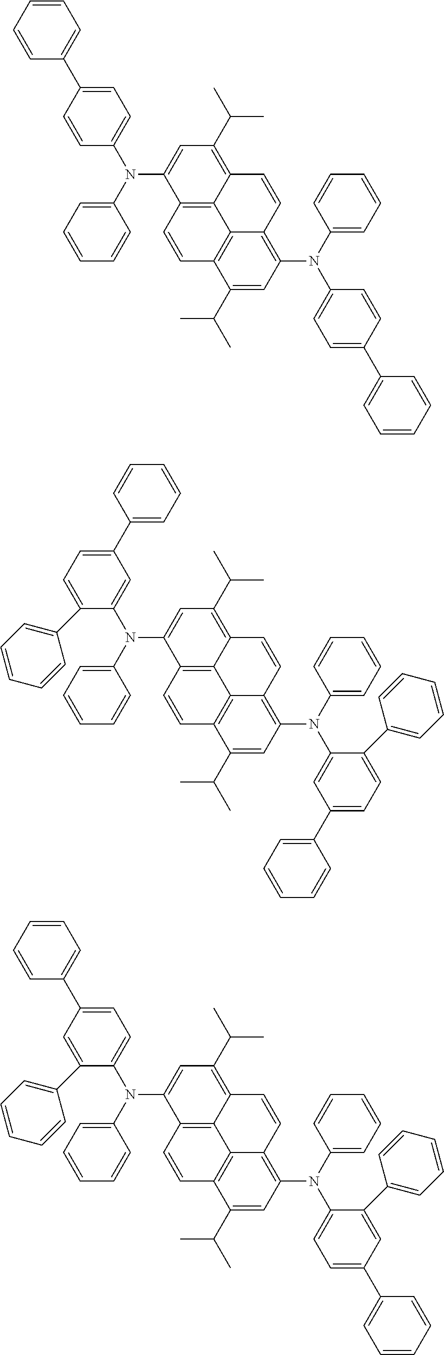 [SMILES: CC(C)c1cc(N(c2ccccc2)c2ccc(-c3ccccc3)cc2)c2ccc3c(C(C)C)cc(N(c4ccccc4)c4ccc(-c5ccccc5)cc4)c4ccc1c2c34 ; CC(C)c1cc(N(c2ccccc2)c2cc(-c3ccccc3)ccc2-c2ccccc2)c2ccc3c(C(C)C)cc(N(c4ccccc4)c4cc(-c5ccccc5)ccc4-c4ccccc4)c4ccc1c2c34 ; CC(C)c1cc(N(c2ccccc2)c2ccc(-c3ccccc3)cc2-c2ccccc2)c2ccc3c(C(C)C)cc(N(c4ccccc4)c4ccc(-c5ccccc5)cc4-c4ccccc4)c4ccc1c2c34]

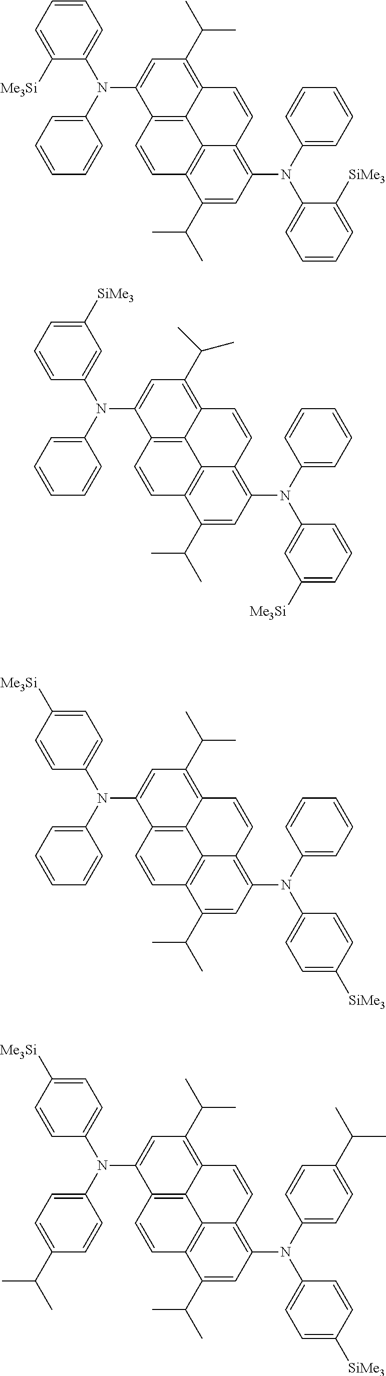 [SMILES: CC(C)c1cc(N(c2ccccc2)c2ccccc2[Si](C)(C)C)c2ccc3c(C(C)C)cc(N(c4ccccc4)c4ccccc4[Si](C)(C)C)c4ccc1c2c34 ; CC(C)c1cc(N(c2ccccc2)c2cccc([Si](C)(C)C)c2)c2ccc3c(C(C)C)cc(N(c4ccccc4)c4cccc([Si](C)(C)C)c4)c4ccc1c2c34 ; CC(C)c1cc(N(c2ccccc2)c2ccc([Si](C)(C)C)cc2)c2ccc3c(C(C)C)cc(N(c4ccccc4)c4ccc([Si](C)(C)C)cc4)c4ccc1c2c34 ; CC(C)c1ccc(N(c2ccc([Si](C)(C)C)cc2)c2cc(C(C)C)c3ccc4c(N(c5ccc(C(C)C)cc5)c5ccc([Si](C)(C)C)cc5)cc(C(C)C)c5ccc2c3c54)cc1]

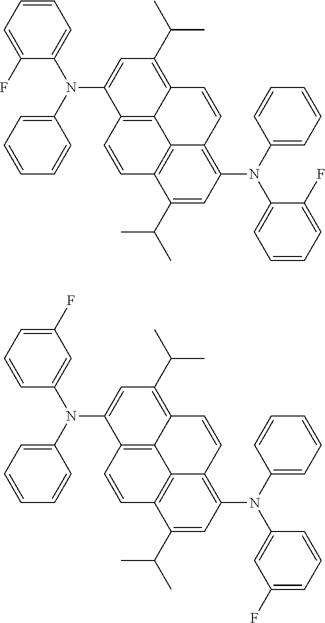 [SMILES: CC(C)c1cc(N(c2ccccc2)c2ccccc2F)c2ccc3c(C(C)C)cc(N(c4ccccc4)c4ccccc4F)c4ccc1c2c34 ; CC(C)c1cc(N(c2ccccc2)c2cccc(F)c2)c2ccc3c(C(C)C)cc(N(c4ccccc4)c4cccc(F)c4)c4ccc1c2c34]

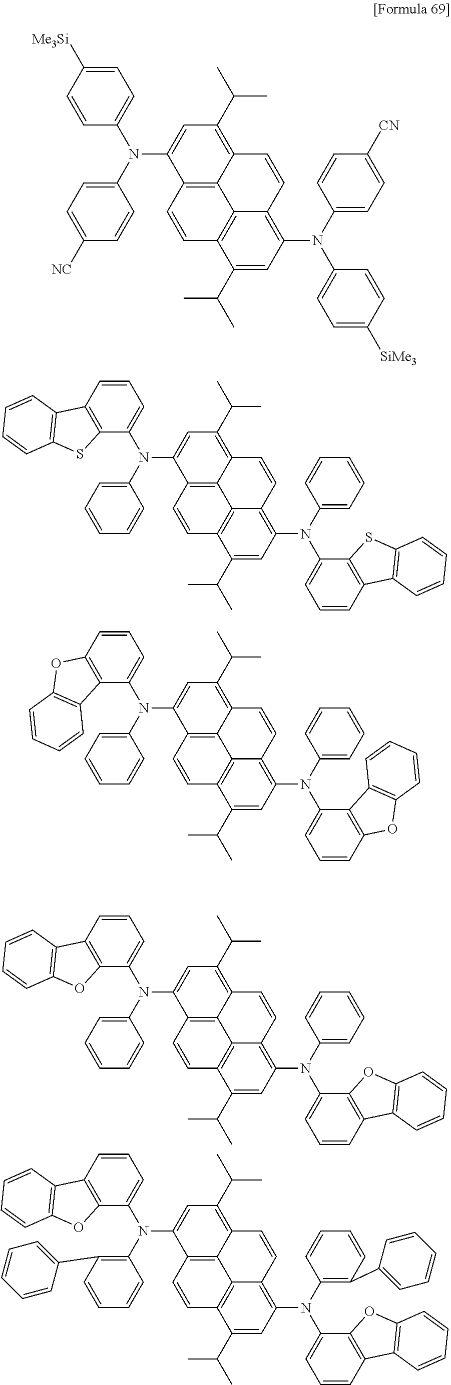

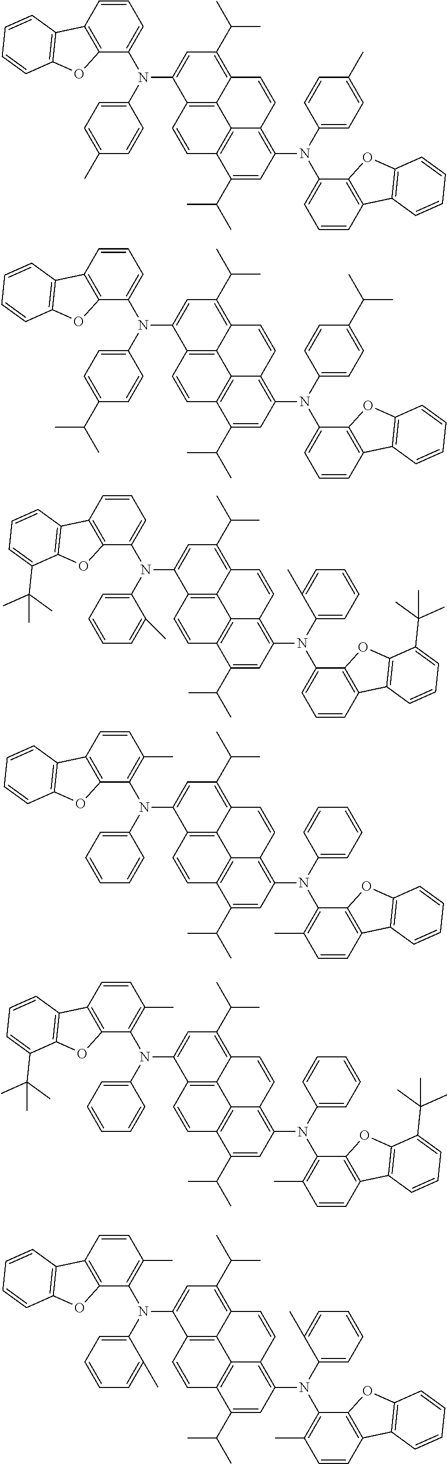

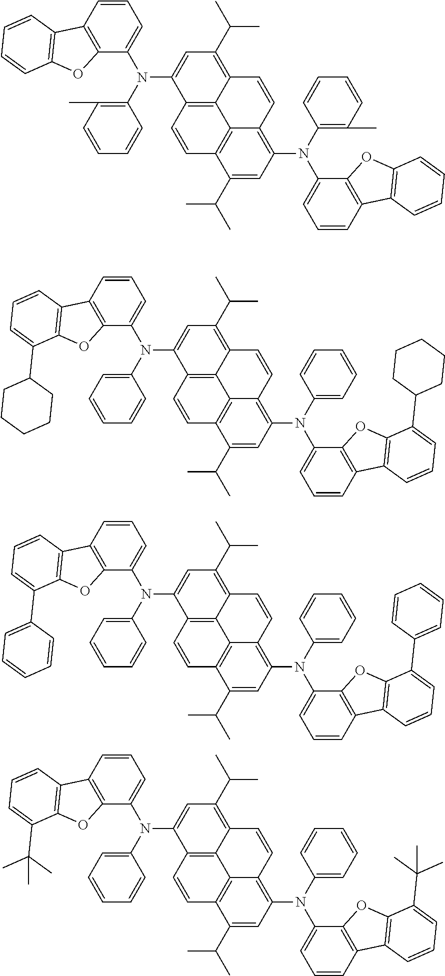

### Compounds Represented by Formula (4)

The following describes the compounds represented by formula (4).

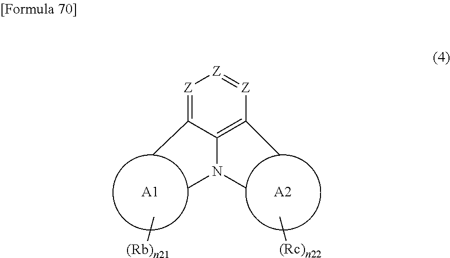

In formula (4),

the Zs each independently represent CRa or a nitrogen atom;

rings A1 and A2 each independently represent: a substituted or unsubstituted aromatic hydrocarbon ring having 6 to 50 ring carbon atoms; or a substituted or unsubstituted heterocycle having 5 to 50 ring atoms;

when multiple Ras are present, at least one combination of adjacent two or more of the multiple Ras are: bonded together to form a substituted or unsubstituted monocyclic ring; bonded together to form a substituted or unsubstituted fused ring; or not bonded together;

n21 and n22 each independently represent 0, 1, 2, 3, or 4;

when multiple Rbs are present, at least one combination of adjacent two or more of the multiple Rbs are: bonded together to form a substituted or unsubstituted monocyclic ring; bonded together to form a substituted or unsubstituted fused ring; or not bonded together;

when multiple Rcs are present, at least one combination of adjacent two or more of the multiple Rcs are: bonded together to form a substituted or unsubstituted monocyclic ring; bonded together to form a substituted or unsubstituted fused ring; or not bonded together; and

Ra, Rb, and Rc not forming the monocyclic ring and not forming the fused ring each independently represent: a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

An “aromatic hydrocarbon ring” as ring A1 or A2 is structurally the same as a compound that is formed when hydrogen atom(s) is introduced into an “aryl group” as described above.

The ring atoms of an “aromatic hydrocarbon ring” as ring A1 or A2 include the two carbon atoms on the two-ring fused structure in the middle of formula (4).

Specific examples of the “substituted or unsubstituted aromatic hydrocarbon ring having 6 to 50 ring carbon atoms” include a compound formed by introducing a hydrogen atom to the “aryl group” described in the specific example group G1.

A “heterocycle” as ring A1 or A2 is structurally the same as a compound that is formed when hydrogen atom(s) is introduced into a “heterocyclic group” as described above.

The ring atoms of a “heterocycle” as ring A1 or A2 include the two carbon atoms on the two-ring fused structure in the middle of formula (4).

Specific examples of the “substituted or unsubstituted heterocycle having 5 to 50 ring atoms” include a compound formed by introducing a hydrogen atom to the “heterocyclic group” described in the specific example group G2.

The Rb(s) is bonded to any of the carbon atoms forming an aromatic hydrocarbon ring as ring A1 or any of the atoms forming a heterocycle as ring A1.

The Rc(s) is bonded to any of the carbon atoms forming an aromatic hydrocarbon ring as ring A2 or any of the atoms forming a heterocycle as ring A2.

Preferably, at least one of Ra, Rb, or Rc is a group represented by formula (4a) below. More preferably, at least two are groups represented by formula (4a) below.

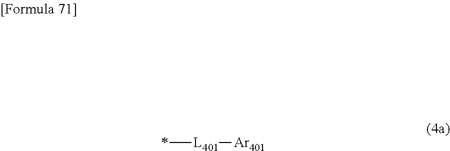

In formula (4a),

L₄₀₁ is: a single bond; a substituted or unsubstituted arylene group having 6 to 30 ring carbon atoms; or a substituted or unsubstituted divalent heterocyclic group having 5 to 30 ring atoms; and

Ar₄₀₁ is: a substituted or unsubstituted aryl group having 6 to 50 ring carbon atoms; a substituted or unsubstituted heterocyclic group having 5 to 50 ring atoms; or a group represented by formula (4b) below.

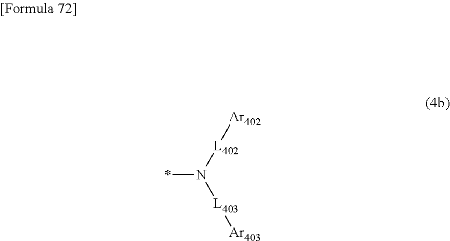

In formula (4b),

L₄₀₂ and L₄₀₃ each independently represent: a single bond; a substituted or unsubstituted arylene group having 6 to 30 ring carbon atoms; or a substituted or unsubstituted divalent heterocyclic group having 5 to 30 ring atoms;

the combination of Ar₄₀₂ and Ar₄₀₃ are: bonded together to form a substituted or unsubstituted monocyclic ring; bonded together to form a substituted or unsubstituted fused ring; or not bonded together; and

Ar₄₀₂ and Ar₄₀₃ not forming the monocyclic ring and not forming the fused ring each independently represent: a substituted or unsubstituted aryl group having 6 to 50 ring carbon atoms; or a substituted or unsubstituted heterocyclic group having 5 to 50 ring atoms.

In an exemplary embodiment, the compounds represented by formula (4) are represented by formula (42) below.

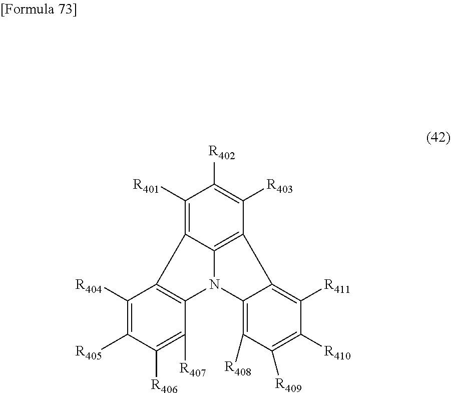

In formula (42),

at least one combination of adjacent two or more of R₄₀₁ to R₄₁₁ are: bonded together to form a substituted or unsubstituted monocyclic ring; bonded together to form a substituted or unsubstituted fused ring; or not bonded together; and

R₄₀₁ to R₄₁₁ not forming the monocyclic ring and not forming the fused ring each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

Preferably, at least one of R₄₀₁ to R₄₁₁ is a group represented by formula (4a). More preferably, at least two are groups represented by formula (4a).

Preferably, R₄₀₄ and R₄₁₁ are groups represented by formula (4a).

In an exemplary embodiment, the compounds represented by formula (4) are compounds that are formed when a structure represented by formula (4-1) or (4-2) below is bonded to their ring A1.

In an exemplary embodiment, furthermore, the compounds represented by formula (42) are compounds that are formed when a structure represented by formula (4-1) or (4-2) below is bonded to their ring to which R₄₀₄ to R₄₀₇ are bonded.

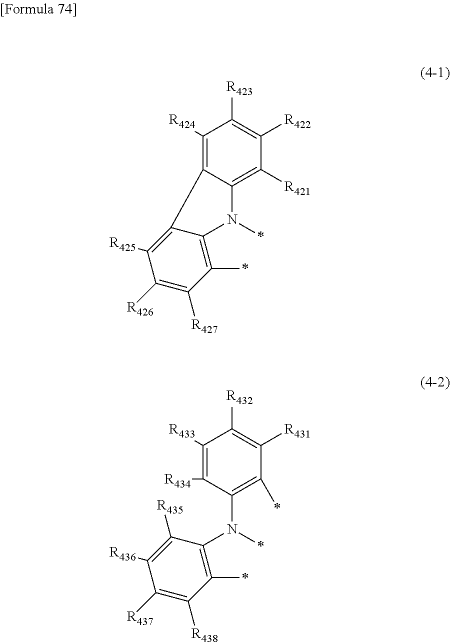

In formula (4-1), the two *s are each independently bonded to a ring carbon atom of an aromatic hydrocarbon ring or a ring atom of a heterocycle as ring A1 in formula (4) or any of R₄₀₄ to R₄₀₇ in formula (42);

the three *s in formula (4-2) are each independently bonded to a ring carbon atom of an aromatic hydrocarbon ring or a ring atom of a heterocycle as ring A1 in formula (4) or any of R₄₀₄ to R₄₀₇ in formula (42); at least one combination of adjacent two or more of R₄₂₁ to R₄₂₇ are: bonded together to form a substituted or unsubstituted monocyclic ring; bonded together to form a substituted or unsubstituted fused ring; or not bonded together;

at least one combination of adjacent two or more of R₄₃₁ to R₄₃₈ are: bonded together to form a substituted or unsubstituted monocyclic ring; bonded together to form a substituted or unsubstituted fused ring; or not bonded together; and

R₄₂₁ to R₄₂₇ and R₄₃₁ to R₄₃₈ not forming the monocyclic ring and not forming the fused ring each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

In an exemplary embodiment, the compounds represented by formula (4) are compounds represented by formula (41-3), (41-4), or (41-5) below.

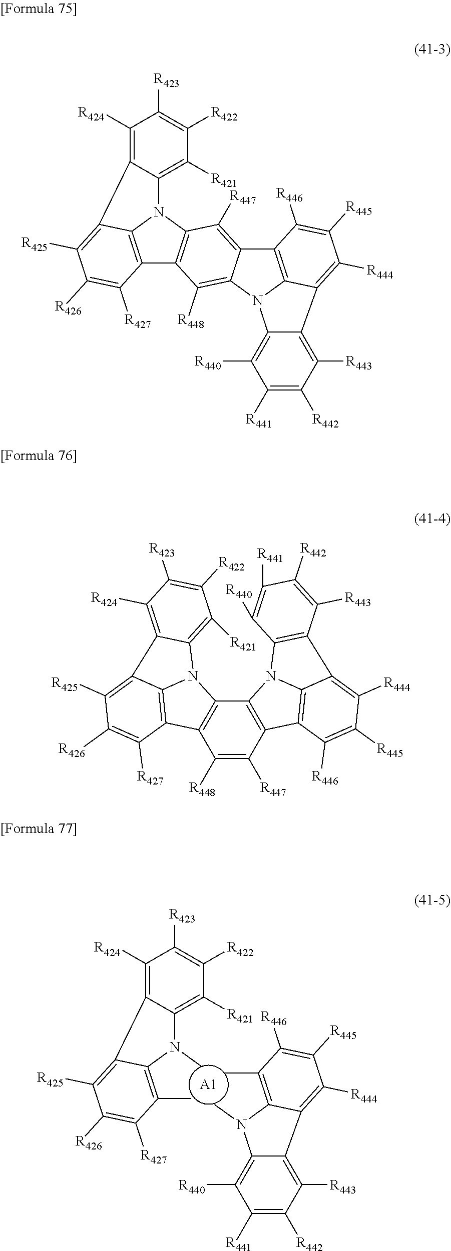

In formulae (41-3), (41-4), and (41-5), ring A1 is as defined in formula (4);

R₄₂₁ to R₄₂₇ each independently represent the same as R₄₂₁ to R₄₂₇ in formula (4-1); and

R₄₄₀ to R₄₄₈ each independently represent the same as R₄₀₁ to R₄₁₁ in formula (42).

In an exemplary embodiment, a substituted or unsubstituted aromatic hydrocarbon ring having 6 to 50 ring carbon atoms as ring A1 in formula (41-5) is: a substituted or unsubstituted naphthalene ring; or a substituted or unsubstituted fluorene ring.

In an exemplary embodiment, a substituted or unsubstituted heterocycle having 5 to 50 ring atoms as ring A1 in formula (41-5) is: a substituted or unsubstituted dibenzofuran ring; a substituted or unsubstituted carbazole ring; or a substituted or unsubstituted dibenzothiophene ring.

In an exemplary embodiment, the compounds represented by formula (4) or (42) are selected from the group consisting of the compounds represented by formulae (461) to (467) below.

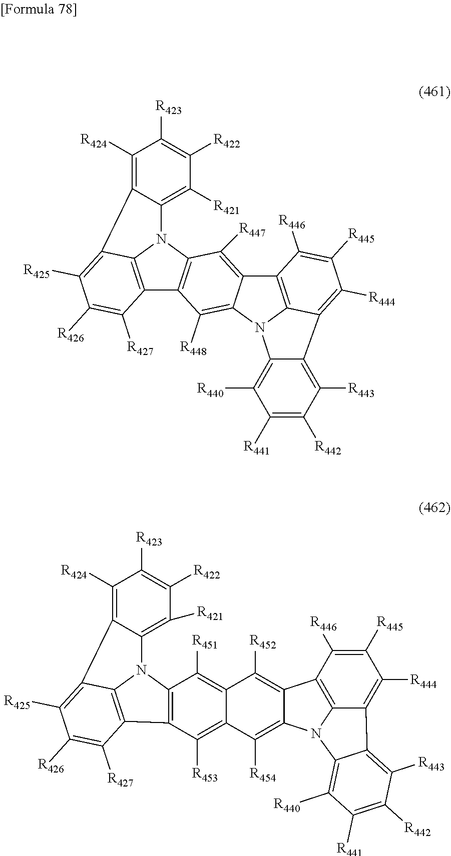

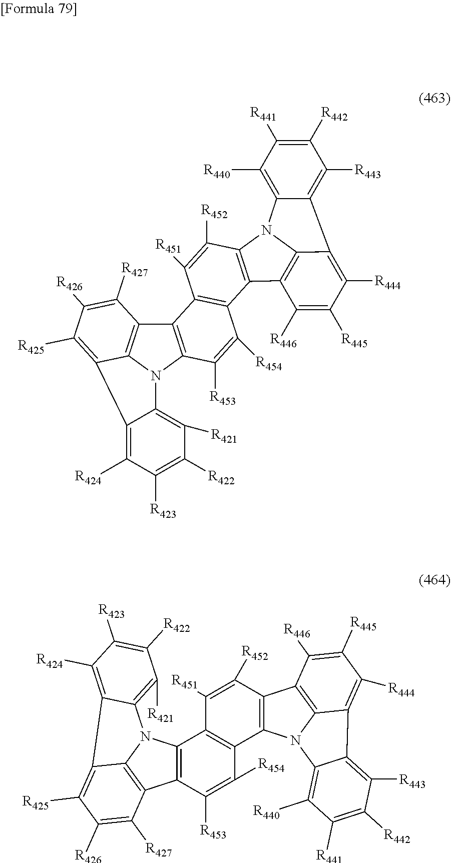

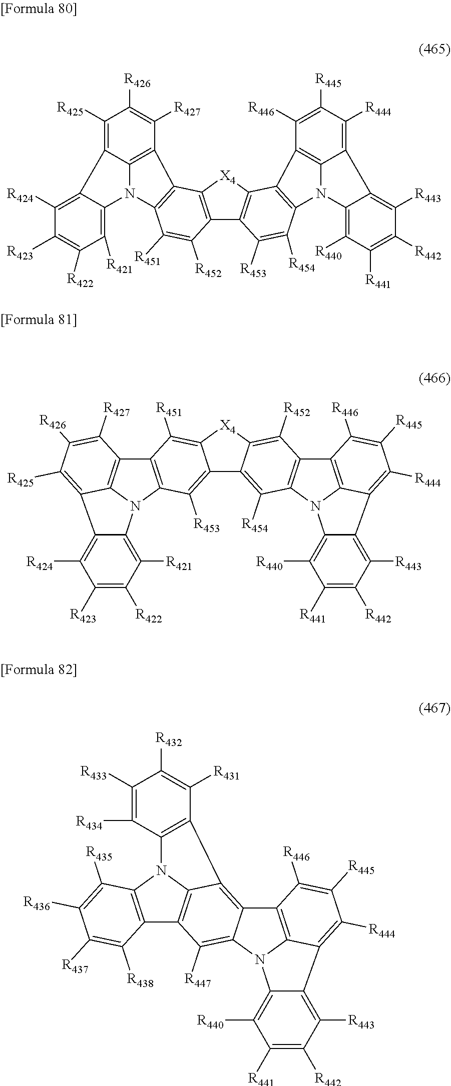

In formulae (461), (462), (463), (464), (465), (466), and (467), R₄₂₁ to R₄₂₇ each independently represent the same as R₄₂₁ to R₄₂₇ in formula (4-1);

R₄₃₁ to R₄₃₈ each independently represent the same as R₄₃₁ to R₄₃₈ in formula (4-2);

R₄₄₀ to R₄₄₈ and R₄₅₁ to R₄₅₄ each independently represent the same as R₄₀₁ to R₄₁₁ in formula (42);

X₄ is an oxygen atom, NR₈₀₁, or C(R₈₀₂)(R₈₀₃);

R₈₀₁, R₈₀₂, and R₈₀₃ each independently represent: a hydrogen atom; a substituted or unsubstituted alkyl group having 1 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms; a substituted or unsubstituted alkyl group having 1 to 50 carbon atoms; or a substituted or unsubstituted aryl group having 6 to 50 ring carbon atoms;

when multiple R₈₀₁s are present, the multiple R₈₀₁s are mutually the same or different;

when multiple R₈₀₂s are present, the multiple R₈₀₂s are mutually the same or different; and

when multiple R₈₀₃s are present, the multiple R₈₀₃s are mutually the same or different.

In an exemplary embodiment, at least one combination of adjacent two or more of R₄₀₁ to R₄₁₁ in a compound represented by formula (42) are bonded together to form a substituted or unsubstituted monocyclic ring or bonded together to form a substituted or unsubstituted fused ring. The following describes this exemplary embodiment in detail, with such compounds defined as compounds represented by formula (45).

### Compounds Represented by Formula (45)

The following describes the compounds represented by formula (45).

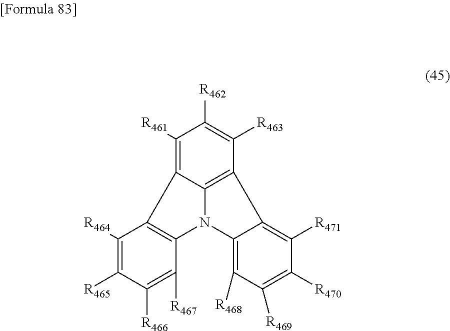

In formula (45),

two or more of combinations selected from the group consisting of a combination of R₄₆₁ and R₄₆₂, a combination of R₄₆₂ and R₄₆₃, a combination of R₄₆₄ and R₄₆₅, a combination of R₄₆₅ and R₄₆₆, a combination of R₄₆₆ and R₄₆₇, a combination of R₄₆₈ and R₄₆₉, a combination of R₄₆₉ and R₄₇₀, and a combination of R₄₇₀ and R₄₇₁ are mutually bonded to form a substituted or unsubstituted monocyclic ring or a substituted or unsubstituted fused ring.

However, the combination of R₄₆₁ and R₄₆₂ and the combination of R₄₆₂ and R₄₆₃; the combination of R₄₆₄ and R₄₆₅ and the combination of R₄₆₅ and R₄₆₆; the combination of R₄₆₅ and R₄₆₆ and the combination of R₄₆₆ and R₄₆₇; the combination of R₄₆₈ and R₄₆₉ and the combination of R₄₆₉ and R₄₇₀; and the combination of R₄₆₉ and R₄₇₀ and the combination of R₄₇₀ and R₄₇₁ do not form a ring at the same time.

At least two rings formed by R₄₆₁ to R₄₇₁ are mutually the same or different.

R₄₆₁ to R₄₇₁ not forming the monocyclic ring and not forming the fused ring each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

In formula (45), Rₙ and Rₙ₊₁ (where n indicates an integer selected from 461, 462, 464 to 466, and 468 to 470) are bonded together to form a substituted or unsubstituted monocyclic ring or substituted or unsubstituted fused ring in conjunction with the two ring carbon atoms to which Rₙ and Rₙ₊₁ are bonded. Preferably, the ring is formed by atoms selected from the group consisting of carbon, oxygen, sulfur, and nitrogen atoms. Preferably, the number of atoms in the ring is between 3 and 7, more preferably 5 or 6.

The number of such cyclic structures in a compound represented by formula (45) is, for example, two, three, or four. Each of the two or more cyclic structures may be present on the same benzene ring on the base skeleton in formula (45) or may be present on different benzene rings. For example, if the compound has three cyclic structures, each of the three benzene rings in formula (45) may have one of them.

Examples of such cyclic structures in a compound represented by formula (45) include, for instance, the structures represented by formulae (451) to (460) below.

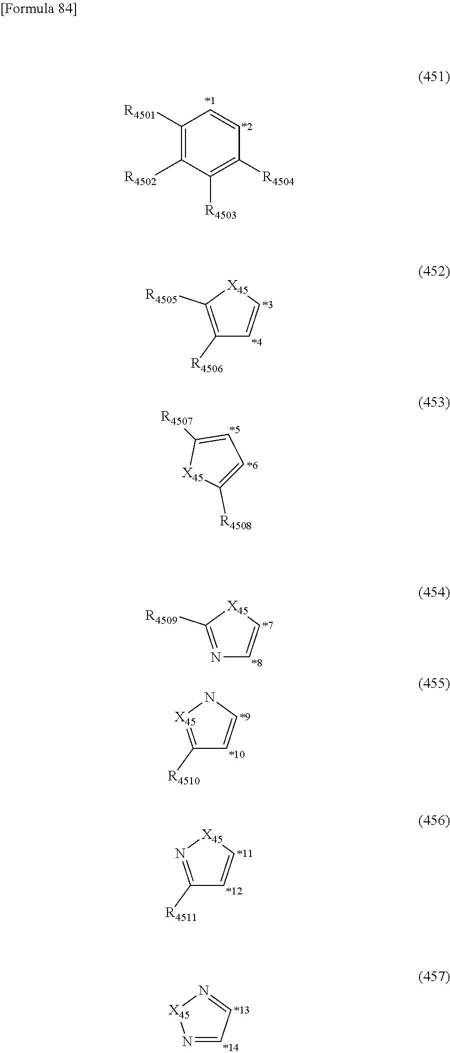

In formulae (451) to (457),

each of the pairs *1 and *2, *3 and *4, *5 and *6, *7 and *8, *9 and *10, *11 and *12, and *13 and *14 represents the aforementioned two ring carbon atoms to which Rₙ and Rₙ+1 are bonded;

the ring carbon atom to which Rₙ is bonded can be either of the two represented by *1 and *2, *3 and *4, *5 and *6, *7 and *8, *9 and *10, *11 and *12, or *13 and *14;

X₄₅ is C(R₄₅₁₂)(R₄₅₁₃), NR₄₅₁₄, an oxygen atom, or a sulfur atom;

at least one combination of adjacent two or more of R₄₅₀₁ to R₄₅₀₆ and R₄₅₁₂ to R₄₅₁₃ are: bonded together to form a substituted or unsubstituted monocyclic ring; bonded together to form a substituted or unsubstituted fused ring; or not bonded together; and

R₄₅₀₁ to R₄₅₁₄ not forming the monocyclic ring and not forming the fused ring each independently represent the same as R₄₆₁ to R₄₇₁ in formula (45).

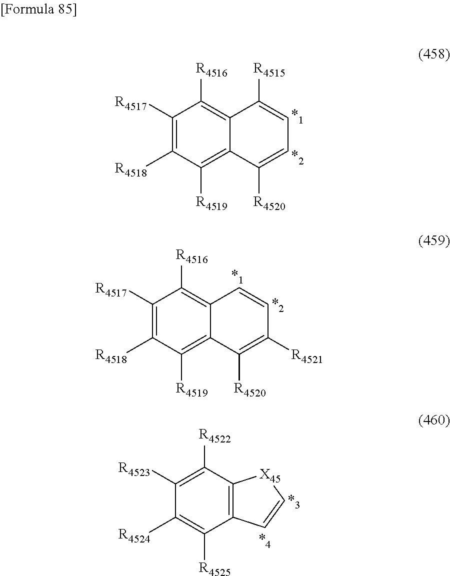

In formulae (458) to (460),

each of the pairs *1 and *2 and *3 and *4 represents the aforementioned two ring carbon atoms to which Rₙ and Rₙ₊₁ are bonded;

the ring carbon atom to which Rₙ is bonded can be either of the two represented by *1 and *2 or *3 and *4;

X₄₅ is C(R₄₅₁₂)(R₄₅₁₃), NR₄₅₁₄, an oxygen atom, or a sulfur atom;

at least one combination of adjacent two or more of R₄₅₁₂ to R₄₅₁₃ and R₄₅₁₅ to R₄₅₂₅ are: bonded together to form a substituted or unsubstituted monocyclic ring; bonded together to form a substituted or unsubstituted fused ring; or not bonded together; and

R₄₅₁₂ to R₄₅₁₃, R₄₅₁₅ to R₄₅₂₁, and R₄₅₂₂ to R₄₅₂₅ not forming the monocyclic ring and not forming the fused ring and R₄₅₁₄ each independently represent the same as R₄₆₁ to R₄₇₁ in formula (45).

In formula (45), it is preferred that at least one of R₄₆₂, R₄₆₄, R₄₆₅, R₄₇₀, or R₄₇₁ (preferably at least one of R₄₆₂, R₄₆₅, or R₄₇₀, more preferably R₄₆₂) be a group not forming the cyclic structure.

Preferably, (i) the substituent(s) in any substituted ring structure(s) formed by Rₙ and Rₙ₊₁ in formula (45); (ii) R₄₆₁ to R₄₇₁ not forming the cyclic structure in formula (45); and (iii) R₄₅₀₁ to R₄₅₁₄ and R₄₅₁₅ to R₄₅₂₅ in formulae (451) to (460) each independently represent any of: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —N(R₉₀₆)(R₉₀₇); a substituted or unsubstituted aryl group having 6 to 50 ring carbon atoms; a substituted or unsubstituted heterocyclic group having 5 to 50 ring atoms; or a group selected from the group consisting of the groups represented by formulae (461) to (464) below.

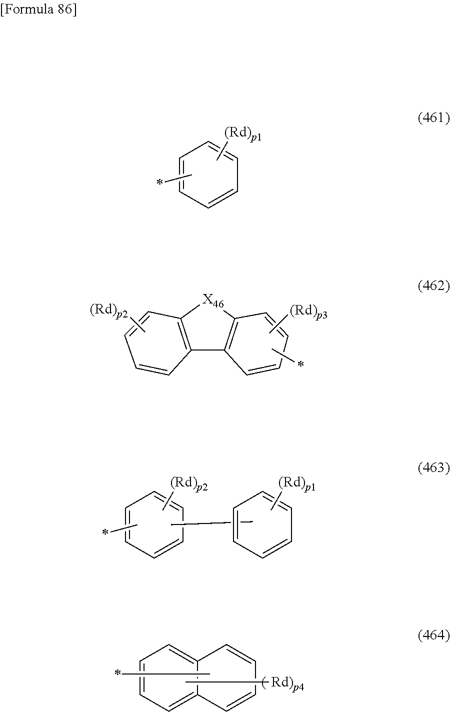

In formulae (461) to (464),

the R_{d}s each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms;

X₄₆ is C(R₈₀₁)(R₈₀₂), NR₈₀₃, an oxygen atom, or a sulfur atom;

R₈₀₁, R₈₀₂, and R₈₀₃ each independently represent: a hydrogen atom; a substituted or unsubstituted alkyl group having 1 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms; a substituted or unsubstituted alkyl group having 1 to 50 carbon atoms; or a substituted or unsubstituted aryl group having 6 to 50 ring carbon atoms;

when multiple R₈₀₁s are present, the multiple R₈₀₁s are mutually the same or different;

when multiple R₈₀₂s are present, the multiple R₈₀₂s are mutually the same or different;

when multiple R₈₀₃s are present, the multiple R₈₀₃s are mutually the same or different;

p1 is 5;

p2 is 4;

p3 is 3;

p4 is 7; and

the *s in formulae (461) to (464) each independently indicate a position of bonding with the cyclic structure.

In the second compound, R₉₀₁ to R₉₀₇ are as defined above.

In an exemplary embodiment, the compounds represented by formula (45) are represented by any of formulae (45-1) to (45-6) below.

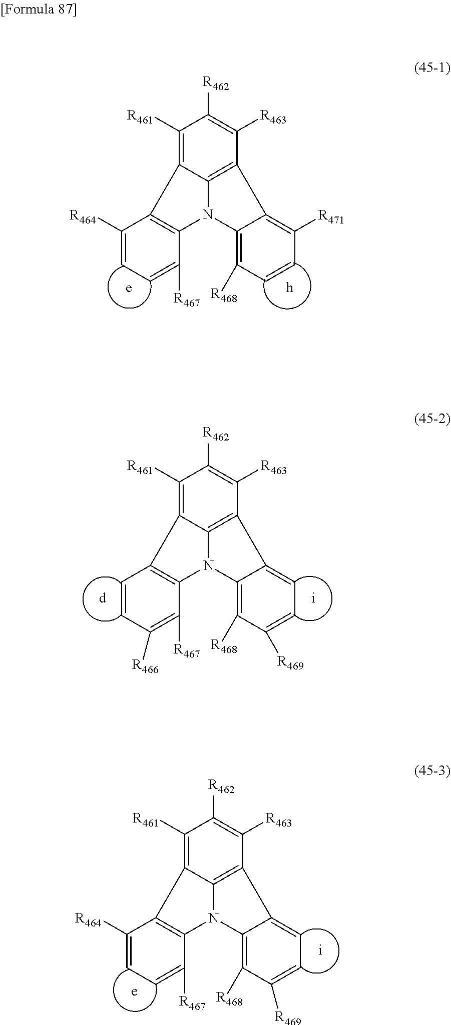

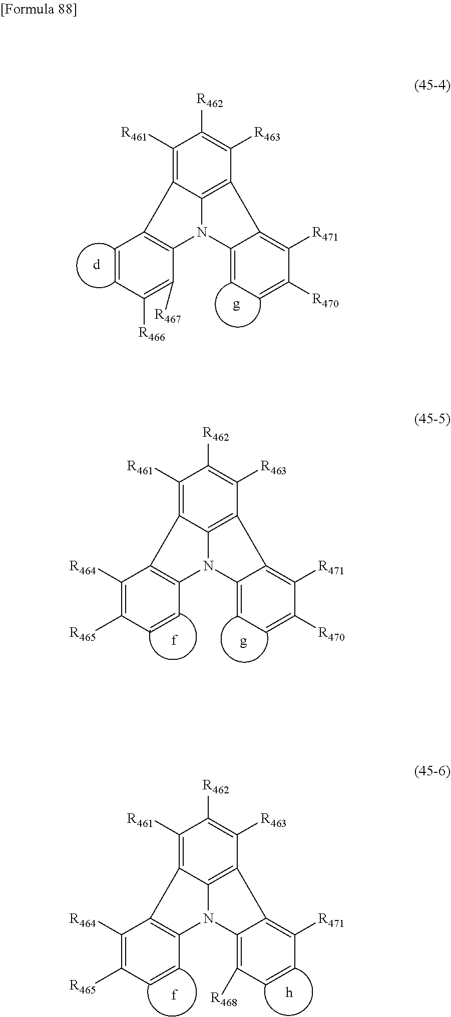

In formulae (45-1) to (45-6),

rings d to i each independently represent a substituted or unsubstituted monocyclic ring or substituted or unsubstituted fused ring; and

R₄₆₁ to R₄₇₁ each independently represent the same as R₄₆₁ to R₄₇₁ in formula (45).

In an exemplary embodiment, the compounds represented by formula (45) are represented by any of formulae (45-7) to (45-12) below.

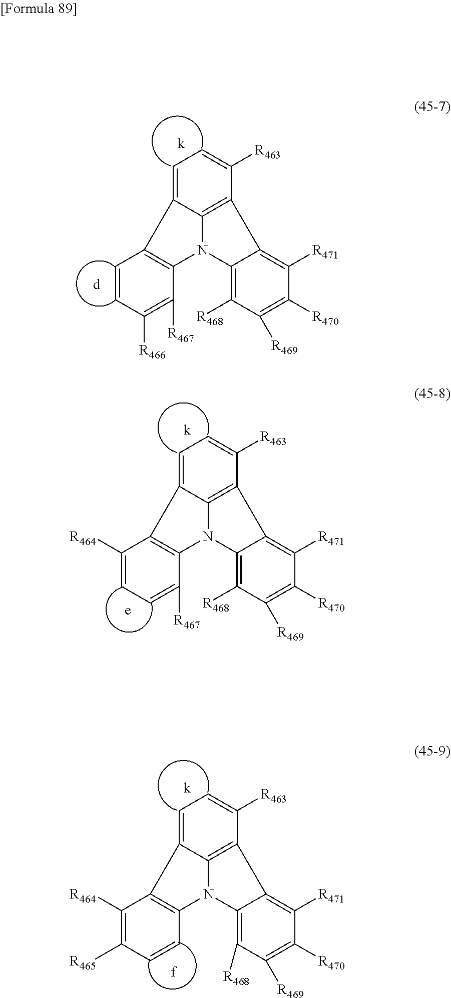

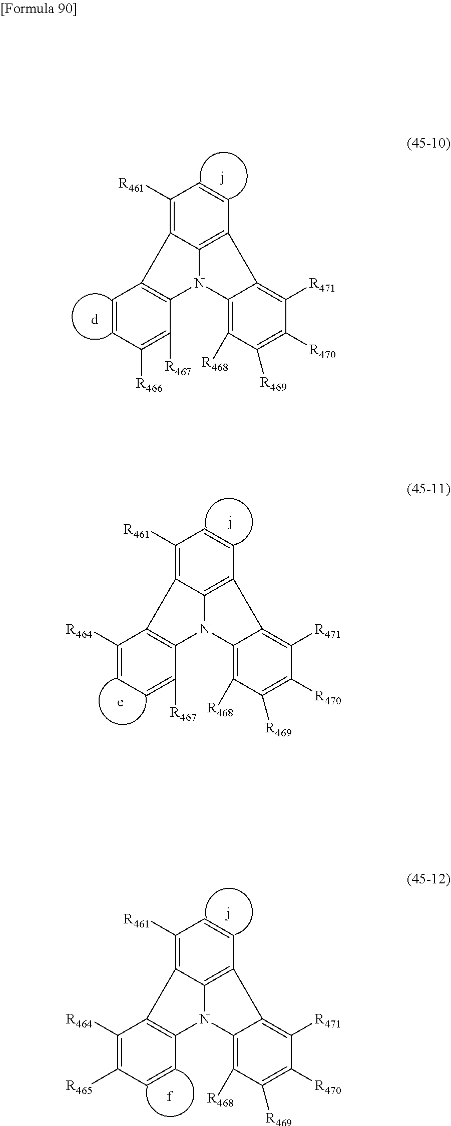

In formulae (45-7) to (45-12),

rings d to f, k, and j each independently represent a substituted or unsubstituted monocyclic ring or substituted or unsubstituted fused ring; and

R₄₆₁ to R₄₇₁ each independently represent the same as R₄₆₁ to R₄₇₁ in formula (45).

In an exemplary embodiment, the compounds represented by formula (45) are represented by any of formulae (45-13) to (45-21) below.

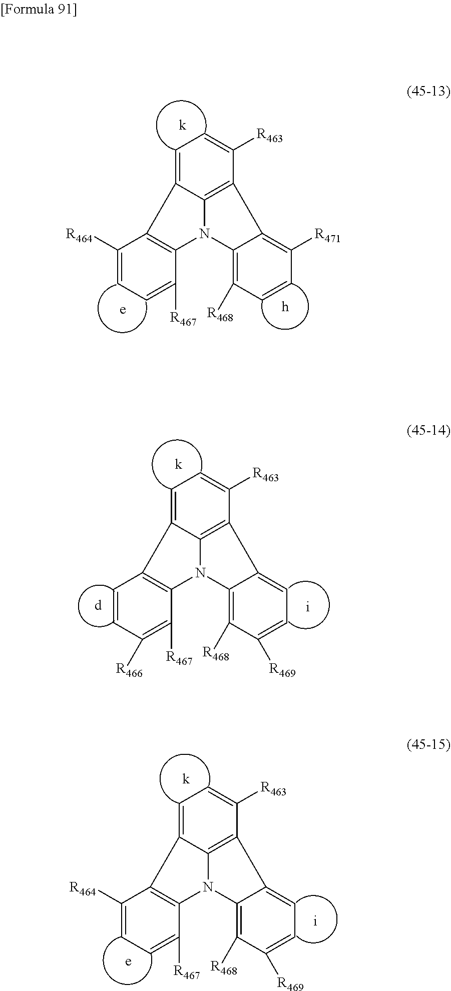

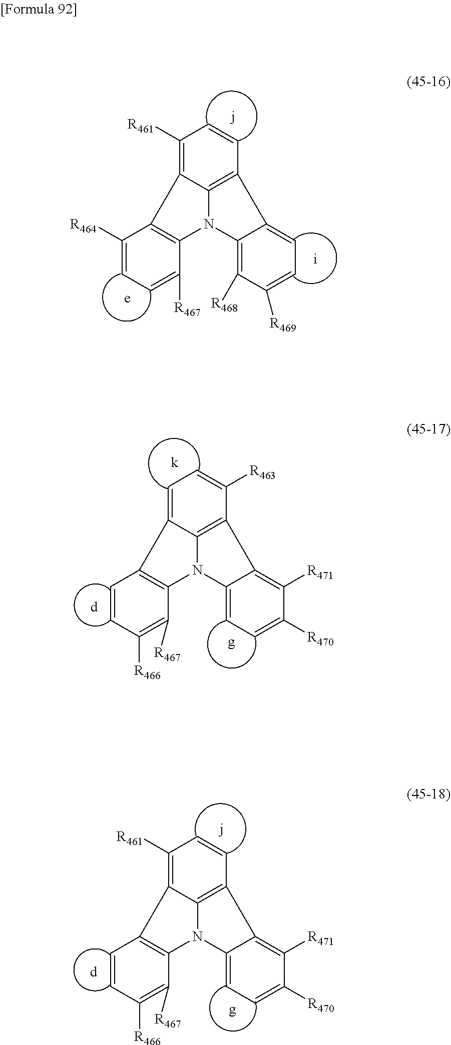

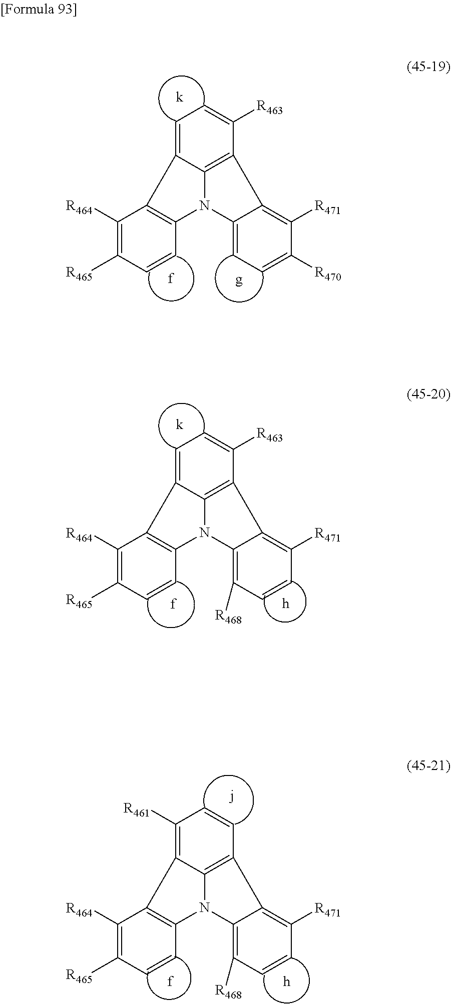

In formulae (45-13) to (45-21),

rings d to k each independently represent a substituted or unsubstituted monocyclic ring or substituted or unsubstituted fused ring; and

R₄₆₁ to R₄₇₁ each independently represent the same as R₄₆₁ to R₄₇₁ in formula (45).

Examples of substituents if ring g or h has substituent(s) include: a substituted or unsubstituted alkyl group having 1 to 50 carbon atoms; a substituted or unsubstituted aryl group having 6 to 50 ring carbon atoms; a group represented by formula (461); a group represented by formula (463); and a group represented by formula (464).

In an exemplary embodiment, the compounds represented by formula (45) are represented by any of formulae (45-22) to (45-25).

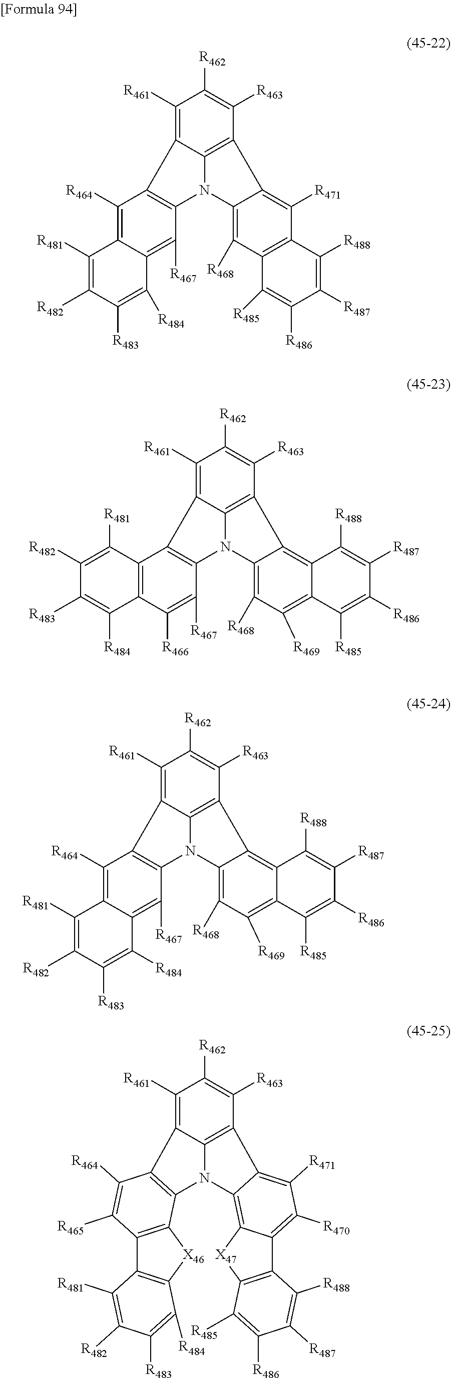

In formulae (45-22) to (45-25),

X₄₆ and X₄₇ each independently represent C(R₈₀₁)(R₈₀₂), NR₈₀₃, an oxygen atom, or a sulfur atom; and

R₄₆₁ to R₄₇₁ and R₄₈₁ to R₄₈₈ each independently represent the same as R₄₆₁ to R₄₇₁ in formula (45).

R₈₀₁, R₈₀₂, and R₈₀₃ each independently represent: a hydrogen atom; a substituted or unsubstituted alkyl group having 1 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms; a substituted or unsubstituted alkyl group having 1 to 50 carbon atoms; or a substituted or unsubstituted aryl group having 6 to 50 ring carbon atoms;

when multiple R₈₀₁s are present, the multiple R₈₀₁s are mutually the same or different;

when multiple R₈₀₂s are present, the multiple R₈₀₂s are mutually the same or different; and

when multiple R₈₀₃s are present, the multiple R₈₀₃s are mutually the same or different.

In an exemplary embodiment, the compounds represented by formula (45) are represented by formula (45-26) below.

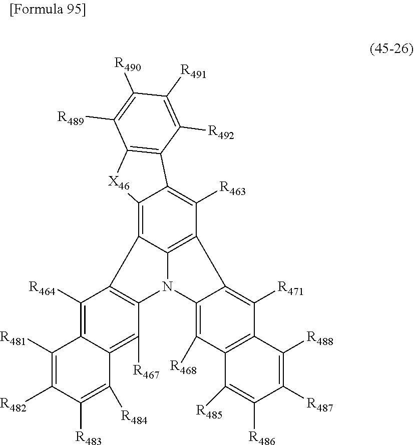

In formula (45-26),

X₄₆ is C(R₈₀₁)(R₈₀₂), NR₈₀₃, an oxygen atom, or a sulfur atom; and

R₄₆₃, R₄₆₄, R₄₆₇, R₄₆₈, R₄₇₁, and R₄₈₁ to R₄₉₂ each independently represent the same as R₄₆₁ to R₄₇₁ in formula (45).

R₈₀₁, R₈₀₂, and R₈₀₃ each independently represent: a hydrogen atom; a substituted or unsubstituted alkyl group having 1 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms; a substituted or unsubstituted alkyl group having 1 to 50 carbon atoms; or a substituted or unsubstituted aryl group having 6 to 50 ring carbon atoms;

when multiple R₈₀₁s are present, the multiple R₈₀₁s are mutually the same or different;

when multiple R₈₀₂s are present, the multiple R₈₀₂s are mutually the same or different; and

when multiple R₈₀₃s are present, the multiple R₈₀₃s are mutually the same or different.

Specific examples of compounds represented by formula (4) include, for instance, the following compounds. In these specific examples, Ph denotes a phenyl group, and D denotes a deuterium atom.

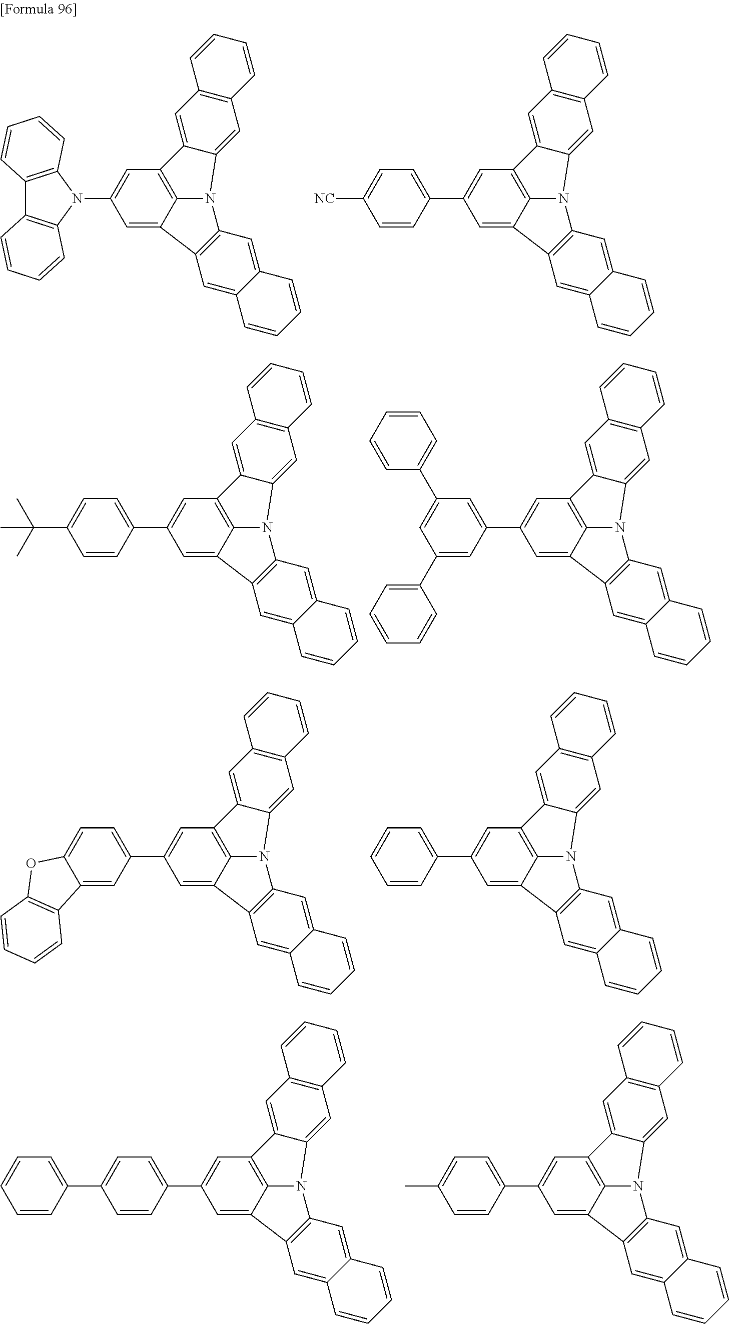

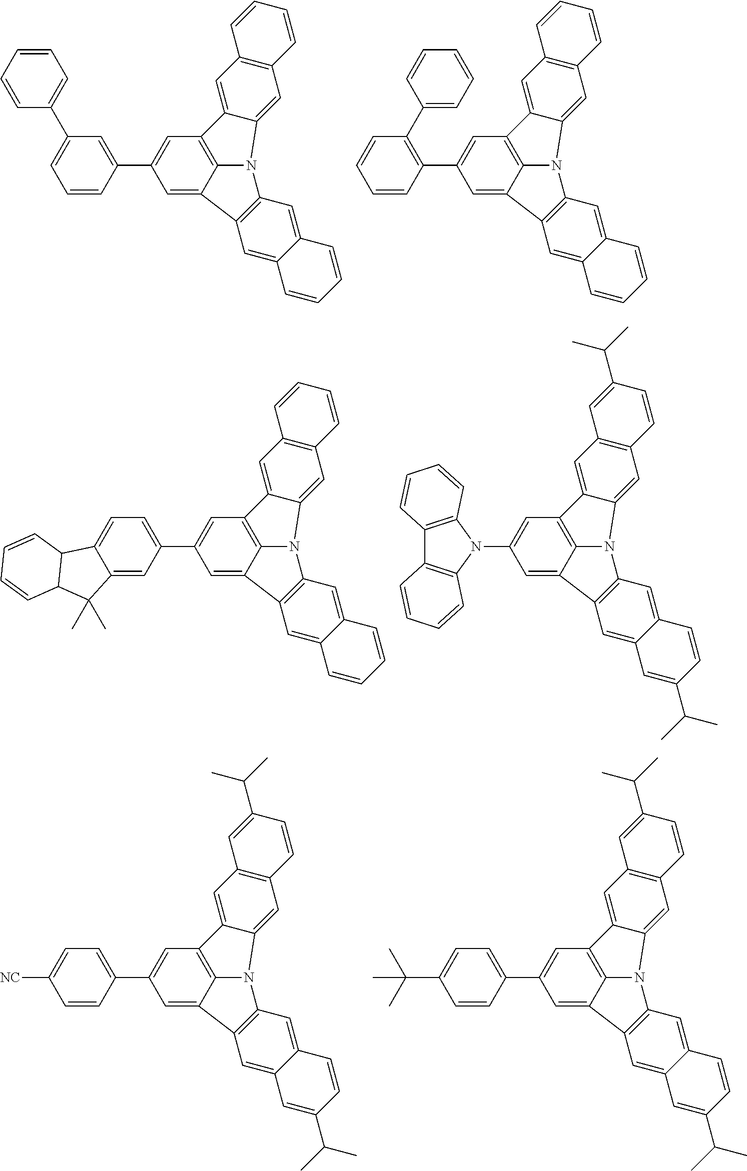

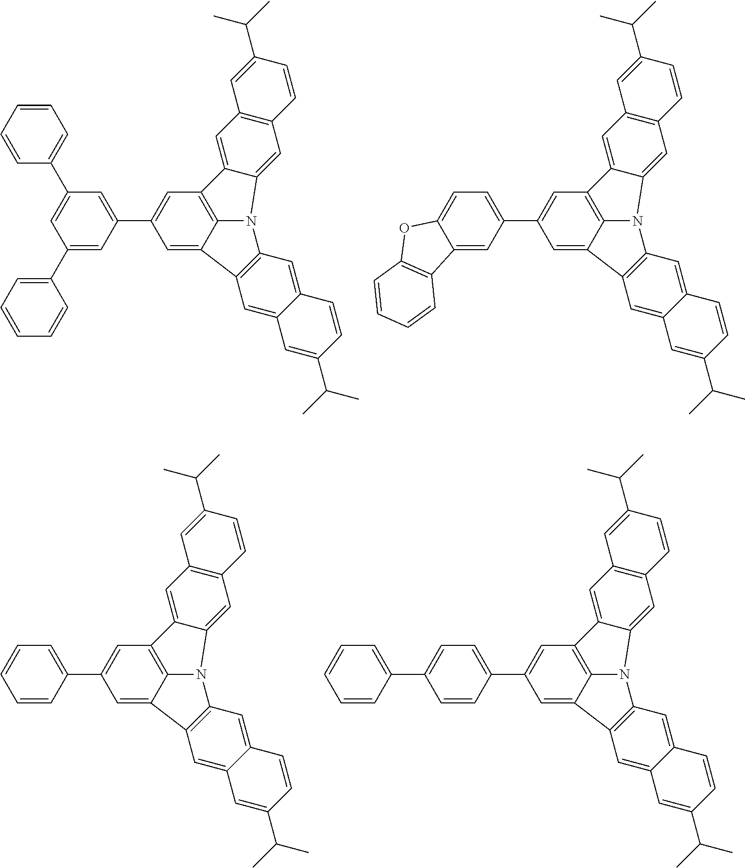

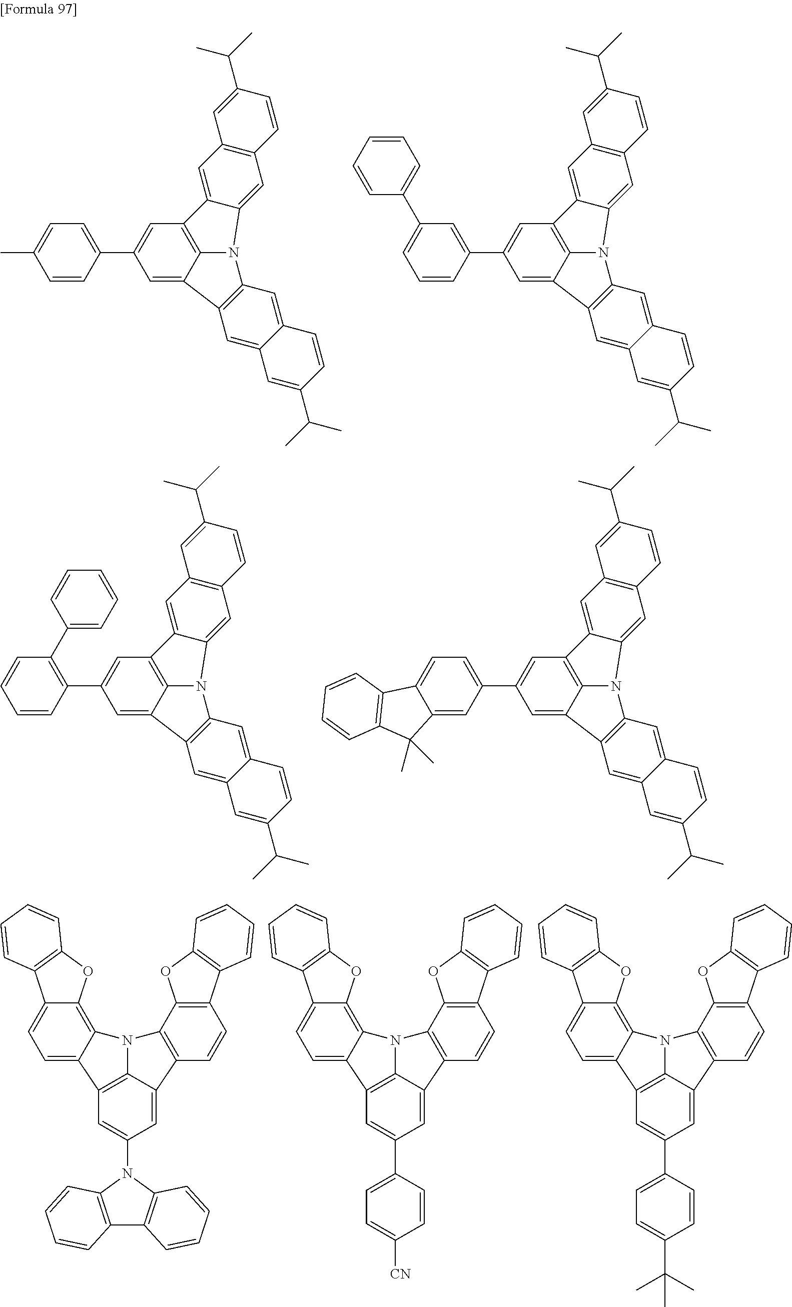

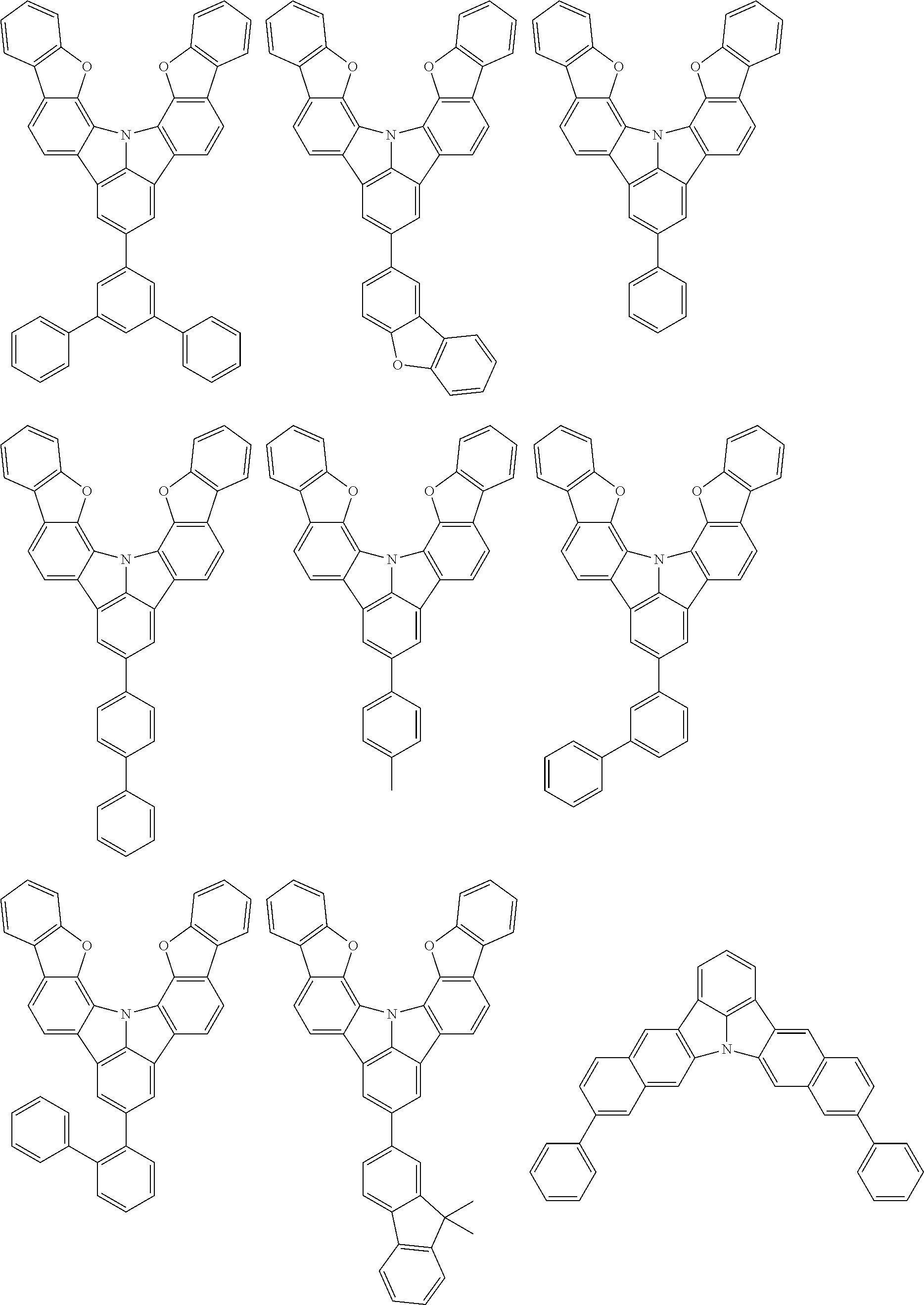

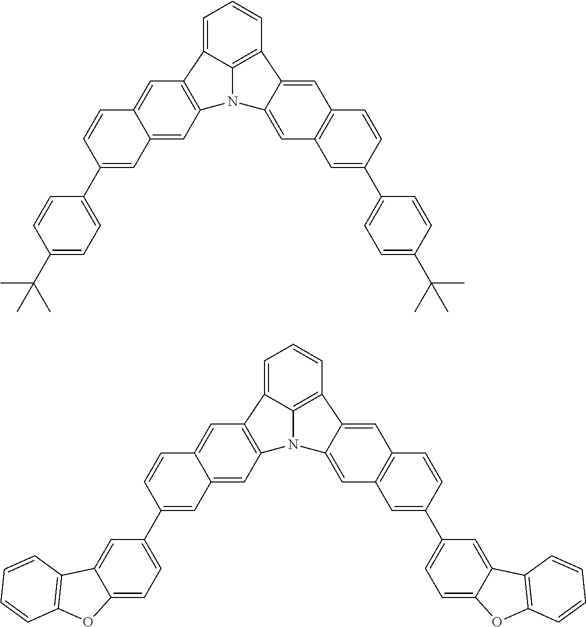 [SMILES: CC(C)(C)c1ccc(-c2ccc3cc4c5cccc6c7cc8ccc(-c9ccc(C(C)(C)C)cc9)cc8cc7n(c4cc3c2)c56)cc1 ; c1ccc2c(c1)oc1ccc(-c3ccc4cc5c6cccc7c8cc9ccc(-c%10ccc%11oc%12ccccc%12c%11c%10)cc9cc8n(c5cc4c3)c67)cc12]

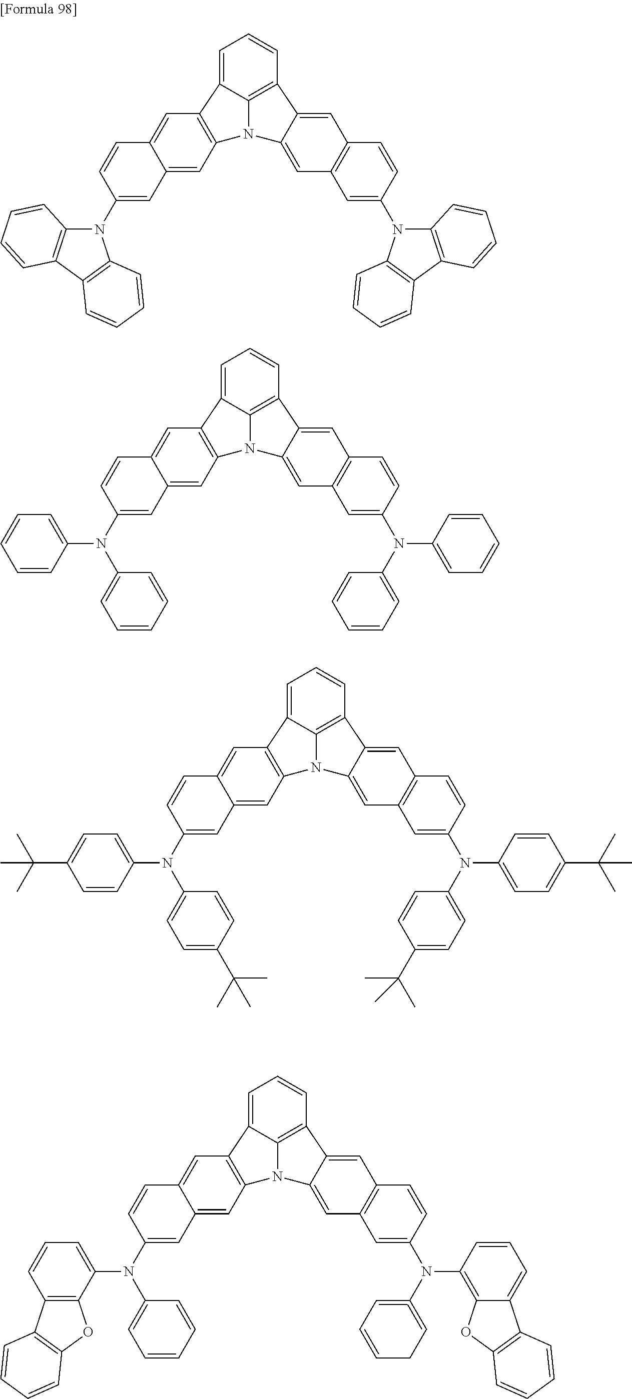

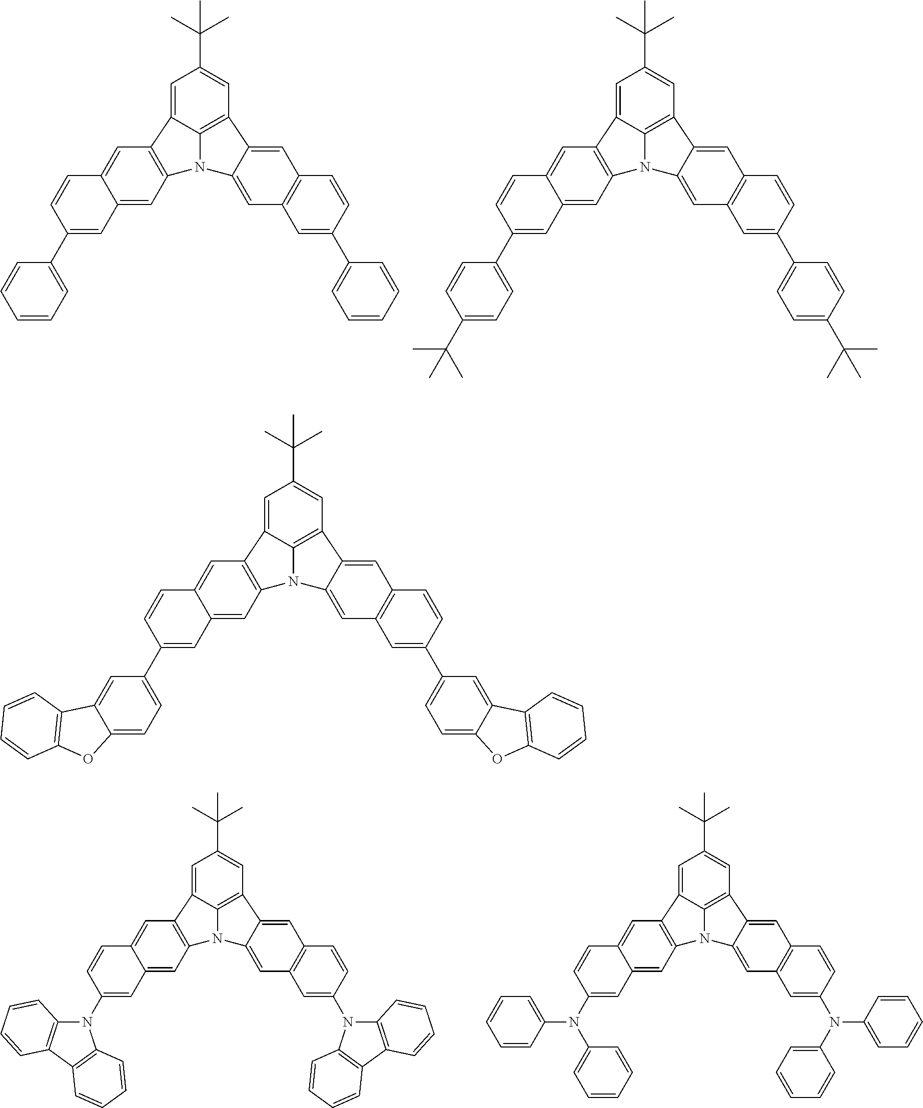

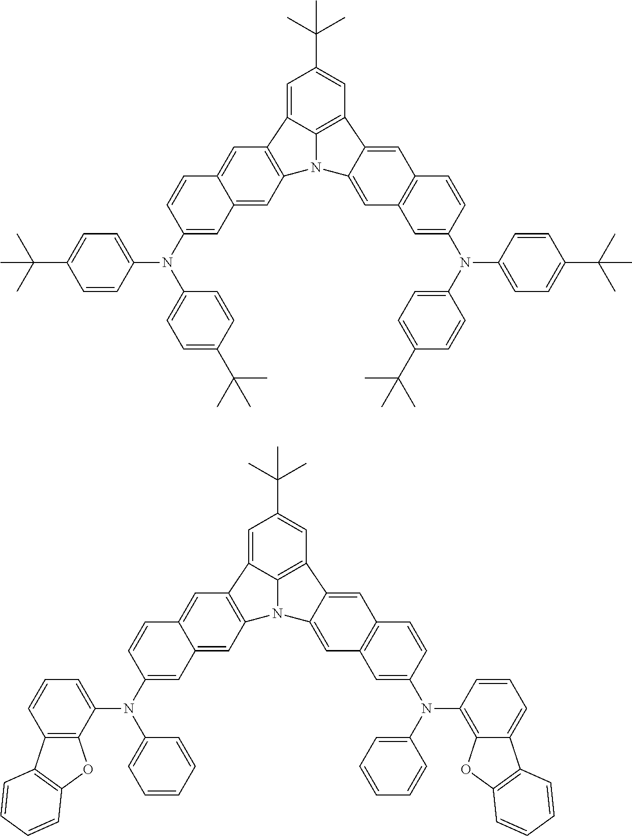 [SMILES: CC(C)(C)c1ccc(N(c2ccc(C(C)(C)C)cc2)c2ccc3cc4c5cc(C(C)(C)C)cc6c7cc8ccc(N(c9ccc(C(C)(C)C)cc9)c9ccc(C(C)(C)C)cc9)cc8cc7n(c4cc3c2)c56)cc1 ; CC(C)(C)c1cc2c3cc4ccc(N(c5ccccc5)c5cccc6c5oc5ccccc56)cc4cc3n3c4cc5cc(N(c6ccccc6)c6cccc7c6oc6ccccc67)ccc5cc4c(c1)c23]

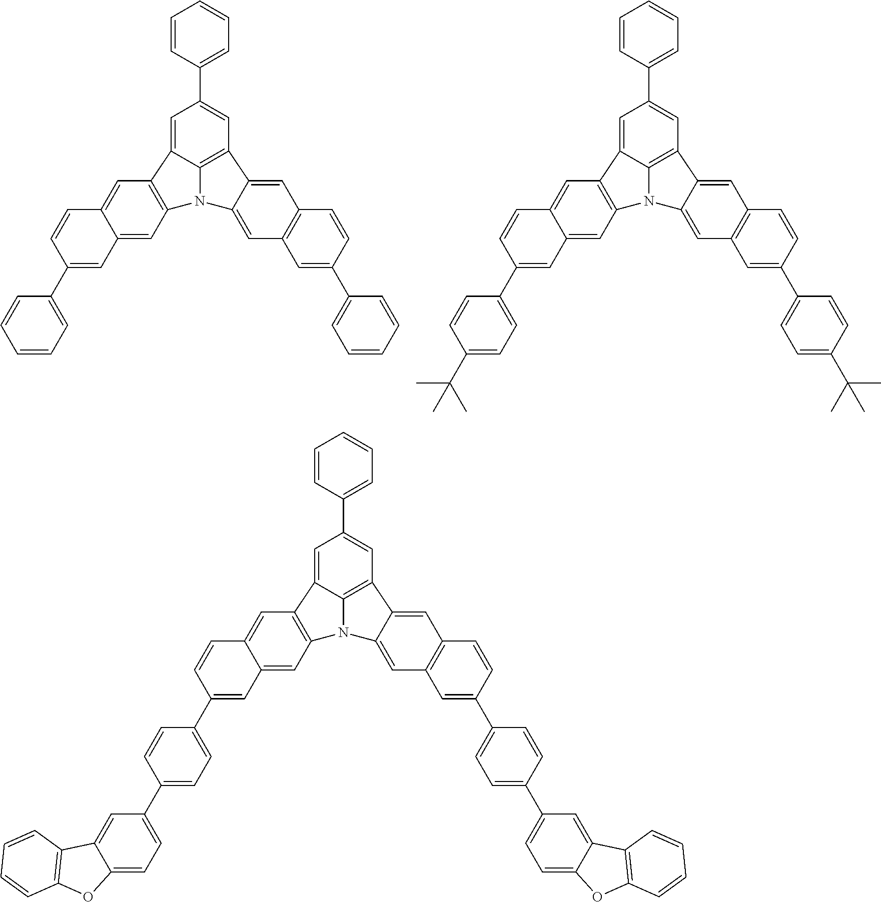

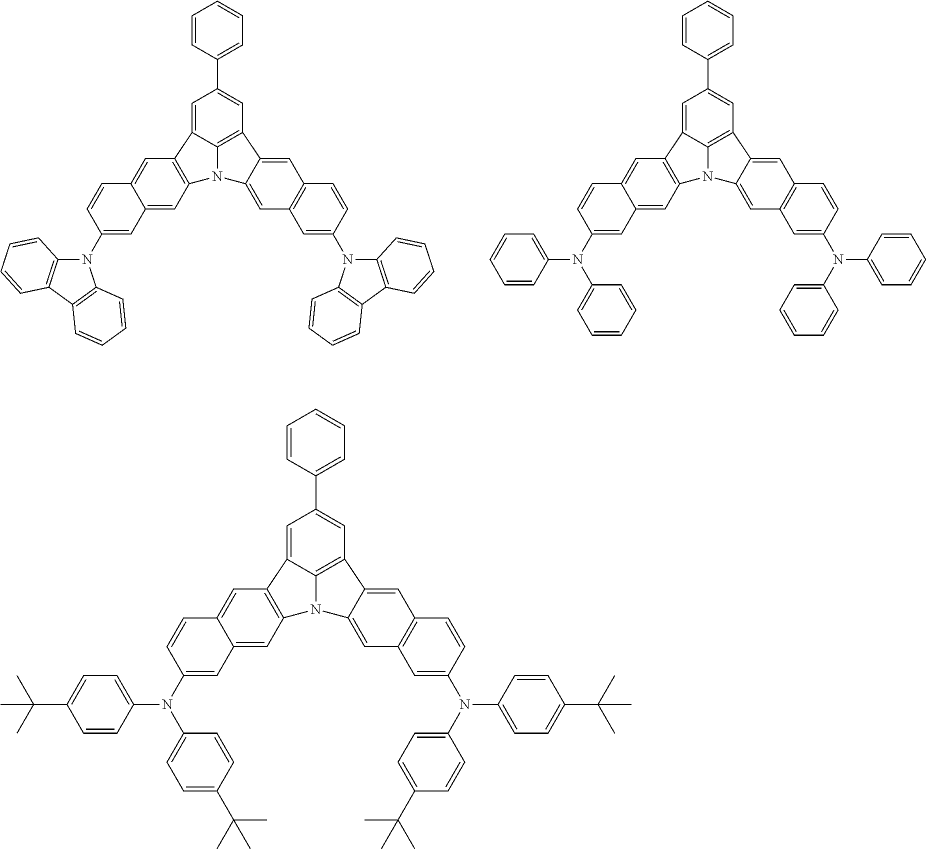 [SMILES: c1ccc(-c2cc3c4cc5ccc(-n6c7ccccc7c7ccccc76)cc5cc4n4c5cc6cc(-n7c8ccccc8c8ccccc87)ccc6cc5c(c2)c34)cc1 ; c1ccc(-c2cc3c4cc5ccc(N(c6ccccc6)c6ccccc6)cc5cc4n4c5cc6cc(N(c7ccccc7)c7ccccc7)ccc6cc5c(c2)c34)cc1 ; CC(C)(C)c1ccc(N(c2ccc(C(C)(C)C)cc2)c2ccc3cc4c5cc(-c6ccccc6)cc6c7cc8ccc(N(c9ccc(C(C)(C)C)cc9)c9ccc(C(C)(C)C)cc9)cc8cc7n(c4cc3c2)c56)cc1]

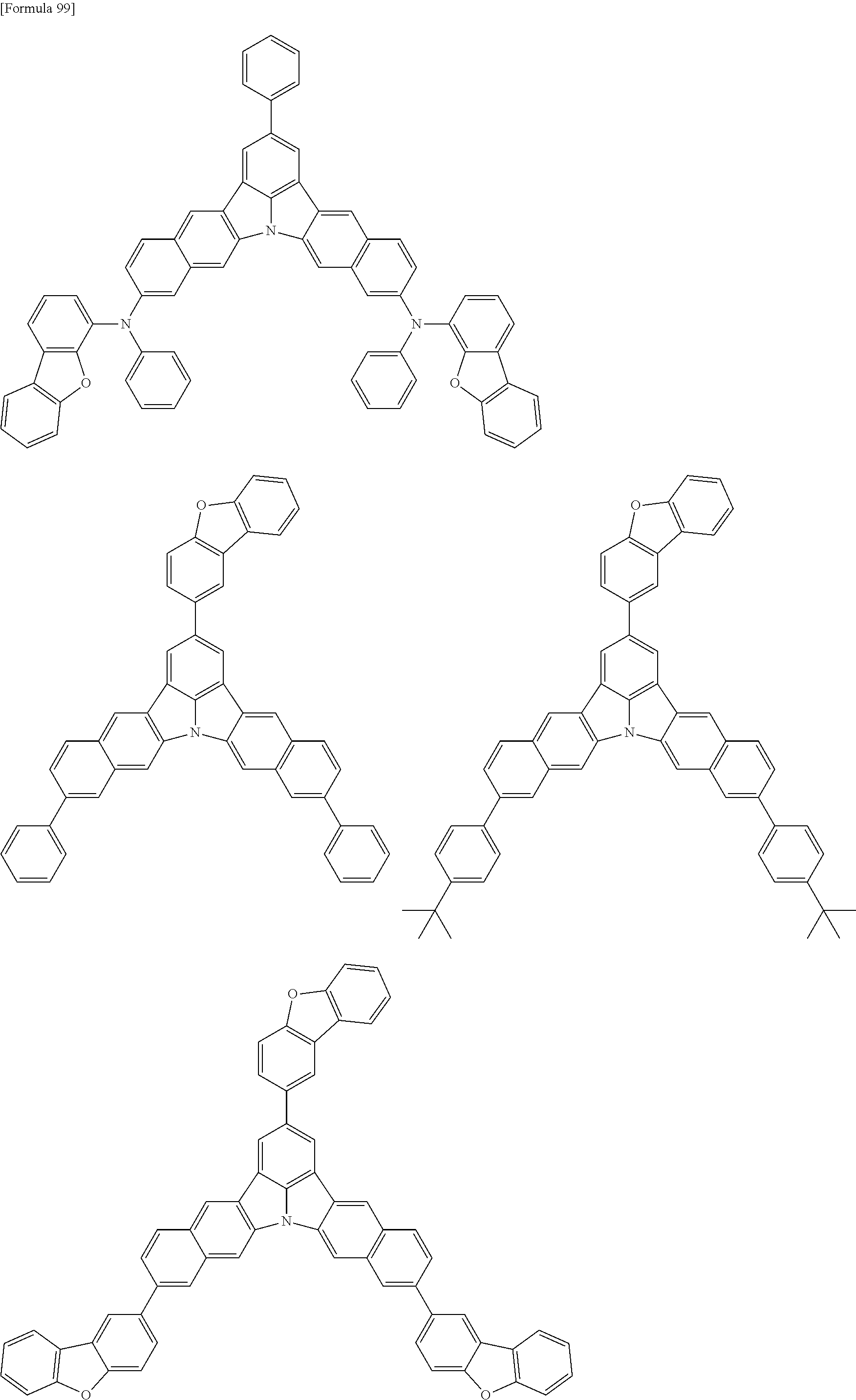

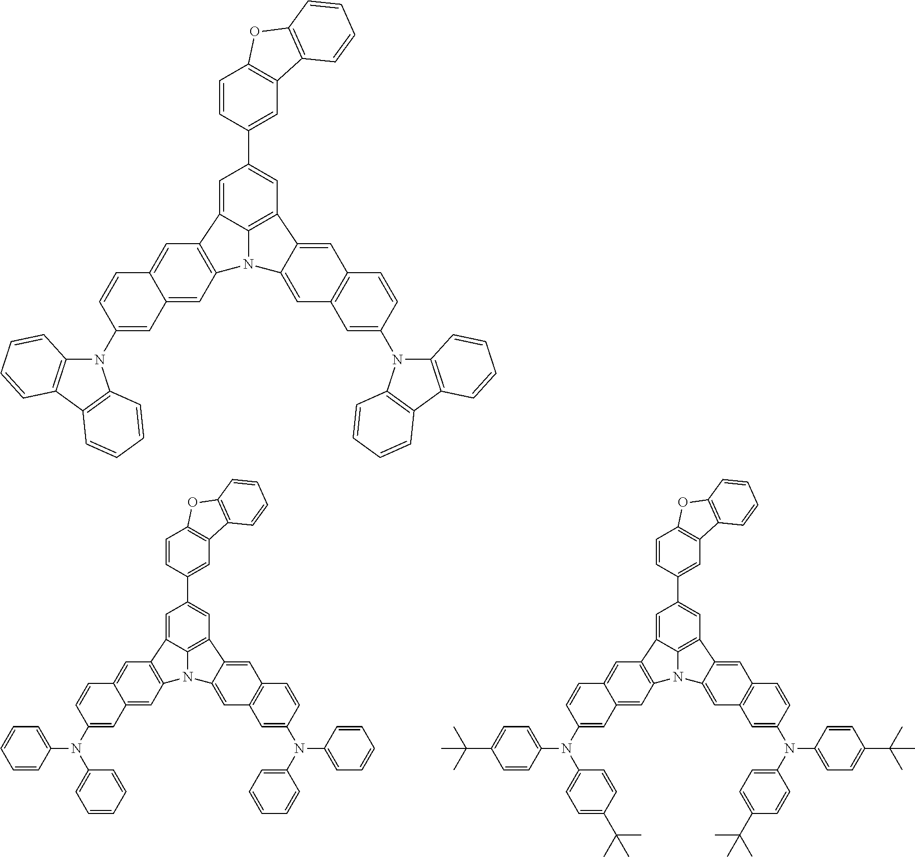 [SMILES: c1ccc2c(c1)oc1ccc(-c3cc4c5cc6ccc(-n7c8ccccc8c8ccccc87)cc6cc5n5c6cc7cc(-n8c9ccccc9c9ccccc98)ccc7cc6c(c3)c45)cc12 ; c1ccc(N(c2ccccc2)c2ccc3cc4c5cc(-c6ccc7oc8ccccc8c7c6)cc6c7cc8ccc(N(c9ccccc9)c9ccccc9)cc8cc7n(c4cc3c2)c56)cc1 ; CC(C)(C)c1ccc(N(c2ccc(C(C)(C)C)cc2)c2ccc3cc4c5cc(-c6ccc7oc8ccccc8c7c6)cc6c7cc8ccc(N(c9ccc(C(C)(C)C)cc9)c9ccc(C(C)(C)C)cc9)cc8cc7n(c4cc3c2)c56)cc1]

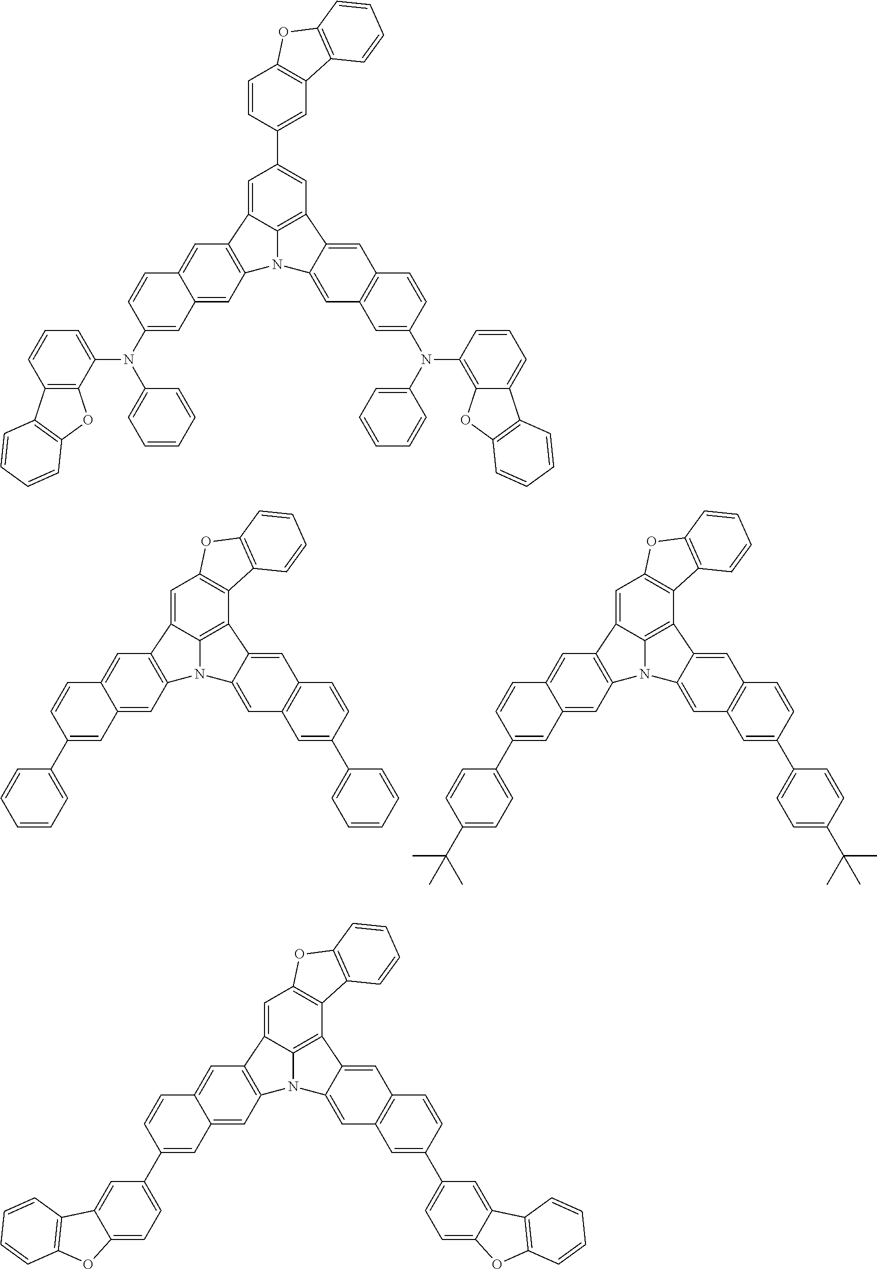

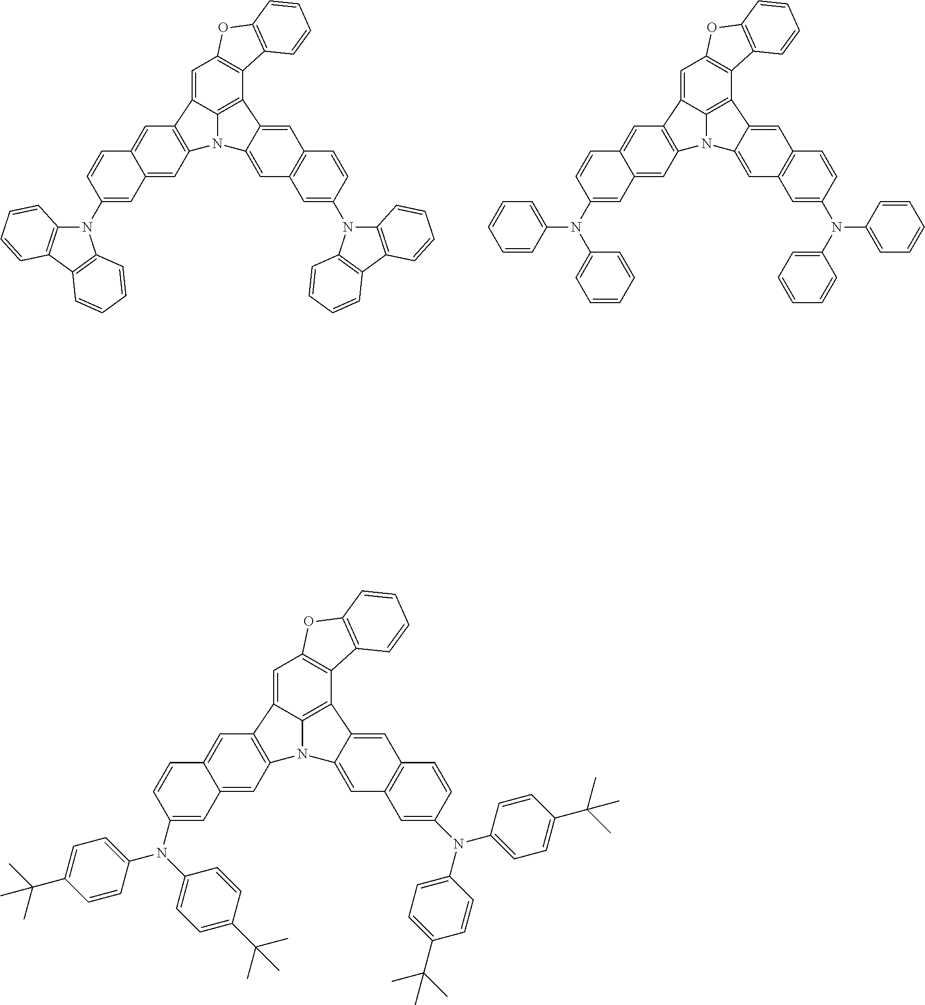 [SMILES: c1ccc2c(c1)oc1cc3c4cc5ccc(-n6c7ccccc7c7ccccc76)cc5cc4n4c5cc6cc(-n7c8ccccc8c8ccccc87)ccc6cc5c(c12)c34 ; c1ccc(N(c2ccccc2)c2ccc3cc4c5cc6oc7ccccc7c6c6c7cc8ccc(N(c9ccccc9)c9ccccc9)cc8cc7n(c4cc3c2)c56)cc1 ; CC(C)(C)c1ccc(N(c2ccc(C(C)(C)C)cc2)c2ccc3cc4c5cc6oc7ccccc7c6c6c7cc8ccc(N(c9ccc(C(C)(C)C)cc9)c9ccc(C(C)(C)C)cc9)cc8cc7n(c4cc3c2)c56)cc1]

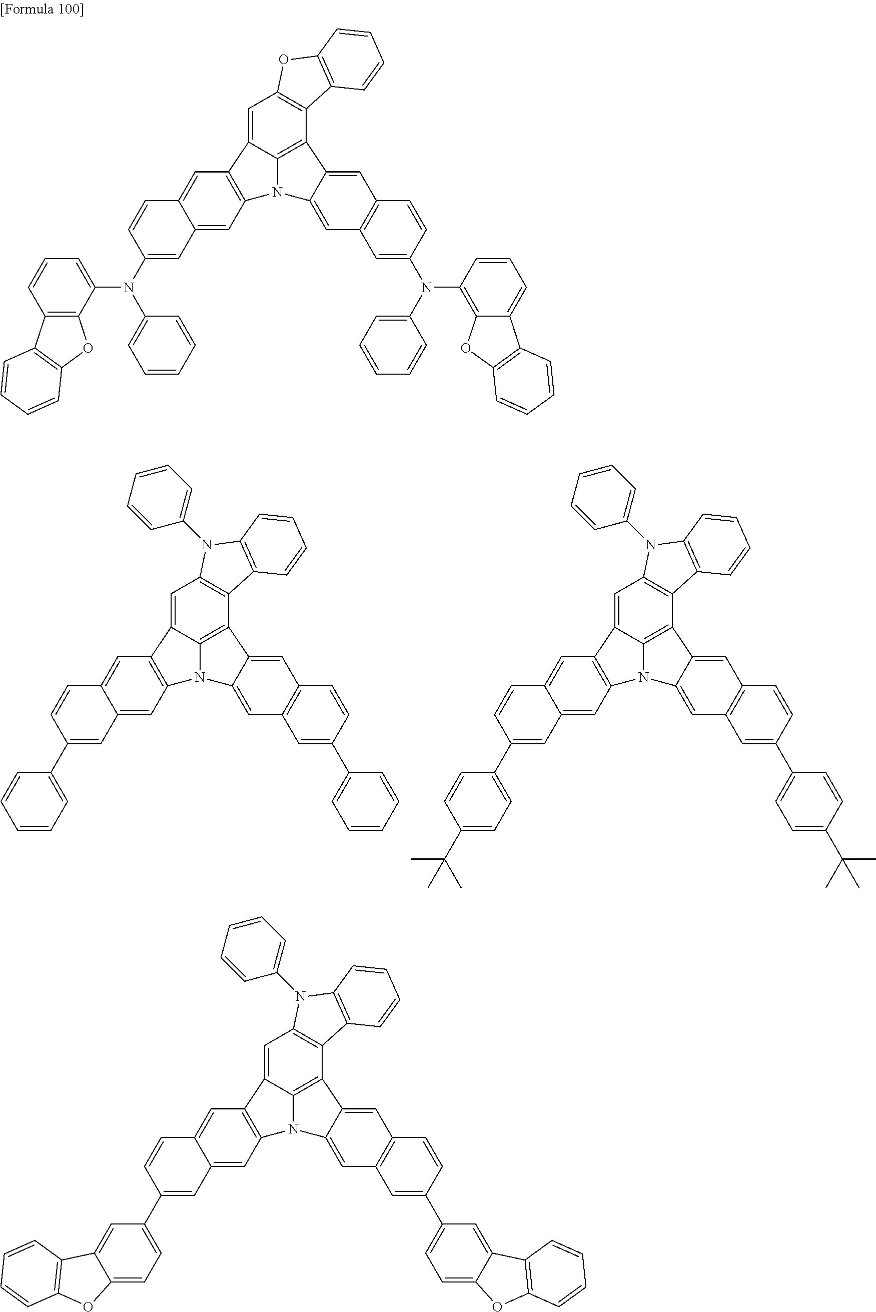

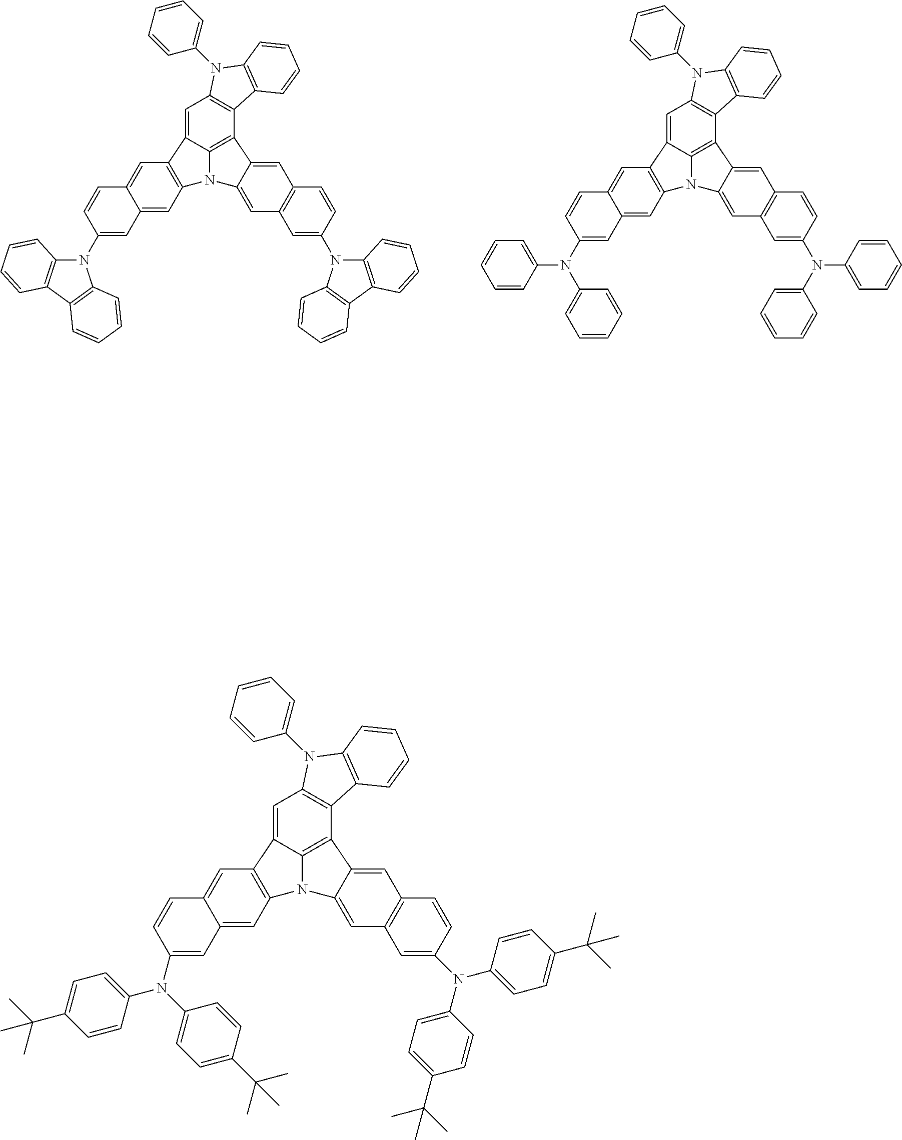 [SMILES: c1ccc(-n2c3ccccc3c3c4c5cc6ccc(-n7c8ccccc8c8ccccc87)cc6cc5n5c6cc7cc(-n8c9ccccc9c9ccccc98)ccc7cc6c(cc32)c45)cc1 ; c1ccc(N(c2ccccc2)c2ccc3cc4c5cc6c(c7ccccc7n6-c6ccccc6)c6c7cc8ccc(N(c9ccccc9)c9ccccc9)cc8cc7n(c4cc3c2)c56)cc1 ; CC(C)(C)c1ccc(N(c2ccc(C(C)(C)C)cc2)c2ccc3cc4c5cc6c(c7ccccc7n6-c6ccccc6)c6c7cc8ccc(N(c9ccc(C(C)(C)C)cc9)c9ccc(C(C)(C)C)cc9)cc8cc7n(c4cc3c2)c56)cc1]

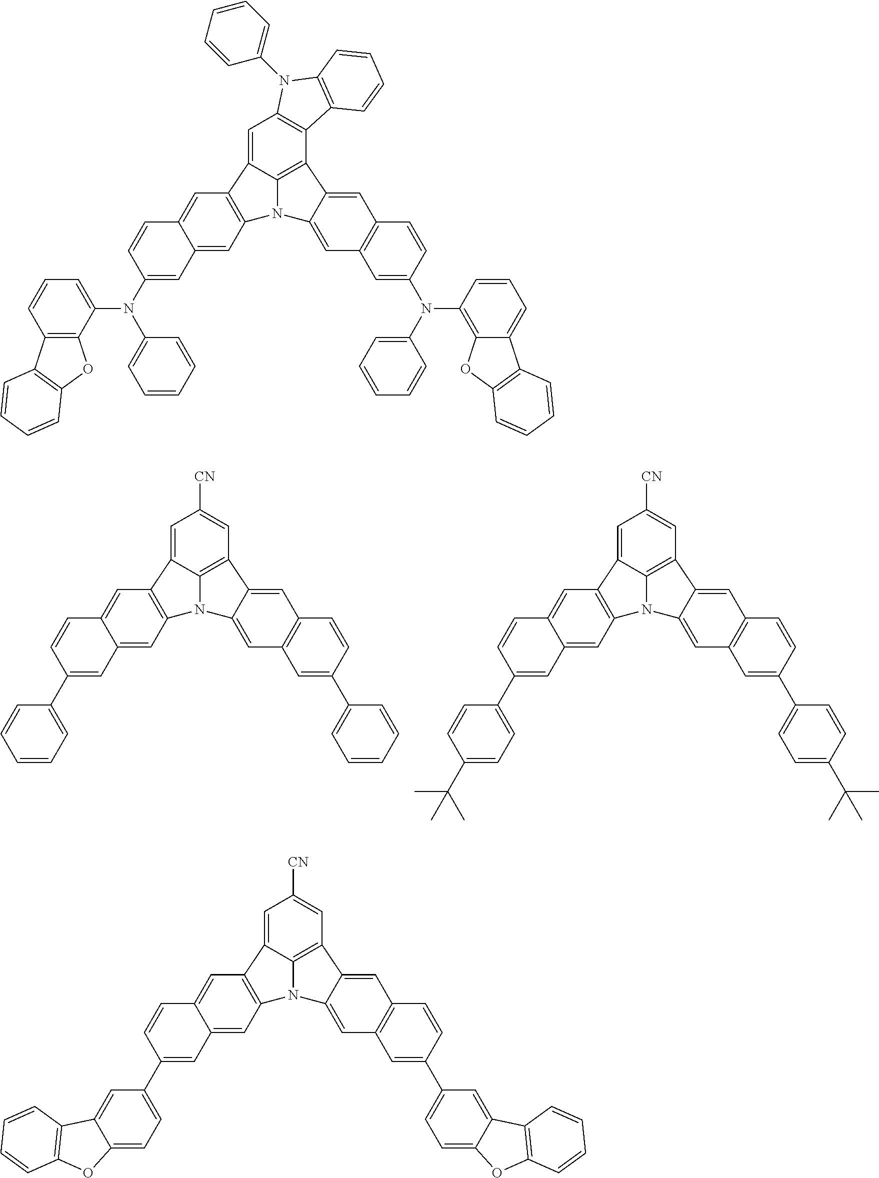

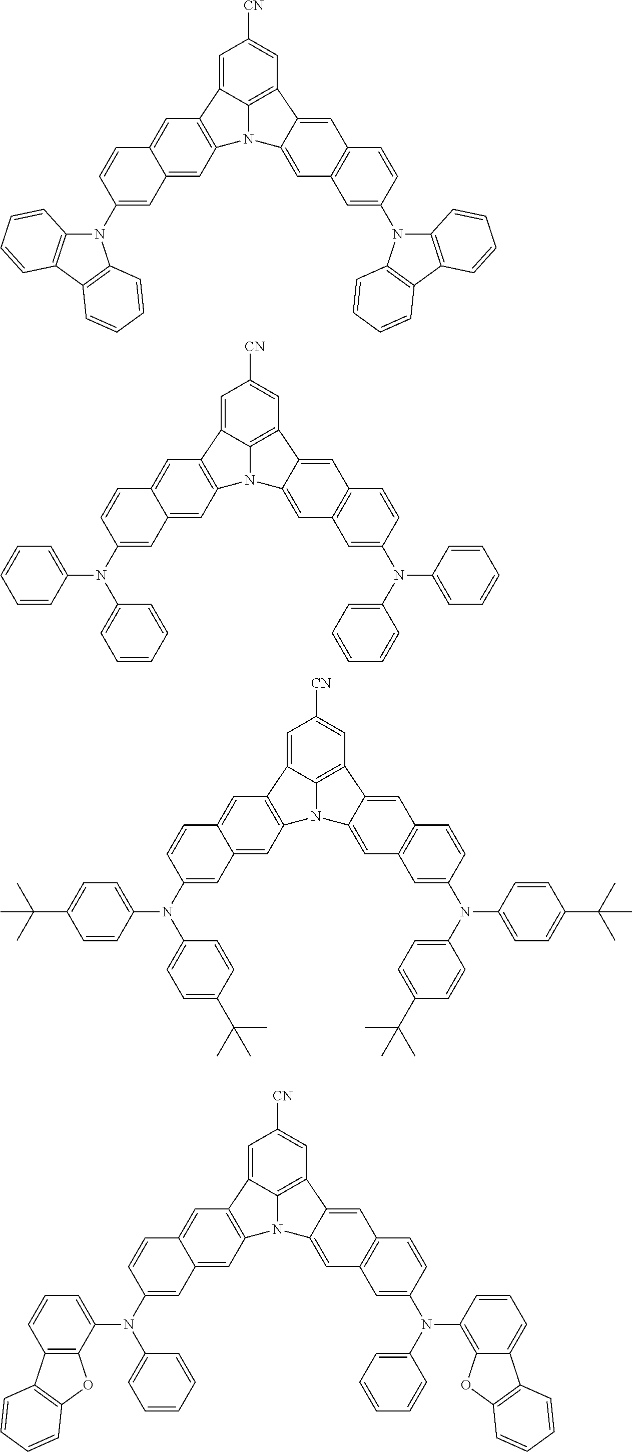

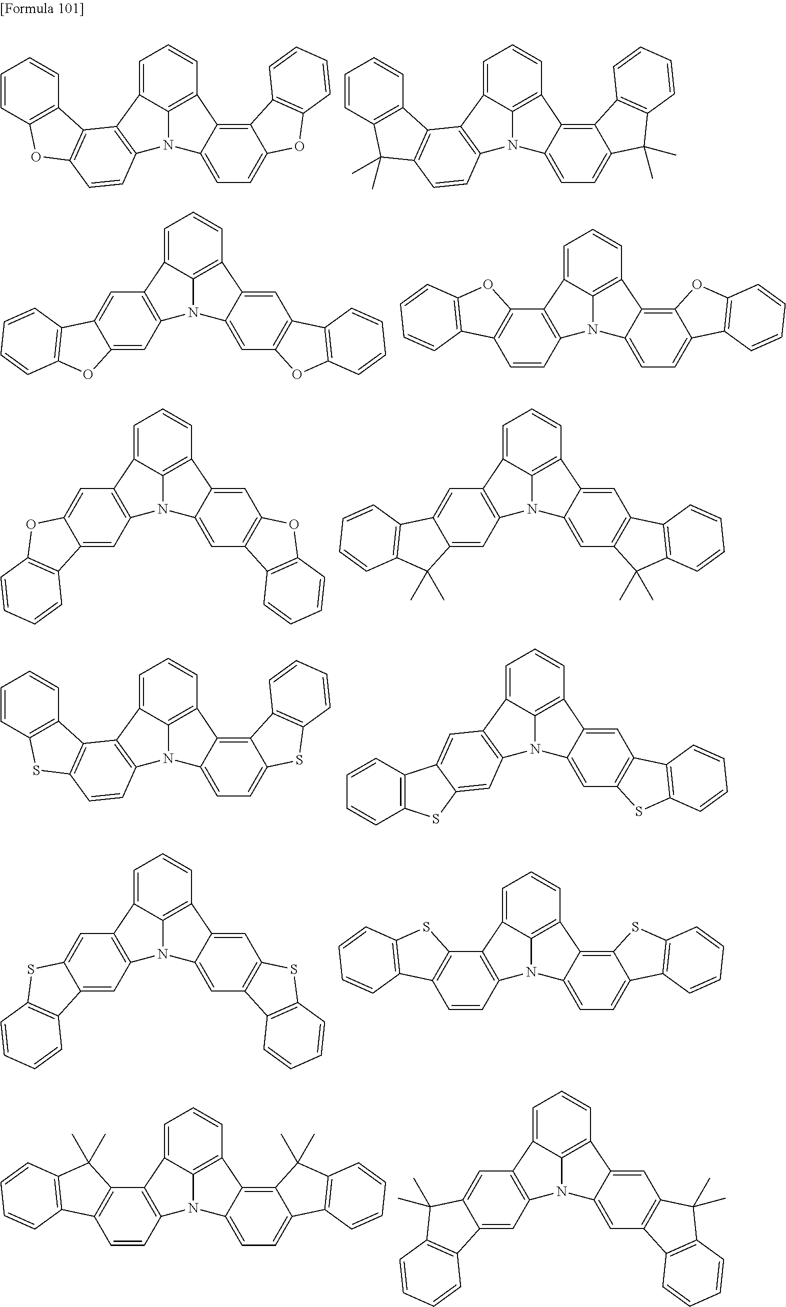

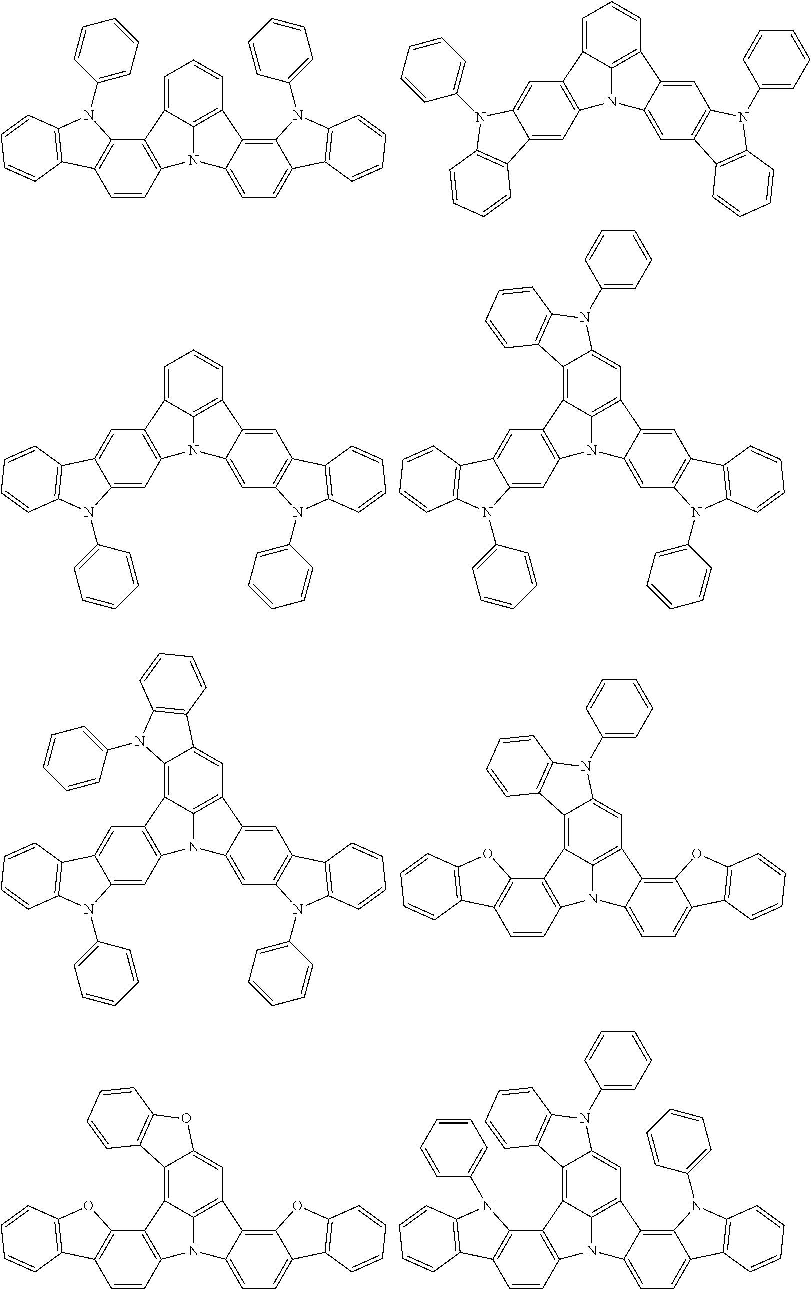

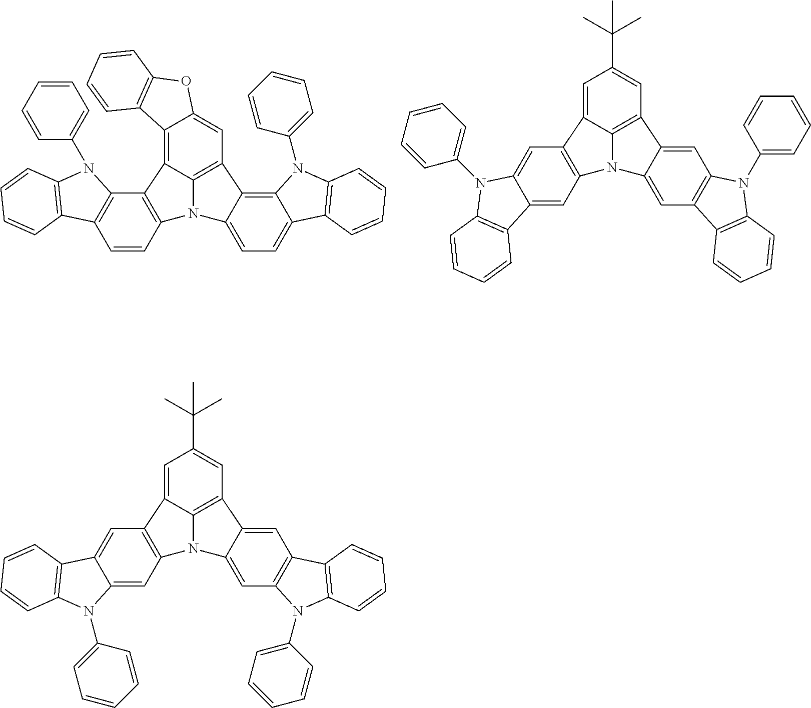

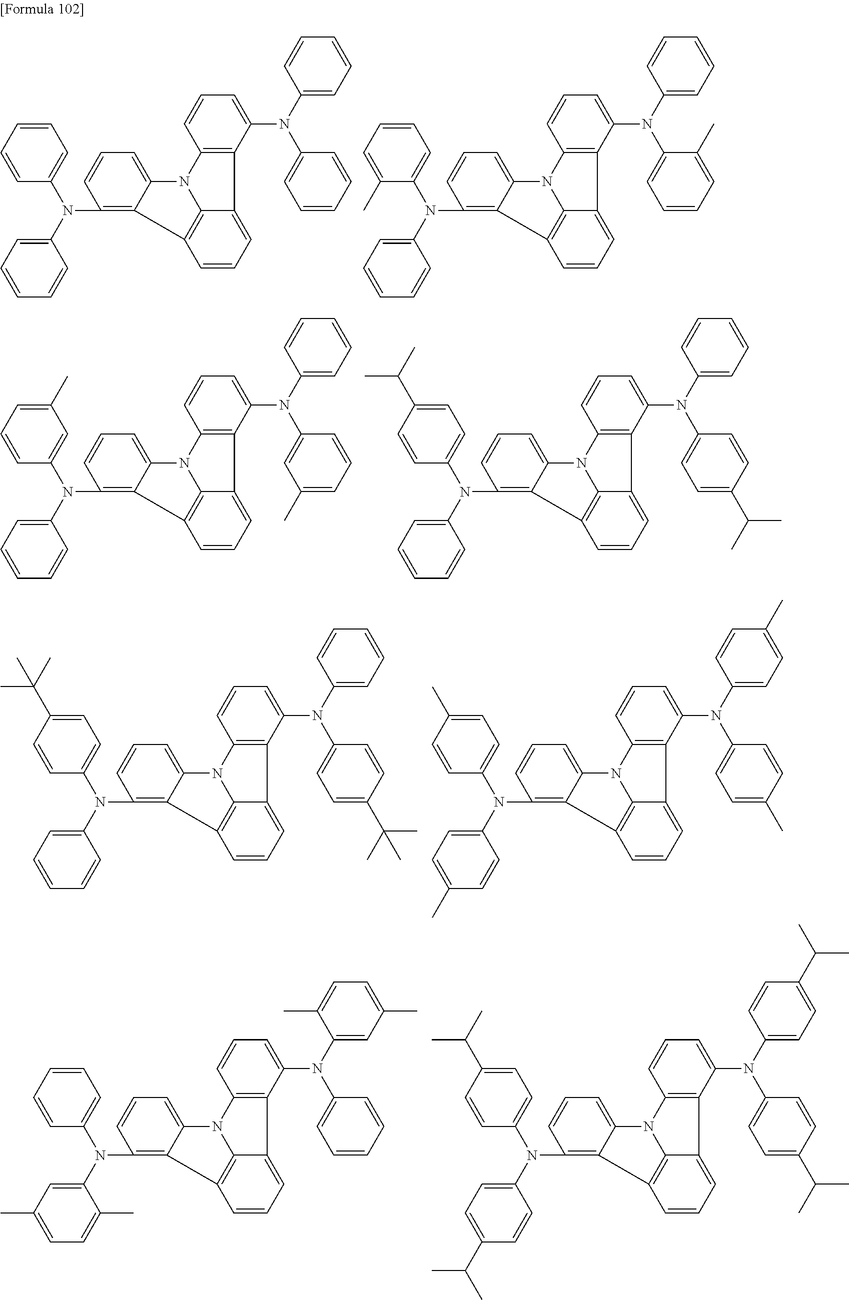

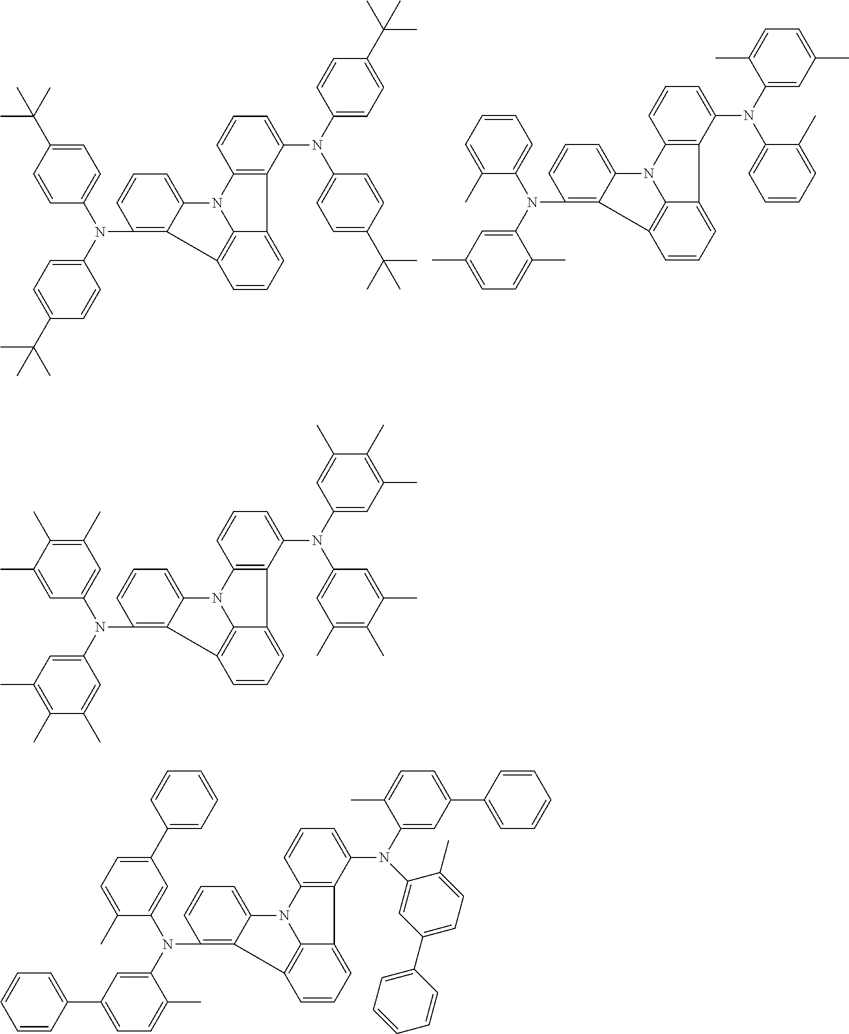

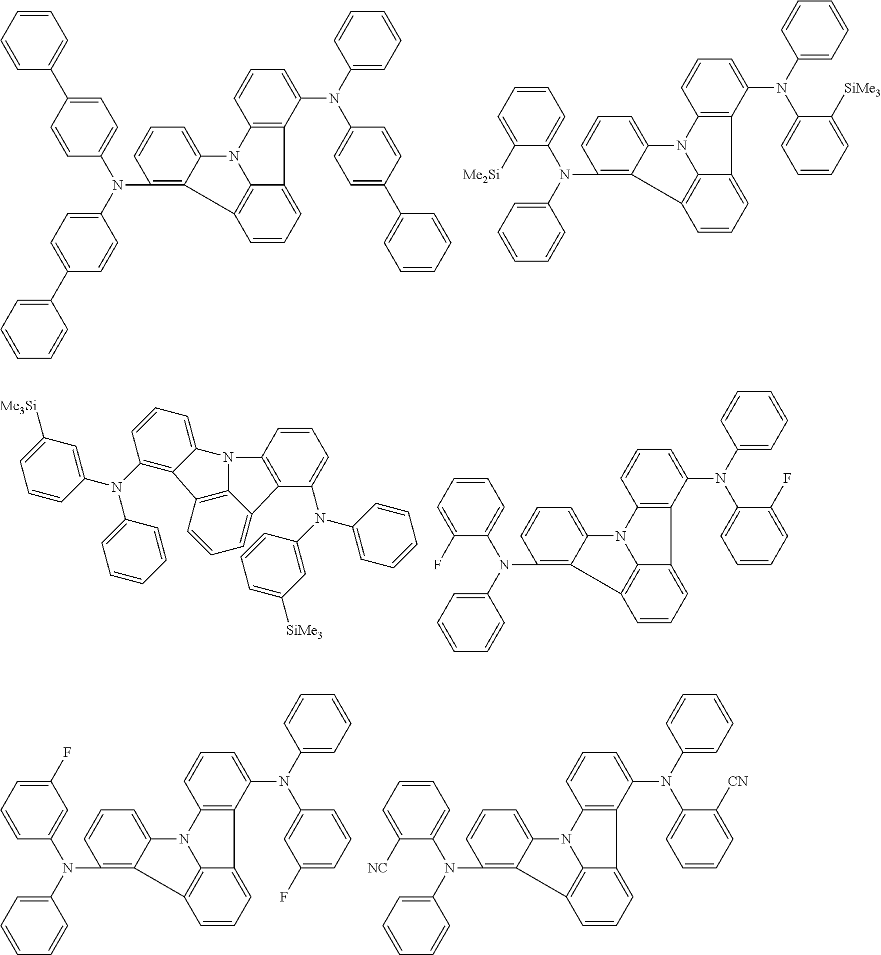

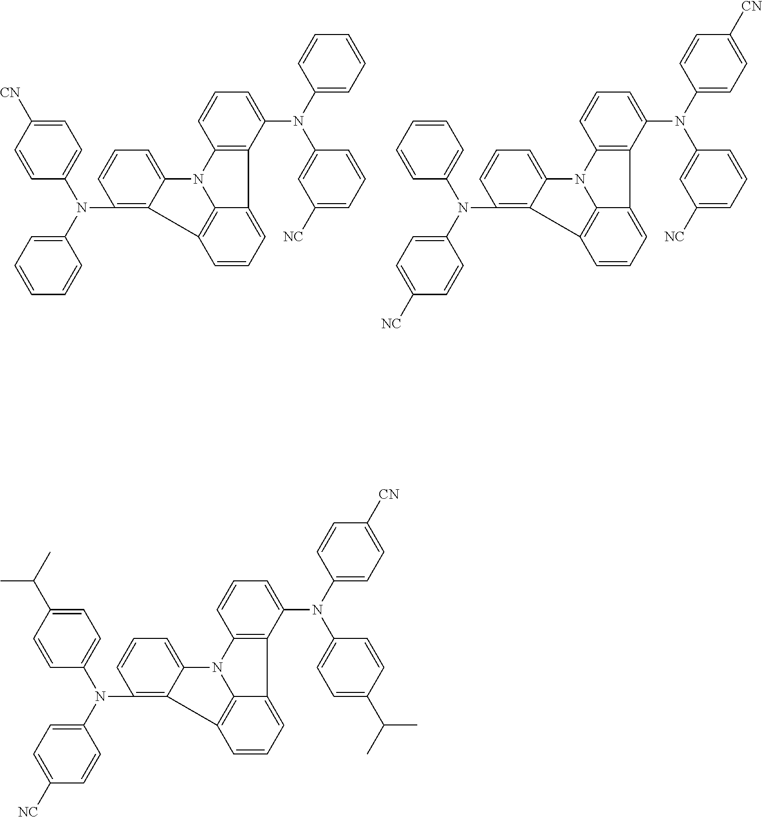

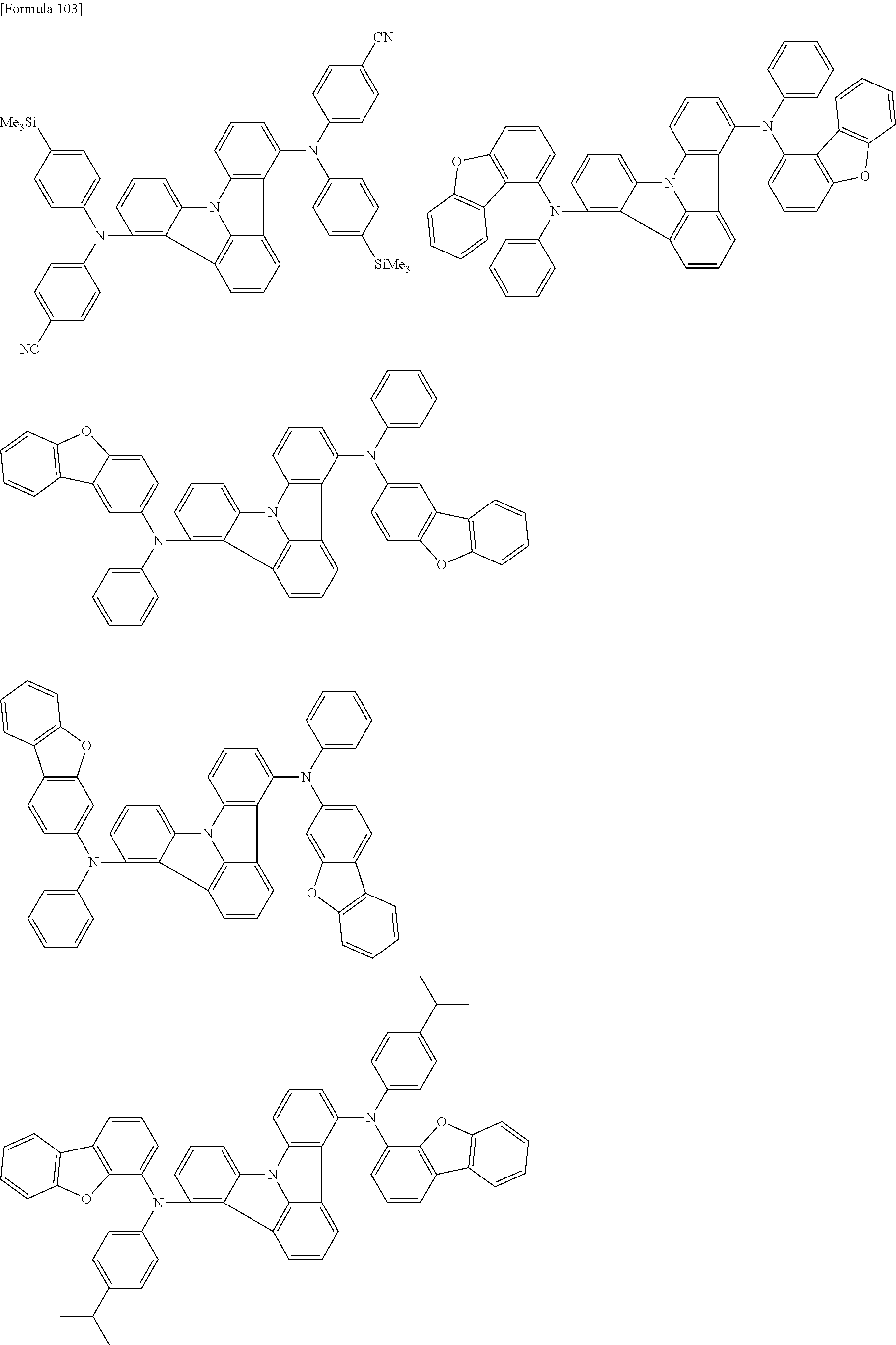

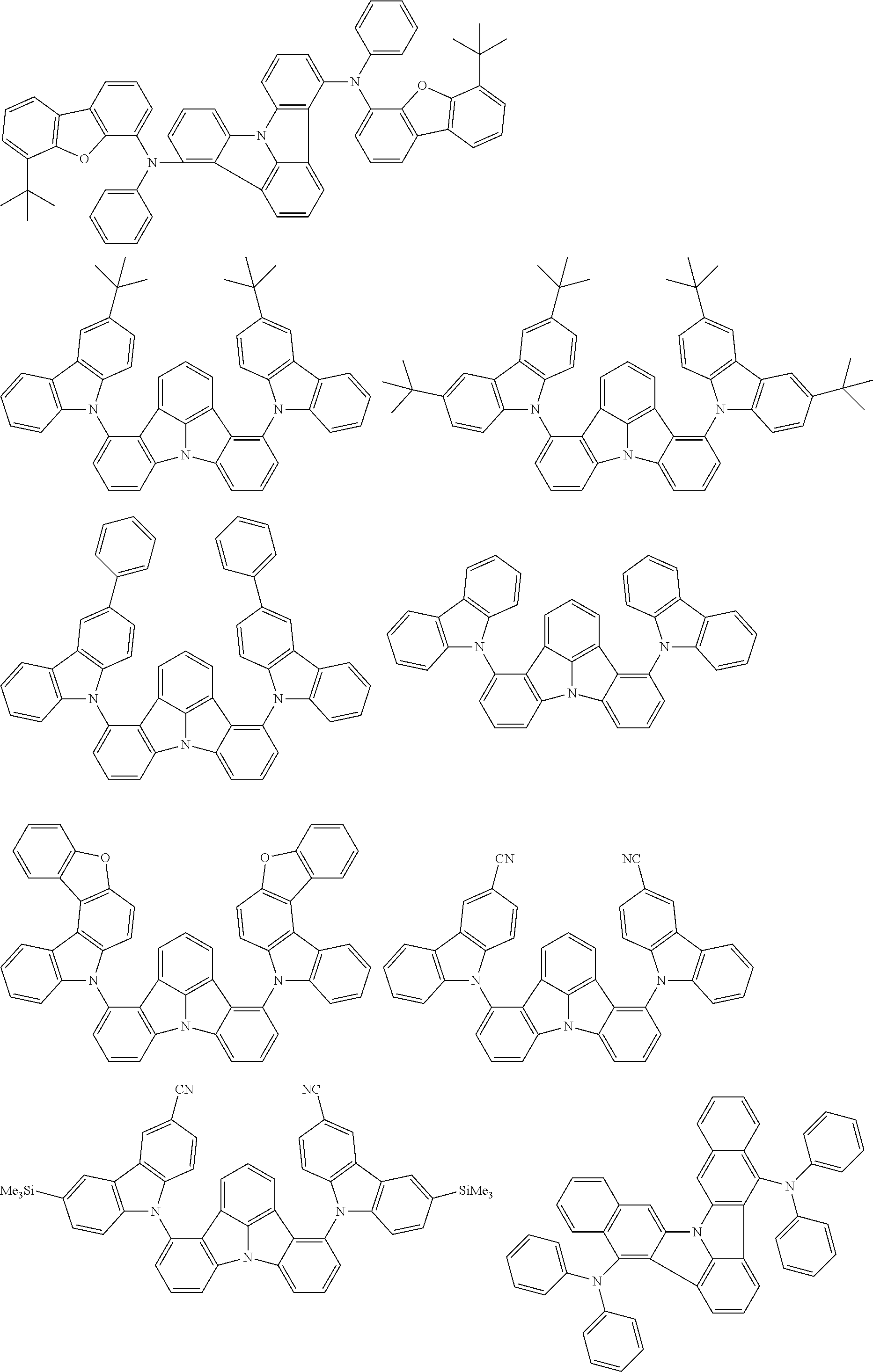

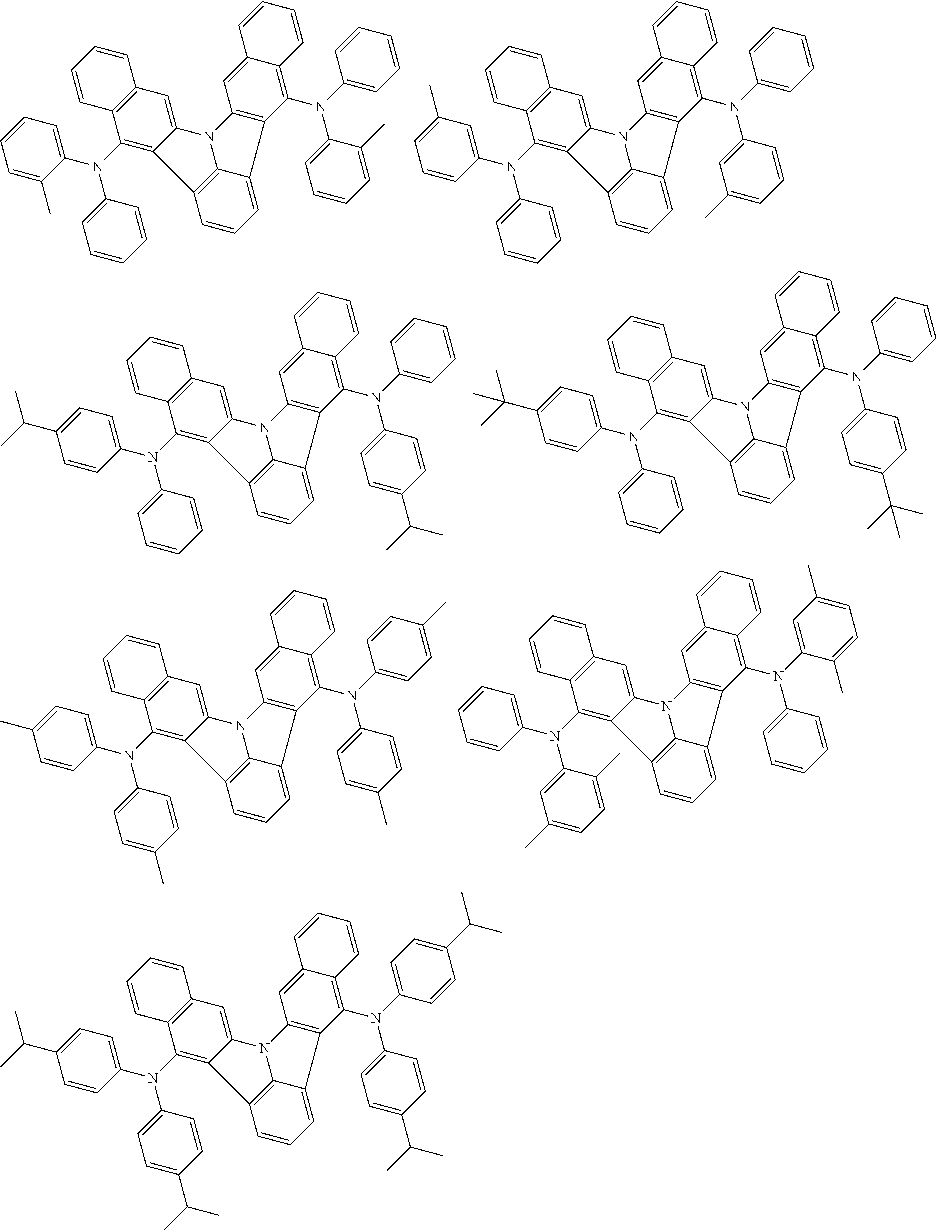

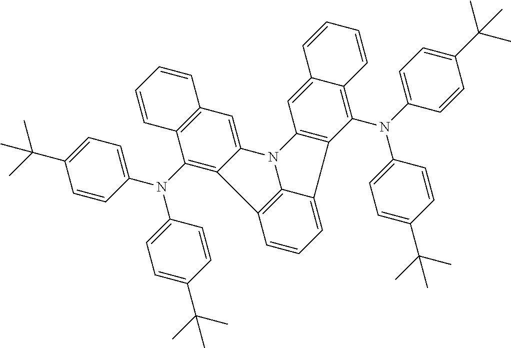 [SMILES: CC(C)(C)c1ccc(N(c2ccc(C(C)(C)C)cc2)c2c3ccccc3cc3c2c2cccc4c5c(N(c6ccc(C(C)(C)C)cc6)c6ccc(C(C)(C)C)cc6)c6ccccc6cc5n3c24)cc1]

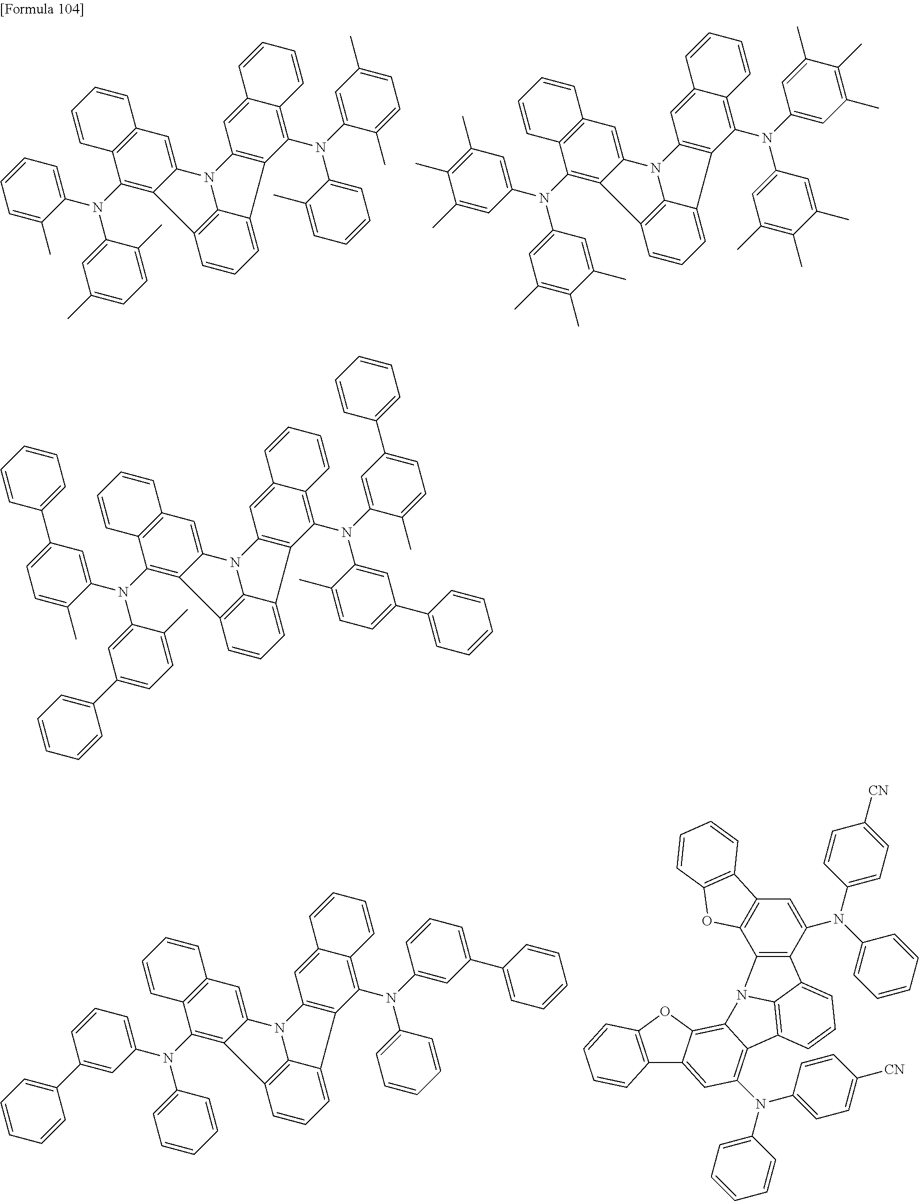

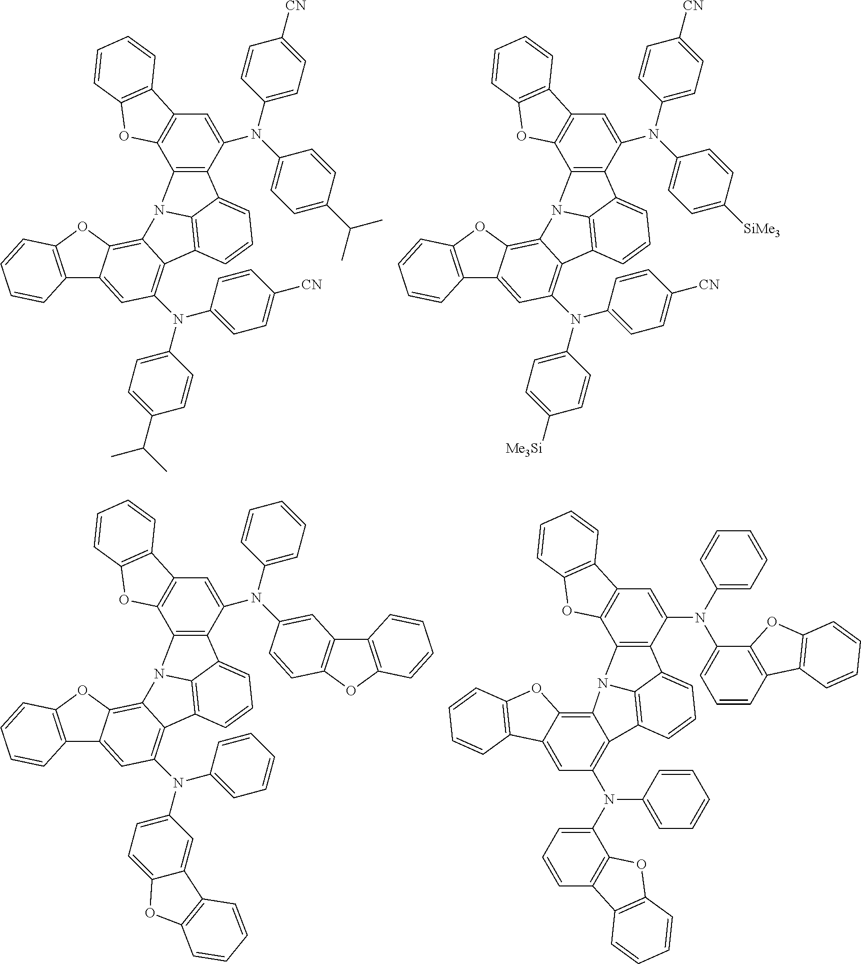

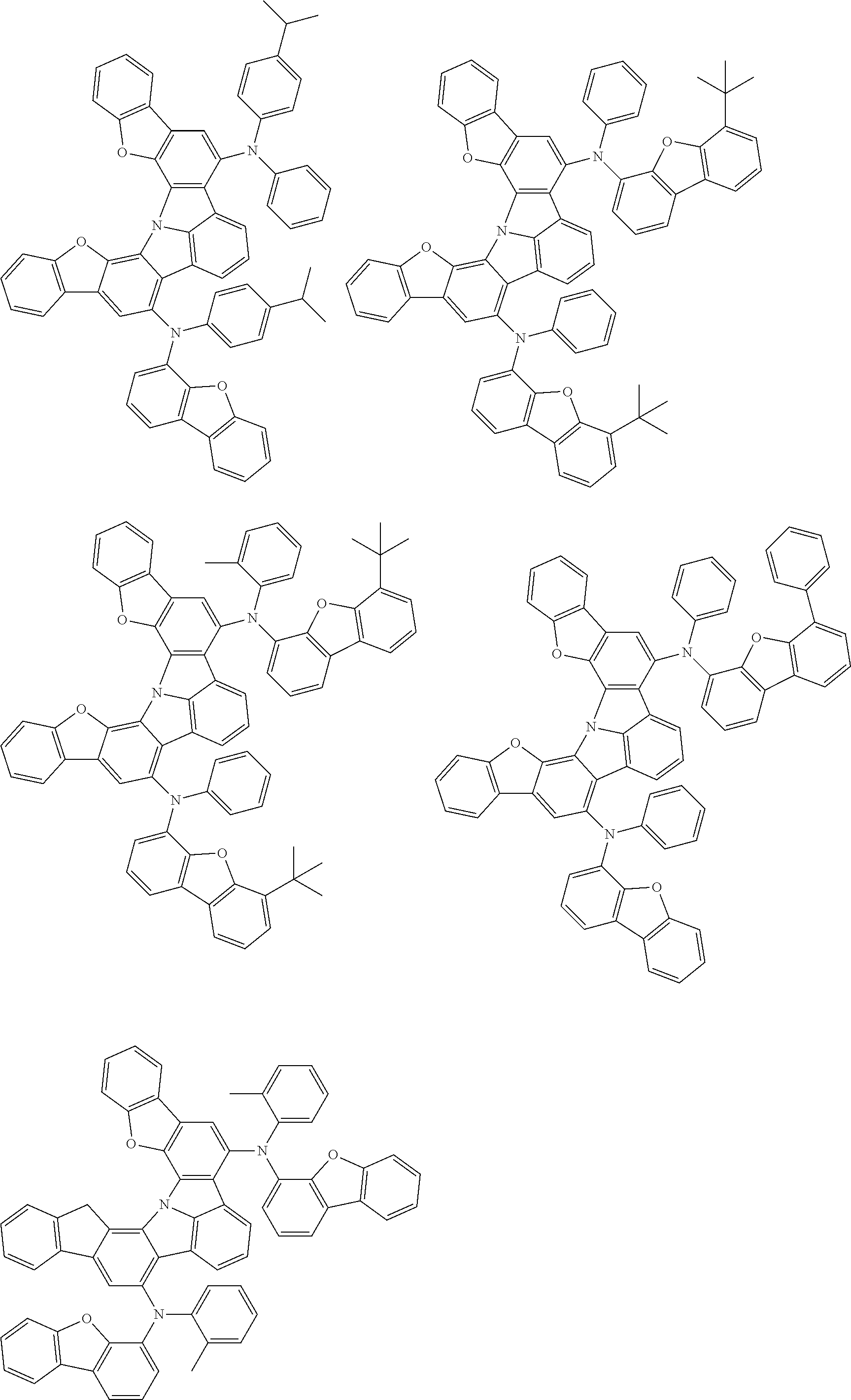

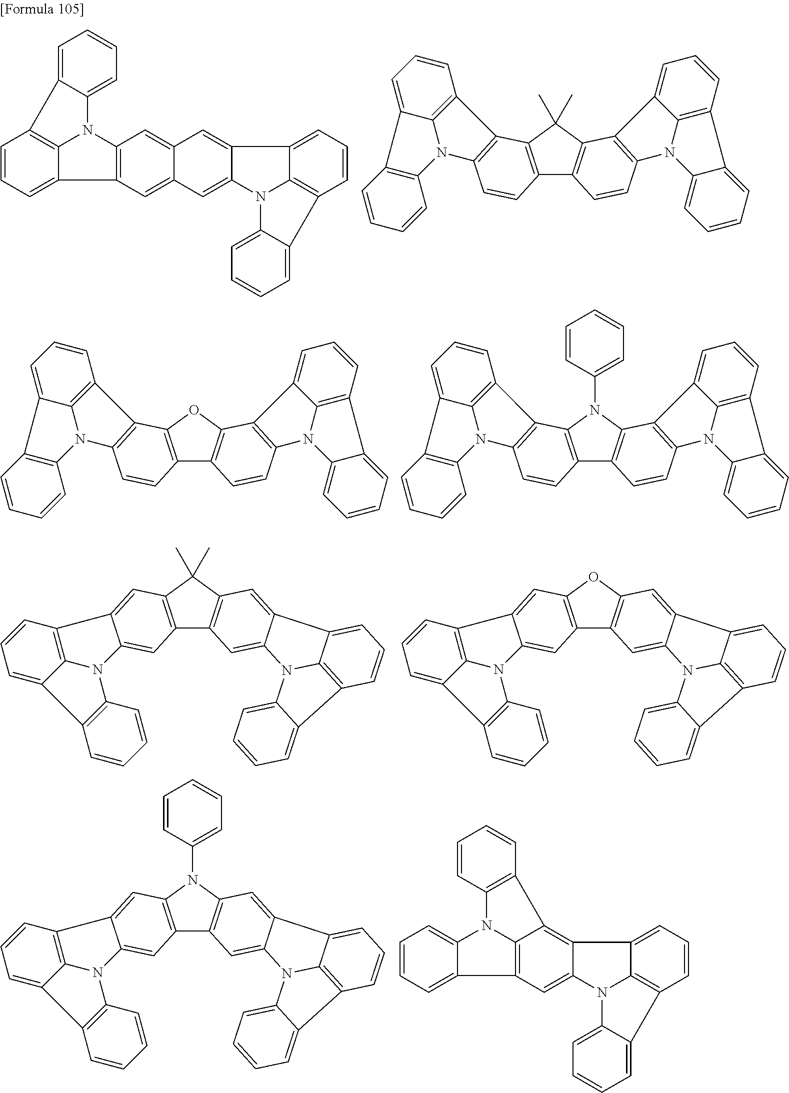

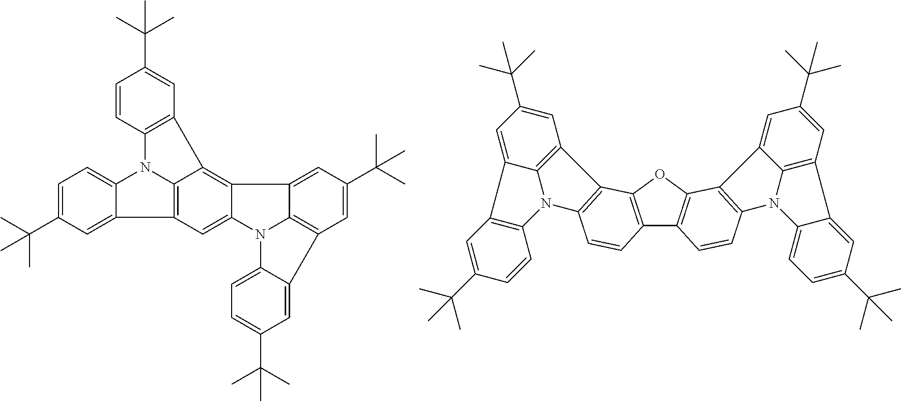 [SMILES: CC(C)(C)c1ccc2c(c1)c1cc(C(C)(C)C)cc3c4c5c6cc(C(C)(C)C)ccc6n6c7ccc(C(C)(C)C)cc7c(cc4n2c13)c56 ; CC(C)(C)c1ccc2c(c1)c1cc(C(C)(C)C)cc3c4c5oc6c(ccc7c6c6cc(C(C)(C)C)cc8c9cc(C(C)(C)C)ccc9n7c86)c5ccc4n2c13]

### Compounds Represented by Formula (5)

The following describes the compounds represented by formula (5). The compounds represented by formula (5) are compounds that correspond to the compounds represented by formula (41-3), described above.

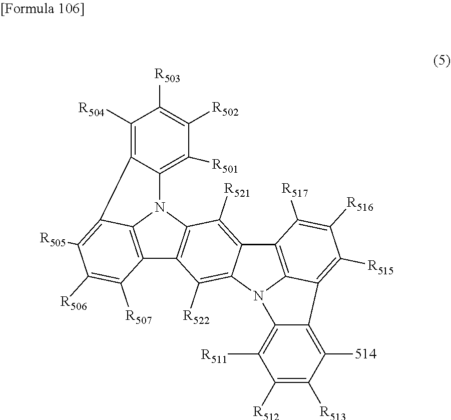

In formula (5),

at least one combination of adjacent two or more of R₅₀₁ to R₅₀₇ and R₅₁₁ to R₅₁₇ are: bonded together to form a substituted or unsubstituted monocyclic ring; bonded together to form a substituted or unsubstituted fused ring; or not bonded together; and

R₅₀₁ to R₅₀₇ and R₅₁₁ to R₅₁₇ not forming the monocyclic ring and not forming the fused ring each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

R₅₂₁ and R₅₂₂ each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

“A combination of adjacent two or more of R₅₀₁ to R₅₀₇ and R₅₁₁ to R₅₁₇” refers to, for instance, a combination of R₅₀₁ and R₅₀₂, a combination of R₅₀₂ and R₅₀₃, a combination of R₅₀₃ and R₅₀₄, a combination of R₅₀₅ and R₅₀₆, a combination of R₅₀₆ and R₅₀₇, and a combination of R₅₀₁, R₅₀₂, and R₅₀₃.

In an exemplary embodiment, at least one of R₅₀₁ to R₅₀₇ or R₅₁₁ to R₅₁₇, preferably two, is a group represented by —N(R₉₀₆)(R₉₀₇).

In an exemplary embodiment, R₅₀₁ to R₅₀₇ and R₅₁₁ to R₅₁₇ each independently represent: a hydrogen atom; a substituted or unsubstituted aryl group having 6 to 50 ring carbon atoms; or a substituted or unsubstituted heterocyclic group having 5 to 50 ring atoms.

In an exemplary embodiment, the compounds represented by formula (5) are the compounds represented by formula (52) below.

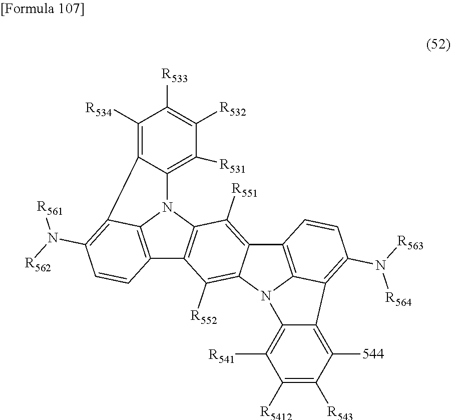

In formula (52),

at least one combination of adjacent two or more of R₅₃₁ to R₅₃₄ and R₅₄₁ to R₅₄₄ are: bonded together to form a substituted or unsubstituted monocyclic ring; bonded together to form a substituted or unsubstituted fused ring; or not bonded together; and

R₅₃₁ to R₅₃₄, R₅₄₁ to R₅₄₄ not forming the monocyclic ring and not forming the fused ring, and R₅₅₁ and R₅₅₂ each independently represent: a hydrogen atom; a substituted or unsubstituted aryl group having 6 to 50 ring carbon atoms; or a substituted or unsubstituted heterocyclic group having 5 to 50 ring atoms; and

R₅₆₁ to R₅₆₄ each independently represent: a substituted or unsubstituted aryl group having 6 to 50 ring carbon atoms; or a substituted or unsubstituted heterocyclic group having 5 to 50 ring atoms.

In an exemplary embodiment, the compounds represented by formula (5) are the compounds represented by formula (53) below.

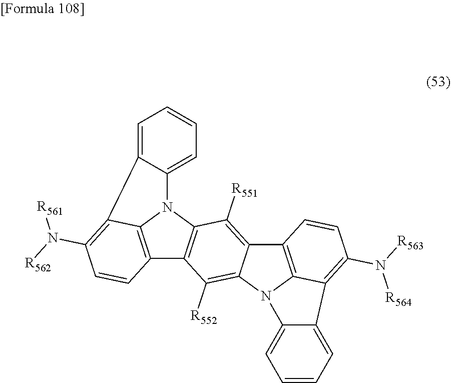

In formula (53), R₅₅₁, R₅₅₂, and R₅₆₁ to R₅₆₄ each independently represent the same as R₅₅₁, R₅₅₂, and R₅₆₁ to R₅₆₄ in formula (52).

In an exemplary embodiment, R₅₆₁ to R₅₆₄ in formulae (52) and (53) each independently represent a substituted or unsubstituted aryl group having 6 to 50 ring carbon atoms (preferably, a phenyl group).

In an exemplary embodiment, R₅₂₁ and R₅₂₂ in formula (5) and R₅₅₁ and R₅₅₂ in formulae (52) and (53) are hydrogen atoms.

In an exemplary embodiment, a substituent for “substituted or unsubstituted” group in formulae (5), (52) and (53) is: a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms.

Specific examples of compounds represented by formula (5) include, for instance, the following compounds.

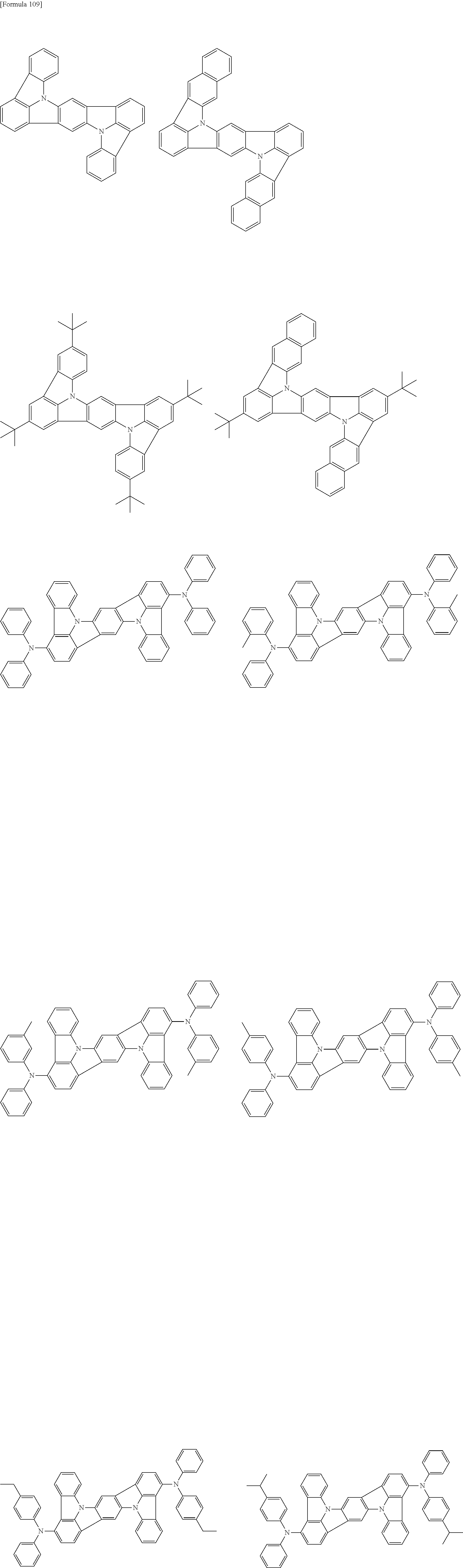

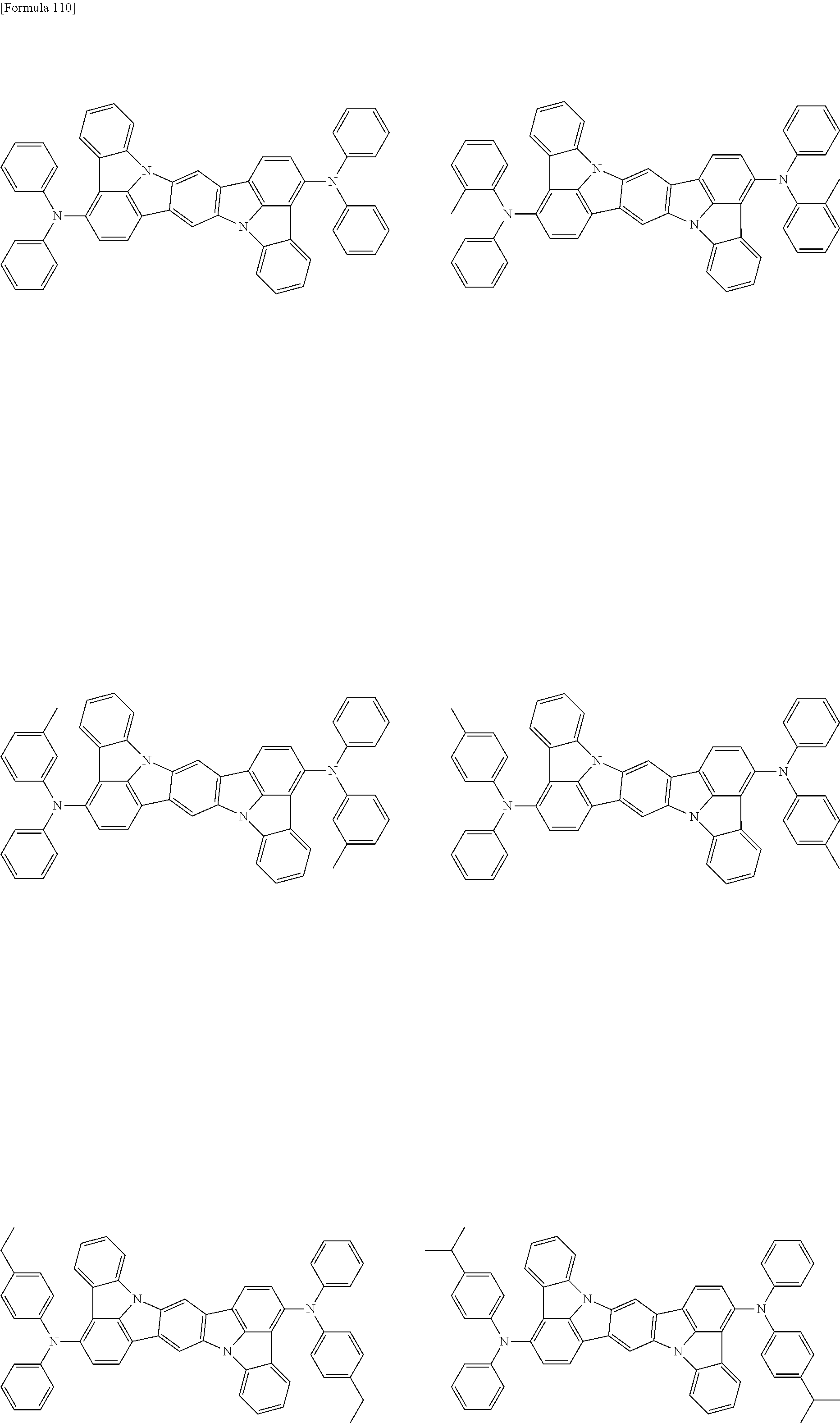

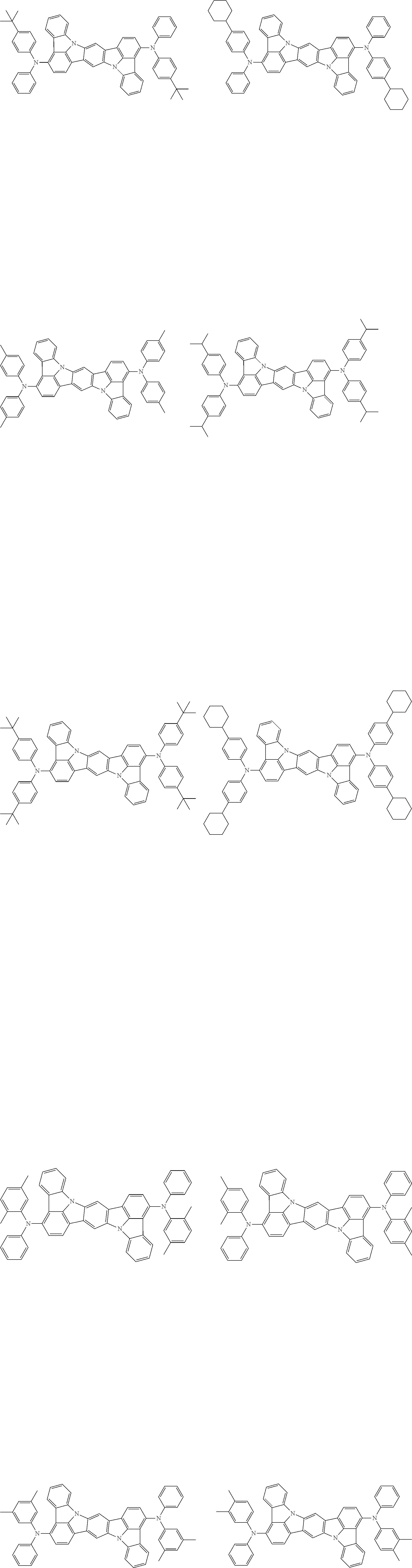

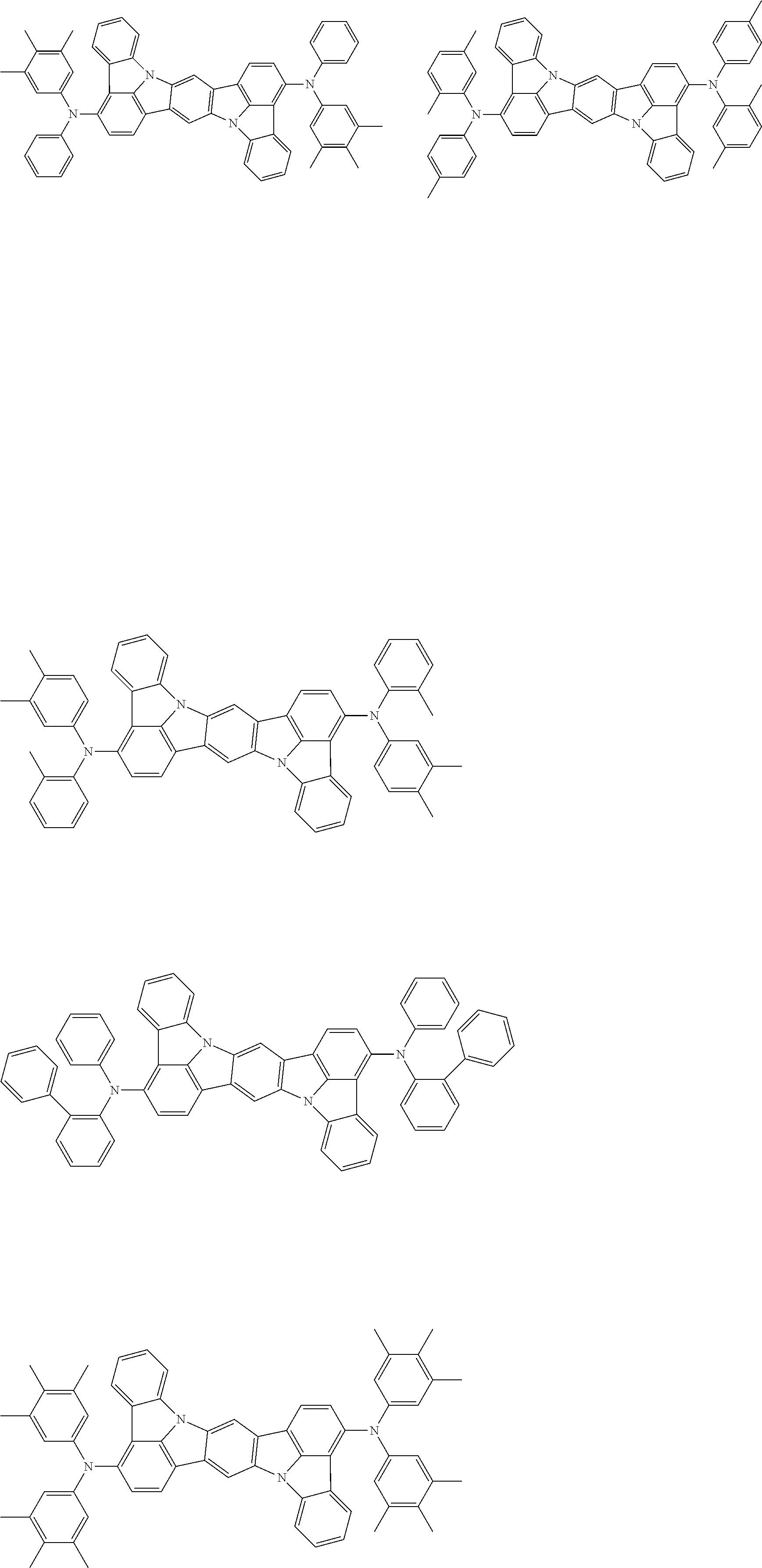

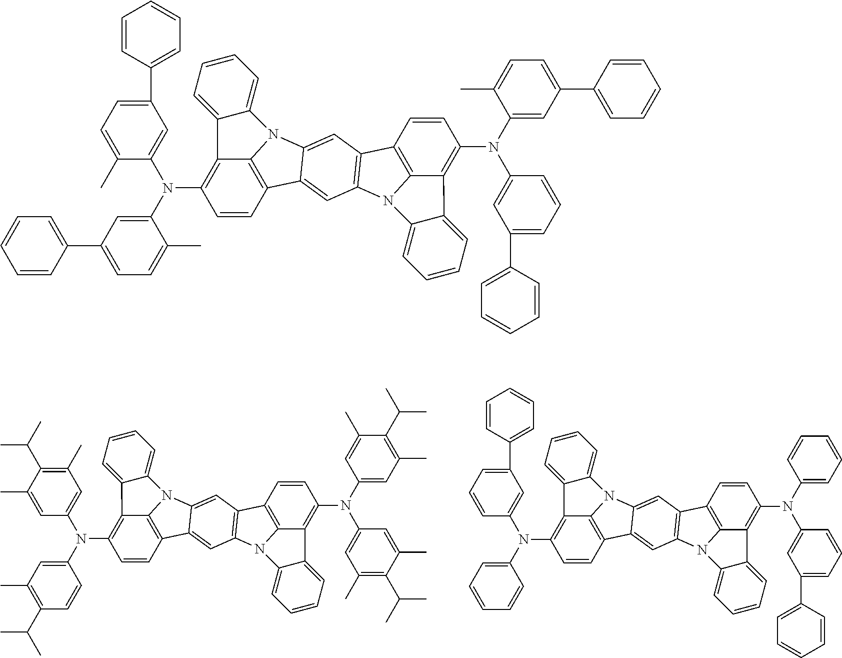 [SMILES: Cc1ccc(-c2ccccc2)cc1N(c1cccc(-c2ccccc2)c1)c1ccc2c3cc4c(cc3n3c5ccccc5c1c23)c1ccc(N(c2cc(-c3ccccc3)ccc2C)c2cc(-c3ccccc3)ccc2C)c2c3ccccc3n4c12 ; Cc1cc(N(c2cc(C)c(C(C)C)c(C)c2)c2ccc3c4cc5c(cc4n4c6ccccc6c2c34)c2ccc(N(c3cc(C)c(C(C)C)c(C)c3)c3cc(C)c(C(C)C)c(C)c3)c3c4ccccc4n5c23)ccc1C(C)C ; c1ccc(-c2cccc(N(c3ccccc3)c3ccc4c5cc6c(cc5n5c7ccccc7c3c45)c3ccc(N(c4ccccc4)c4cccc(-c5ccccc5)c4)c4c5ccccc5n6c34)c2)cc1]

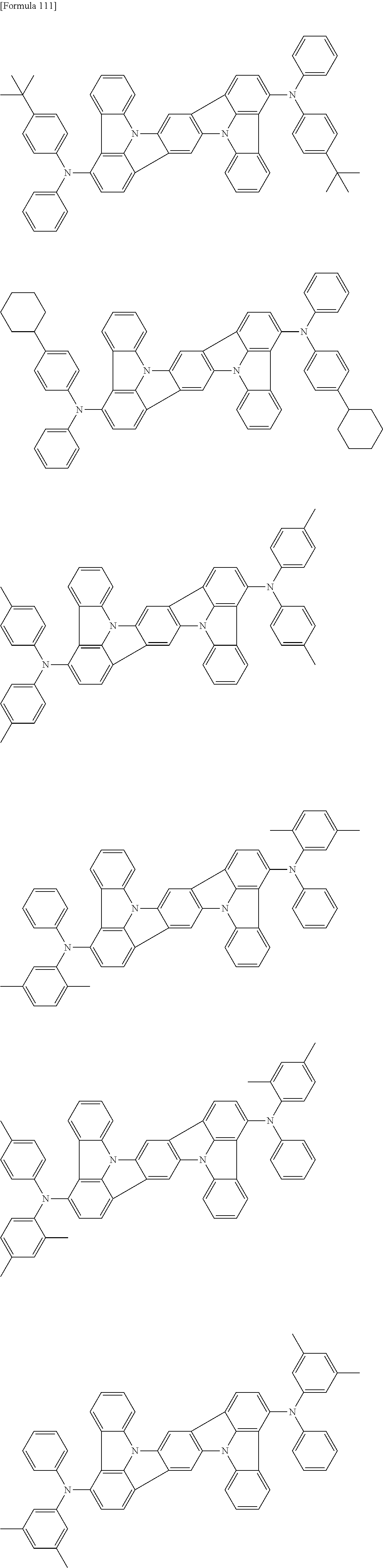

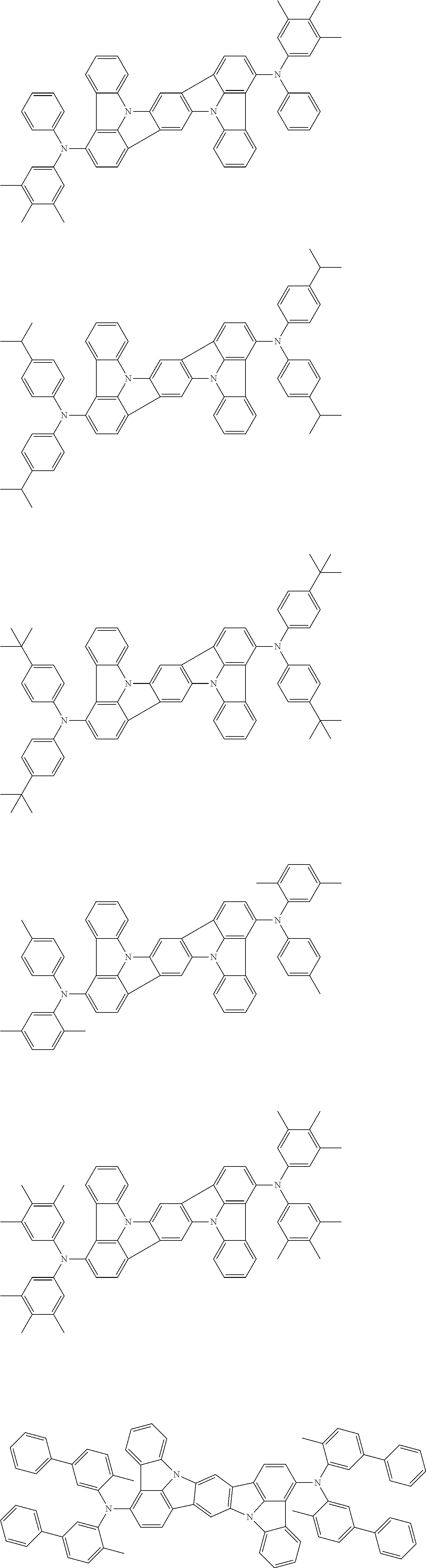

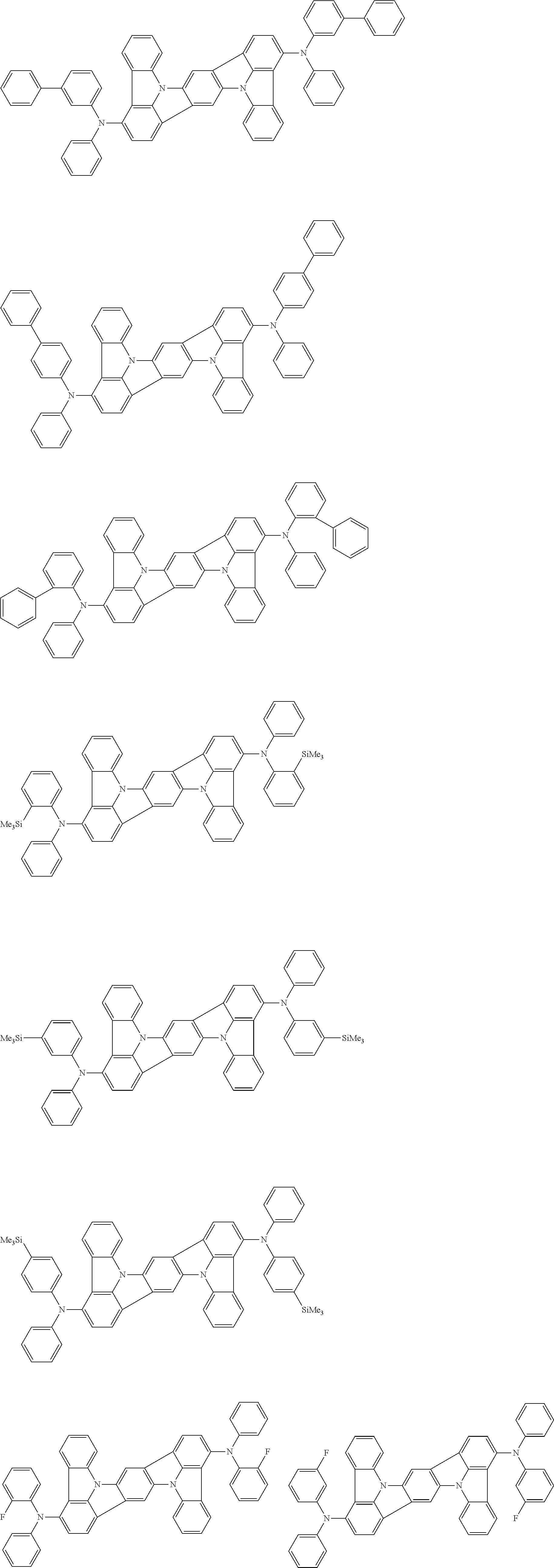

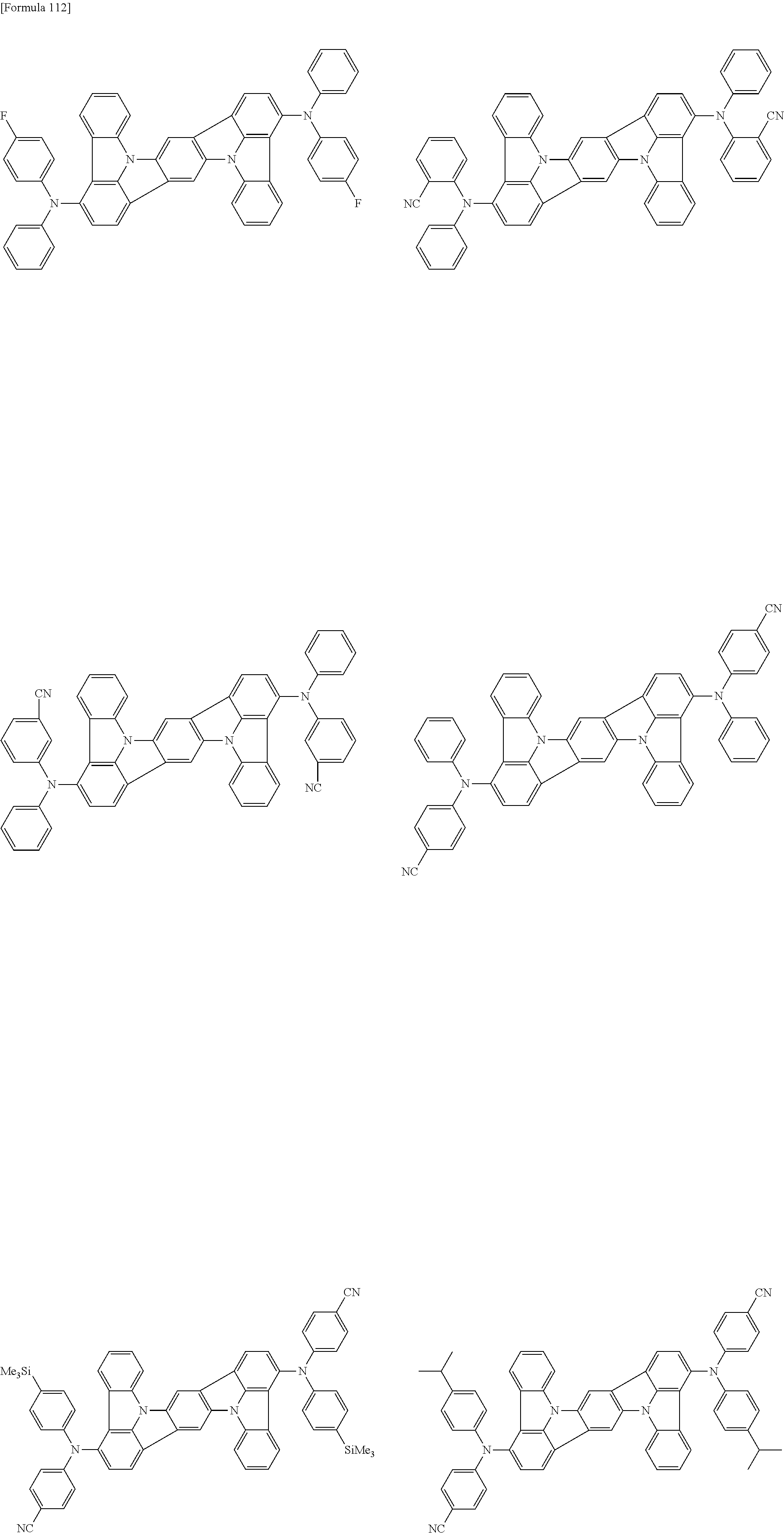

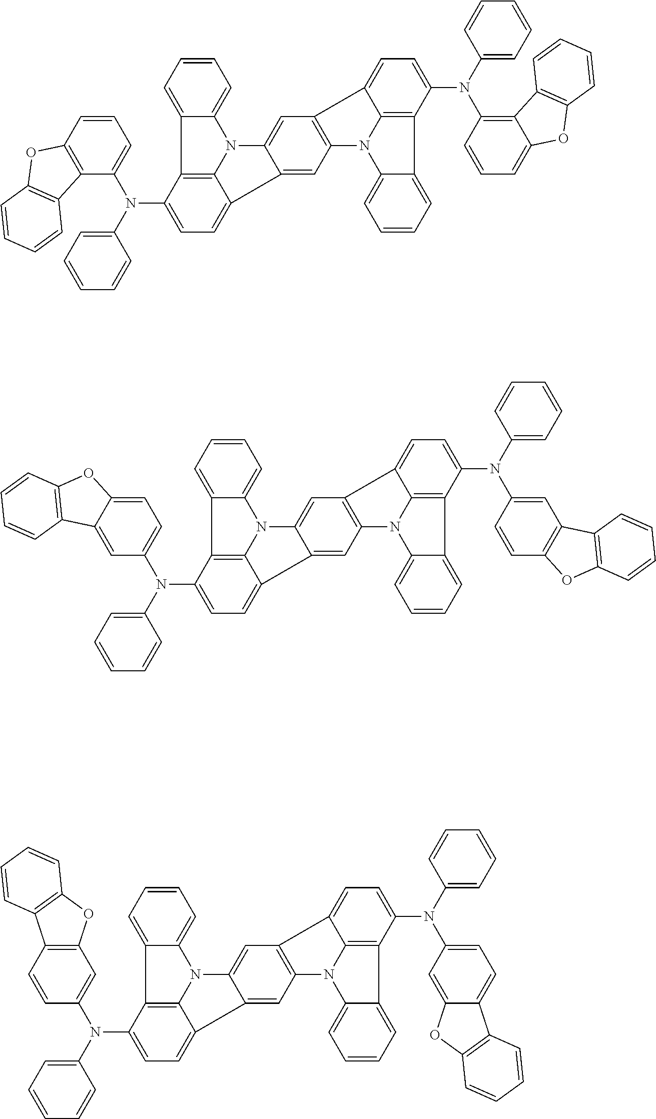 [SMILES: c1ccc(N(c2cccc3oc4ccccc4c23)c2ccc3c4cc5c(cc4n4c6ccccc6c2c34)c2ccc(N(c3ccccc3)c3cccc4oc6ccccc6c34)c3c4ccccc4n5c23)cc1 ; c1ccc(N(c2ccc3oc4ccccc4c3c2)c2ccc3c4cc5c(cc4n4c6ccccc6c2c34)c2ccc(N(c3ccccc3)c3ccc4oc6ccccc6c4c3)c3c4ccccc4n5c23)cc1 ; c1ccc(N(c2ccc3c(c2)oc2ccccc23)c2ccc3c4cc5c(cc4n4c6ccccc6c2c34)c2ccc(N(c3ccccc3)c3ccc4c(c3)oc3ccccc34)c3c4ccccc4n5c23)cc1]

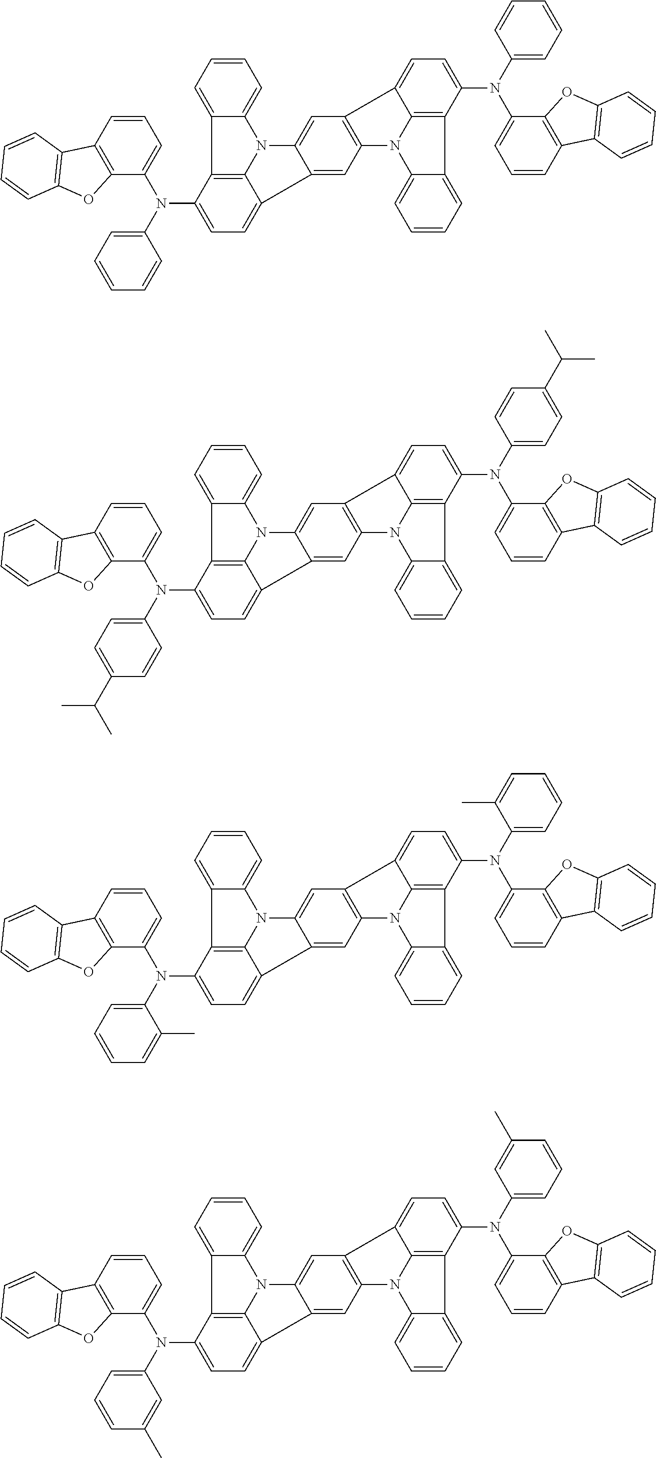 [SMILES: c1ccc(N(c2cccc3c2oc2ccccc23)c2ccc3c4cc5c(cc4n4c6ccccc6c2c34)c2ccc(N(c3ccccc3)c3cccc4c3oc3ccccc34)c3c4ccccc4n5c23)cc1 ; CC(C)c1ccc(N(c2cccc3c2oc2ccccc23)c2ccc3c4cc5c(cc4n4c6ccccc6c2c34)c2ccc(N(c3ccc(C(C)C)cc3)c3cccc4c3oc3ccccc34)c3c4ccccc4n5c23)cc1 ; Cc1ccccc1N(c1cccc2c1oc1ccccc12)c1ccc2c3cc4c(cc3n3c5ccccc5c1c23)c1ccc(N(c2ccccc2C)c2cccc3c2oc2ccccc23)c2c3ccccc3n4c12 ; Cc1cccc(N(c2cccc3c2oc2ccccc23)c2ccc3c4cc5c(cc4n4c6ccccc6c2c34)c2ccc(N(c3cccc(C)c3)c3cccc4c3oc3ccccc34)c3c4ccccc4n5c23)c1]

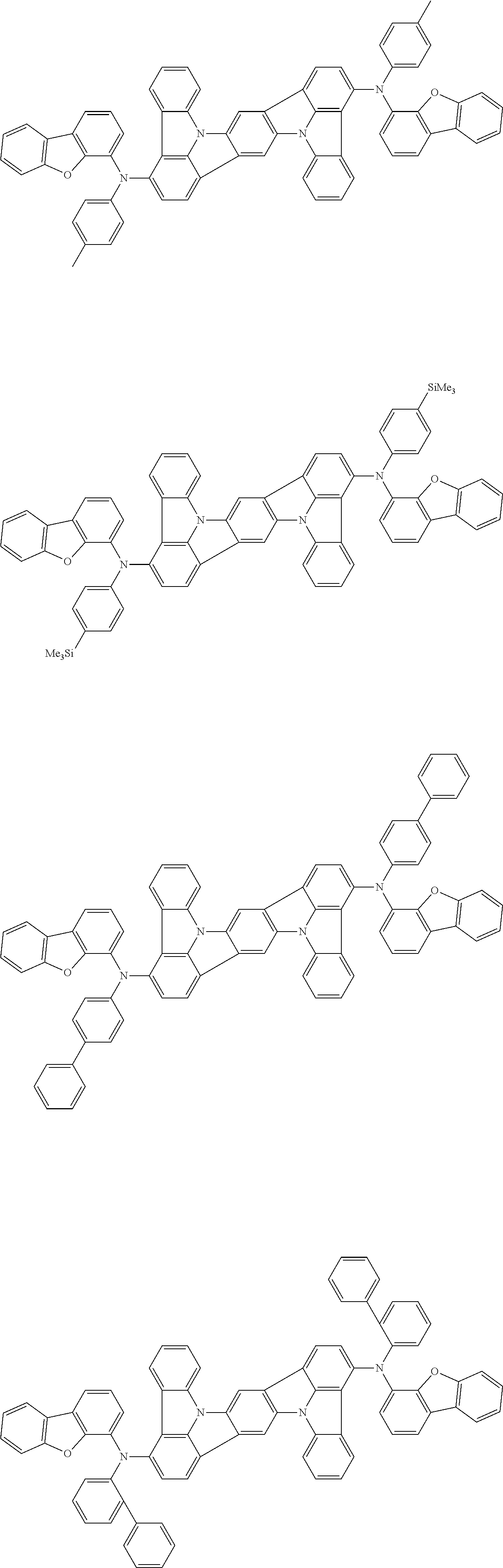

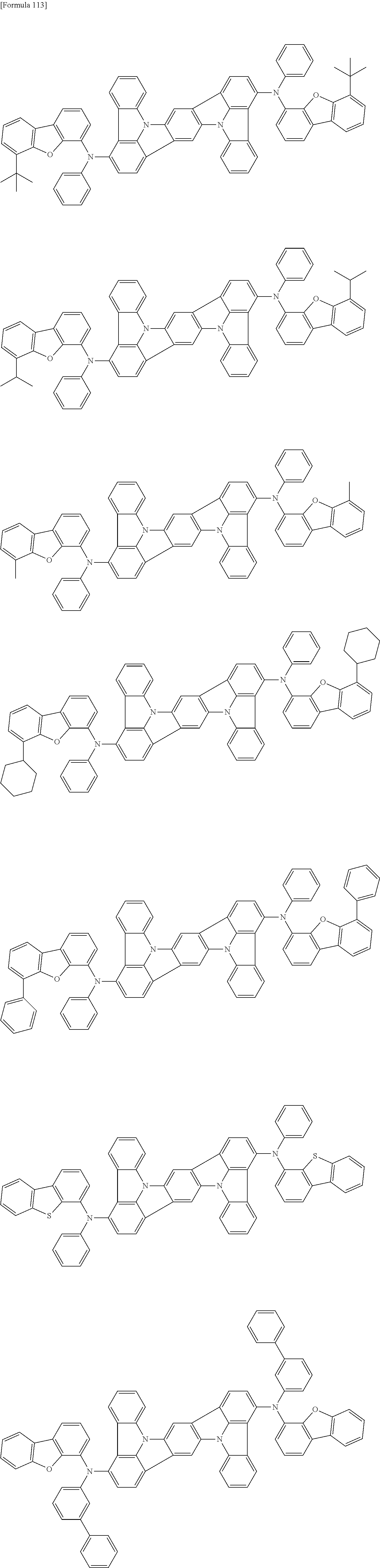

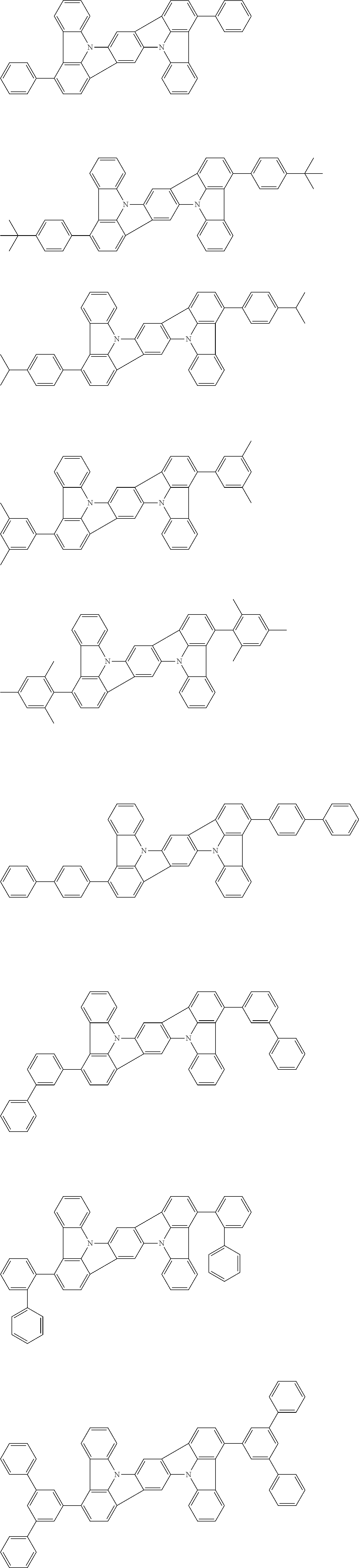

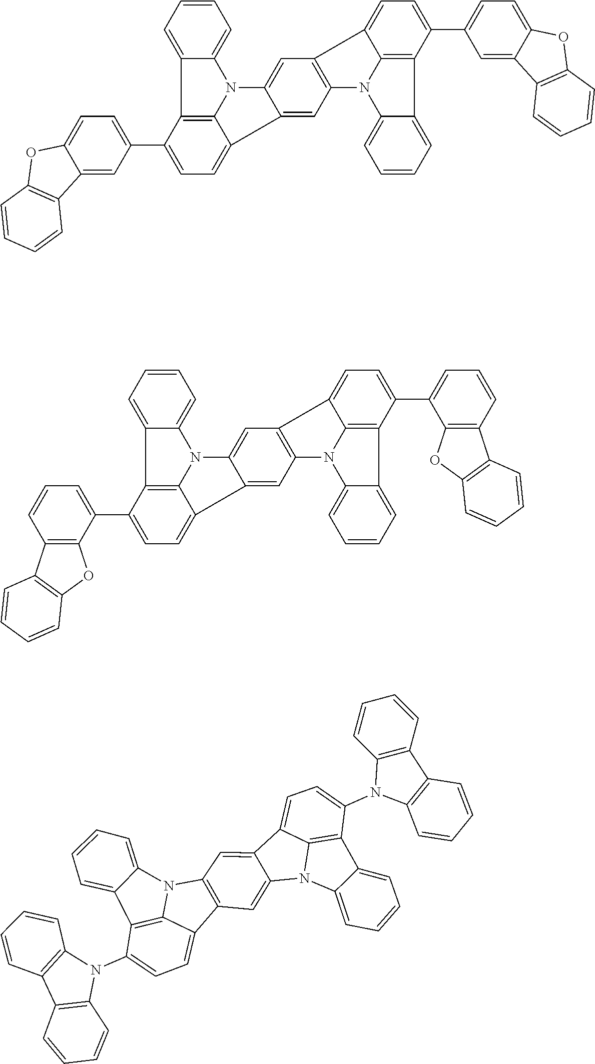 [SMILES: c1ccc2c(c1)oc1ccc(-c3ccc4c5cc6c(cc5n5c7ccccc7c3c45)c3ccc(-c4ccc5oc7ccccc7c5c4)c4c5ccccc5n6c34)cc12 ; c1ccc2c(c1)oc1c(-c3ccc4c5cc6c(cc5n5c7ccccc7c3c45)c3ccc(-c4cccc5c4oc4ccccc45)c4c5ccccc5n6c34)cccc12 ; c1ccc2c(c1)c1ccccc1n2-c1ccc2c3cc4c(cc3n3c5ccccc5c1c23)c1ccc(-n2c3ccccc3c3ccccc32)c2c3ccccc3n4c12]

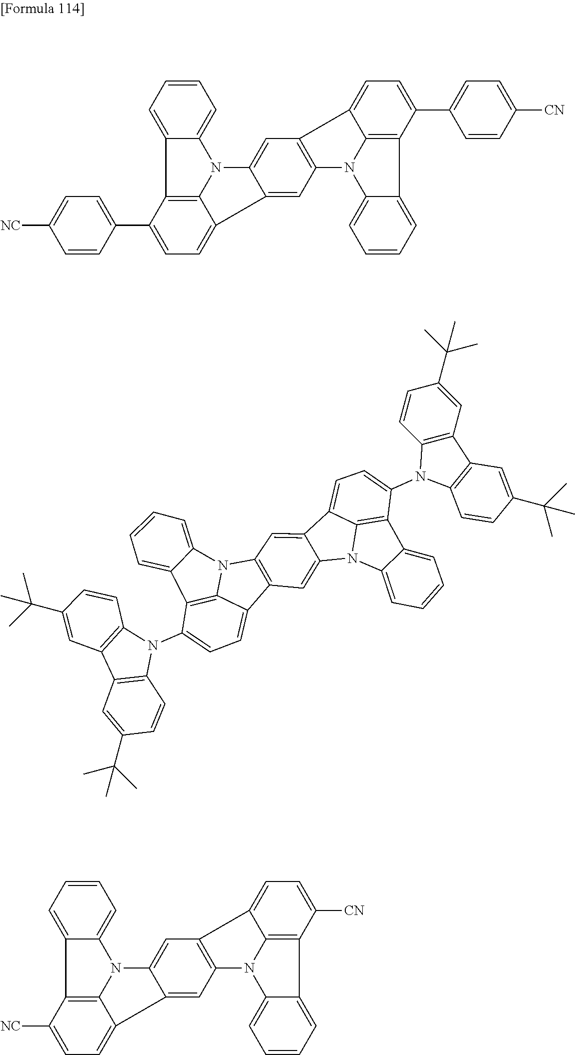 [SMILES: N#Cc1ccc(-c2ccc3c4cc5c(cc4n4c6ccccc6c2c34)c2ccc(-c3ccc(C#N)cc3)c3c4ccccc4n5c23)cc1 ; CC(C)(C)c1ccc2c(c1)c1cc(C(C)(C)C)ccc1n2-c1ccc2c3cc4c(cc3n3c5ccccc5c1c23)c1ccc(-n2c3ccc(C(C)(C)C)cc3c3cc(C(C)(C)C)ccc32)c2c3ccccc3n4c12 ; N#Cc1ccc2c3cc4c(cc3n3c5ccccc5c1c23)c1ccc(C#N)c2c3ccccc3n4c12]

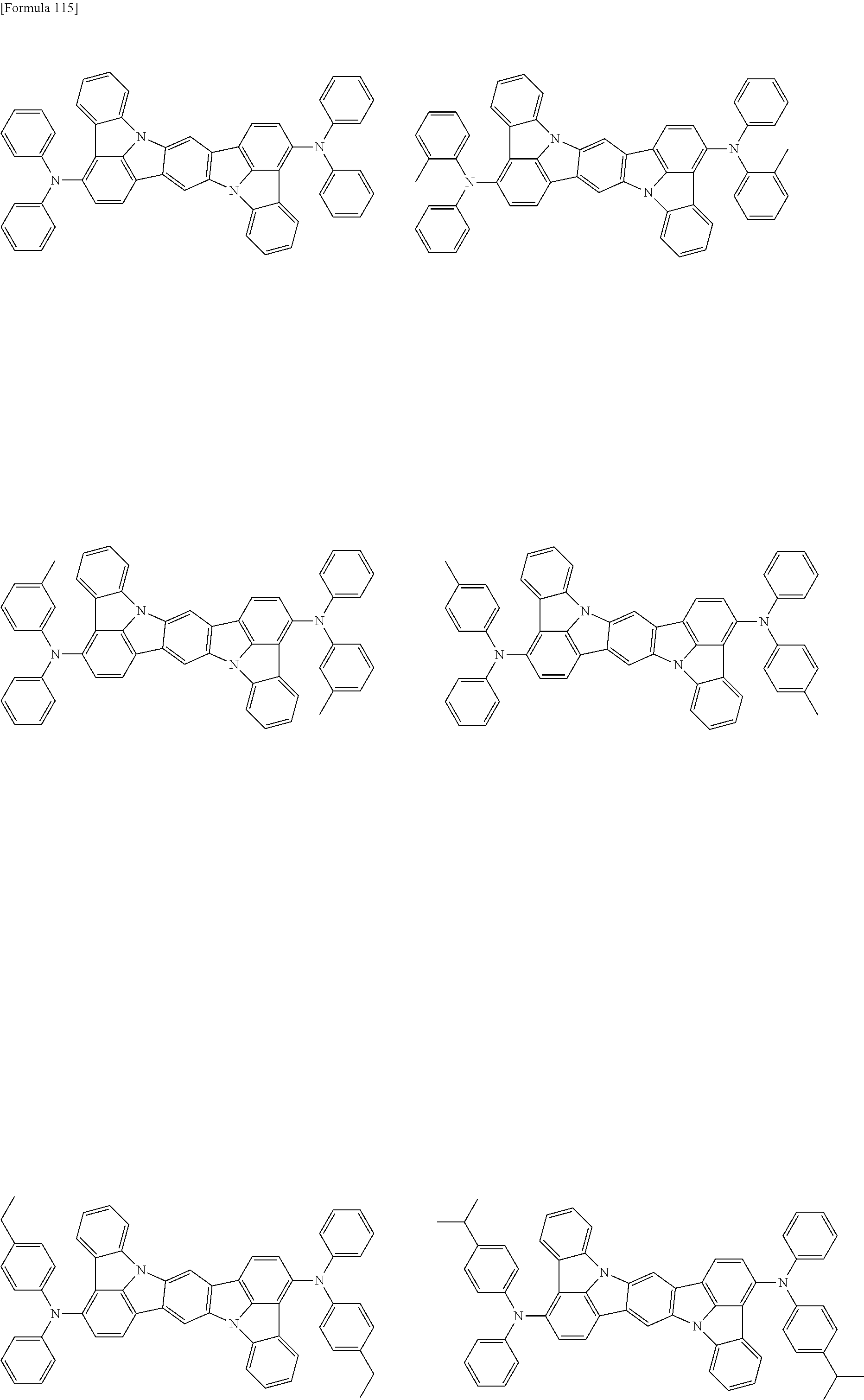

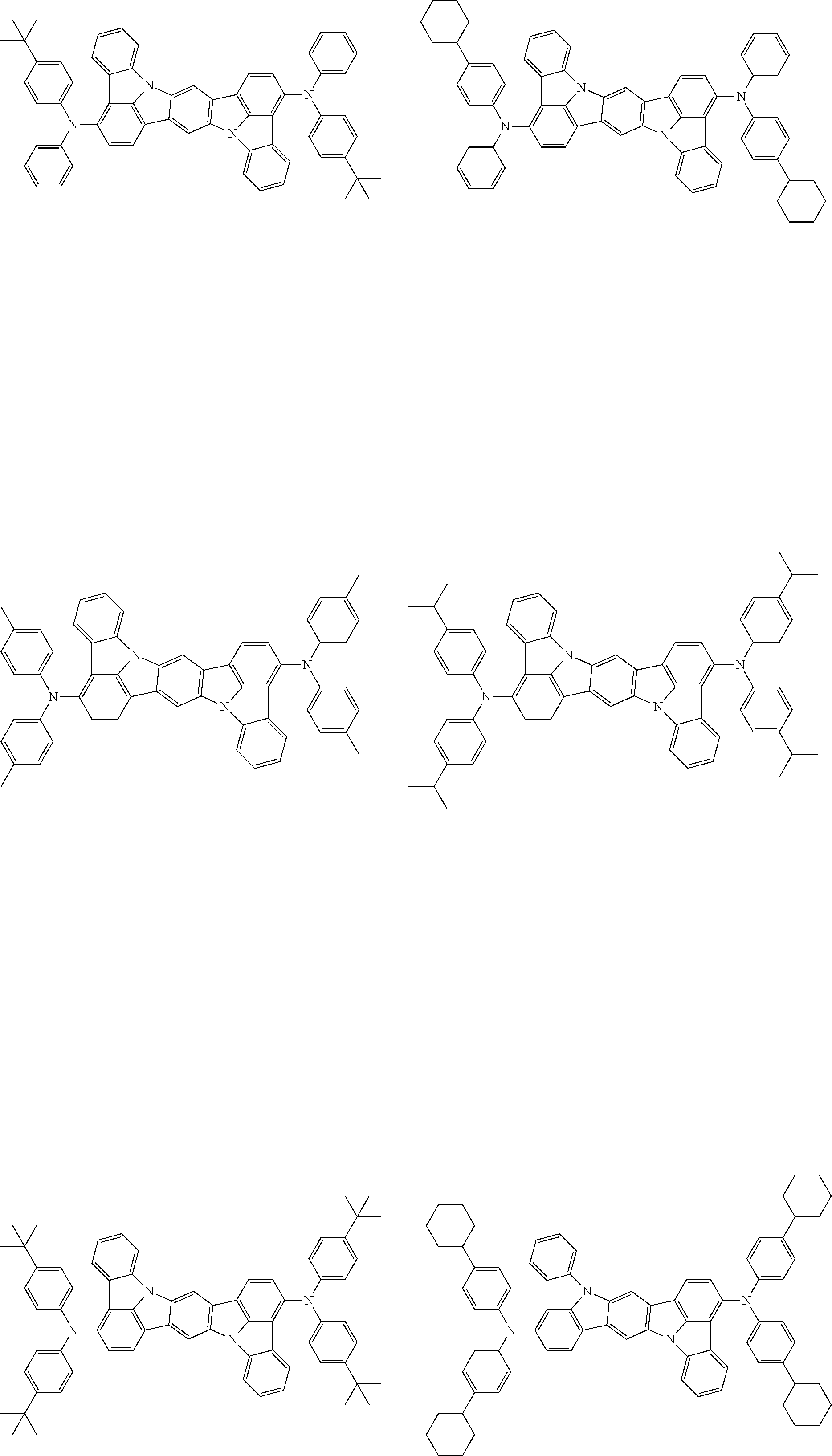

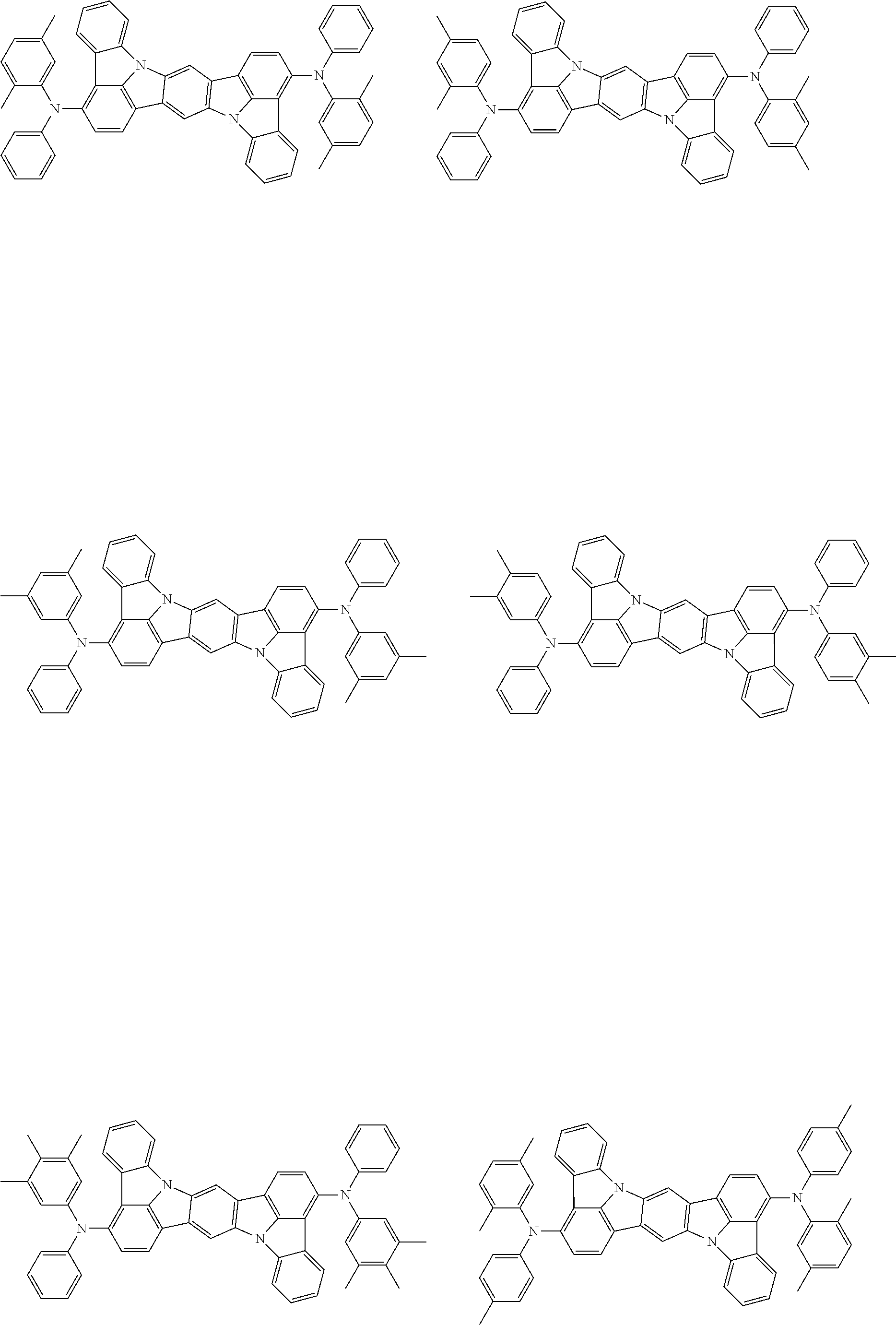

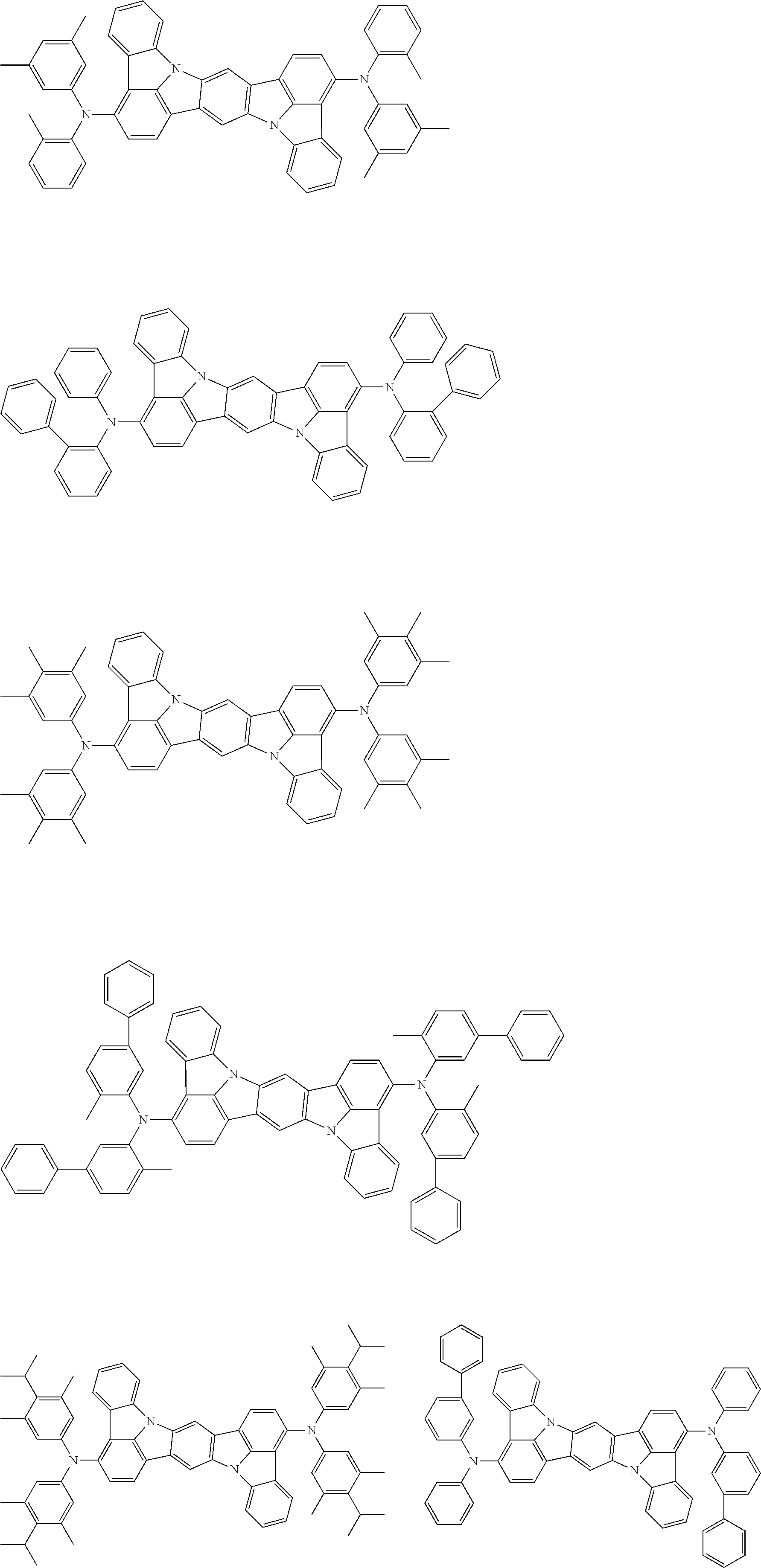

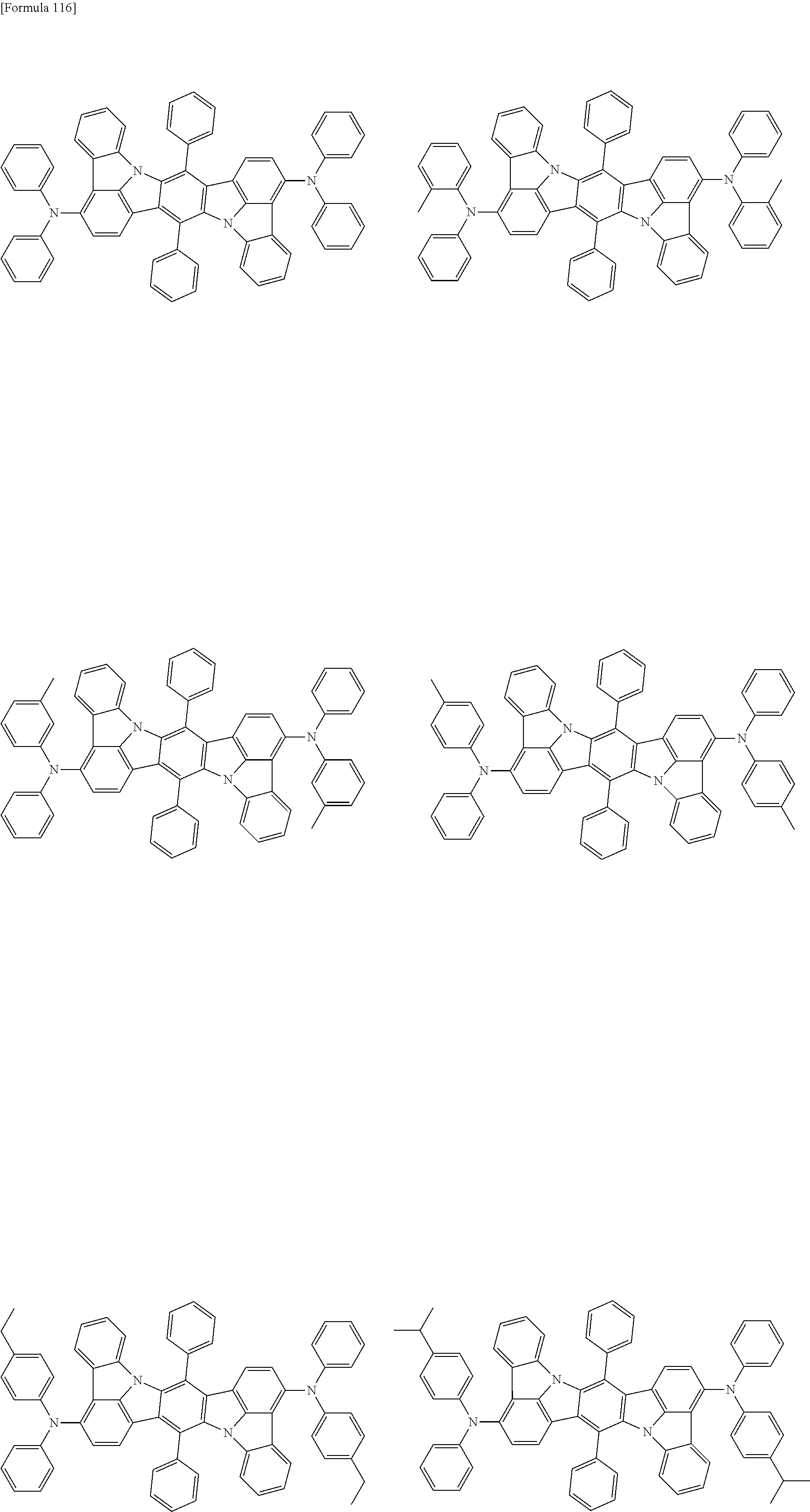

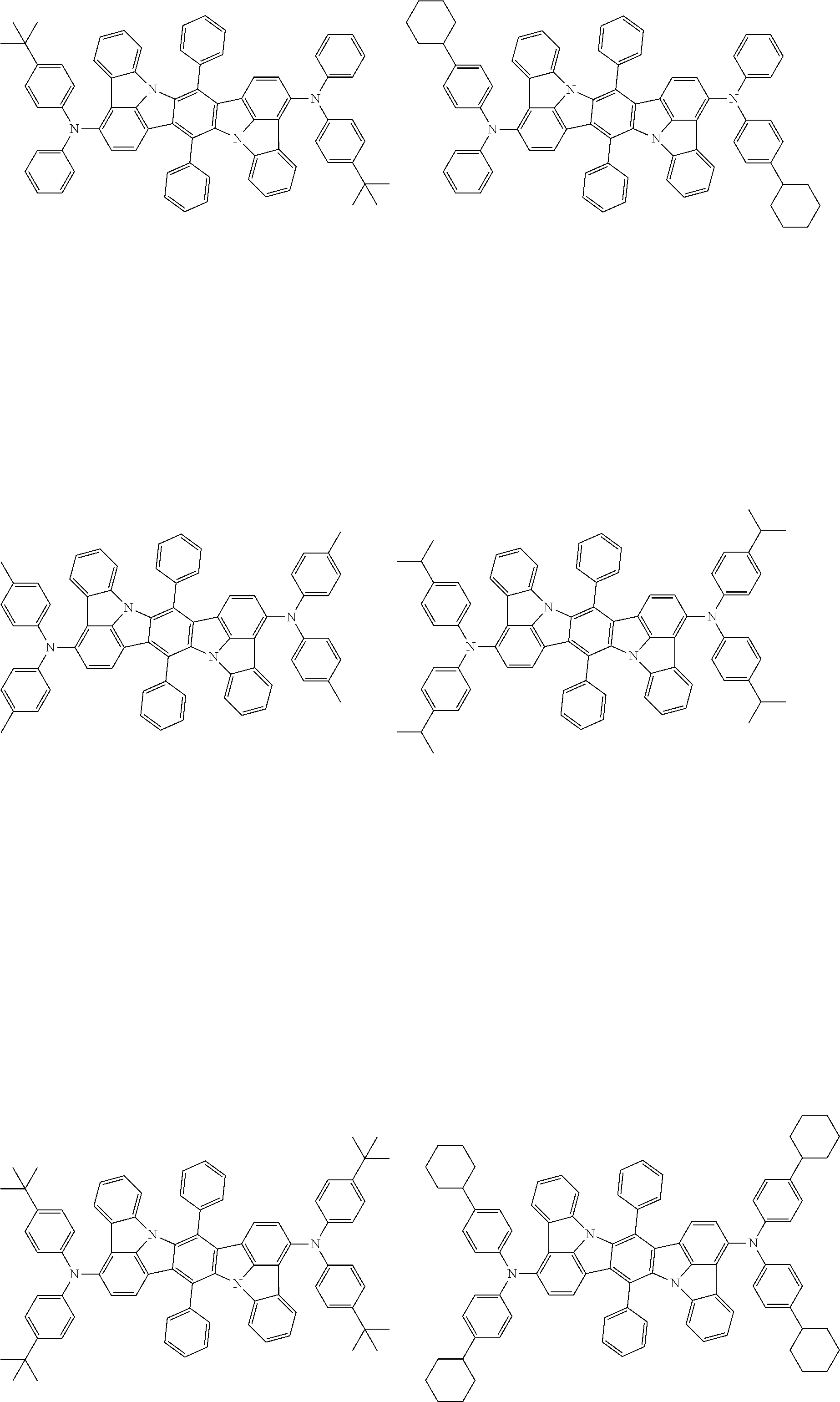

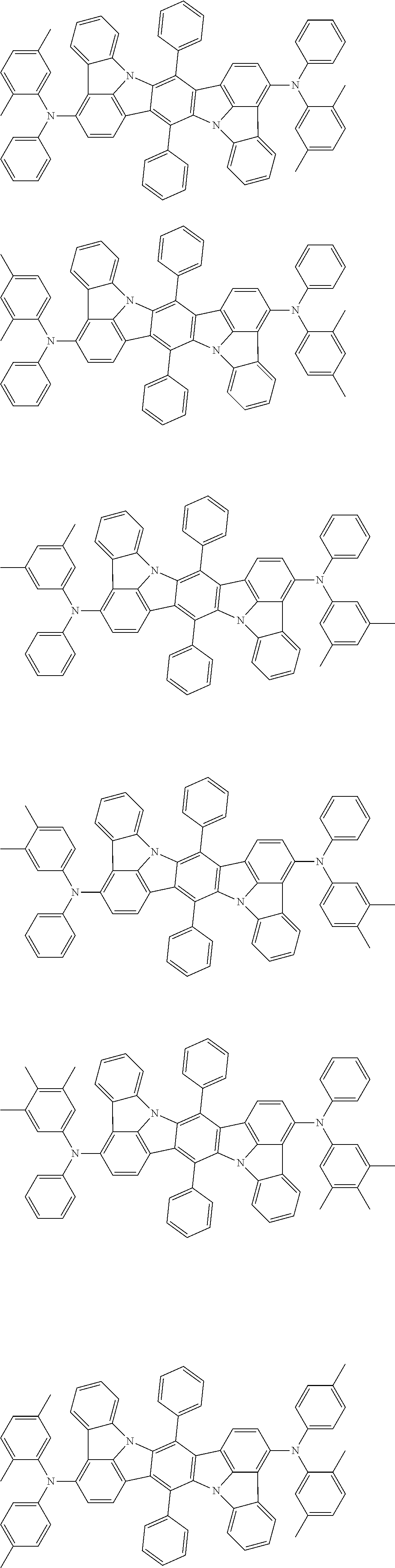

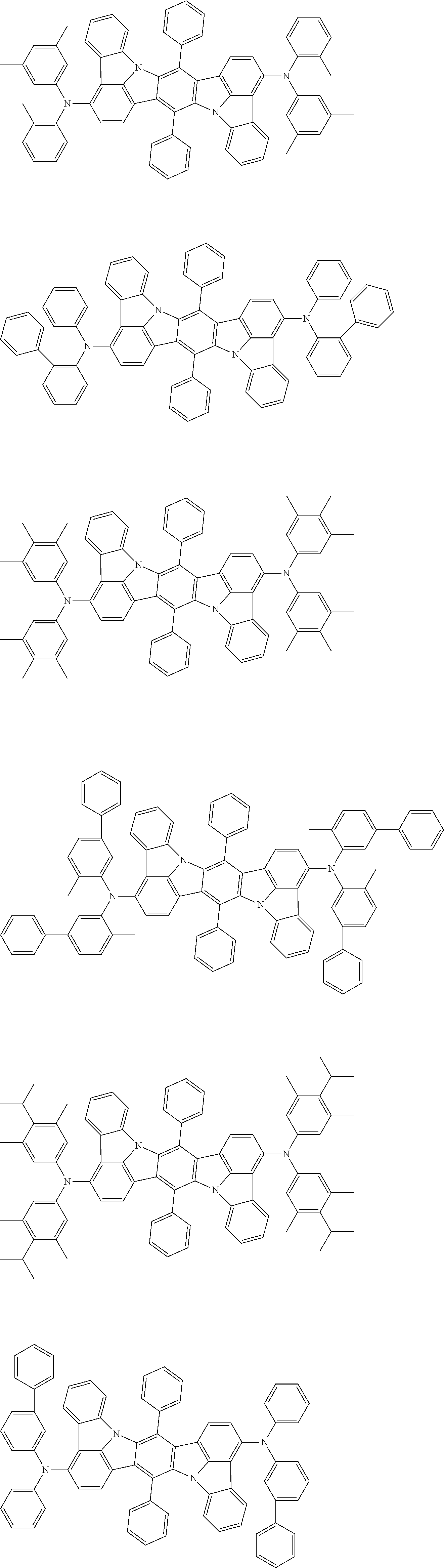

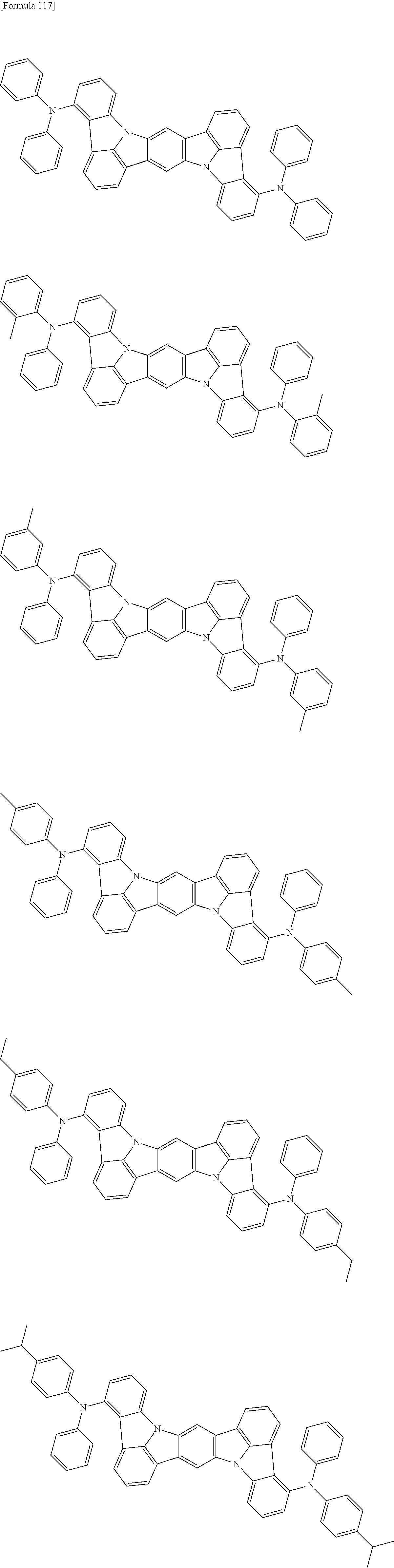

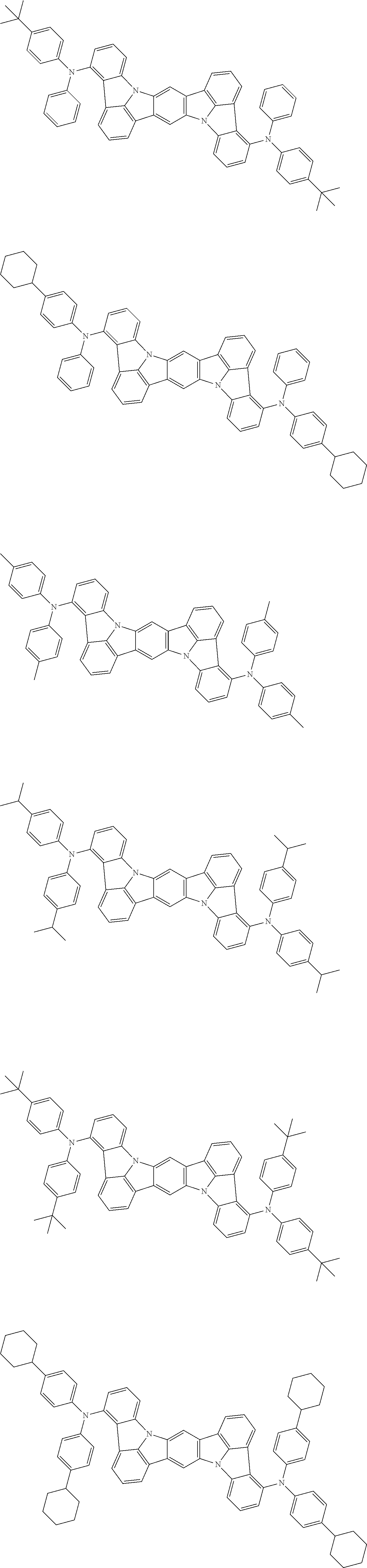

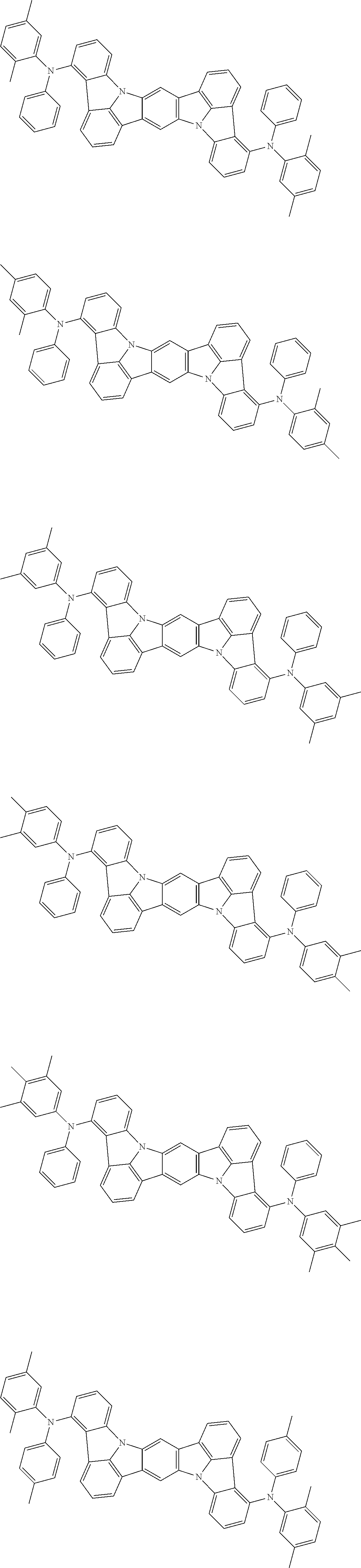

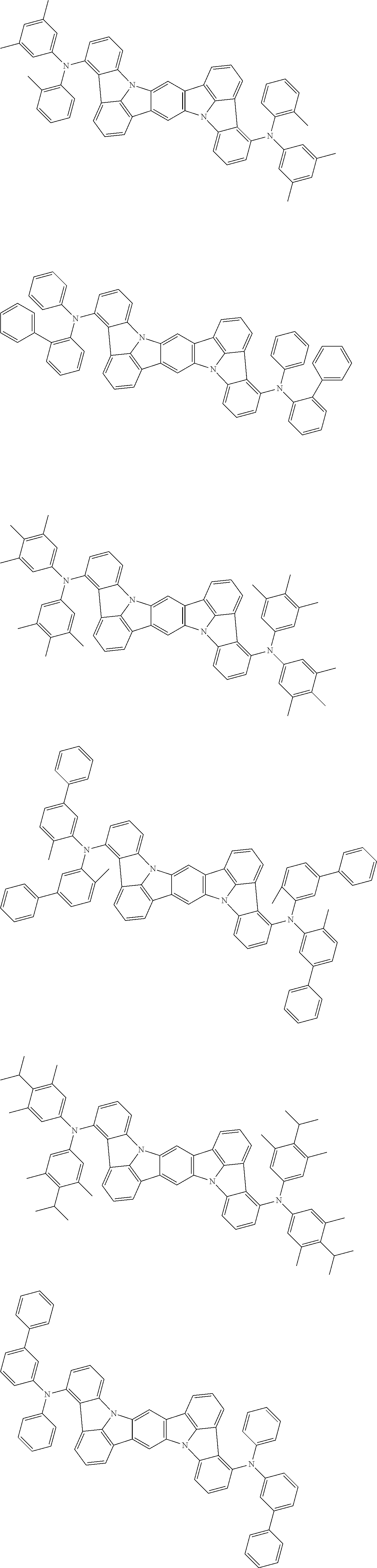

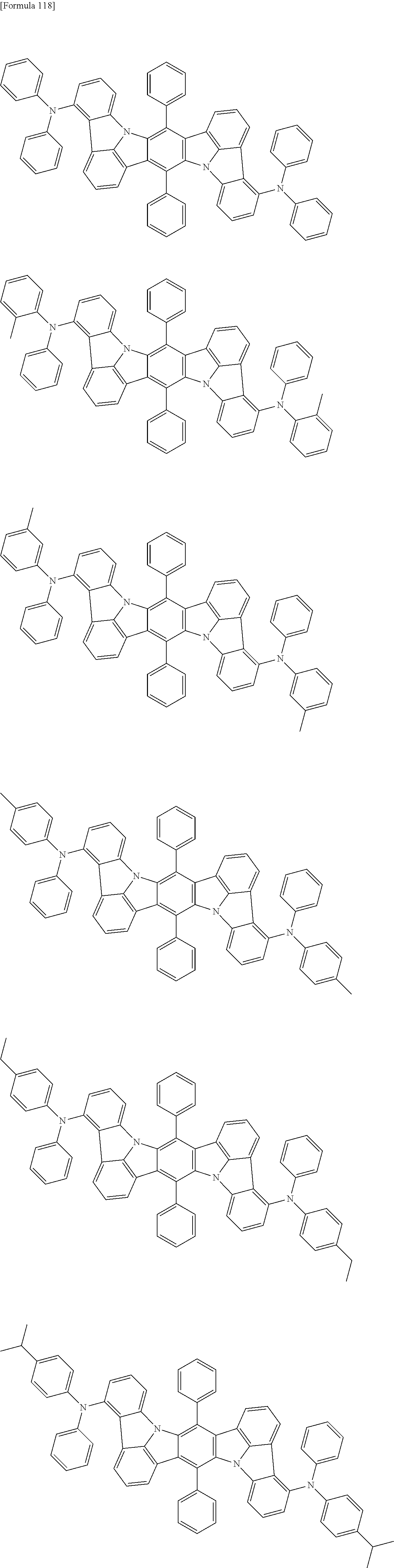

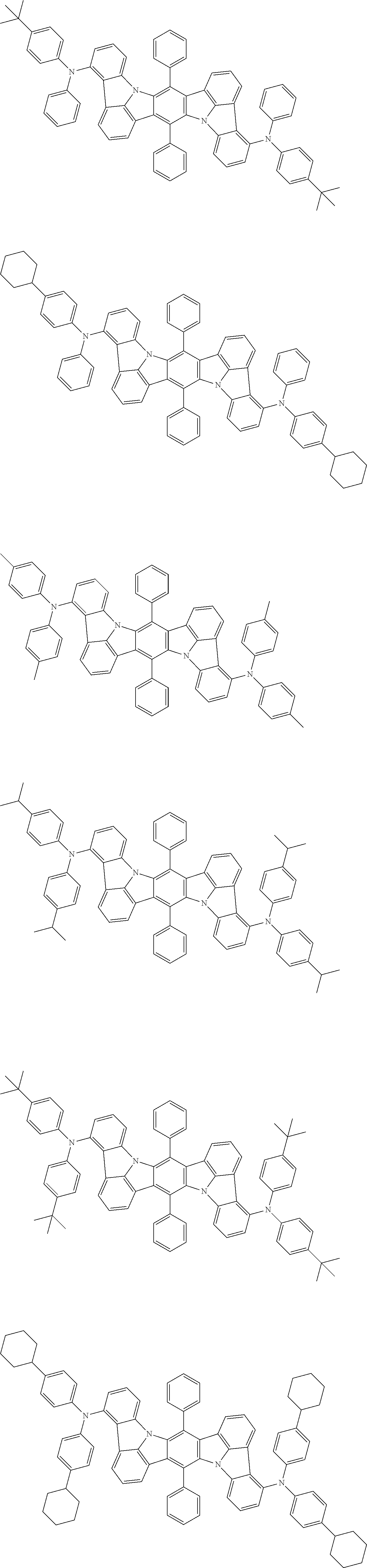

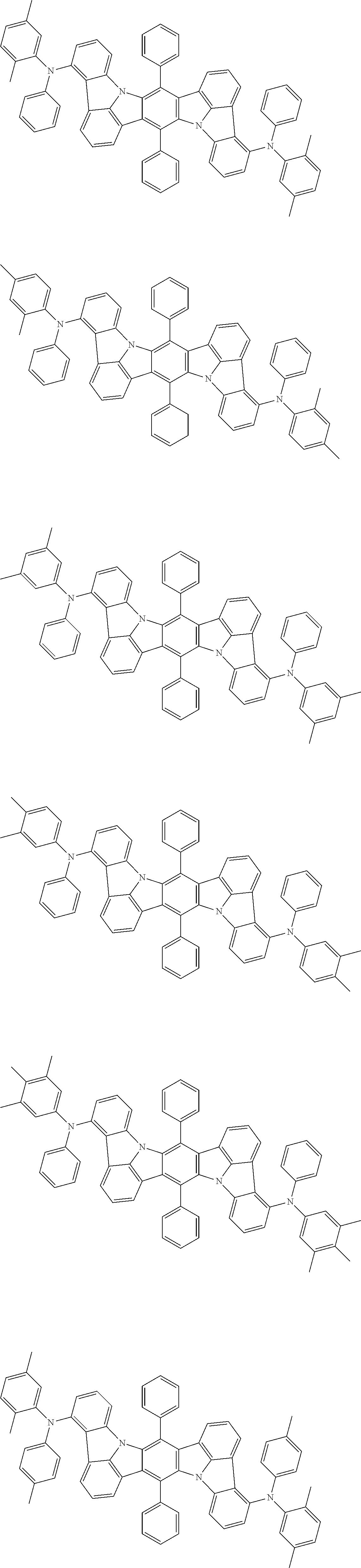

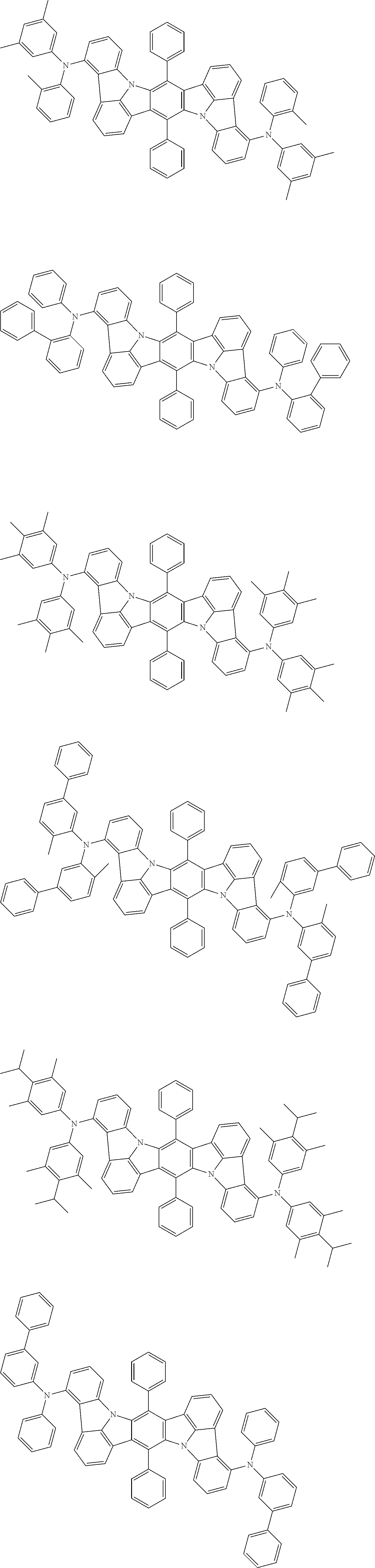

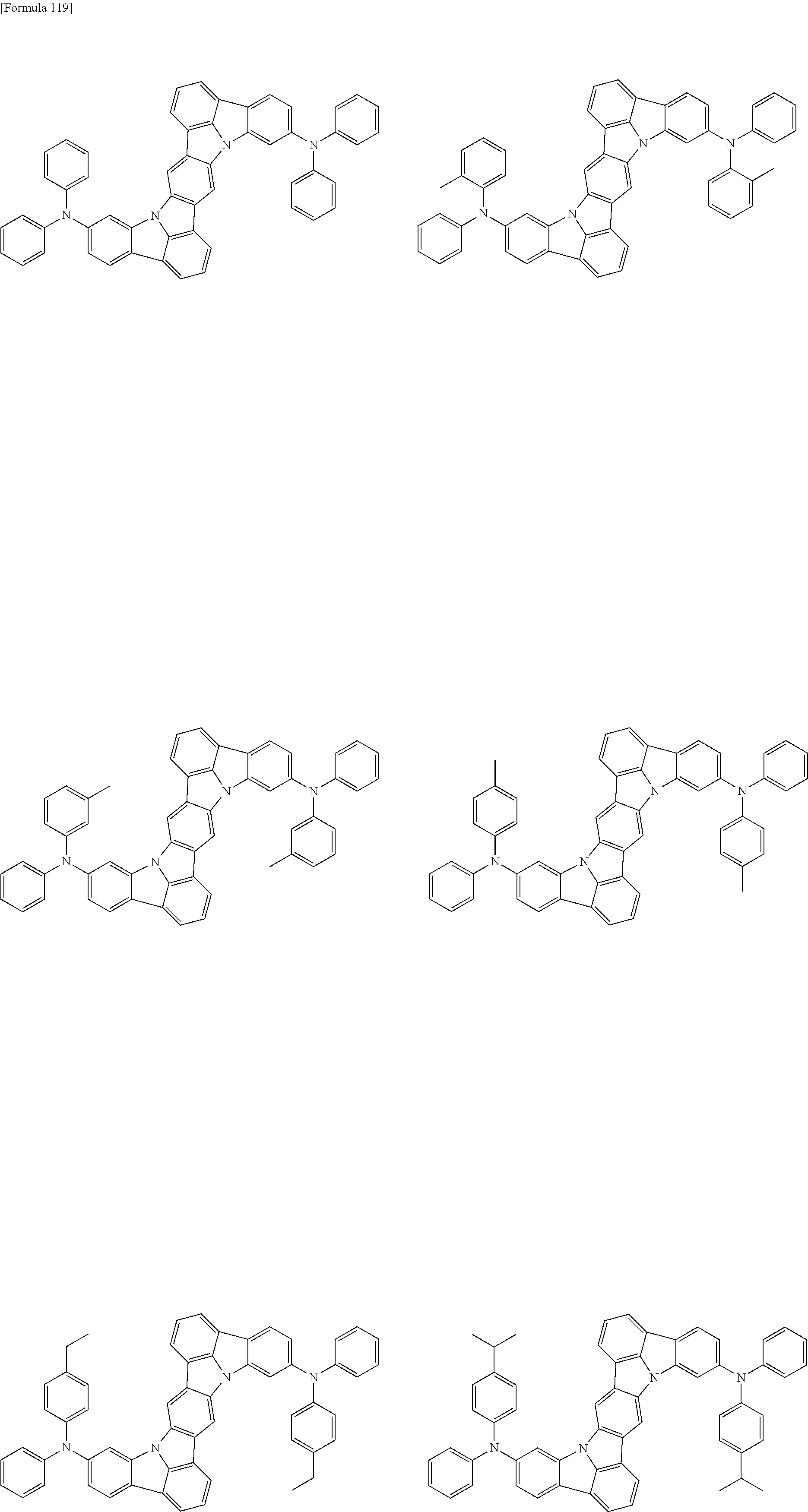

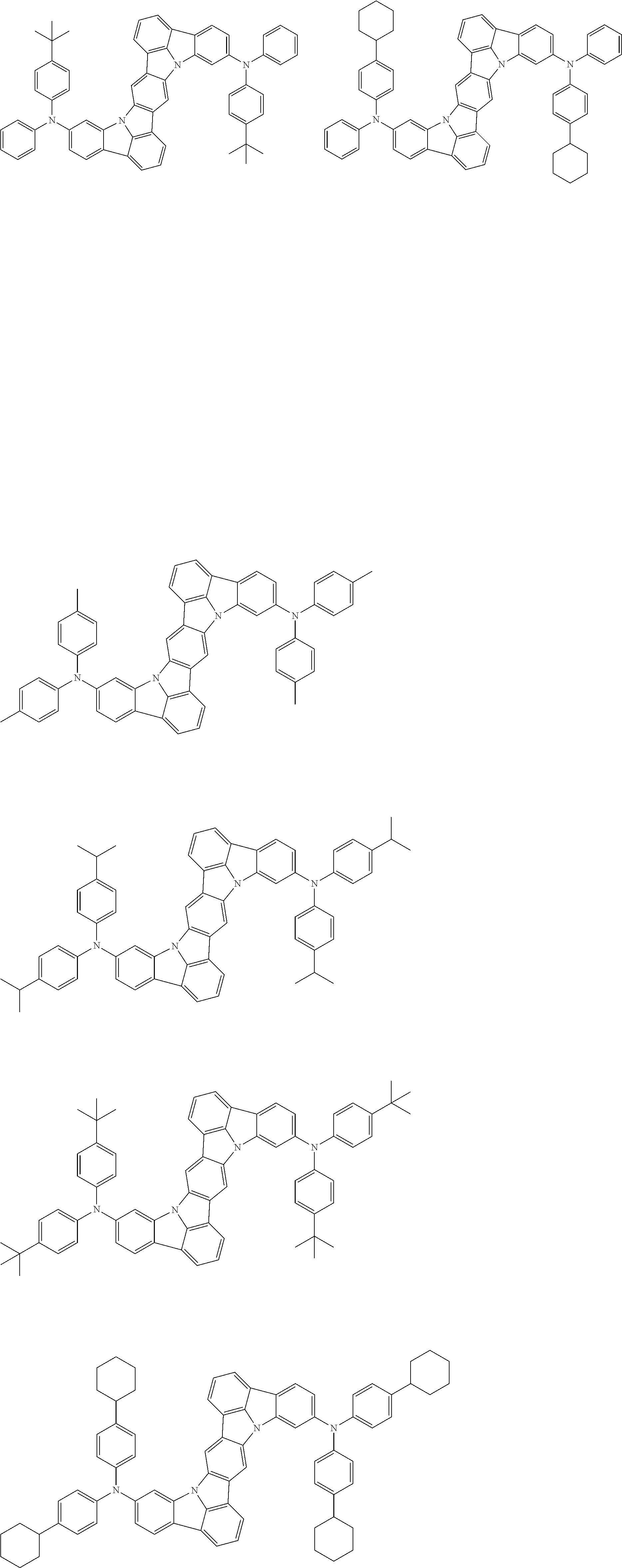

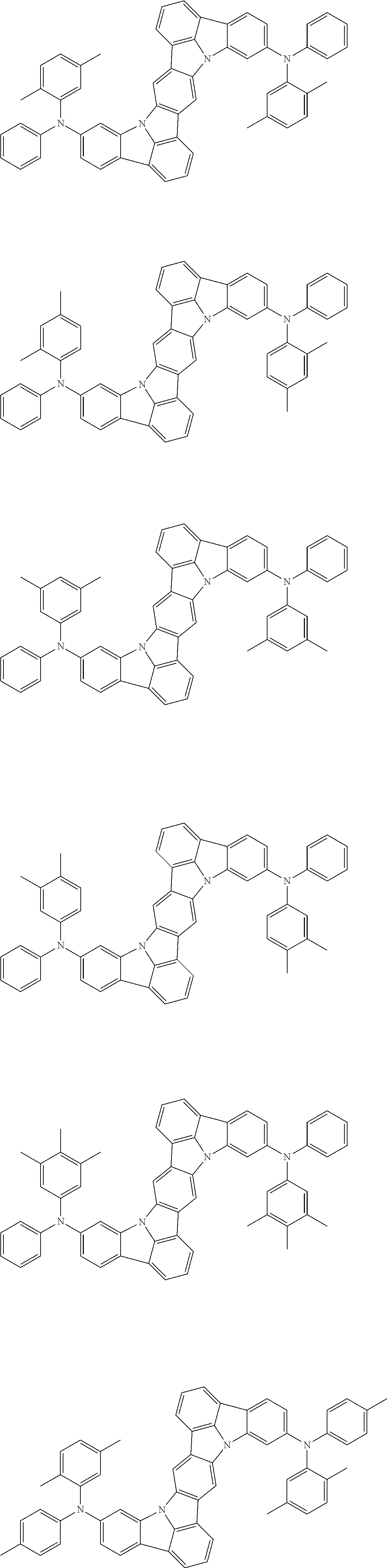

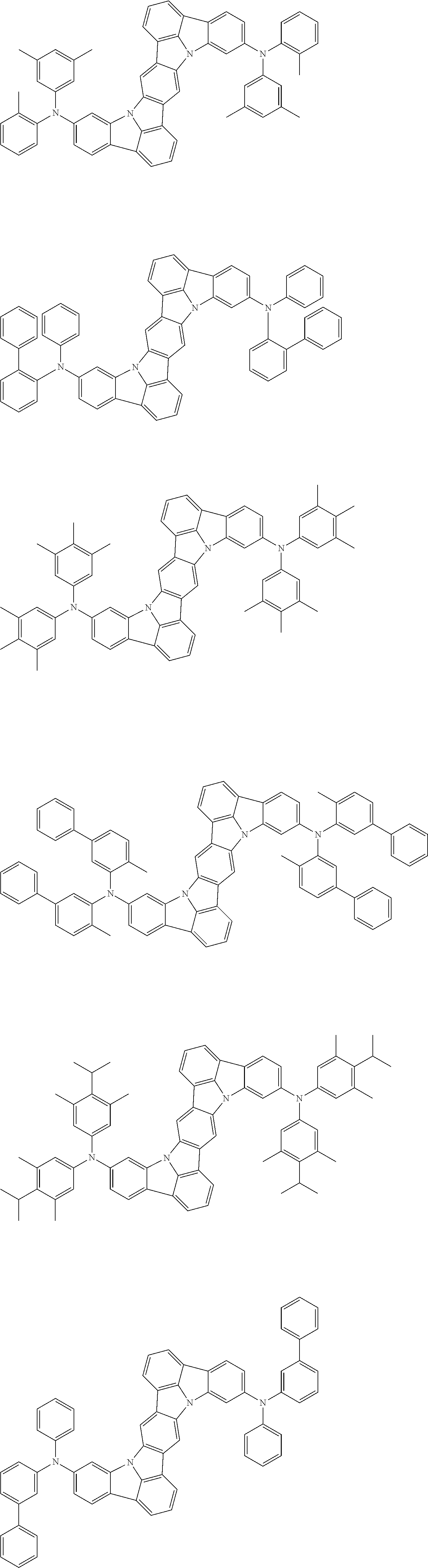

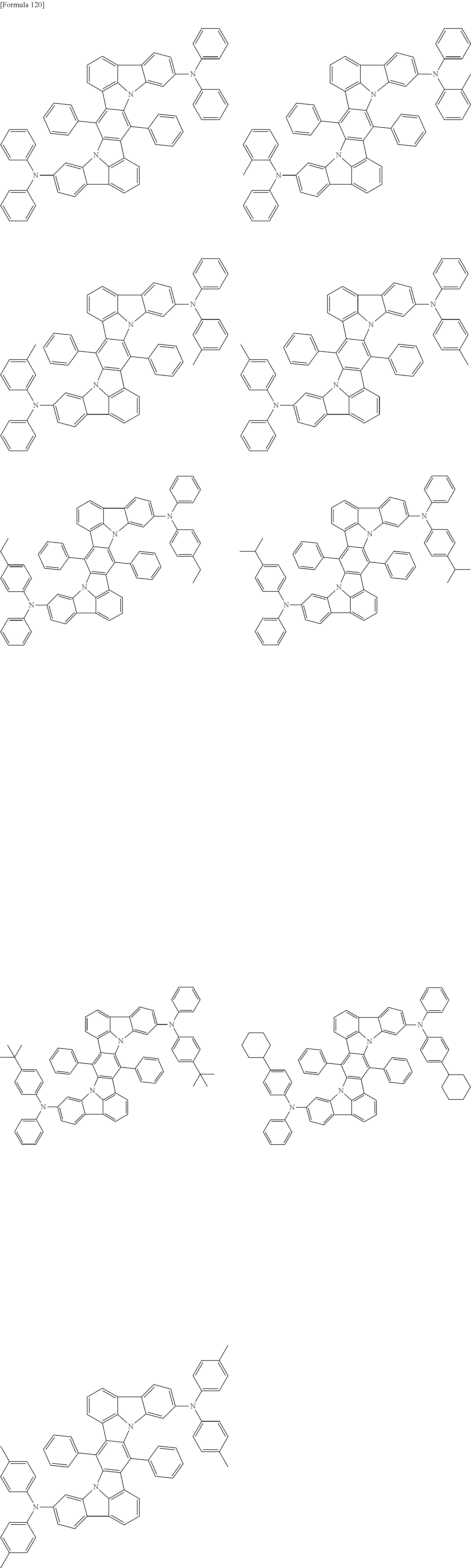

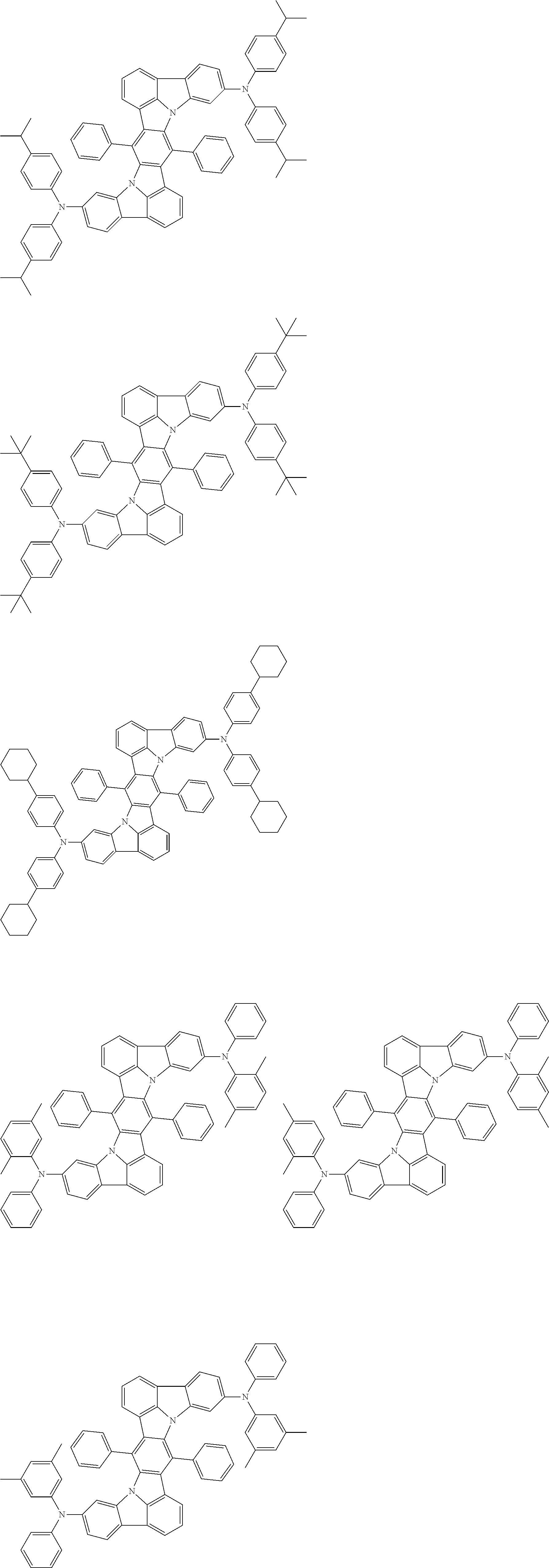

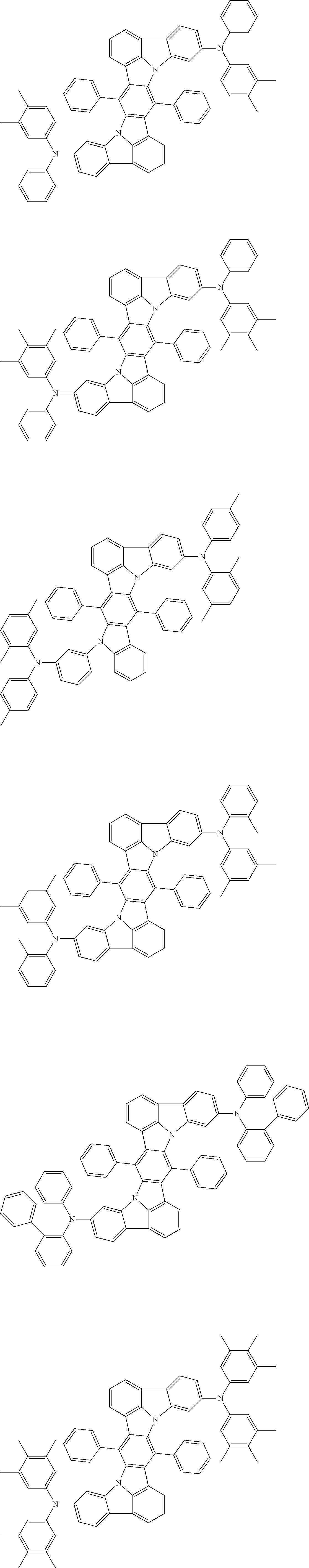

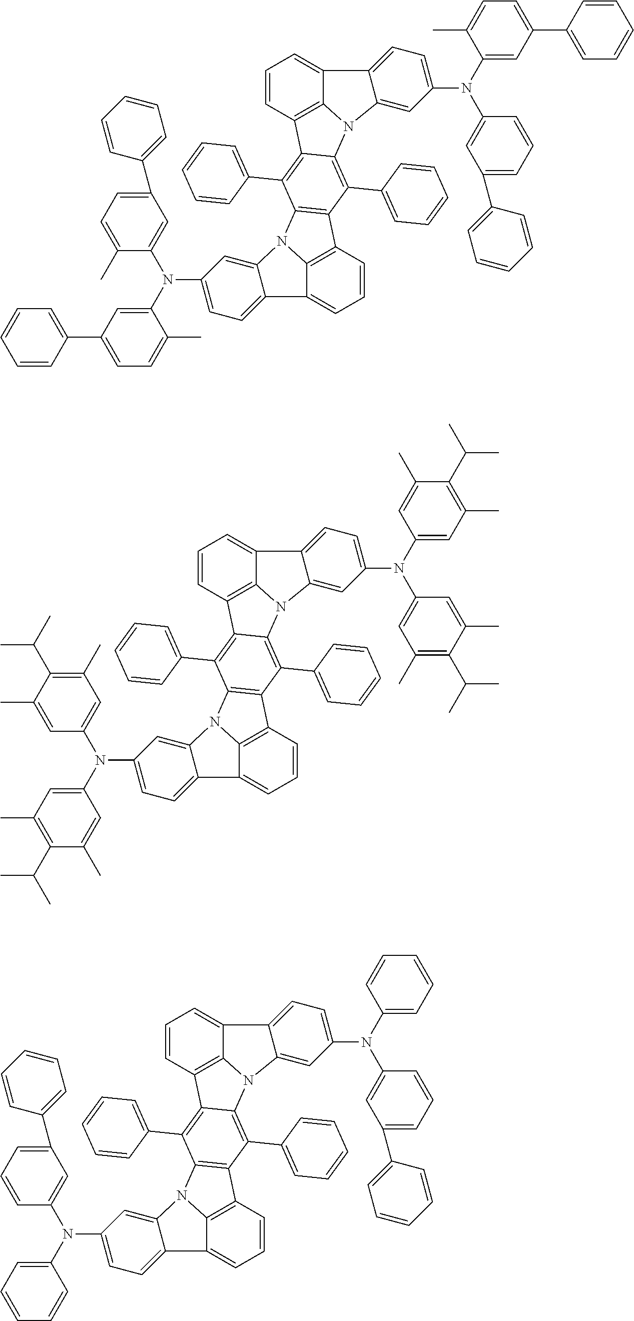 [SMILES: Cc1ccc(-c2ccccc2)cc1N(c1cccc(-c2ccccc2)c1)c1ccc2c3cccc4c5c(-c6ccccc6)c6c(c(-c7ccccc7)c5n(c2c1)c34)c1cccc2c3ccc(N(c4cc(-c5ccccc5)ccc4C)c4cc(-c5ccccc5)ccc4C)cc3n6c21 ; Cc1cc(N(c2cc(C)c(C(C)C)c(C)c2)c2ccc3c4cccc5c6c(-c7ccccc7)c7c(c(-c8ccccc8)c6n(c3c2)c45)c2cccc3c4ccc(N(c5cc(C)c(C(C)C)c(C)c5)c5cc(C)c(C(C)C)c(C)c5)cc4n7c32)cc(C)c1C(C)C ; c1ccc(-c2cccc(N(c3ccccc3)c3ccc4c5cccc6c7c(-c8ccccc8)c8c(c(-c9ccccc9)c7n(c4c3)c56)c3cccc4c5ccc(N(c6ccccc6)c6cccc(-c7ccccc7)c6)cc5n8c43)c2)cc1]

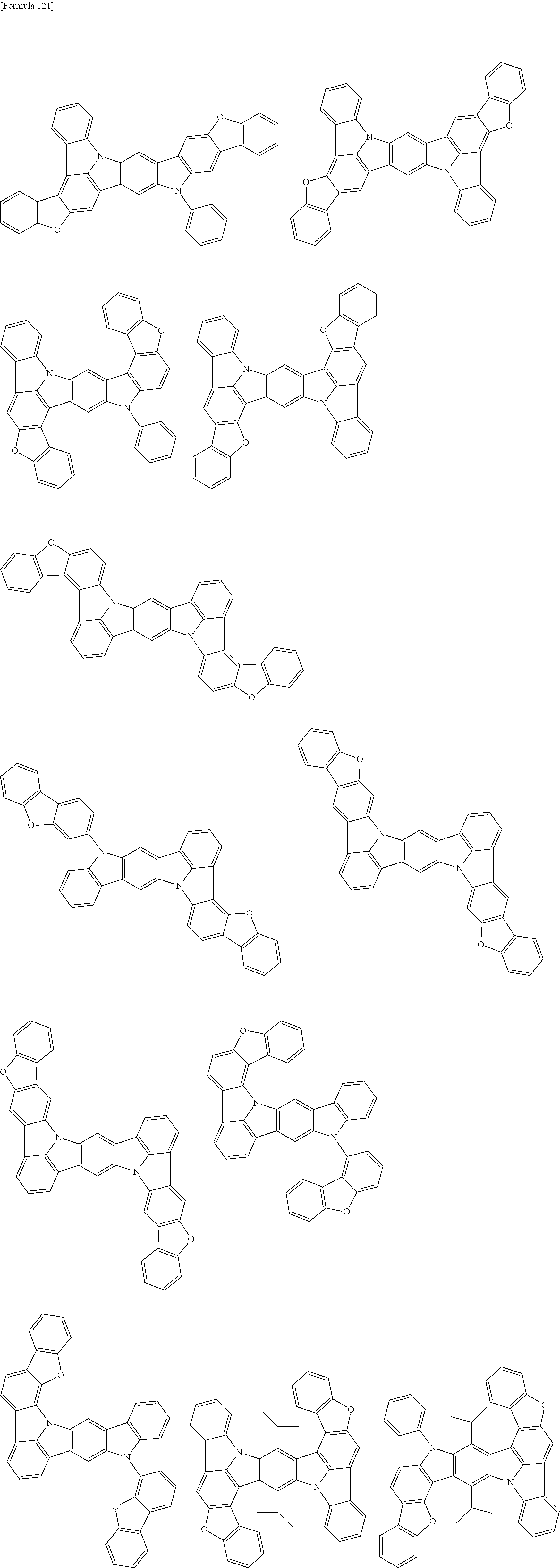

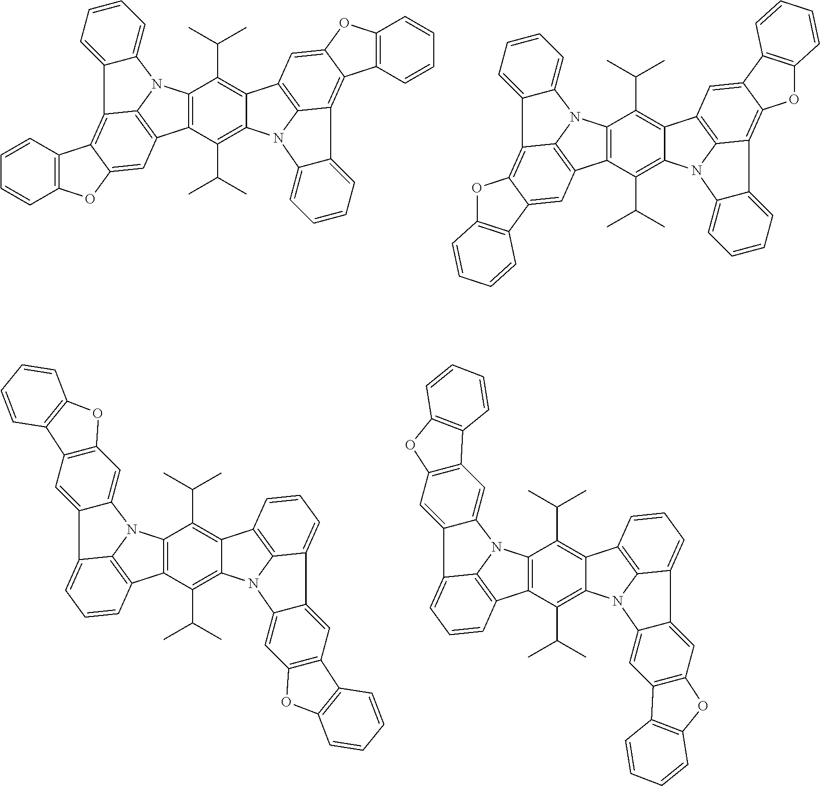

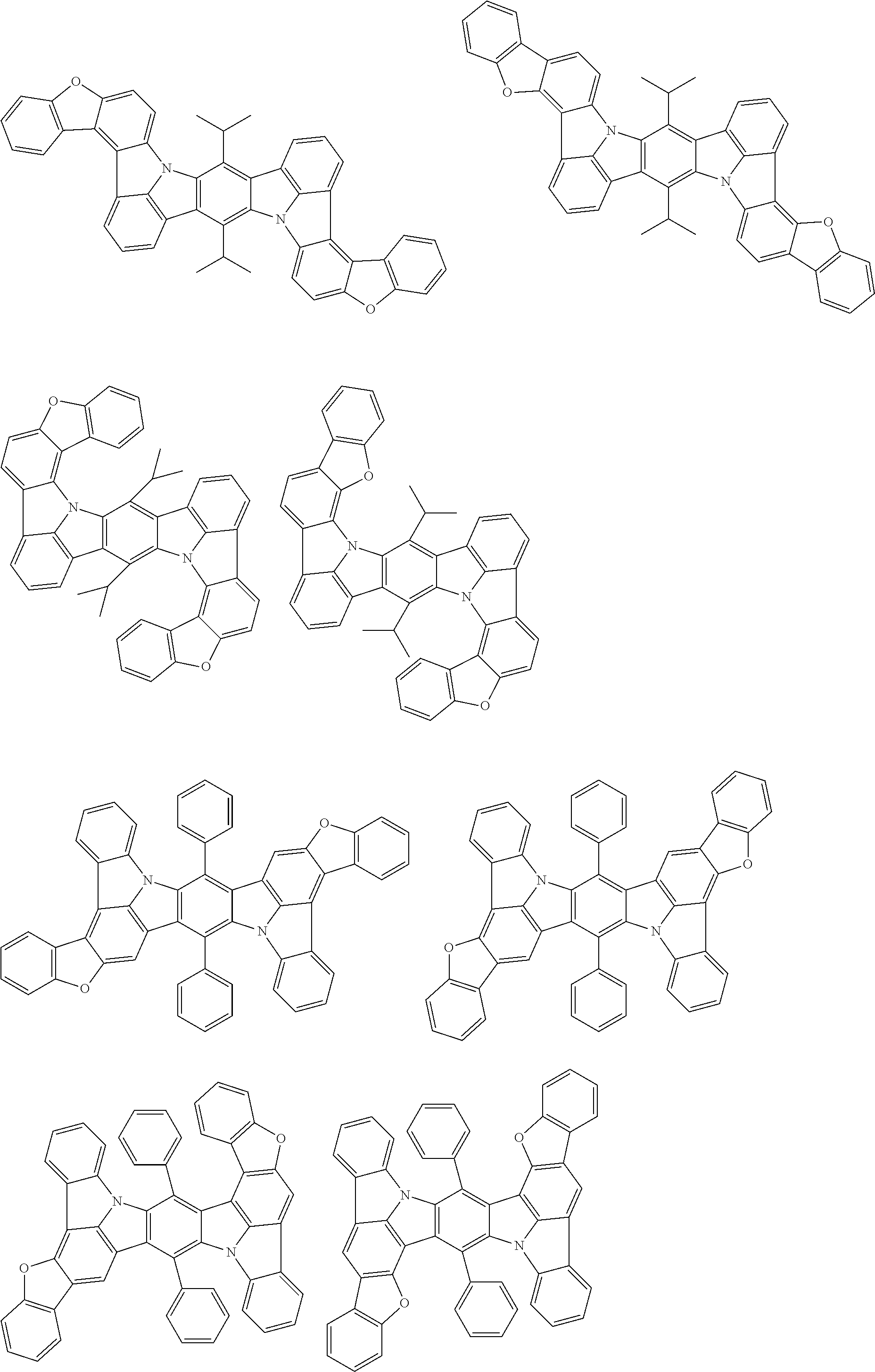

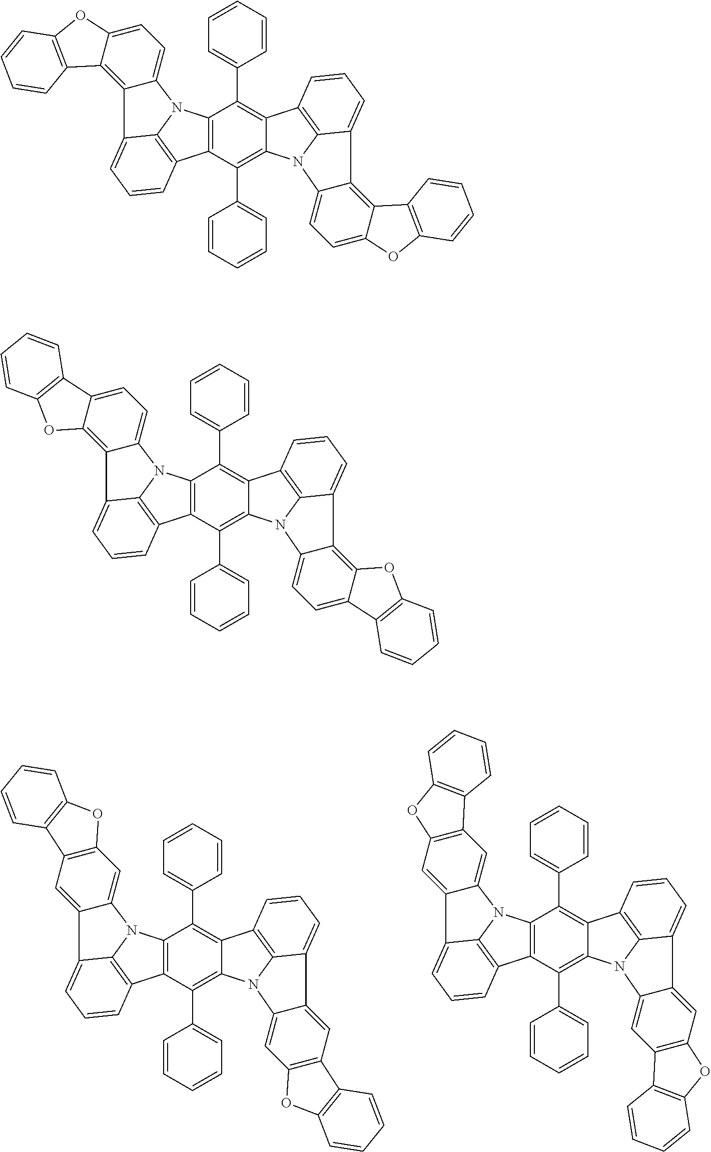

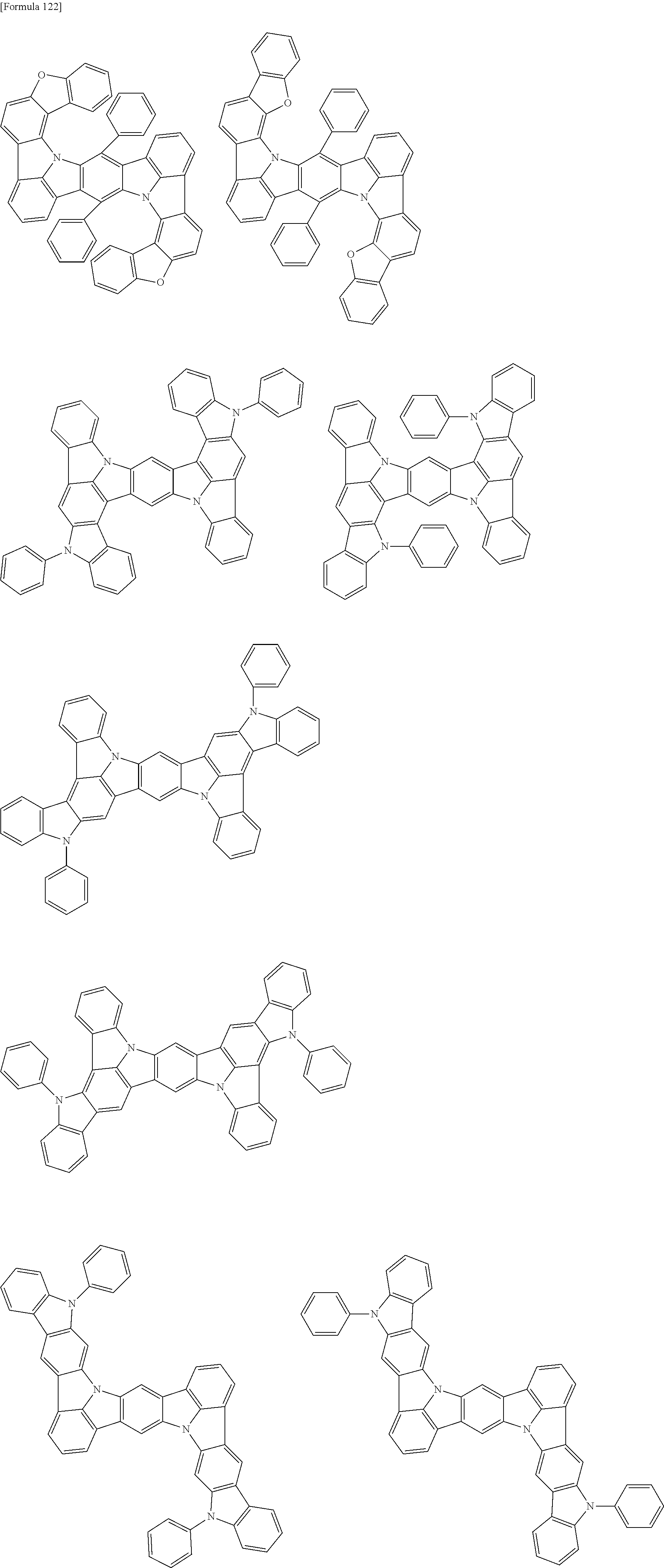

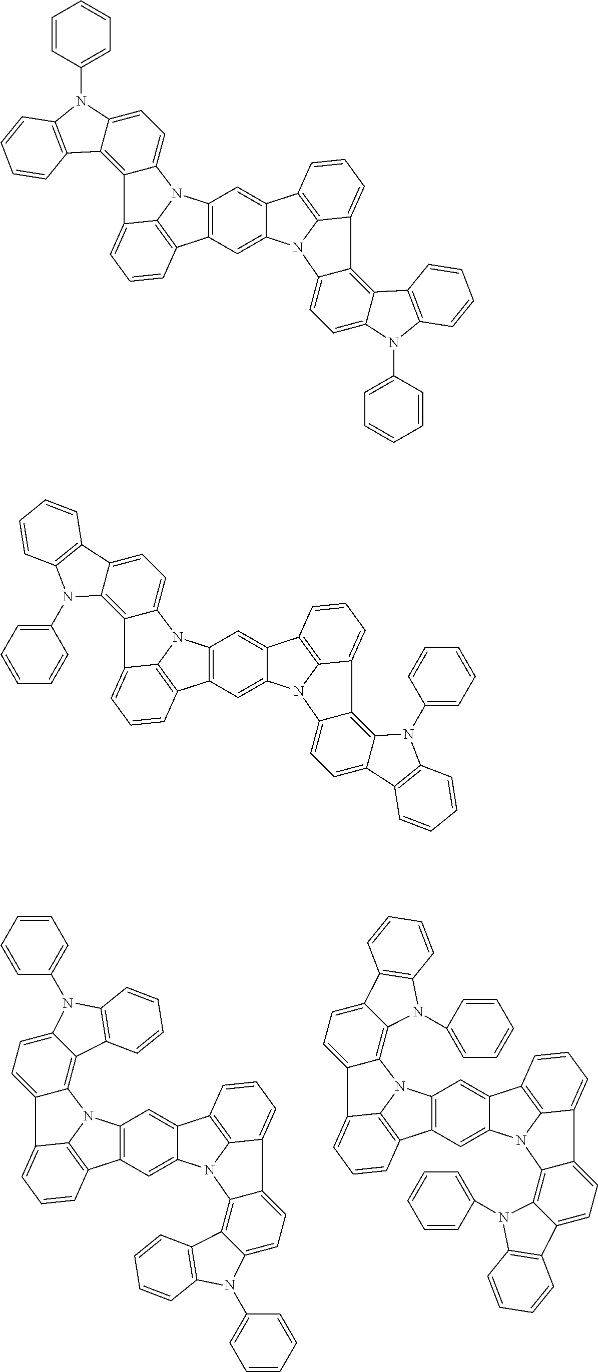

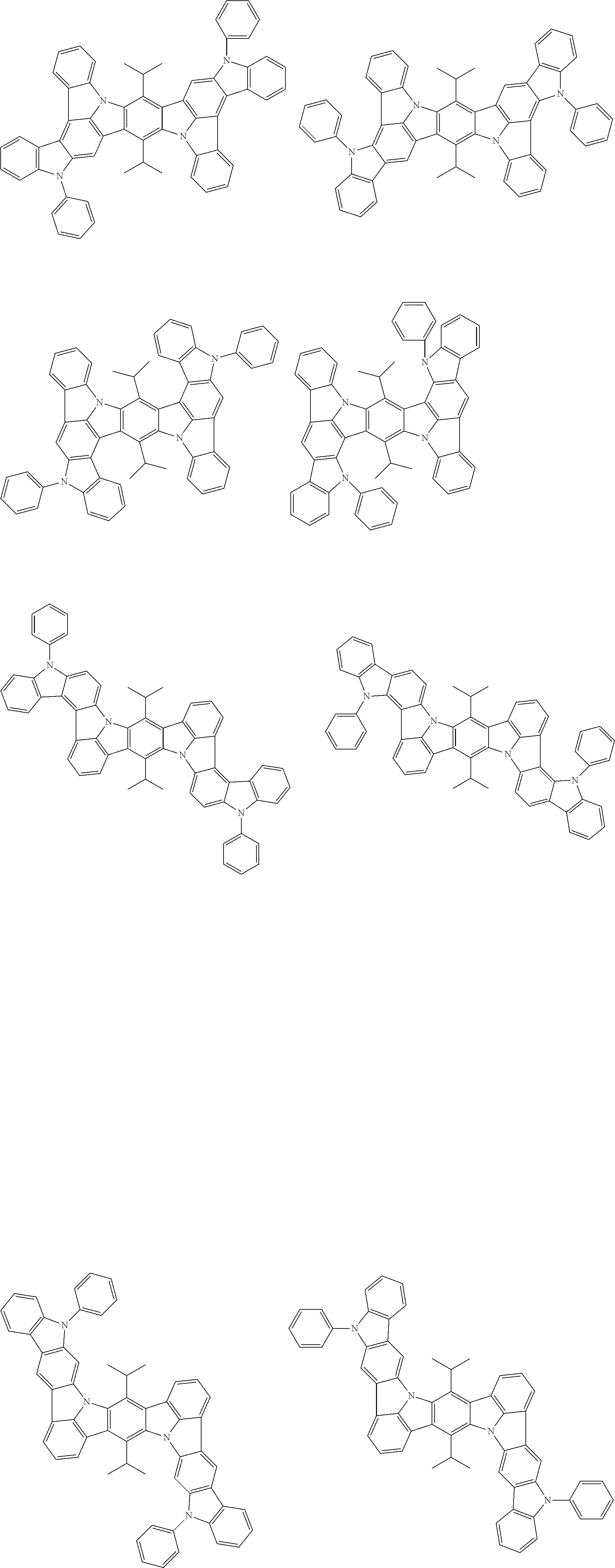

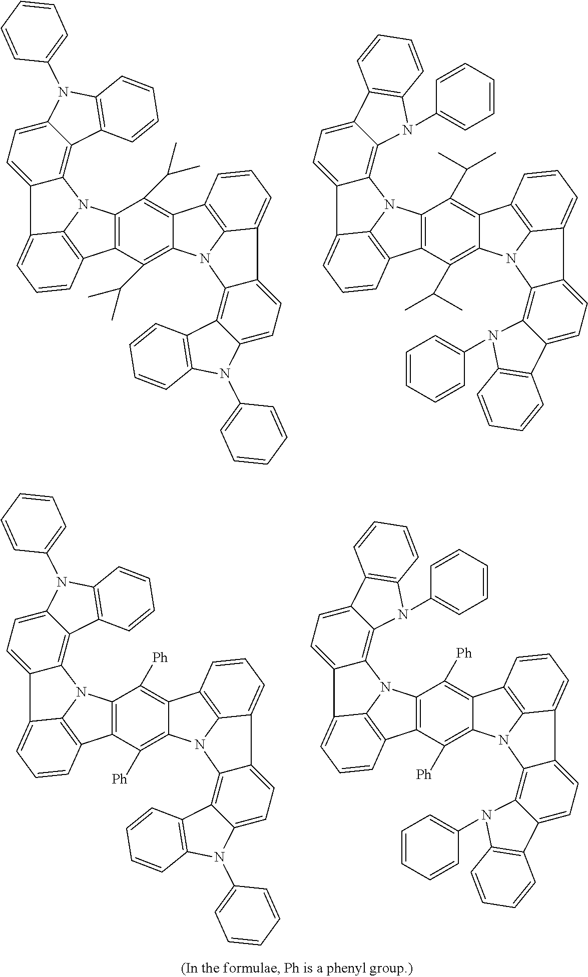

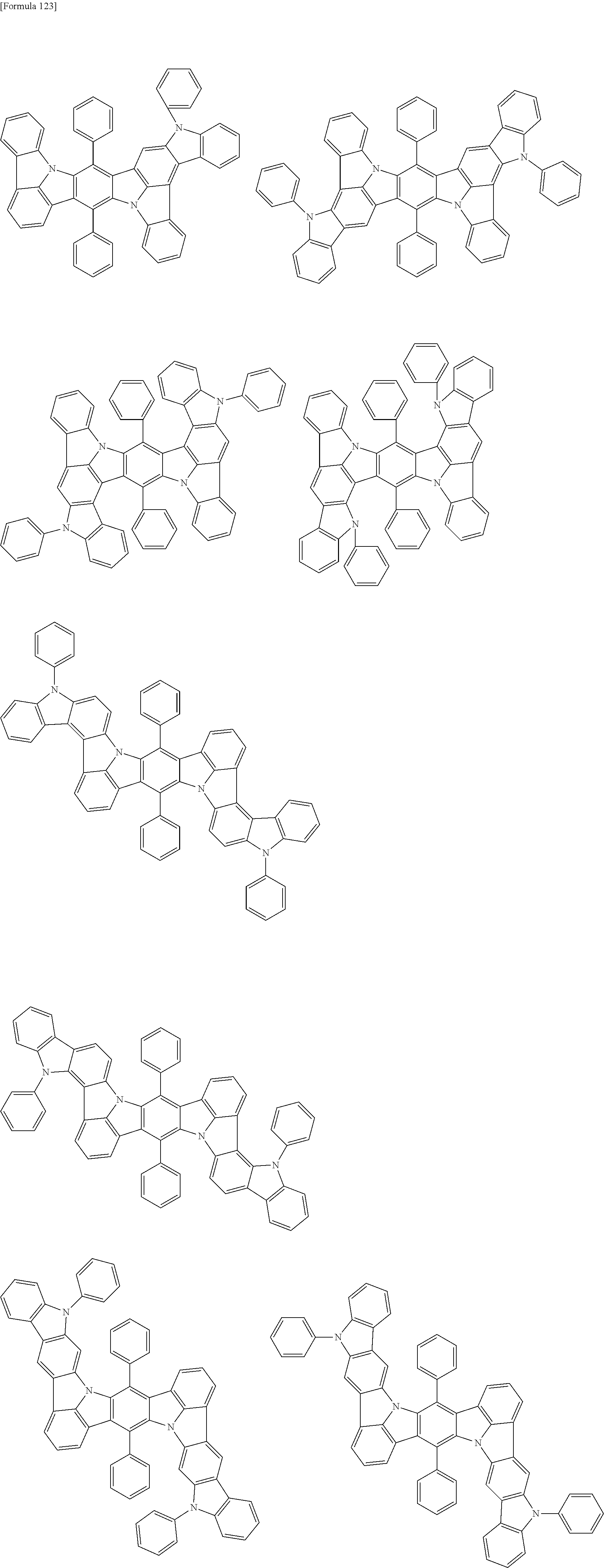

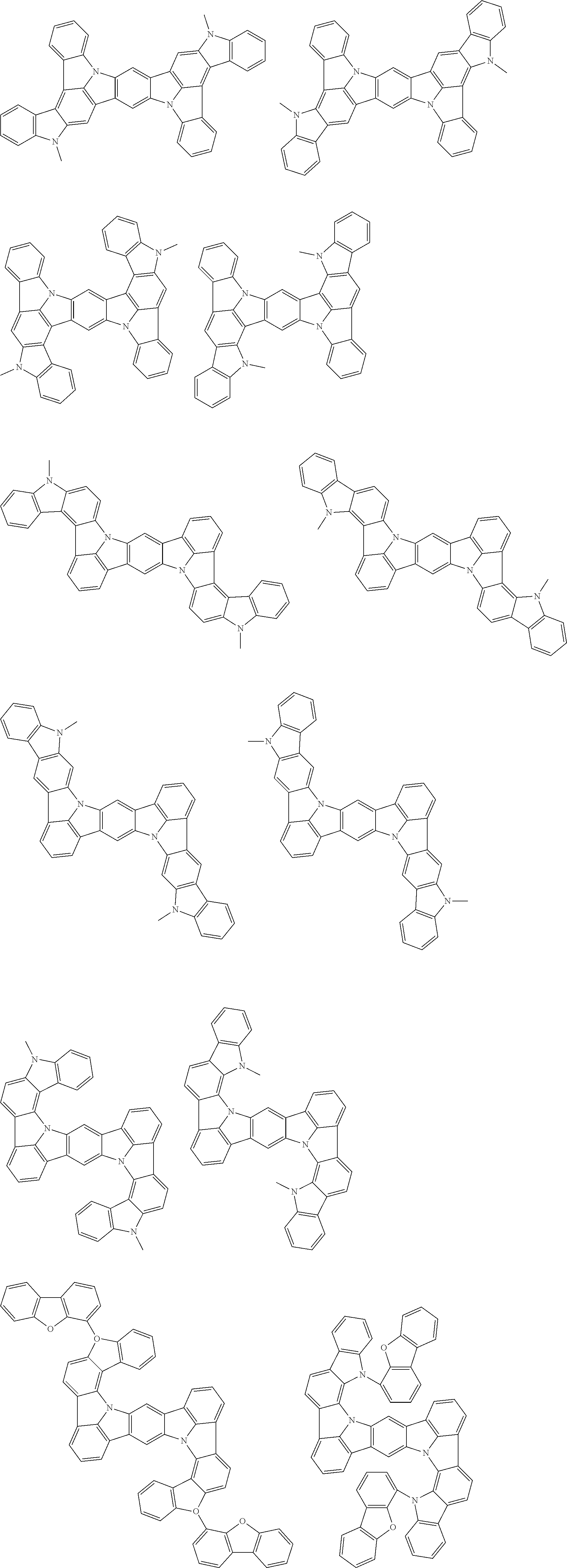

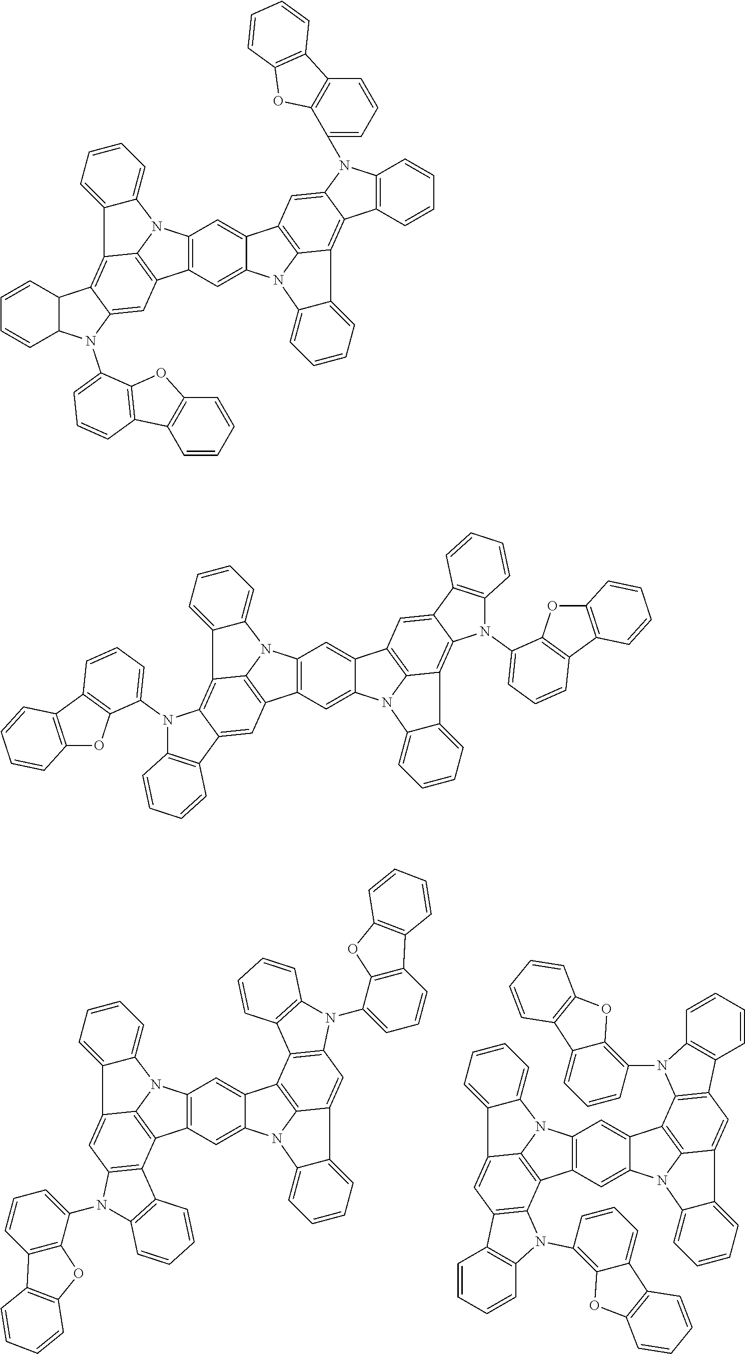

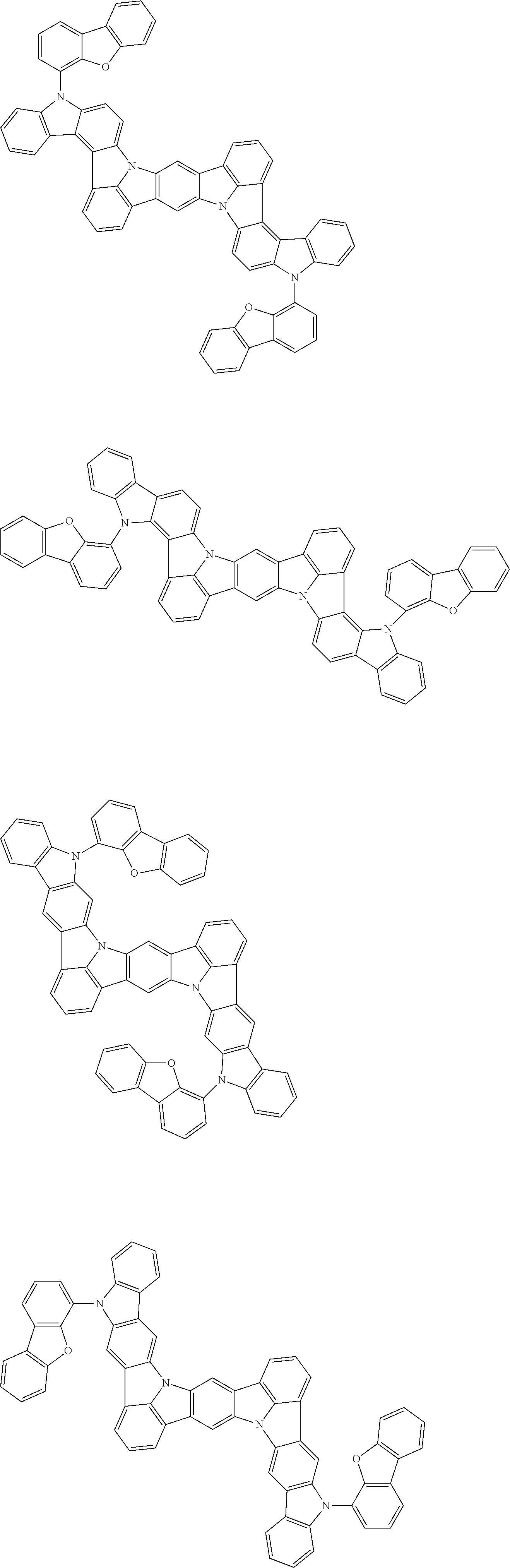

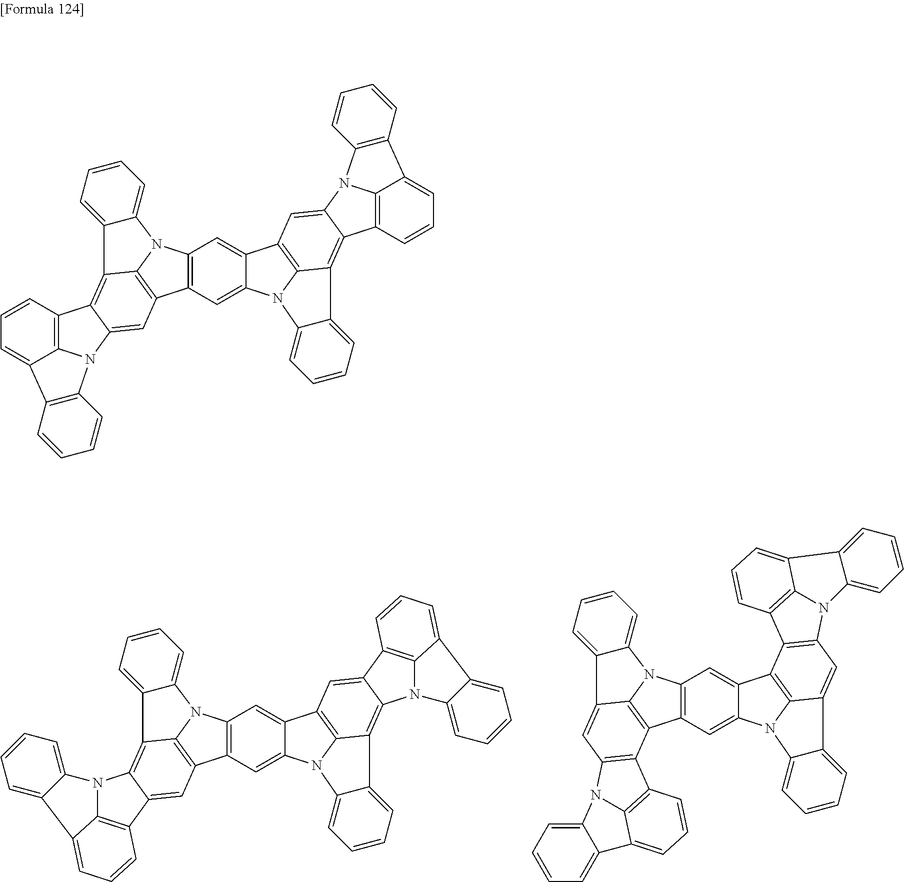

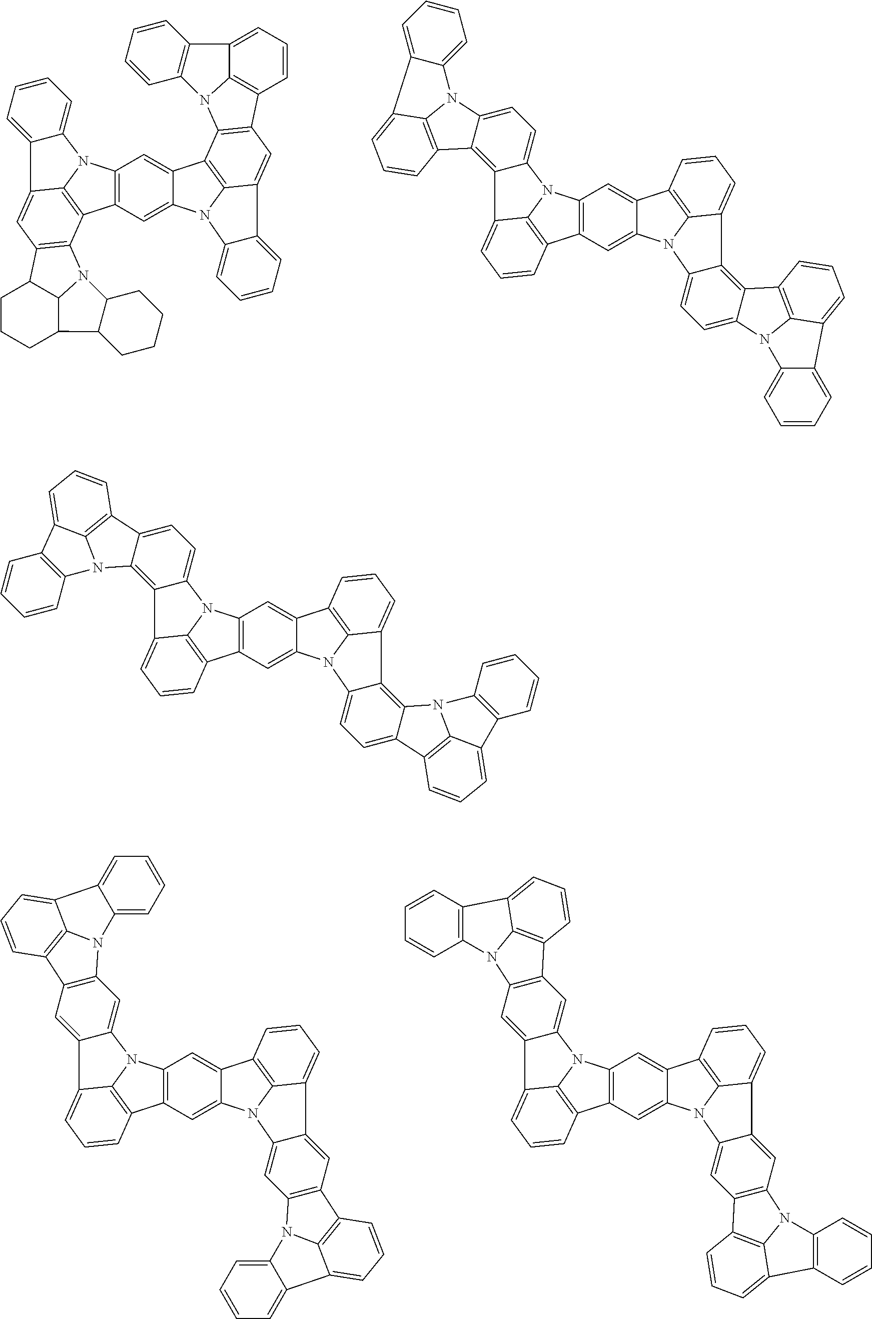

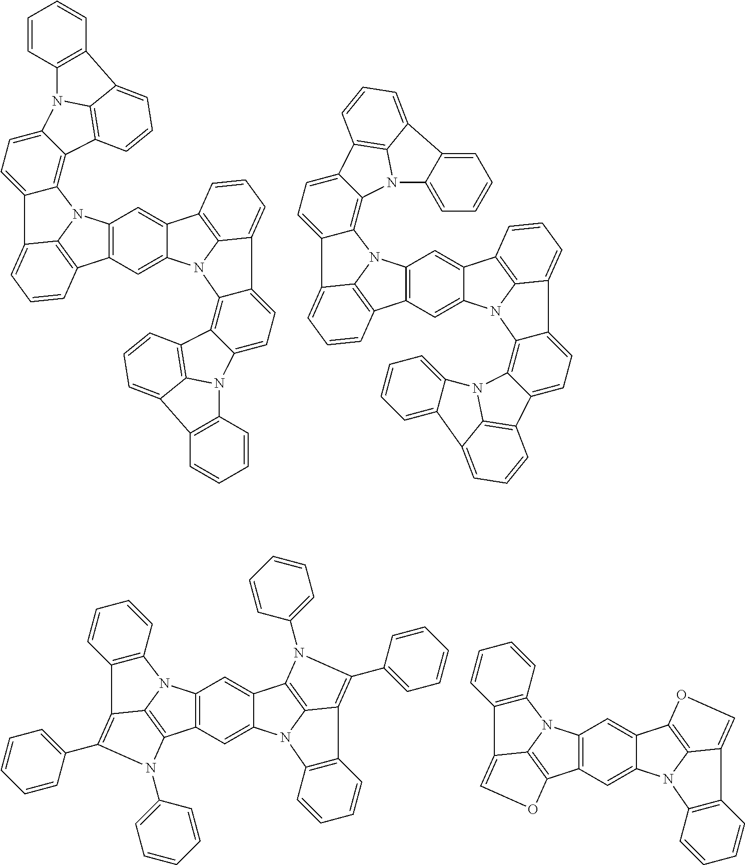

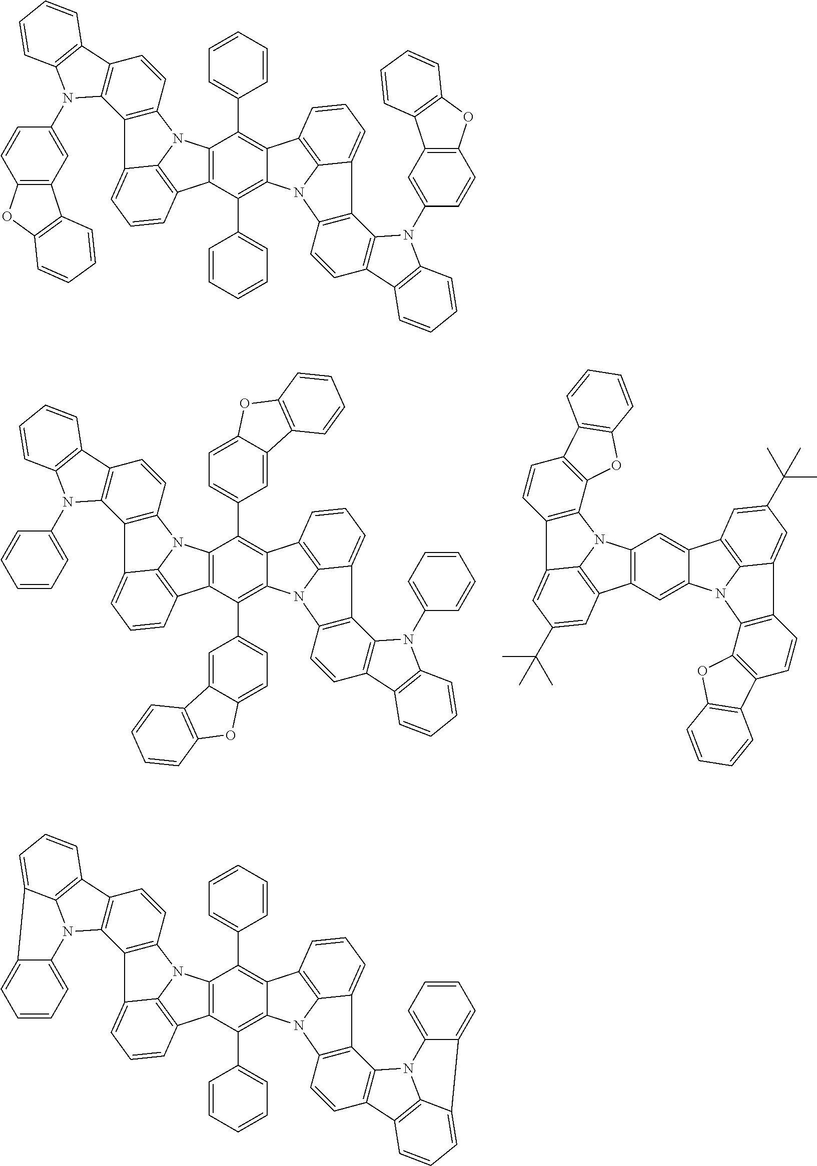

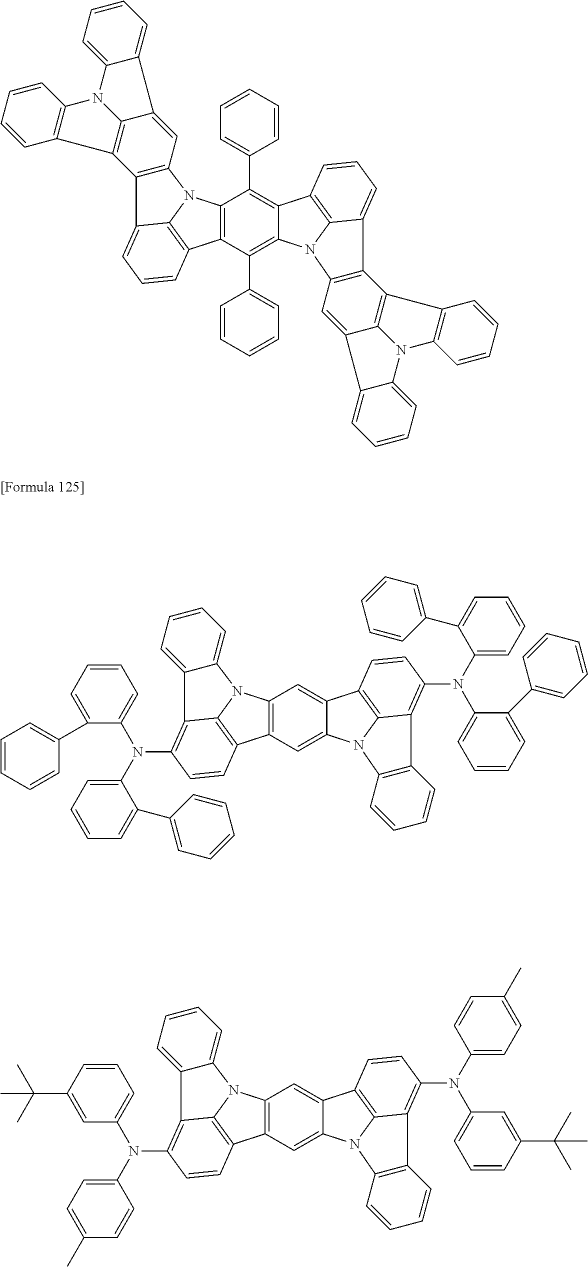

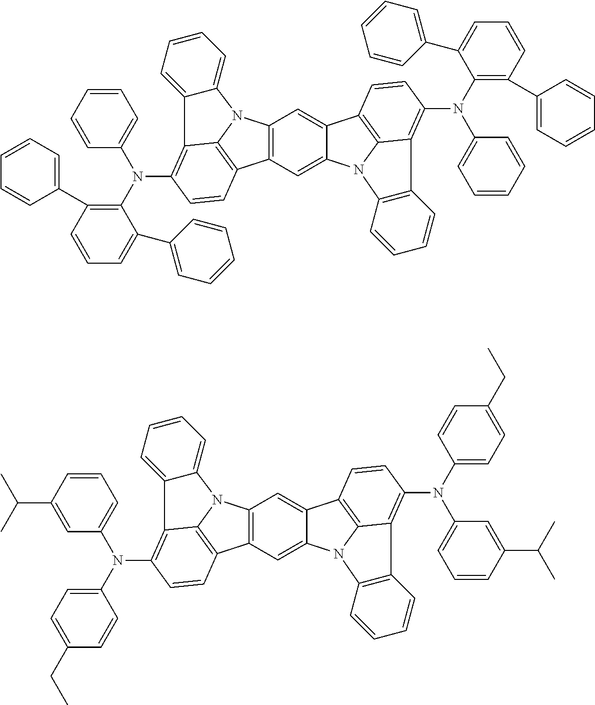

### Compounds Represented by Formula (6)

The following describes the compounds represented by formula (6).

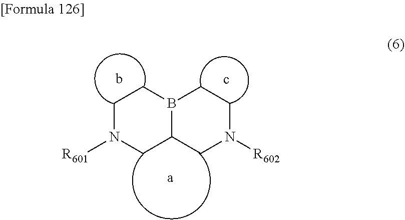

In formula (6),

rings a, b, and c each independently represent: a substituted or unsubstituted aromatic hydrocarbon ring having 6 to 50 ring carbon atoms; or a substituted or unsubstituted heterocycle having 5 to 50 ring atoms;

R₆₀₁ and R₆₀₂ are each independently bonded to ring a, ring b or ring c to form a substituted or unsubstituted heterocycle, or not bonded to form no substituted or unsubstituted heterocycle; and

R₆₀₁ and R₆₀₂ not forming the substituted or unsubstituted heterocycle each independently represent: a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms.

Rings a, b, and c are each a ring fused to the two-ring fused structure, formed by a boron and two nitrogen atoms, in the middle of formula (6) (each being a substituted or unsubstituted aromatic hydrocarbon ring having 6 to 50 ring carbon atoms or a substituted or unsubstituted heterocycle having 5 to 50 ring atoms).

An “aromatic hydrocarbon ring” as ring a, b, or c is structurally the same as a compound that is formed when hydrogen atom(s) is introduced into an “aryl group” as described above.

The ring atoms of an “aromatic hydrocarbon ring” as ring a include the three carbon atoms on the two-ring fused structure in the middle of formula (6).

The ring atoms of an “aromatic hydrocarbon ring” as ring b or c include the two carbon atoms on the two-ring fused structure in the middle of formula (6).

Specific examples of the “substituted or unsubstituted aromatic hydrocarbon ring having 6 to 50 ring carbon atoms” include a compound formed by introducing a hydrogen atom to the “aryl group” described in the specific example group G1.

A “heterocycle” as ring a, b, or c is structurally the same as a compound that is formed when hydrogen atom(s) is introduced into a “heterocyclic group” as described above.

The ring atoms of a “heterocycle” as ring a include the three carbon atoms on the two-ring fused structure in the middle of formula (6). A “heterocycle” as ring b or c include the two carbon atoms on the two-ring fused structure in the middle of formula (6). Specific examples of the “substituted or unsubstituted heterocycle having 5 to 50 ring atoms” include a compound formed by introducing a hydrogen atom to the “heterocyclic group” described in the specific example group G2.

R₆₀₁ and R₆₀₂ are optionally each independently bonded with ring a, ring b, or ring c to form a substituted or unsubstituted heterocycle. A heterocycle in that case includes the nitrogen atom on the two-ring fused structure in the middle of formula (6). A heterocycle in that case may include heteroatoms other than the nitrogen atom. The binding of R₆₀₁ or R₆₀₂ to ring a, b, or c specifically means an atom as a component of ring a, b, or c and that as a component of R₆₀₁ or R₆₀₂ are bonded together. For example, R₆₀₁ may bind to ring a to form a nitrogen-containing heterocycle with two (or three or more) fused rings in which ring(s) including R₉₀₁ and ring a are fused together. Specific examples of the “substituted or unsubstituted heterocycle having 5 to 50 ring atoms” include a compound formed by introducing a hydrogen atom to the “heterocyclic group” described in the specific example group G2.

The same is true when R₆₀₁ is bonded to ring b, when R₆₀₂ is bonded to ring a, or when R₆₀₂ is bonded to ring c, too.

In an exemplary embodiment, rings a, b, and c in formula (6) each independently represent a substituted or unsubstituted aromatic hydrocarbon ring having 6 to 50 ring carbon atoms.

In an exemplary embodiment, rings a, b, and c in formula (6) each independently represent a substituted or unsubstituted benzene or naphthalene ring.

In an exemplary embodiment, R₉₀₁ and R₆₀₂ in formula (6) each independently represent: a substituted or unsubstituted aryl group having 6 to 50 ring carbon atoms; or a substituted or unsubstituted heterocyclic group having 5 to 50 ring atoms, preferably a substituted or unsubstituted aryl group having 6 to 50 ring carbon atoms.

In an exemplary embodiment, the compounds represented by formula (6) are the compounds represented by formula (62) below.

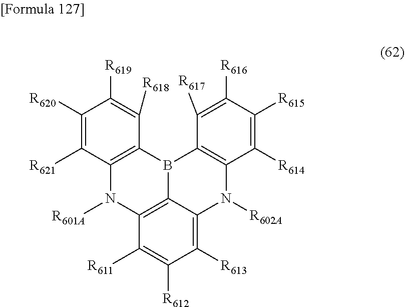

In formula (62),

R_{601A} is bonded with at least one of R₆₁₁ or R₆₂₁ to form a substituted or unsubstituted heterocycle, or not bonded to form no substituted or unsubstituted heterocycle;

R_{602A} is bonded with at least one of R₆₁₃ or R₆₁₄ to form a substituted or unsubstituted heterocycle, or not bonded to form no substituted or unsubstituted heterocycle;

R_{601A} and R_{602A} not forming the substituted or unsubstituted heterocycle each independently represent: a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms;

at least one combination of adjacent two or more of R₆₁₁ to R₆₂₁ are: bonded together to form a substituted or unsubstituted monocyclic ring; bonded together to form a substituted or unsubstituted fused ring; or not bonded together; and

R₆₁₁ to R₆₂₁ not forming the substituted or unsubstituted heterocycle, not forming the monocyclic ring and not forming the fused ring each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

R_{601A} and R_{602A} in formula (62) are groups corresponding to R₆₀₁ and R₆₀₂, respectively, in formula (6).

For example, R_{601A} and R₆₁₁ may be bonded together to form a nitrogen-containing heterocycle with two (or three or more) fused rings in which ring(s) including them and the benzene ring corresponding to ring a are fused together. Specific examples of such nitrogen-containing heterocycles include compounds corresponding to the nitrogen-containing heterocyclic groups with two or more fused rings in specific example group G2. The same is true when R_{601A} and R₆₂₁ are bonded together, when R_{602A} and R₆₁₃ are bonded together, or when R_{602A} and R₆₁₄ are bonded together, too.

It may be that at least one combination of adjacent two or more of R₆₁₁ to R₆₂₁ are: bonded together to form a substituted or unsubstituted monocyclic ring; or bonded together to form a substituted or unsubstituted fused ring.

For example, R₆₁₁ and R₆₁₂ may be bonded together to form a structure in which a benzene, indole, pyrrole, benzofuran, or benzothiophene ring, for example, is fused to the six-membered ring to which the Rs are bonded. The resulting fused ring is a naphthalene, carbazole, indole, dibenzofuran, or dibenzothiophene ring.

In an exemplary embodiment, R₆₁₁ to R₆₂₁ not contributing to ring formation each independently represent: a hydrogen atom; a substituted or unsubstituted alkyl group having 1 to 50 carbon atoms; a substituted or unsubstituted aryl group having 6 to 50 ring carbon atoms; or a substituted or unsubstituted heterocyclic group having 5 to 50 ring atoms.

In an exemplary embodiment, R₆₁₁ to R₆₂₁ not contributing to ring formation each independently represent: a hydrogen atom; a substituted or unsubstituted aryl group having 6 to 50 ring carbon atoms; or a substituted or unsubstituted heterocyclic group having 5 to 50 ring atoms.

In an exemplary embodiment, R₆₁₁ to R₆₂₁ not contributing to ring formation each independently represent: a hydrogen atom; or a substituted or unsubstituted alkyl group having 1 to 50 carbon atoms.

In an exemplary embodiment, R₆₁₁ to R₆₂₁ not contributing to ring formation each independently represent: a hydrogen atom; or a substituted or unsubstituted alkyl group having 1 to 50 carbon atoms; and at least one of R₆₁₁ to R₆₂₁ is a substituted or unsubstituted alkyl group having 1 to 50 carbon atoms.

In an exemplary embodiment, the compounds represented by formula (62) are the compounds represented by formula (63) below.

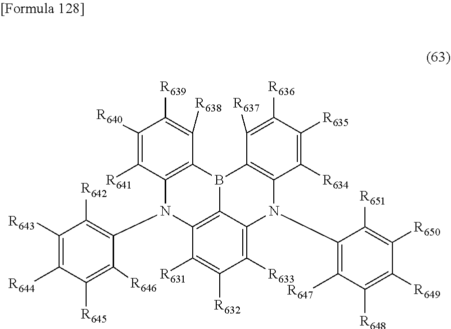

In formula (63),

R₆₃₁ is bonded with R₆₄₆ to form a substituted or unsubstituted heterocycle, or not bonded therewith to form no substituted or unsubstituted heterocycle;

R₆₃₃ is bonded with R₆₄₇ to form a substituted or unsubstituted heterocycle, or not bonded therewith to form no substituted or unsubstituted heterocycle;

R₆₃₄ is bonded with R₆₅₁ to form a substituted or unsubstituted heterocycle, or not bonded therewith to form no substituted or unsubstituted heterocycle;

R₆₄₁ is bonded with R₆₄₂ to form a substituted or unsubstituted heterocycle, or not bonded therewith to form no substituted or unsubstituted heterocycle; at least one combination of adjacent two or more of R₆₃₁ to R₆₅₁ are mutually bonded to form a substituted or unsubstituted monocyclic ring, mutually bonded to form a substituted or unsubstituted fused ring, or not mutually bonded; and

R₆₃₁ to R₆₅₁ not forming the substituted or unsubstituted heterocycle, not forming the monocyclic ring, and not forming the fused ring each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

R₆₃₁ are optionally mutually bonded with R₆₄₆ to form a substituted or unsubstituted heterocycle. For example, R₆₃₁ and R₆₄₆ may be bonded together to form a nitrogen-containing heterocycle with three or more fused rings in which the benzene ring to which R₆₄₆ is bonded, the ring including N, and the benzene ring corresponding to ring a are fused together. Specific examples of such nitrogen-containing heterocycles include compounds corresponding to the nitrogen-containing heterocyclic groups with three or more fused rings in specific example group G2. The same is true when R₆₃₃ and R₆₄₇ are bonded together, when R₆₃₄ and R₆₅₁ are bonded together, or when R₆₄₁ and R₆₄₂ are bonded together, too.

In an exemplary embodiment, R₆₃₁ to R₆₅₁ not contributing to ring formation each independently represent: a hydrogen atom; a substituted or unsubstituted alkyl group having 1 to 50 carbon atoms; a substituted or unsubstituted aryl group having 6 to 50 ring carbon atoms; or a substituted or unsubstituted heterocyclic group having 5 to 50 ring atoms.

In an exemplary embodiment, R₆₃₁ to R₆₅₁ not contributing to ring formation each independently represent: a hydrogen atom; a substituted or unsubstituted aryl group having 6 to 50 ring carbon atoms; or a substituted or unsubstituted heterocyclic group having 5 to 50 ring atoms.

In an exemplary embodiment, R₆₃₁ to R₆₅₁ not contributing to ring formation each independently represent: a hydrogen atom; or a substituted or unsubstituted alkyl group having 1 to 50 carbon atoms.

In an exemplary embodiment, R₆₃₁ to R₆₅₁ not contributing to ring formation each independently represent: a hydrogen atom; or a substituted or unsubstituted alkyl group having 1 to 50 carbon atoms; and

at least one of R₆₃₁ to R₆₅₁ is a substituted or unsubstituted alkyl group having 1 to 50 carbon atoms.

In an exemplary embodiment, the compounds represented by formula (63) are the compounds represented by formula (63A) below.

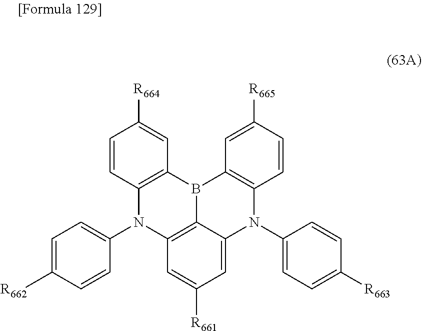

In formula (63A),

R₆₆₁ is: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; or a substituted or unsubstituted aryl group having 6 to 50 ring carbon atoms; and

R₆₆₂ to R₆₆₅ each independently represent: a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; or a substituted or unsubstituted aryl group having 6 to 50 ring carbon atoms.

In an exemplary embodiment, R₆₆₁ to R₆₆₅ each independently represent: a substituted or unsubstituted alkyl group having 1 to 50 carbon atoms; or a substituted or unsubstituted aryl group having 6 to 50 ring carbon atoms.

In an exemplary embodiment, R₆₆₁ to R₆₆₅ each independently represent a substituted or unsubstituted alkyl group having 1 to 50 carbon atoms.

In an exemplary embodiment, the compounds represented by formula (63) are the compounds represented by formula (63B) below.

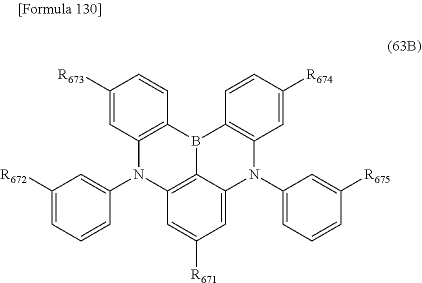

In formula (63B),

R₆₇₁ and R₆₇₂ each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —N(R₉₀₆)(R₉₀₇); or a substituted or unsubstituted aryl group having 6 to 50 ring carbon atoms; and

R₆₇₃ to R₆₇₅ each independently represent: a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —N(R₉₀₆)(R₉₀₇); or a substituted or unsubstituted aryl group having 6 to 50 ring carbon atoms.

In an exemplary embodiment, the compounds represented by formula (63) are the compounds represented by formula (63B′) below.

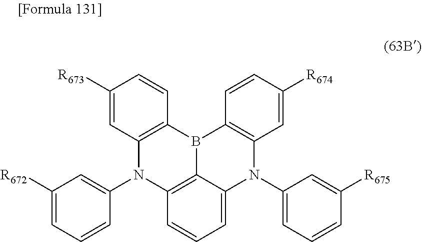

In formula (63B′), R₆₇₂ to R₆₇₅ each independently represent the same as R₆₇₂ to R₆₇₅ in formula (63B).

In an exemplary embodiment, at least one of R₆₇₁ to R₆₇₅ is: a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —N(R₉₀₆)(R₉₀₇); or a substituted or unsubstituted aryl group having 6 to 50 ring carbon atoms.

In an exemplary embodiment, R₆₇₂ is: a hydrogen atom; a substituted or unsubstituted alkyl group having 1 to 50 carbon atoms; a group represented by —N(R₉₀₆)(R₉₀₇); or a substituted or unsubstituted aryl group having 6 to 50 ring carbon atoms; and

R₆₇₁ and R₆₇₃ to R₆₇₅ each independently represent: a substituted or unsubstituted alkyl group having 1 to 50 carbon atoms; a group represented by —N(R₉₀₆)(R₉₀₇); or a substituted or unsubstituted aryl group having 6 to 50 ring carbon atoms.

In an exemplary embodiment, the compounds represented by formula (63) are the compounds represented by formula (63C) below.

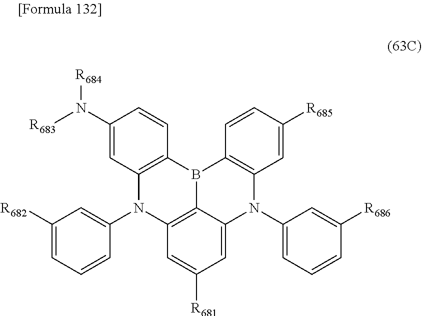

In formula (63C),

R₆₈₁ and R₆₈₂ each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; or a substituted or unsubstituted aryl group having 6 to 50 ring carbon atoms.

R₆₈₃ to R₆₈₆ each independently represent: a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; or a substituted or unsubstituted aryl group having 6 to 50 ring carbon atoms.

In an exemplary embodiment, the compounds represented by formula (63) are the compounds represented by formula (63C′) below.

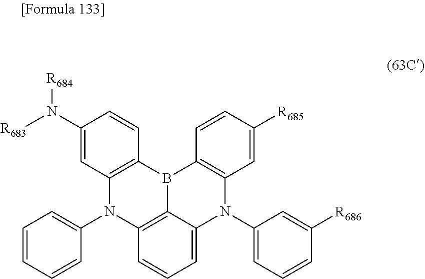

In formula (63C′), R₆₈₃ to R₆₈₆ each independently represent the same as R₆₈₃ to R₆₈₆ in formula (63C).

In an exemplary embodiment, R₆₈₁ to R₆₈₆ each independently represent: a substituted or unsubstituted alkyl group having 1 to 50 carbon atoms; or a substituted or unsubstituted aryl group having 6 to 50 ring carbon atoms.

In an exemplary embodiment, R₆₈₁ to R₆₈₆ each independently represent a substituted or unsubstituted aryl group having 6 to 50 ring carbon atoms.

To make a compound represented by formula (6), an intermediate is first produced by binding rings a, b, and c together using linking groups (a group including N—R₆₀₁ and that including N—R₆₀₂) (first reaction), and then binding rings a, b, and c using a linking group (including a boron atom) will give the final product (second reaction). The first reaction can be amination, such as the Buchwald-Hartwig amination. The second reaction can be, for example, heterogeneously catalyzed tandem Friedel-Crafts reactions.

The following are specific examples of compounds represented by formula (6). It should be noted that these are given for illustrative purposes only; the following specific examples are not the only possible forms of compounds represented by formula (6).

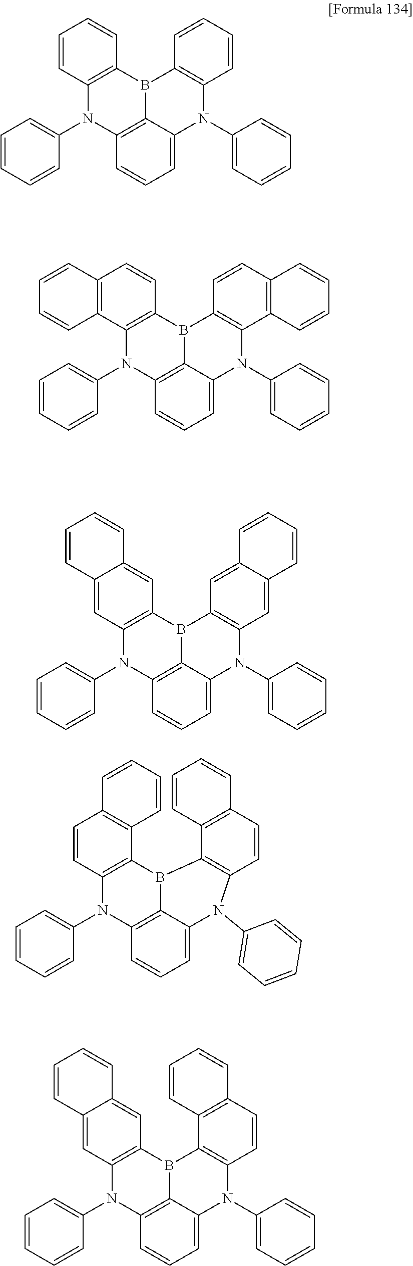

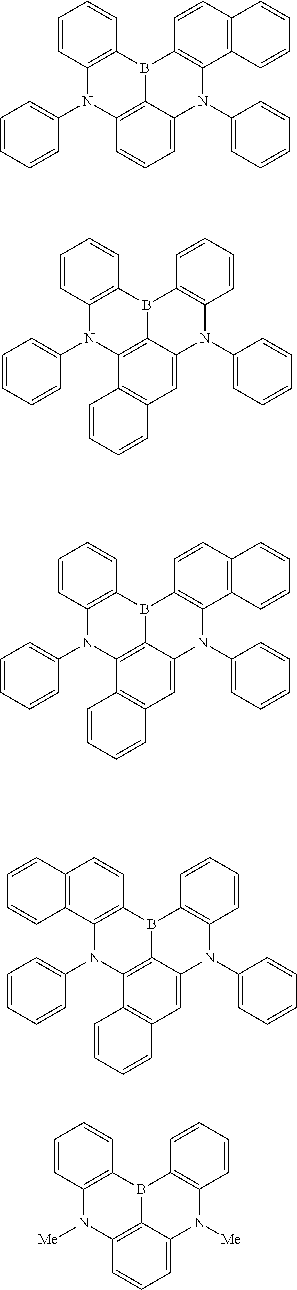 [SMILES: c1ccc(N2c3ccccc3B3c4ccc5ccccc5c4N(c4ccccc4)c4cccc2c43)cc1 ; c1ccc(N2c3ccccc3B3c4ccccc4N(c4ccccc4)c4c3c2cc2ccccc42)cc1 ; c1ccc(N2c3cc4ccccc4c4c3B(c3ccccc3N4c3ccccc3)c3ccc4ccccc4c32)cc1 ; c1ccc(N2c3ccccc3B3c4ccc5ccccc5c4N(c4ccccc4)c4c3c2cc2ccccc42)cc1 ; CN1c2ccccc2B2c3ccccc3N(C)c3cccc1c32]

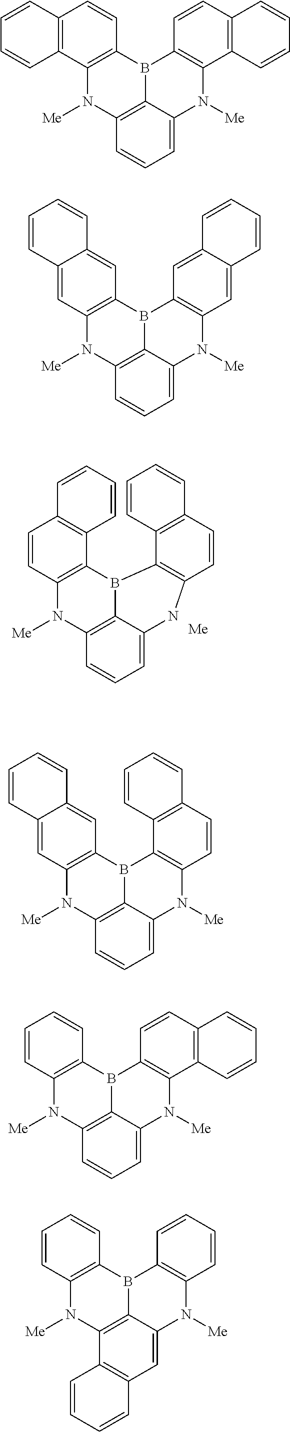

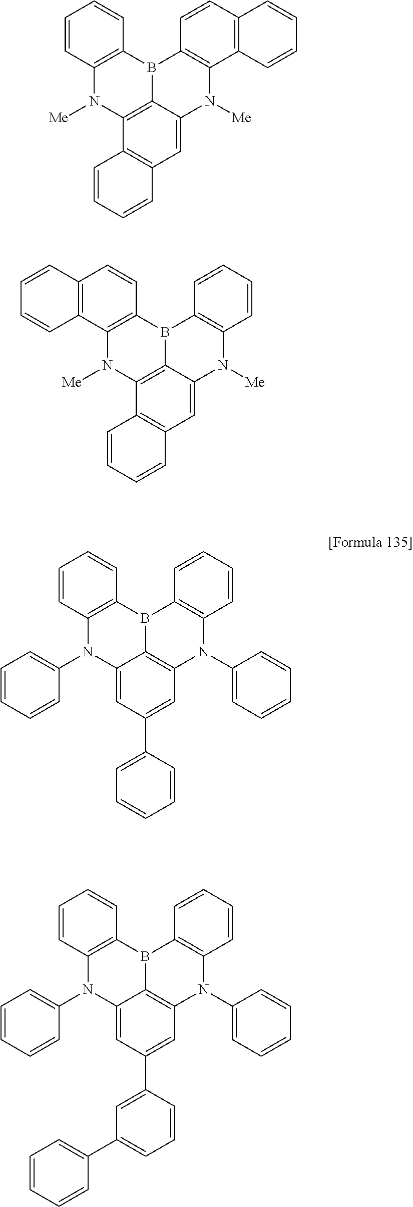 [SMILES: CN1c2cc3ccccc3c3c2B(c2ccccc2N3C)c2ccc3ccccc3c21 ; CN1c2ccccc2B2c3ccc4ccccc4c3N(C)c3c2c1cc1ccccc31 ; c1ccc(-c2cc3c4c(c2)N(c2ccccc2)c2ccccc2B4c2ccccc2N3c2ccccc2)cc1 ; c1ccc(-c2cccc(-c3cc4c5c(c3)N(c3ccccc3)c3ccccc3B5c3ccccc3N4c3ccccc3)c2)cc1]

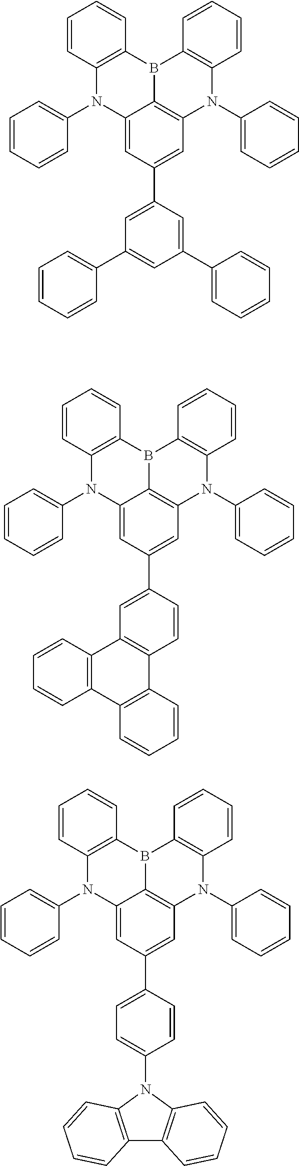 [SMILES: c1ccc(-c2cc(-c3ccccc3)cc(-c3cc4c5c(c3)N(c3ccccc3)c3ccccc3B5c3ccccc3N4c3ccccc3)c2)cc1 ; c1ccc(N2c3ccccc3B3c4ccccc4N(c4ccccc4)c4cc(-c5ccc6c7ccccc7c7ccccc7c6c5)cc2c43)cc1 ; c1ccc(N2c3ccccc3B3c4ccccc4N(c4ccccc4)c4cc(-c5ccc(-n6c7ccccc7c7ccccc76)cc5)cc2c43)cc1]

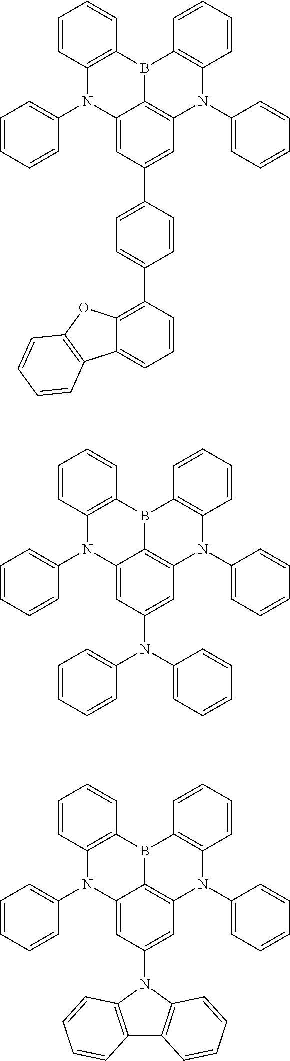 [SMILES: c1ccc(N2c3ccccc3B3c4ccccc4N(c4ccccc4)c4cc(-c5ccc(-c6cccc7c6oc6ccccc67)cc5)cc2c43)cc1 ; c1ccc(N(c2ccccc2)c2cc3c4c(c2)N(c2ccccc2)c2ccccc2B4c2ccccc2N3c2ccccc2)cc1 ; c1ccc(N2c3ccccc3B3c4ccccc4N(c4ccccc4)c4cc(-n5c6ccccc6c6ccccc65)cc2c43)cc1]

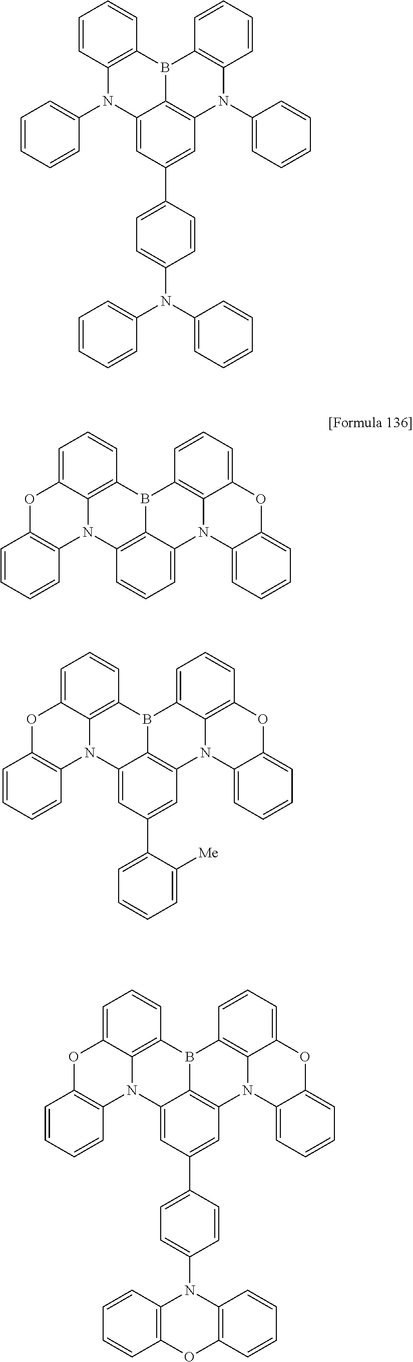 [SMILES: c1ccc(N(c2ccccc2)c2ccc(-c3cc4c5c(c3)N(c3ccccc3)c3ccccc3B5c3ccccc3N4c3ccccc3)cc2)cc1 ; c1ccc2c(c1)Oc1cccc3c1N2c1cccc2c1B3c1cccc3c1N2c1ccccc1O3 ; Cc1ccccc1-c1cc2c3c(c1)N1c4ccccc4Oc4cccc(c41)B3c1cccc3c1N2c1ccccc1O3 ; c1ccc2c(c1)Oc1ccccc1N2c1ccc(-c2cc3c4c(c2)N2c5ccccc5Oc5cccc(c52)B4c2cccc4c2N3c2ccccc2O4)cc1]

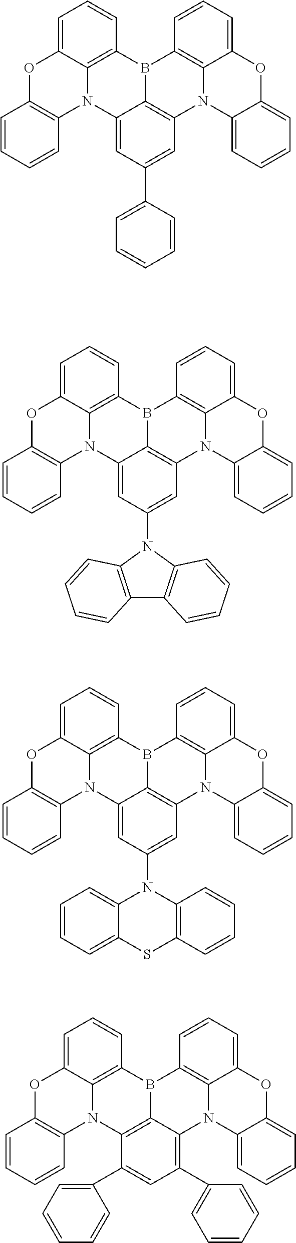 [SMILES: c1ccc(-c2cc3c4c(c2)N2c5ccccc5Oc5cccc(c52)B4c2cccc4c2N3c2ccccc2O4)cc1 ; c1ccc2c(c1)Oc1cccc3c1N2c1cc(-n2c4ccccc4c4ccccc42)cc2c1B3c1cccc3c1N2c1ccccc1O3 ; c1ccc2c(c1)Oc1cccc3c1N2c1cc(N2c4ccccc4Sc4ccccc42)cc2c1B3c1cccc3c1N2c1ccccc1O3 ; c1ccc(-c2cc(-c3ccccc3)c3c4c2N2c5ccccc5Oc5cccc(c52)B4c2cccc4c2N3c2ccccc2O4)cc1]

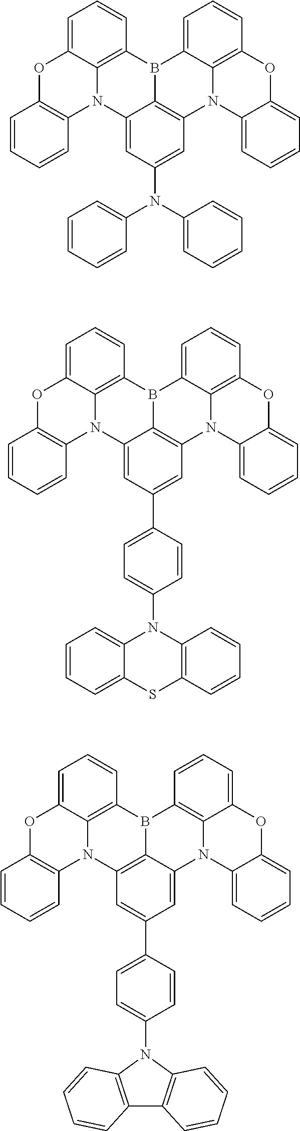 [SMILES: c1ccc(N(c2ccccc2)c2cc3c4c(c2)N2c5ccccc5Oc5cccc(c52)B4c2cccc4c2N3c2ccccc2O4)cc1 ; c1ccc2c(c1)Oc1cccc3c1N2c1cc(-c2ccc(N4c5ccccc5Sc5ccccc54)cc2)cc2c1B3c1cccc3c1N2c1ccccc1O3 ; c1ccc2c(c1)Oc1cccc3c1N2c1cc(-c2ccc(-n4c5ccccc5c5ccccc54)cc2)cc2c1B3c1cccc3c1N2c1ccccc1O3]

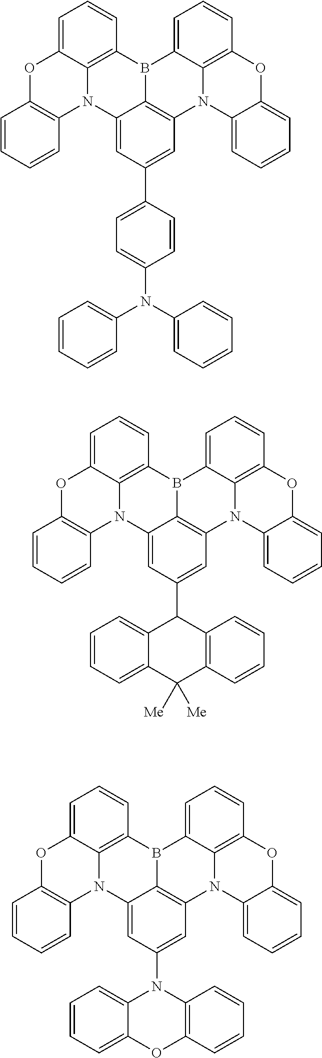 [SMILES: c1ccc(N(c2ccccc2)c2ccc(-c3cc4c5c(c3)N3c6ccccc6Oc6cccc(c63)B5c3cccc5c3N4c3ccccc3O5)cc2)cc1 ; CC1(C)c2ccccc2C(c2cc3c4c(c2)N2c5ccccc5Oc5cccc(c52)B4c2cccc4c2N3c2ccccc2O4)c2ccccc21 ; c1ccc2c(c1)Oc1ccccc1N2c1cc2c3c(c1)N1c4ccccc4Oc4cccc(c41)B3c1cccc3c1N2c1ccccc1O3]

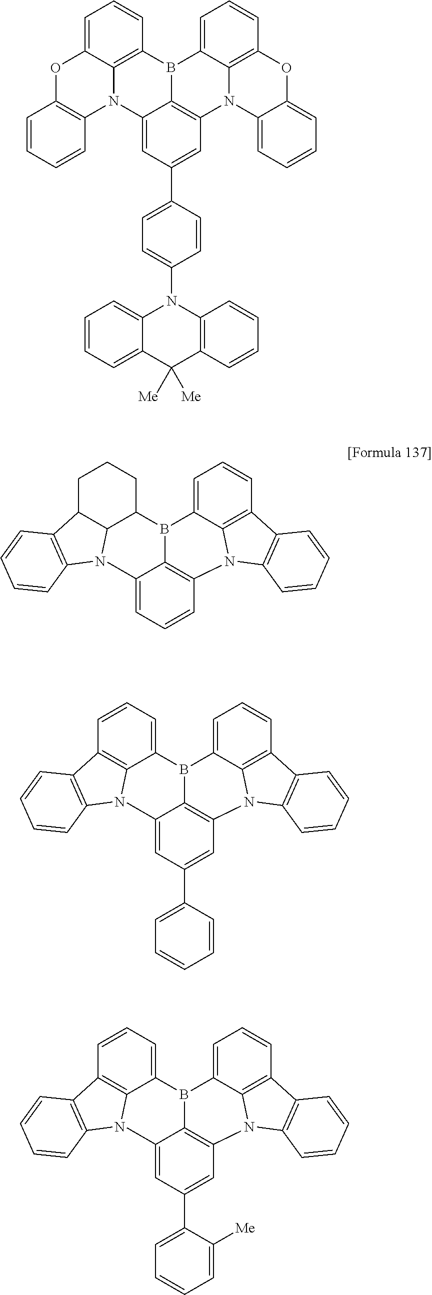 [SMILES: CC1(C)c2ccccc2N(c2ccc(-c3cc4c5c(c3)N3c6ccccc6Oc6cccc(c63)B5c3cccc5c3N4c3ccccc3O5)cc2)c2ccccc21 ; Cc1cccc2c1B(C1CCCC3c4ccccc4NC13)c1cccc3c4ccccc4n-2c13 ; Cc1cc(-c2ccccc2)cc2c1B(c1cccc3c1[nH]c1ccccc13)c1cccc3c4ccccc4n-2c13 ; Cc1ccccc1-c1cc(C)c2c(c1)-n1c3ccccc3c3cccc(c31)B2c1cccc2c1[nH]c1ccccc12]

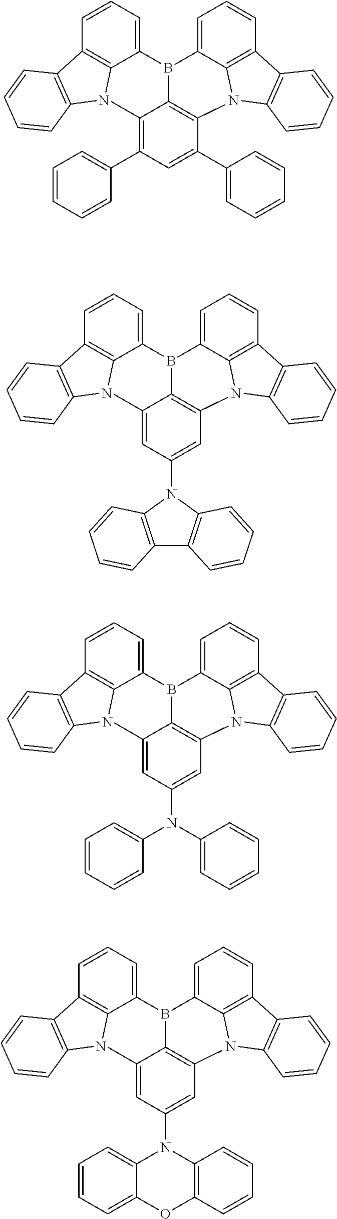 [SMILES: Cc1c(-c2ccccc2)cc(-c2ccccc2)c2c1B(c1cccc3c1[nH]c1ccccc13)c1cccc3c4ccccc4n-2c13 ; Cc1cc(-n2c3ccccc3c3ccccc32)cc2c1B(c1cccc3c1[nH]c1ccccc13)c1cccc3c4ccccc4n-2c13 ; Cc1cc(N(c2ccccc2)c2ccccc2)cc2c1B(c1cccc3c1[nH]c1ccccc13)c1cccc3c4ccccc4n-2c13 ; Cc1cc(N2c3ccccc3Oc3ccccc32)cc2c1B(c1cccc3c1[nH]c1ccccc13)c1cccc3c4ccccc4n-2c13]

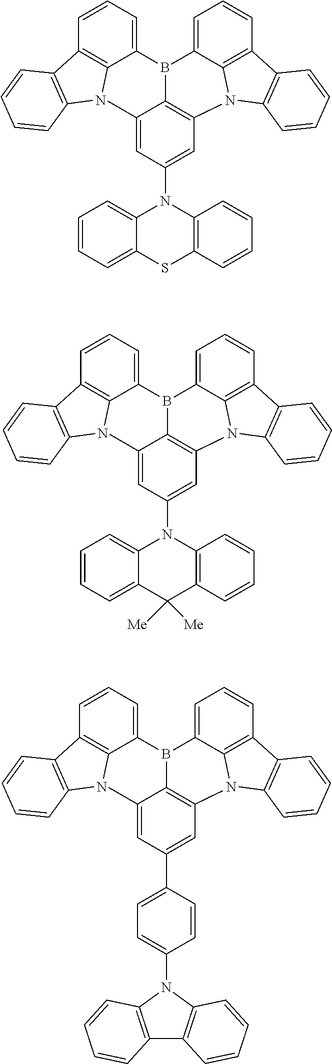 [SMILES: Cc1cc(N2c3ccccc3Sc3ccccc32)cc2c1B(c1cccc3c1[nH]c1ccccc13)c1cccc3c4ccccc4n-2c13 ; Cc1cc(N2c3ccccc3C(C)(C)c3ccccc32)cc2c1B(c1cccc3c1[nH]c1ccccc13)c1cccc3c4ccccc4n-2c13 ; Cc1cc(-c2ccc(-n3c4ccccc4c4ccccc43)cc2)cc2c1B(c1cccc3c1[nH]c1ccccc13)c1cccc3c4ccccc4n-2c13]

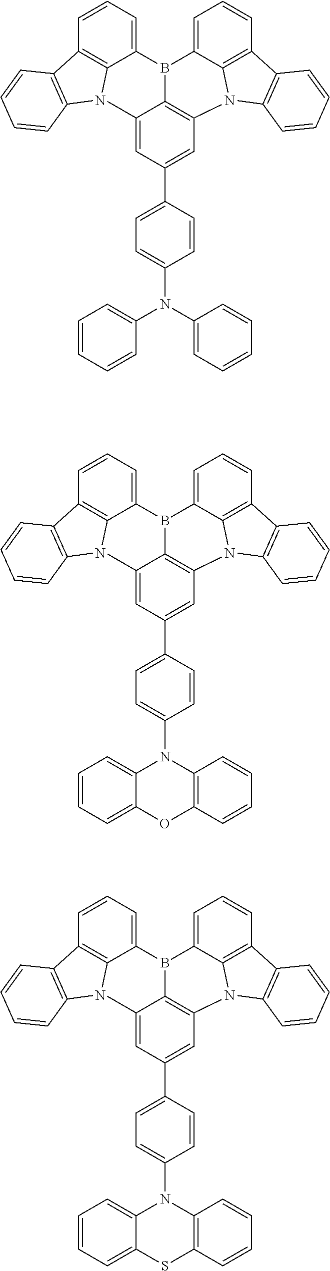 [SMILES: Cc1cc(-c2ccc(N(c3ccccc3)c3ccccc3)cc2)cc2c1B(c1cccc3c1[nH]c1ccccc13)c1cccc3c4ccccc4n-2c13 ; Cc1cc(-c2ccc(N3c4ccccc4Oc4ccccc43)cc2)cc2c1B(c1cccc3c1[nH]c1ccccc13)c1cccc3c4ccccc4n-2c13 ; Cc1cc(-c2ccc(N3c4ccccc4Sc4ccccc43)cc2)cc2c1B(c1cccc3c1[nH]c1ccccc13)c1cccc3c4ccccc4n-2c13]

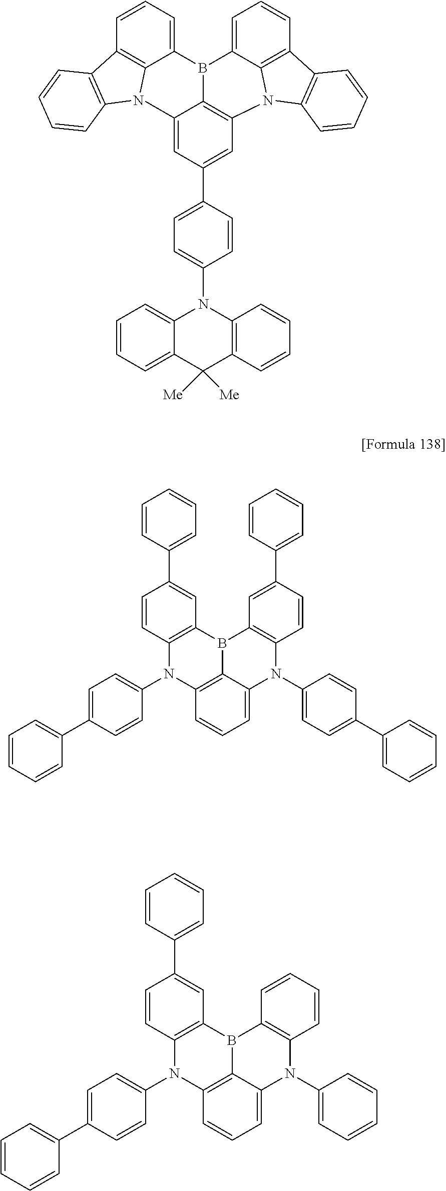 [SMILES: Cc1cc(-c2ccc(N3c4ccccc4C(C)(C)c4ccccc43)cc2)cc2c1B(c1cccc3c1[nH]c1ccccc13)c1cccc3c4ccccc4n-2c13 ; c1ccc(-c2ccc(N3c4ccc(-c5ccccc5)cc4B4c5cc(-c6ccccc6)ccc5N(c5ccc(-c6ccccc6)cc5)c5cccc3c54)cc2)cc1 ; c1ccc(-c2ccc(N3c4ccc(-c5ccccc5)cc4B4c5ccccc5N(c5ccccc5)c5cccc3c54)cc2)cc1]

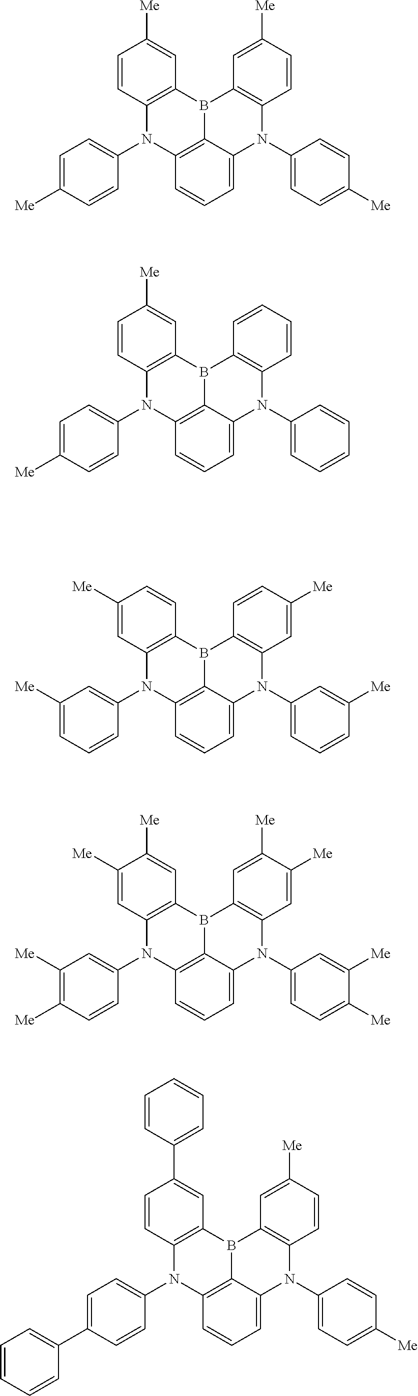 [SMILES: Cc1ccc(N2c3ccc(C)cc3B3c4cc(C)ccc4N(c4ccc(C)cc4)c4cccc2c43)cc1 ; Cc1ccc(N2c3ccc(C)cc3B3c4ccccc4N(c4ccccc4)c4cccc2c43)cc1 ; Cc1cccc(N2c3cc(C)ccc3B3c4ccc(C)cc4N(c4cccc(C)c4)c4cccc2c43)c1 ; Cc1ccc(N2c3cc(C)c(C)cc3B3c4cc(C)c(C)cc4N(c4ccc(C)c(C)c4)c4cccc2c43)cc1C ; Cc1ccc(N2c3ccc(C)cc3B3c4cc(-c5ccccc5)ccc4N(c4ccc(-c5ccccc5)cc4)c4cccc2c43)cc1]

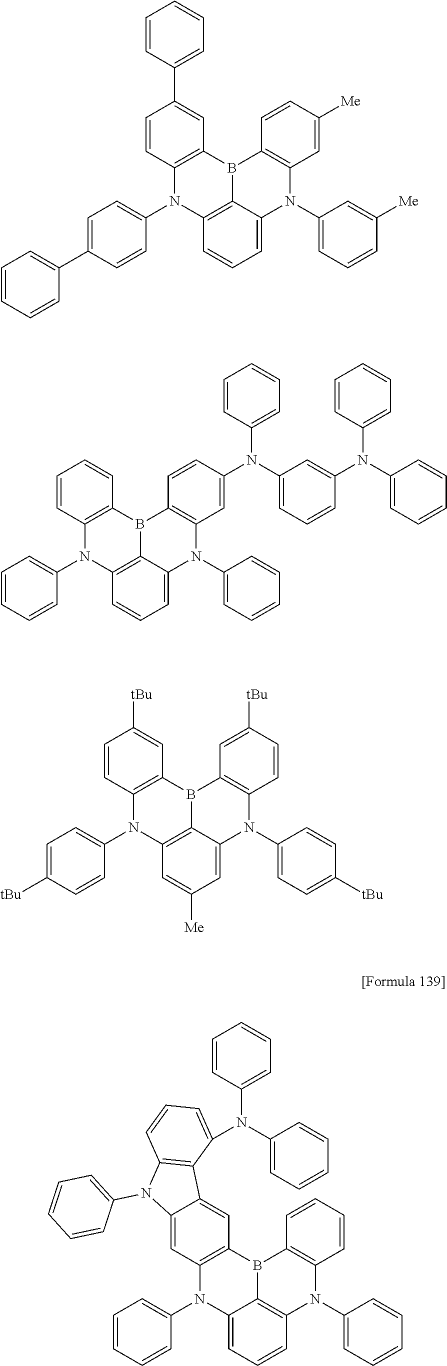 [SMILES: Cc1cccc(N2c3cc(C)ccc3B3c4cc(-c5ccccc5)ccc4N(c4ccc(-c5ccccc5)cc4)c4cccc2c43)c1 ; c1ccc(N(c2ccccc2)c2cccc(N(c3ccccc3)c3ccc4c(c3)N(c3ccccc3)c3cccc5c3B4c3ccccc3N5c3ccccc3)c2)cc1 ; Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1 ; c1ccc(N2c3ccccc3B3c4cc5c6c(N(c7ccccc7)c7ccccc7)cccc6n(-c6ccccc6)c5cc4N(c4ccccc4)c4cccc2c43)cc1]

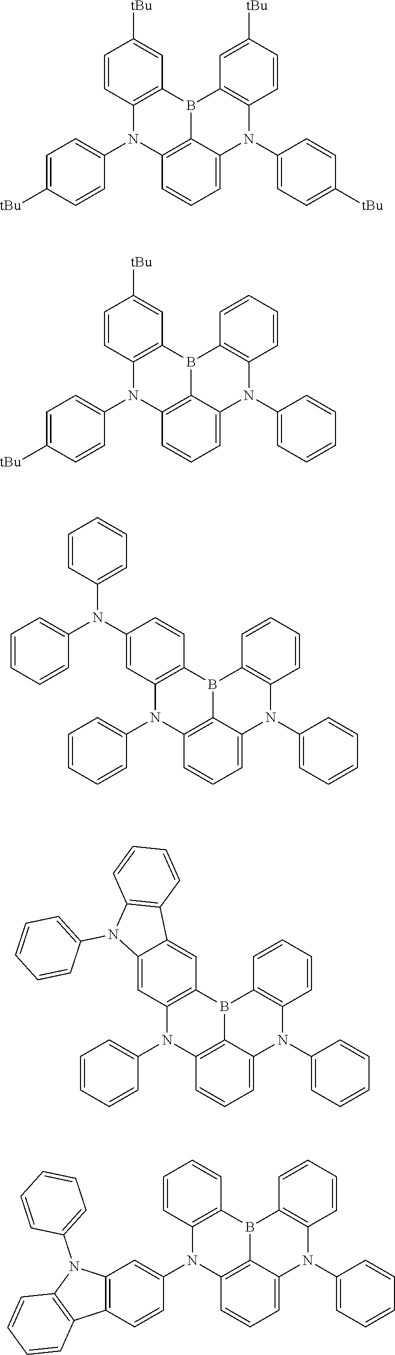 [SMILES: CC(C)(C)c1ccc(N2c3ccc(C(C)(C)C)cc3B3c4cc(C(C)(C)C)ccc4N(c4ccc(C(C)(C)C)cc4)c4cccc2c43)cc1 ; CC(C)(C)c1ccc(N2c3ccc(C(C)(C)C)cc3B3c4ccccc4N(c4ccccc4)c4cccc2c43)cc1 ; c1ccc(N(c2ccccc2)c2ccc3c(c2)N(c2ccccc2)c2cccc4c2B3c2ccccc2N4c2ccccc2)cc1 ; c1ccc(N2c3ccccc3B3c4cc5c6ccccc6n(-c6ccccc6)c5cc4N(c4ccccc4)c4cccc2c43)cc1 ; c1ccc(N2c3ccccc3B3c4ccccc4N(c4ccc5c6ccccc6n(-c6ccccc6)c5c4)c4cccc2c43)cc1]

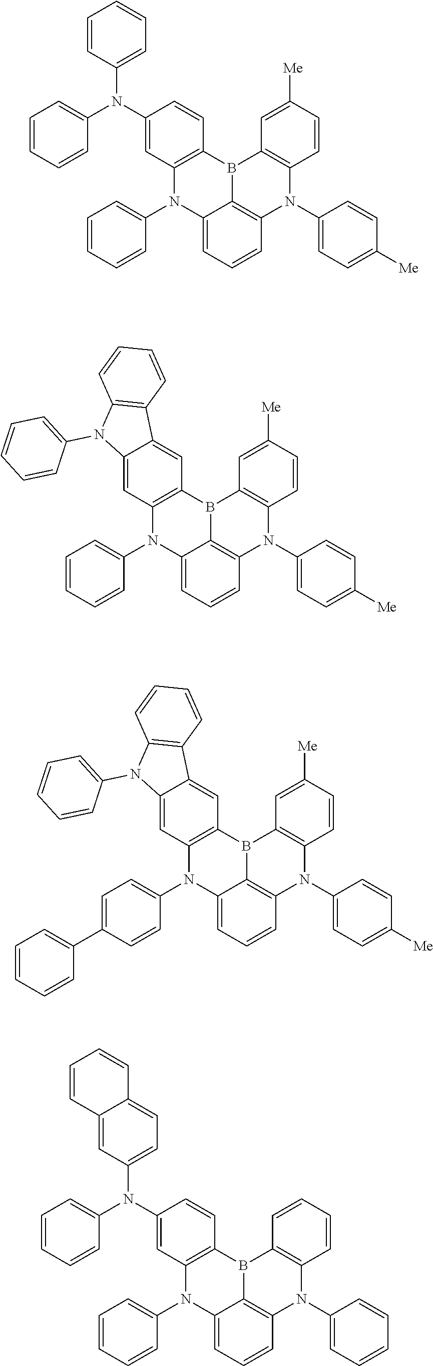 [SMILES: Cc1ccc(N2c3ccc(C)cc3B3c4ccc(N(c5ccccc5)c5ccccc5)cc4N(c4ccccc4)c4cccc2c43)cc1 ; Cc1ccc(N2c3ccc(C)cc3B3c4cc5c6ccccc6n(-c6ccccc6)c5cc4N(c4ccccc4)c4cccc2c43)cc1 ; Cc1ccc(N2c3ccc(C)cc3B3c4cc5c6ccccc6n(-c6ccccc6)c5cc4N(c4ccc(-c5ccccc5)cc4)c4cccc2c43)cc1 ; c1ccc(N(c2ccc3c(c2)N(c2ccccc2)c2cccc4c2B3c2ccccc2N4c2ccccc2)c2ccc3ccccc3c2)cc1]

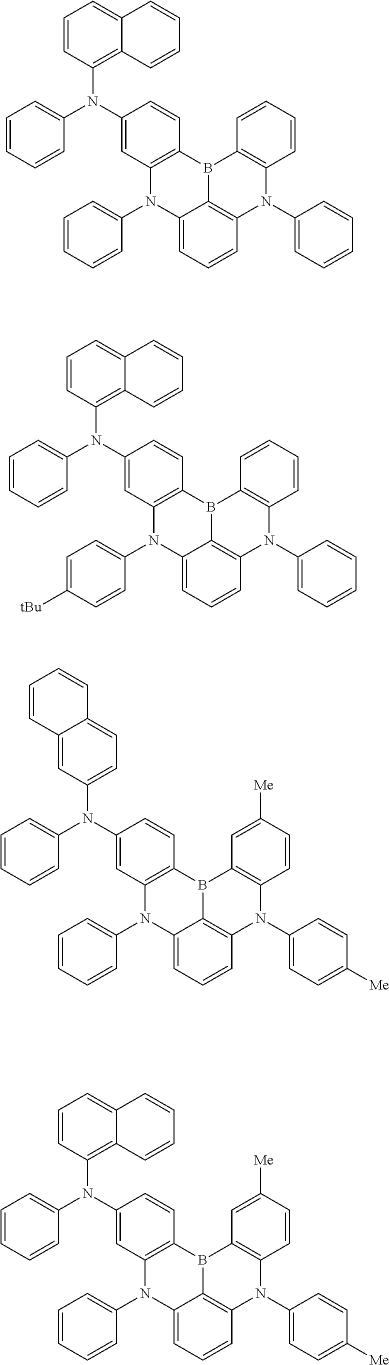 [SMILES: c1ccc(N2c3ccccc3B3c4ccc(N(c5ccccc5)c5cccc6ccccc56)cc4N(c4ccccc4)c4cccc2c43)cc1 ; CC(C)(C)c1ccc(N2c3cc(N(c4ccccc4)c4cccc5ccccc45)ccc3B3c4ccccc4N(c4ccccc4)c4cccc2c43)cc1 ; Cc1ccc(N2c3ccc(C)cc3B3c4ccc(N(c5ccccc5)c5ccc6ccccc6c5)cc4N(c4ccccc4)c4cccc2c43)cc1 ; Cc1ccc(N2c3ccc(C)cc3B3c4ccc(N(c5ccccc5)c5cccc6ccccc56)cc4N(c4ccccc4)c4cccc2c43)cc1]

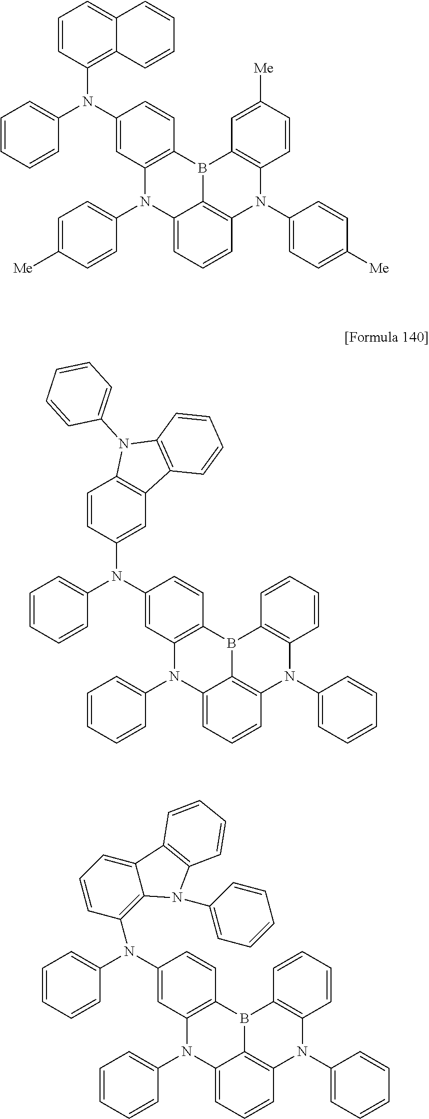 [SMILES: Cc1ccc(N2c3ccc(C)cc3B3c4ccc(N(c5ccccc5)c5cccc6ccccc56)cc4N(c4ccc(C)cc4)c4cccc2c43)cc1 ; c1ccc(N(c2ccc3c(c2)N(c2ccccc2)c2cccc4c2B3c2ccccc2N4c2ccccc2)c2ccc3c(c2)c2ccccc2n3-c2ccccc2)cc1 ; c1ccc(N2c3ccccc3B3c4ccc(N(c5ccccc5)c5cccc6c7ccccc7n(-c7ccccc7)c56)cc4N(c4ccccc4)c4cccc2c43)cc1]

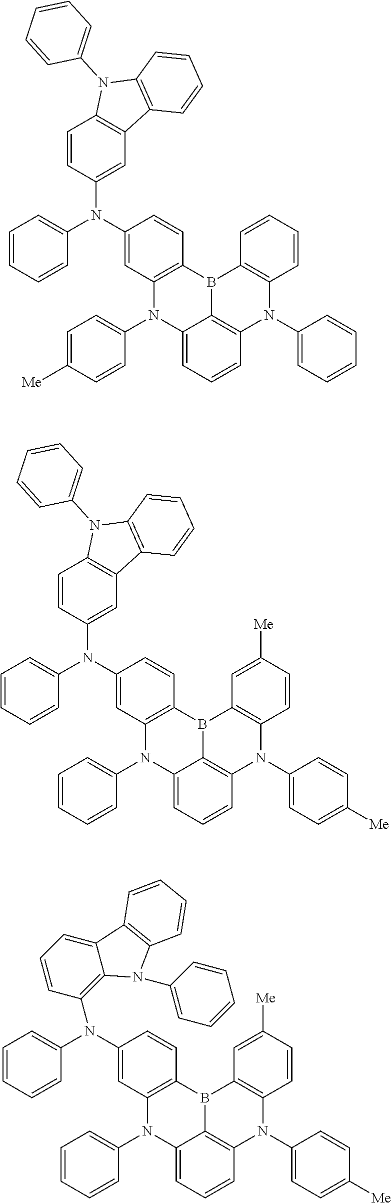 [SMILES: Cc1ccc(N2c3cc(N(c4ccccc4)c4ccc5c(c4)c4ccccc4n5-c4ccccc4)ccc3B3c4ccccc4N(c4ccccc4)c4cccc2c43)cc1 ; Cc1ccc(N2c3ccc(C)cc3B3c4ccc(N(c5ccccc5)c5ccc6c(c5)c5ccccc5n6-c5ccccc5)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccccc4)c4cccc2c43)cc1]

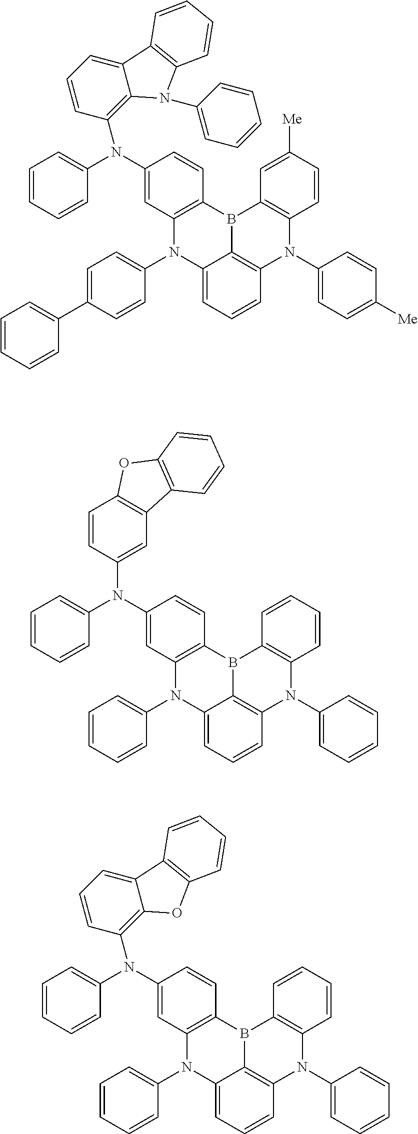 [SMILES: Cc1ccc(N2c3ccc(C)cc3B3c4ccc(N(c5ccccc5)c5cccc6c7ccccc7n(-c7ccccc7)c56)cc4N(c4ccc(-c5ccccc5)cc4)c4cccc2c43)cc1 ; c1ccc(N(c2ccc3c(c2)N(c2ccccc2)c2cccc4c2B3c2ccccc2N4c2ccccc2)c2ccc3oc4ccccc4c3c2)cc1 ; c1ccc(N2c3ccccc3B3c4ccc(N(c5ccccc5)c5cccc6c5oc5ccccc56)cc4N(c4ccccc4)c4cccc2c43)cc1]

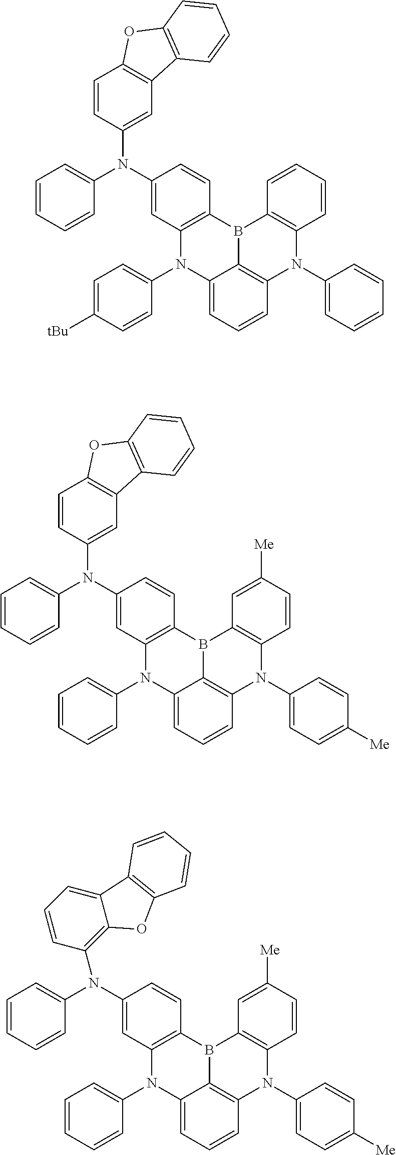 [SMILES: CC(C)(C)c1ccc(N2c3cc(N(c4ccccc4)c4ccc5oc6ccccc6c5c4)ccc3B3c4ccccc4N(c4ccccc4)c4cccc2c43)cc1 ; Cc1ccc(N2c3ccc(C)cc3B3c4ccc(N(c5ccccc5)c5ccc6oc7ccccc7c6c5)cc4N(c4ccccc4)c4cccc2c43)cc1 ; Cc1ccc(N2c3ccc(C)cc3B3c4ccc(N(c5ccccc5)c5cccc6c5oc5ccccc56)cc4N(c4ccccc4)c4cccc2c43)cc1]

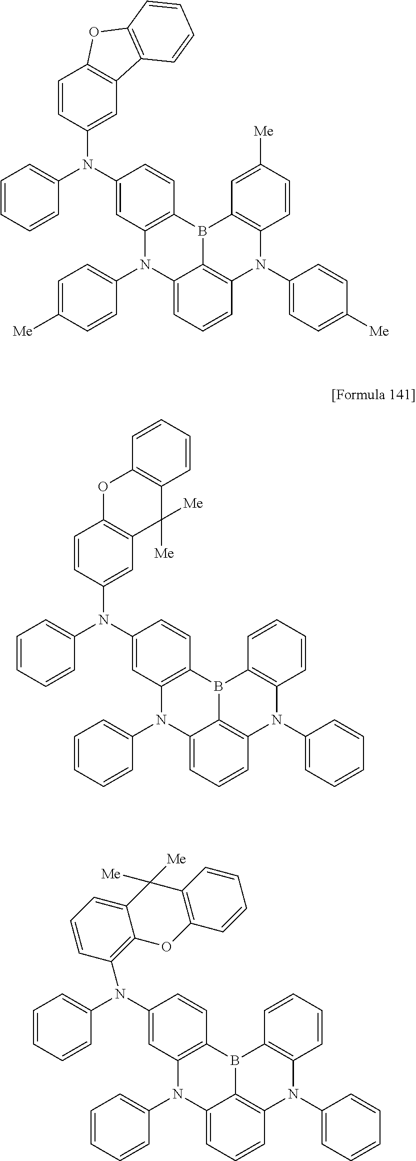 [SMILES: Cc1ccc(N2c3ccc(C)cc3B3c4ccc(N(c5ccccc5)c5ccc6oc7ccccc7c6c5)cc4N(c4ccc(C)cc4)c4cccc2c43)cc1 ; CC1(C)c2ccccc2Oc2ccc(N(c3ccccc3)c3ccc4c(c3)N(c3ccccc3)c3cccc5c3B4c3ccccc3N5c3ccccc3)cc21 ; CC1(C)c2ccccc2Oc2c(N(c3ccccc3)c3ccc4c(c3)N(c3ccccc3)c3cccc5c3B4c3ccccc3N5c3ccccc3)cccc21]

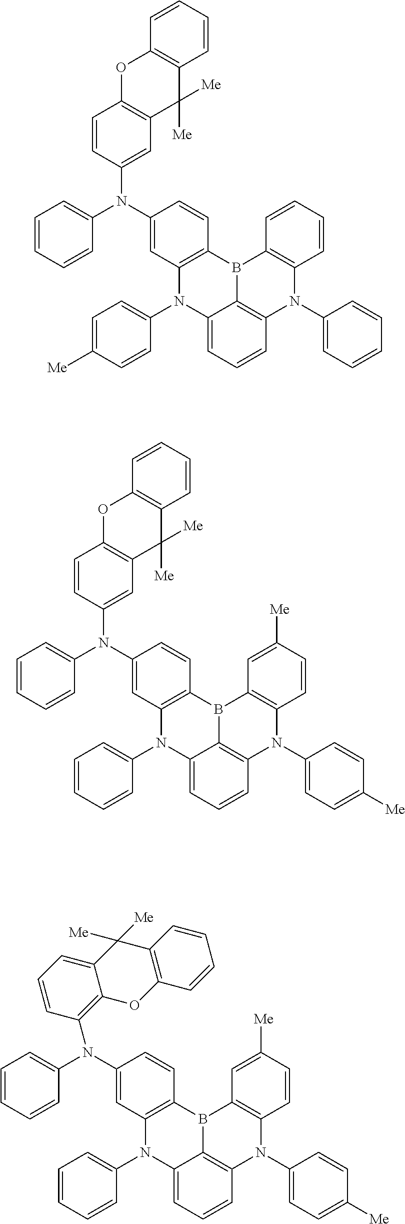 [SMILES: Cc1ccc(N2c3cc(N(c4ccccc4)c4ccc5c(c4)C(C)(C)c4ccccc4O5)ccc3B3c4ccccc4N(c4ccccc4)c4cccc2c43)cc1 ; Cc1ccc(N2c3ccc(C)cc3B3c4ccc(N(c5ccccc5)c5ccc6c(c5)C(C)(C)c5ccccc5O6)cc4N(c4ccccc4)c4cccc2c43)cc1 ; Cc1ccc(N2c3ccc(C)cc3B3c4ccc(N(c5ccccc5)c5cccc6c5Oc5ccccc5C6(C)C)cc4N(c4ccccc4)c4cccc2c43)cc1]

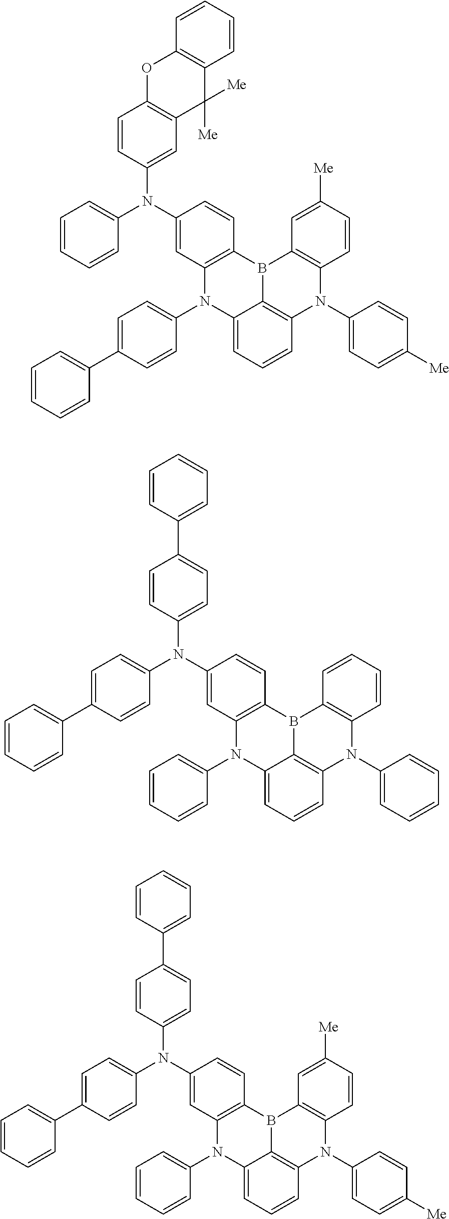 [SMILES: Cc1ccc(N2c3ccc(C)cc3B3c4ccc(N(c5ccccc5)c5ccc6c(c5)C(C)(C)c5ccccc5O6)cc4N(c4ccc(-c5ccccc5)cc4)c4cccc2c43)cc1 ; c1ccc(-c2ccc(N(c3ccc(-c4ccccc4)cc3)c3ccc4c(c3)N(c3ccccc3)c3cccc5c3B4c3ccccc3N5c3ccccc3)cc2)cc1 ; Cc1ccc(N2c3ccc(C)cc3B3c4ccc(N(c5ccc(-c6ccccc6)cc5)c5ccc(-c6ccccc6)cc5)cc4N(c4ccccc4)c4cccc2c43)cc1]

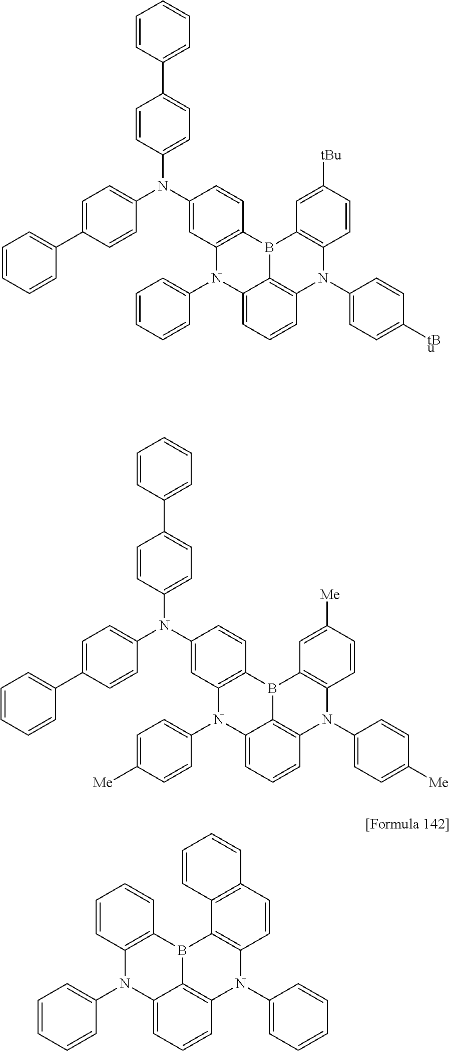 [SMILES: CC(C)(C)c1ccc(N2c3ccc(C(C)(C)C)cc3B3c4ccc(N(c5ccc(-c6ccccc6)cc5)c5ccc(-c6ccccc6)cc5)cc4N(c4ccccc4)c4cccc2c43)cc1 ; Cc1ccc(N2c3ccc(C)cc3B3c4ccc(N(c5ccc(-c6ccccc6)cc5)c5ccc(-c6ccccc6)cc5)cc4N(c4ccc(C)cc4)c4cccc2c43)cc1 ; c1ccc(N2c3ccccc3B3c4c2cccc4N(c2ccccc2)c2ccc4ccccc4c23)cc1]

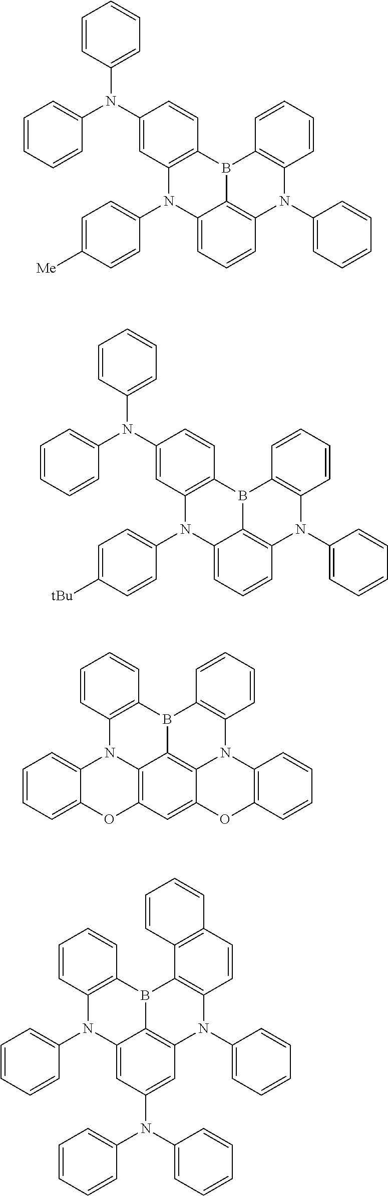 [SMILES: Cc1ccc(N2c3cc(N(c4ccccc4)c4ccccc4)ccc3B3c4ccccc4N(c4ccccc4)c4cccc2c43)cc1 ; CC(C)(C)c1ccc(N2c3cc(N(c4ccccc4)c4ccccc4)ccc3B3c4ccccc4N(c4ccccc4)c4cccc2c43)cc1 ; c1ccc2c(c1)B1c3ccccc3-n3c4ccccc4oc4cc5oc6ccccc6n-2c5c1c43 ; c1ccc(N(c2ccccc2)c2cc3c4c(c2)N(c2ccccc2)c2ccc5ccccc5c2B4c2ccccc2N3c2ccccc2)cc1]

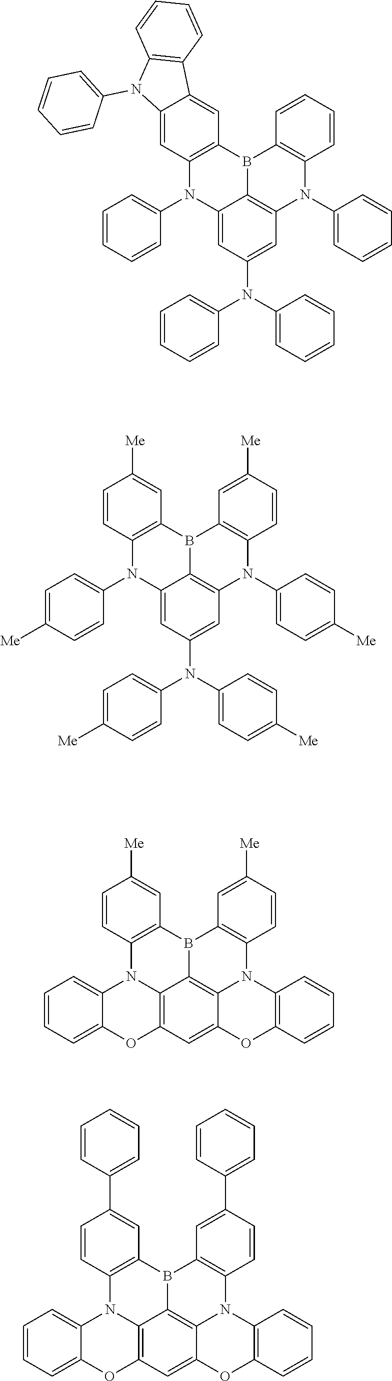 [SMILES: c1ccc(N(c2ccccc2)c2cc3c4c(c2)N(c2ccccc2)c2cc5c(cc2B4c2ccccc2N3c2ccccc2)c2ccccc2n5-c2ccccc2)cc1 ; Cc1ccc(N(c2ccc(C)cc2)c2cc3c4c(c2)N(c2ccc(C)cc2)c2ccc(C)cc2B4c2cc(C)ccc2N3c2ccc(C)cc2)cc1 ; Cc1ccc2c(c1)B1c3cc(C)ccc3-n3c4ccccc4oc4cc5oc6ccccc6n-2c5c1c43 ; c1ccc(-c2ccc3c(c2)B2c4cc(-c5ccccc5)ccc4-n4c5ccccc5oc5cc6oc7ccccc7n-3c6c2c54)cc1]

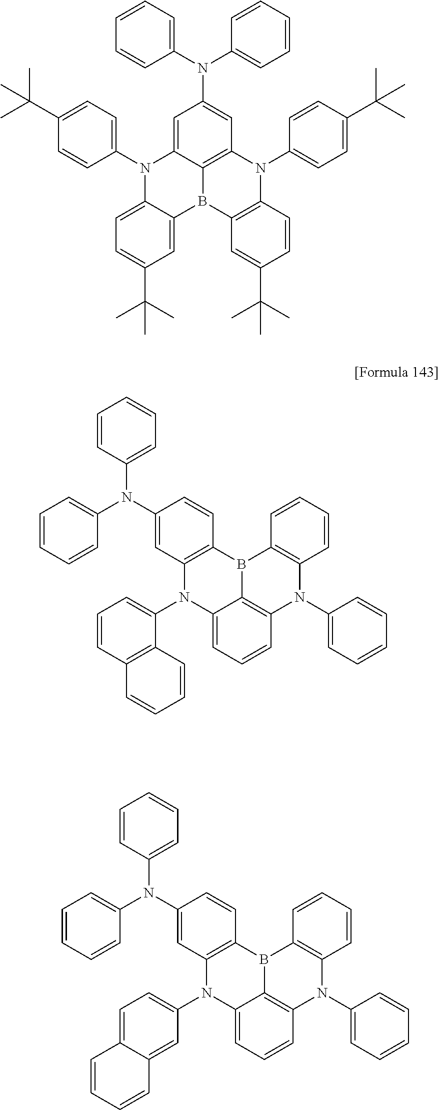 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1 ; c1ccc(N(c2ccccc2)c2ccc3c(c2)N(c2cccc4ccccc24)c2cccc4c2B3c2ccccc2N4c2ccccc2)cc1 ; c1ccc(N(c2ccccc2)c2ccc3c(c2)N(c2ccc4ccccc4c2)c2cccc4c2B3c2ccccc2N4c2ccccc2)cc1]

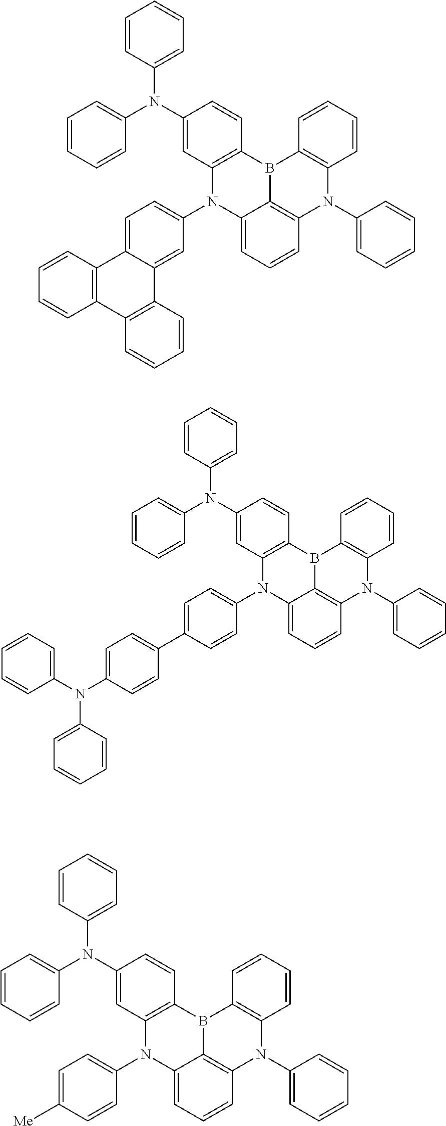 [SMILES: c1ccc(N(c2ccccc2)c2ccc3c(c2)N(c2ccc4c5ccccc5c5ccccc5c4c2)c2cccc4c2B3c2ccccc2N4c2ccccc2)cc1 ; c1ccc(N(c2ccccc2)c2ccc(-c3ccc(N4c5cc(N(c6ccccc6)c6ccccc6)ccc5B5c6ccccc6N(c6ccccc6)c6cccc4c65)cc3)cc2)cc1 ; Cc1ccc(N2c3cc(N(c4ccccc4)c4ccccc4)ccc3B3c4ccccc4N(c4ccccc4)c4cccc2c43)cc1]

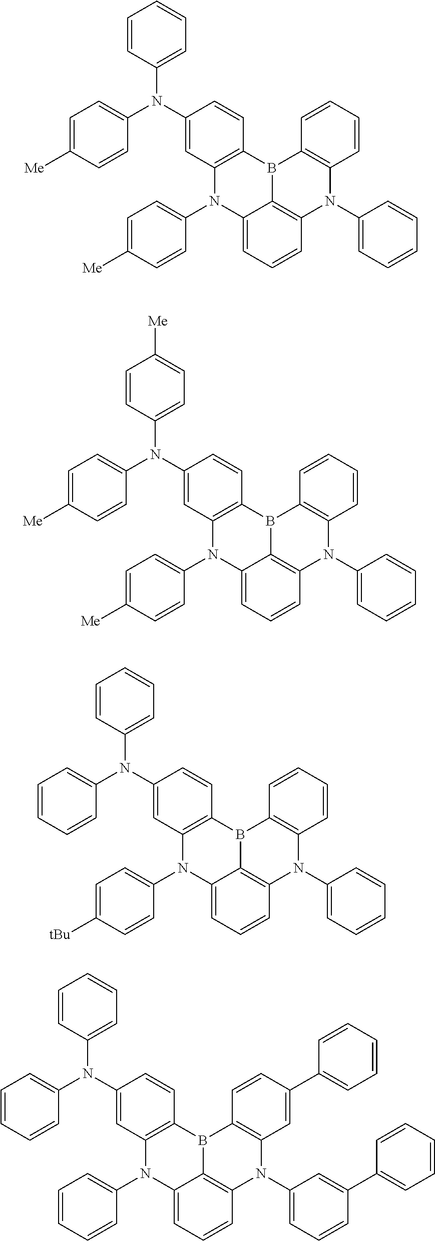

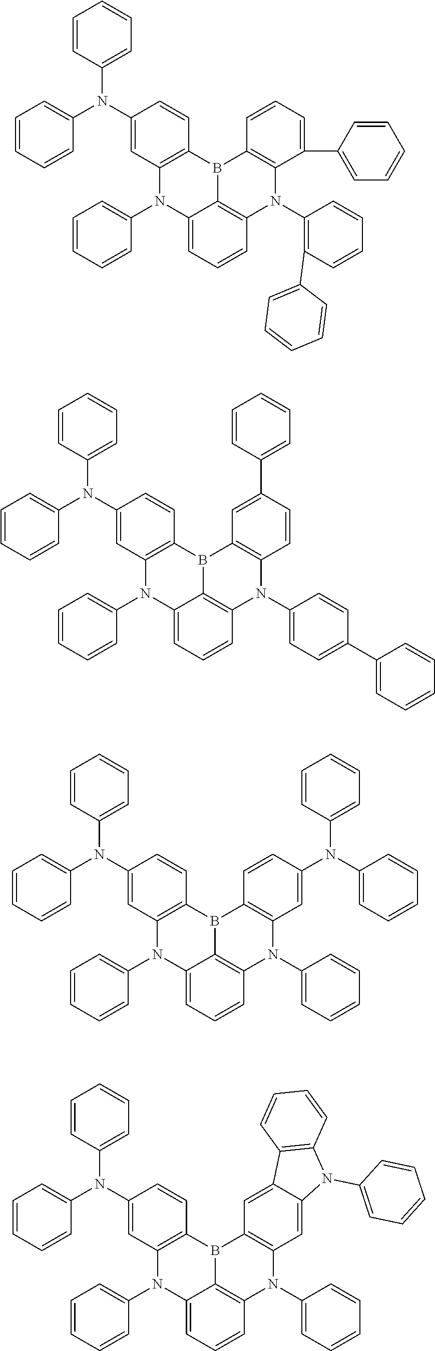 [SMILES: c1ccc(-c2ccccc2N2c3cccc4c3B(c3ccc(N(c5ccccc5)c5ccccc5)cc3N4c3ccccc3)c3cccc(-c4ccccc4)c32)cc1 ; c1ccc(-c2ccc(N3c4ccc(-c5ccccc5)cc4B4c5ccc(N(c6ccccc6)c6ccccc6)cc5N(c5ccccc5)c5cccc3c54)cc2)cc1 ; c1ccc(N(c2ccccc2)c2ccc3c(c2)N(c2ccccc2)c2cccc4c2B3c2ccc(N(c3ccccc3)c3ccccc3)cc2N4c2ccccc2)cc1 ; c1ccc(N(c2ccccc2)c2ccc3c(c2)N(c2ccccc2)c2cccc4c2B3c2cc3c5ccccc5n(-c5ccccc5)c3cc2N4c2ccccc2)cc1]

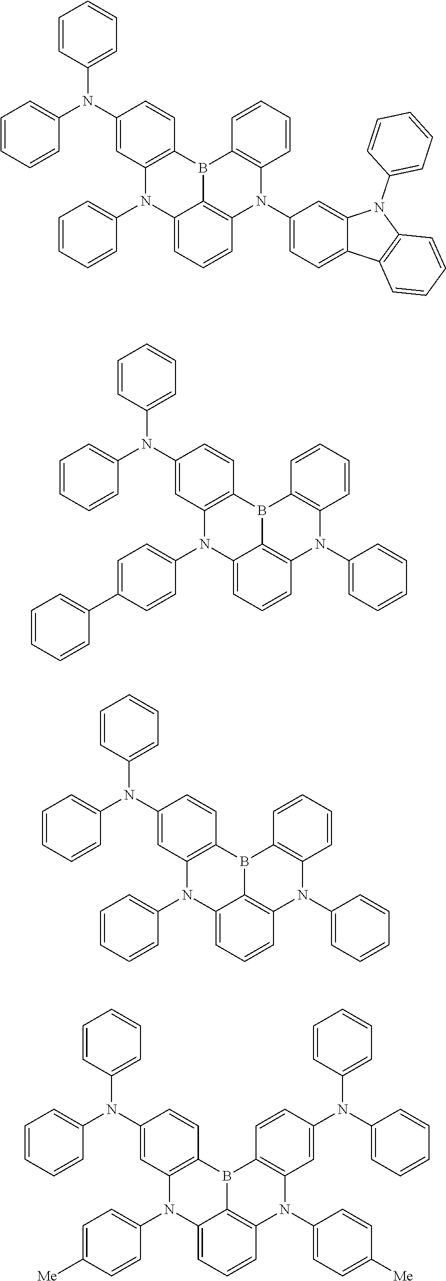 [SMILES: c1ccc(N(c2ccccc2)c2ccc3c(c2)N(c2ccccc2)c2cccc4c2B3c2ccccc2N4c2ccc3c4ccccc4n(-c4ccccc4)c3c2)cc1 ; c1ccc(-c2ccc(N3c4cc(N(c5ccccc5)c5ccccc5)ccc4B4c5ccccc5N(c5ccccc5)c5cccc3c54)cc2)cc1 ; c1ccc(N(c2ccccc2)c2ccc3c(c2)N(c2ccccc2)c2cccc4c2B3c2ccccc2N4c2ccccc2)cc1 ; Cc1ccc(N2c3cc(N(c4ccccc4)c4ccccc4)ccc3B3c4ccc(N(c5ccccc5)c5ccccc5)cc4N(c4ccc(C)cc4)c4cccc2c43)cc1]

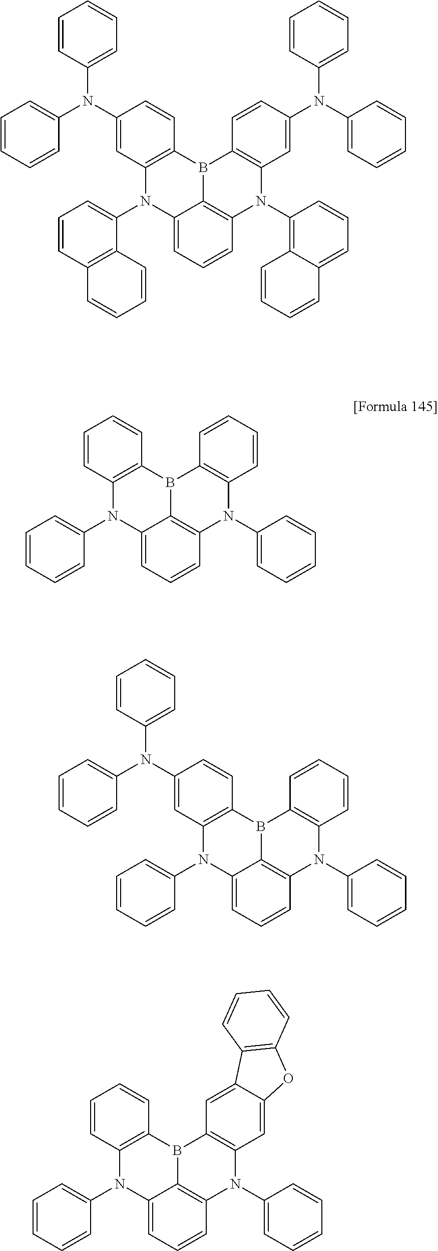 [SMILES: c1ccc(N(c2ccccc2)c2ccc3c(c2)N(c2cccc4ccccc24)c2cccc4c2B3c2ccc(N(c3ccccc3)c3ccccc3)cc2N4c2cccc3ccccc23)cc1 ; c1ccc(N2c3ccccc3B3c4ccccc4N(c4ccccc4)c4cccc2c43)cc1 ; c1ccc(N(c2ccccc2)c2ccc3c(c2)N(c2ccccc2)c2cccc4c2B3c2ccccc2N4c2ccccc2)cc1 ; c1ccc(N2c3ccccc3B3c4cc5c(cc4N(c4ccccc4)c4cccc2c43)oc2ccccc25)cc1]

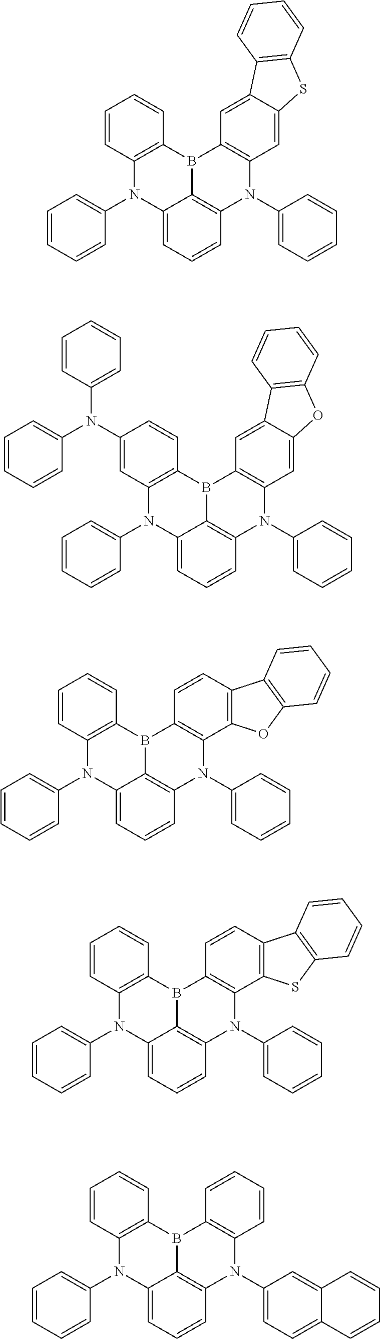 [SMILES: c1ccc(N2c3ccccc3B3c4cc5c(cc4N(c4ccccc4)c4cccc2c43)sc2ccccc25)cc1 ; c1ccc(N(c2ccccc2)c2ccc3c(c2)N(c2ccccc2)c2cccc4c2B3c2cc3c(cc2N4c2ccccc2)oc2ccccc23)cc1 ; c1ccc(N2c3ccccc3B3c4ccc5c(oc6ccccc65)c4N(c4ccccc4)c4cccc2c43)cc1 ; c1ccc(N2c3ccccc3B3c4ccc5c(sc6ccccc65)c4N(c4ccccc4)c4cccc2c43)cc1 ; c1ccc(N2c3ccccc3B3c4ccccc4N(c4ccc5ccccc5c4)c4cccc2c43)cc1]

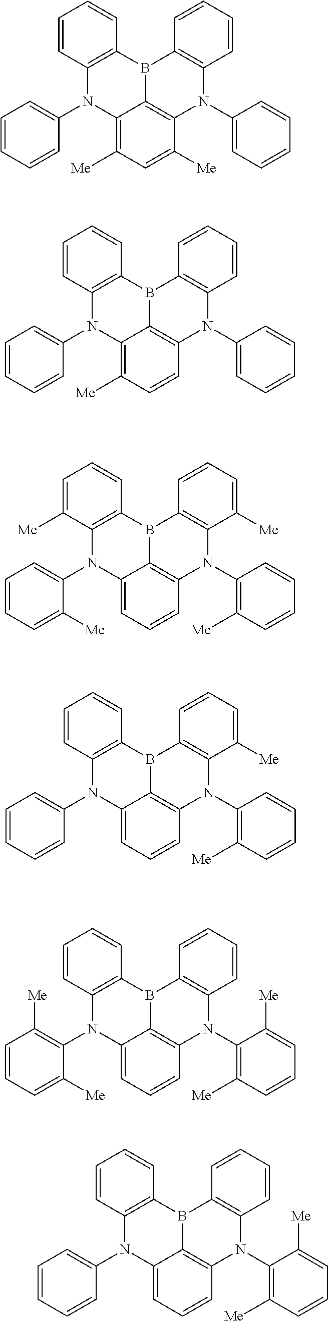 [SMILES: Cc1cc(C)c2c3c1N(c1ccccc1)c1ccccc1B3c1ccccc1N2c1ccccc1 ; Cc1ccc2c3c1N(c1ccccc1)c1ccccc1B3c1ccccc1N2c1ccccc1 ; Cc1ccccc1N1c2cccc3c2B(c2cccc(C)c21)c1cccc(C)c1N3c1ccccc1C ; Cc1ccccc1N1c2cccc3c2B(c2ccccc2N3c2ccccc2)c2cccc(C)c21 ; Cc1cccc(C)c1N1c2ccccc2B2c3ccccc3N(c3c(C)cccc3C)c3cccc1c32 ; Cc1cccc(C)c1N1c2ccccc2B2c3ccccc3N(c3ccccc3)c3cccc1c32]

### Compounds Represented by Formula (7)

The following describes the compounds represented by formula (7).

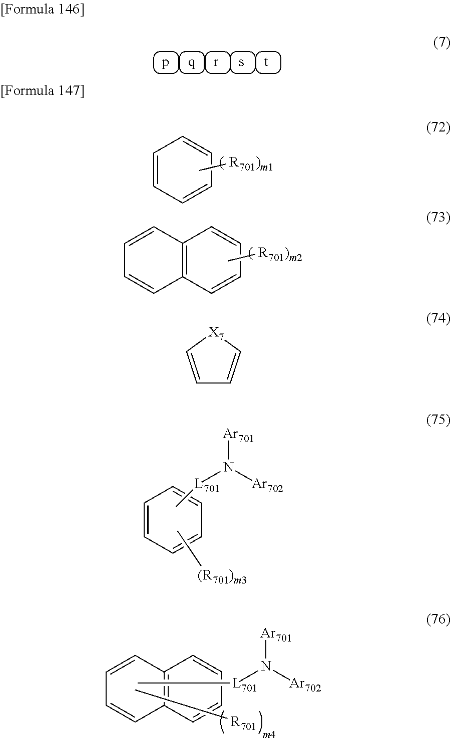

In formula (7),

ring r is a ring represented by formula (72) or (73) and fused with adjacent ring(s) at any position(s);

rings q and s each independently represent a ring represented by formula (74) fused with adjacent ring(s) at any position(s);

rings p and t each independently represent a structure represented by formula (75) or (76) fused with adjacent ring(s) at any position(s); and

X₇ is an oxygen atom, a sulfur atom, or NR₇₀₂.

When multiple R₇₀₁s are present, the multiple R₇₀₁s adjacent to one another are: bonded together to form a substituted or unsubstituted monocyclic ring; bonded together to form a substituted or unsubstituted fused ring; or not bonded together;

R₇₀₁ and R₇₀₂ not forming the monocyclic ring and not forming the fused ring each independently represent: a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms;

Ar₇₀₁ and Ar₇₀₂ each independently represent: a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms;

L₇₀₁ is: a substituted or unsubstituted alkylene group having 1 to 50 carbon atoms; a substituted or unsubstituted alkenylene group having 2 to 50 carbon atoms; a substituted or unsubstituted alkynylene group having 2 to 50 carbon atoms; a substituted or unsubstituted cycloalkylene group having 3 to 50 ring carbon atoms; a substituted or unsubstituted arylene group having 6 to 50 ring carbon atoms; or a substituted or unsubstituted divalent heterocyclic group having 5 to 50 ring atoms;

m1 is 0, 1, or 2;

m2 is 0, 1, 2, 3, or 4;

each m3 independently represents 0, 1, 2, or 3;

each m4 independently represents 0, 1, 2, 3, 4, or 5;

when multiple R₇₀₁s are present, the multiple R₇₀₁s are mutually the same or different;

when multiple X₇s are present, the multiple X₇s are mutually the same or different;

when multiple R₇₀₂s are present, the multiple R₇₀₂s are mutually the same or different;

when multiple Ar₇₀₁s are present, the multiple Ar₇₀₁s are mutually the same or different;

when multiple Ar₇₀₂s are present, the multiple Ar₇₀₂s are mutually the same or different; and

when multiple L₇₀₁s are present, the multiple L₇₀₁s are mutually the same or different.

In formula (7), each of rings p, q, r, s, and t is fused to the adjacent ring(s), sharing two carbon atoms. The position and direction of fusion are not critical; the rings can be fused at any position and in any direction.

In an exemplary embodiment, in formula (72) or (73), as ring r, m1=0, or m2=0 is satisfied.

In an exemplary embodiment, the compounds represented by formula (7) are represented by any of formulae (71-1) to (71-6) below.

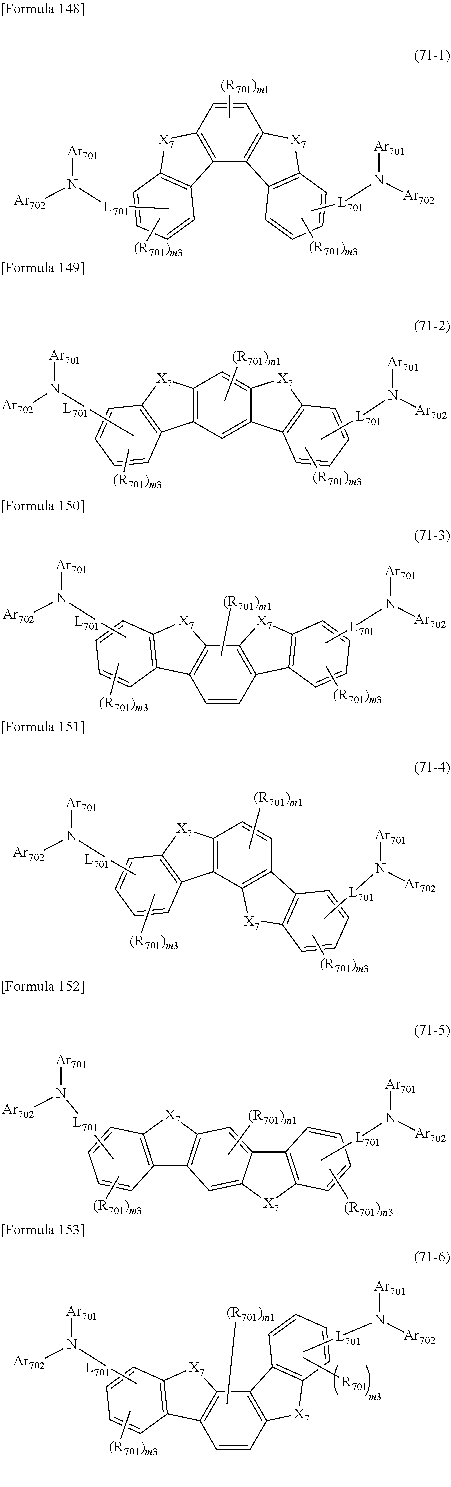

In formulae (71-1) to (71-6), R₇₀₁, X₇, Ar₇₀₁, Ar₇₀₂, L₇₀₁, m1, and m3 represent the same as R₇₀₁, X₇, Ar₇₀₁, Ar₇₀₂, L₇₀₁, m1, and m3, respectively, in formula (7).

In an exemplary embodiment, the compounds represented by formula (7) are represented by any of formulae (71-11) to (71-13) below.

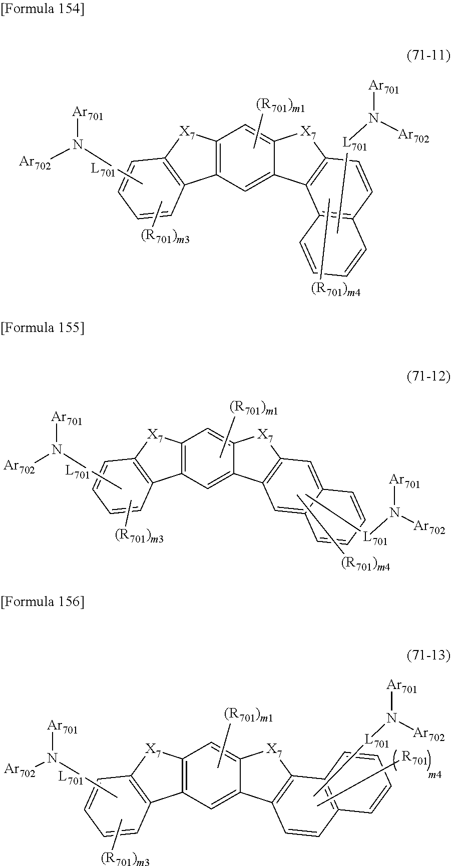

In formulae (71-11) to (71-13), R₇₀₁, X₇, Ar₇₀₁, Ar₇₀₂, L₇₀₁, m1, m3, and m4 represent the same as R₇₀₁, X₇, Ar₇₀₁, Ar₇₀₂, L₇₀₁, m1, m3, and m4, respectively, in formula (7).

In an exemplary embodiment, the compounds represented by formula (7) are represented by any of formulae (71-21) to (71-25) below.

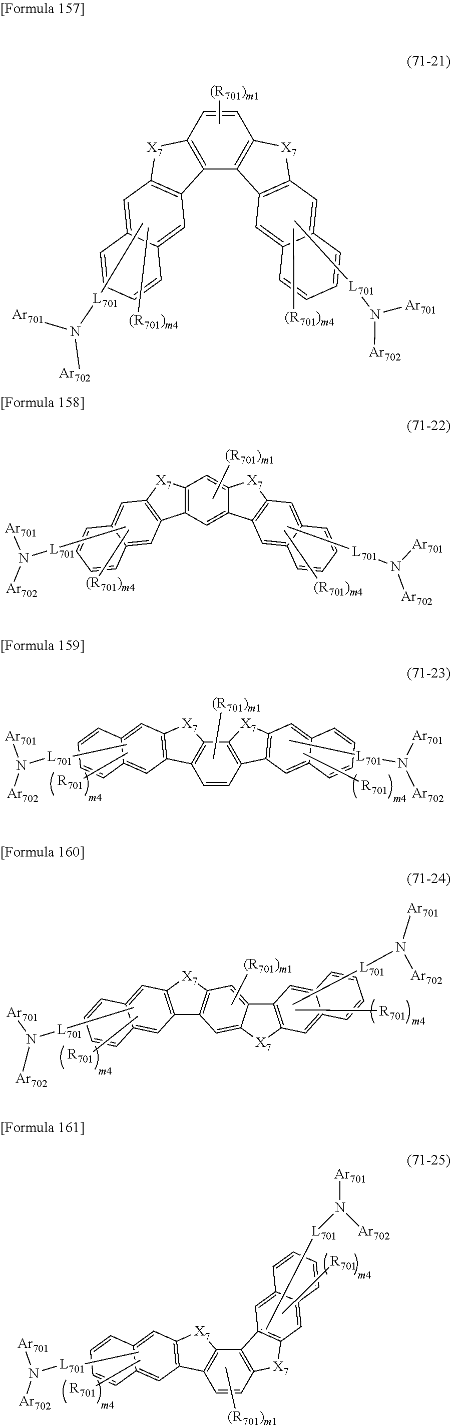

In formulae (71-21) to (71-25), R₇₀₁, X₇, Ar₇₀₁, Ar₇₀₂, L₇₀₁, m1, and m4 represent the same as R₇₀₁, X₇, Ar₇₀₁, Ar₇₀₂, L₇₀₁, m1, and m4, respectively, in formula (7).

In an exemplary embodiment, the compounds represented by formula (7) are represented by any of formulae (71-31) to (71-33) below.

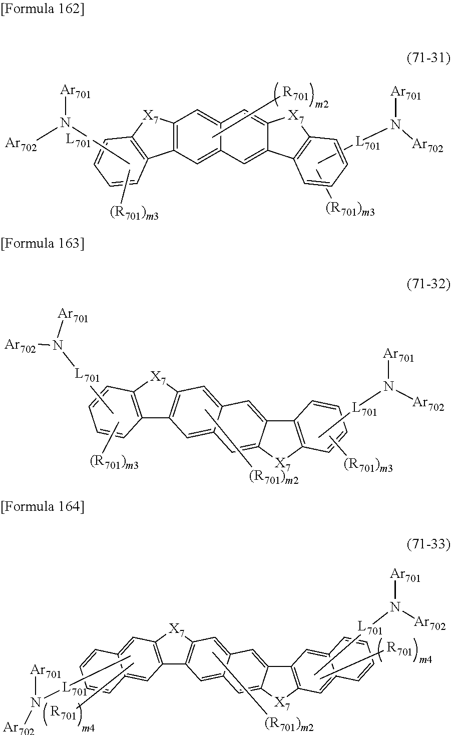

In formulae (71-31) to (71-33), R₇₀₁, X₇, Ar₇₀₁, Ar₇₀₂, L₇₀₁, and m2 to m4 represent the same as R₇₀₁, X₇, Ar₇₀₁, Ar₇₀₂, L₇₀₁, and m2 to m4, respectively, in formula (7).

In an exemplary embodiment, Ar₇₀₁ and Ar₇₀₂ each independently represent a substituted or unsubstituted aryl group having 6 to 50 ring carbon atoms.

In an exemplary embodiment, one of Ar₇₀₁ and Ar₇₀₂ is a substituted or unsubstituted aryl group having 6 to 50 ring carbon atoms, and the other is a substituted or unsubstituted heterocyclic group having 5 to 50 ring atoms.

Specific examples of compounds represented by formula (7) include, for instance, the following compounds.

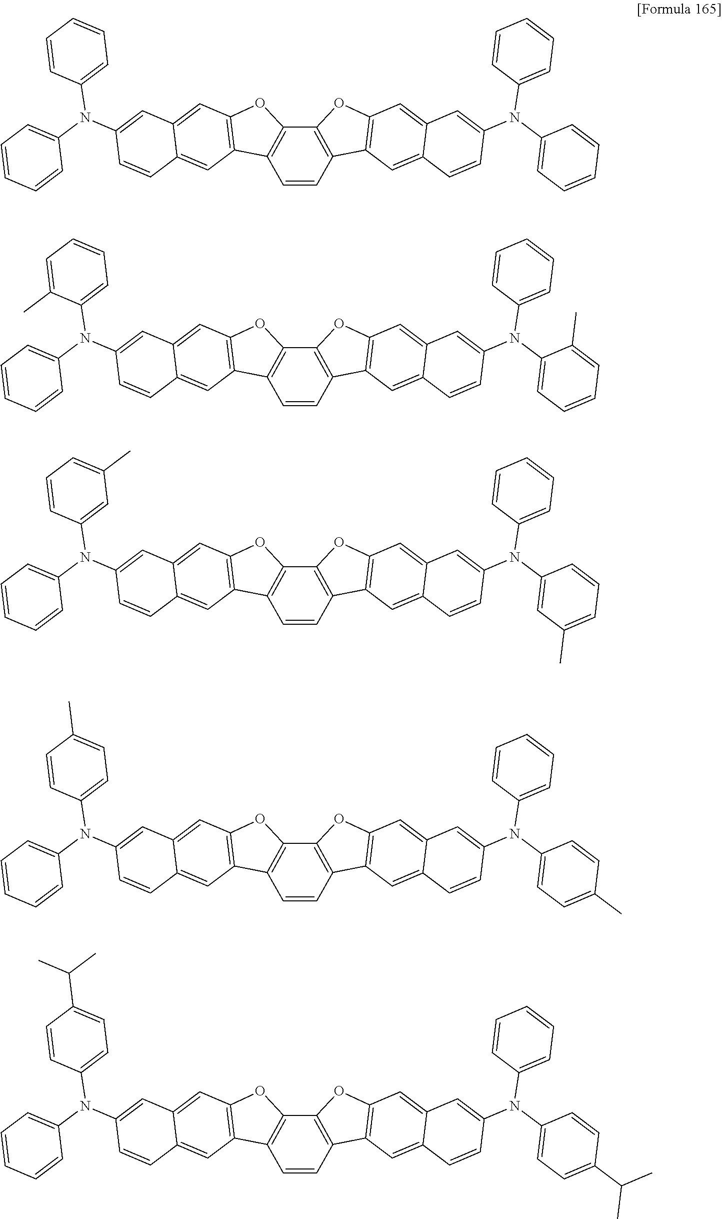 [SMILES: c1ccc(N(c2ccccc2)c2ccc3cc4c(cc3c2)oc2c4ccc3c4cc5ccc(N(c6ccccc6)c6ccccc6)cc5cc4oc32)cc1 ; Cc1ccccc1N(c1ccccc1)c1ccc2cc3c(cc2c1)oc1c3ccc2c3cc4ccc(N(c5ccccc5)c5ccccc5C)cc4cc3oc21 ; Cc1cccc(N(c2ccccc2)c2ccc3cc4c(cc3c2)oc2c4ccc3c4cc5ccc(N(c6ccccc6)c6cccc(C)c6)cc5cc4oc32)c1 ; Cc1ccc(N(c2ccccc2)c2ccc3cc4c(cc3c2)oc2c4ccc3c4cc5ccc(N(c6ccccc6)c6ccc(C)cc6)cc5cc4oc32)cc1 ; CC(C)c1ccc(N(c2ccccc2)c2ccc3cc4c(cc3c2)oc2c4ccc3c4cc5ccc(N(c6ccccc6)c6ccc(C(C)C)cc6)cc5cc4oc32)cc1]

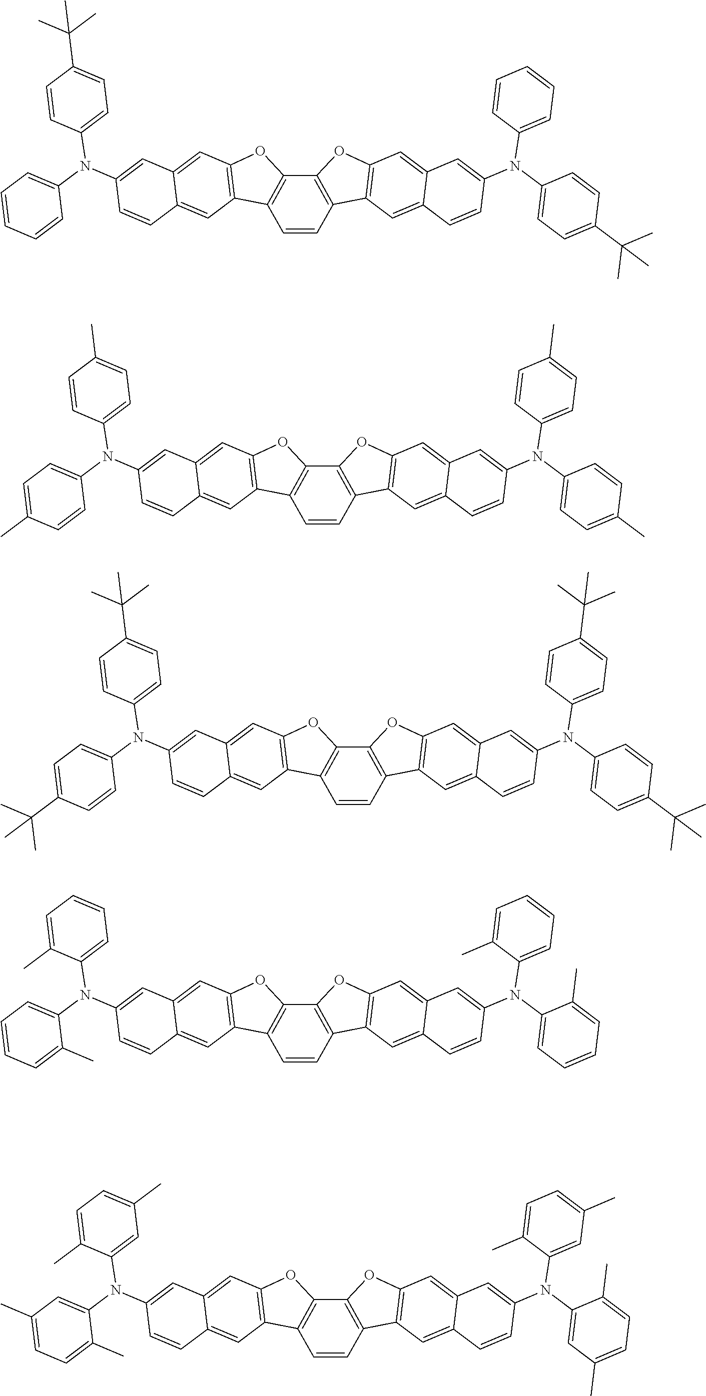

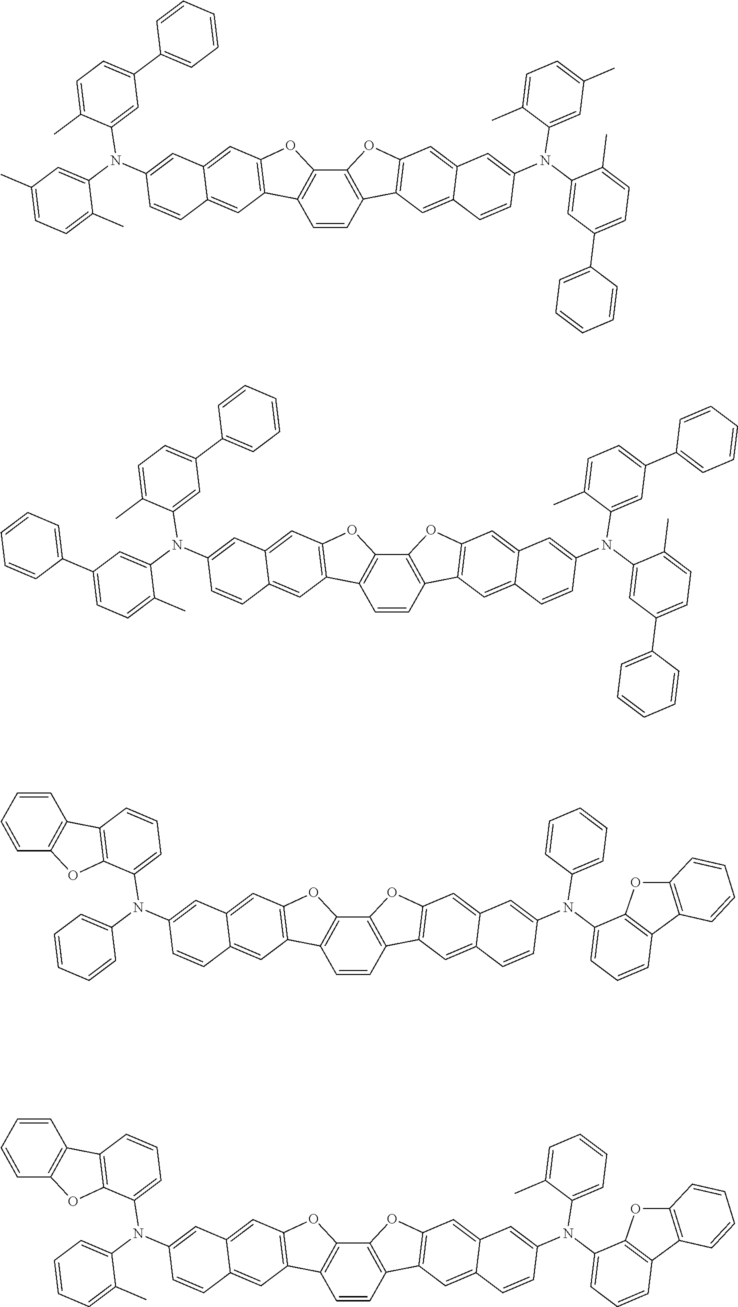 [SMILES: Cc1ccc(C)c(N(c2ccc3cc4c(cc3c2)oc2c4ccc3c4cc5ccc(N(c6cc(C)ccc6C)c6cc(-c7ccccc7)ccc6C)cc5cc4oc32)c2cc(-c3ccccc3)ccc2C)c1 ; Cc1ccc(-c2ccccc2)cc1N(c1ccc2cc3c(cc2c1)oc1c3ccc2c3cc4ccc(N(c5cc(-c6ccccc6)ccc5C)c5cc(-c6ccccc6)ccc5C)cc4cc3oc21)c1cc(-c2ccccc2)ccc1C ; c1ccc(N(c2ccc3cc4c(cc3c2)oc2c4ccc3c4cc5ccc(N(c6ccccc6)c6cccc7c6oc6ccccc67)cc5cc4oc32)c2cccc3c2oc2ccccc23)cc1 ; Cc1ccccc1N(c1ccc2cc3c(cc2c1)oc1c3ccc2c3cc4ccc(N(c5ccccc5C)c5cccc6c5oc5ccccc56)cc4cc3oc21)c1cccc2c1oc1ccccc12]

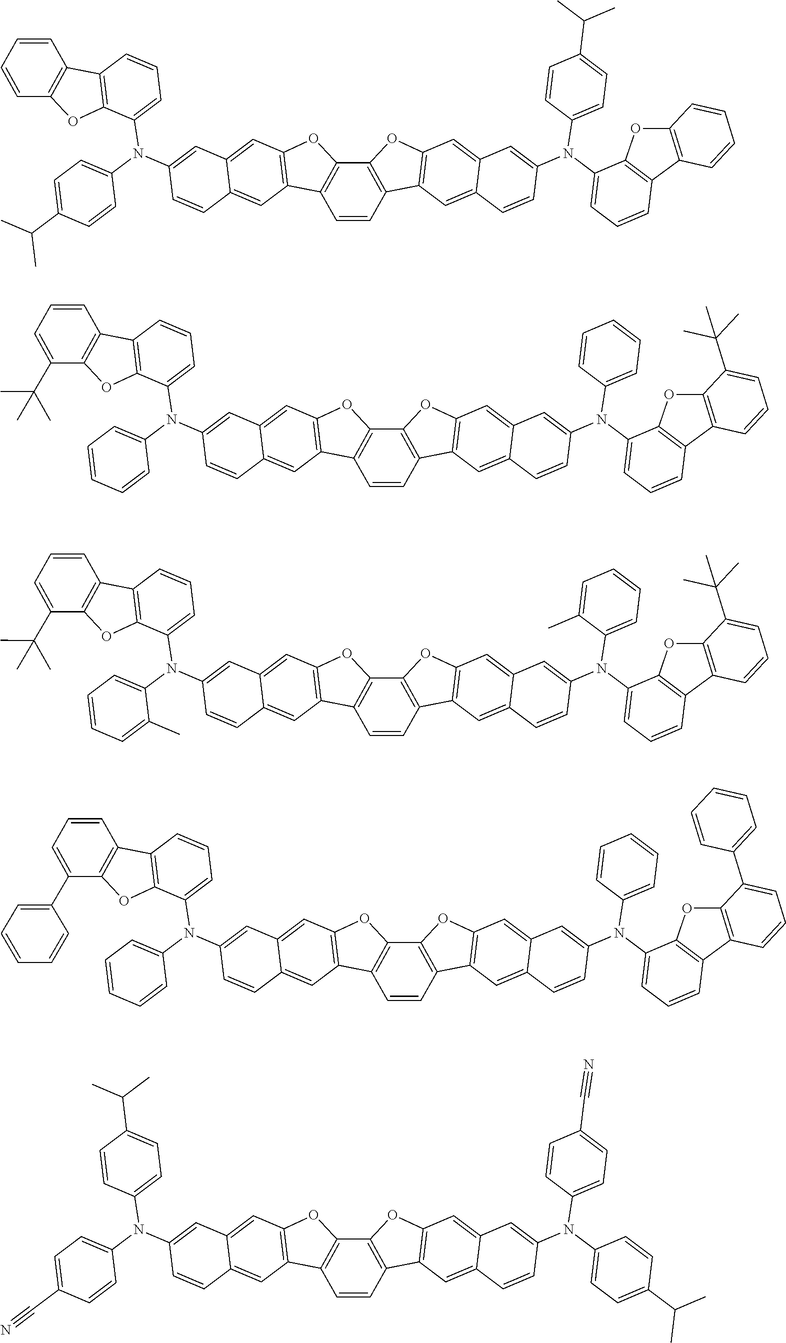

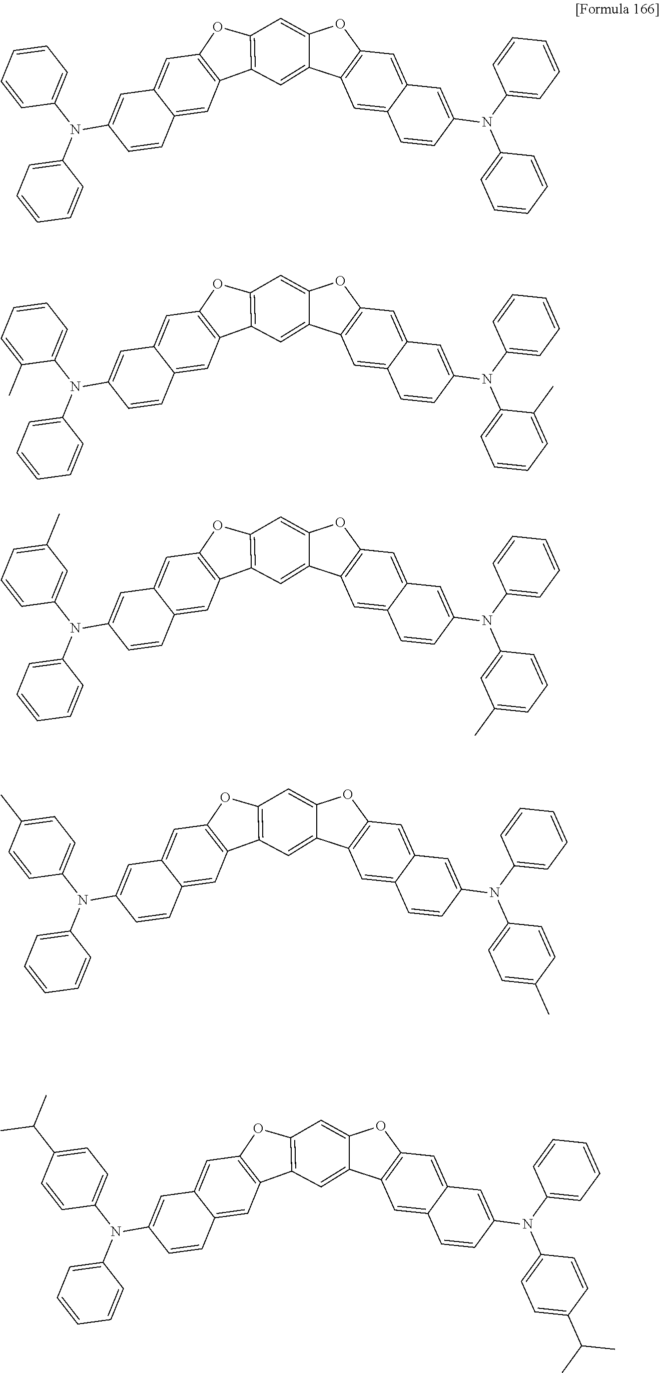

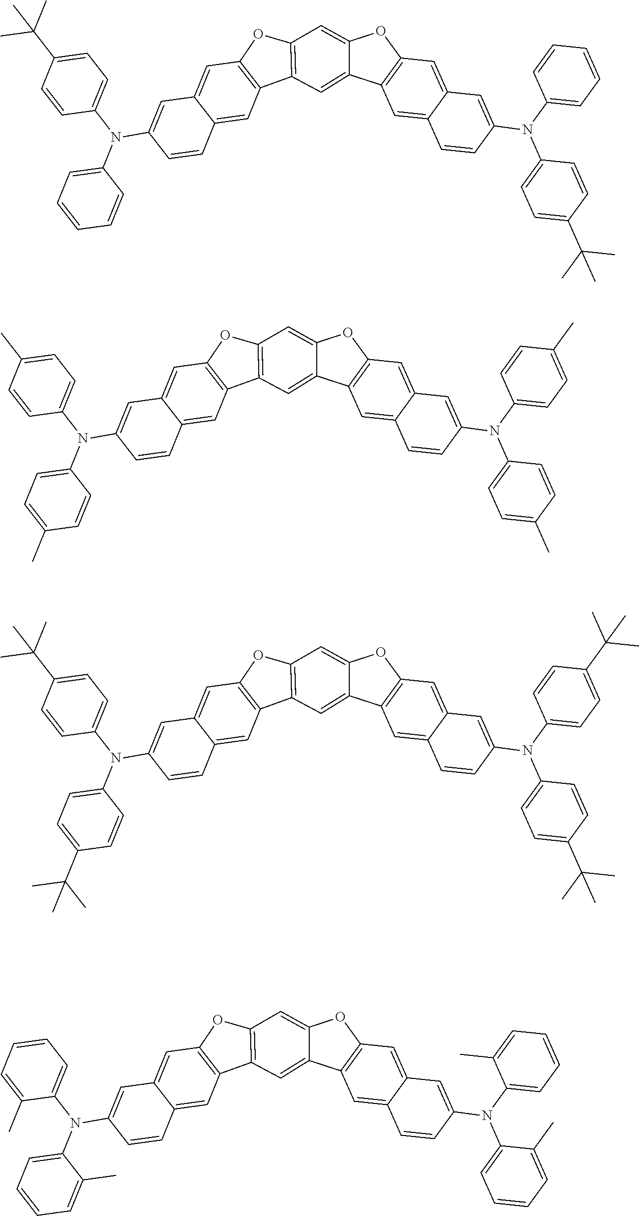

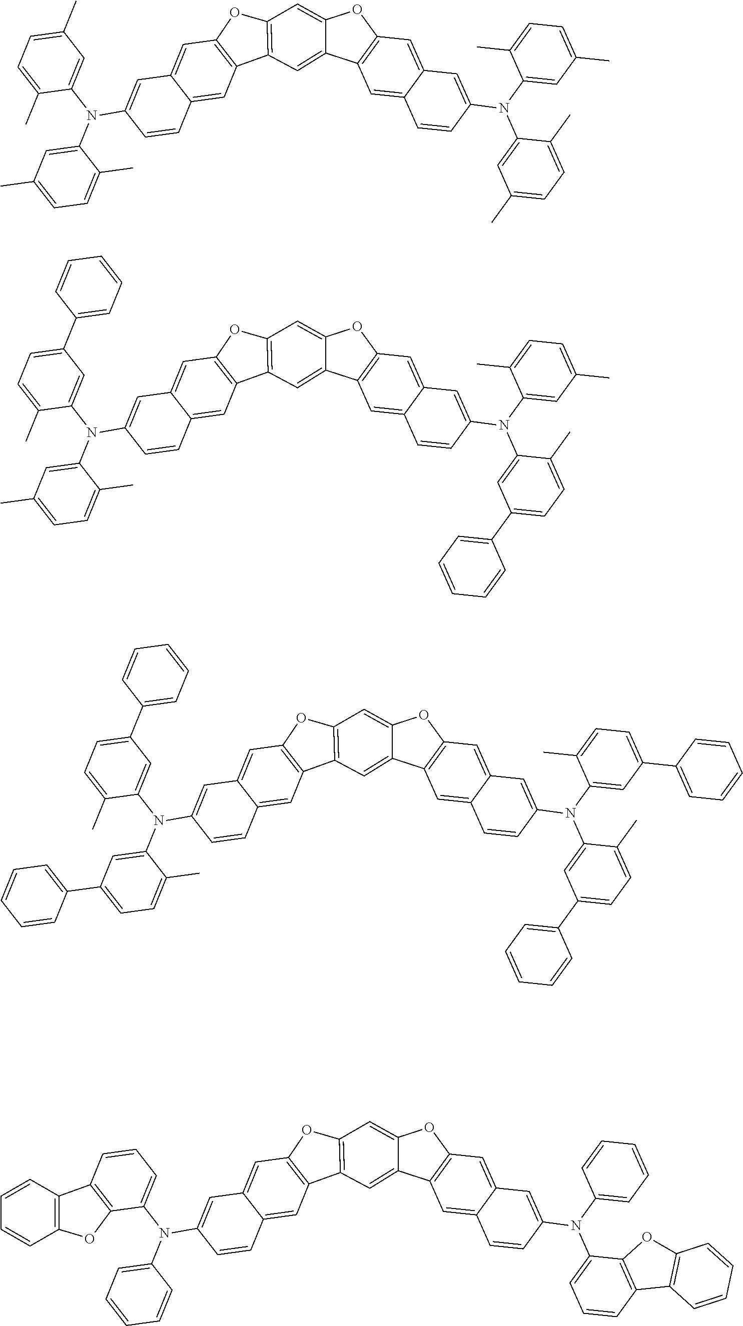

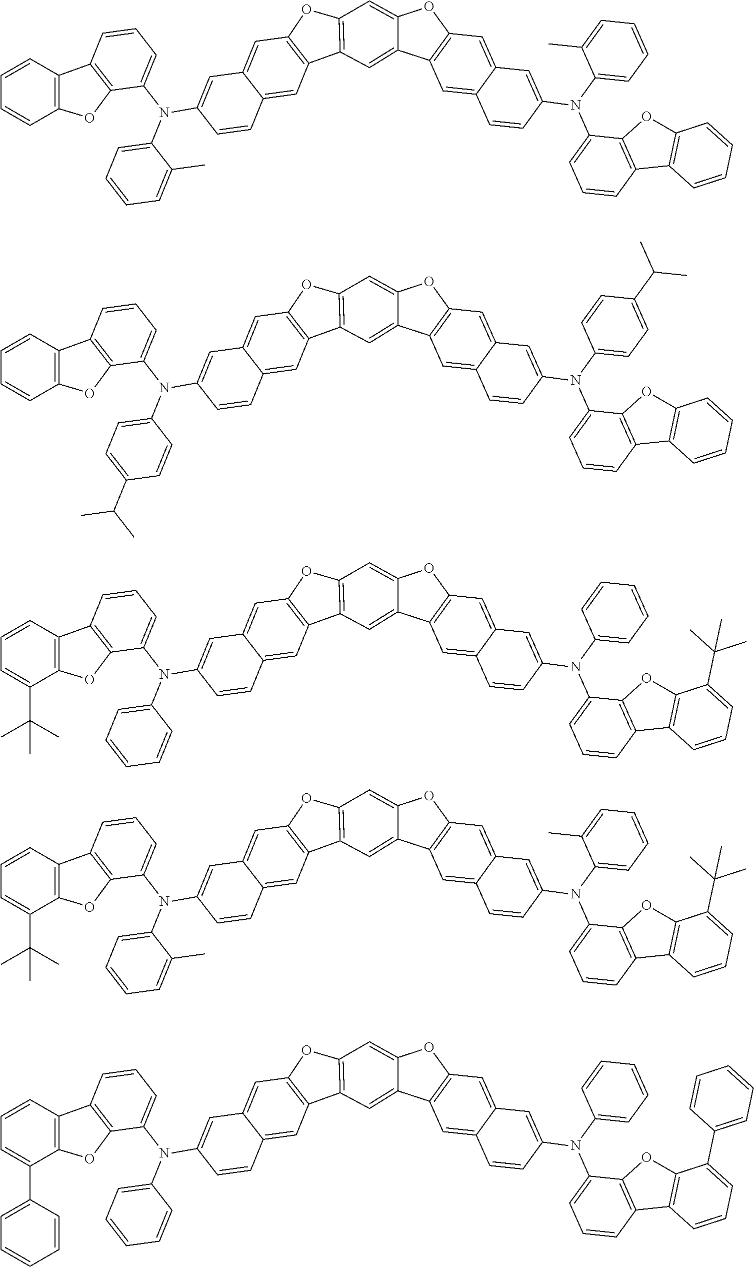

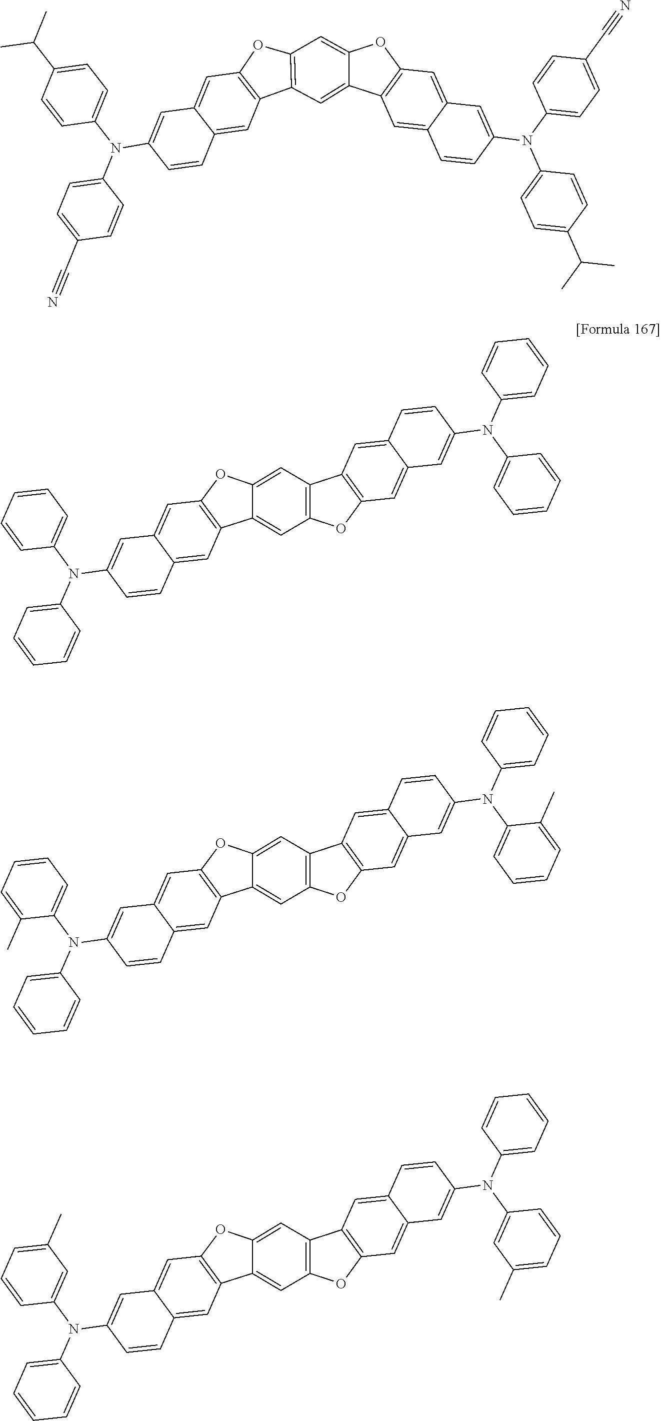 [SMILES: CC(C)c1ccc(N(c2ccc(C#N)cc2)c2ccc3cc4c(cc3c2)oc2cc3oc5cc6cc(N(c7ccc(C#N)cc7)c7ccc(C(C)C)cc7)ccc6cc5c3cc24)cc1 ; c1ccc(N(c2ccccc2)c2ccc3cc4c(cc3c2)oc2cc3c(cc24)oc2cc4cc(N(c5ccccc5)c5ccccc5)ccc4cc23)cc1 ; Cc1ccccc1N(c1ccccc1)c1ccc2cc3c(cc2c1)oc1cc2c(cc13)oc1cc3cc(N(c4ccccc4)c4ccccc4C)ccc3cc12 ; Cc1cccc(N(c2ccccc2)c2ccc3cc4c(cc3c2)oc2cc3c(cc24)oc2cc4cc(N(c5ccccc5)c5cccc(C)c5)ccc4cc23)c1]

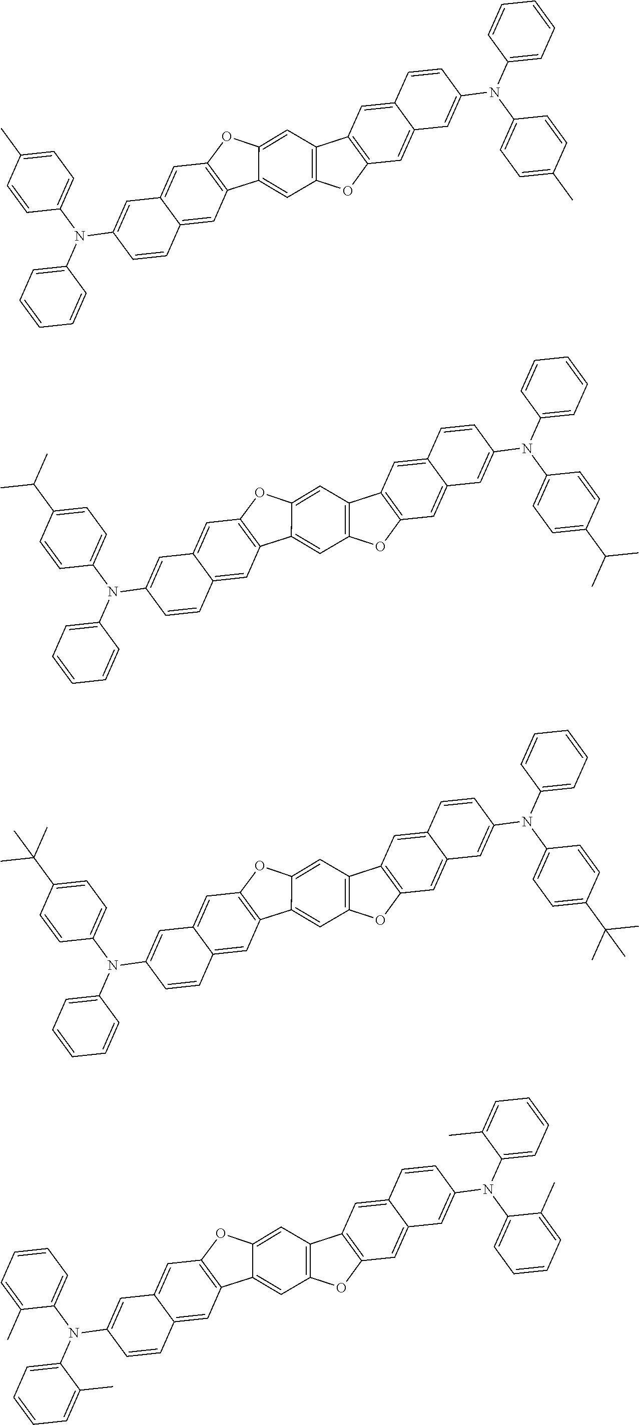

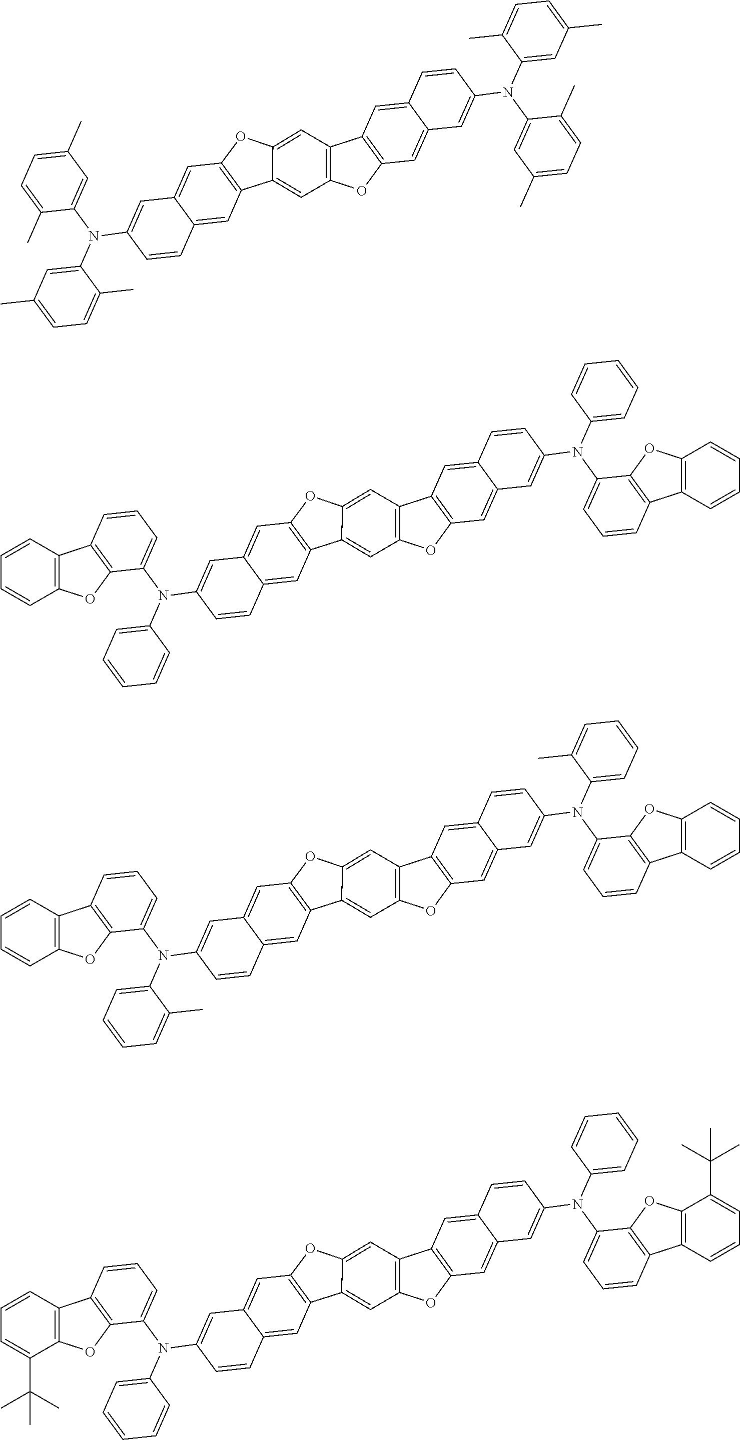

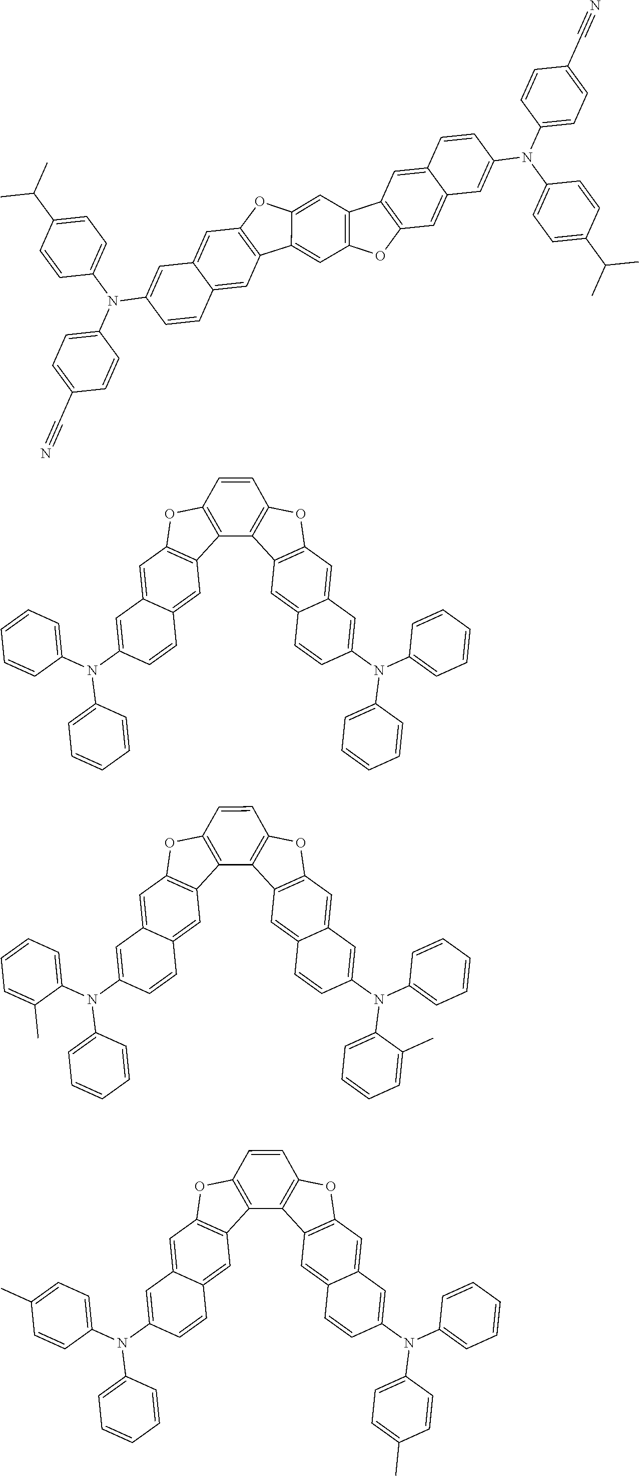

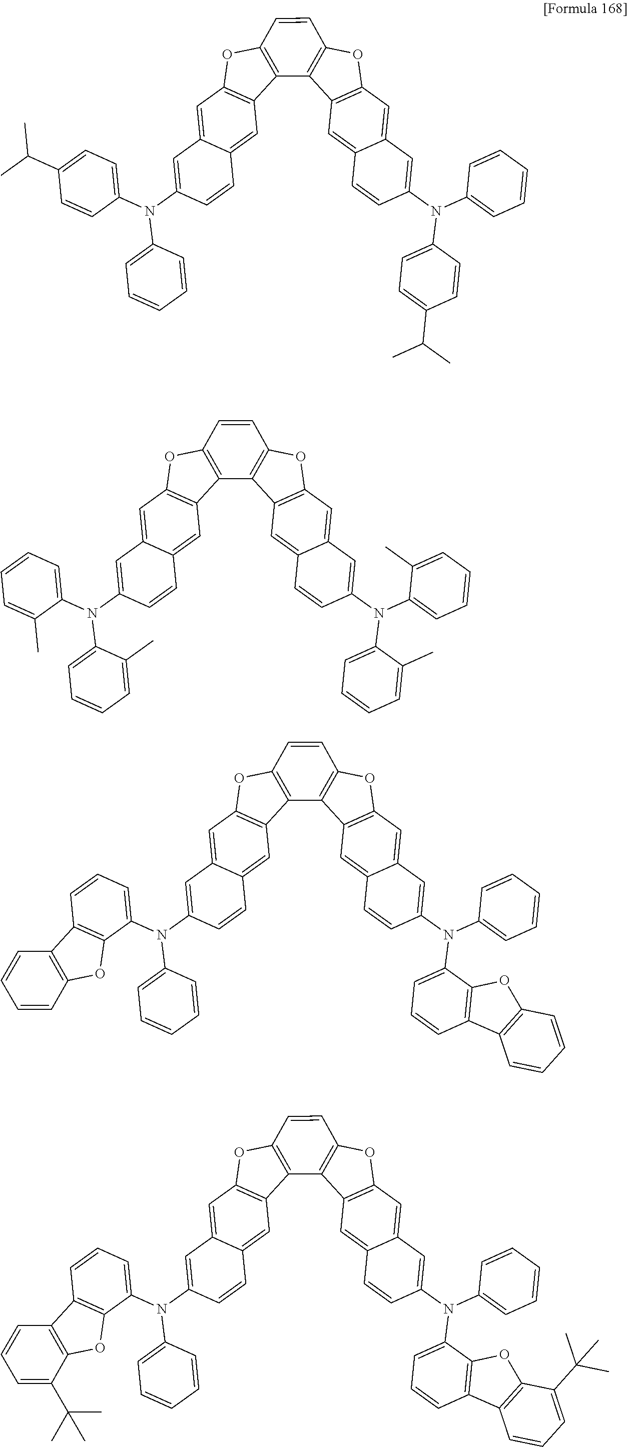 [SMILES: CC(C)c1ccc(N(c2ccccc2)c2ccc3cc4c(cc3c2)oc2ccc3oc5cc6cc(N(c7ccccc7)c7ccc(C(C)C)cc7)ccc6cc5c3c24)cc1 ; Cc1ccccc1N(c1ccc2cc3c(cc2c1)oc1ccc2oc4cc5cc(N(c6ccccc6C)c6ccccc6C)ccc5cc4c2c13)c1ccccc1C ; c1ccc(N(c2ccc3cc4c(cc3c2)oc2ccc3oc5cc6cc(N(c7ccccc7)c7cccc8c7oc7ccccc78)ccc6cc5c3c24)c2cccc3c2oc2ccccc23)cc1 ; CC(C)(C)c1cccc2c1oc1c(N(c3ccccc3)c3ccc4cc5c(cc4c3)oc3ccc4oc6cc7cc(N(c8ccccc8)c8cccc9c8oc8c(C(C)(C)C)cccc89)ccc7cc6c4c35)cccc12]

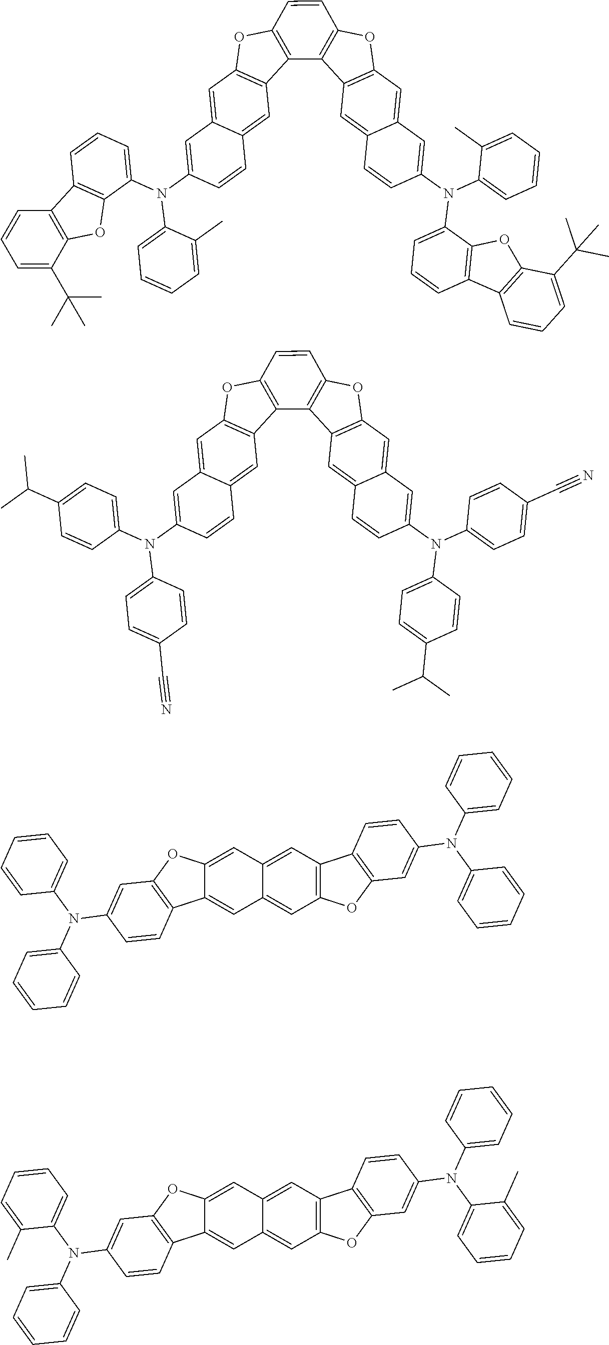

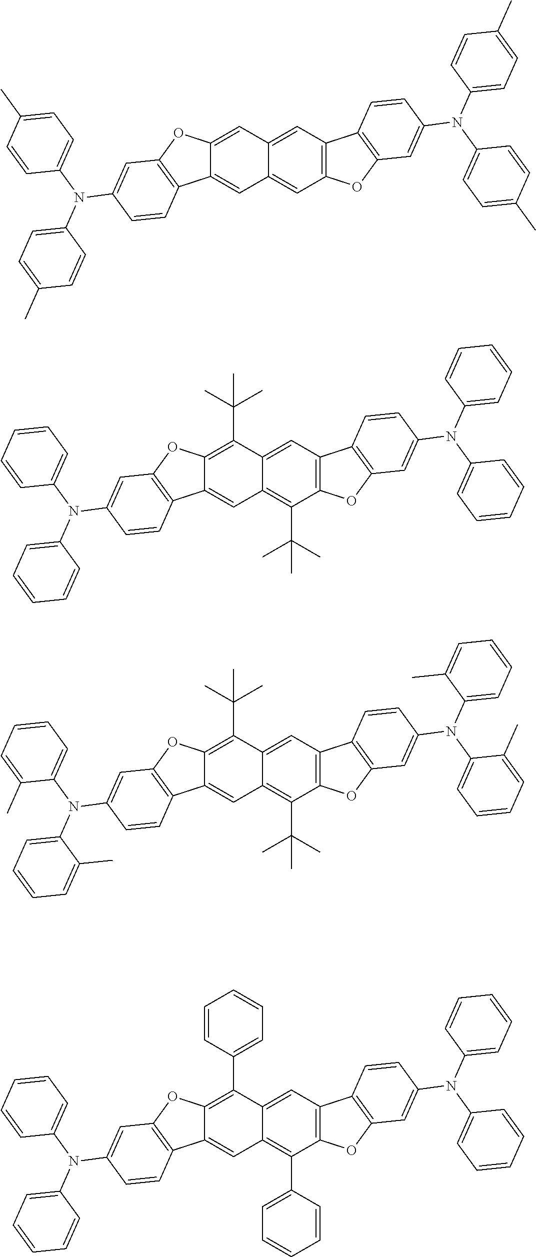

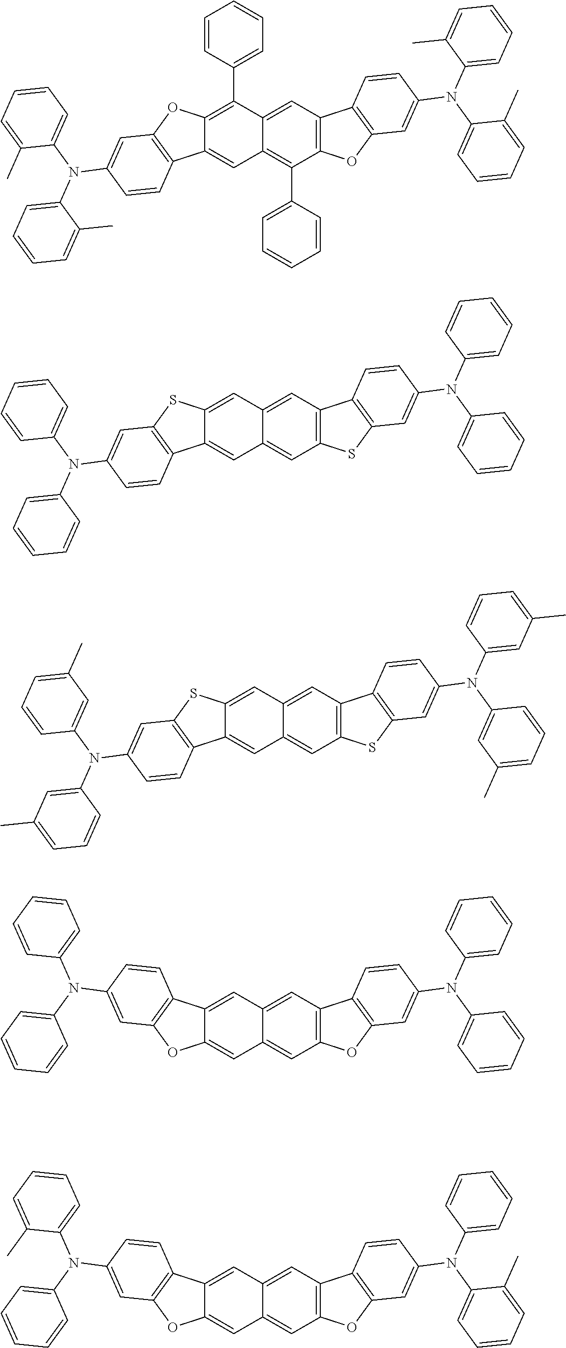

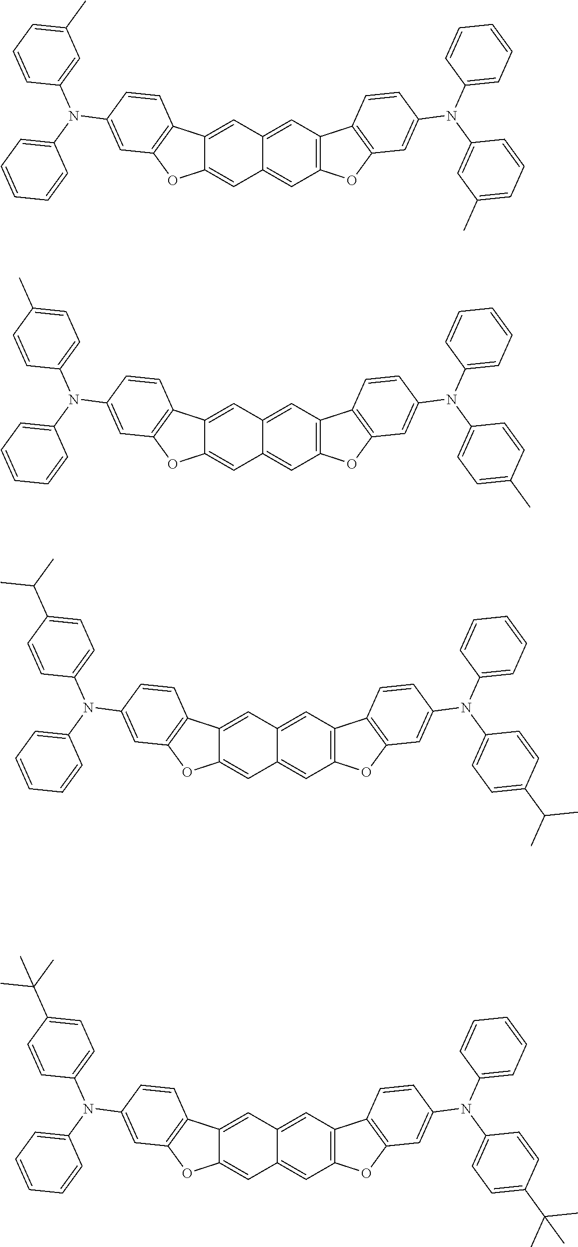

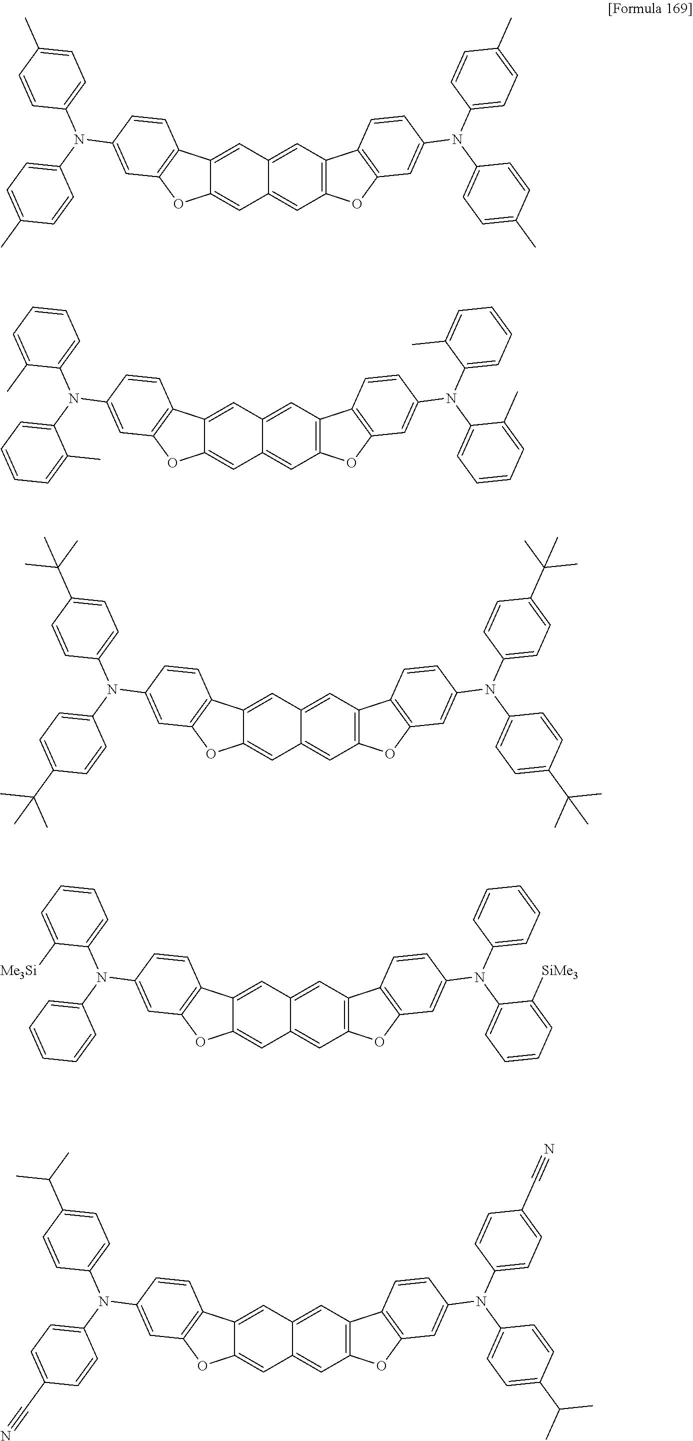

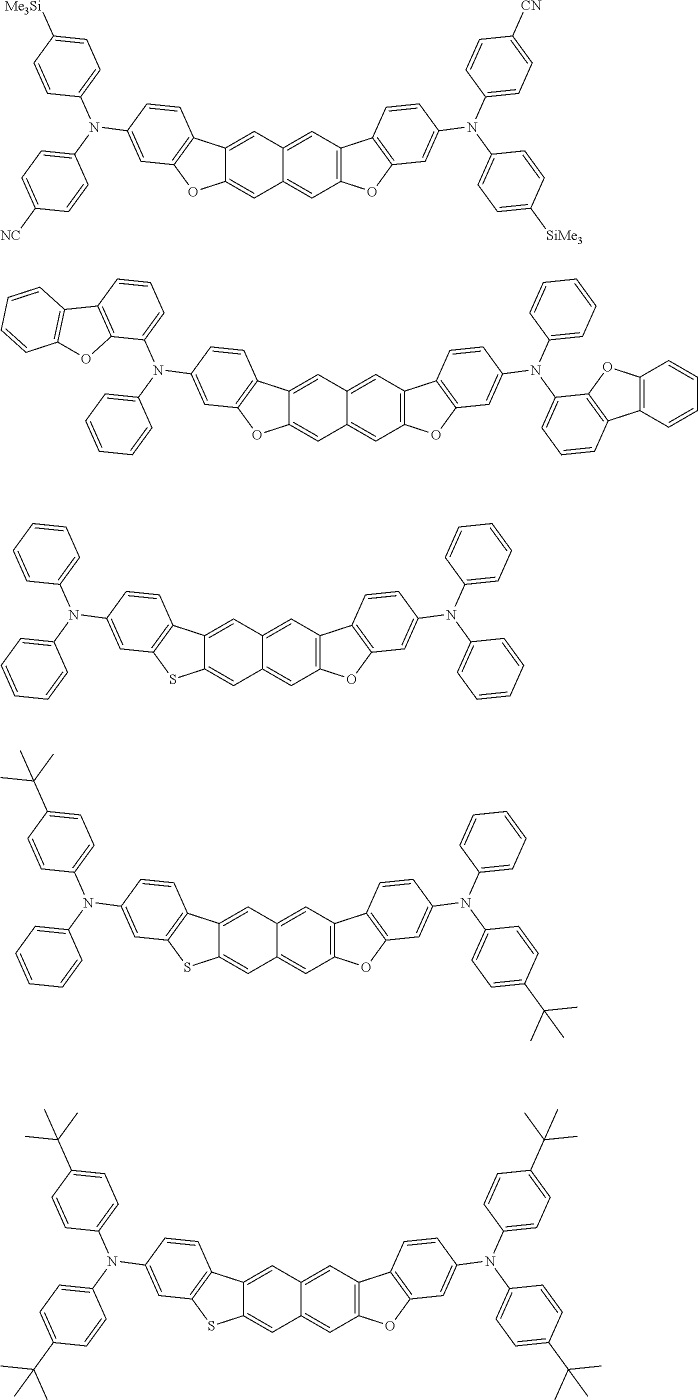

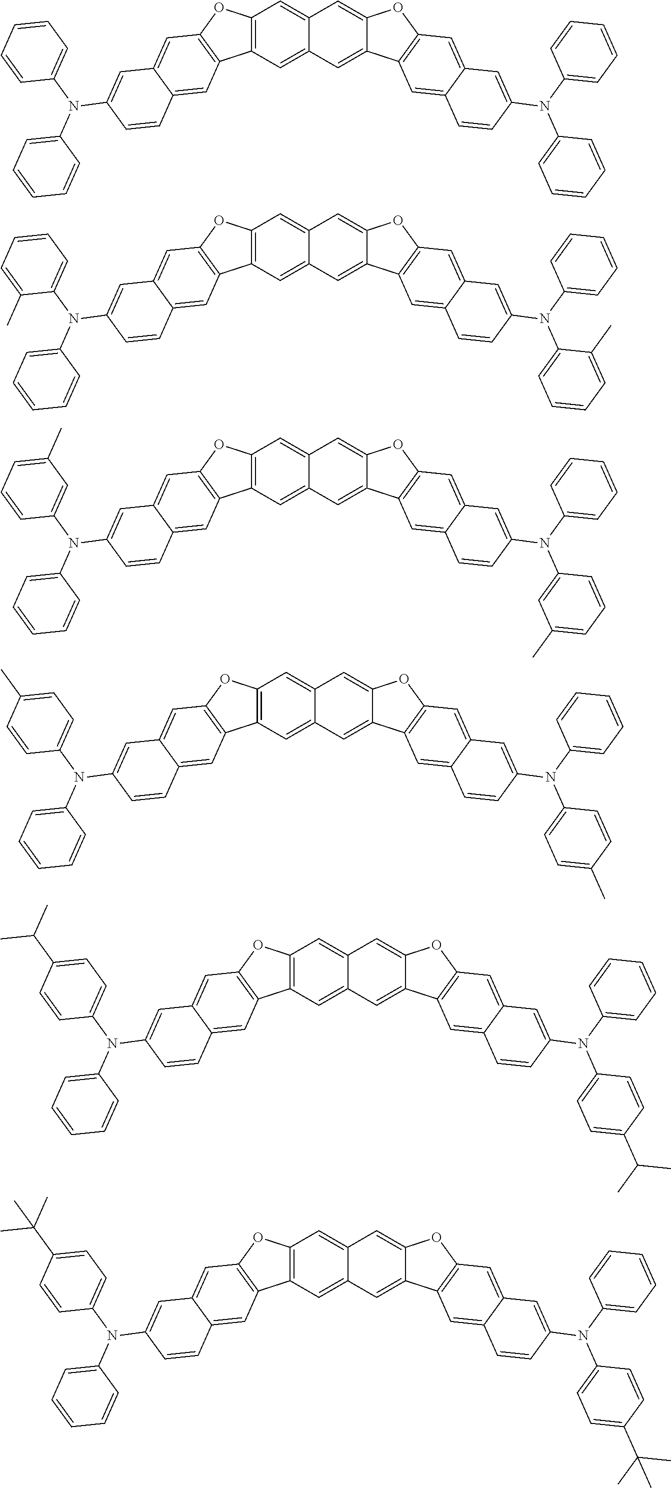

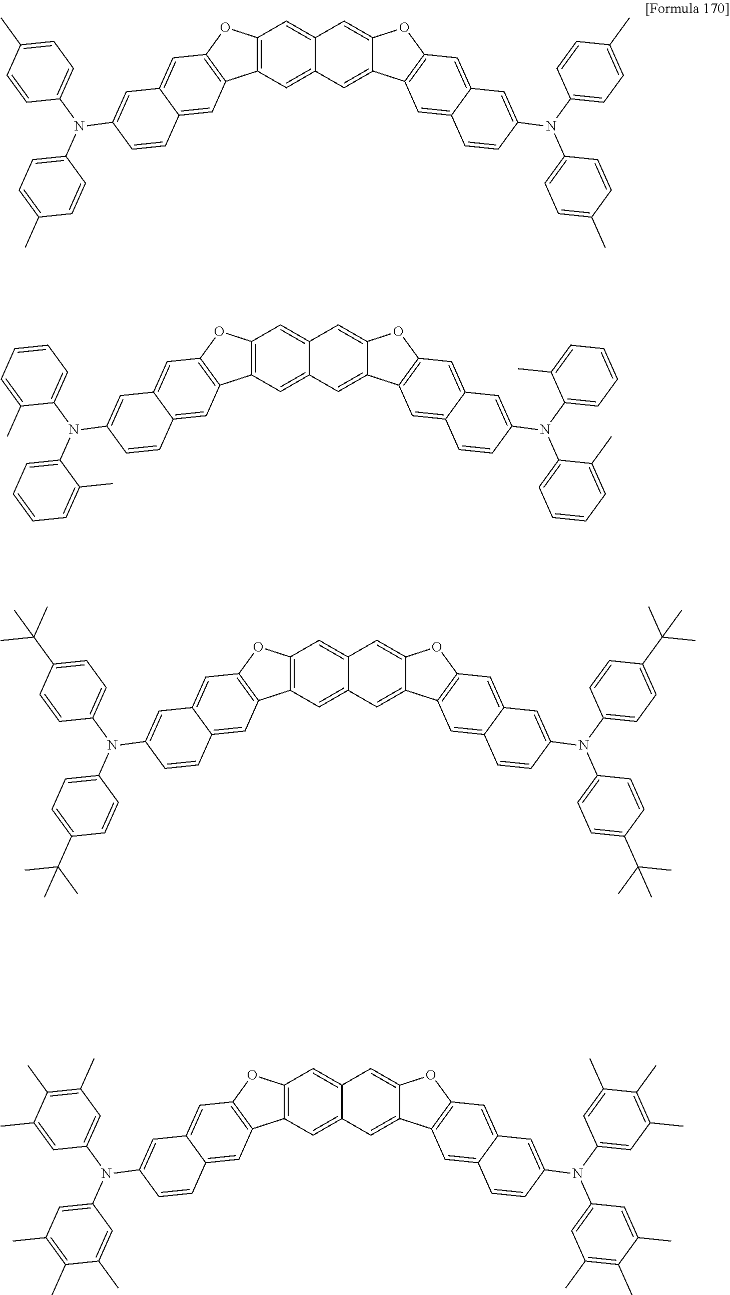

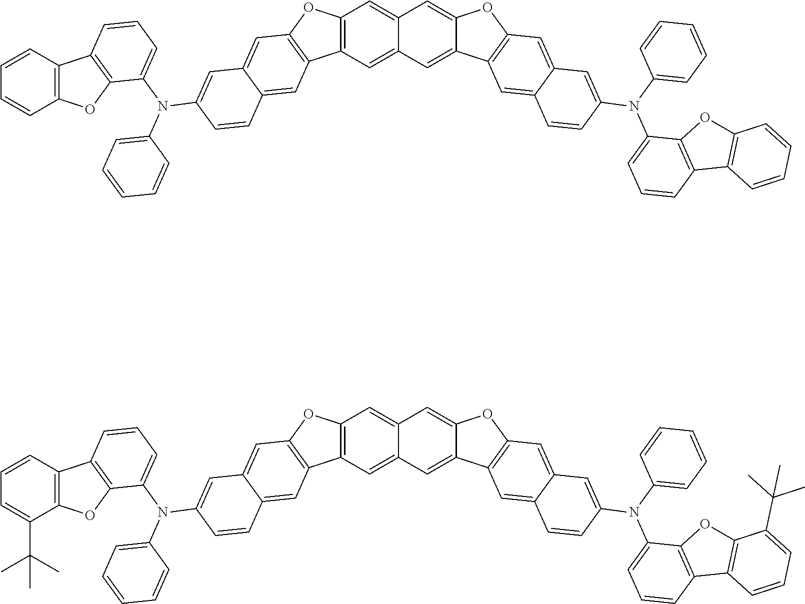 [SMILES: c1ccc(N(c2ccc3cc4c(cc3c2)oc2cc3cc5oc6cc7cc(N(c8ccccc8)c8cccc9c8oc8ccccc89)ccc7cc6c5cc3cc24)c2cccc3c2oc2ccccc23)cc1 ; CC(C)(C)c1cccc2c1oc1c(N(c3ccccc3)c3ccc4cc5c(cc4c3)oc3cc4cc6oc7cc8cc(N(c9ccccc9)c9cccc%10c9oc9c(C(C)(C)C)cccc9%10)ccc8cc7c6cc4cc35)cccc12]

### Compounds Represented by Formula (8)

The following describes the compounds represented by formula (8).

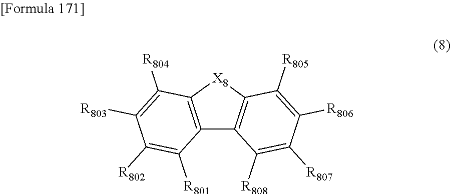

In formula (8),

at least one combination of R₈₀₁ and R₈₀₂, R₈₀₂ and R₈₀₃, or R₈₀₃ and R₈₀₄ are bonded together to form a divalent group represented by formula (82) below or are not bonded together; and

at least one combination of R₈₀₅ and R₈₀₆, R₈₀₆ and R₈₀₇, or R₈₀₇ and R₈₀₈ are bonded together to form a divalent group represented by formula (83) below or are not bonded together.

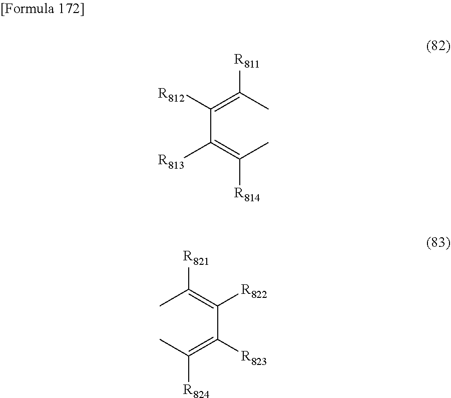

At least one of R₈₀₁ to R₈₀₄ not forming the divalent group represented by formula (82) or R₈₁₁ to R₈₁₄ is a monovalent group represented by formula (84) below;

at least one of R₈₀₅ to R₈₀₈ not forming the divalent group represented by formula (83) or R₈₂₁ to R₈₂₄ is a monovalent group represented by formula (84) below;

X₈ is CR₈₁R₈₂, an oxygen atom, a sulfur atom, or NR₈₀₈; the combination of R₈₁ and R₈₂ are: bonded together to form a substituted or unsubstituted monocyclic ring; bonded together to form a substituted or unsubstituted fused ring; or not bonded together; and

R₈₀₁ to R₈₀₈ not forming the divalent groups represented by the formulae (82) and (83) and not being the monovalent group represented by the formula (84), R₈₁₁ to R₈₁₄ and R₈₂₁ to R₈₂₄ not being the monovalent group represented by the formula (84), R₈₁ and R₈₂ not forming the substituted or unsubstituted monocyclic ring and not forming the substituted or unsubstituted fused ring, and R₈₀₈ each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

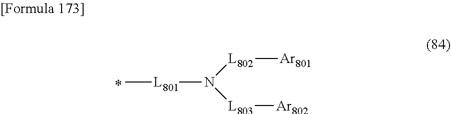

In formula (84),

Ar₈₁₁ and Ar₈₀₂ each independently represent: a substituted or unsubstituted aryl group having 6 to 50 ring carbon atoms; or a substituted or unsubstituted heterocyclic group having 5 to 50 ring atoms;

L₈₀₁ to L₈₀₃ each independently represent: a single bond; a substituted or unsubstituted arylene group having 6 to 30 ring carbon atoms; a substituted or unsubstituted divalent heterocyclic group having 5 to 30 ring atoms; or a divalent linking group formed by two to four groups bonded together, each of the two to four selected from the group consisting of a substituted or unsubstituted arylene group having 6 to 30 ring carbon atoms and a substituted or unsubstituted divalent heterocyclic group having 5 to 30 ring atoms; and

* in formula (84) indicates the position of bonding with the cyclic structure represented by formula (8) or the group represented by formula (82) or (83).

It is also preferred that at least one combination of R₈₀₁ and R₈₀₂, R₈₀₂ and R₈₀₃, or R₈₀₃ and R₈₀₄ be bonded together while R₈₀₅ and R₈₀₆, R₈₀₆ and R₈₀₇, and R₈₀₇ and R₈₀₈ are not bonded together.

It is also preferred that R₈₀₁ and R₈₀₂, R₈₀₂ and R₈₀₃, and R₈₀₃ and R₈₀₄ be not bonded together while at least one combination of R₈₀₅ and R₈₀₆, R₈₀₆ and R₈₀₇, or R₈₀₇ and R₈₀₈ are bonded together.

It is also preferred that at least one combination of R₈₀₁ and R₈₀₂, R₈₀₂ and R₈₀₃, or R₈₀₃ and R₈₀₄ be bonded together to form a divalent group represented by formula (82) while at least one combination of R₈₀₅ and R₈₀₆, R₈₀₆ and R₈₀₇, or R₈₀₇ and R₈₀₈ are bonded together to form a divalent group represented by formula (83).

In formula (8), the position at which the divalent group represented by formula (82) or that represented by formula (83) is formed is not critical; the group can be formed at any possible position from R₈₀₁ to R₈₀₈.

In an exemplary embodiment, the compounds represented by formula (8) are represented by any of formulae (81A-1) to (81A-3) below.

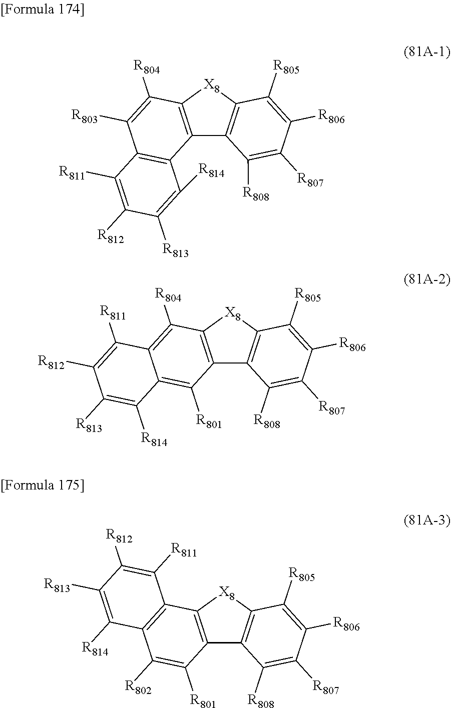

In formulae (81A-1) to (81A-3),

X₈ represents the same as X₈ in formula (8);

at least one of R₈₀₃, R₈₀₄, or R₈₁₁ to R₈₁₄ in formula (81A-1) is a monovalent group represented by formula (84);

at least one of R₈₀₁, R₈₀₄, or R₈₁₁ to R₈₁₄ in formula (81A-2) is a monovalent group represented by formula (84);

at least one of R₈₀₁, R₈₀₂, or R₈₁₁ to R₈₁₄ in formula (81A-3) is a monovalent group represented by formula (84);

at least one of R₈₀₅ to R₈₀₈ in formulae (81A-1) to (81A-3) is a monovalent group represented by formula (84); and

R₈₀₁ to R₈₀₈ and R₈₁₁ to R₈₁₄ not being the monovalent group represented by formula (84) each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

In an exemplary embodiment, the compounds represented by formula (8) are represented by any of formulae (81-1) to (81-6) below.

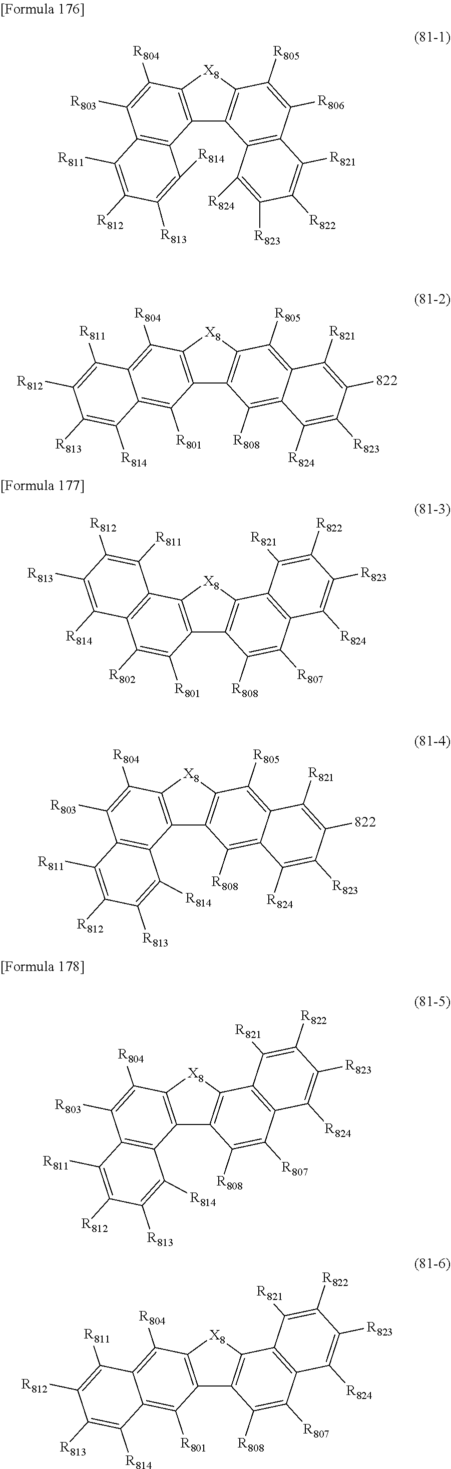

In formulae (81-1) to (81-6),

X₈ represents the same as X₈ in formula (8);

at least two of R₈₁ to R₈₂₄ are monovalent groups represented by formula (84); and

R₈₀₁ to R₈₂₄ not being the monovalent group represented by formula (84) each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

In an exemplary embodiment, the compounds represented by formula (8) are represented by any of formulae (81-7) to (81-18) below.

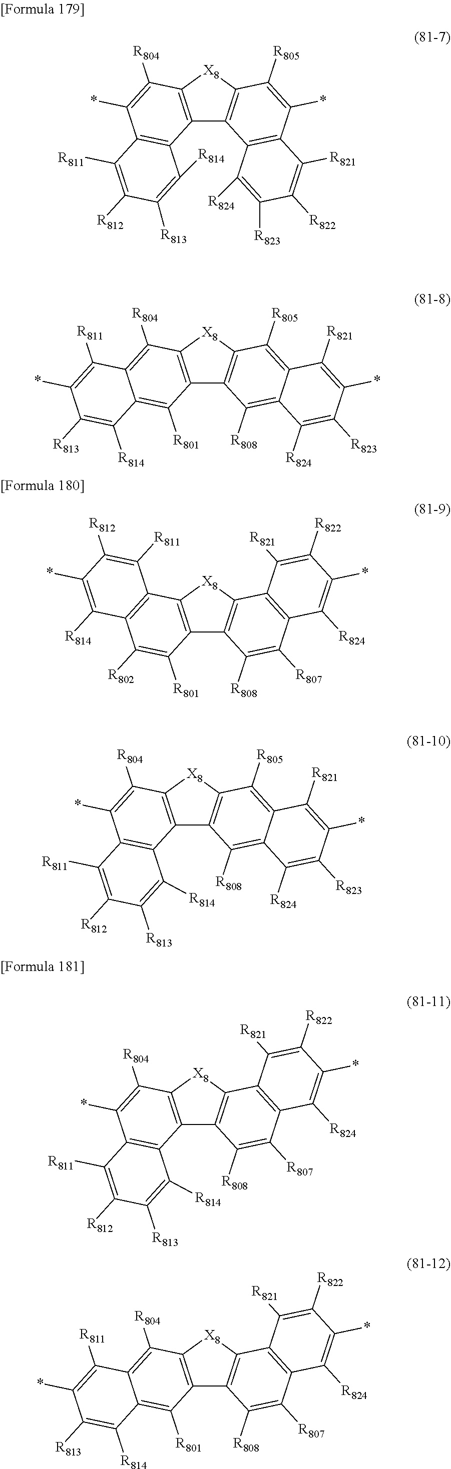

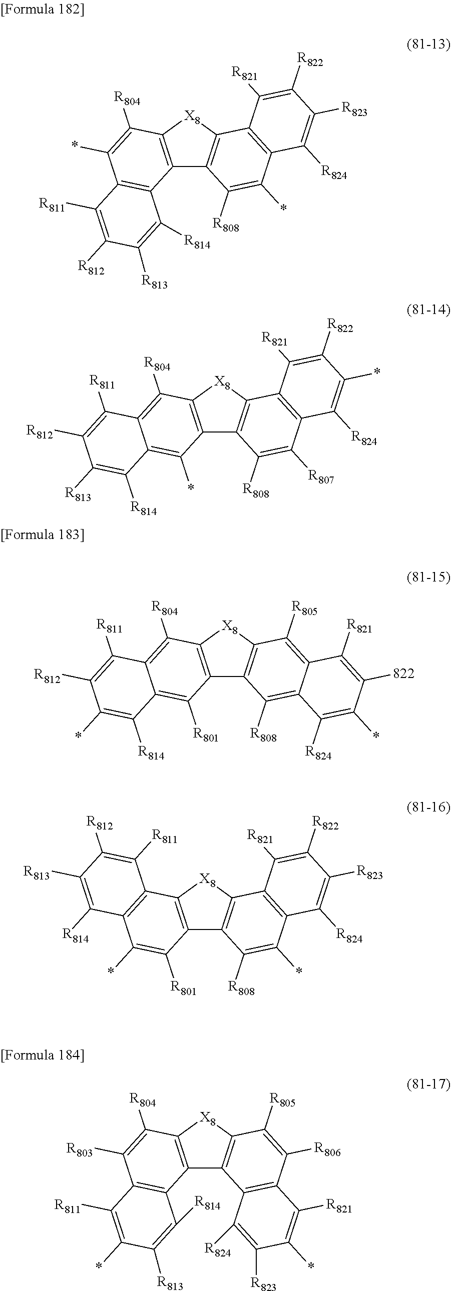

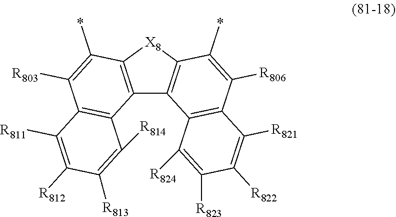

In formulae (81-7) to (81-18),

X₈ represents the same as X₈ in formula (8);

the *s are single bonds bonded to the monovalent groups represented by formula (84); and

R₈₀₁ to R₈₂₄ each independently represent the same as when R₈₀₁ to R₈₂₄ in formulae (81-1) to (81-6) are not monovalent groups represented by formula (84).

Preferably, R₈₀₁ to R₈₀₈ not forming the divalent group represented by formula (82) or (83) and not being the monovalent group represented by formula (84) and R₈₁₁ to R₈₁₄ and R₈₂₁ to R₈₂₄ not being the monovalent group represented by formula (84) each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a substituted or unsubstituted aryl group having 6 to 50 ring carbon atoms; or substituted or unsubstituted heterocyclic group having 5 to 50 ring atoms.

Preferably, the monovalent groups represented by formula (84) are represented by formula (85) or (86) below.

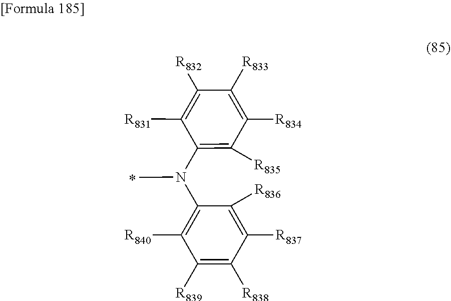

In formula (85),

R₈₃₁ to R₈₄₀ each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms; and

* in formula (85) represents the same as * in formula (84).

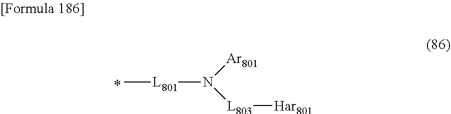

In formula (86),

Ar₈₀₁, L₈₀₁, and L₈₀₃ represent the same as Ar₈₀₁, L₈₀₁, and L₈₀₃ in formula (84); and HAr₈₀₁ is a structure represented by formula (87) below.

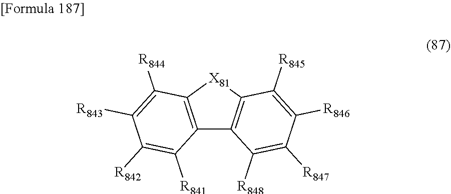

In formula (87),

X₈₁ is an oxygen or sulfur atom;

one of R₈₄₁ to R₈₄₈ is a single bond bonded to L₈₀₃; and

R₈₄₁ to R₈₄₈ not being the single bond each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

Specific examples of compounds represented by formula (8) include compounds mentioned in WO 2014/104144. Besides them, the following, for instance, are also specific examples of such compounds.

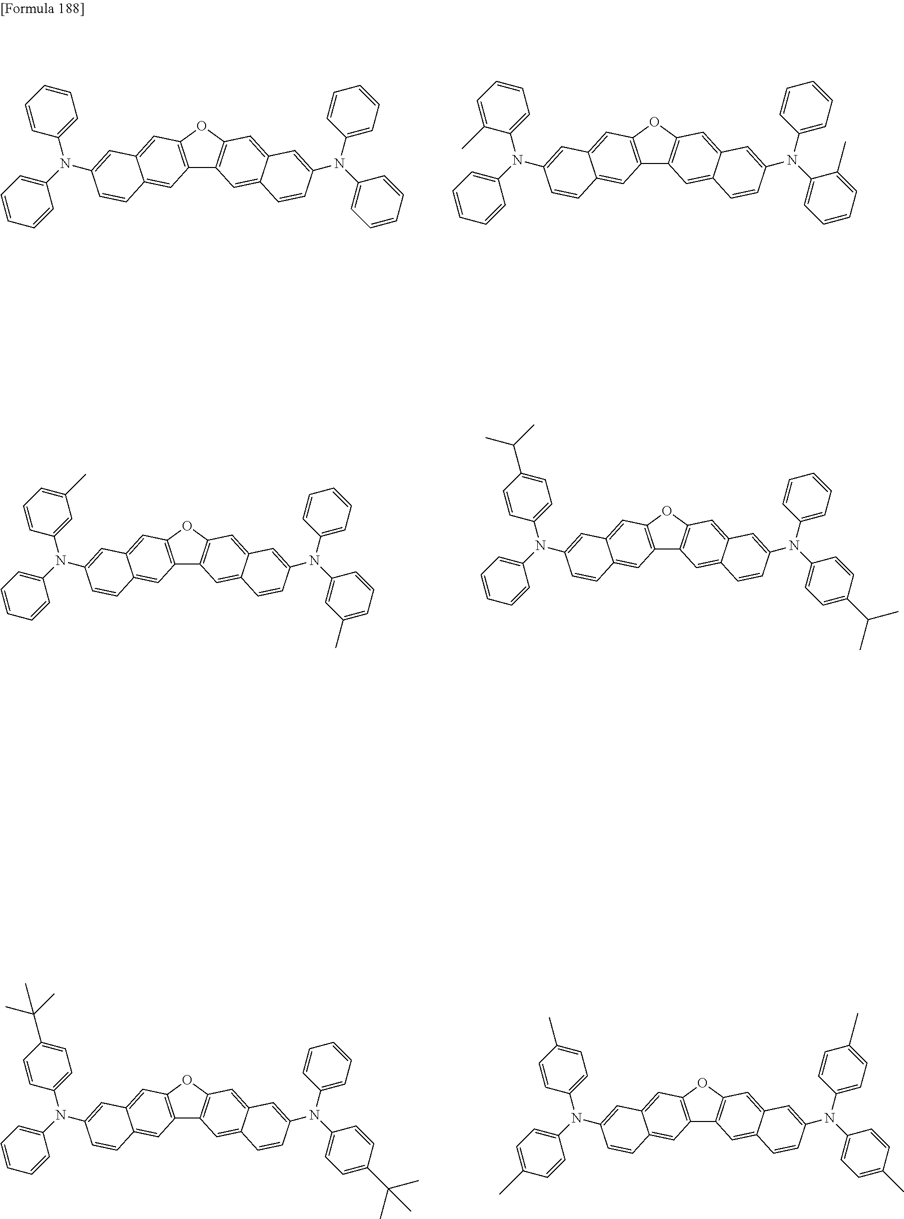

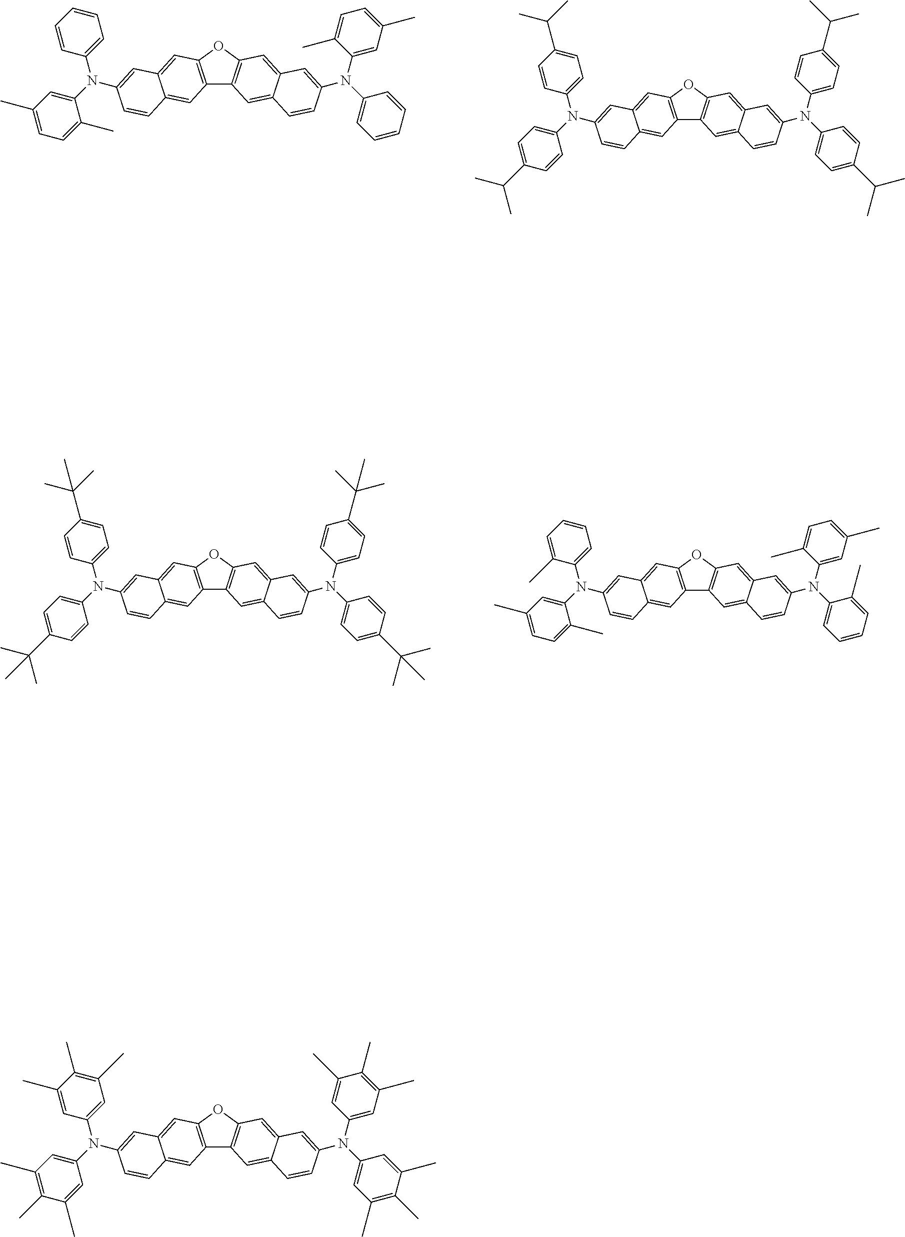

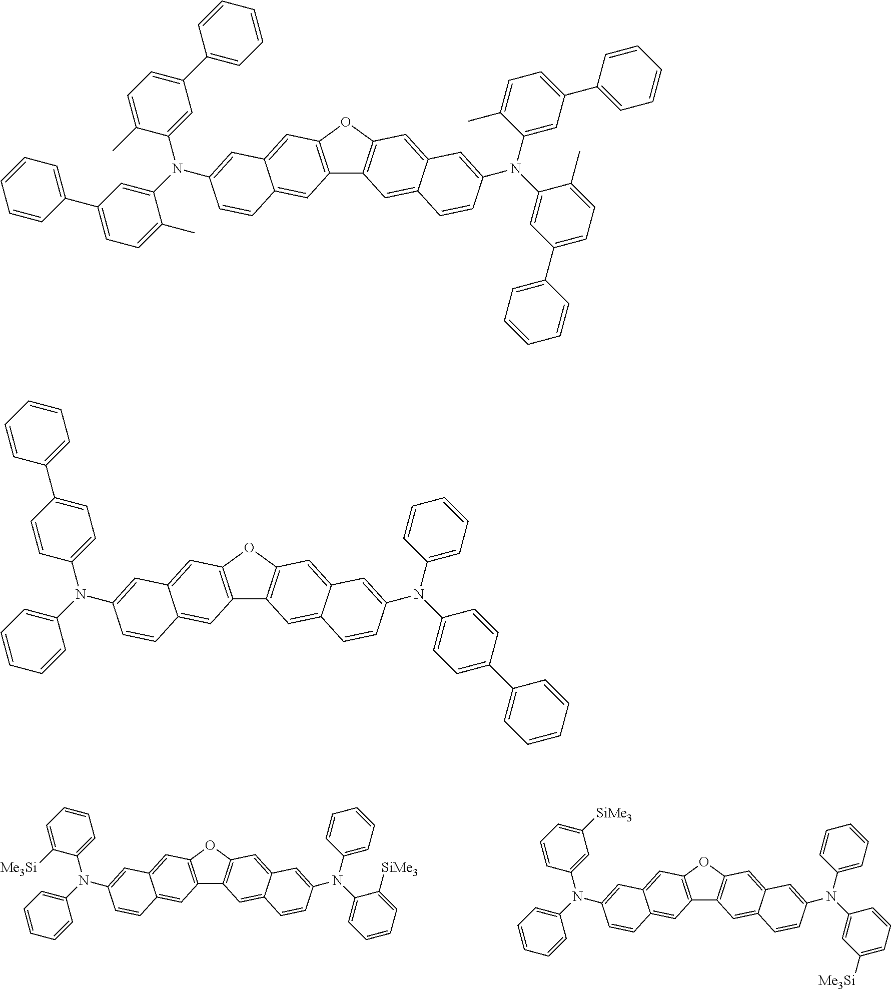 [SMILES: Cc1ccc(-c2ccccc2)cc1N(c1ccc2cc3c(cc2c1)oc1cc2cc(N(c4cc(-c5ccccc5)ccc4C)c4cc(-c5ccccc5)ccc4C)ccc2cc13)c1cc(-c2ccccc2)ccc1C ; c1ccc(-c2ccc(N(c3ccccc3)c3ccc4cc5c(cc4c3)oc3cc4cc(N(c6ccccc6)c6ccc(-c7ccccc7)cc6)ccc4cc35)cc2)cc1 ; C[Si](C)(C)c1ccccc1N(c1ccccc1)c1ccc2cc3c(cc2c1)oc1cc2cc(N(c4ccccc4)c4ccccc4[Si](C)(C)C)ccc2cc13 ; C[Si](C)(C)c1cccc(N(c2ccccc2)c2ccc3cc4c(cc3c2)oc2cc3cc(N(c5ccccc5)c5cccc([Si](C)(C)C)c5)ccc3cc24)c1]

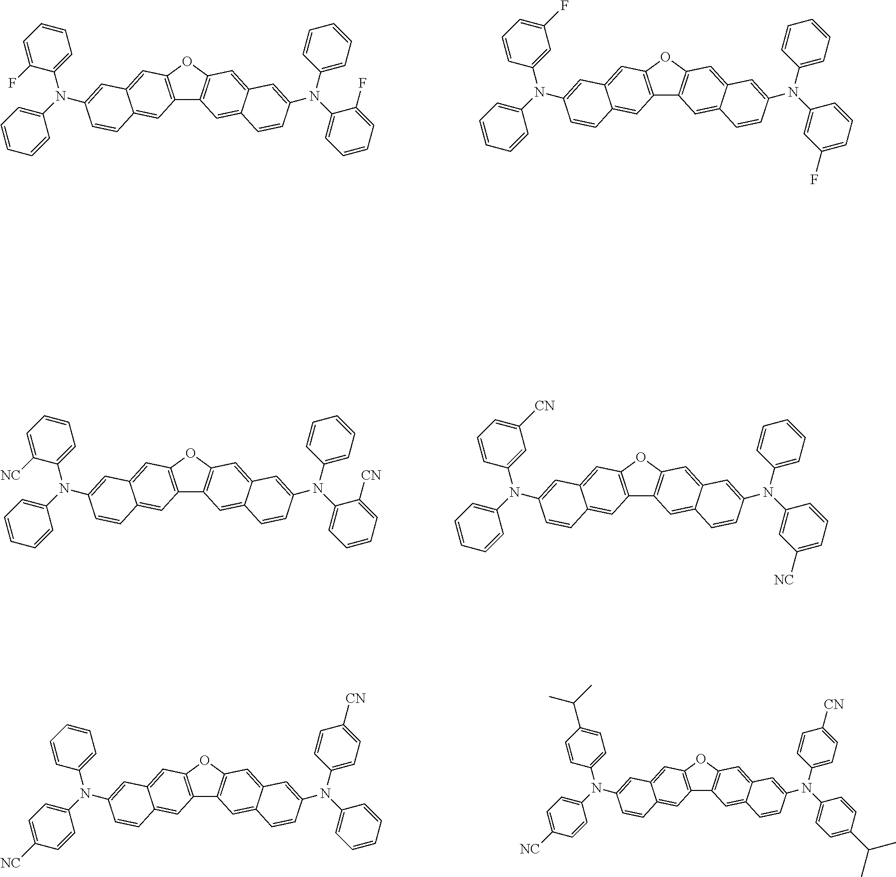

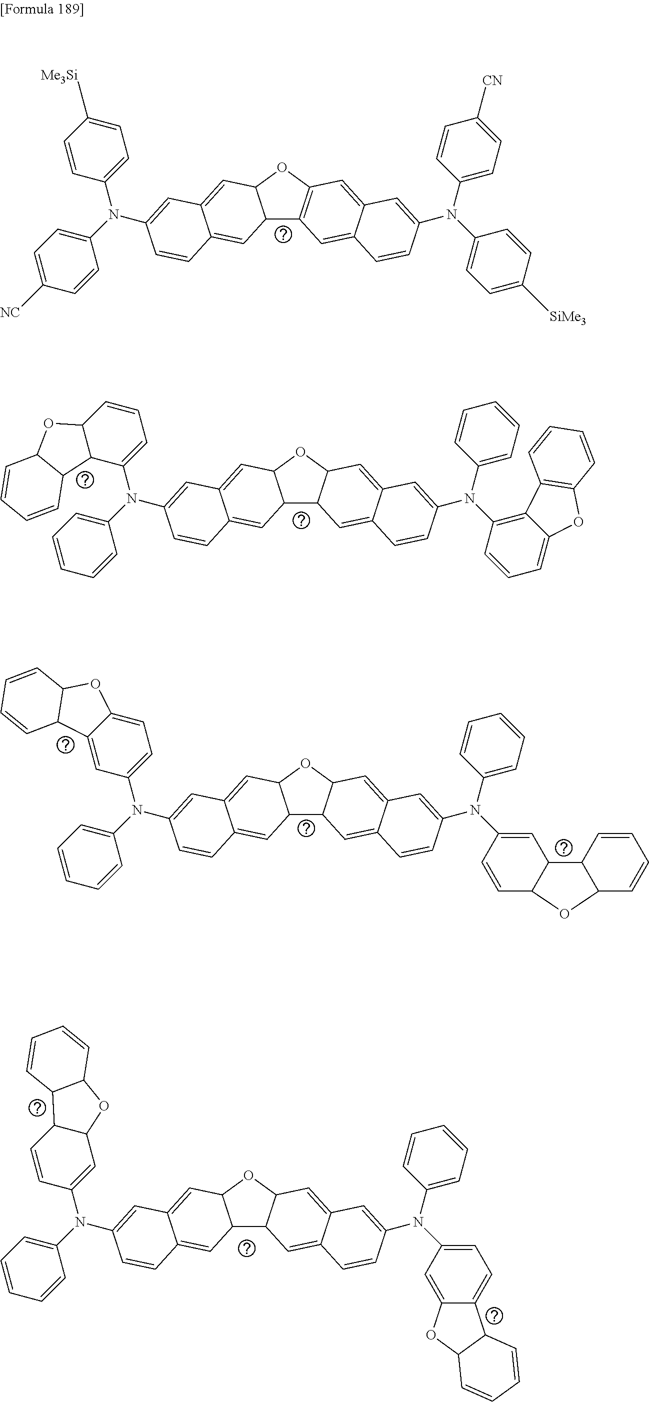 [SMILES: C[Si](C)(C)c1ccc(N(c2ccc(C#N)cc2)c2ccc3c(c2)=CC2Oc4cc5cc(N(c6ccc(C#N)cc6)c6ccc([Si](C)(C)C)cc6)ccc5cc4C2C=3)cc1 ; C1=CC2OC3C=CC=C(N(c4ccccc4)c4ccc5c(c4)=CC4OC6C=c7cc(N(c8ccccc8)c8cccc9oc%10ccccc%10c89)ccc7=CC6C4C=5)C3C2C=C1 ; C1=CC2Oc3ccc(N(c4ccccc4)c4ccc5c(c4)=CC4OC6C=c7cc(N(C8=CC9C(C=C8)OC8C=CC=CC89)c8ccccc8)ccc7=CC6C4C=5)cc3C2C=C1 ; C1=CC2Oc3cc(N(c4ccccc4)c4ccc5c(c4)=CC4OC6C=c7cc(N(C8=CC9OC%10C=CC=CC%10C9C=C8)c8ccccc8)ccc7=CC6C4C=5)ccc3C2C=C1]

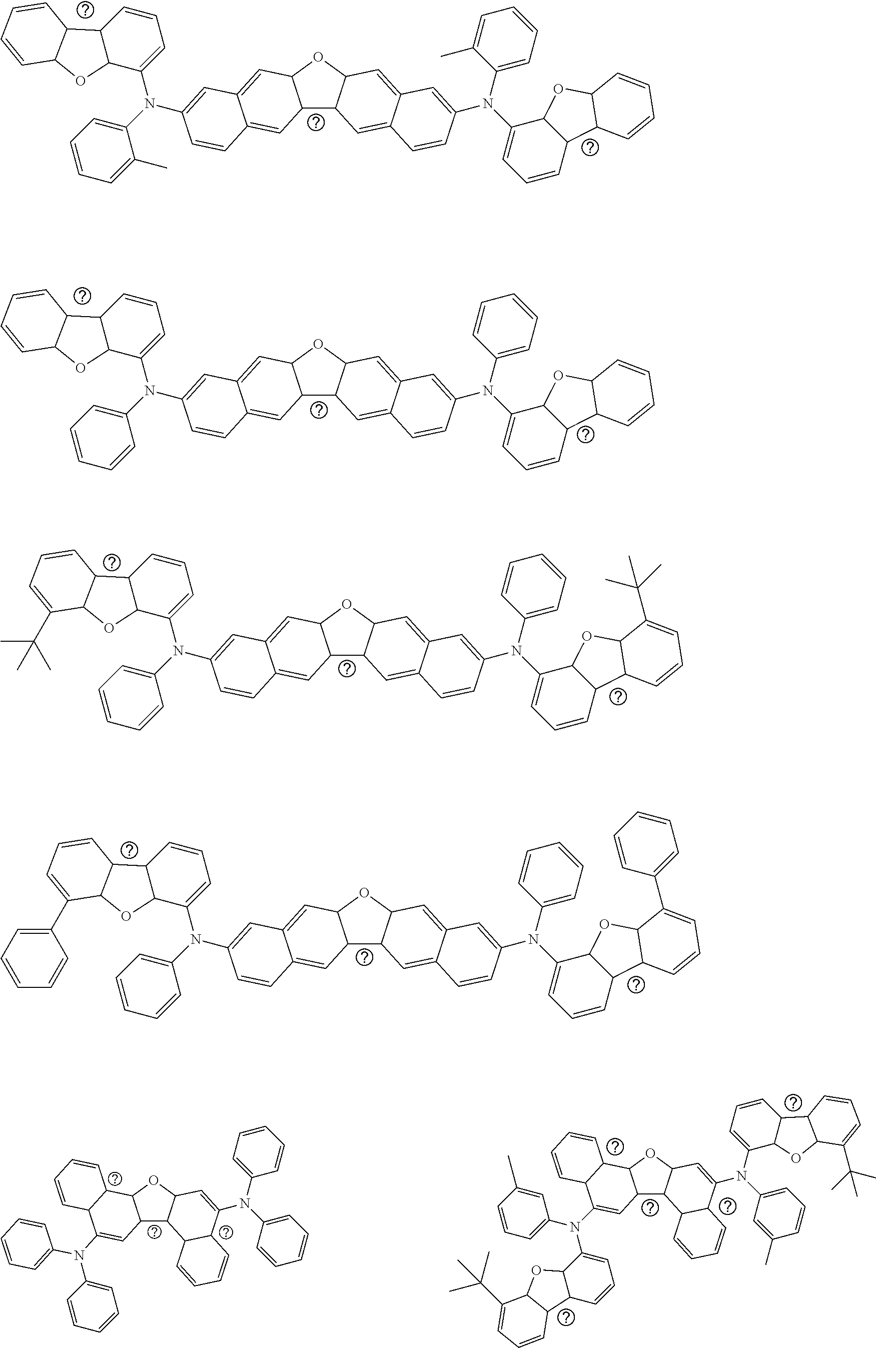

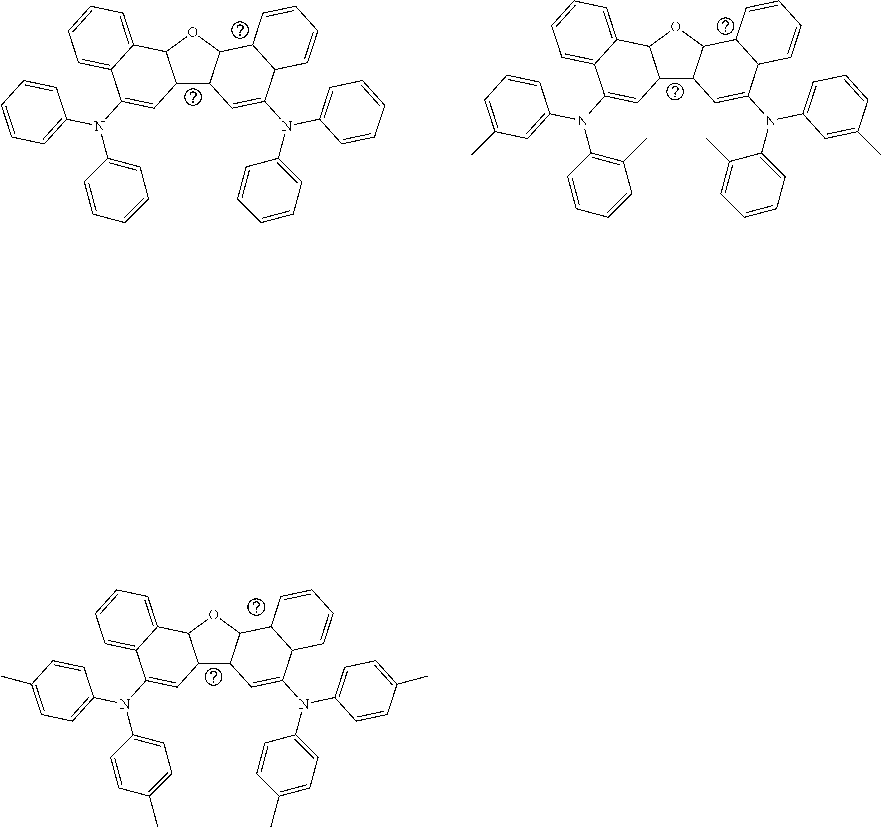

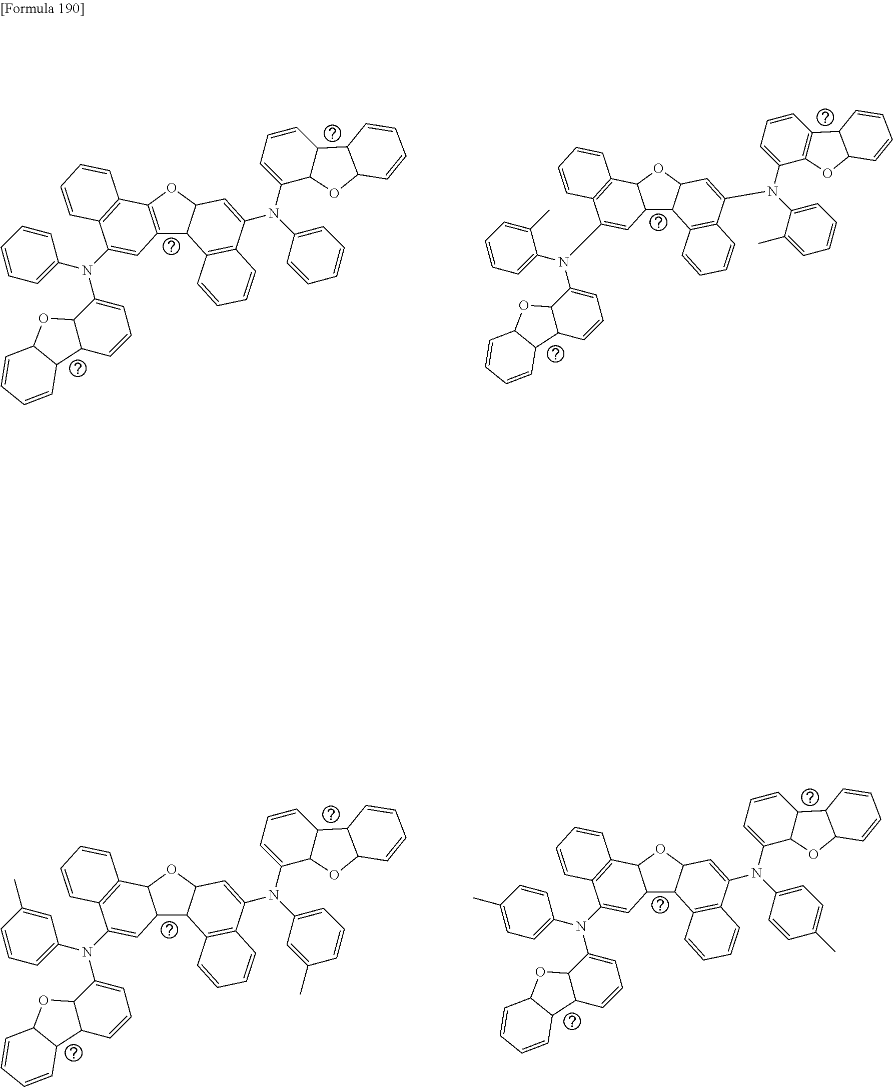 [SMILES: C1=CC2OC3C(N(C4=CC5Oc6c(cc(N(C7=CC=CC8C7OC7C=CC=CC78)c7ccccc7)c7ccccc67)C5c5ccccc54)c4ccccc4)=CC=CC3C2C=C1 ; Cc1ccccc1N(C1=CC2C(OC3C=C(N(c4ccccc4C)c4cccc5c4OC4C=CC=CC54)c4ccccc4C32)c2ccccc21)C1=CC=CC2C1OC1C=CC=CC12 ; Cc1cccc(N(C2=CC3C(OC4C=C(N(C5=CC=CC6C5OC5C=CC=CC56)c5cccc(C)c5)c5ccccc5C43)c3ccccc32)C2=CC=CC3C2OC2C=CC=CC23)c1 ; Cc1ccc(N(C2=CC3C(OC4C=C(N(C5=CC=CC6C5OC5C=CC=CC56)c5ccc(C)cc5)c5ccccc5C43)c3ccccc32)C2=CC=CC3C2OC2C=CC=CC23)cc1]

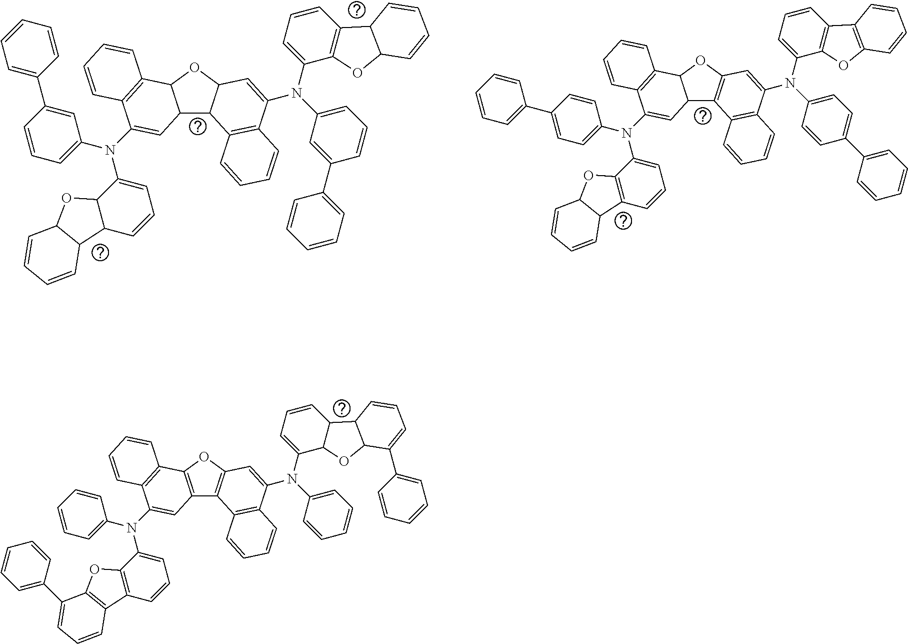 [SMILES: C1=CC2Oc3c(cccc3N(C3=CC4OC5c6ccccc6C(N(C6=CC=CC7C6OC6C=CC=CC67)c6cccc(-c7ccccc7)c6)=CC5C4c4ccccc43)c3cccc(-c4ccccc4)c3)C2C=C1 ; C1=CC2Oc3c(cccc3N(C3=CC4c5c(cc(N(c6ccc(-c7ccccc7)cc6)c6cccc7c6oc6ccccc67)c6ccccc56)OC4c4ccccc43)c3ccc(-c4ccccc4)cc3)C2C=C1 ; C1=CC2C(OC3C(N(c4ccccc4)c4cc5oc6c7ccccc7c(N(c7ccccc7)c7cccc8c7oc7c(-c9ccccc9)cccc78)cc6c5c5ccccc45)=CC=CC32)C(c2ccccc2)=C1]

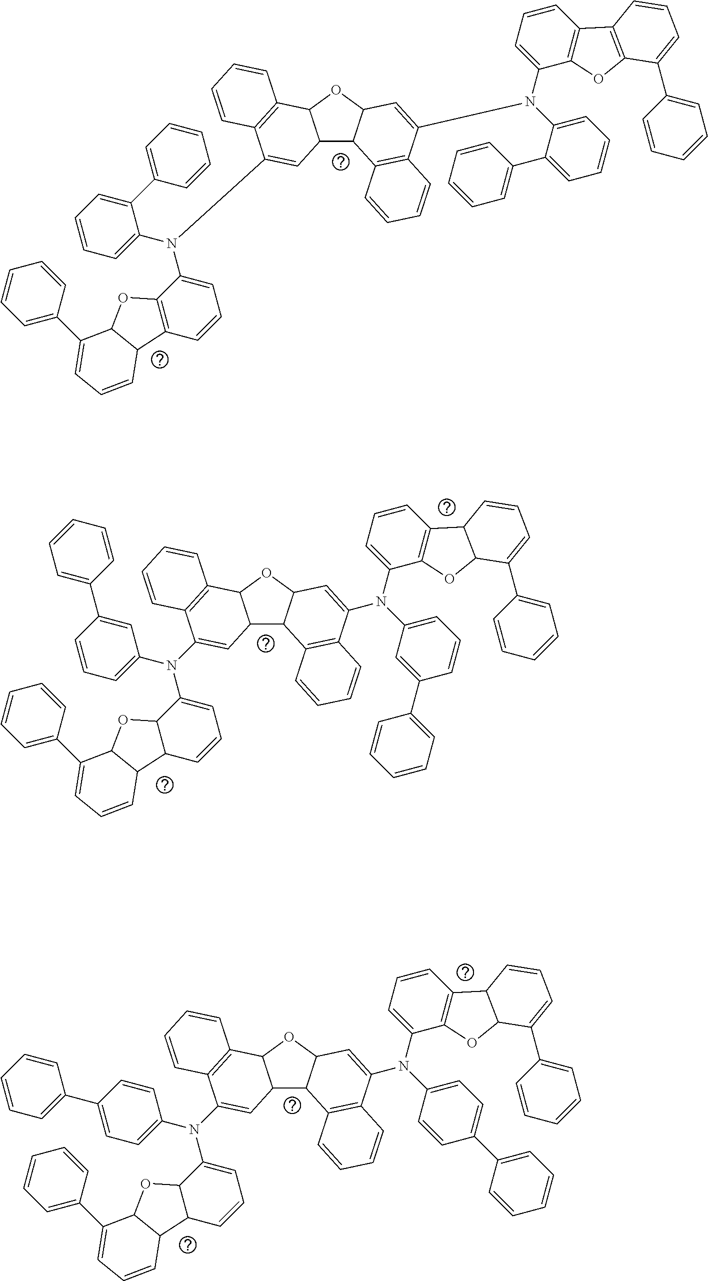 [SMILES: C1=CC2c3cccc(N(C4=CC5C(OC6C=C(N(c7ccccc7-c7ccccc7)c7cccc8c7oc7c(-c9ccccc9)cccc78)c7ccccc7C65)c5ccccc54)c4ccccc4-c4ccccc4)c3OC2C(c2ccccc2)=C1 ; C1=CC2c3cccc(N(C4=CC5OC6c7ccccc7C(N(C7=CC=CC8C7OC7C(c9ccccc9)=CC=CC78)c7cccc(-c8ccccc8)c7)=CC6C5c5ccccc54)c4cccc(-c5ccccc5)c4)c3OC2C(c2ccccc2)=C1 ; C1=CC2c3cccc(N(C4=CC5OC6c7ccccc7C(N(C7=CC=CC8C7OC7C(c9ccccc9)=CC=CC78)c7ccc(-c8ccccc8)cc7)=CC6C5c5ccccc54)c4ccc(-c5ccccc5)cc4)c3OC2C(c2ccccc2)=C1]

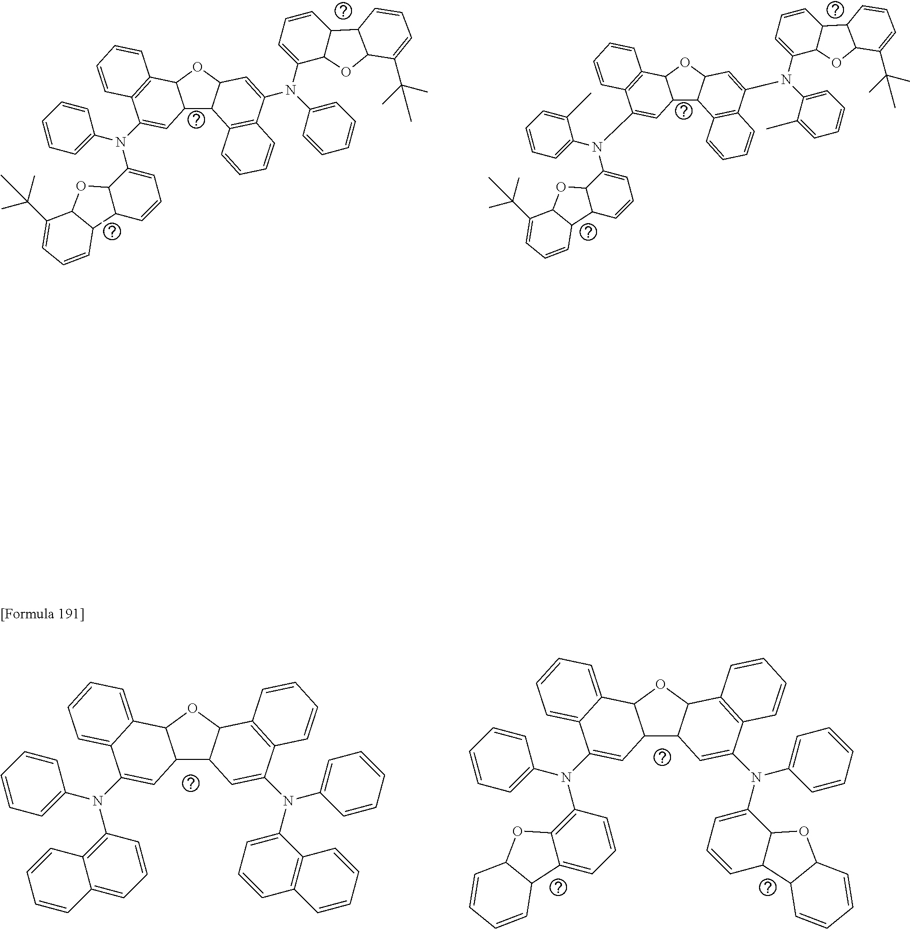 [SMILES: CC(C)(C)C1=CC=CC2C1OC1C(N(C3=CC4C(OC5C=C(N(C6=CC=CC7C6OC6C(C(C)(C)C)=CC=CC67)c6ccccc6)c6ccccc6C54)c4ccccc43)c3ccccc3)=CC=CC12 ; Cc1ccccc1N(C1=CC2C(OC3C=C(N(C4=CC=CC5C4OC4C(C(C)(C)C)=CC=CC45)c4ccccc4C)c4ccccc4C32)c2ccccc21)C1=CC=CC2C1OC1C(C(C)(C)C)=CC=CC12 ; C1=C(N(c2ccccc2)c2cccc3ccccc23)c2ccccc2C2OC3c4ccccc4C(N(c4ccccc4)c4cccc5ccccc45)=CC3C12 ; C1=CC2Oc3c(cccc3N(C3=CC4C(OC5c6ccccc6C(N(C6=CC=CC7C6OC6C=CC=CC67)c6ccccc6)=CC54)c4ccccc43)c3ccccc3)C2C=C1]

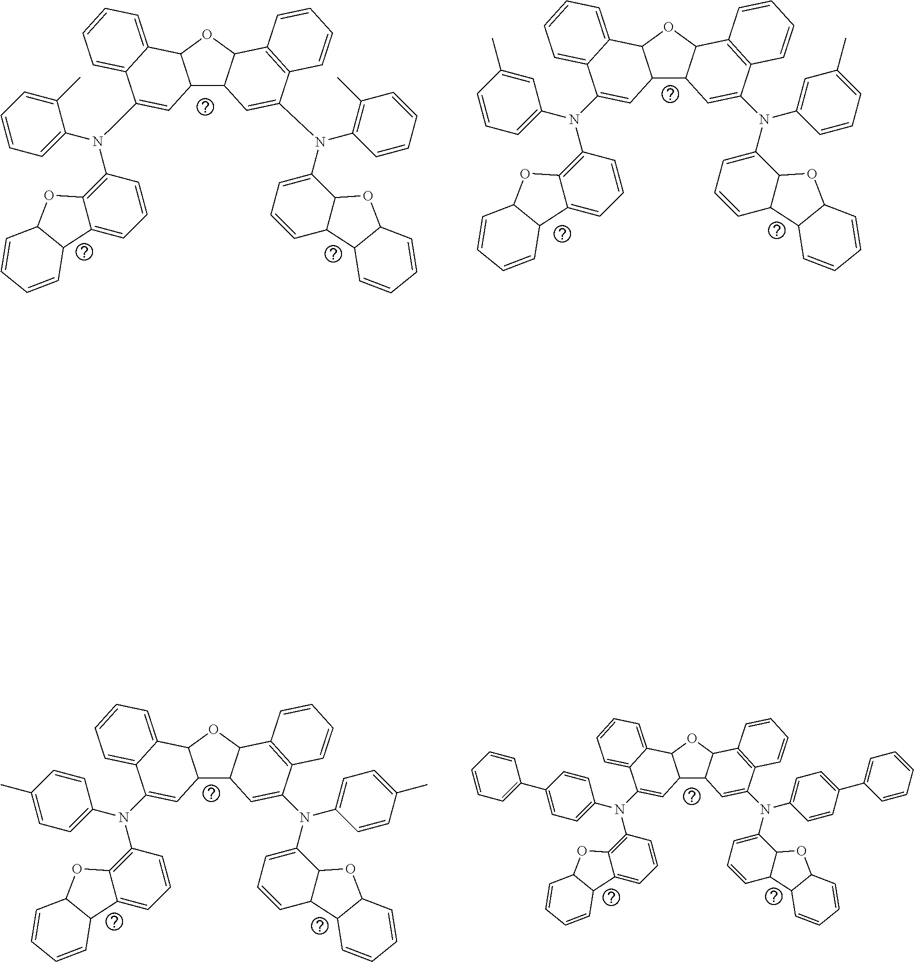

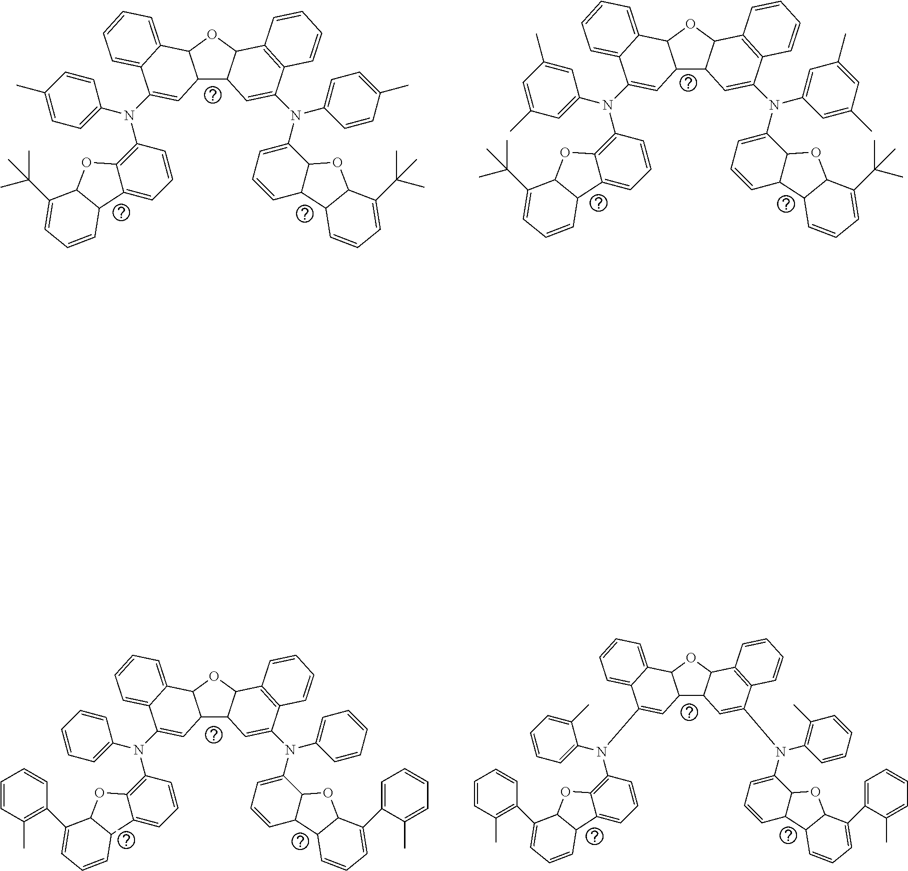

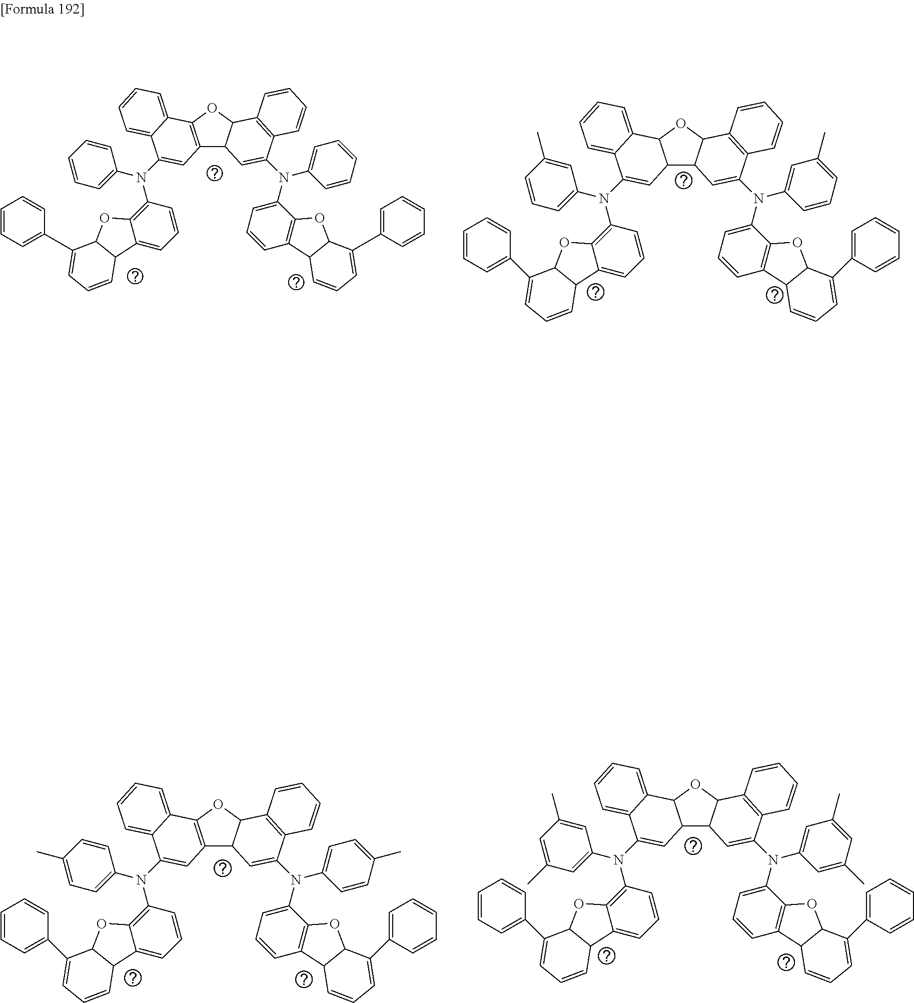

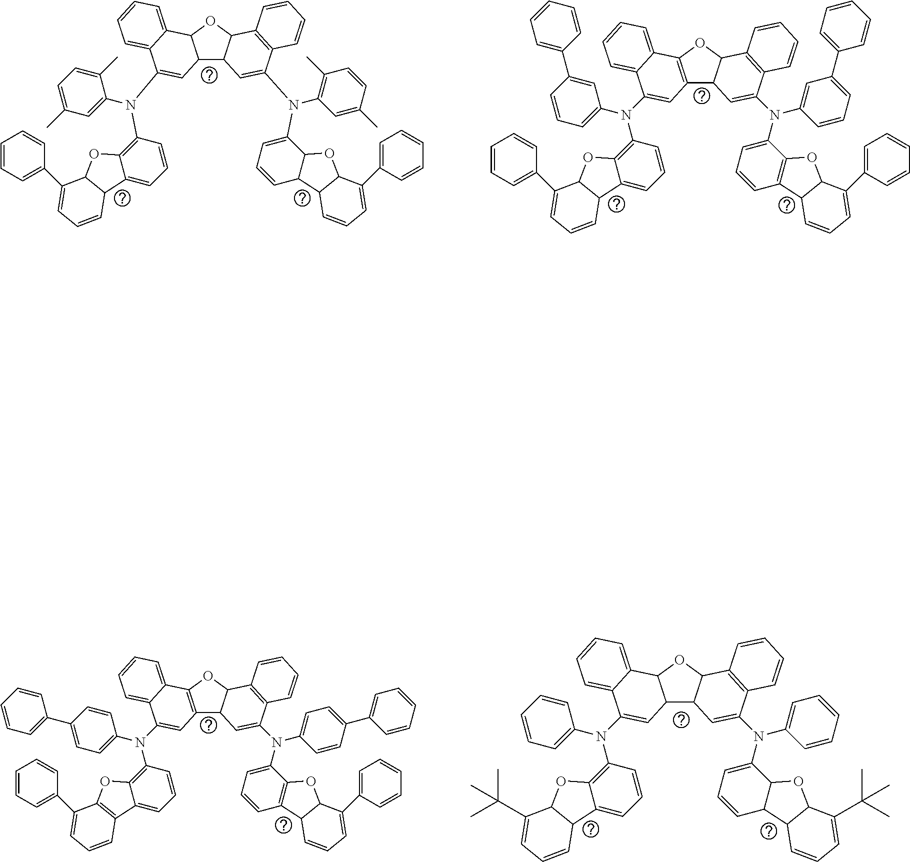

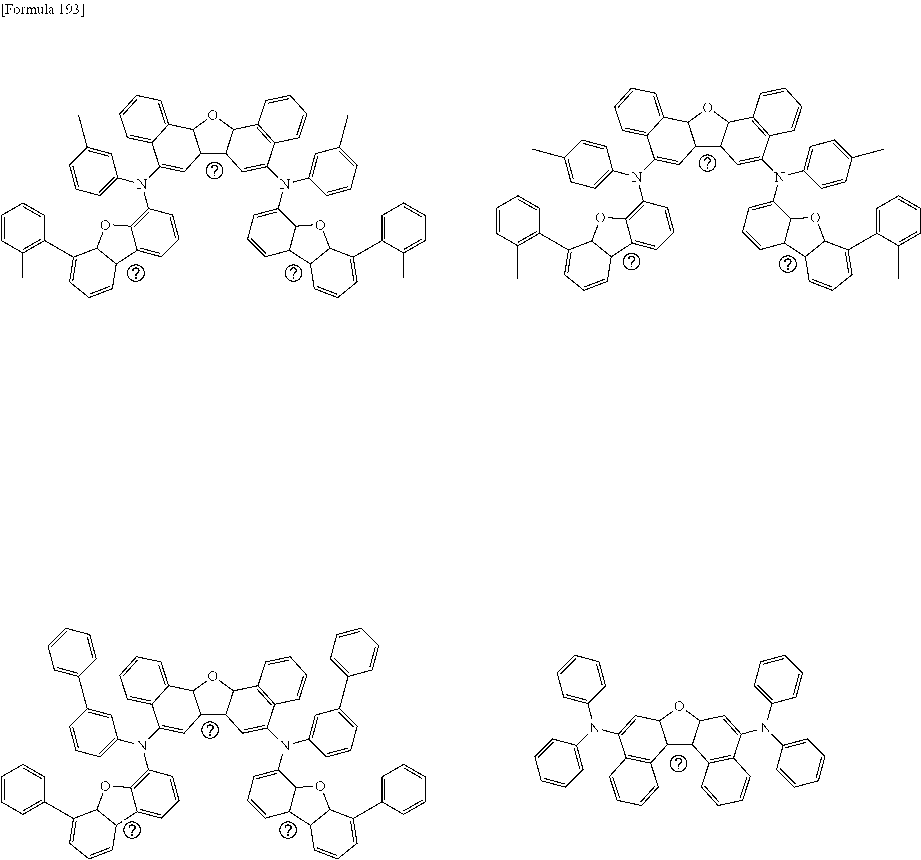 [SMILES: Cc1cccc(N(C2=CC3C(OC4c5ccccc5C(N(c5cccc(C)c5)c5cccc6c5OC5C(c7ccccc7C)=CC=CC65)=CC43)c3ccccc32)C2=CC=CC3C2OC2C(c4ccccc4C)=CC=CC23)c1 ; Cc1ccc(N(C2=CC3C(OC4c5ccccc5C(N(c5ccc(C)cc5)c5cccc6c5OC5C(c7ccccc7C)=CC=CC65)=CC43)c3ccccc32)C2=CC=CC3C2OC2C(c4ccccc4C)=CC=CC23)cc1 ; C1=CC2c3cccc(N(C4=CC5C(OC6c7ccccc7C(N(C7=CC=CC8C7OC7C(c9ccccc9)=CC=CC78)c7cccc(-c8ccccc8)c7)=CC65)c5ccccc54)c4cccc(-c5ccccc5)c4)c3OC2C(c2ccccc2)=C1 ; C1=C(N(c2ccccc2)c2ccccc2)c2ccccc2C2C1OC1C=C(N(c3ccccc3)c3ccccc3)c3ccccc3C12]

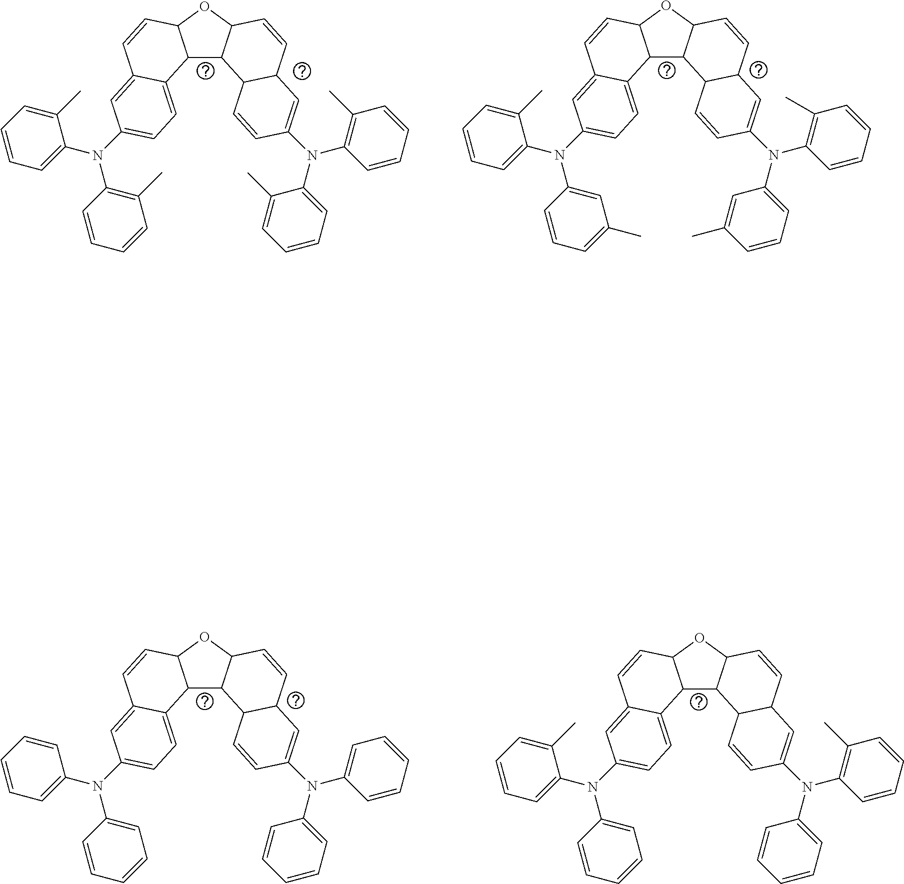 [SMILES: Cc1ccccc1N(C1=CC2C=CC3OC4C=Cc5cc(N(c6ccccc6C)c6ccccc6C)ccc5C4C3C2C=C1)c1ccccc1C ; Cc1cccc(N(C2=CC3C=CC4OC5C=Cc6cc(N(c7cccc(C)c7)c7ccccc7C)ccc6C5C4C3C=C2)c2ccccc2C)c1 ; C1=CC2C(C=CC3OC4C=Cc5cc(N(c6ccccc6)c6ccccc6)ccc5C4C32)C=C1N(c1ccccc1)c1ccccc1 ; Cc1ccccc1N(C1=CC2C=CC3OC4C=Cc5cc(N(c6ccccc6)c6ccccc6C)ccc5C4C3C2C=C1)c1ccccc1]

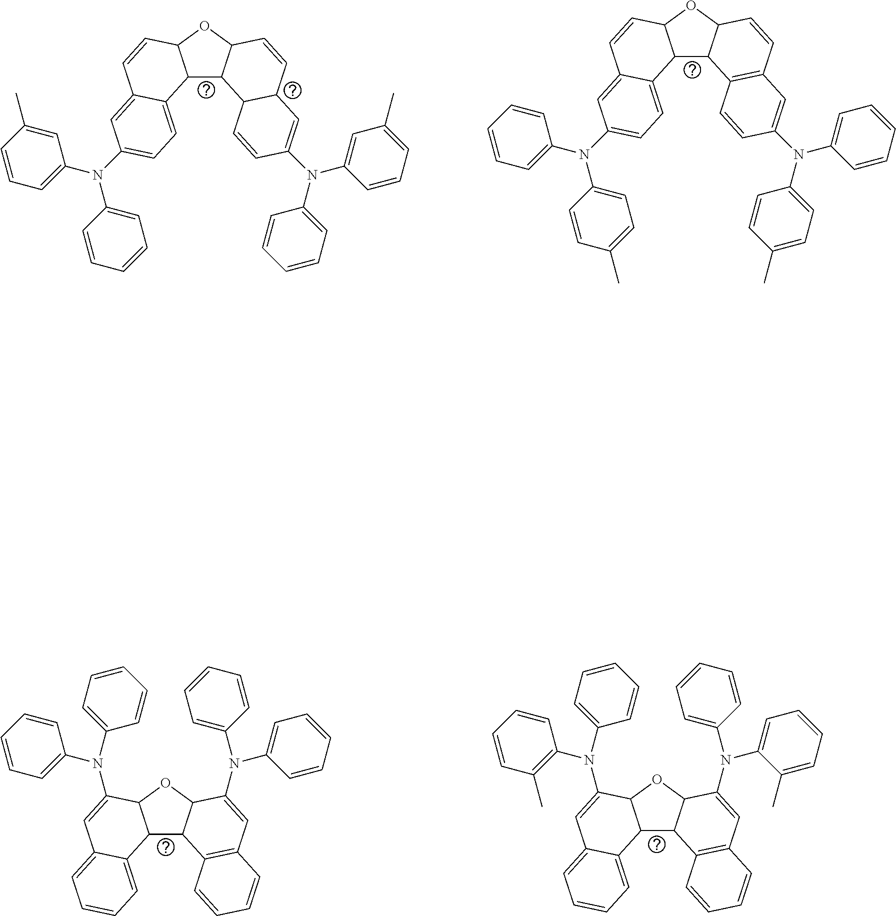 [SMILES: Cc1cccc(N(C2=CC3C=CC4OC5C=Cc6cc(N(c7ccccc7)c7cccc(C)c7)ccc6C5C4C3C=C2)c2ccccc2)c1 ; Cc1ccc(N(c2ccccc2)c2ccc3c(c2)C=CC2OC4C=Cc5cc(N(c6ccccc6)c6ccc(C)cc6)ccc5C4C32)cc1 ; C1=C(N(c2ccccc2)c2ccccc2)C2OC3C(N(c4ccccc4)c4ccccc4)=Cc4ccccc4C3C2c2ccccc21 ; Cc1ccccc1N(C1=Cc2ccccc2C2C1OC1C(N(c3ccccc3)c3ccccc3C)=Cc3ccccc3C12)c1ccccc1]

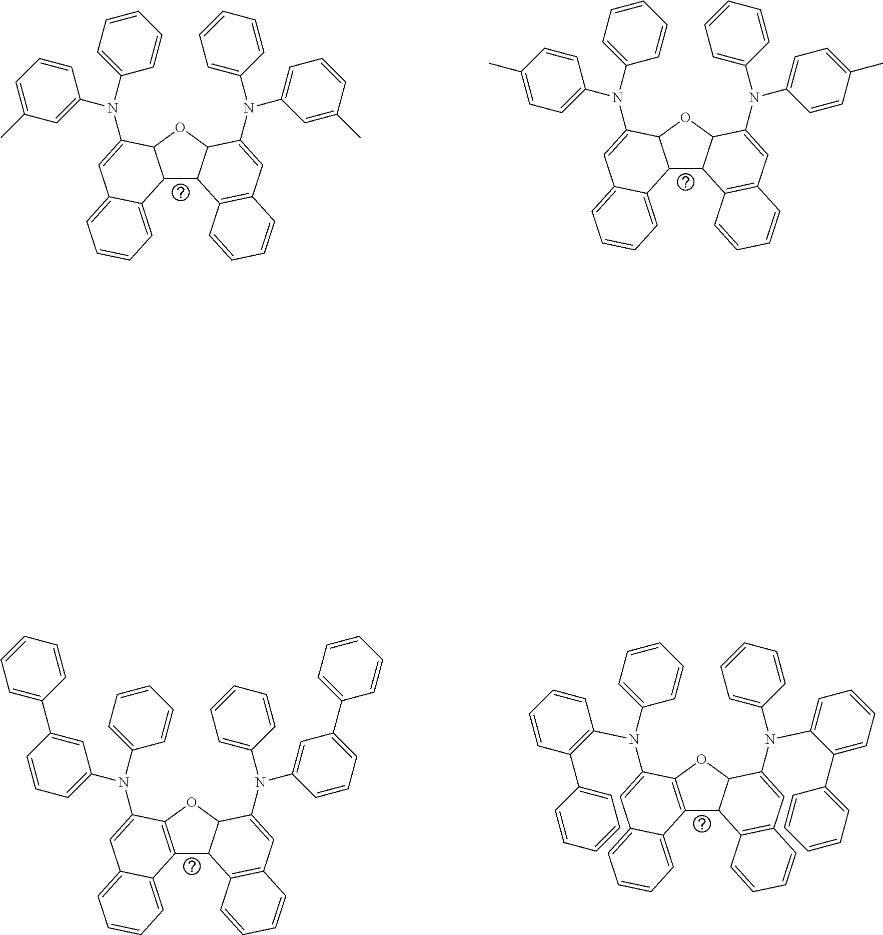

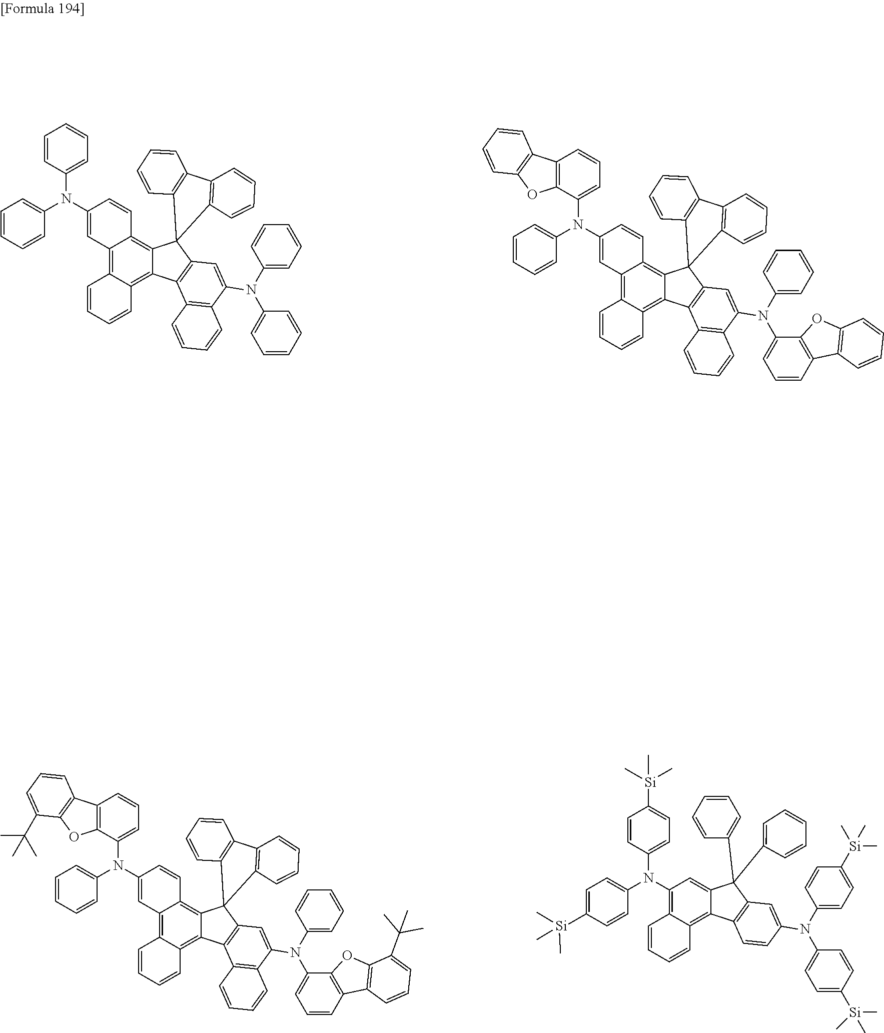

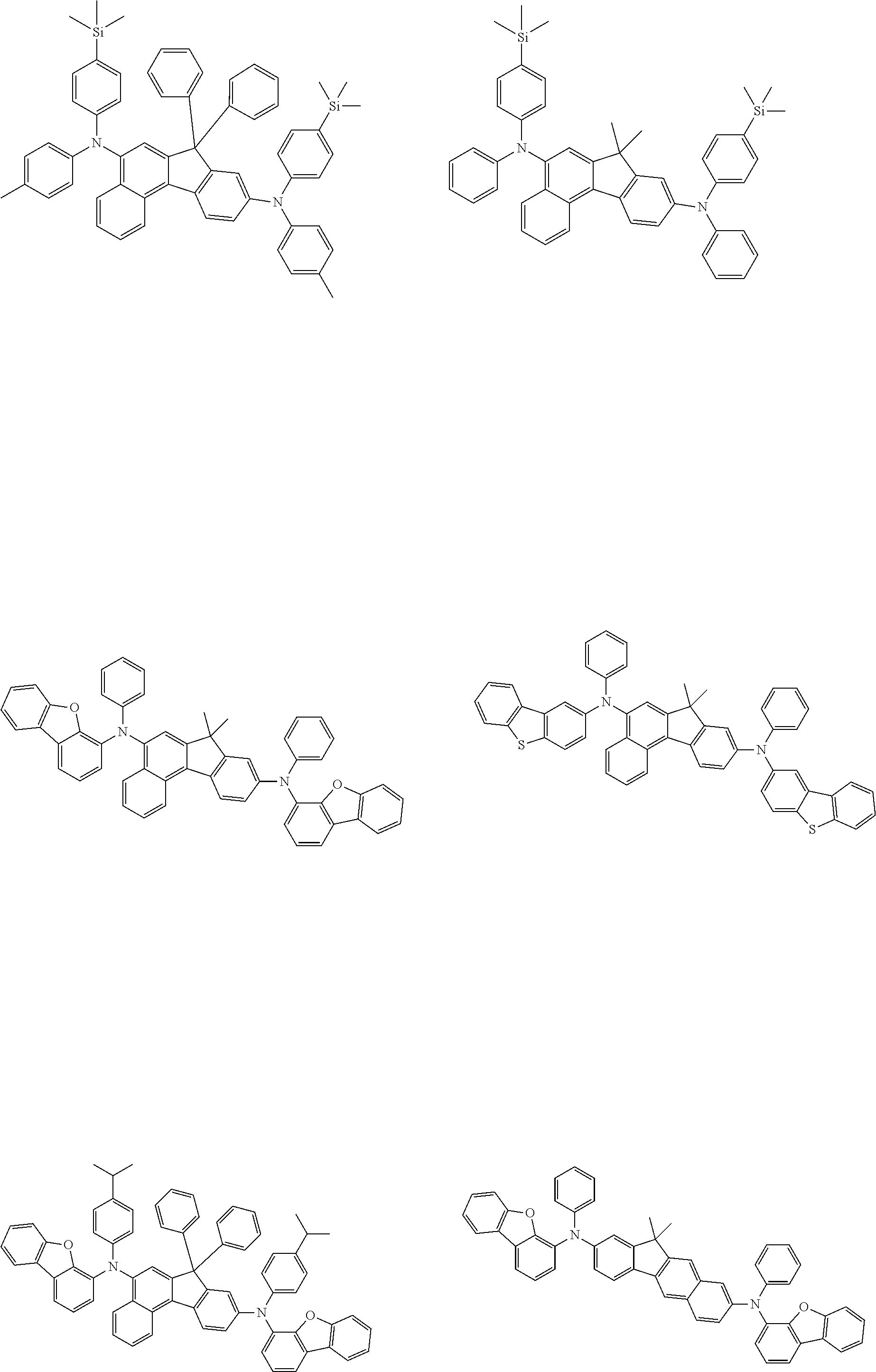

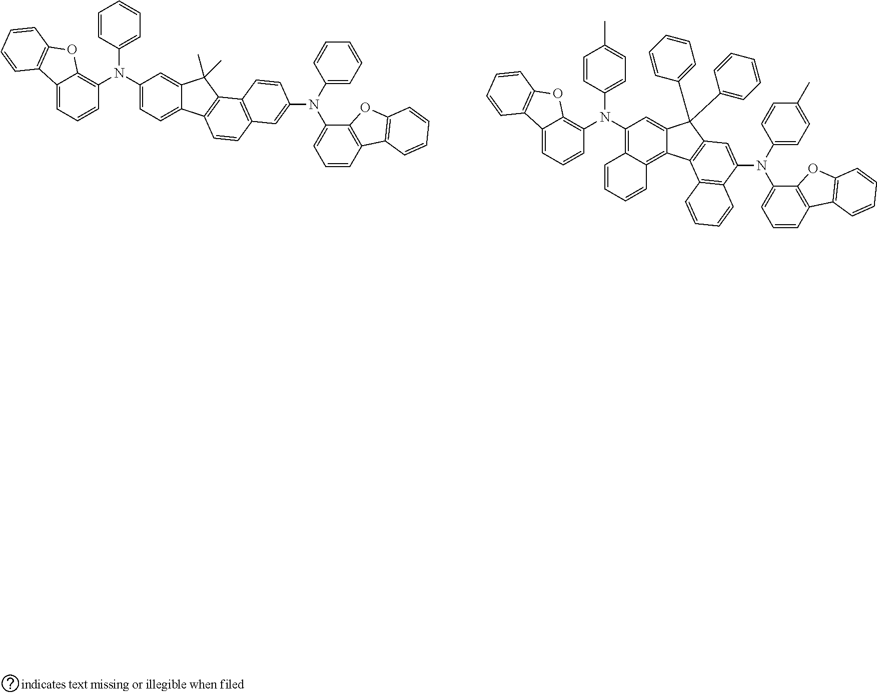 [SMILES: CC1(C)c2cc(N(c3ccccc3)c3cccc4c3oc3ccccc34)ccc2-c2ccc3cc(N(c4ccccc4)c4cccc5c4oc4ccccc45)ccc3c21 ; Cc1ccc(N(c2cc3c(c4ccccc24)-c2c(cc(N(c4ccc(C)cc4)c4cccc5c4oc4ccccc45)c4ccccc24)C3(c2ccccc2)c2ccccc2)c2cccc3c2oc2ccccc23)cc1]

### Compounds Represented by Formula (9)

The following describes the compounds represented by formula (9).

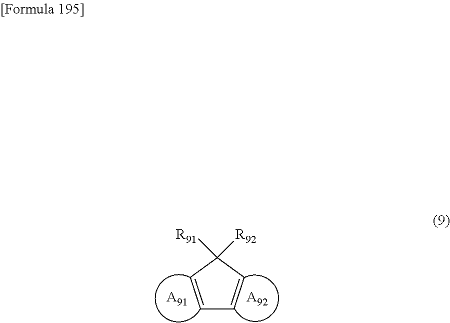

In formula (9),

rings A₉₁ and A₉₂ each independently represent: a substituted or unsubstituted aromatic hydrocarbon ring having 6 to 50 ring carbon atoms; or a substituted or unsubstituted heterocycle having 5 to 50 ring atoms; and one or more rings selected from the group consisting of rings A₉₁ and A₉₂ are bonded to the *s in a structure represented by formula (92) below.

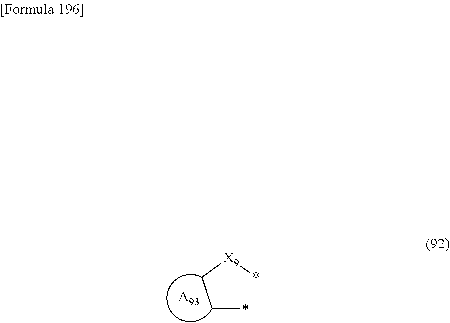

In formula (92),

ring A₉₃ is: a substituted or unsubstituted aromatic hydrocarbon ring having 6 to 50 ring carbon atoms; or a substituted or unsubstituted heterocycle having 5 to 50 ring atoms;

X₉ is NR₉₃, C(R₉₄)(R₉₅), Si(R₉₆)(R₉₇), Ge(R₉₈)(R₉₉), an oxygen atom, a sulfur atom, or a selenium atom;

R₉₁ and R₉₂ are: bonded together to form a substituted or unsubstituted monocyclic ring; bonded together to form a substituted or unsubstituted fused ring; or not bonded together; and

R₉₁ and R₉₂ not forming the monocyclic ring or the fused ring and R₉₃ to R₉₉ each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

One or more rings selected from the group consisting of rings A₉₁ and A₉₂ are bonded to the *s in a structure represented by formula (92). That is, in an exemplary embodiment, ring carbon atoms of the aromatic hydrocarbon ring as ring A₉₁ or ring atoms of the heterocycle as that ring are bonded to the *s in a structure represented by formula (92). In an exemplary embodiment, furthermore, ring carbon atoms of the aromatic hydrocarbon ring as ring A₉₂ or ring atoms of the heterocycle as that ring are bonded to the *s in a structure represented by formula (92).

In an exemplary embodiment, a group represented by formula (93) below is bonded to one or both of rings A₉₁ and A₉₂.

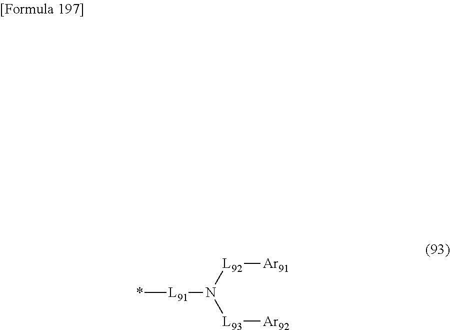

In formula (93),

Ar₉₁ and Ar₉₂ each independently represent: a substituted or unsubstituted aryl group having 6 to 50 ring carbon atoms; or a substituted or unsubstituted heterocyclic group having 5 to 50 ring atoms;

L₉₁ to L₉₃ each independently represent: a single bond; a substituted or unsubstituted arylene group having 6 to 30 ring carbon atoms; a substituted or unsubstituted divalent heterocyclic group having 5 to 30 ring atoms; or a divalent linking group formed by two to four groups bonded together, each of the two to four selected from the group consisting of a substituted or unsubstituted arylene group having 6 to 30 ring carbon atoms and a substituted or unsubstituted divalent heterocyclic group having 5 to 30 ring atoms; and

* in formula (93) indicates the position of bonding with either one of ring A₉₁ or A₉₂.

In an exemplary embodiment, ring carbon atoms of the aromatic hydrocarbon ring as ring A₉₂ or ring atoms of the heterocycle as that ring are bonded to the *s in a structure represented by formula (92), as well as ring A₉₁.

In that case, the structures represented by formula (92) may be mutually the same or different.

In an exemplary embodiment, R₉₁ and R₉₂ each independently represent a substituted or unsubstituted aryl group having 6 to 50 ring carbon atoms.

In an exemplary embodiment, R₉₁ and R₉₂ are bonded together to form a fluorene structure.

In an exemplary embodiment, rings A₉₁ and A₉₂ each independently represent a substituted or unsubstituted aromatic hydrocarbon ring having 6 to 50 ring carbon atoms, such as a substituted or unsubstituted benzene ring.

In an exemplary embodiment, ring A₉₃ is a substituted or unsubstituted aromatic hydrocarbon ring having 6 to 50 ring carbon atoms, such as a substituted or unsubstituted benzene ring.

In an exemplary embodiment, X₉ is an oxygen or sulfur atom.

Specific examples of compounds represented by formula (9) include, for instance, the following compounds.

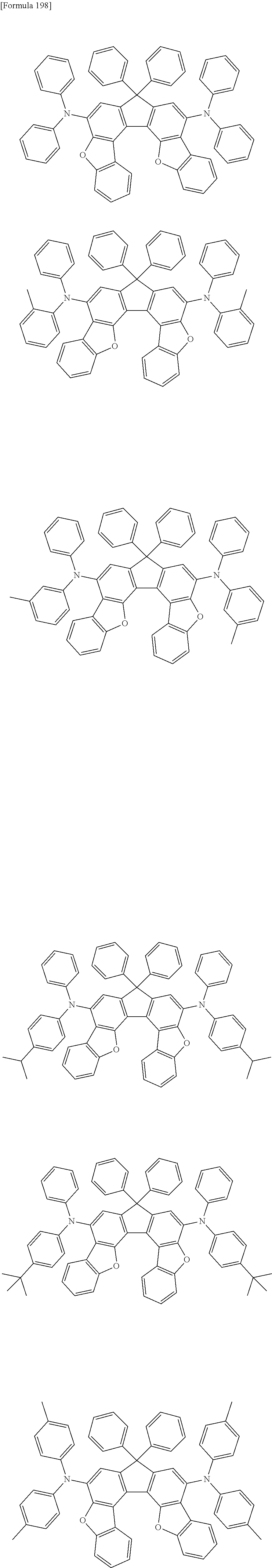

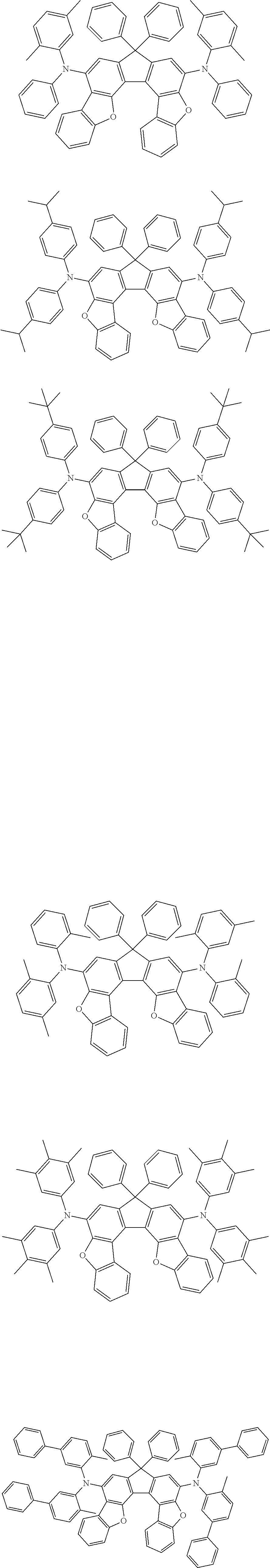

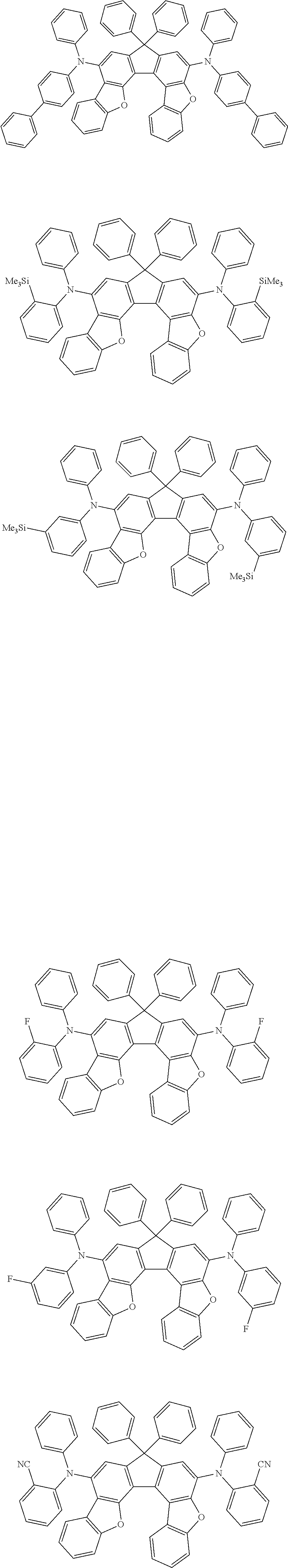

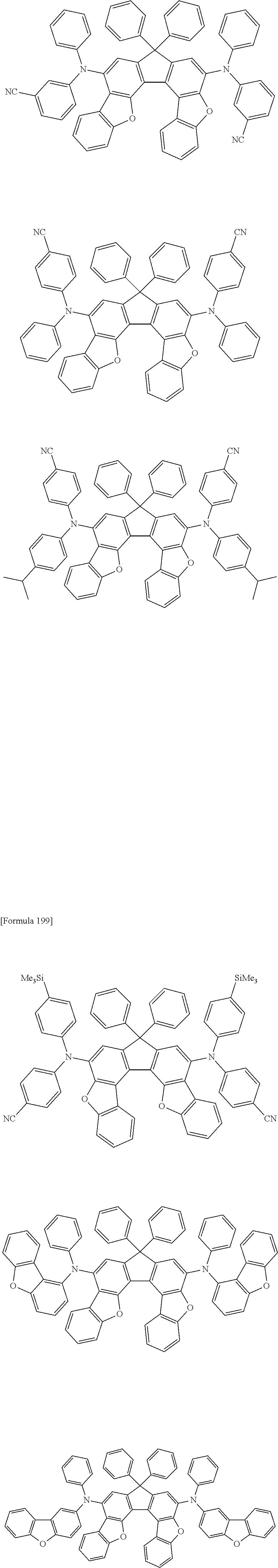

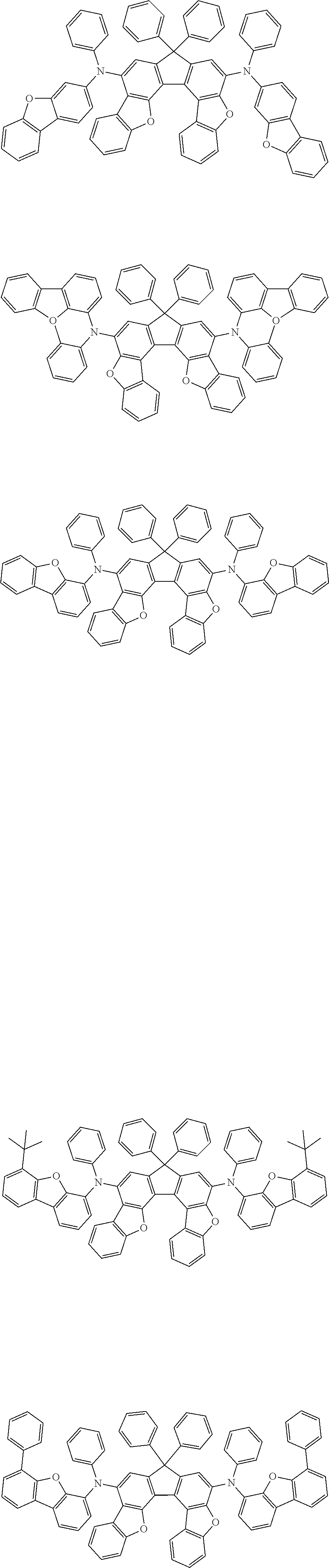

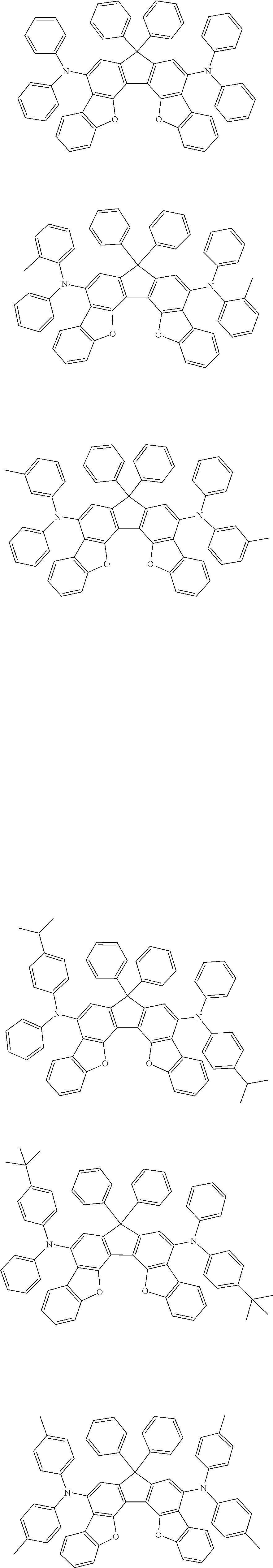

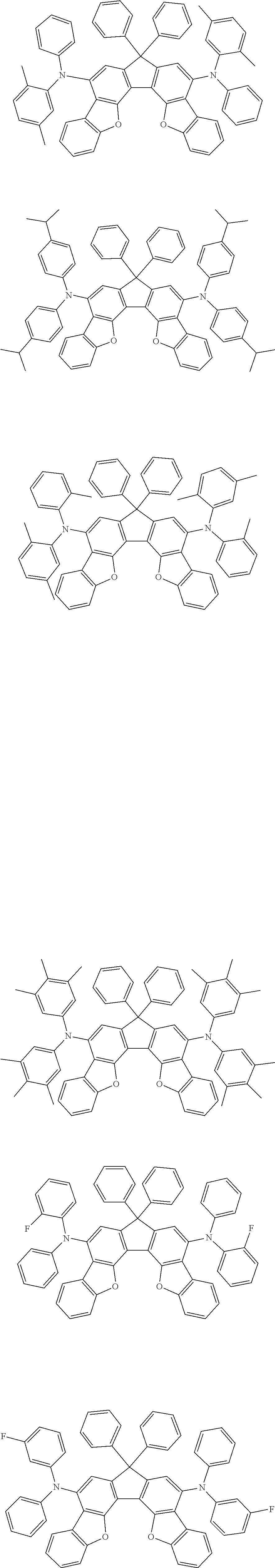

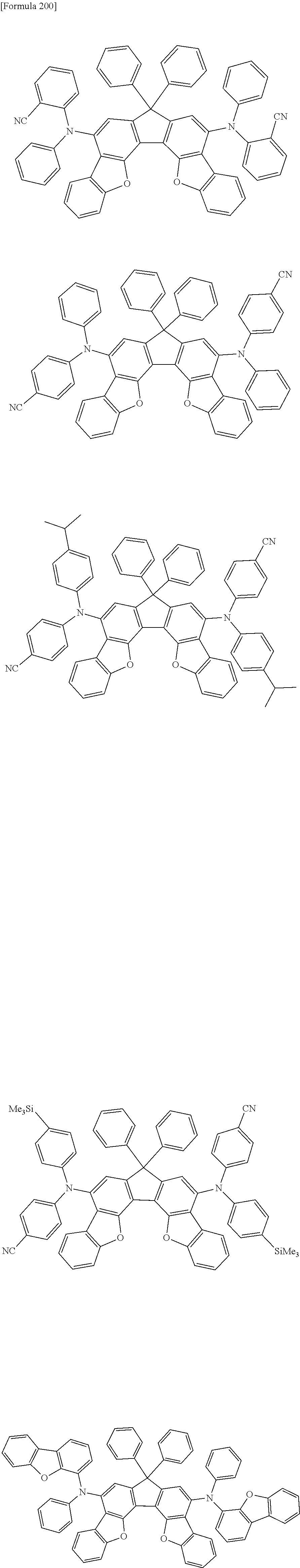

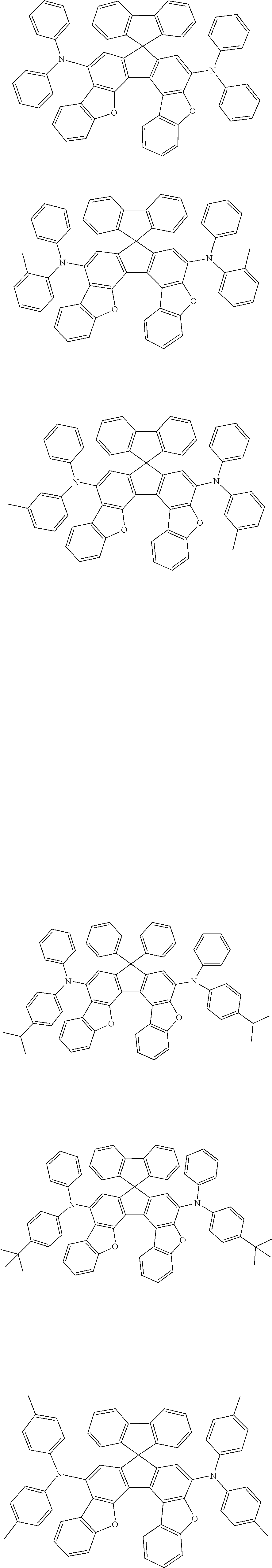

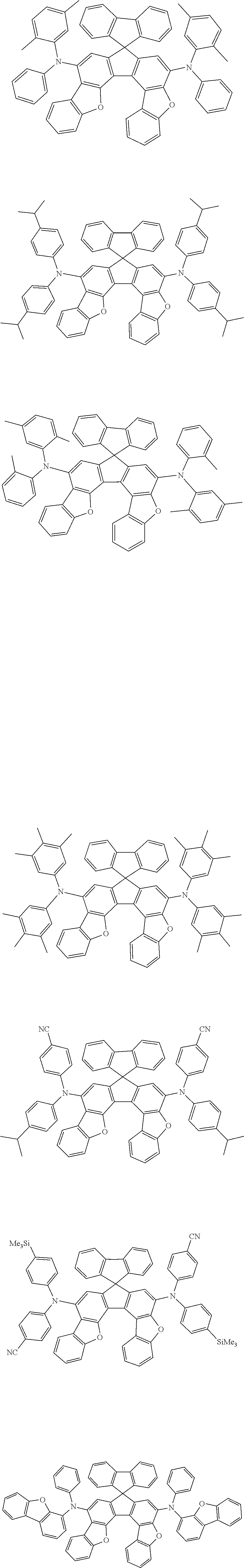

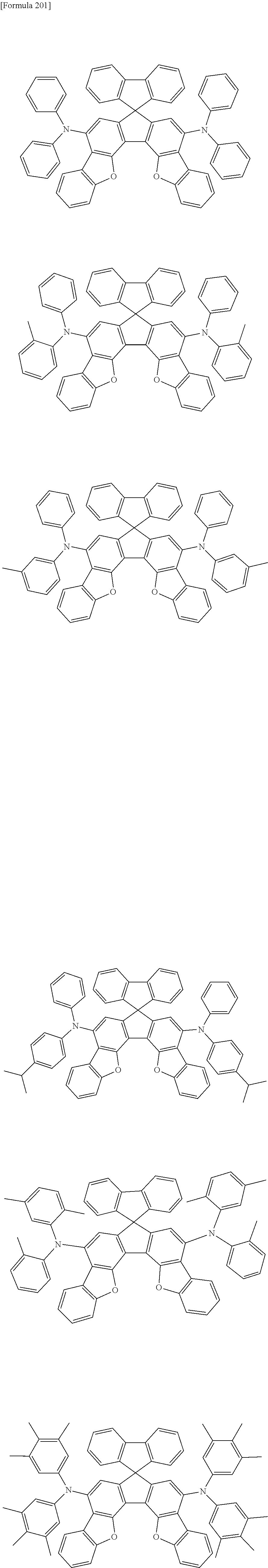

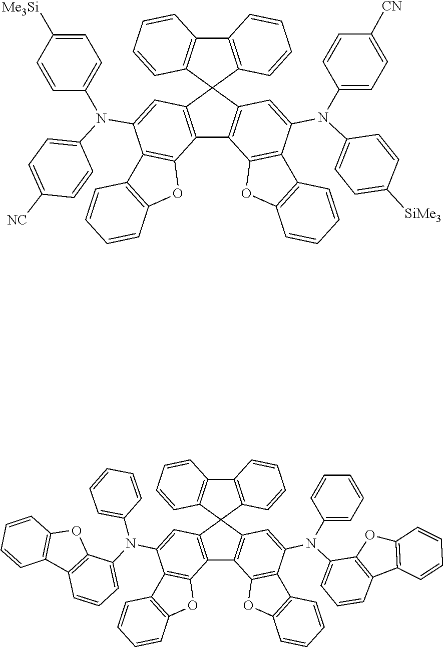 [SMILES: C[Si](C)(C)c1ccc(N(c2ccc(C#N)cc2)c2cc3c(c4oc5ccccc5c24)-c2c(cc(N(c4ccc(C#N)cc4)c4ccc([Si](C)(C)C)cc4)c4c2oc2ccccc24)C32c3ccccc3-c3ccccc32)cc1 ; c1ccc(N(c2cccc3c2oc2ccccc23)c2cc3c(c4oc5ccccc5c24)-c2c(cc(N(c4ccccc4)c4cccc5c4oc4ccccc45)c4c2oc2ccccc24)C32c3ccccc3-c3ccccc32)cc1]

### Compounds Represented by Formula (10)

The following describes the compounds represented by formula (10).

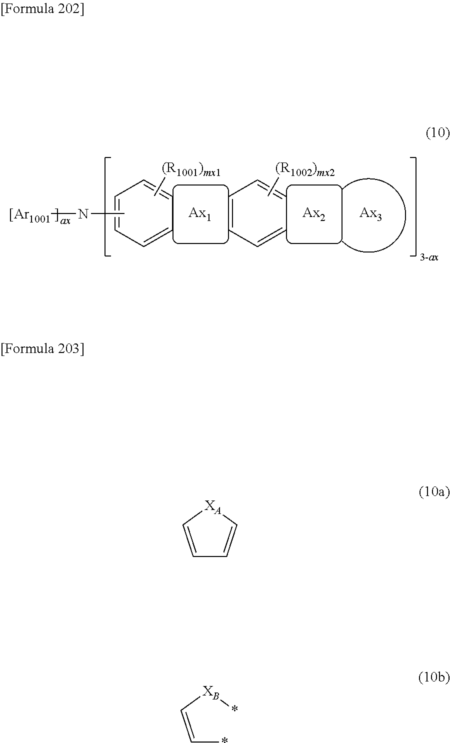

In formula (10),

ring Ax₁ is a ring represented by formula (10a) fused with adjacent ring(s) at any position(s);

ring Ax₂ is a ring represented by formula (10b) fused with adjacent ring(s) at any position(s);

the two *s in formula (10b) are bonded to any positions of ring Ax₃;

X_{A} and X_{B} each independently represent C(R₁₀₀₃)(R₁₀₀₄), Si(R₁₀₀₅)(R₁₀₀₆), an oxygen atom, or a sulfur atom;

ring Ax₃ is: a substituted or unsubstituted aromatic hydrocarbon ring having 6 to 50 ring carbon atoms; or a substituted or unsubstituted heterocycle having 5 to 50 ring atoms;

Ar₁₀₀₁ is: a substituted or unsubstituted aryl group having 6 to 50 ring carbon atoms; or a substituted or unsubstituted heterocyclic group having 5 to 50 ring atoms;

R₁₁₀₁ to R₁₀₀₆ each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms;

mx1 is 3; mx2 is 2;

the multiple R₁₀₀₁s are mutually the same or different;

the multiple R₁₀₀₂s are mutually the same or different;

ax is 0, 1, or 2;

if ax is 0 or 1, the structures in the brackets indicated by “3-ax” are mutually the same or different; and

if ax is 2, the multiple Ar₁₀₀₁s are mutually the same or different.

In an exemplary embodiment, Ar₁₀₀₁ is a substituted or unsubstituted aryl group having 6 to 50 ring carbon atoms.

In an exemplary embodiment, ring Ax₃ is a substituted or unsubstituted aromatic hydrocarbon ring having 6 to 50 ring carbon atoms, such as a substituted or unsubstituted benzene ring, substituted or unsubstituted naphthalene ring, or substituted or unsubstituted anthracene ring.

In an exemplary embodiment, R₁₀₀₃ and R₁₀₀₄ each independently represent a substituted or unsubstituted alkyl group having 1 to 50 carbon atoms.

In an exemplary embodiment, ax is 1.

Specific examples of compounds represented by formula (10) include, for instance, the following compounds.

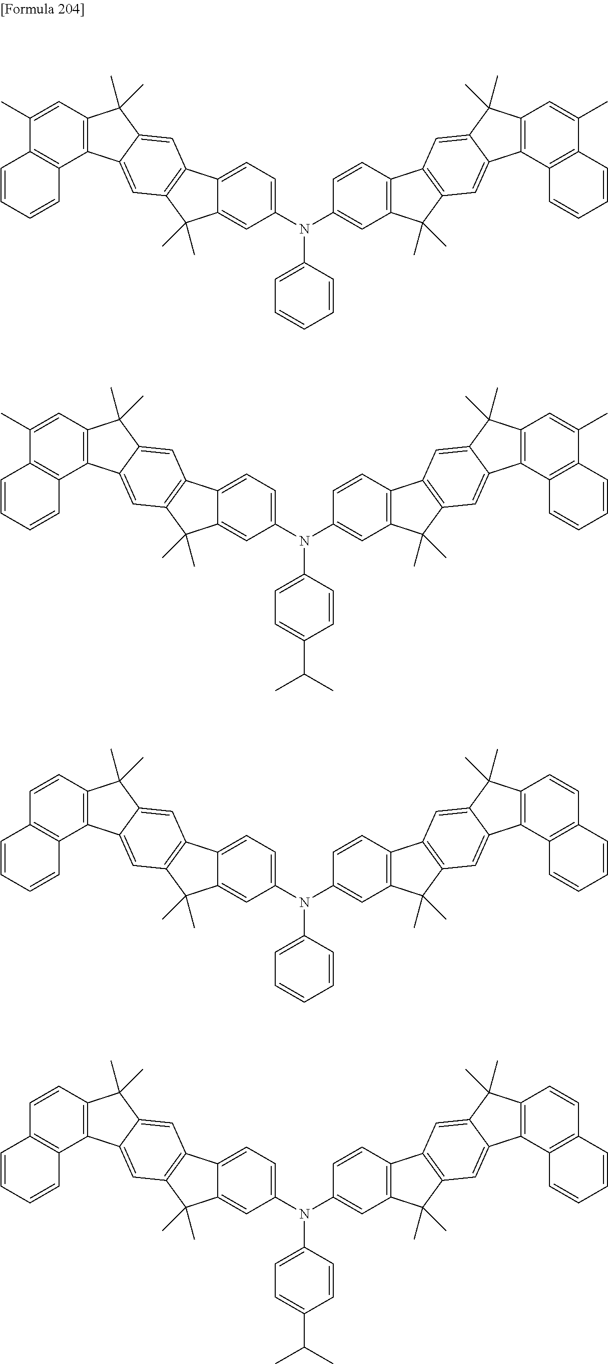

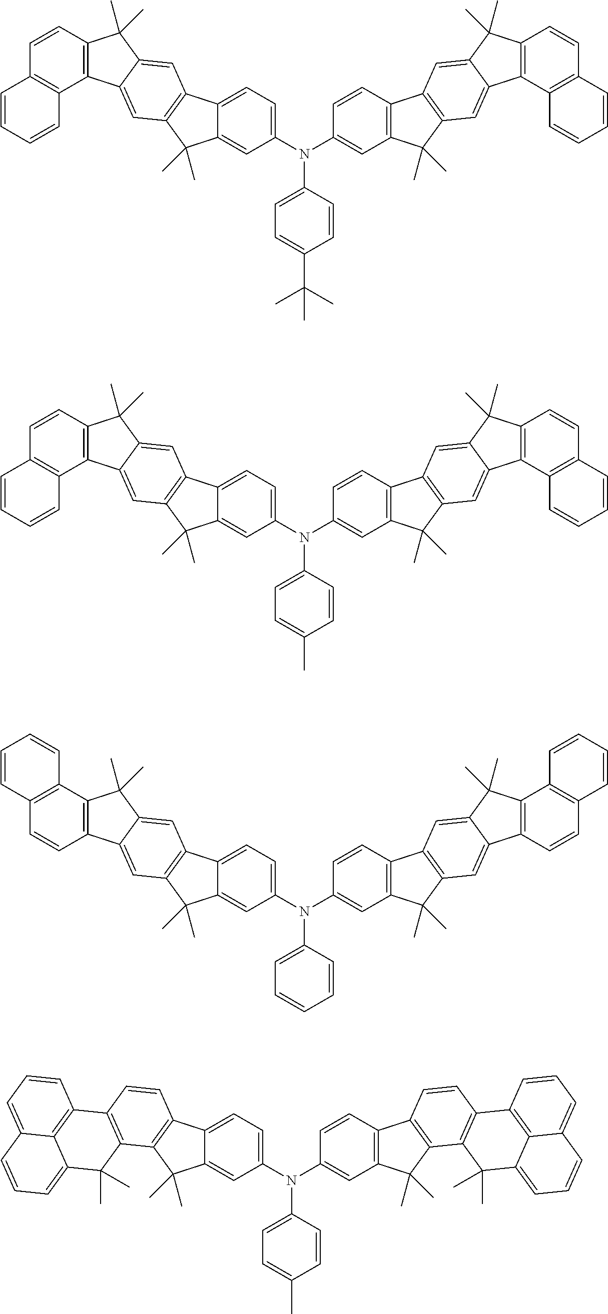 [SMILES: CC(C)(C)c1ccc(N(c2ccc3c(c2)C(C)(C)c2cc4c(cc2-3)C(C)(C)c2ccc3ccccc3c2-4)c2ccc3c(c2)C(C)(C)c2cc4c(cc2-3)C(C)(C)c2ccc3ccccc3c2-4)cc1 ; Cc1ccc(N(c2ccc3c(c2)C(C)(C)c2cc4c(cc2-3)C(C)(C)c2ccc3ccccc3c2-4)c2ccc3c(c2)C(C)(C)c2cc4c(cc2-3)C(C)(C)c2ccc3ccccc3c2-4)cc1 ; CC1(C)c2cc(N(c3ccccc3)c3ccc4c(c3)C(C)(C)c3cc5c(cc3-4)C(C)(C)c3c-5ccc4ccccc34)ccc2-c2cc3c(cc21)-c1ccc2ccccc2c1C3(C)C ; Cc1ccc(N(c2ccc3c(c2)C(C)(C)c2c-3ccc3c2C(C)(C)c2cccc4cccc-3c24)c2ccc3c(c2)C(C)(C)c2c-3ccc3c2C(C)(C)c2cccc4cccc-3c24)cc1]

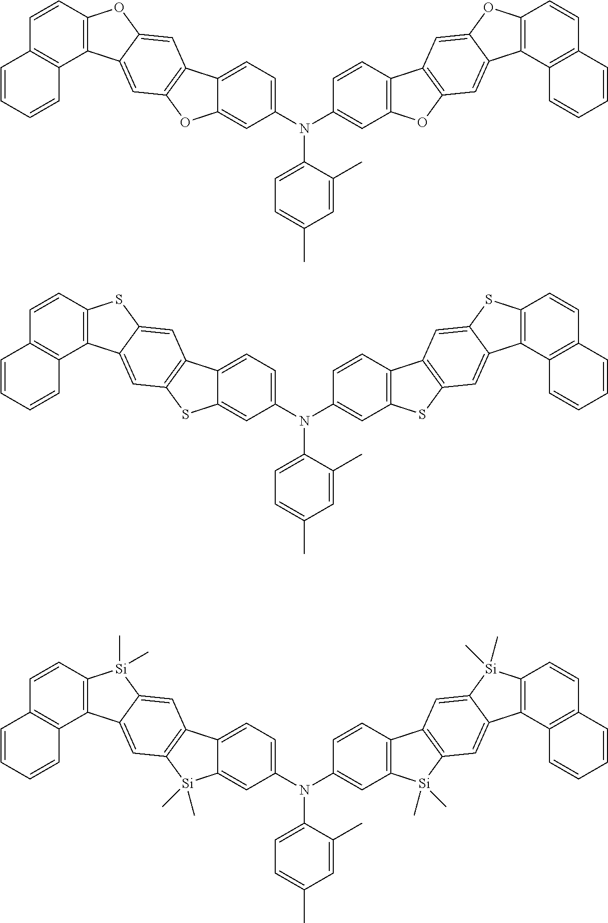 [SMILES: Cc1ccc(N(c2ccc3c(c2)oc2cc4c(cc23)oc2ccc3ccccc3c24)c2ccc3c(c2)oc2cc4c(cc23)oc2ccc3ccccc3c24)c(C)c1 ; Cc1ccc(N(c2ccc3c(c2)sc2cc4c(cc23)sc2ccc3ccccc3c24)c2ccc3c(c2)sc2cc4c(cc23)sc2ccc3ccccc3c24)c(C)c1 ; Cc1ccc(N(c2ccc3c(c2)[Si](C)(C)c2cc4c(cc2-3)[Si](C)(C)c2ccc3ccccc3c2-4)c2ccc3c(c2)[Si](C)(C)c2cc4c(cc2-3)[Si](C)(C)c2ccc3ccccc3c2-4)c(C)c1]

In an exemplary embodiment, the emitting layer contains, as the second compound(s), one or more compounds selected from the group consisting of: the compounds represented by formula (4); the compounds represented by formula (5); the compounds represented by formula (7); the compounds represented by formula (8); the compounds represented by formula (9); and the compounds represented by formula (63a) below.

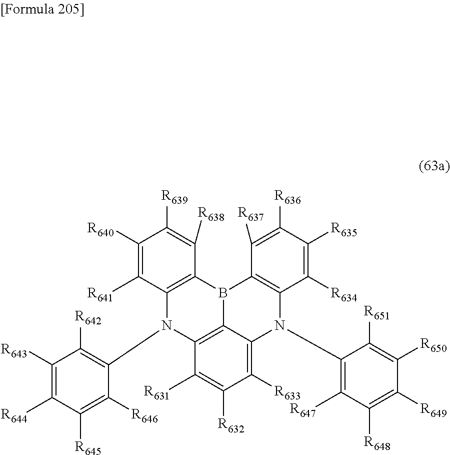

In formula (63a),

R₆₃₁ is bonded with R₆₄₆ to form a substituted or unsubstituted heterocycle, or not bonded therewith to form no substituted or unsubstituted heterocycle,

R₆₃₃ is bonded with R₆₄₇ to form a substituted or unsubstituted heterocycle, or not bonded therewith to form no substituted or unsubstituted heterocycle,

R₆₃₄ is bonded with R₆₅₁ to form a substituted or unsubstituted heterocycle, or not bonded therewith to form no substituted or unsubstituted heterocycle,

R₆₄₁ is bonded with R₆₄₂ to form a substituted or unsubstituted heterocycle, or not bonded therewith to form no substituted or unsubstituted heterocycle, at least one combination of adjacent two or more of R₆₃₁ to R₆₅₁ are mutually bonded to form a substituted or unsubstituted monocyclic ring, mutually bonded to form a substituted or unsubstituted fused ring, or not mutually bonded,

R₆₃₁ to R₆₅₁ not forming the substituted or unsubstituted heterocycle, not forming the monocyclic ring and not forming the fused ring each independently represent: a hydrogen atom; a halogen atom; a cyano group; a nitro group; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a substituted or unsubstituted aryl group having 6 to 50 ring carbon atoms; or a substituted or unsubstituted heterocyclic group having 5 to 50 ring atoms;

at least one of R₆₃₁ to R₆₅₁ not forming the substituted or unsubstituted heterocycle, not forming the monocyclic ring and not forming the fused ring is: a halogen atom; a cyano group; a nitro group; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a halogen atom; a cyano group; a nitro group; a substituted or unsubstituted aryl group having 6 to 50 ring carbon atoms; or a substituted or unsubstituted heterocyclic group having 5 to 50 ring atoms.

In an exemplary embodiment, the compounds represented by formula (4) are the compounds represented by formula (41-3), (41-4), or (41-5), and ring A1 in formula (41-5) is a substituted or unsubstituted fused aromatic hydrocarbon ring system having 10 to 50 ring carbon atoms or substituted or unsubstituted fused heterocyclic system having 8 to 50 ring atoms.

In an exemplary embodiment, in formulae (41-3), (41-4), and (41-5), the substituted or unsubstituted fused aromatic hydrocarbon ring system having 10 to 50 ring carbon atoms is: a substituted or unsubstituted naphthalene ring; a substituted or unsubstituted anthracene ring; or a substituted or unsubstituted fluorene ring; and

the substituted or unsubstituted fused heterocyclic system having 8 to 50 ring atoms is: a substituted or unsubstituted dibenzofuran ring; a substituted or unsubstituted carbazole ring; or a substituted or unsubstituted dibenzothiophene ring.

In an exemplary embodiment, in formula (41-3), (41-4), or (41-5), the substituted or unsubstituted fused aromatic hydrocarbon ring system having 10 to 50 ring carbon atoms is: a substituted or unsubstituted naphthalene ring; or a substituted or unsubstituted fluorene ring; and

the substituted or unsubstituted fused heterocyclic system having 8 to 50 ring atoms is: a substituted or unsubstituted dibenzofuran ring; a substituted or unsubstituted carbazole ring; or a substituted or unsubstituted dibenzothiophene ring.

In an exemplary embodiment, the compounds represented by formula (4) are selected from the group consisting of: the compounds represented by formula (461) below; the compounds represented by formula (462) below; the compounds represented by formula (463) below; the compounds represented by formula (464) below; the compounds represented by formula (465) below; the compounds represented by formula (466) below; and the compounds represented by formula (467) below.

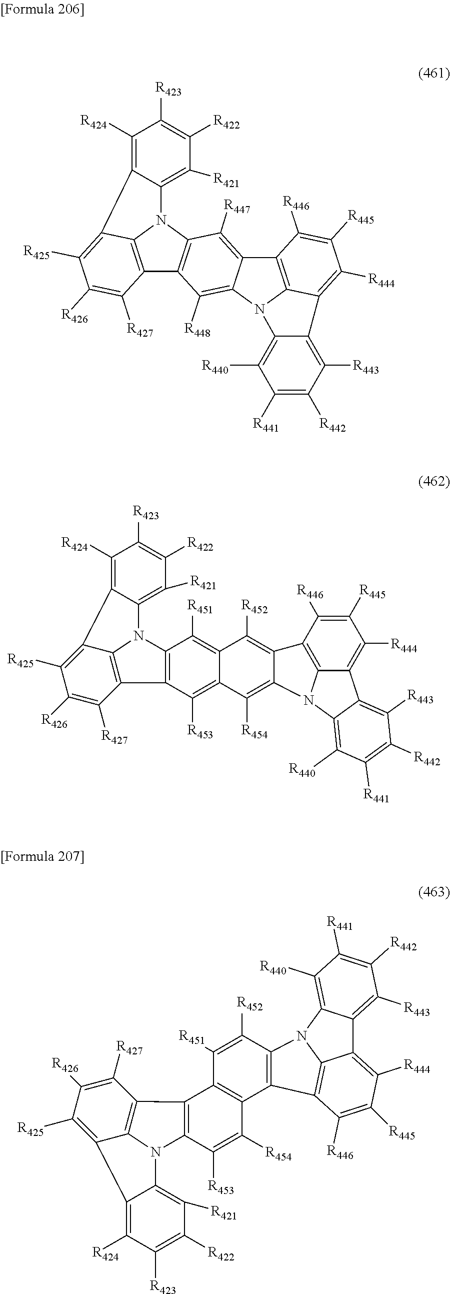

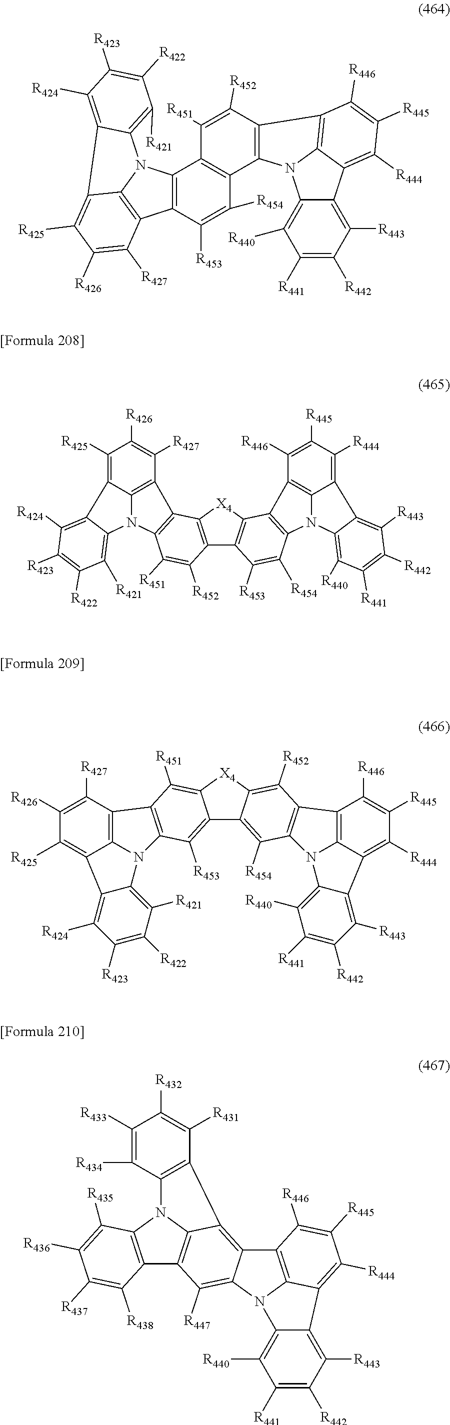

In formulae (461) to (467),

at least one combination of adjacent two or more of R₄₂₁ to R₄₂₇, R₄₃₁ to 5 R₄₃₆, R₄₄₀ to R₄₄₈, and R₄₄₁ to R₄₄ are: bonded together to form a substituted or unsubstituted monocyclic ring; bonded together to form a substituted or unsubstituted fused ring; or not bonded together;

R₄₃₇, R₄₃₈, and R₄₂₁ to R₄₂₇, R₄₃₁ to R₄₃₆, R₄₄₀ to R₄₄₈, and R₄₅₁ to R₄₅₄ not forming the monocyclic ring and not forming the fused ring each independently represent: a hydrogen atom; a substituted or unsubstituted alkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₀)(R₉₀₀); a halogen atom; a cyano group; a nitro group; a substituted or unsubstituted aryl group having 6 to 50 ring carbon atoms; or a substituted or unsubstituted heterocyclic group having 5 to 50 ring atoms;

X₄ is an oxygen atom, NR₈₀₁, or C(R₈₀₂)(R₈₀₃);

R₈₀₁, R₈₀₂, and R₈₀₃ each independently represent: a hydrogen atom; a substituted or unsubstituted alkyl group having 1 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms;

a substituted or unsubstituted alkyl group having 1 to 50 carbon atoms; or a substituted or unsubstituted aryl group having 6 to 50 ring carbon atoms;

when multiple R₈₀₁s are present, the multiple R₈₀₁s are mutually the same or different;

when multiple R₈₀₂s are present, the multiple R₈₀₂s are mutually the same or different; and

when multiple R₈₀₃s are present, the multiple R₈₀₃s are mutually the same or different.

In an exemplary embodiment, R₄₂₁ to R₄₂₇ and R₄₄₀ to R₄₄₈ each independently represent: a hydrogen atom; a substituted or unsubstituted aryl group having 6 to 50 ring carbon atoms; or a substituted or unsubstituted heterocyclic group having 5 to 50 ring atoms.

In an exemplary embodiment, R₄₂₁ to R₄₂₇ and R₄₄₀ to R₄₄₇ are each independently selected from the group consisting of: a hydrogen atom; a substituted or unsubstituted aryl group having 6 to 18 ring carbon atoms; and a substituted or unsubstituted heterocyclic group having 5 to 18 ring atoms.

In an exemplary embodiment, the compounds represented by formula (41-3) are the compounds represented by formula (41-3-1) below.

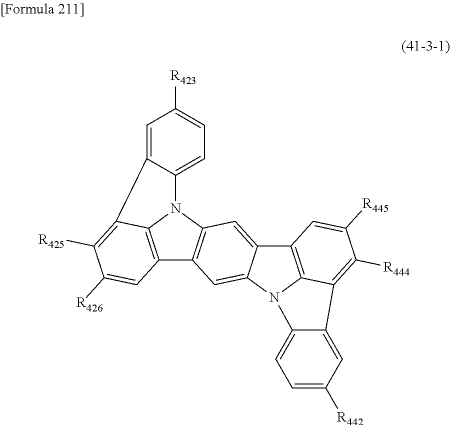

In formula (41-3-1), R₄₂₃, R₄₂₅, R₄₂₆, R₄₄₂, R₄₄₄, and R₄₄₅ each independently represent the same as R₄₂₃, R₄₂₅, R₄₂₆, R₄₄₂, R₄₄₄, and R₄₄₅ in formula (41-3).

In an exemplary embodiment, the compounds represented by formula (41-3) are the compounds represented by formula (41-3-2) below.

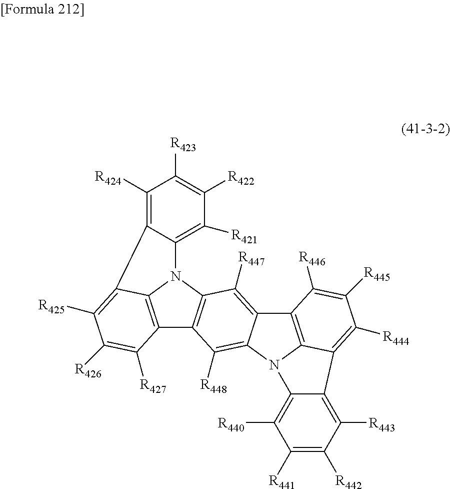

In formula (41-3-2), R₄₂₁ to R₄₂₇ and R₄₄₀ to R₄₄₈ each independently represent the same as R₄₂₁ to R₄₂₇ and R₄₄₀ to R₄₄₈ in formula (41-3); and

at least one of R₄₂₁ to R₄₂₇ or R₄₄₀ to R₄₄₆ is a group represented by —N(R₉₀₆)(R₉₀₇).

In an exemplary embodiment, any two of R₄₂₁ to R₄₂₇ and R₄₄₀ to R₄₄₆ in formula (41-3-2) are groups represented by —N(R₉₀₆)(R₉₀₇).

In an exemplary embodiment, the compounds represented by (41-3-2) are the compounds represented by formula (41-3-3) below.

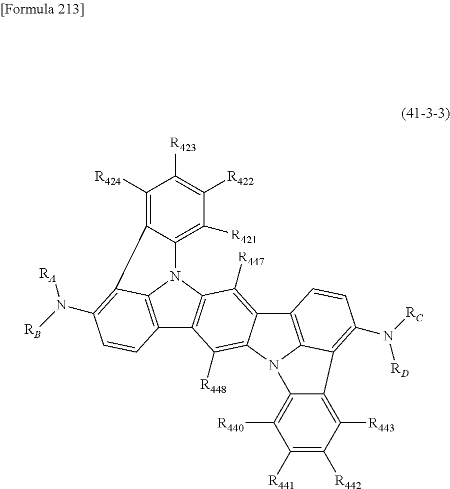

In formula (41-3-3), R₄₂₁ to R₄₂₄, R₄₄₀ to R₄₄₃, R₄₄₇, and R₄₄₈ each independently represent the same as R₄₂₁ to R₄₂₄, R₄₄₀ to R₄₄₃, R₄₄₇, and R₄₄₈ in formula (41-3); and

R_{A}, R_{B}, R_{C}, and R_{D} each independently represent: a substituted or unsubstituted aryl group having 6 to 18 ring carbon atoms; or a substituted or unsubstituted heterocyclic group having 5 to 18 ring atoms.

In an exemplary embodiment, the compounds represented by formula (41-3-3) are the compounds represented by formula (41-3-4) below.

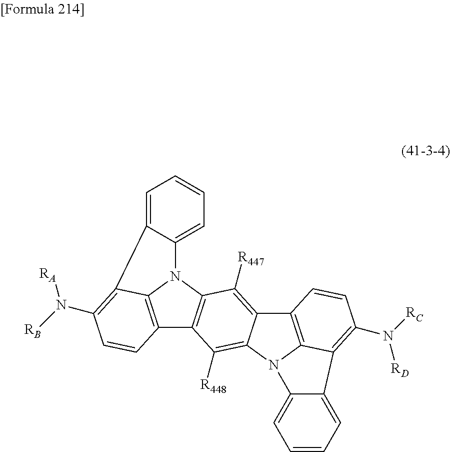

In formula (41-3-4), R₄₄₇, R₄₄₈, R_{A}, R_{B}, R_{C}, and R_{D} each independently represent the same as R₄₄₇, R₄₄₈, R_{A}, R_{B}, R_{C}, and R_{D} in formula (41-3-3).

In an exemplary embodiment, R_{A}, R_{B}, R_{C}, and R_{D} each independently represent a substituted or unsubstituted aryl group having 6 to 18 ring carbon atoms.

In an exemplary embodiment, R_{A}, R_{B}, R_{C}, and R_{D} each independently represent a substituted or unsubstituted phenyl group.

In an exemplary embodiment, R₄₄₇ and R₄₄₈ are hydrogen atoms.

In an exemplary embodiment, a substituent for “substituted or unsubstituted” group in each of the formulae is: an unsubstituted alkyl group having 1 to 50 carbon atoms; an unsubstituted alkenyl group having 2 to 50 carbon atoms; an unsubstituted alkynyl group having 2 to 50 carbon atoms; an unsubstituted cycloalkyl group having 3 to 50 ring carbon atoms; —Si(R₉₀₁a)(R₉₀₂ₐ)(R₉₀₃ₐ); —O—(R₉₀₄ₐ); —S—(R₉₀₅a); —N(R₉₀₆ₐ)(R₉₀₇ₐ); a halogen atom; a cyano group; a nitro group; an unsubstituted aryl group having 6 to 50 ring carbon atoms; or an unsubstituted heterocyclic group having 5 to 50 ring atoms;

R₉₀₁ₐ to R₉₀₇ₐ each independently represent: a hydrogen atom; an unsubstituted alkyl group having 1 to 50 carbon atoms; an unsubstituted aryl group having 6 to 50 ring carbon atoms; or an unsubstituted heterocyclic group having 5 to 50 ring atoms;

when two or more R₉₀₁ₐs are present, the two or more R₉₀₁ₐs are mutually the same or different;

when two or more R₉₀₂ₐs are present, the two or more R₉₀₂ₐs are mutually the same or different;

when two or more R₉₀₃ₐs are present, the two or more R₉₀₃ₐs are mutually the same or different;

when two or more R₉₀₄ₐs are present, the two or more R₉₀₄ₐs are mutually the same or different;

when two or more R₉₀₅ₐs are present, the two or more R₉₀₅ₐs are mutually the same or different;

when two or more R₉₀₆ₐs are present, the two or more R₉₀₆ₐs are mutually the same or different; and

when two or more R₉₀₇ₐs are present, the two or more R₉₀₇ₐs are mutually the same or different.

In an exemplary embodiment, a substituent for “substituted or unsubstituted” group in each of the formulae is: an unsubstituted alkyl group having 1 to 50 carbon atoms; an unsubstituted aryl group having 6 to 50 ring carbon atoms; or an unsubstituted heterocyclic group having 5 to 50 ring atoms.

In an exemplary embodiment, a substituent for “substituted or unsubstituted” group in each of the formulae is: an unsubstituted alkyl group having 1 to 18 carbon atoms; an unsubstituted aryl group having 6 to 18 ring carbon atoms; or an unsubstituted heterocyclic group having 5 to 18 ring atoms.

In the organic EL device according to this exemplary embodiment, it is preferred that the second compound(s) be compound(s) that exhibits light emission with a maximum peak wavelength in a range from 430 nm to 480 nm.

The measurement of the maximum peak wavelength of a compound is as follows. A 10⁻⁶ mol/L or more and 10⁻⁵ mol/L or less solution of the compound of interest in toluene is prepared and put into a quartz cell, and the emission spectrum of this sample is measured at room temperature (300 K) (the ordinate axis, luminous intensity; the abscissa axis, wavelength). The emission spectrum can be measured using Hitachi High-Tech Science Corporation's spectrophotometer (model: F-7000), although the system for measuring the emission spectrum does not need to be this.

In the emission spectrum, the peak wavelength of the emission spectrum at which the luminous intensity peaks is defined as the maximum emission peak wavelength. It should be noted that the maximum peak wavelength for fluorescence may herein be referred to as the maximum fluorescence peak wavelength (FL-peak).

In the second compound(s), it is preferred that all groups described as “substituted or unsubstituted” be “unsubstituted” groups

### Third and Fifth Compounds

In the organic EL device according to this exemplary embodiment, examples of third and fifth compounds as host materials include, for instance, heterocyclic compounds and fused aromatic compounds. Examples of preferred fused aromatic compounds include, for instance, anthracene derivatives, pyrene derivatives, chrysene derivatives, and naphthacene derivatives.

In the organic EL device according to this exemplary embodiment, it is also preferred that the third compound be a compound represented by formula (1). In that case, the compound represented by formula (1) as the first compound, contained in the first hole transporting layer, and that as the third compound, contained in the emitting layer, are mutually the same or different.

It is also preferred that a third compound in a first emitting layer be a compound represented by formula (1) while a fifth compound in a second emitting layer is not. In that case, the compound represented by formula (1) as the first compound, contained in the first hole transporting layer, and that as the third compound, contained in the first emitting layer, are mutually the same or different.

In the organic EL device according to this exemplary embodiment, it is also preferred that the third compound is a compound represented by formula (2) below.

It is also preferred that a fifth compound in a second emitting layer be a compound represented by formula (2) below while a third compound in a first emitting layer is not.

It is also preferred that a third compound in a first emitting layer be a compound represented by formula (1) while a fifth compound in a second emitting layer is a compound represented by formula (2) below.

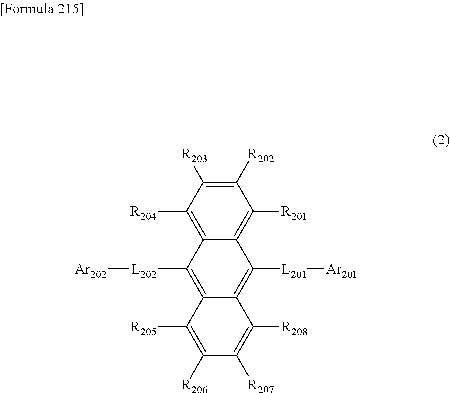

In formula (2),

R₂₀₁ to R₂₀₈ each independently represent: a hydrogen atom; a substituted or unsubstituted alkyl group having 1 to 50 carbon atoms; a substituted or unsubstituted haloalkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a substituted or unsubstituted aralkyl group having 7 to 50 carbon atoms; a group represented by —C(═O)R₈₀₁; a group represented by —COOR₈₀₂; a halogen atom; a cyano group; a nitro group; a substituted or unsubstituted aryl group having 6 to 50 ring carbon atoms; or a substituted or unsubstituted heterocyclic group having 5 to 50 ring atoms;

L₂₀₁ and L₂₀₂ each independently represent: a single bond; a substituted or unsubstituted arylene group having 6 to 50 ring carbon atoms; or a substituted or unsubstituted divalent heterocyclic group having 5 to 50 ring atoms; and Ar₂₀₁ and Ar₂₀₂ each independently represent: a substituted or unsubstituted aryl group having 6 to 50 ring carbon atoms; or a substituted or unsubstituted heterocyclic group having 5 to 50 ring atoms.

In a third compound according to this exemplary embodiment, R₉₀₁, R₉₀₂, R₉₀₃, R₉₀₄, R₉₀₅, R₉₀₅, R₉₀₇, R₈₀₁, and R₈₀₂ each independently represent: a hydrogen atom; a substituted or unsubstituted alkyl group having 1 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms;

when multiple R₉₀₁s are present, the multiple R₉₀₁s are mutually the same or different;

when multiple R₉₀₂s are present, the multiple R₉₀₂s are mutually the same or different;

when multiple R₉₀₃s are present, the multiple R₉₀₃s are mutually the same or different;

when multiple R₉₀₄s are present, the multiple R₉₀₄s are mutually the same or different;

when multiple R₉₀₅s are present, the multiple R₉₀₅s are mutually the same or different;

when multiple R₉₀₆s are present, the multiple R₉₀₆s are mutually the same or different;

when multiple R₉₀₇s are present, the multiple R₉₀₇s are mutually the same or different;

when multiple R₈₀₁s are present, the multiple R₈₀₁s are mutually the same or different; and

when multiple R₈₀₂s are present, the multiple R₈₀₂s are mutually the same or different.

In the organic EL device according to this exemplary embodiment, it is preferred that

R₂₀₁ to R₂₀₈ each independently represent: a hydrogen atom; a substituted or unsubstituted alkyl group having 1 to 50 carbon atoms; a substituted or unsubstituted haloalkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a group represented by —N(R₉₀₆)(R₉₀₇); a substituted or unsubstituted aralkyl group having 7 to 50 carbon atoms; a group represented by —C(═O)R₈₀₁; a group represented by —COOR₈₀₂; a halogen atom; a cyano group; or a nitro group;

L₂₀₁ and L₂₀₂ each independently represent: a single bond; a substituted or unsubstituted arylene group having 6 to 50 ring carbon atoms; or a substituted or unsubstituted divalent heterocyclic group having 5 to 50 ring atoms; and

Ar₂₀₁ and Ar₂₀₂ each independently represent: a substituted or unsubstituted aryl group having 6 to 50 ring carbon atoms; or a substituted or unsubstituted heterocyclic group having 5 to 50 ring atoms.

In the organic EL device according to this exemplary embodiment, it is preferred that

L₂₀₁ and L₂₀₂ each independently represent: a single bond; or a substituted or unsubstituted arylene group having 6 to 50 ring carbon atoms; and

Ar₂₀₁ and Ar₂₀₂ each independently represent a substituted or unsubstituted aryl group having 6 to 50 ring carbon atoms.

In the organic EL device according to this exemplary embodiment, it is preferred that Ar₂₀₁ and Ar₂₀₂ each independently represent: a phenyl group, a naphthyl group, a phenanthryl group, a biphenyl group, a terphenyl group, a diphenylfluorenyl group, a dimethylfluorenyl group, a benzodiphenylfluorenyl group, a benzodimethylfluorenyl group, a dibenzofuranyl group, a dibenzothienyl group, a naphthobenzofuranyl group, or a naphthobenzothienyl group.

In the organic EL device according to this exemplary embodiment, it is preferred that the third compound represented by formula (2) be a compound represented by formula (201), (202), (203), (204), (205), (206), (207), (208), (209), or (210) below.

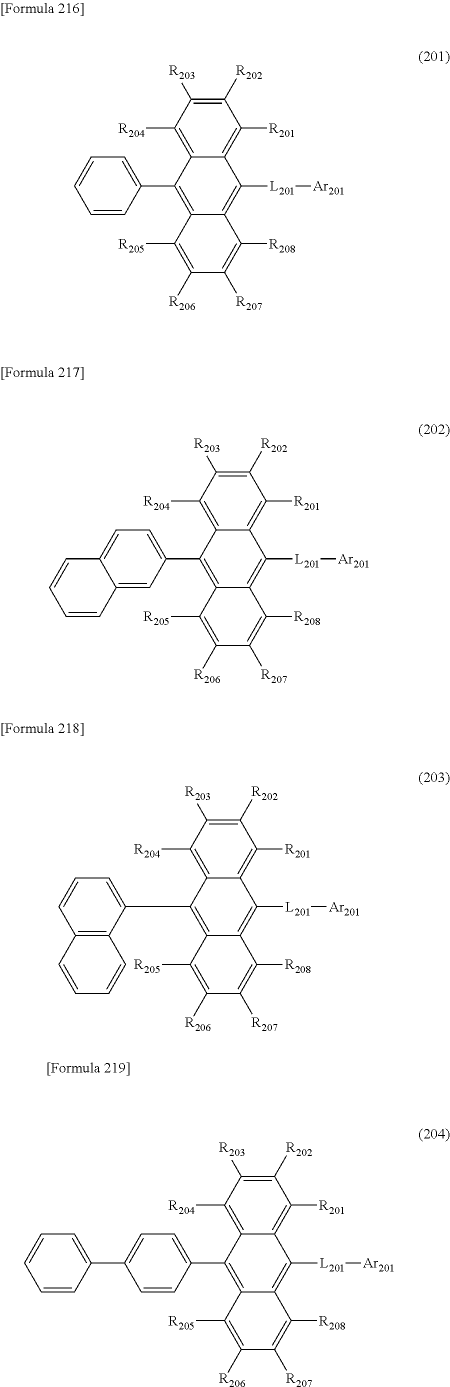

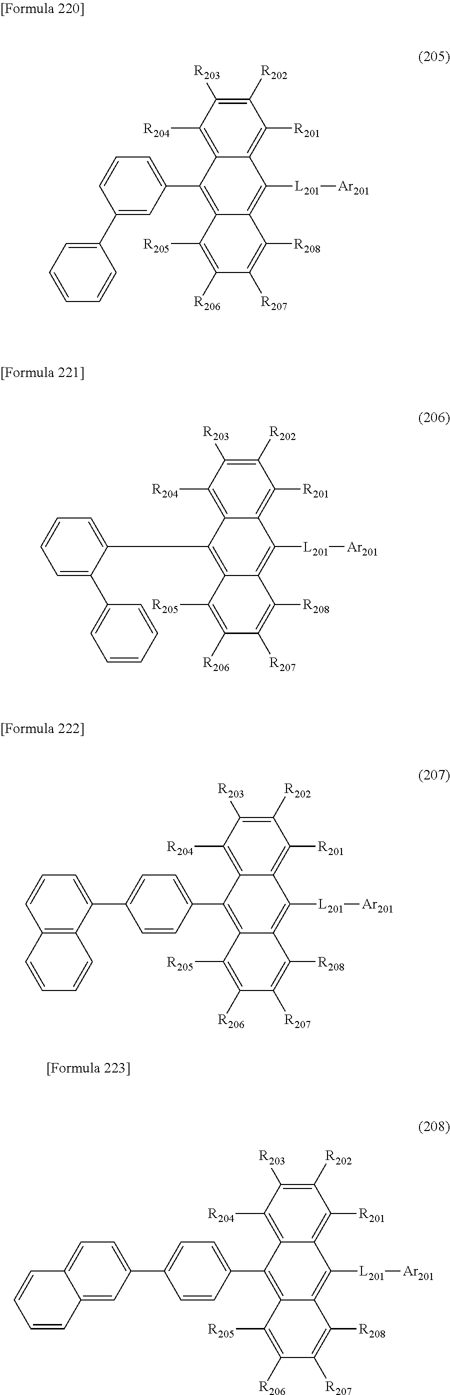

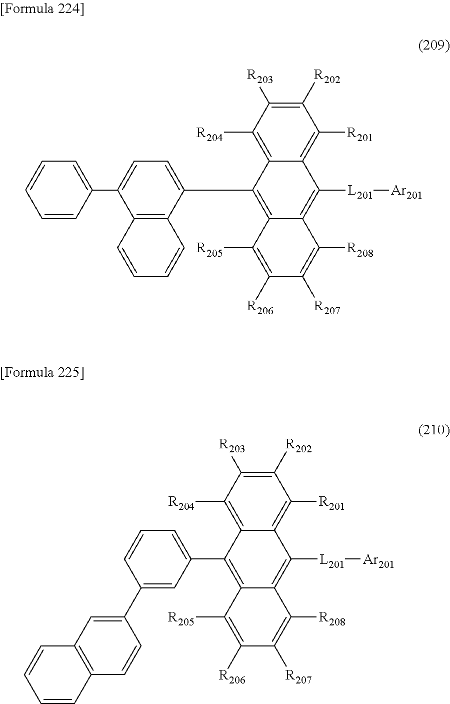

In formulae (201) to (210),

L₂₀₁ and Ar₂₀₁ represent the same as L₂₀₁ and Ar₂₀₁ in formula (2); and

R₂₀₁ to R₂₀₈ each independently represent the same as R₂₀₁ to R₂₀₈ in formula (2).

It is also preferred that the third compound represented by formula (2) be a compound represented by formula (221), (222), (223), (224), (225), (226), (227), (228), or (229) below.

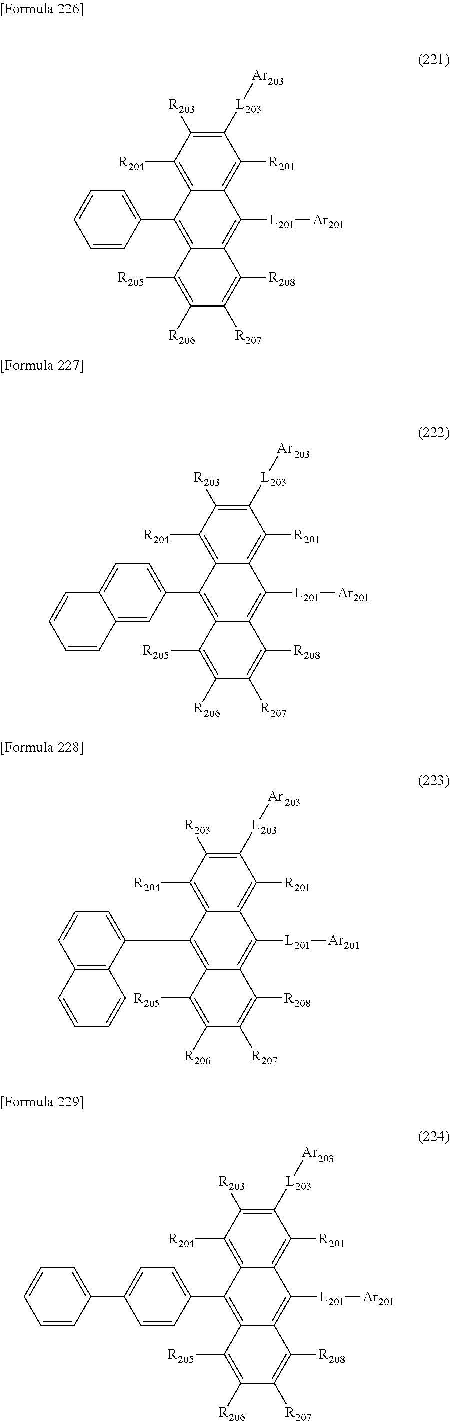

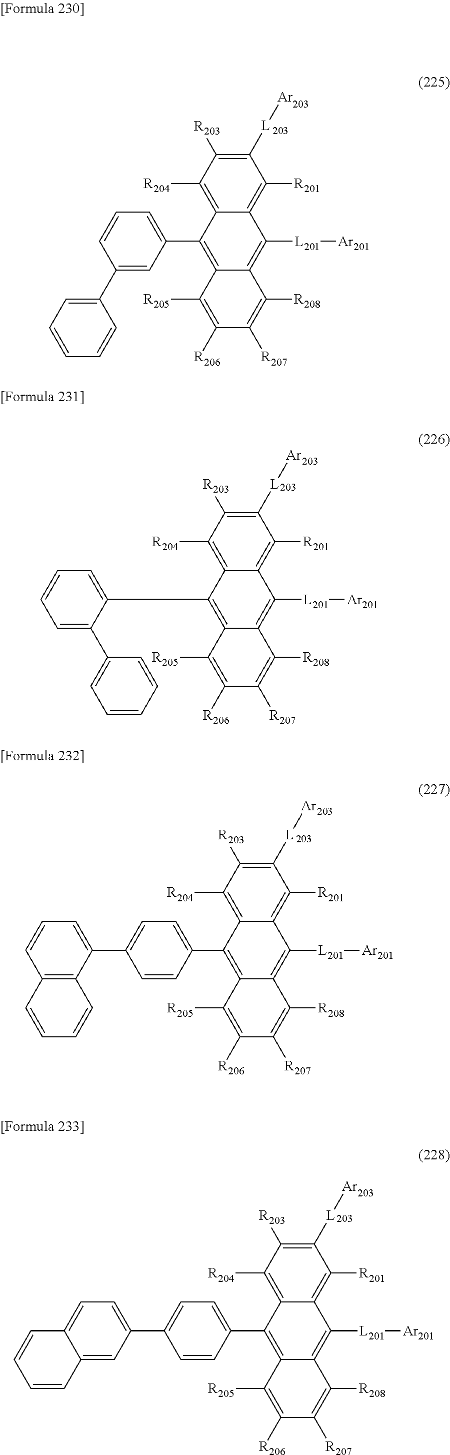

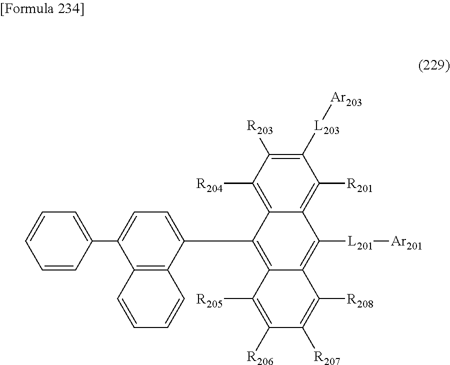

In formulae (221), (222), (223), (224), (225), (226), (227), (228), and (229),

R₂₀₁ and R₂₀₃ to R₂₀₈ each independently represent the same as R₂₀₁ and R₂₀₃ to R₂₀₈ in formula (2);

L₂₀₁ and Ar₂₀₁ represent the same as L₂₀₁ and Ar₂₀₁, respectively, in formula (2);

L₂₀₃ represents the same as L₂₀₁ in formula (2);

L₂₀₃ and L₂₀₁ are mutually the same or different;

Ar₂₀₃ represents the same as Ar₂₀₁ in formula (2); and

Ar₂₀₃ and Ar₂₀₁ are mutually the same or different.

It is also preferred that the third compound represented by formula (2) be a compound represented by formula (241), (242), (243), (244), (245), (246), (247), (248), or (249) below.

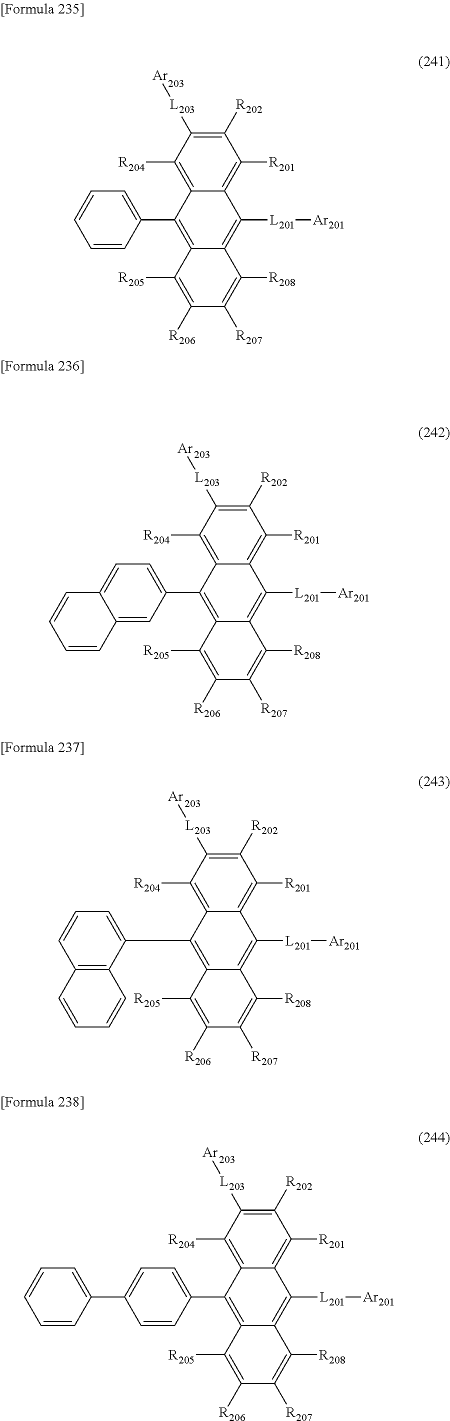

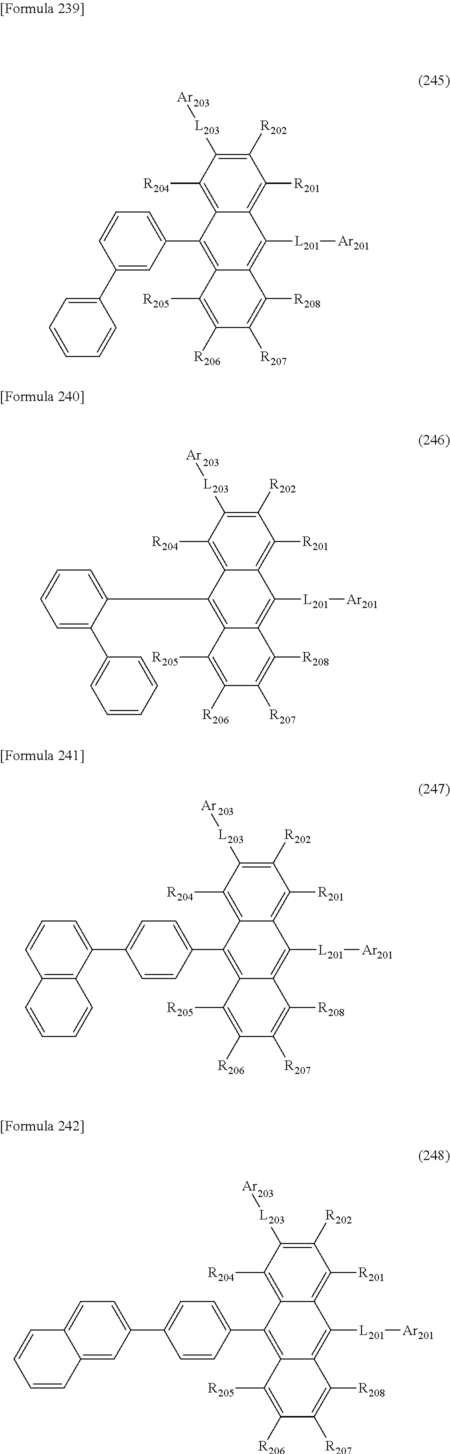

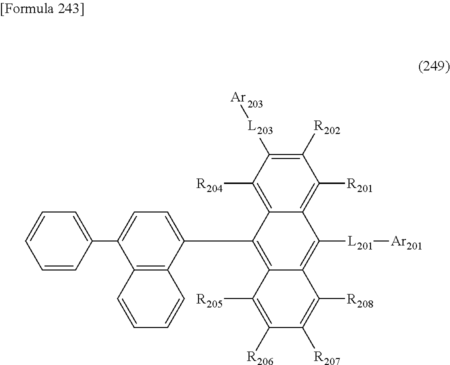

In formulae (241), (242), (243), (244), (245), (246), (247), (248), and (249),

R₂₀₁, R₂₀₂ and R₂₀₄ to R₂₀₈ each independently represent the same as R₂₀₁, R₂₀₂ and R₂₀₄ to R₂₀₈ in formula (2);

L₂₀₁ and Ar₂₀₁ represent the same as L₂₀₁ and Ar₂₀₁, respectively, in formula (2);

L₂₀₃ represents the same as L₂₀₁ in formula (2);

L₂₀₃ and L₂₀₁ are mutually the same or different;

Ar₂₀₃ represents the same as Ar₂₀₁ in formula (2); and

Ar₂₀₃ and Ar₂₀₁ are mutually the same or different.

Preferably, in the third compound represented by formula (2), R₂₀₁ to R₂₀₈ not being the group represented by formula (21) each independently represent: a hydrogen atom; a substituted or unsubstituted alkyl group having 1 to 50 carbon atoms; a substituted or unsubstituted cycloalkyl group having 3 to 50 ring carbon atoms; or a group represented by —Si(R₉₀₁)(R₉₀₂)(R₉₀₃).

Preferably, L₁₀₁ is: a single bond; or an unsubstituted arylene group having 6 to 22 ring carbon atoms; and Ar₁₀₁ is a substituted or unsubstituted aryl group having 6 to 22 ring carbon atoms.

In the organic EL device according to this exemplary embodiment, it is preferred that R₂₀₁ to R₂₀₈ in the third compound represented by formula (2) each independently represent: a hydrogen atom; a substituted or unsubstituted alkyl group having 1 to 50 carbon atoms; a substituted or unsubstituted cycloalkyl group having 3 to 50 ring carbon atoms; or a group represented by —Si(R₉₀)(R₉₀₂)(R₉₀₃).

In the organic EL device according to this exemplary embodiment, it is preferred that R₂₀₁ to R₂₀₈ in the third compound represented by formula (2) be hydrogen atoms.

In the third compound, it is preferred that all groups described as “substituted or unsubstituted” be “unsubstituted” groups.

### Production Method of Third Compound

The third compound can be produced by methods known in the related art. Alternatively, the third compound can be produced based on a method known in the related art by selecting known alternative reaction(s) and materials according to the final product.

### Specific Examples of Third Compounds

Specific examples of third compounds include, for instance, the following compounds, although the invention is not limited to these specific examples of third compounds. If the third compound is a compound represented by formula (1), specific examples of third compounds also include the compounds listed as specific examples of first compounds.

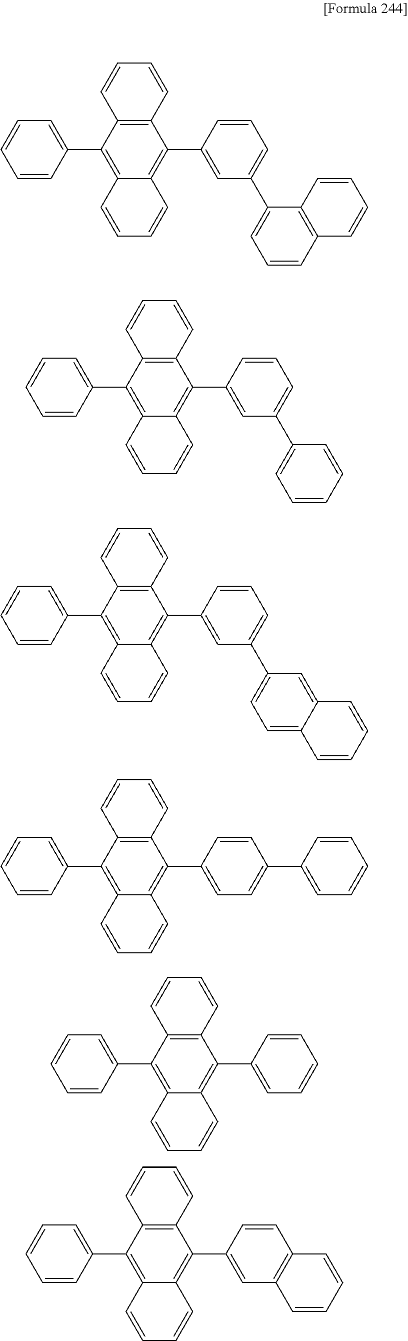

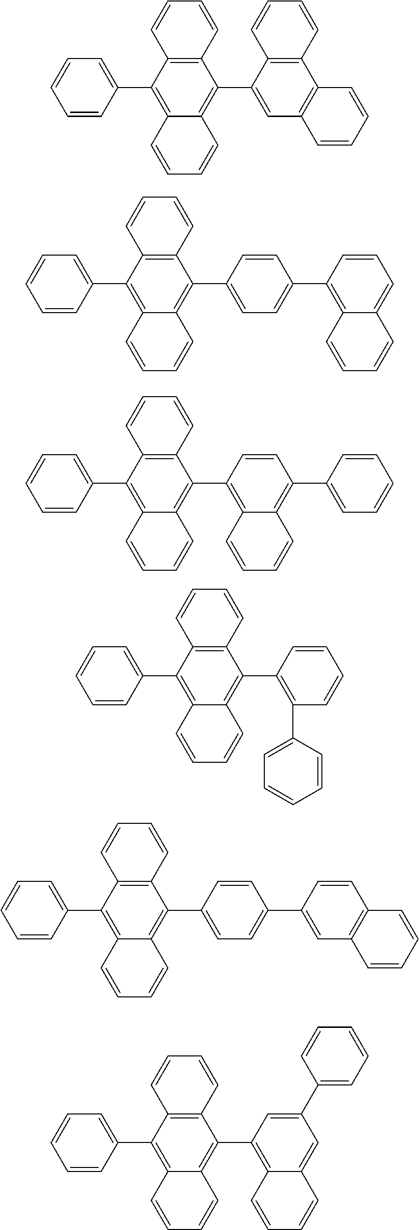

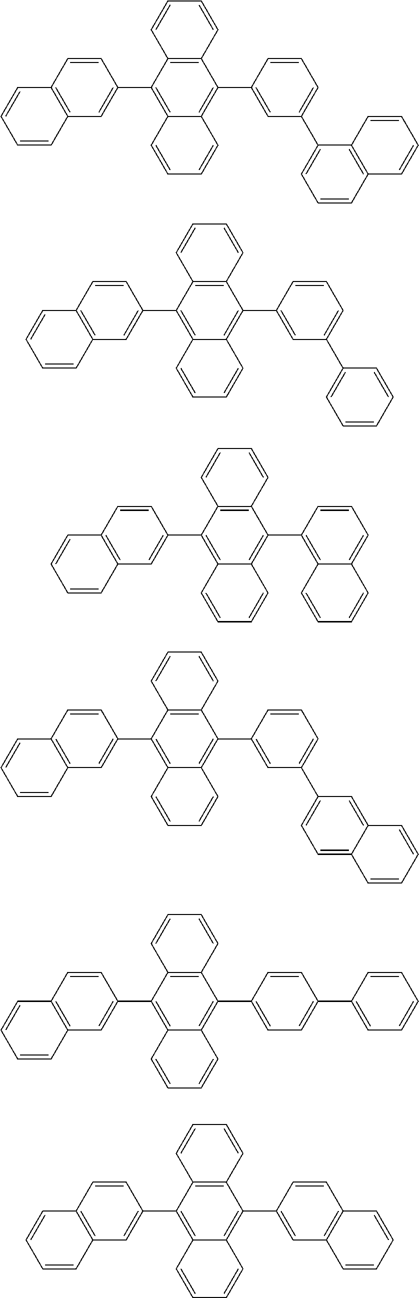

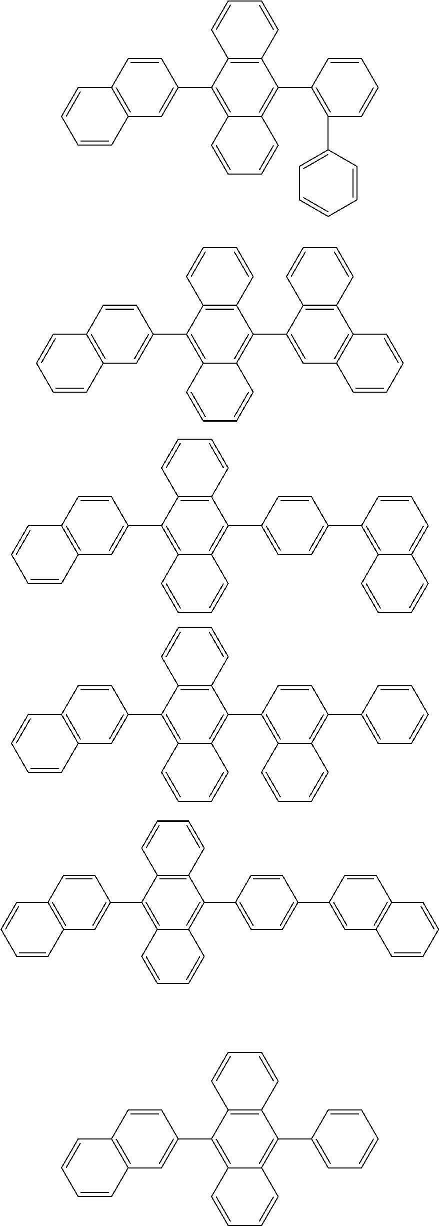

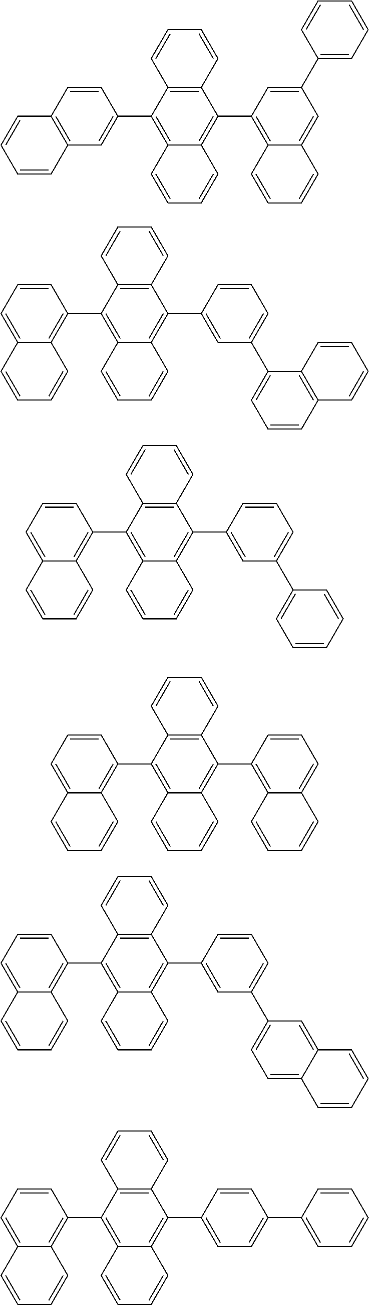

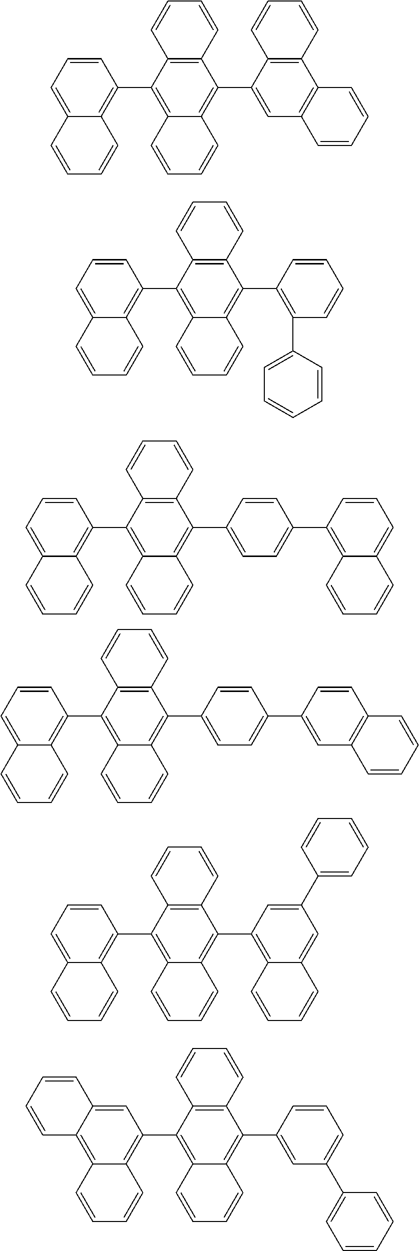

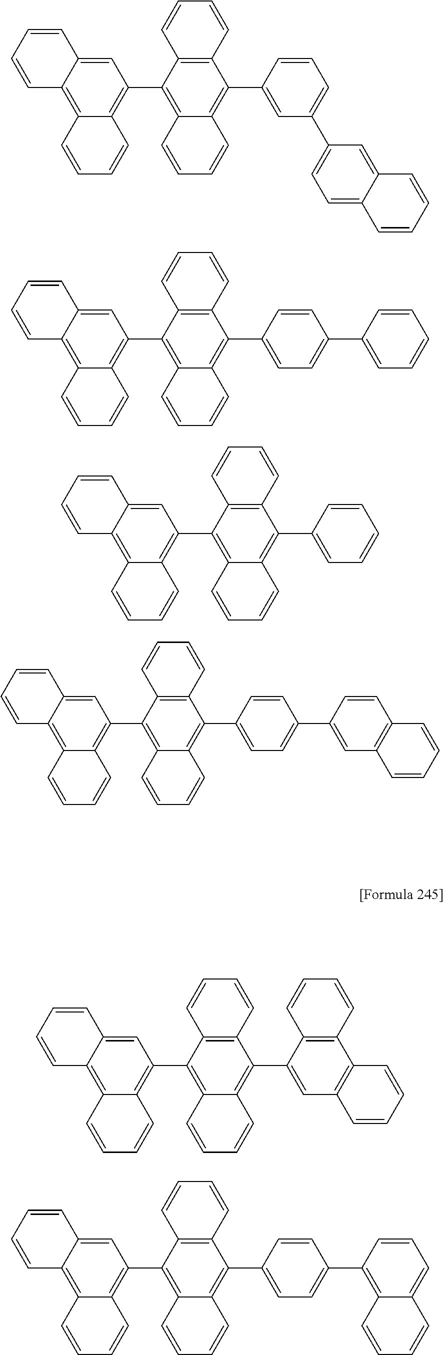

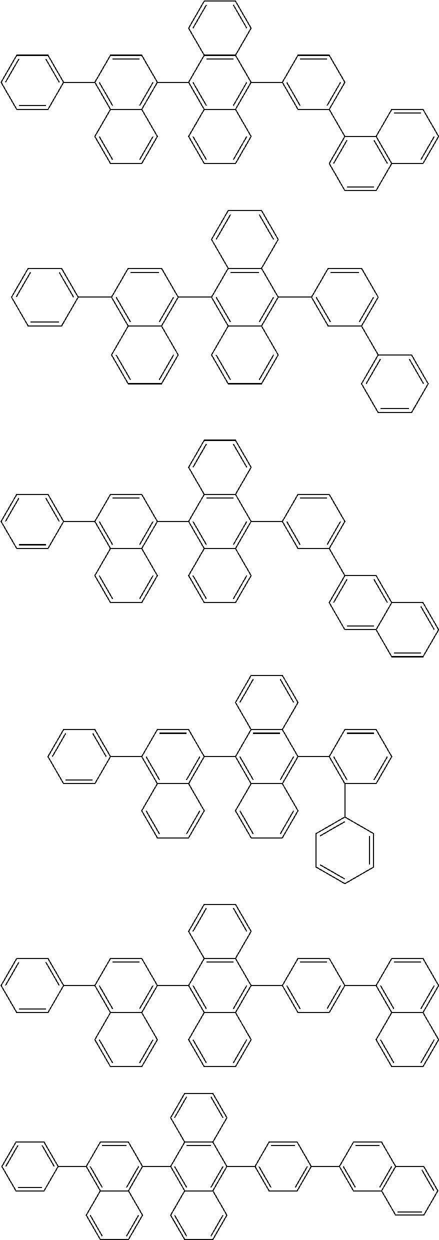

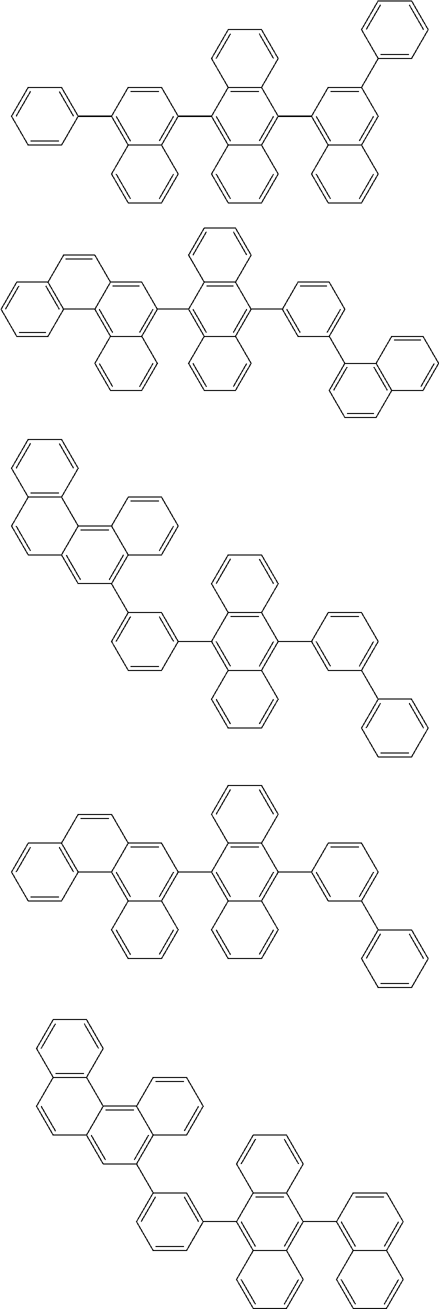

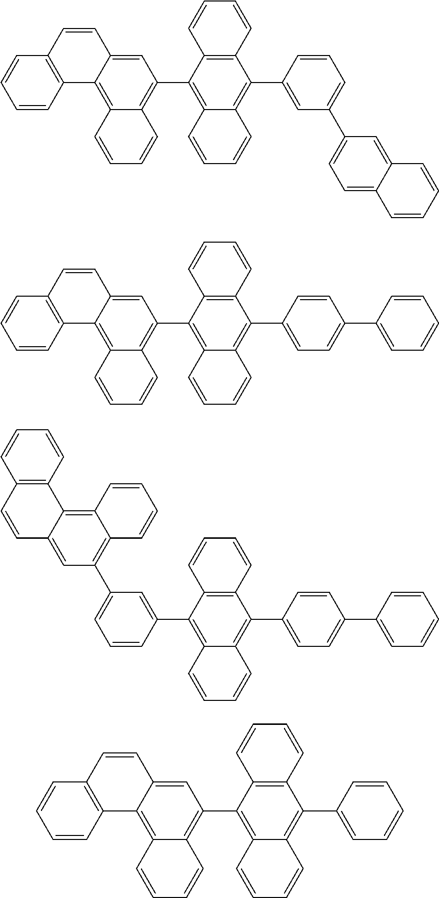

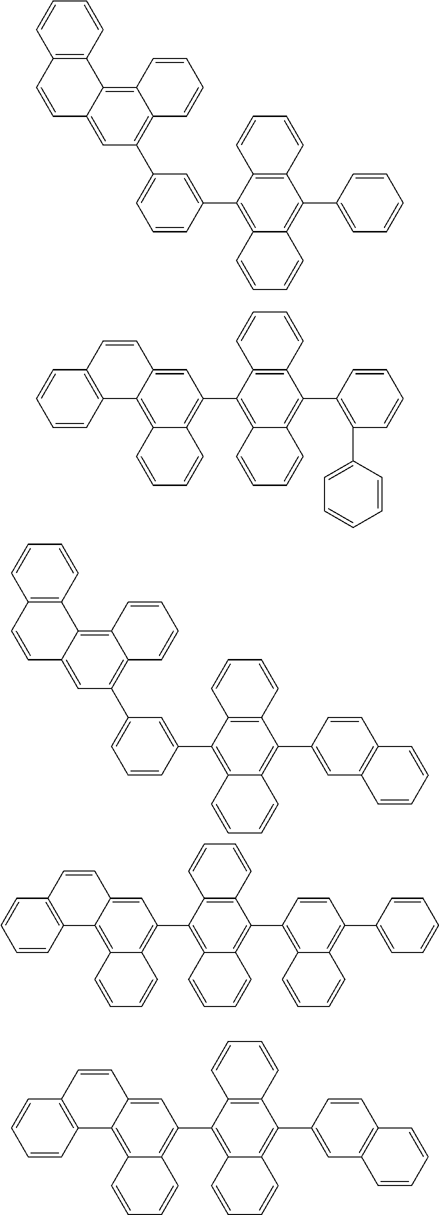

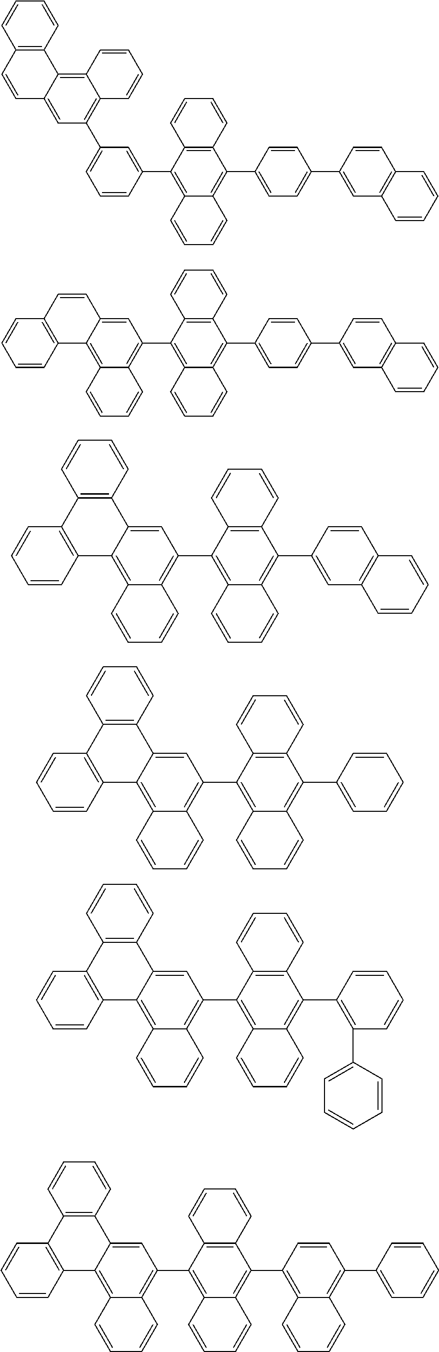

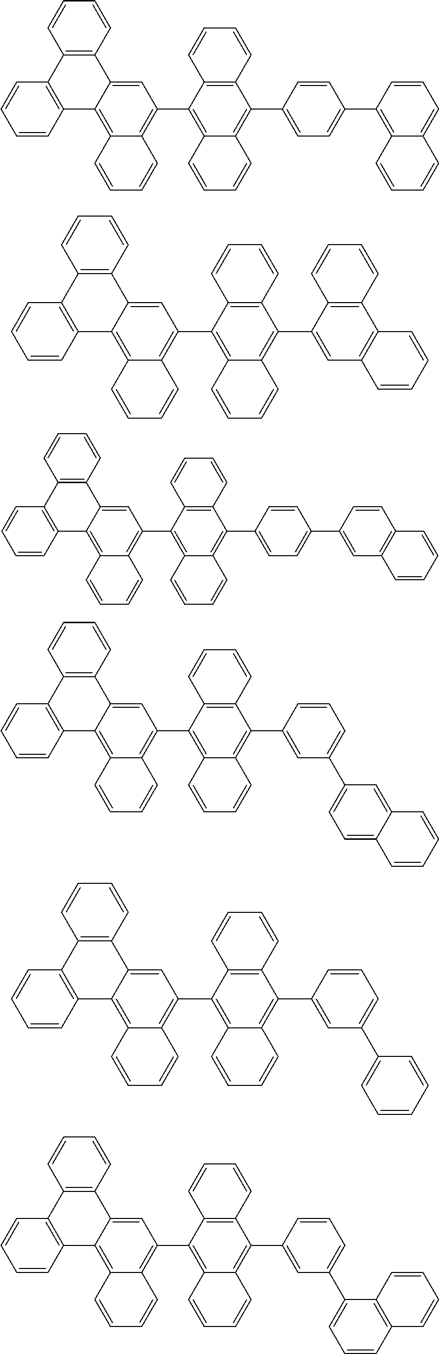

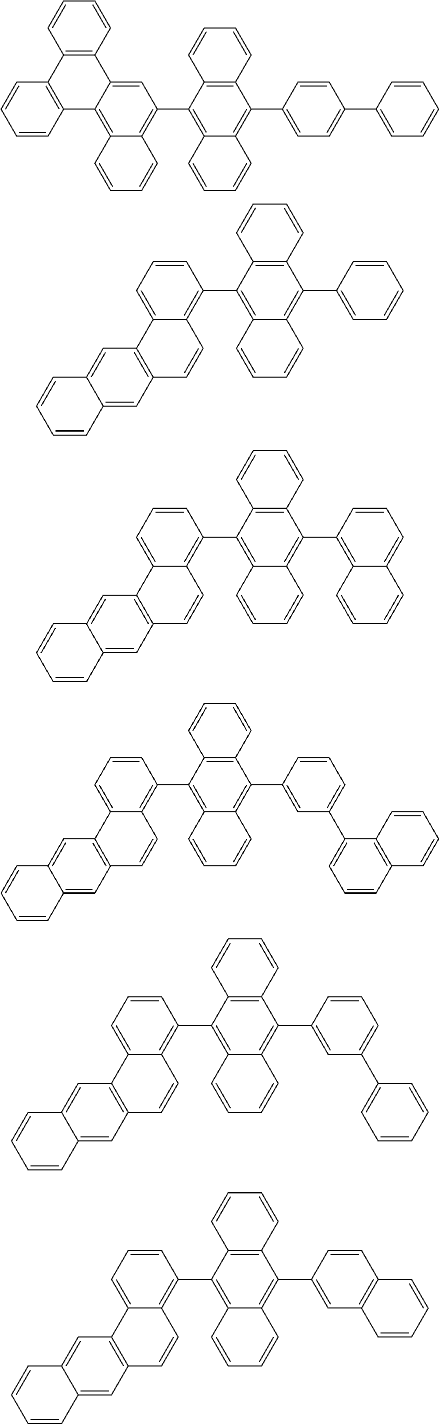

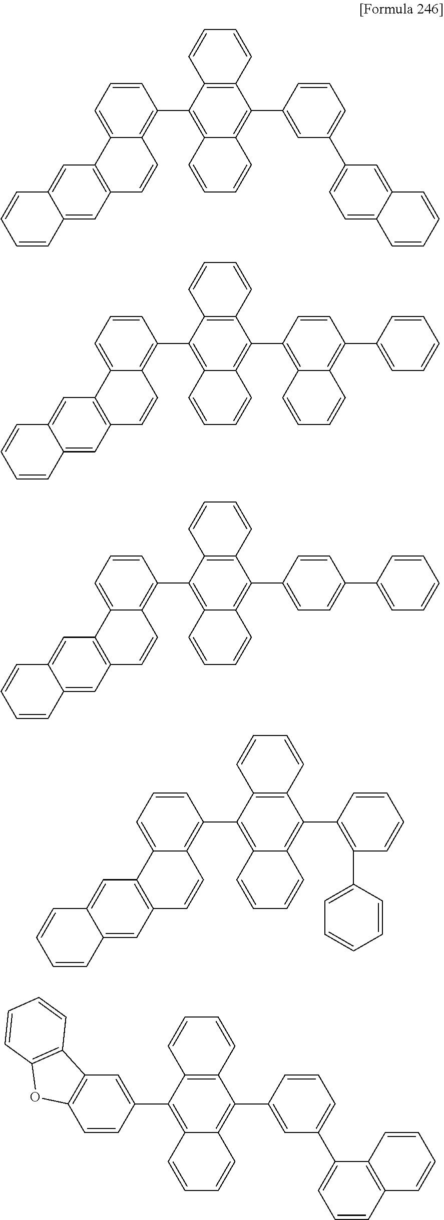

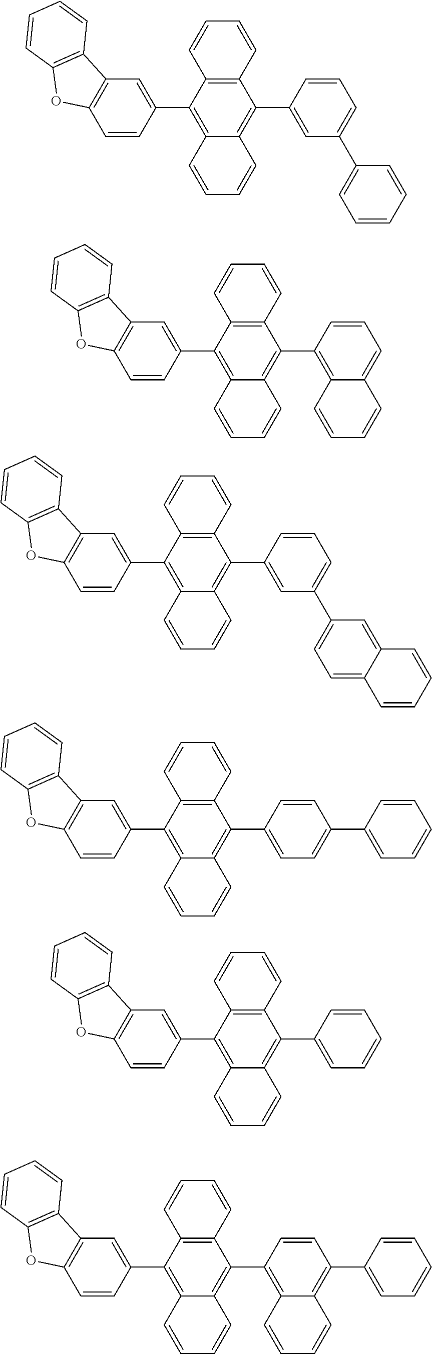

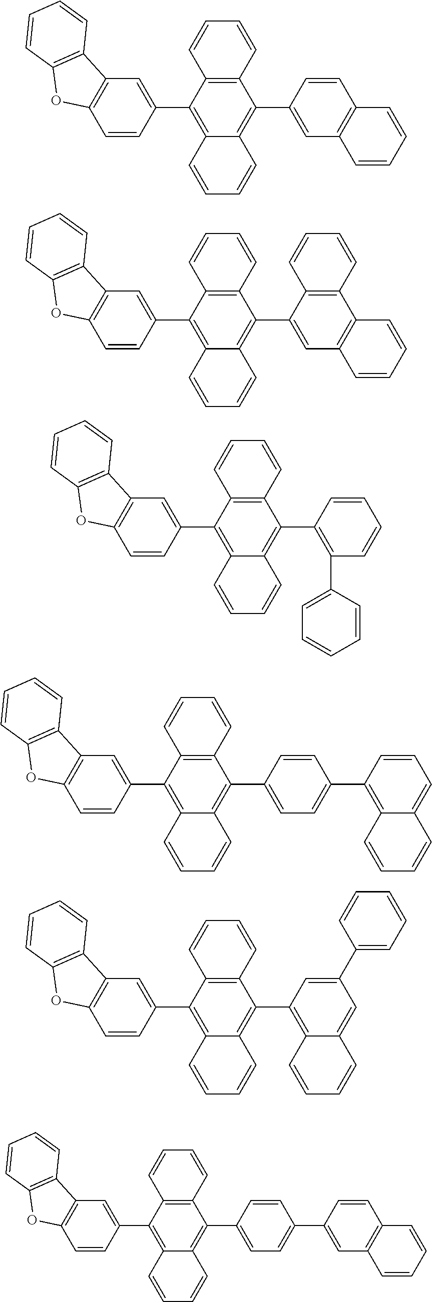

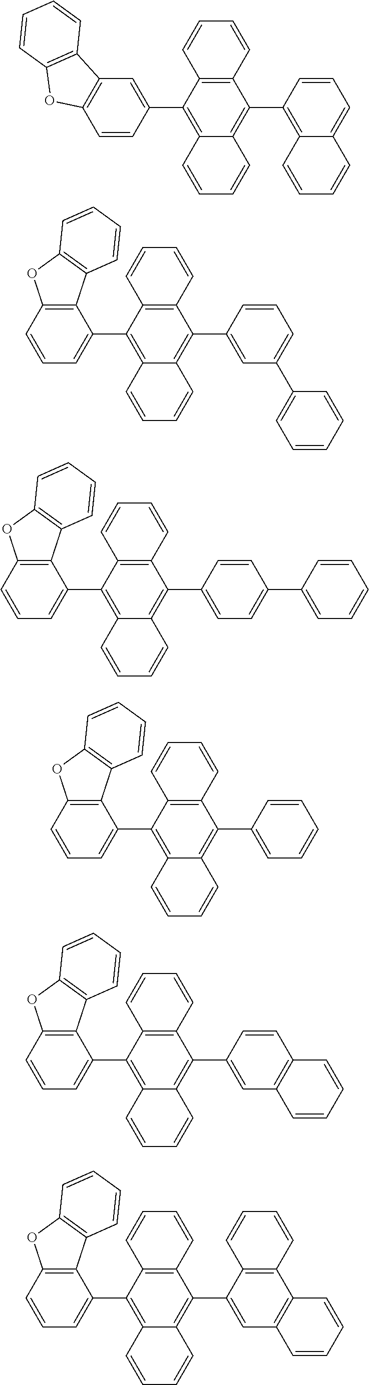

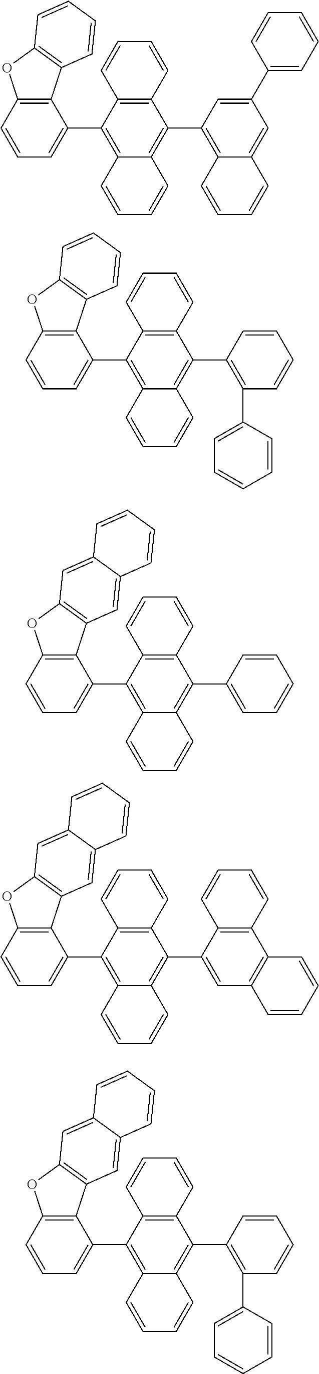

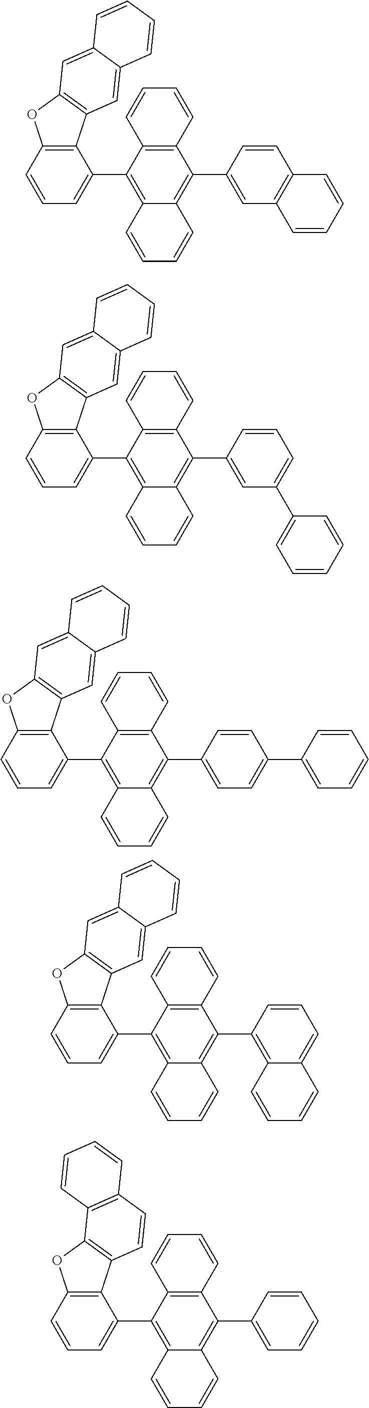

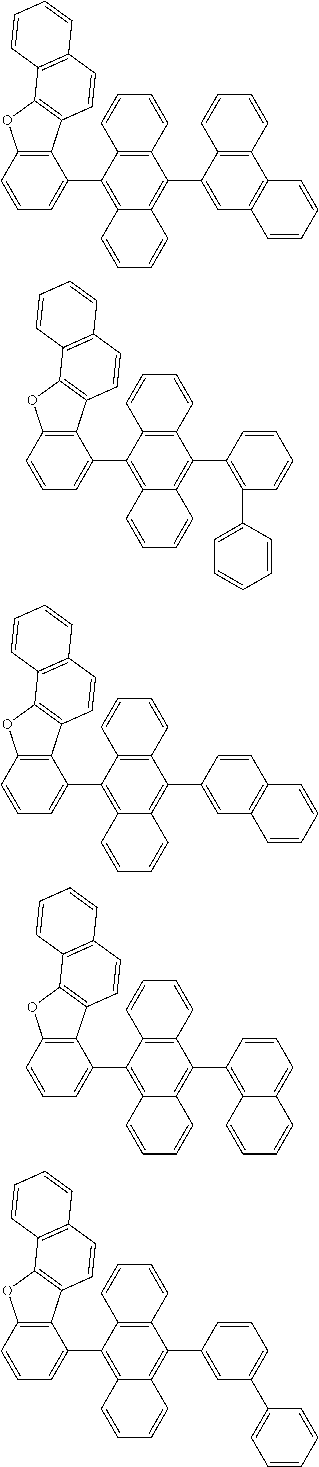

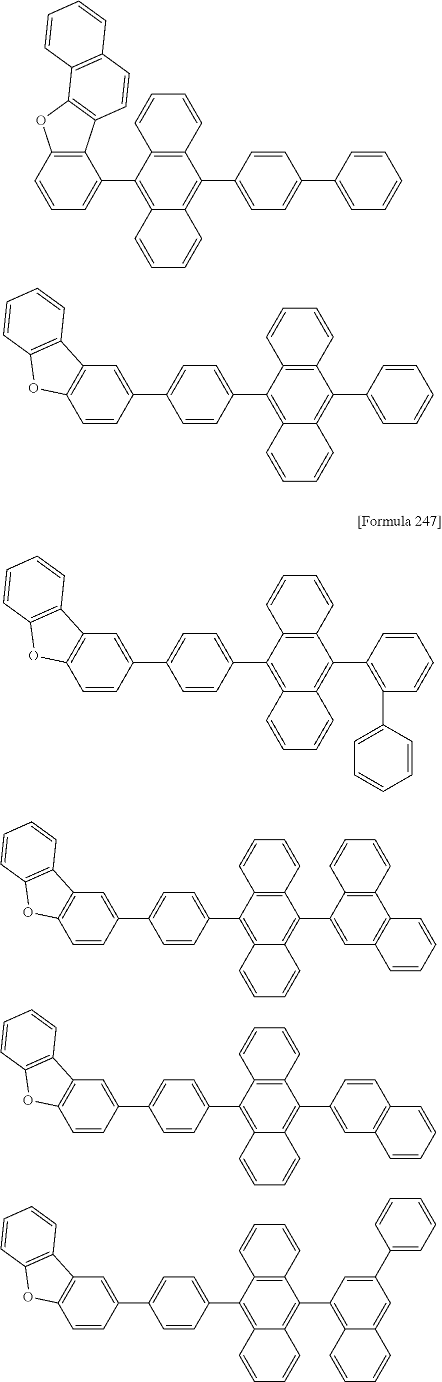

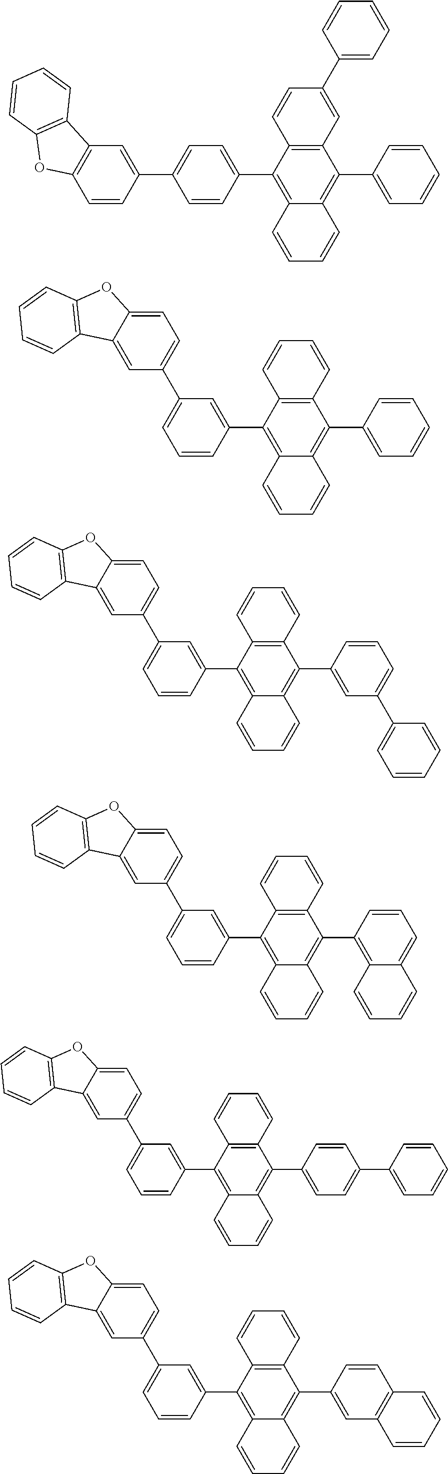 [SMILES: c1ccc(-c2ccc3c(-c4ccc(-c5ccc6oc7ccccc7c6c5)cc4)c4ccccc4c(-c4ccccc4)c3c2)cc1 ; c1ccc(-c2c3ccccc3c(-c3cccc(-c4ccc5oc6ccccc6c5c4)c3)c3ccccc23)cc1 ; c1ccc(-c2cccc(-c3c4ccccc4c(-c4cccc(-c5ccc6oc7ccccc7c6c5)c4)c4ccccc34)c2)cc1 ; c1cc(-c2ccc3oc4ccccc4c3c2)cc(-c2c3ccccc3c(-c3cccc4ccccc34)c3ccccc23)c1 ; c1ccc(-c2ccc(-c3c4ccccc4c(-c4cccc(-c5ccc6oc7ccccc7c6c5)c4)c4ccccc34)cc2)cc1 ; c1cc(-c2ccc3oc4ccccc4c3c2)cc(-c2c3ccccc3c(-c3ccc4ccccc4c3)c3ccccc23)c1]

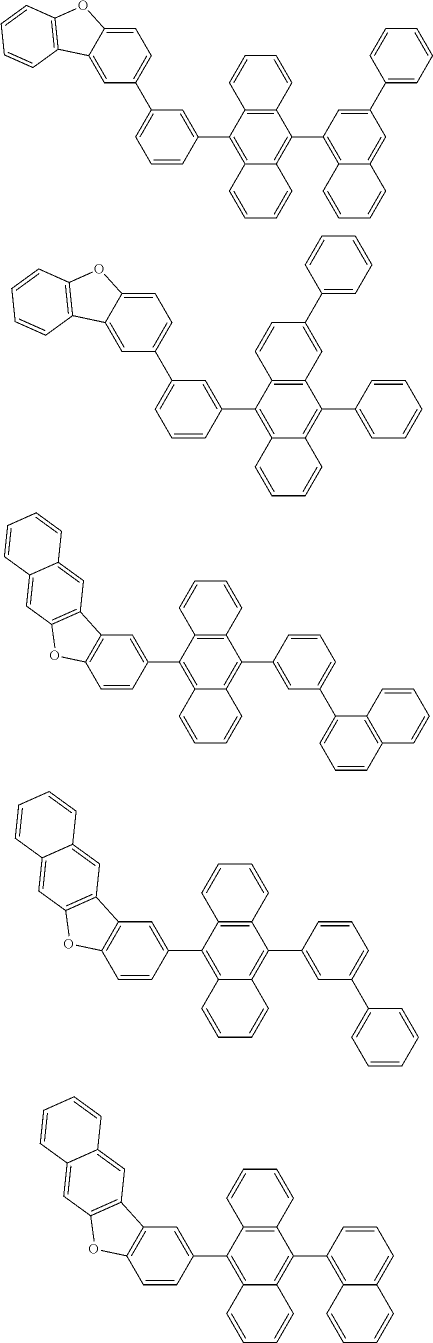

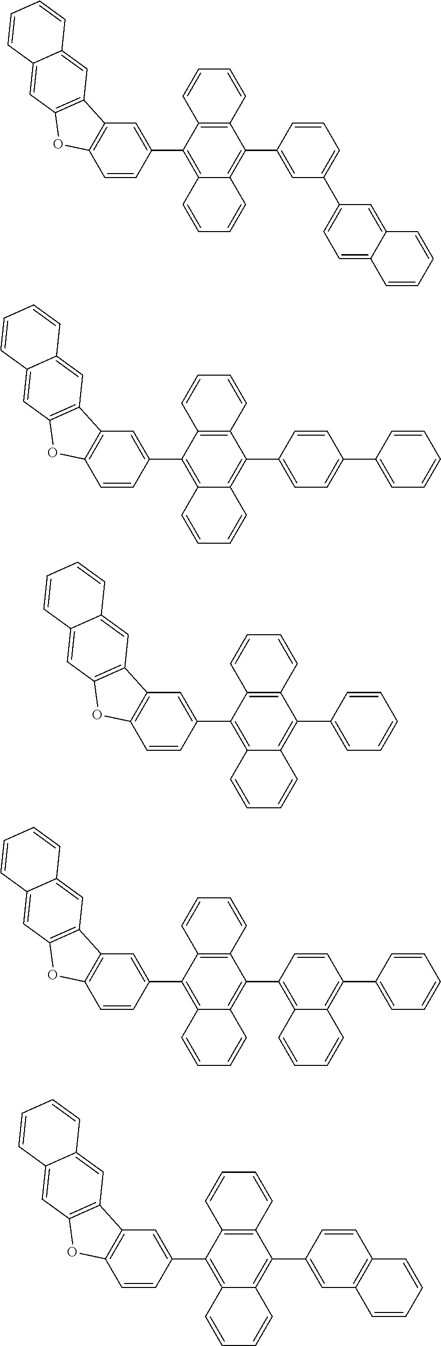 [SMILES: c1cc(-c2ccc3ccccc3c2)cc(-c2c3ccccc3c(-c3ccc4oc5cc6ccccc6cc5c4c3)c3ccccc23)c1 ; c1ccc(-c2ccc(-c3c4ccccc4c(-c4ccc5oc6cc7ccccc7cc6c5c4)c4ccccc34)cc2)cc1 ; c1ccc(-c2c3ccccc3c(-c3ccc4oc5cc6ccccc6cc5c4c3)c3ccccc23)cc1 ; c1ccc(-c2ccc(-c3c4ccccc4c(-c4ccc5oc6cc7ccccc7cc6c5c4)c4ccccc34)c3ccccc23)cc1 ; c1ccc2cc(-c3c4ccccc4c(-c4ccc5oc6cc7ccccc7cc6c5c4)c4ccccc34)ccc2c1]

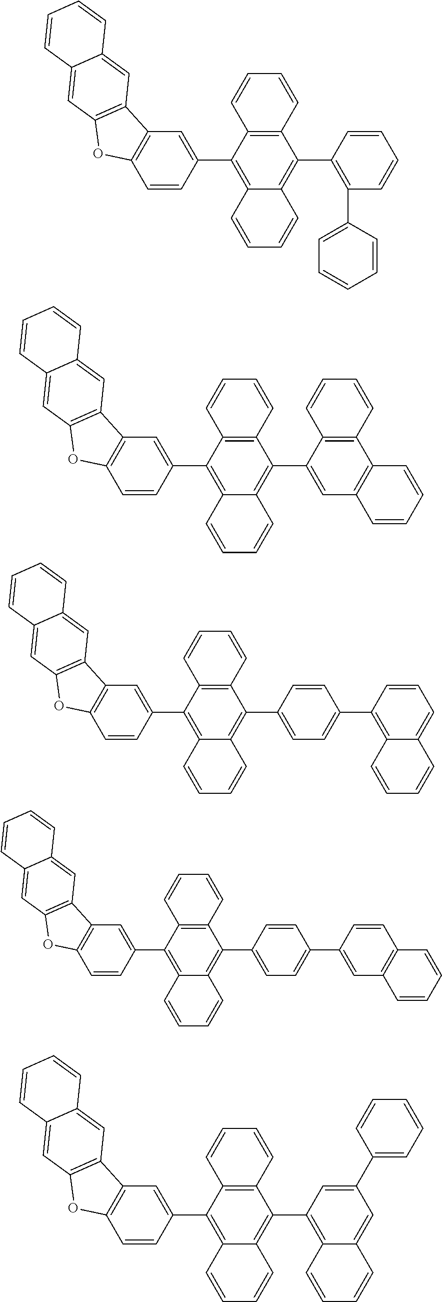 [SMILES: c1ccc(-c2ccccc2-c2c3ccccc3c(-c3ccc4oc5cc6ccccc6cc5c4c3)c3ccccc23)cc1 ; c1ccc2cc3c(cc2c1)oc1ccc(-c2c4ccccc4c(-c4cc5ccccc5c5ccccc45)c4ccccc24)cc13 ; c1ccc2cc3c(cc2c1)oc1ccc(-c2c4ccccc4c(-c4ccc(-c5cccc6ccccc56)cc4)c4ccccc24)cc13 ; c1ccc2cc(-c3ccc(-c4c5ccccc5c(-c5ccc6oc7cc8ccccc8cc7c6c5)c5ccccc45)cc3)ccc2c1 ; c1ccc(-c2cc(-c3c4ccccc4c(-c4ccc5oc6cc7ccccc7cc6c5c4)c4ccccc34)c3ccccc3c2)cc1]

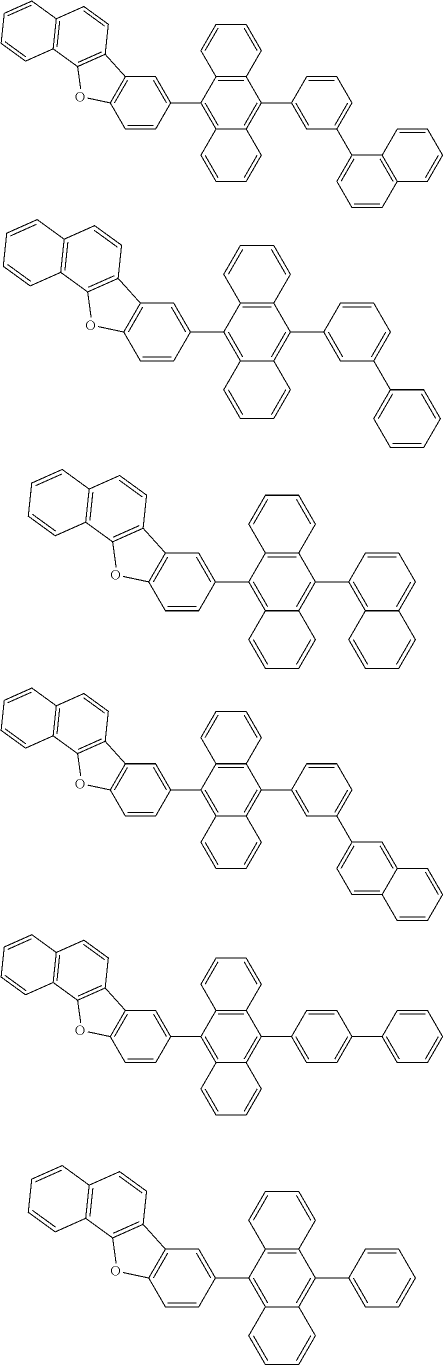 [SMILES: c1cc(-c2cccc3ccccc23)cc(-c2c3ccccc3c(-c3ccc4oc5c6ccccc6ccc5c4c3)c3ccccc23)c1 ; c1ccc(-c2cccc(-c3c4ccccc4c(-c4ccc5oc6c7ccccc7ccc6c5c4)c4ccccc34)c2)cc1 ; c1ccc2c(-c3c4ccccc4c(-c4ccc5oc6c7ccccc7ccc6c5c4)c4ccccc34)cccc2c1 ; c1cc(-c2ccc3ccccc3c2)cc(-c2c3ccccc3c(-c3ccc4oc5c6ccccc6ccc5c4c3)c3ccccc23)c1 ; c1ccc(-c2ccc(-c3c4ccccc4c(-c4ccc5oc6c7ccccc7ccc6c5c4)c4ccccc34)cc2)cc1 ; c1ccc(-c2c3ccccc3c(-c3ccc4oc5c6ccccc6ccc5c4c3)c3ccccc23)cc1]

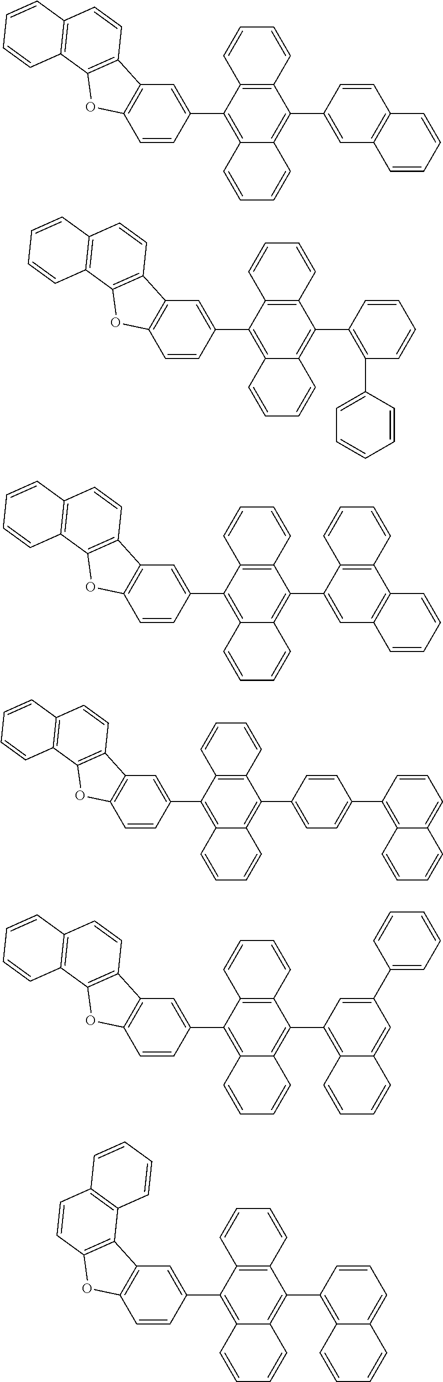

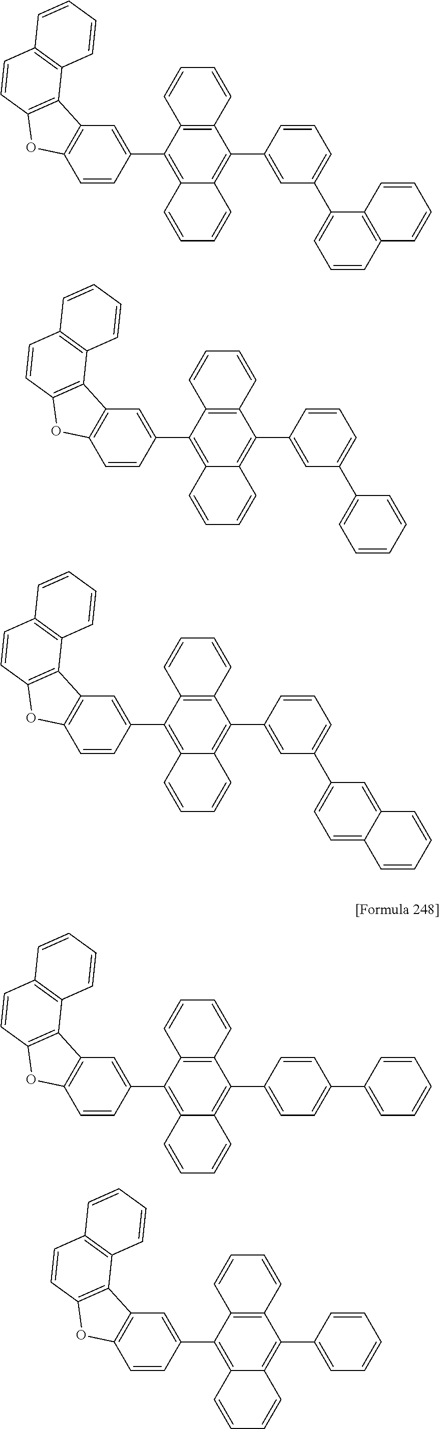 [SMILES: c1cc(-c2cccc3ccccc23)cc(-c2c3ccccc3c(-c3ccc4oc5ccc6ccccc6c5c4c3)c3ccccc23)c1 ; c1ccc(-c2cccc(-c3c4ccccc4c(-c4ccc5oc6ccc7ccccc7c6c5c4)c4ccccc34)c2)cc1 ; c1cc(-c2ccc3ccccc3c2)cc(-c2c3ccccc3c(-c3ccc4oc5ccc6ccccc6c5c4c3)c3ccccc23)c1 ; c1ccc(-c2ccc(-c3c4ccccc4c(-c4ccc5oc6ccc7ccccc7c6c5c4)c4ccccc34)cc2)cc1 ; c1ccc(-c2c3ccccc3c(-c3ccc4oc5ccc6ccccc6c5c4c3)c3ccccc23)cc1]

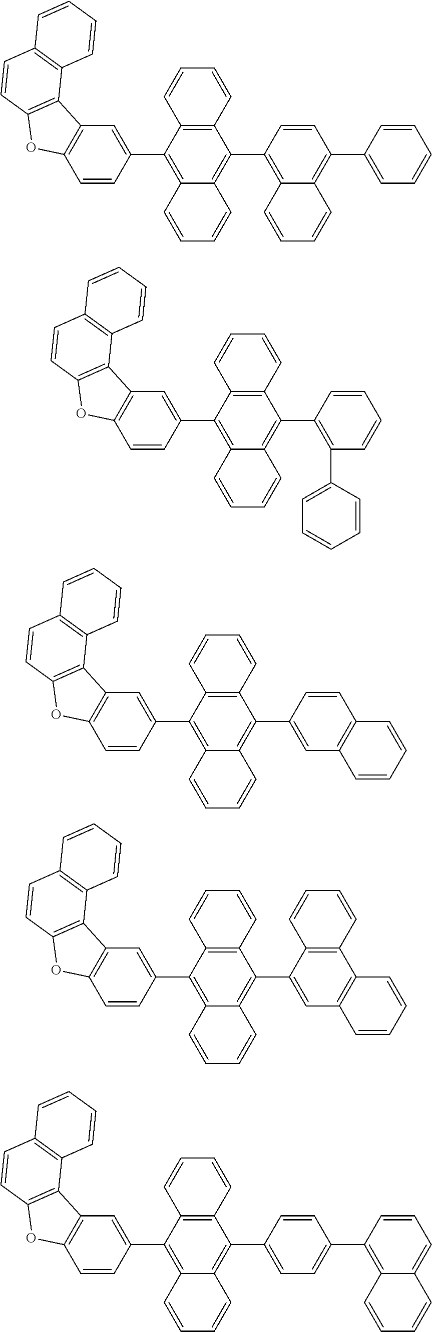 [SMILES: c1ccc(-c2ccc(-c3c4ccccc4c(-c4ccc5oc6ccc7ccccc7c6c5c4)c4ccccc34)c3ccccc23)cc1 ; c1ccc(-c2ccccc2-c2c3ccccc3c(-c3ccc4oc5ccc6ccccc6c5c4c3)c3ccccc23)cc1 ; c1ccc2cc(-c3c4ccccc4c(-c4ccc5oc6ccc7ccccc7c6c5c4)c4ccccc34)ccc2c1 ; c1ccc2c(c1)cc(-c1c3ccccc3c(-c3ccc4oc5ccc6ccccc6c5c4c3)c3ccccc13)c1ccccc12 ; c1ccc2c(-c3ccc(-c4c5ccccc5c(-c5ccc6oc7ccc8ccccc8c7c6c5)c5ccccc45)cc3)cccc2c1]

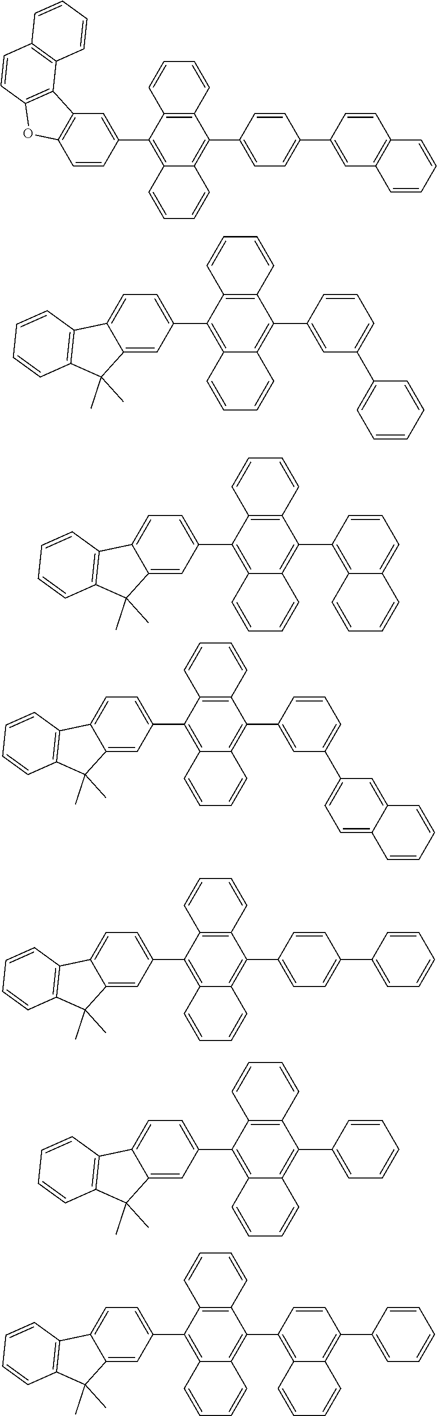

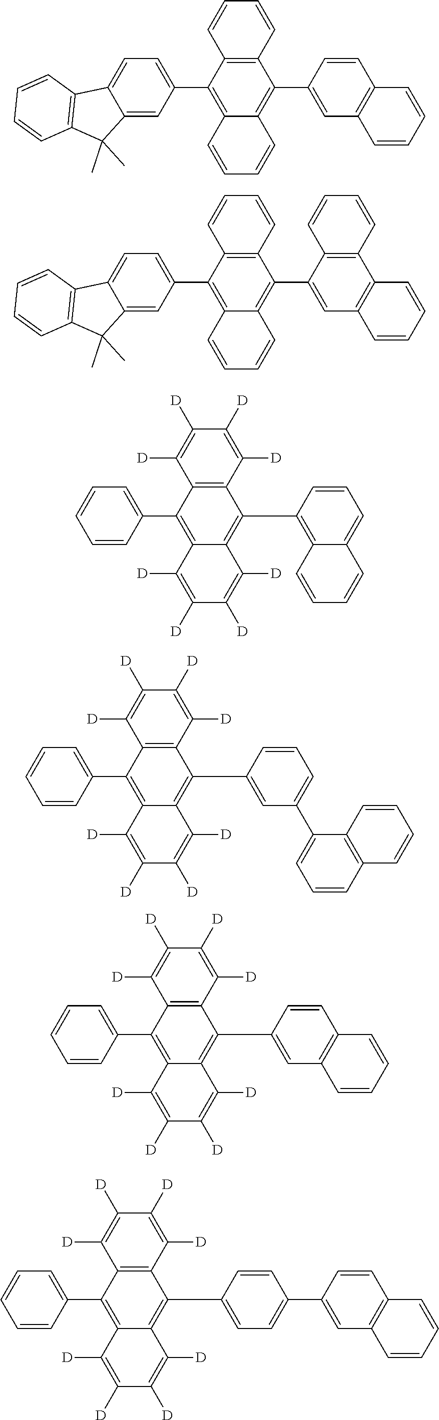

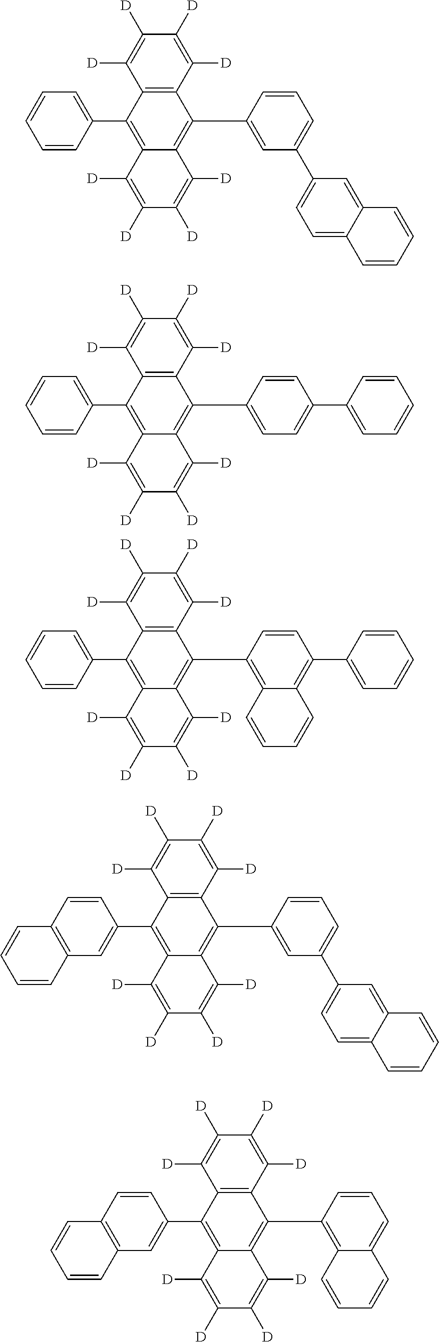

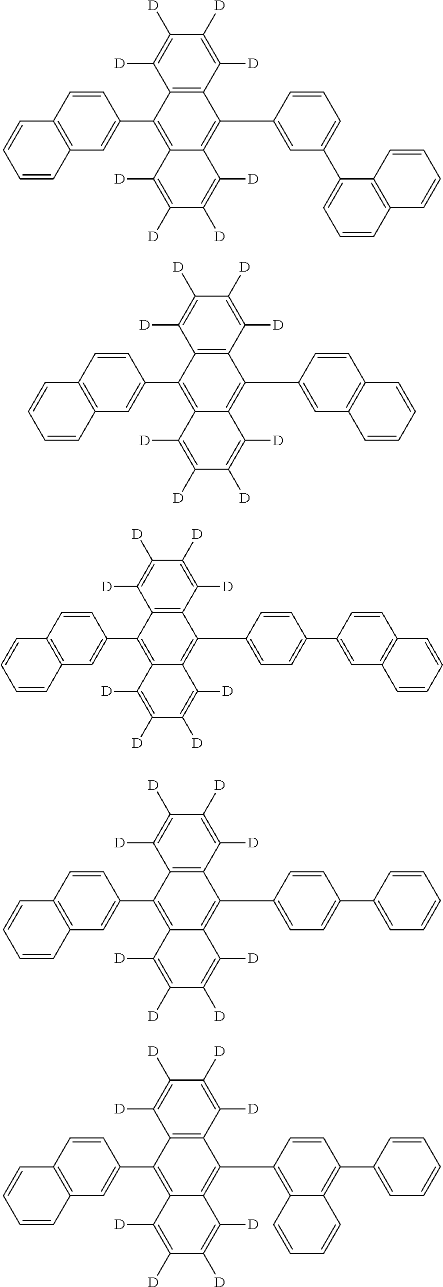

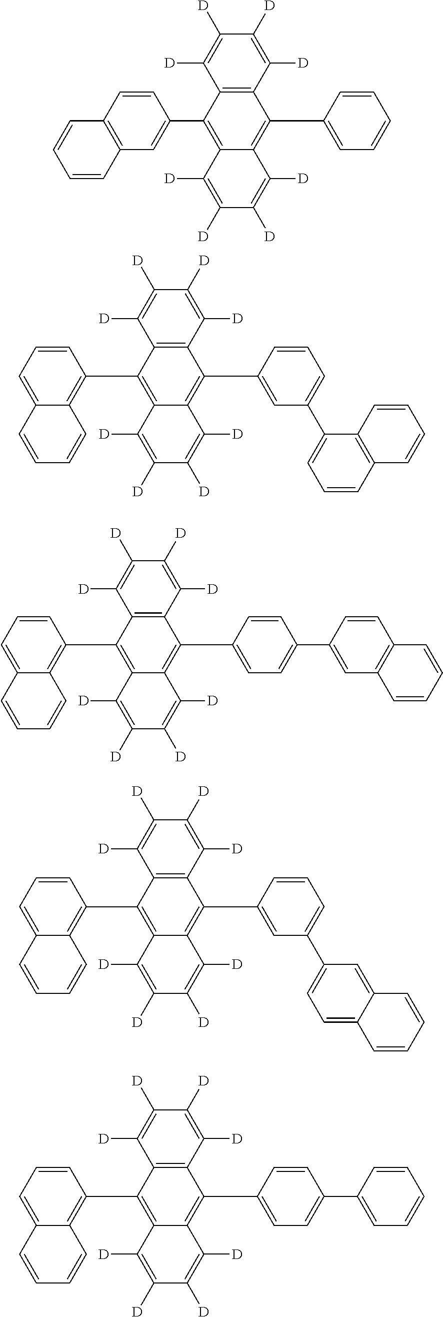

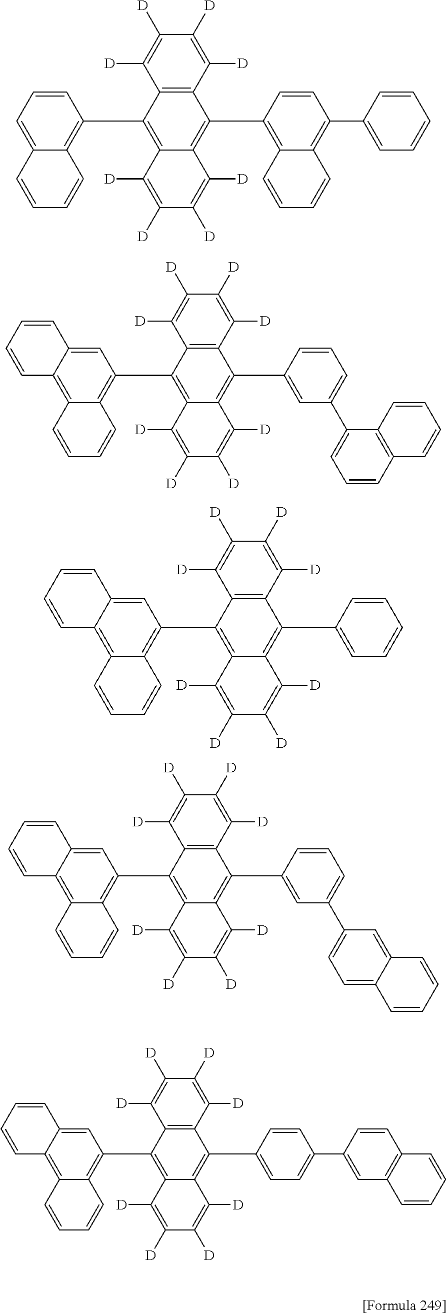

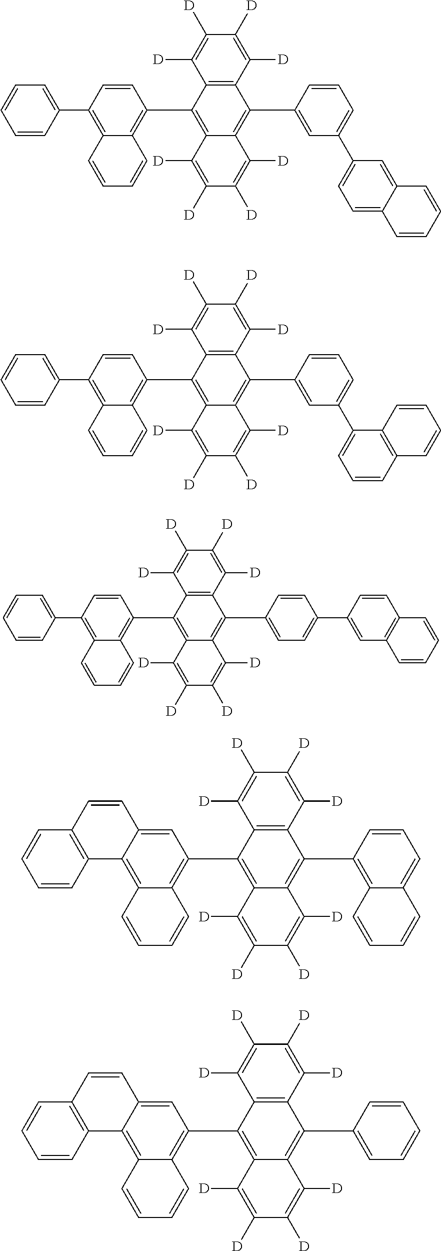

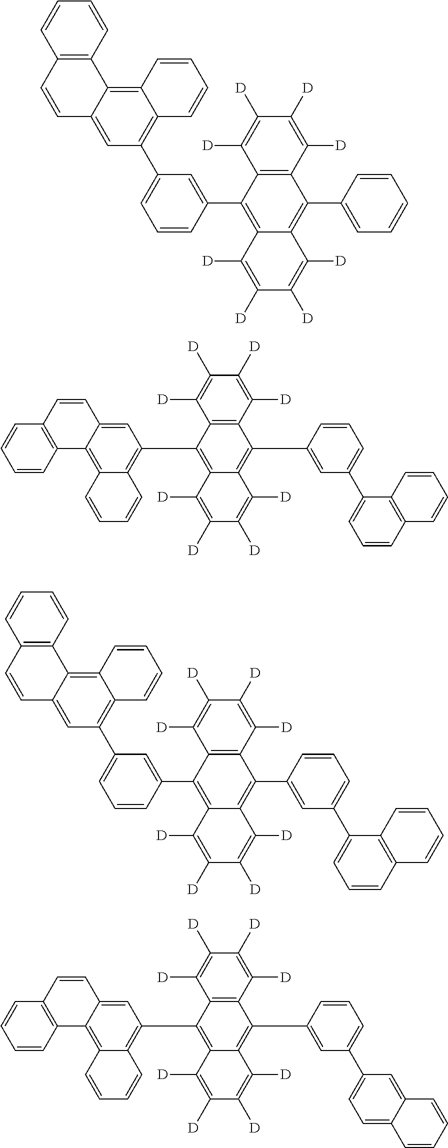

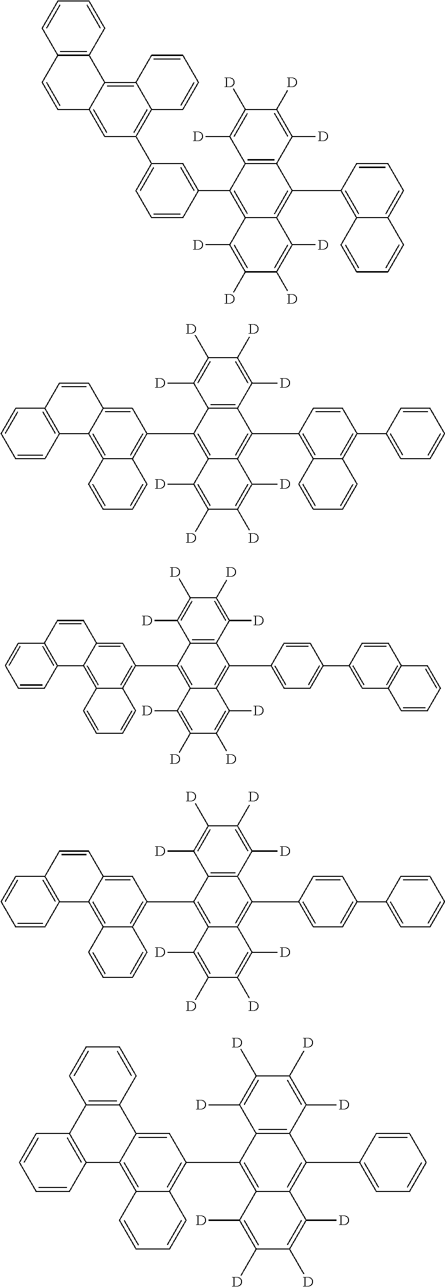

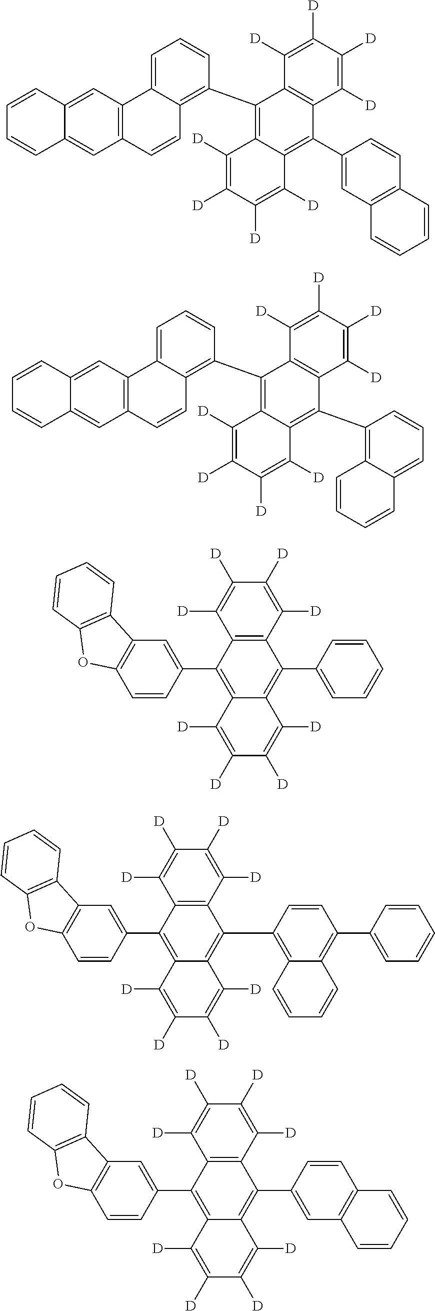

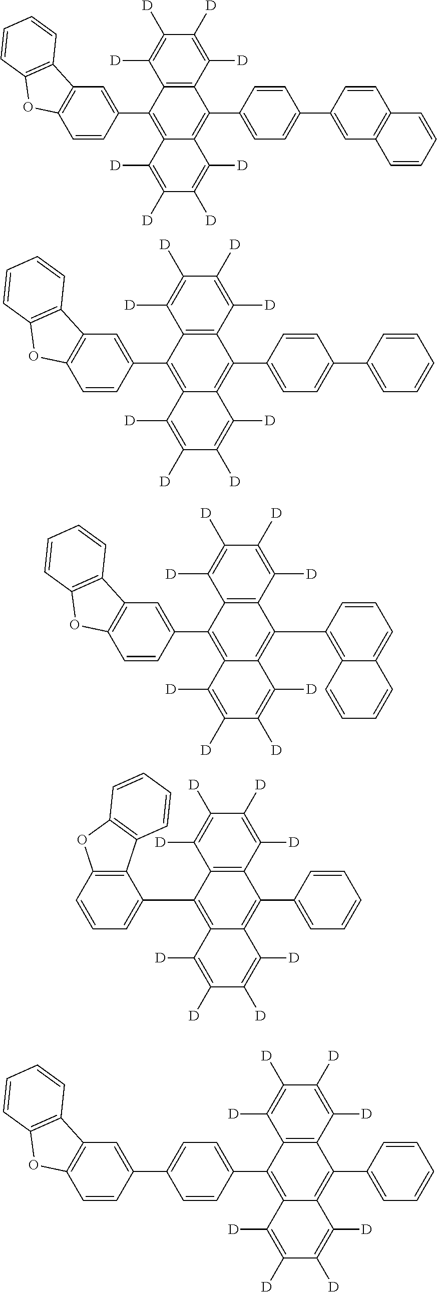

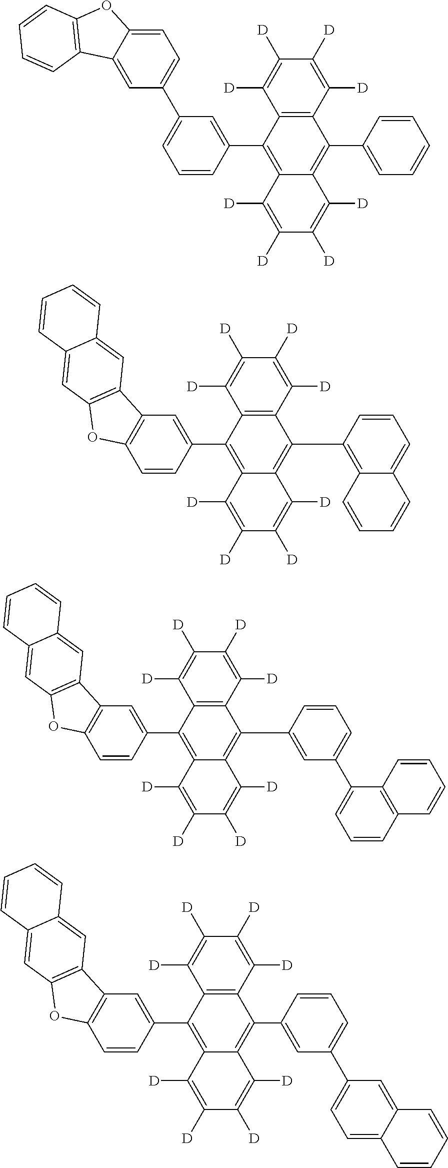 [SMILES: [2H]c1c([2H])c([2H])c2c(-c3cccc(-c4ccc5oc6ccccc6c5c4)c3)c3c([2H])c([2H])c([2H])c([2H])c3c(-c3ccccc3)c2c1[2H] ; [2H]c1c([2H])c([2H])c2c(-c3cccc4ccccc34)c3c([2H])c([2H])c([2H])c([2H])c3c(-c3ccc4oc5cc6ccccc6cc5c4c3)c2c1[2H] ; [2H]c1c([2H])c([2H])c2c(-c3ccc4oc5cc6ccccc6cc5c4c3)c3c([2H])c([2H])c([2H])c([2H])c3c(-c3cccc(-c4cccc5ccccc45)c3)c2c1[2H] ; [2H]c1c([2H])c([2H])c2c(-c3ccc4oc5cc6ccccc6cc5c4c3)c3c([2H])c([2H])c([2H])c([2H])c3c(-c3cccc(-c4ccc5ccccc5c4)c3)c2c1[2H]]

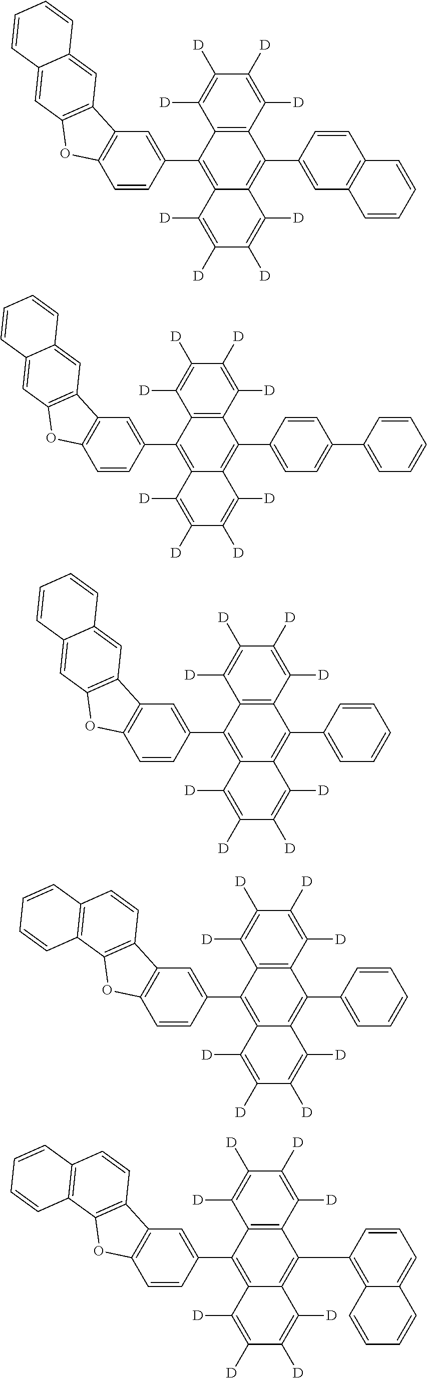

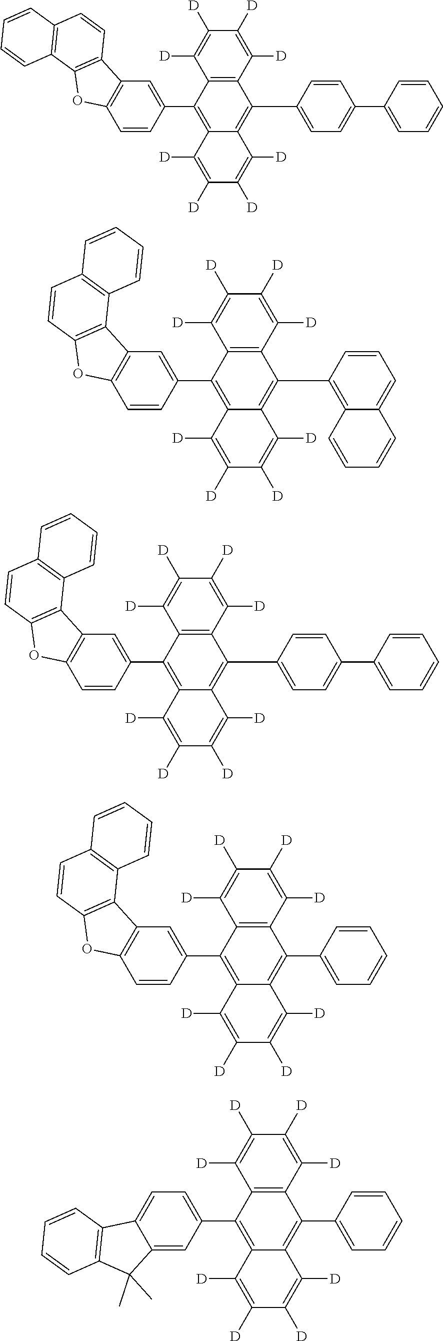

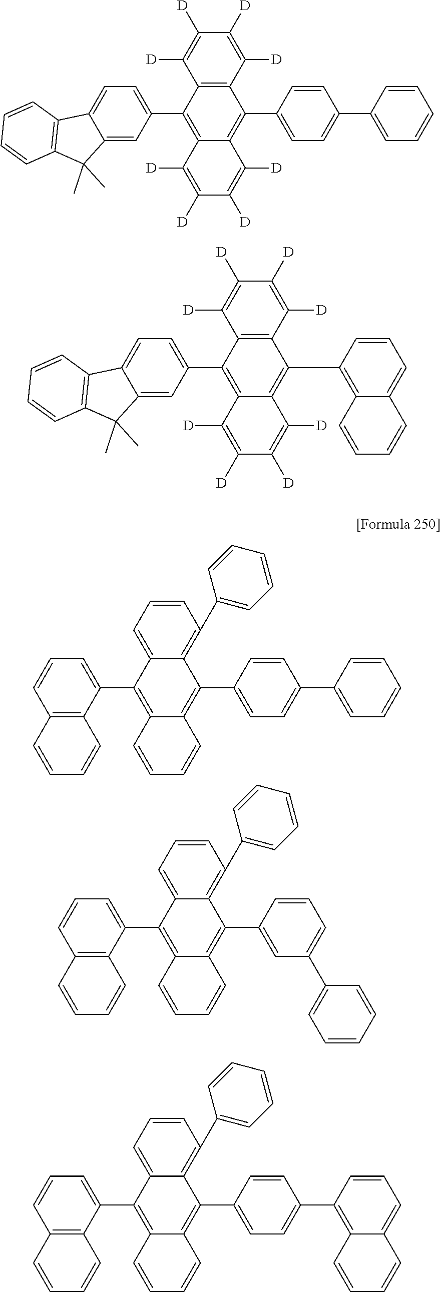

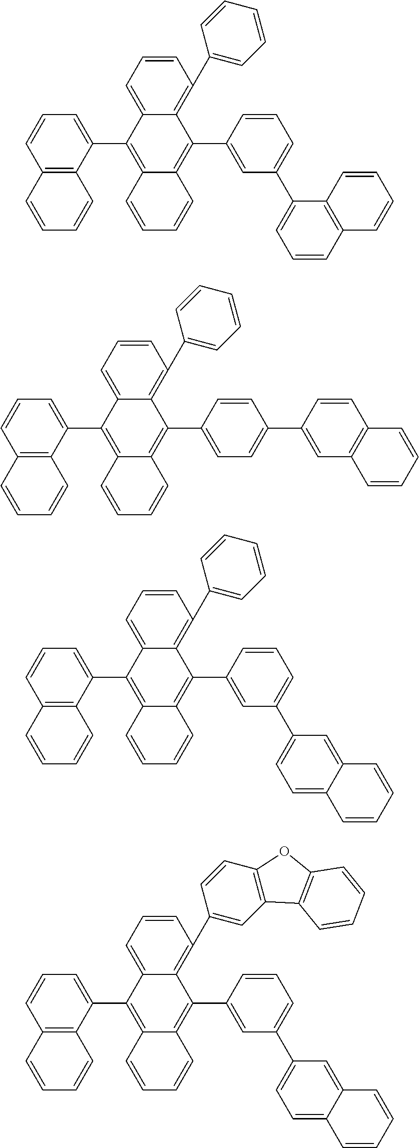

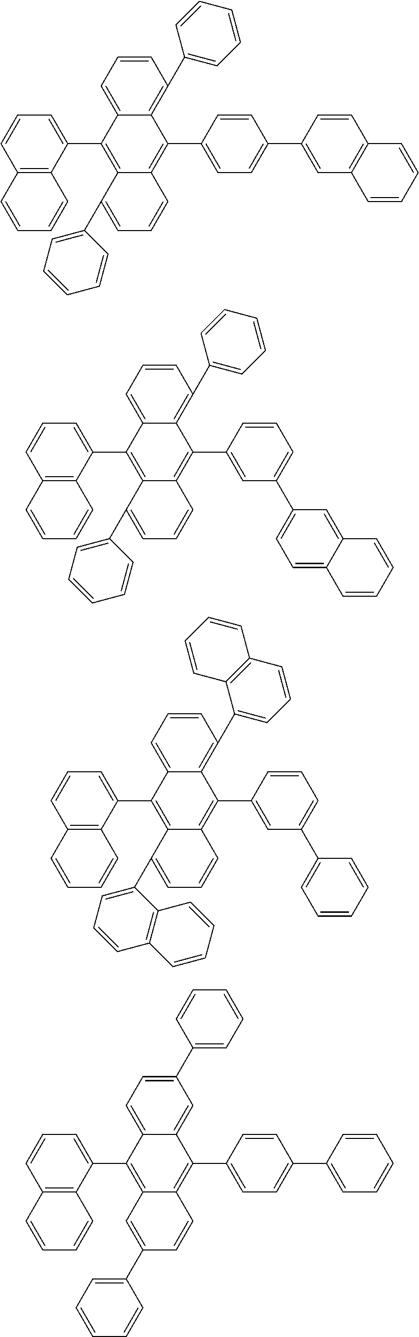

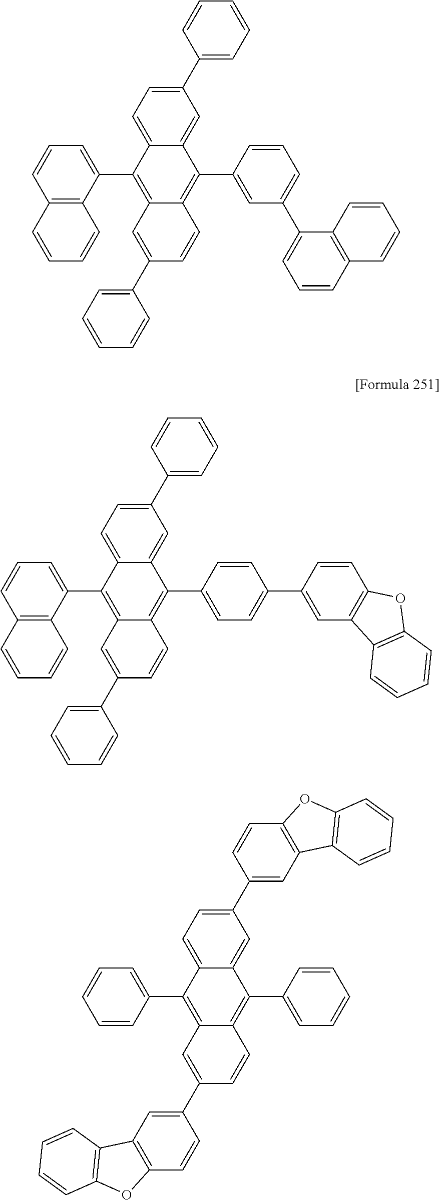

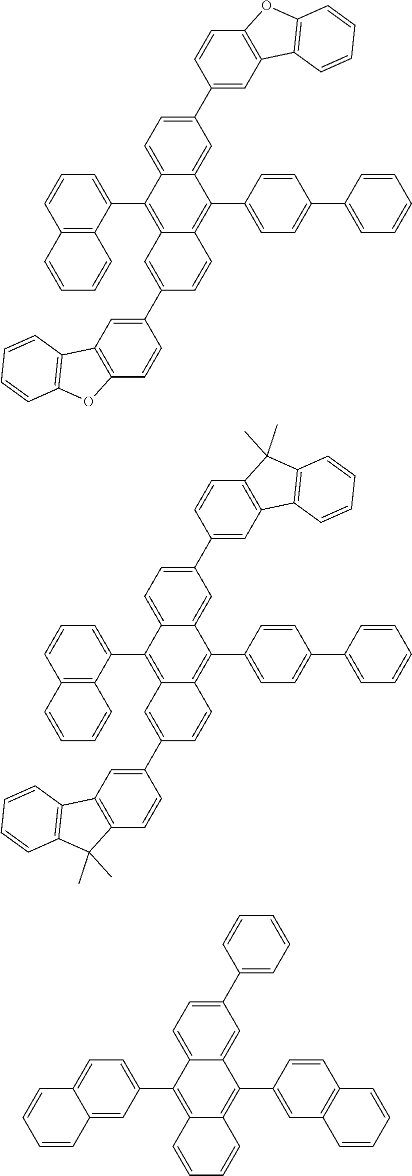

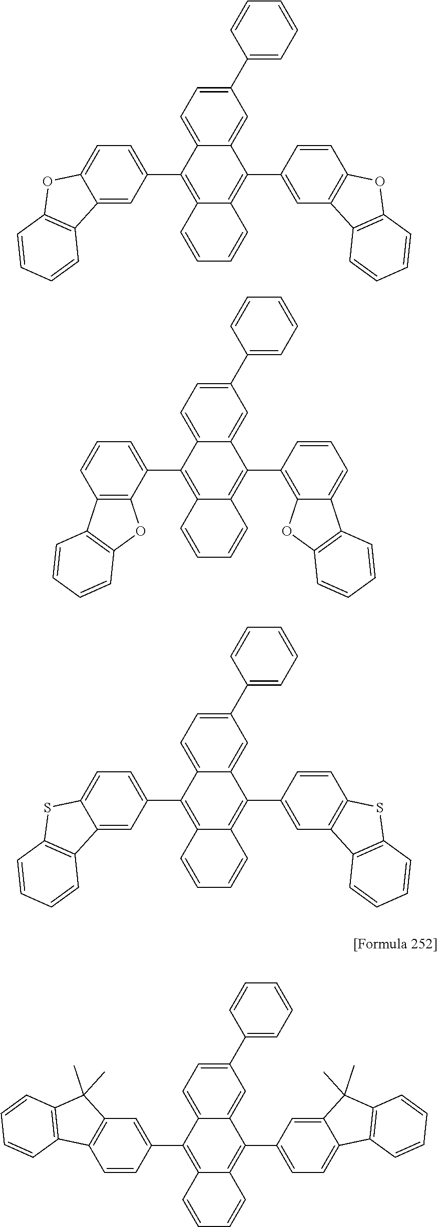

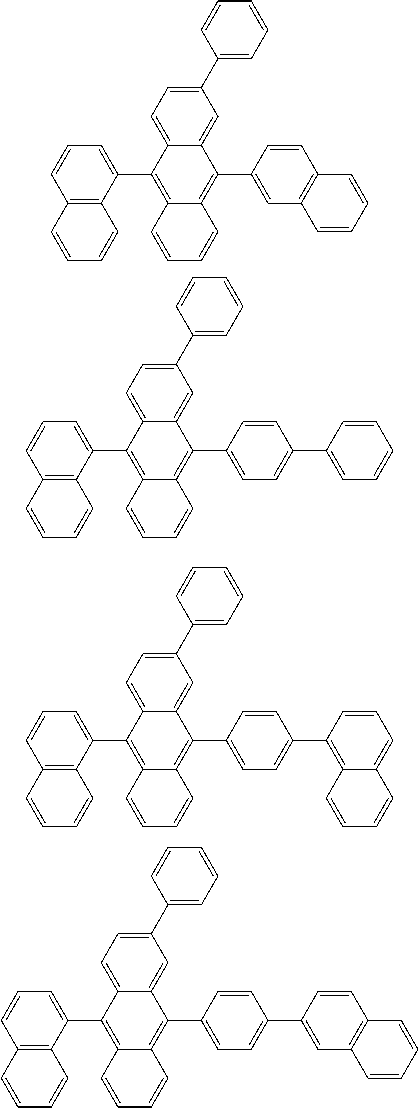

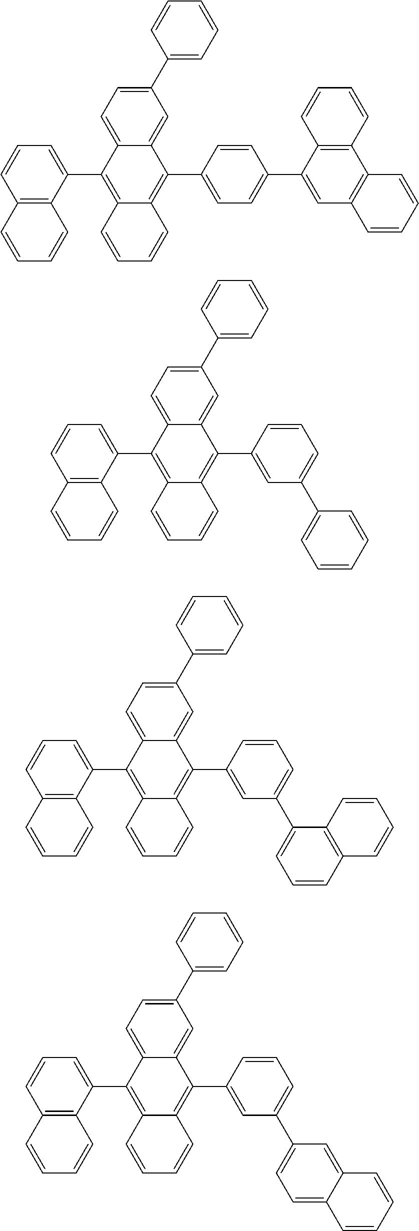

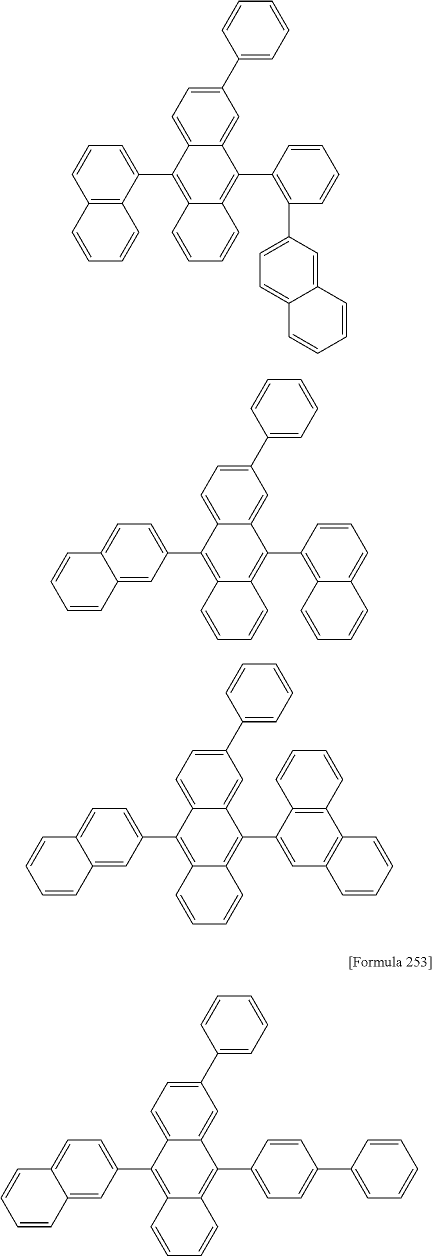

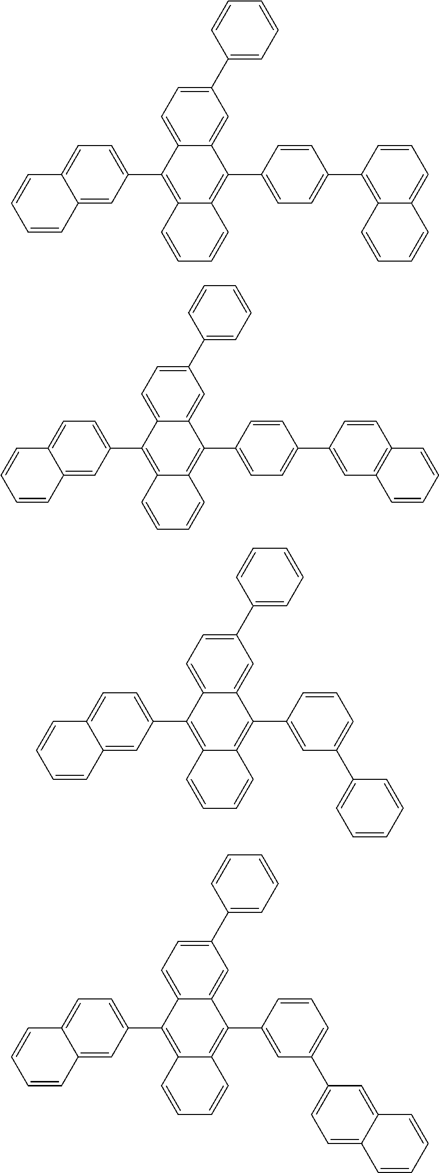

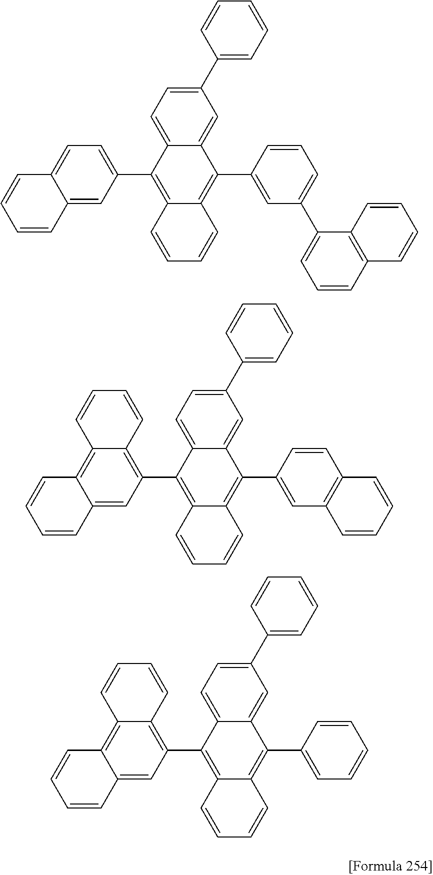

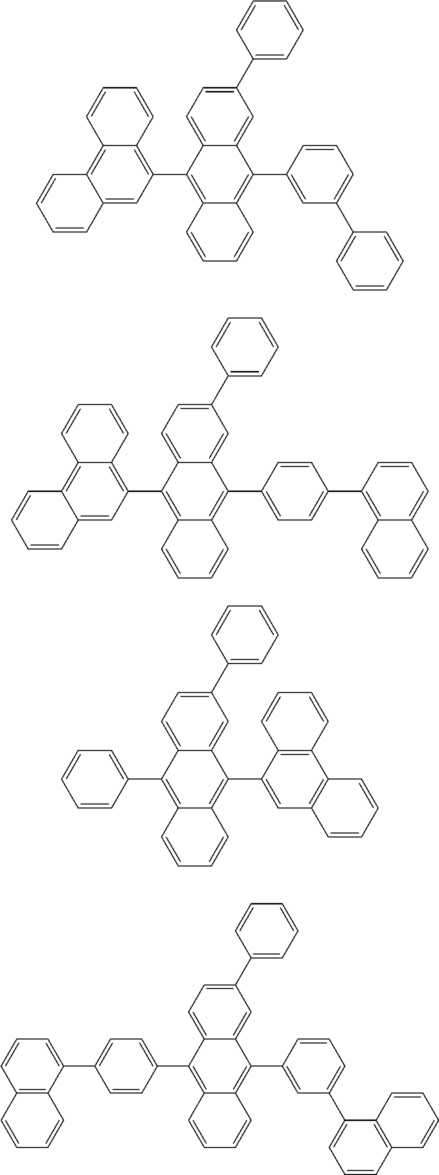

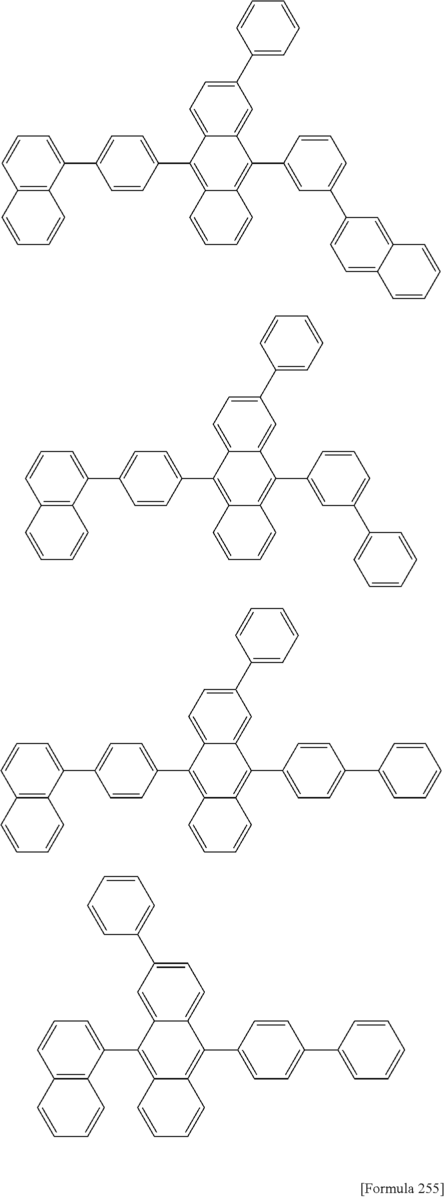

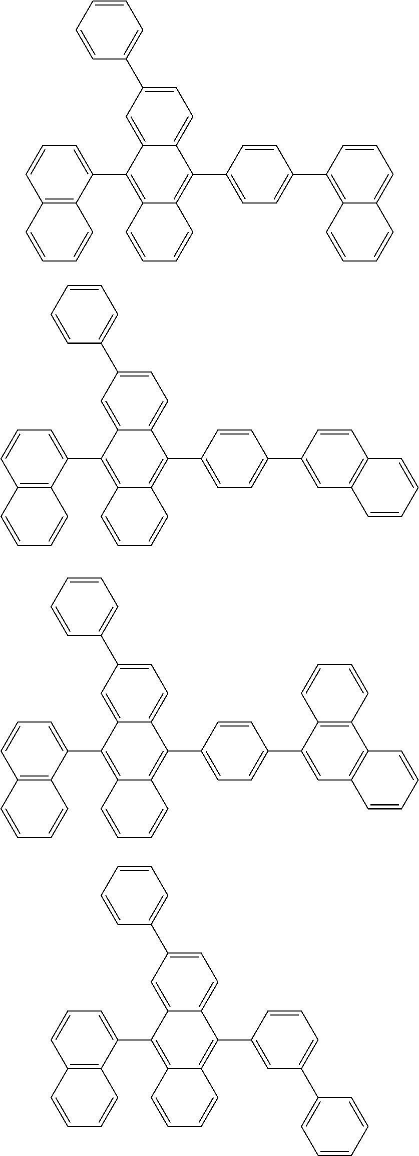

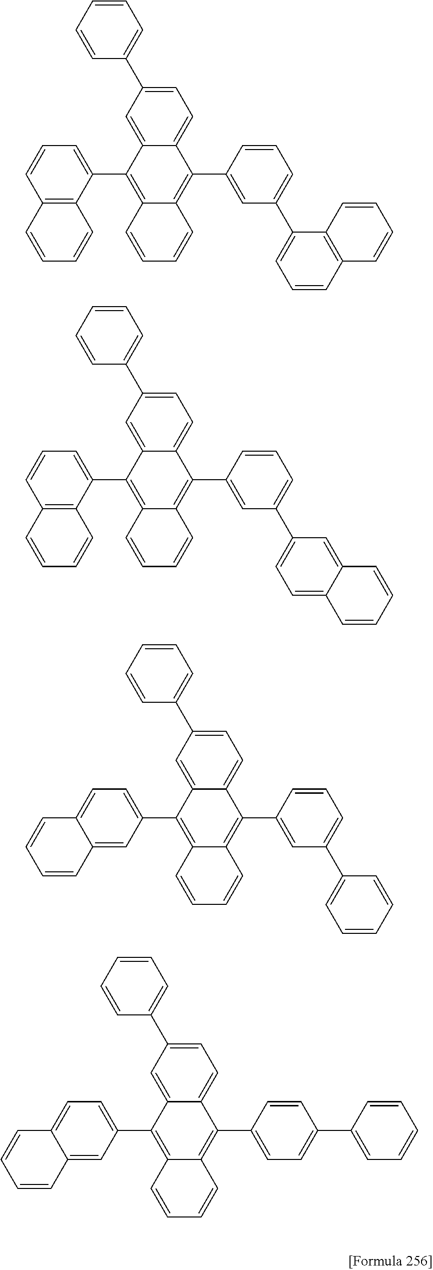

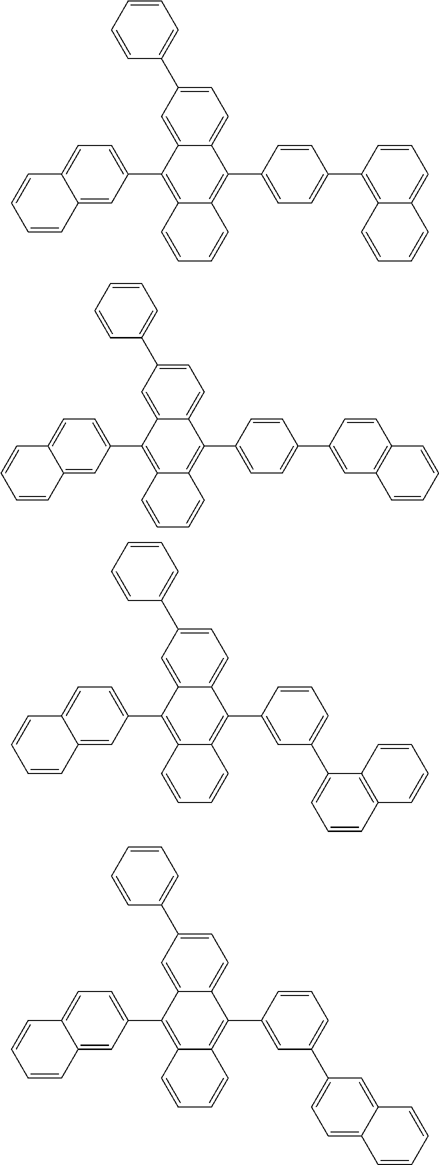

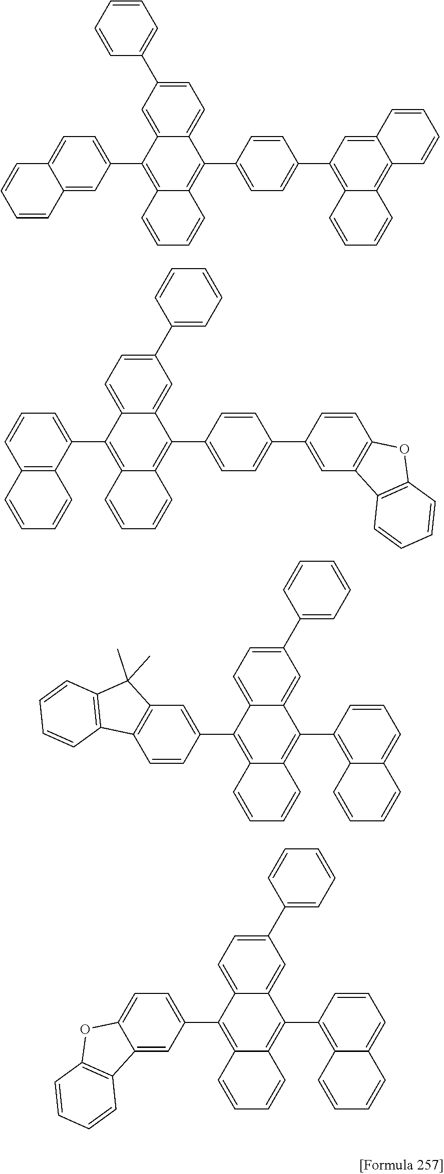

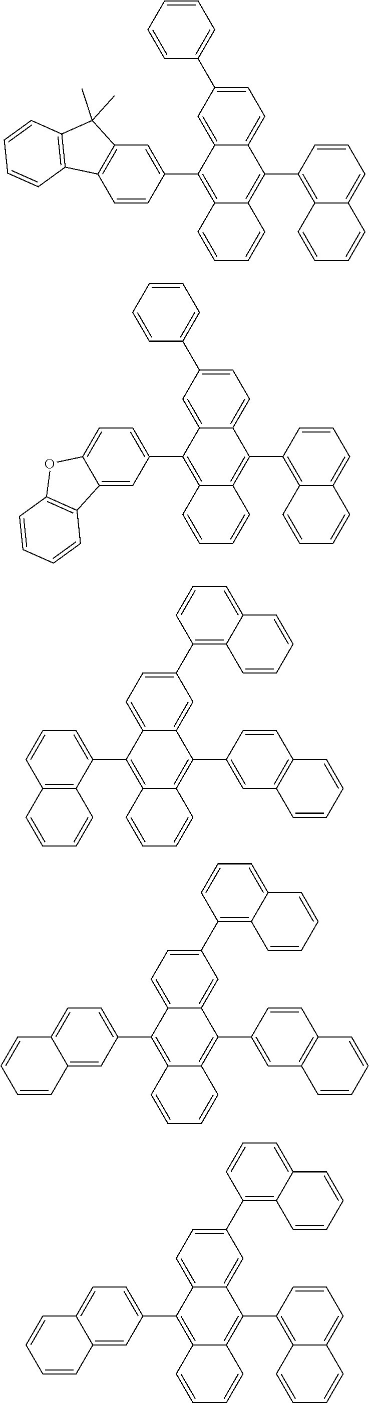

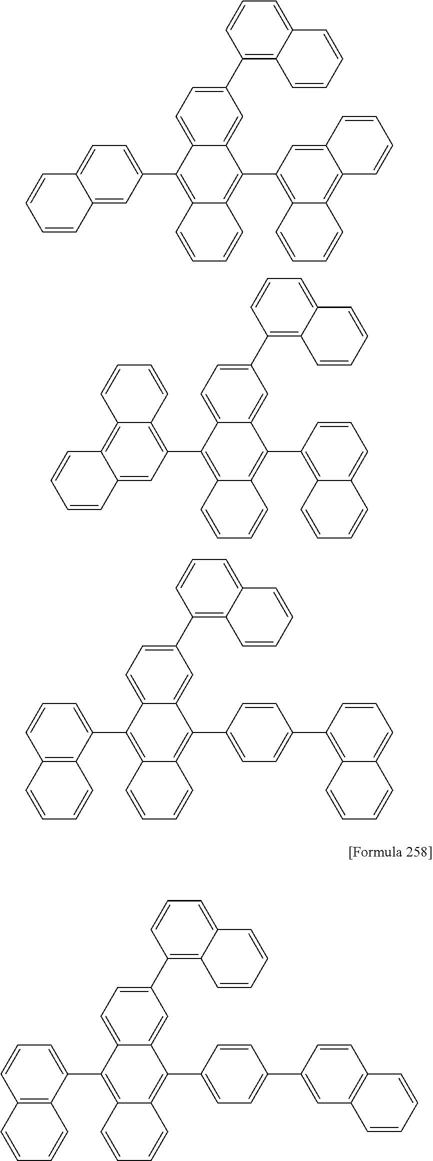

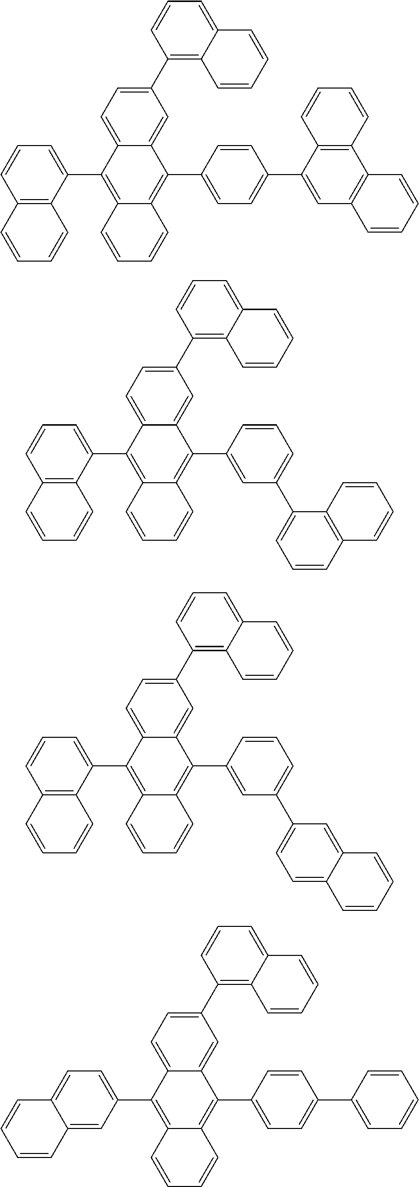

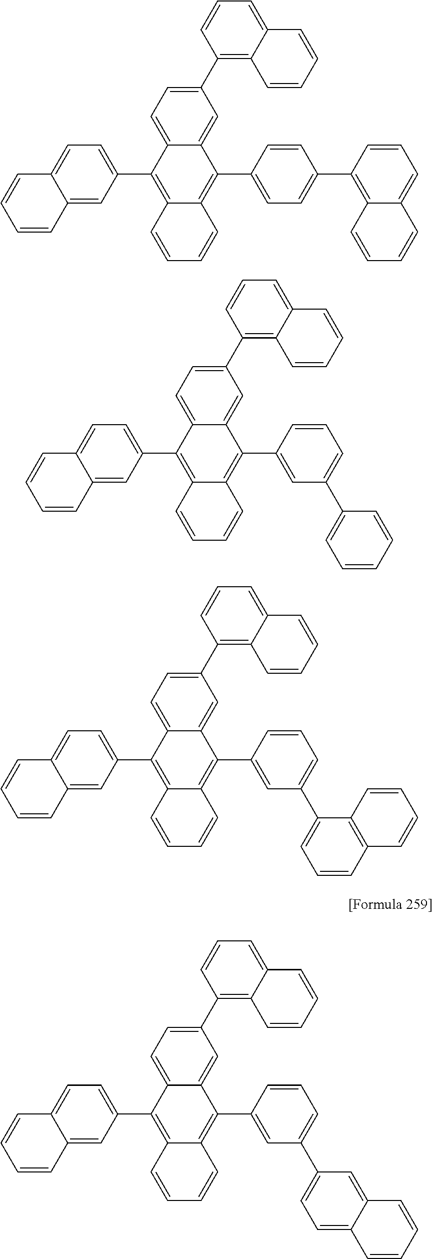

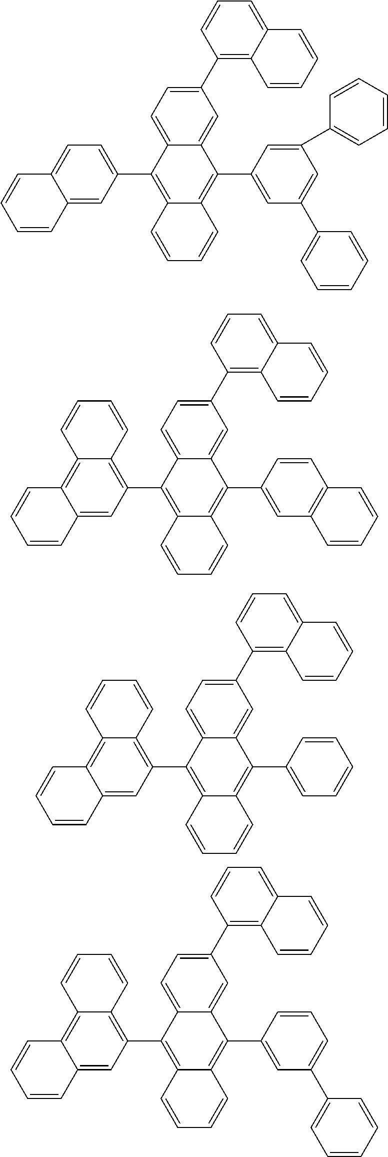

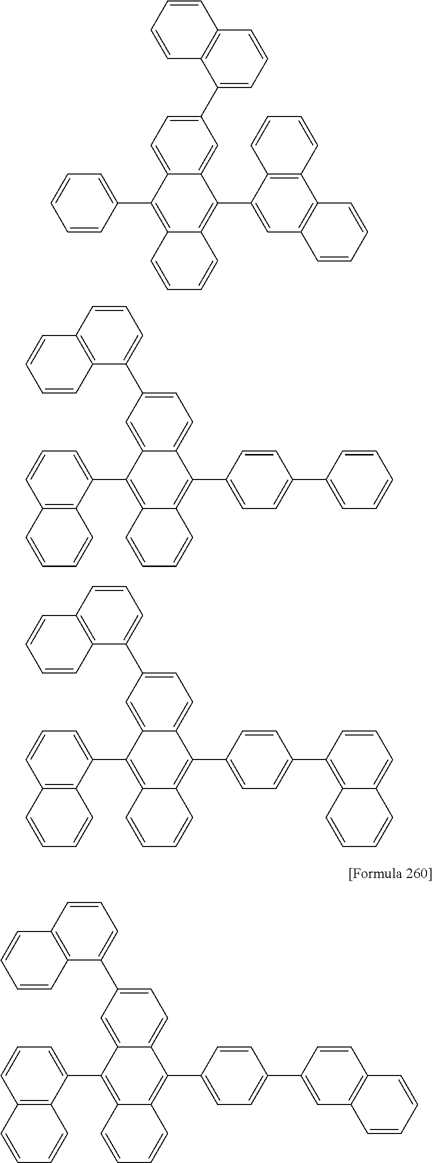

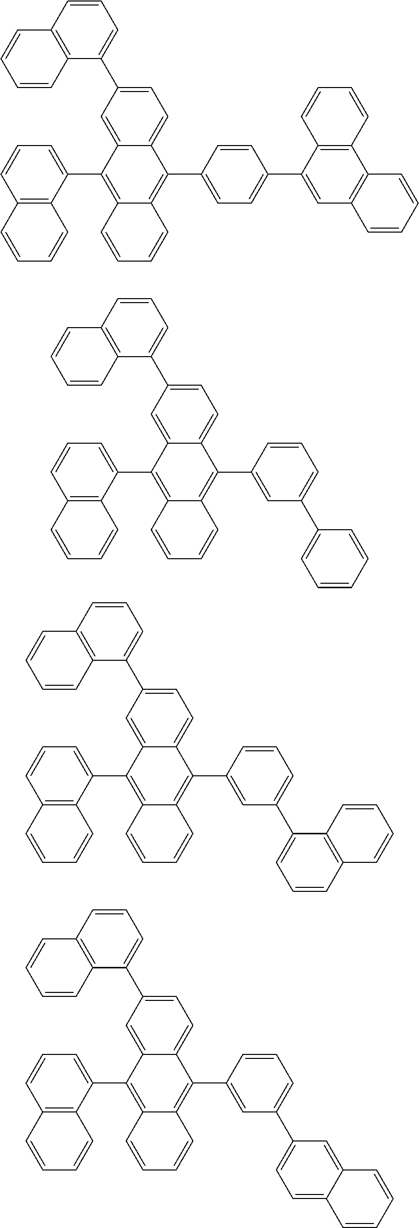

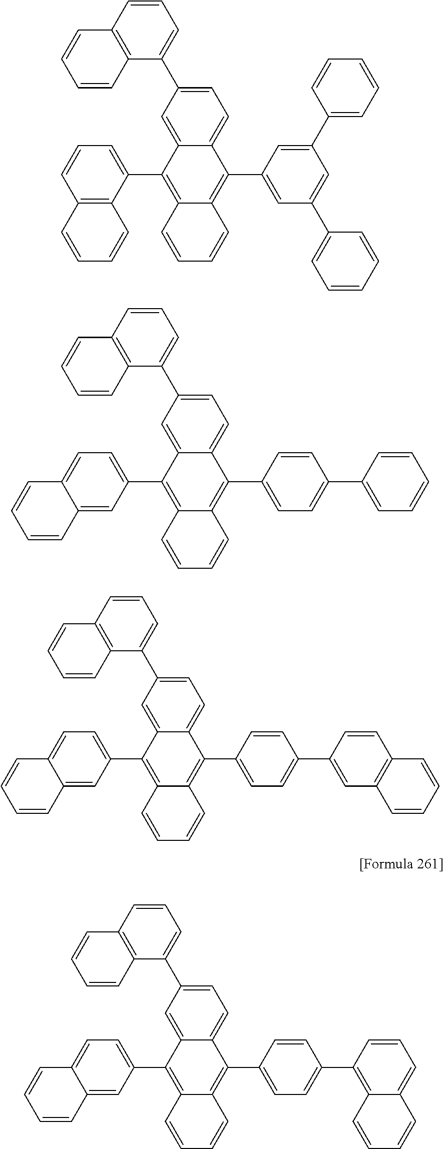

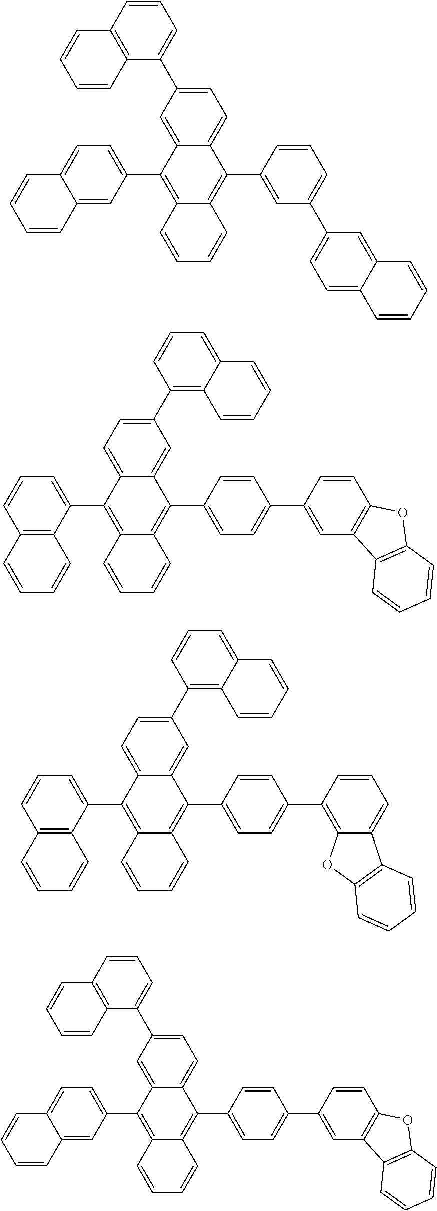

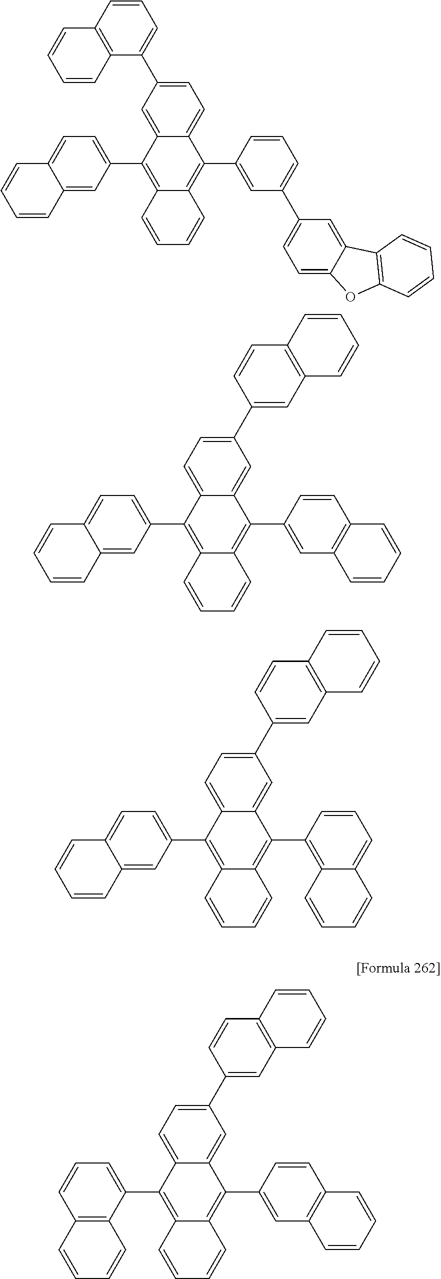

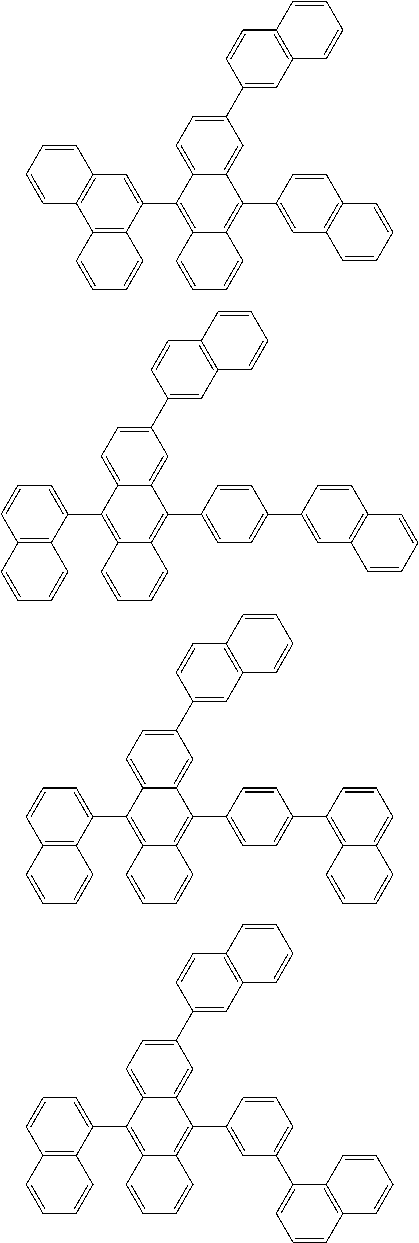

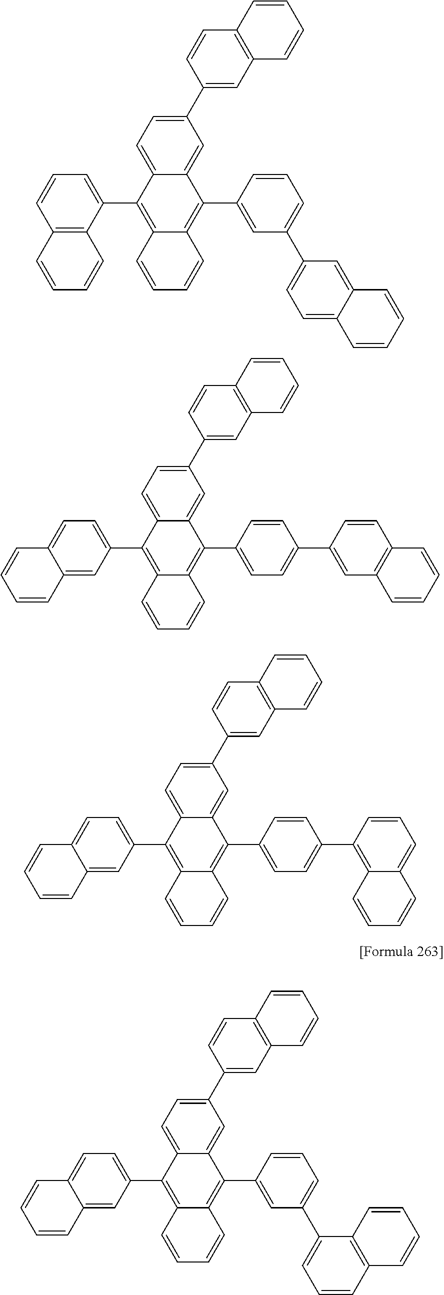

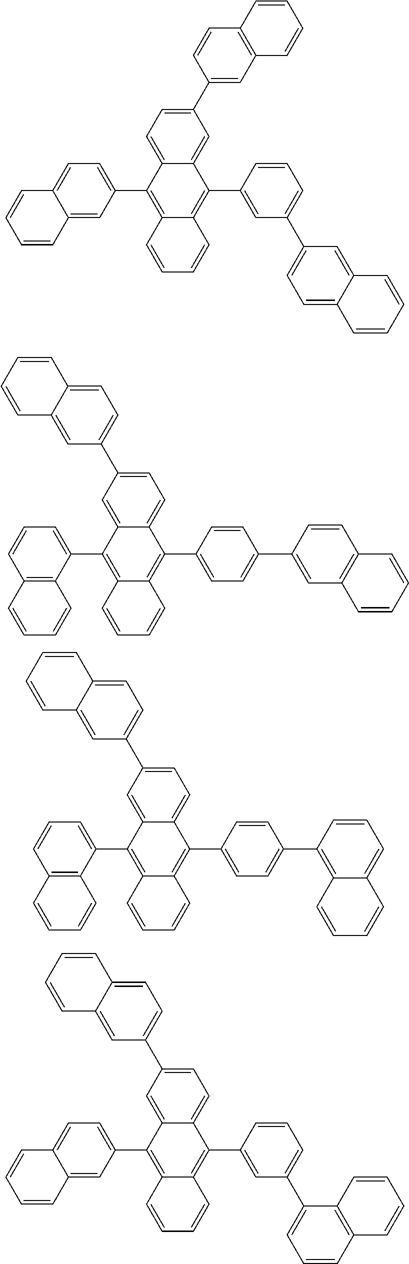

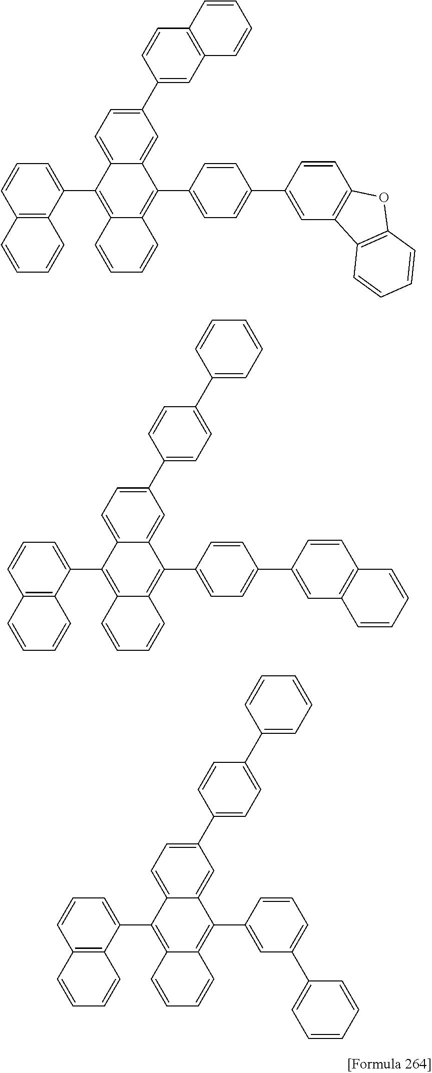

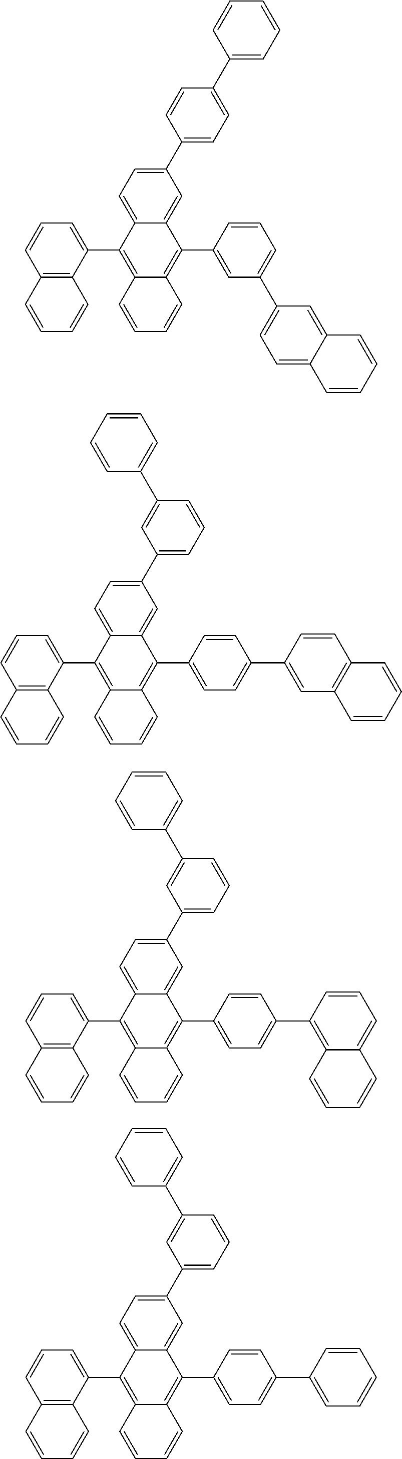

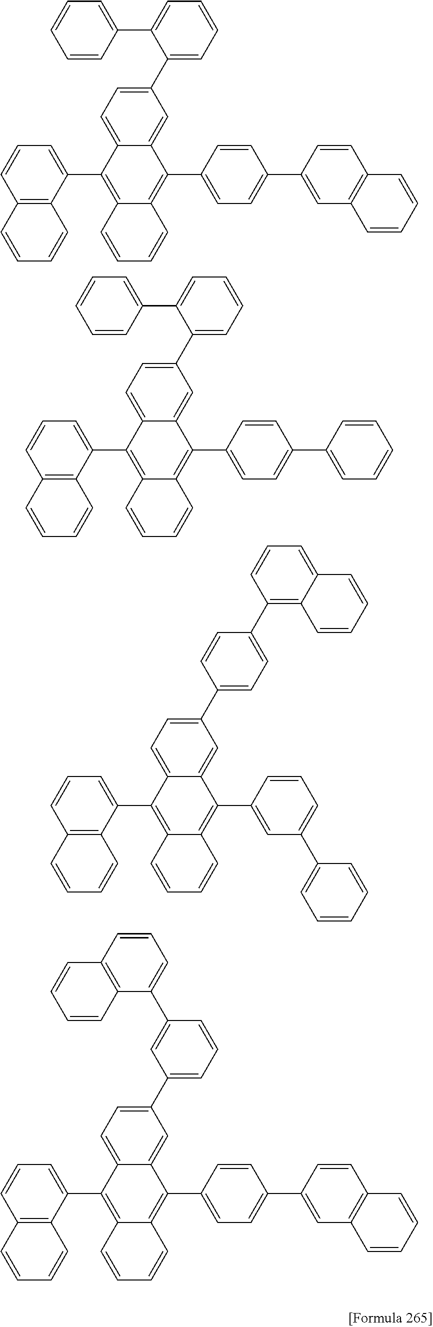

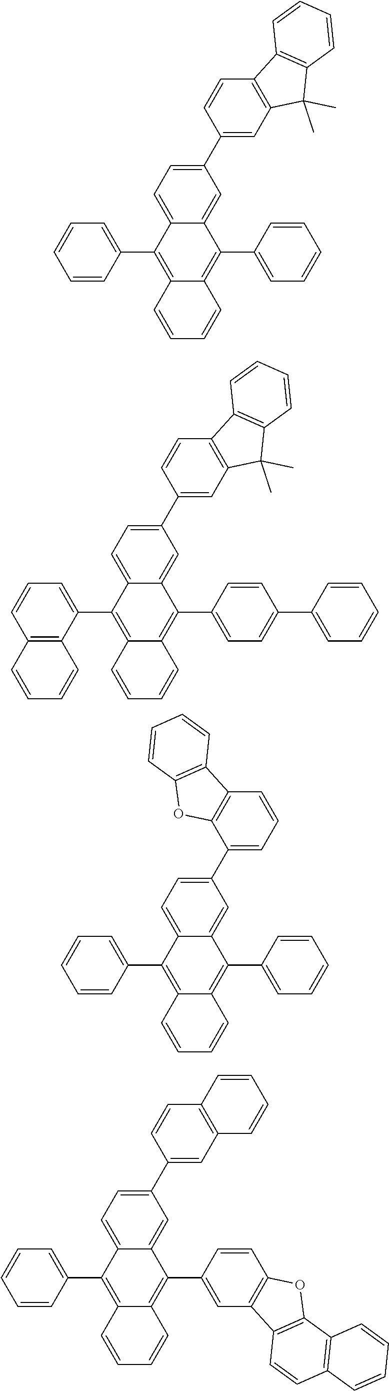

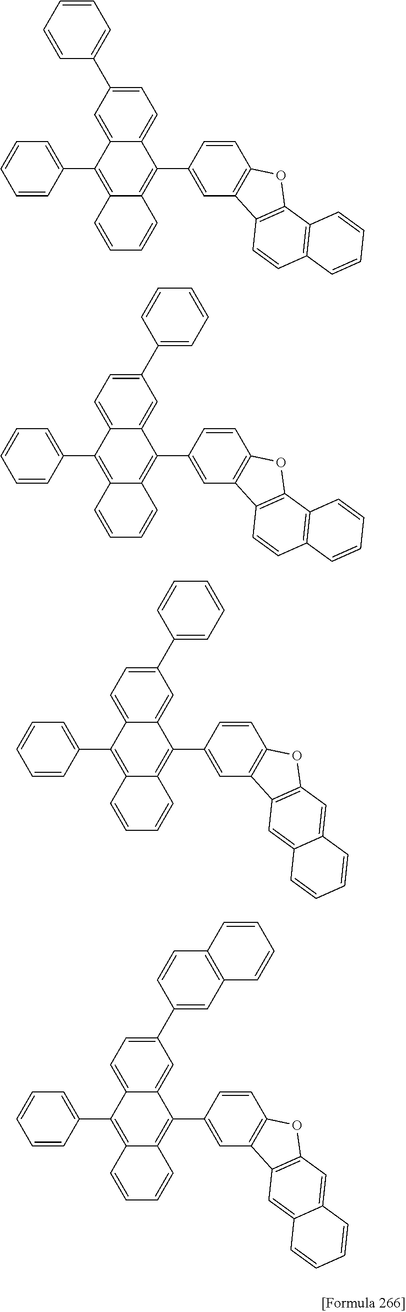

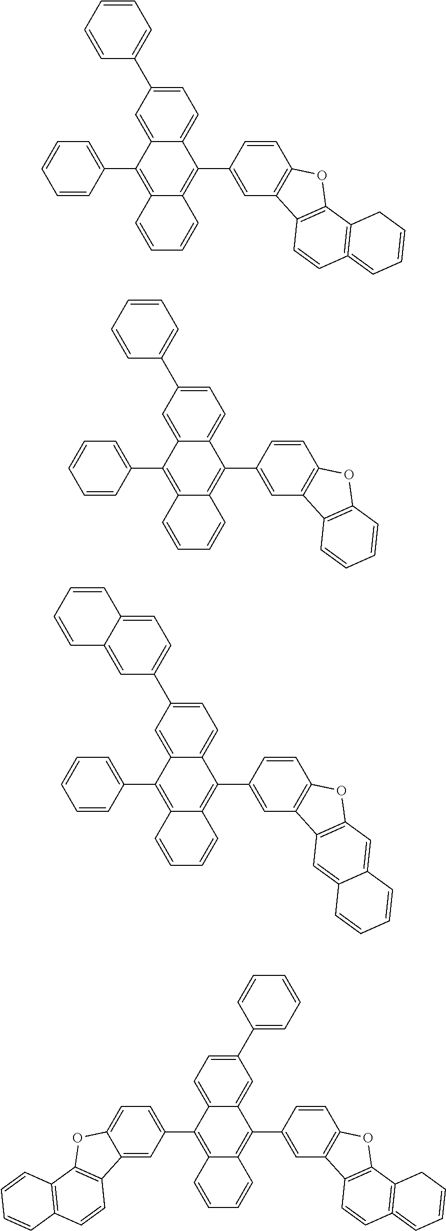

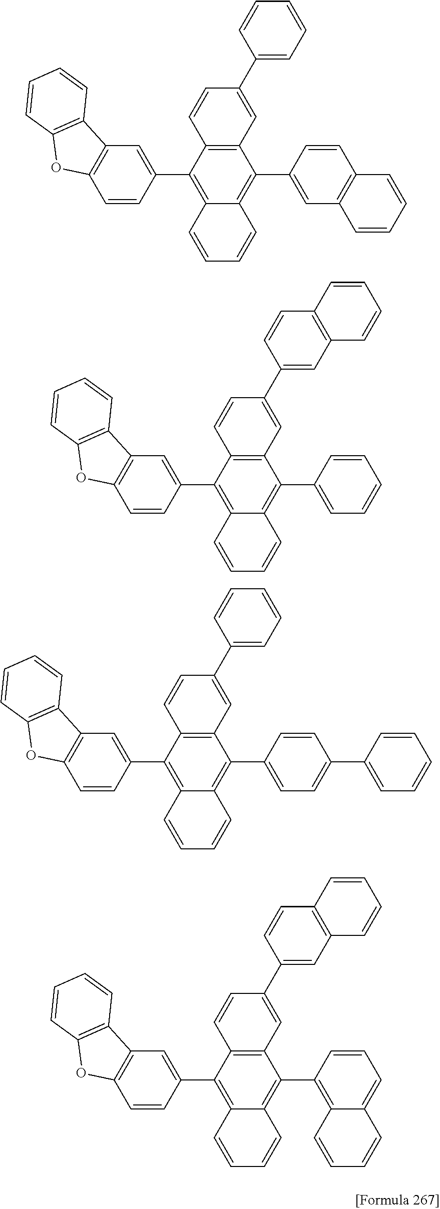

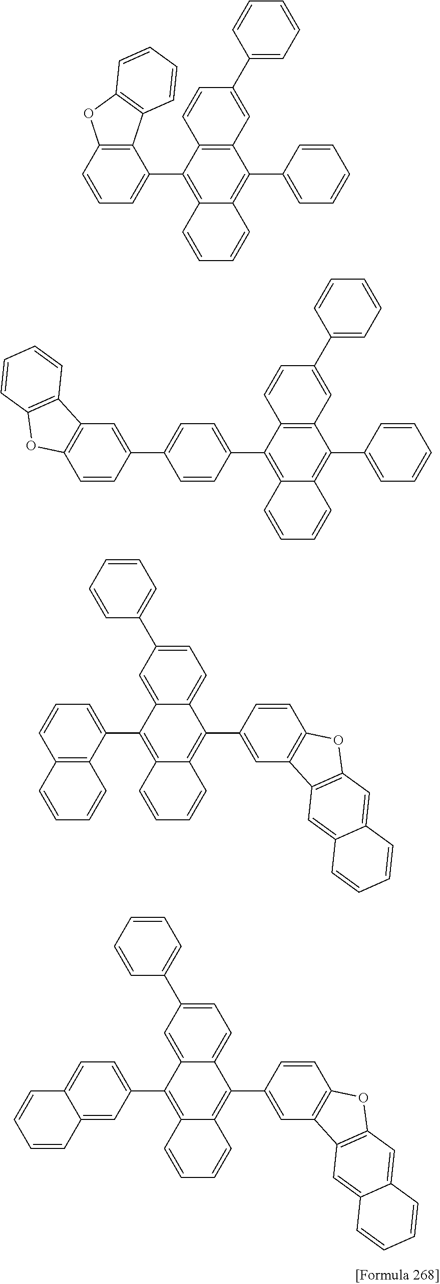 [SMILES: c1ccc(-c2ccc3c(-c4cccc5oc6ccccc6c45)c4ccccc4c(-c4ccccc4)c3c2)cc1 ; c1ccc(-c2ccc3c(-c4ccc(-c5ccc6oc7ccccc7c6c5)cc4)c4ccccc4c(-c4ccccc4)c3c2)cc1 ; c1ccc(-c2ccc3c(-c4ccc5oc6cc7ccccc7cc6c5c4)c4ccccc4c(-c4cccc5ccccc45)c3c2)cc1 ; c1ccc(-c2ccc3c(-c4ccc5oc6cc7ccccc7cc6c5c4)c4ccccc4c(-c4ccc5ccccc5c4)c3c2)cc1]

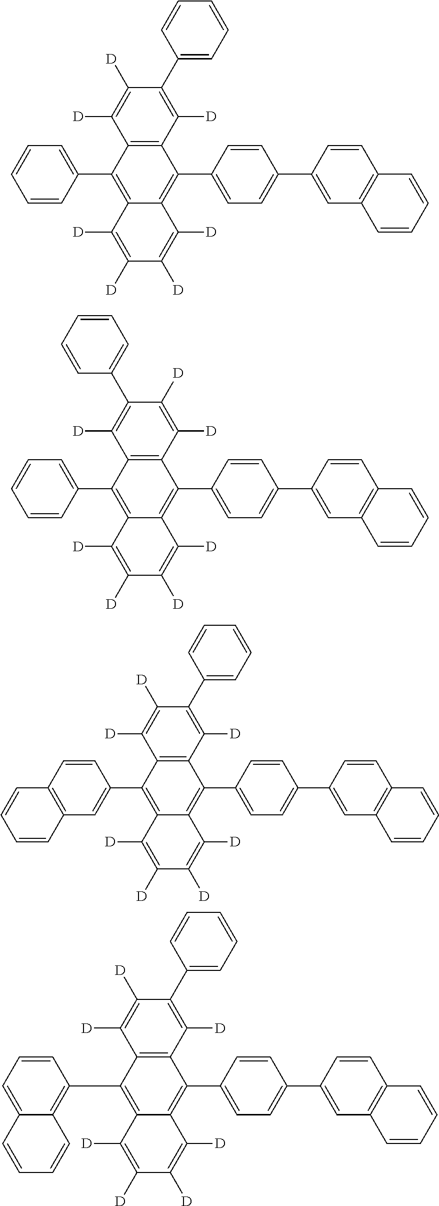

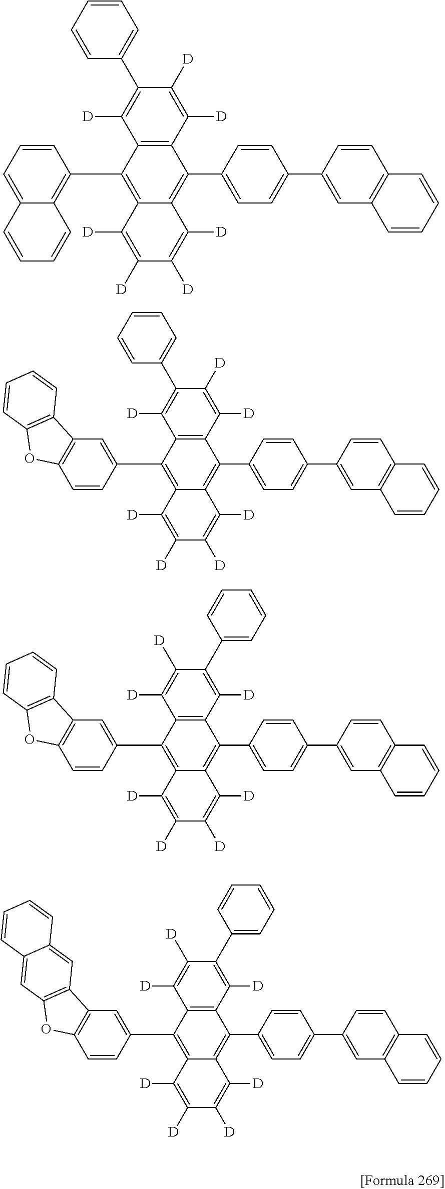

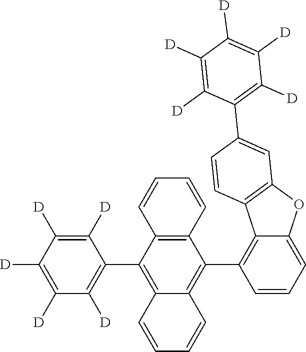 [SMILES: [2H]c1c([2H])c([2H])c(-c2ccc3c(c2)oc2cccc(-c4c5ccccc5c(-c5c([2H])c([2H])c([2H])c([2H])c5[2H])c5ccccc45)c23)c([2H])c1[2H]]

If the emitting layer of the organic EL device according to this exemplary embodiment contains second and third compounds, it is preferred that the relationship between the singlet energy S₁(H3) of the third compound and that Si (D2) of the second compound(s) be as in the numerical formula below (Numerical Formula 1).

S₁(H3)>S₁(D2) (Numerical Formula 1)

### Singlet Energy S₁

The following is an example of how to measure the singlet energy Si using a solution (also referred to as the solution method).

A toluene solution of a measurement target compound at a concentration ranging from 10⁻⁵ mol/L to 10⁻⁴ mol/L is prepared and put in a quartz cell. An absorption spectrum (ordinate axis: absorption intensity, abscissa axis: wavelength) of the thus-obtained sample is measured at a normal temperature (300K). A tangent is drawn to the fall of the absorption spectrum close to the long-wavelength region, and a wavelength value kedge (nm) at an intersection of the tangent and the abscissa axis is assigned to a conversion equation (F2) below to calculate singlet energy.

Conversion equation (F2): S₁ [eV]=1239.85/λedge

An example of a system used to measure the absorption spectrum is Hitachi's spectrophotometer (model: U3310), although this is not the only system that can be used.

The tangent to the fall of the absorption spectrum close to the long-wavelength region is drawn as follows. While moving on a curve of the absorption spectrum from the local maximum value closest to the long-wavelength region, among the local maximum values of the absorption spectrum, in a long-wavelength direction, a tangent at each point on the curve is checked. An inclination of the tangent is decreased and increased in a repeated manner as the curve falls (i.e., a value of the ordinate axis is decreased). A tangent drawn at a point where the inclination of the curve is the local minimum closest to the long-wavelength region (except when absorbance is 0.1 or less) is defined as the tangent to the fall of the absorption spectrum close to the long-wavelength region.

The local maximum absorbance of 0.2 or less is not counted as the above-mentioned local maximum absorbance closest to the long-wavelength region.

### Thickness of Emitting Layer

Preferably, the thickness of the emitting layer of the organic EL device according to this exemplary embodiment is in a range from 5 nm to 50 nm, more preferably in a range from 7 nm to 50 nm, even more preferably in a range from 10 nm to 50 nm. An emitting layer that is 5 nm or thicker is easy to form, and, with such an emitting layer, it is easy to adjust chromaticity. An emitting layer that is 50 nm or thinner helps prevent an increase in drive voltage.

### Content Ratios of Compounds in Emitting Layer

If the emitting layer contains second and third compounds, it is preferred that the content ratios of the second and third compounds in the emitting layer be, for example, in the following ranges.

Preferably, the content ratio of the third compound is in a range from 80% by mass to 99% by mass, more preferably in a range from 90% by mass to 99% by mass, even more preferably in a range from 95% by mass to 99% by mass.

Preferably, the content ratio of the second compound(s) is in a range from 1% by mass to 10% by mass, more preferably in a range from 1% by mass to 7% by mass, even more preferably in a range from 1% by mass to 5% by mass.

The upper limit to the total content ratio of the second and third compounds in the emitting layer, however, is 100% by mass.

It should be noted that this exemplary embodiment does not exclude the possibility that the emitting layer contains any material other than second and third compounds.

The emitting layer may contain one type of second compound alone or may contain two or more types thereof. The emitting layer may contain one type of third compound alone or may contain two or more types thereof.

The following further describes the structure of the organic EL device. Codes may be omitted in the following description.

### Substrate

The substrate is used as a support for the organic EL device. For instance, glass, quartz, plastics and the like are usable for the substrate. A flexible substrate is also usable. The flexible substrate is a bendable substrate, which is exemplified by a plastic substrate. Examples of the material for the plastic substrate include polycarbonate, polyarylate, polyethersulfone, polypropylene, polyester, polyvinyl fluoride, polyvinyl chloride, polyimide, and polyethylene naphthalate. Moreover, an inorganic vapor deposition film is also usable.

### Anode

Metal, an alloy, an electrically conductive compound, a mixture thereof, or the like having a large work function (specifically, 4.0 eV or more) is preferably used as the anode formed on the substrate. Specific examples of the material include ITO (Indium Tin Oxide), indium oxide-tin oxide containing silicon or silicon oxide, indium oxide-zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metal material (e.g., titanium nitride) are usable.

The material is typically formed into a film by a sputtering method. For instance, the indium oxide-zinc oxide can be formed into a film by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like.

Among the organic layers formed on the anode, since the hole injecting layer adjacent to the anode is formed of a composite material into which holes are easily injectable irrespective of the work function of the anode, a material usable as an electrode material (e.g., metal, an alloy, an electroconductive compound, a mixture thereof, and the elements belonging to the group 1 or 2 of the periodic table) is also usable for the anode.

A material having a small work function such as elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), alloys including the rare earth metal are also usable for the anode. It should be noted that the vacuum deposition method and the sputtering method are usable for forming the anode using the alkali metal, alkaline earth metal and the alloy thereof. Further, when a silver paste is used for the anode, the coating method and the inkjet method are usable.

### Cathode

It is preferable to use metal, an alloy, an electroconductive compound, a mixture thereof, or the like having a small work function (specifically, 3.8 eV or less) for the cathode. Examples of the material for the cathode include elements belonging to Groups 1 and 2 in the periodic table of the elements, specifically, the alkali metal such as lithium (Li) and cesium (Cs), the alkaline earth metal such as magnesium (Mg), calcium (Ca) and strontium (Sr), alloys (e.g., MgAg and AlLi) including the alkali metal or the alkaline earth metal, the rare earth metal such as europium (Eu) and ytterbium (Yb), and alloys including the rare earth metal.

It should be noted that the vacuum deposition method and the sputtering method are usable for forming the cathode using the alkali metal, alkaline earth metal and the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method and the like.

### Hole Injecting Layer

The hole injecting layer is a layer containing a substance exhibiting a high hole injectability. Examples of the substance exhibiting a high hole injectability include molybdenum oxide, titanium oxide, vanadium oxide, rhenium oxide, ruthenium oxide, chrome oxide, zirconium oxide, hafnium oxide, tantalum oxide, silver oxide, tungsten oxide, and manganese oxide.

In addition, the examples of the highly hole-injectable substance further include: an aromatic amine compound, which is a low-molecule organic compound, such that 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazole-3-yl)-N-phenylamino]-9-phenylcarbazole (abbreviation: PCzPCA1), 3,6-bis[N-(9-phenylcarbazole-3-yl)-N-phenylamino]-9-phenylcarbazole (abbreviation: PCzPCA2), and 3-[N-(1-naphthyl)-N-(9-phenylcarbazole-3-yl)amino]-9-phenylcarbazole (abbreviation: PCzPCN1); and dipyrazino[2,3-f:20,30-h]quinoxaline-2,3,6,7,10,11-hexacarbonitrile (HAT-CN).

In addition, a high polymer compound (e.g., oligomer, dendrimer and polymer) is usable as the substance exhibiting a high hole injectability. Examples of the high-molecule compound include poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide](abbreviation: PTPDMA), and poly[N,N′-bis(4-butylphenyl)-N,N′-bis(phenyl)benzidine] (abbreviation: Poly-TPD). Moreover, an acid-added high polymer compound such as poly(3,4-ethylenedioxythiophene)/poly(styrene sulfonic acid) (PEDOT/PSS) and polyaniline/poly(styrene sulfonic acid)(PAni/PSS) are also usable.

### Hole Transporting Layers

The organic EL device according to this exemplary embodiment may further include a hole transporting layer besides the first hole transporting layer.

### Second Hole Transporting Layer

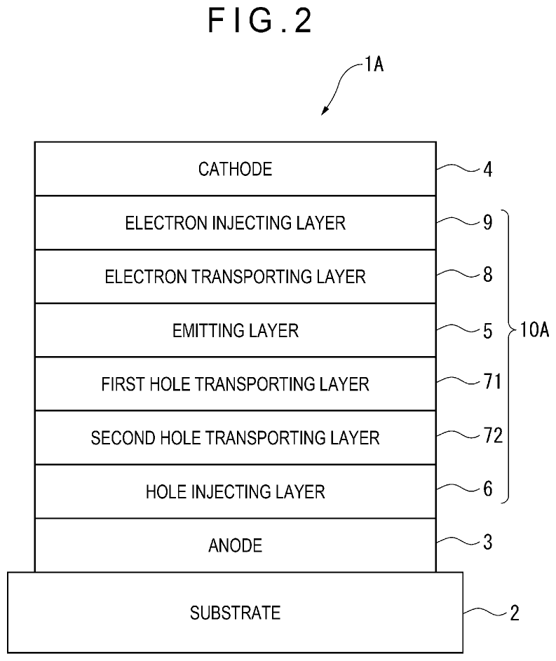

An organic EL device according to an exemplary embodiment further includes a second hole transporting layer between the anode and the first hole transporting layer. FIG. 2 illustrates an example of an outline of an organic EL device having first and second hole transporting layers.

The organic EL device 1A includes a light-transmissive substrate 2, an anode 3, a cathode 4, and an organic layer 10A between the anode 3 and the cathode 4. The organic layer 10A is formed by a hole injecting layer 6, a second hole transporting layer 72, a first hole transporting layer 71, an emitting layer 5, an electron transporting layer 8, and an electron injecting layer 9 stacked in this order on the anode 3.

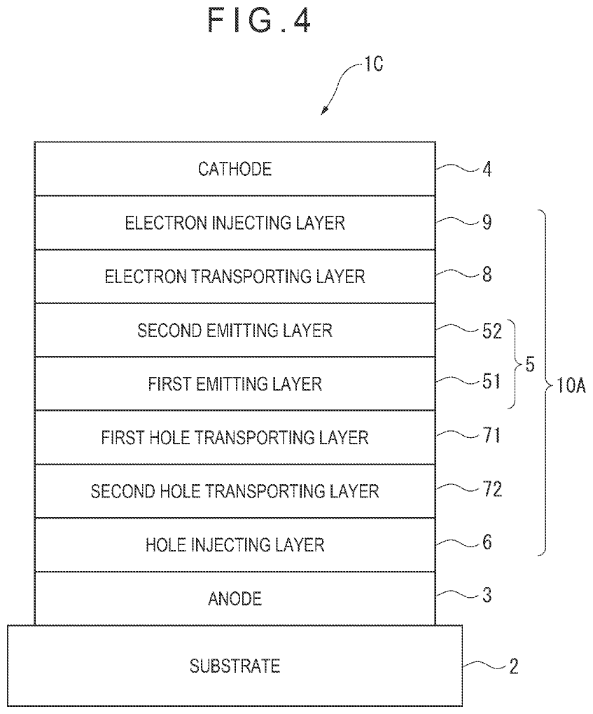

FIG. 4 also illustrates an example of an outline of an organic EL device having first and second hole transporting layers.

The organic EL device 1C includes a light-transmissive substrate 2, an anode 3, a cathode 4, and an organic layer 10A between the anode 3 and the cathode 4. The organic layer 10A is formed by a hole injecting layer 6, a second hole transporting layer 72, a first hole transporting layer 71, an emitting layer 5, an electron transporting layer 8, and an electron injecting layer 9 stacked in this order from on anode 3, and the emitting layer 5 includes a first emitting layer 51 and a second emitting layer 52.

If the organic EL device has a second hole transporting layer, the first hole transporting layer has a first surface close to the cathode and a second surface close to the anode, of the first hole transporting layer. The first surface of the first hole transporting layer is in direct contact with the emitting layer.

Preferably, the second hole transporting layer is directly adjacent to the first hole transporting layer. That is, it is preferred that the second surface of the first hole transporting layer be in direct contact with the second hole transporting layer.

Preferably, the second hole transporting layer contains a compound having an amino group. The compound having an amino group is, for example, an N-(L_{AMN1}-L_{AMN2}-L_{AMN3}-Ar_{AMN})₃. The multiple L_{AMN1}s, L_{AMN2}S, L_{AMN3}S, and Ar_{AMN}S may be the same as or different from each other. L_{AMN1}, L_{AMN2}, and L_{AMN3} are each a single bond, substituted or unsubstituted arylene group, or substituted or unsubstituted divalent heterocyclic group. Ar_{AMN} is a substituted or unsubstituted aryl group or substituted or unsubstituted heterocyclic group. L_{AMN1}, L_{AMN2}, L_{AMN3}, and Ar_{AMN} contain, for example, no pyrene structure.

It is also preferred that the second hole transporting layer contain a compound having only one amino group in its molecule (also referred to as a monoamine compound).

It is also preferred that the second hole transporting layer contain a compound represented by formula (B1) below.

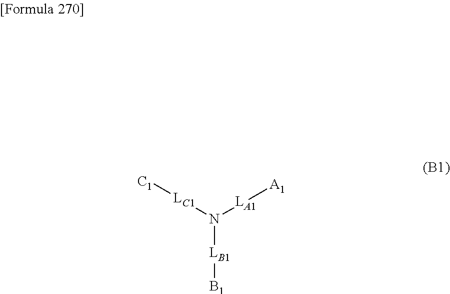

In formula (B1),

L_{A1}, L_{B1}, and L_{C1} each independently represent: a single bond; a substituted or unsubstituted arylene group having 6 to 18 ring carbon atoms; or a substituted or unsubstituted divalent heterocyclic group having 5 to 13 ring atoms;

if L_{A1} and L_{B1} are single bonds, A₁ and B₁ are: bonded together to form a substituted or unsubstituted monocyclic ring; bonded together to form a substituted or unsubstituted fused ring; or not bonded together;

if L_{A1} and L_{C1} are single bonds, A₁ and C₁ are: bonded together to form a substituted or unsubstituted monocyclic ring; bonded together to form a substituted or unsubstituted fused ring; or not bonded together;

if L_{B1} and L_{C1} are single bonds, B₁ and C₁ are: bonded together to form a substituted or unsubstituted monocyclic ring; bonded together to form a substituted or unsubstituted fused ring; or not bonded together;

A₁, B₁, and C₁ not forming the substituted or unsubstituted monocyclic ring and not forming the substituted or unsubstituted fused ring each independently represent: a substituted or unsubstituted aryl group having 6 to 30 ring carbon atoms; a substituted or unsubstituted heterocyclic group having 5 to 30 ring atoms; or a group represented by —Si(R₉₂₁)(R₉₂₂)(R₉₂₃);

R₉₂₁, R₉₂₂, and R₉₂₃ each independently represent a substituted or unsubstituted aryl group having 6 to 30 ring carbon atoms;

when multiple R₉₂₁s are present, the multiple R₉₂₁s are mutually the same or different;

when multiple R₉₂₂s are present, the multiple R₉₂₂s are mutually the same or different; and

when multiple R₉₂₃s are present, the multiple R₉₂₃s are mutually the same or different.

Preferably, the second hole transporting layer consists of a compound containing no pyrene structure.

It is also preferred that the second hole transporting layer consists of a compound having an amino group.

It is also preferred that the second hole transporting layer contain a compound having a carbazolyl group. The compound having a carbazolyl group is, for example, a Cz-(L_{cz1}-L_{cz2}-L_{cz3}-Ar_{cz})₁, Cz-(L_{cz1}-L_{cz2}-L_{cz3}-Ar_{cz})₂, or Cz-(L_{cz1}-L_{cz2}-L_{cz3}-Ar_{cz})₃. Cz is a carbazolyl group. Multiple L_{cz1}s, L_{cz2}s, L_{cz3}s, and Ar_{cz}s may be the same as or different from each other. L_{cz1} is bonded to a carbon atom or the nitrogen atom of Cz. L_{cz1}, L_{cz2}, and L_{cz3} are each a single bond, substituted or unsubstituted arylene group, or substituted or unsubstituted divalent heterocyclic group. Ar_{cz} is a substituted or unsubstituted aryl group or substituted or unsubstituted heterocyclic group. L_{cz1}, L_{cz2}, L_{cz3}, and Ar_{cz} contain, for example, no pyrene structure.

Any hole transporting layer other than the first hole transporting layer is a layer that contains a highly hole transporting substance. An aromatic amine compound, carbazole derivative, anthracene derivative and the like are usable for the hole transporting layer. Specific examples of a material for the hole transporting layer include 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4-phenyl-4′-(9-phenylfluorene-9-yl)triphenylamine (abbreviation: BAFLP), 4,4′-bis[N-(9,9-dimethylfluorene-2-yl)-N-phenylamino]biphenyl (abbreviation: DFLDPBi), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluorene-2-yl)-N-phenylamino]biphenyl (abbreviation: BSPB). The above-described substances mostly have a hole mobility of 10⁻⁶ cm²/(V·s) or more.

For the hole transporting layer, a carbazole derivative such as CBP, 9-[4-(N-carbazolyl)]phenyl-10-phenylanthracene (CzPA), and 9-phenyl-3-[4-(10-phenyl-9-anthryl)phenyl]-9H-carbazole (PCzPA) and an anthracene derivative such as t-BuDNA, DNA, and DPAnth may be used. A high polymer compound such as poly(N-vinylcarbazole) (abbreviation: PVK) and poly(4-vinyltriphenylamine) (abbreviation: PVTPA) is also usable.

Preferably, the first and second hole transporting layers do not contain antimony chloride, vanadium oxide, molybdenum oxide, ruthenium oxide, tungsten oxide, zinc oxide, tin oxide, and iron oxide, more preferably do not contain inorganic compounds.

Preferably, the first and second hole transporting layers do not contain hexacyanoazatriphenylene.

However, in addition to the above substances, any substance exhibiting a higher hole transportability than an electron transportability may be used. It should be noted that the layer containing the substance exhibiting a high hole transportability may be not only a single layer but also a laminate of two or more layers formed of the above substance(s).

The organic EL device according to this exemplary embodiment may further has a third hole transporting layer as a hole transporting layer. Preferably, the third hole transporting layer is in direct contact with the side of the second hole transporting layer close to the anode.

### Electron Transporting Layer

The electron transporting layer is a layer containing a highly electron-transporting substance. For the electron transporting layer, 1) a metal complex such as an aluminum complex, beryllium complex, and zinc complex, 2) a heteroaromatic compound such as imidazole derivative, benzimidazole derivative, azine derivative, carbazole derivative, and phenanthroline derivative, and 3) a high polymer compound are usable. Specifically, as a low-molecule organic compound, a metal complex such as Alq, tris(4-methyl-8-quinolinato)aluminum (abbreviation: Almq₃), bis(10-hydroxybenzo[h]quinolinato)beryllium (abbreviation: BeBq₂), BAlq, Znq, ZnPBO and ZnBTZ is usable. In addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation: BzOs) is usable. In the exemplary embodiment, a benzimidazole compound is preferably usable. The above-described substances mostly have an electron mobility of 10⁻⁶ cm²/(V·s) or more. It should be noted that any substance other than the above substance may be used for the electron transporting layer as long as the substance exhibits a higher electron transportability than the hole transportability. The electron transporting layer may be provided in the form of a single layer or a laminate of two or more layers of the above substance(s).

Further, a high polymer compound is usable for the electron transporting layer. For instance, poly[(9,9-dihexylfluorene-2,7-diyl)-co-(pyridine-3,5-diyl)](abbreviation: PF-Py), poly[(9,9-dioctylfluorene-2,7-diyl)-co-(2,2′-bipyridine-6,6′-diyl)](abbreviation: PF-BPy) and the like are usable.

### Electron Injecting Layer

The electron injecting layer is a layer containing a highly electron-injectable substance. Examples of a material for the electron injecting layer include an alkali metal, alkaline earth metal and a compound thereof, examples of which include lithium (Li), cesium (Cs), calcium (Ca), lithium fluoride (LiF), cesium fluoride (CsF), calcium fluoride (CaF₂), and lithium oxide (LiOx). In addition, the alkali metal, alkaline earth metal or the compound thereof may be added to the substance exhibiting the electron transportability in use. Specifically, for instance, magnesium (Mg) added to Alq may be used. In this case, the electrons can be more efficiently injected from the cathode.

Alternatively, the electron injecting layer may be provided by a composite material in a form of a mixture of the organic compound and the electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the heteroaromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Moreover, a Lewis base such as magnesium oxide is usable. Further, the organic compound such as tetrathiafulvalene (abbreviation: TTF) is usable.

### Layer Formation Method(s)

A method for forming each layer of the organic EL device in the exemplary embodiment is subject to no limitation except for the above particular description. However, known methods of dry film-forming such as vacuum deposition, sputtering, plasma or ion plating and wet film-forming such as spin coating, dipping, flow coating or ink-jet are applicable.

### Film Thickness

A film thickness of each of the organic layers of the organic EL device in the exemplary embodiment is not limited unless otherwise specified in the above. In general, the thickness preferably ranges from several nanometers to 1 μm because excessively small film thickness is likely to cause defects (e.g. pin holes) and excessively large thickness leads to the necessity of applying high voltage and consequent reduction in efficiency.

According to this exemplary embodiment, an organic electroluminescence device with reduced drive voltage can be provided.

The organic EL device according to this exemplary embodiment has a first hole transporting layer containing a first compound, for example represented by formula (1), in direct contact with its emitting layer. Stacking the first hole transporting layer and the emitting layer in such a way improves the injection of holes into the emitting layer. The drive voltage, therefore, is reduced compared with that of known organic EL devices having a hole transporting layer made with a compound having an amino group.

### Second Exemplary Embodiment

### Electronic Device

An electronic device according to a second exemplary embodiment is installed with any one of the organic EL devices according to the above exemplary embodiment. Examples of the electronic device include a display device and a light-emitting device. Examples of the display device include a display component (e.g., an organic EL panel module), TV, mobile phone, tablet and personal computer. Examples of the light-emitting device include an illuminator and a vehicle light.

### Modification of Embodiment(s)

The scope of the invention is not limited to the above-described exemplary embodiments but includes any modification and improvement as long as such modification and improvement are compatible with the invention.

For instance, the emitting layer is not limited to a single layer, but may be provided by laminating two or more emitting layers. When the organic EL device has two or more emitting layers, it is only required that at least one of the emitting layers satisfies the conditions described in the above exemplary embodiments. For instance, the rest of the emitting layers may be a fluorescent emitting layer or a phosphorescent emitting layer with use of emission caused by electron transfer from the triplet excited state directly to the ground state.

When the organic EL device includes a plurality of emitting layers, these emitting layers may be mutually adjacently provided, or may form a so-called tandem organic EL device in which a plurality of emitting units are layered via an intermediate layer.

For instance, a blocking layer is optionally provided adjacent to the emitting layer close to the cathode. Preferably, the blocking layer provided on the side of the emitting layer close to the cathode is in direct contact with the emitting layer. Preferably, the blocking layer on the side of the emitting layer close to the cathode blocks at least one of holes or excitons.

For instance, when the blocking layer is provided in contact with the side of the emitting layer close to the cathode, the blocking layer permits transport of electrons, and blocks holes from reaching a layer provided closer to the cathode (e.g., the electron transporting layer) beyond the blocking layer. When the organic EL device includes the electron transporting layer, the blocking layer is preferably disposed between the emitting layer and the electron transporting layer.

Alternatively, the blocking layer may be provided adjacent to the emitting layer so that excitation energy does not leak out from the emitting layer toward neighboring layer(s). The blocking layer blocks excitons generated in the emitting layer from being transferred to a layer(s) (e.g., the electron transporting layer and the hole transporting layer) closer to the electrode(s) beyond the blocking layer.

The emitting layer is preferably bonded with the blocking layer.

Specific structure, shape and the like of the components in the invention may be designed in any manner as long as an object of the invention can be achieved.

### EXAMPLES

The following describes the invention in further detail by providing examples. The invention is by no means limited to these examples.

### Compounds

The structures of the compounds represented by formula (1) used in the production of the organic EL devices according to Examples 1 to 17 are presented below.

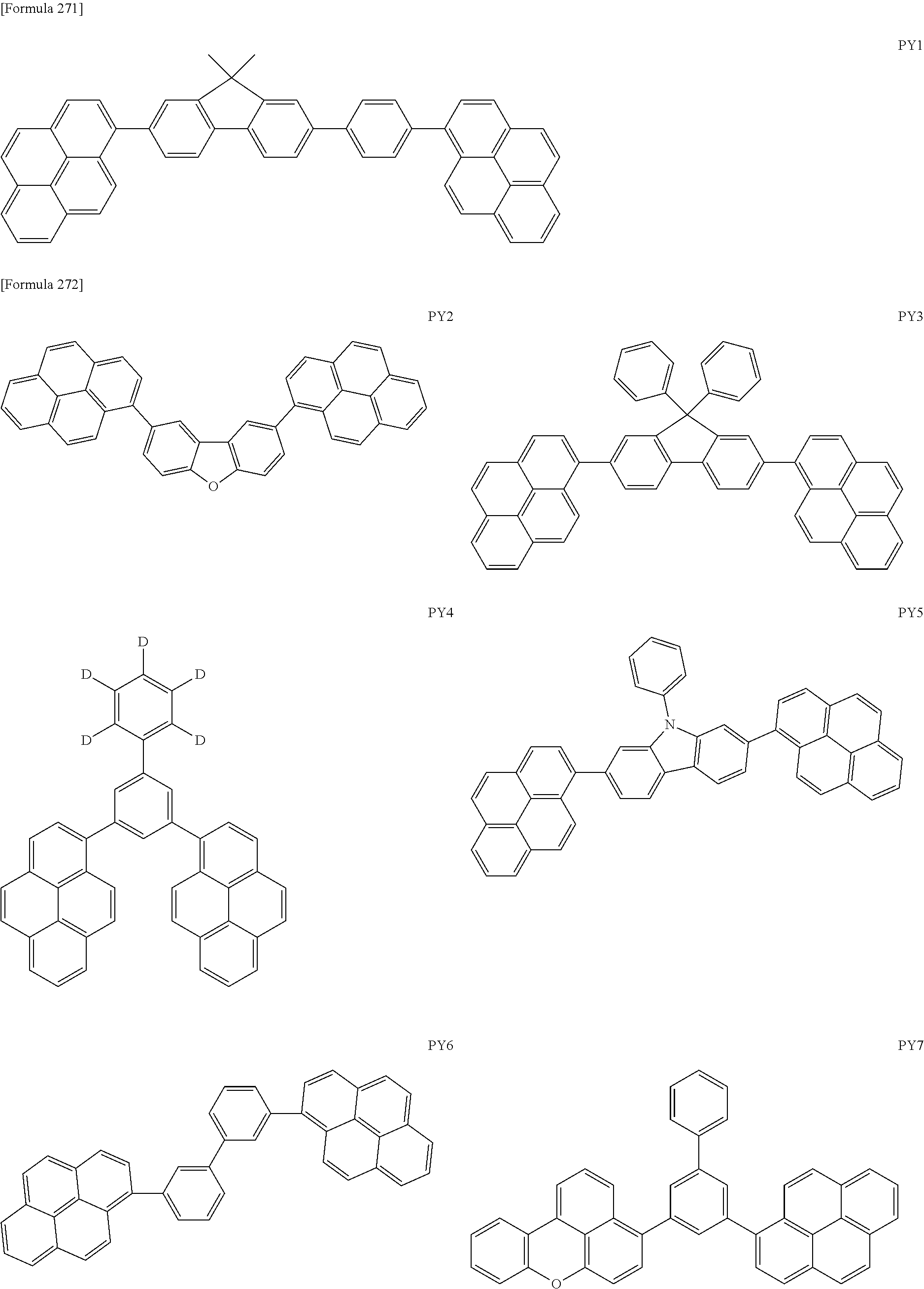

The structures of the other compounds used in the production of the organic EL devices according to Examples 1 to 17 and Comparative Examples 1 to 22 are presented below.

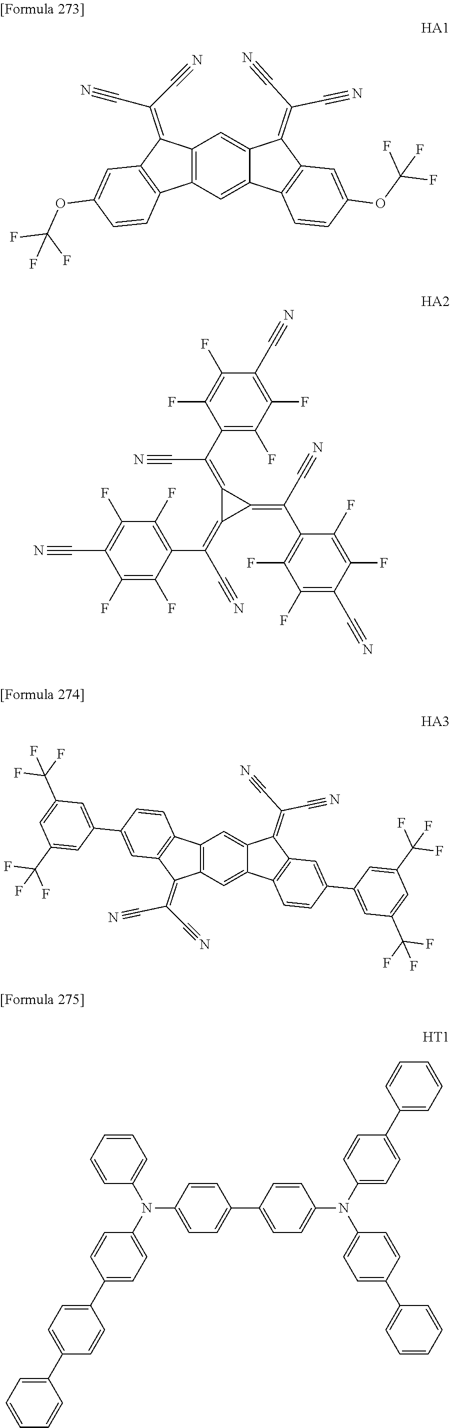 [SMILES: N#CC(C#N)=C1c2cc(OC(F)(F)F)ccc2-c2cc3c(cc21)C(=C(C#N)C#N)c1cc(OC(F)(F)F)ccc1-3 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC(C#N)=C1c2cc(-c3cc(C(F)(F)F)cc(C(F)(F)F)c3)ccc2-c2cc3c(cc21)-c1ccc(-c2cc(C(F)(F)F)cc(C(F)(F)F)c2)cc1C3=C(C#N)C#N ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

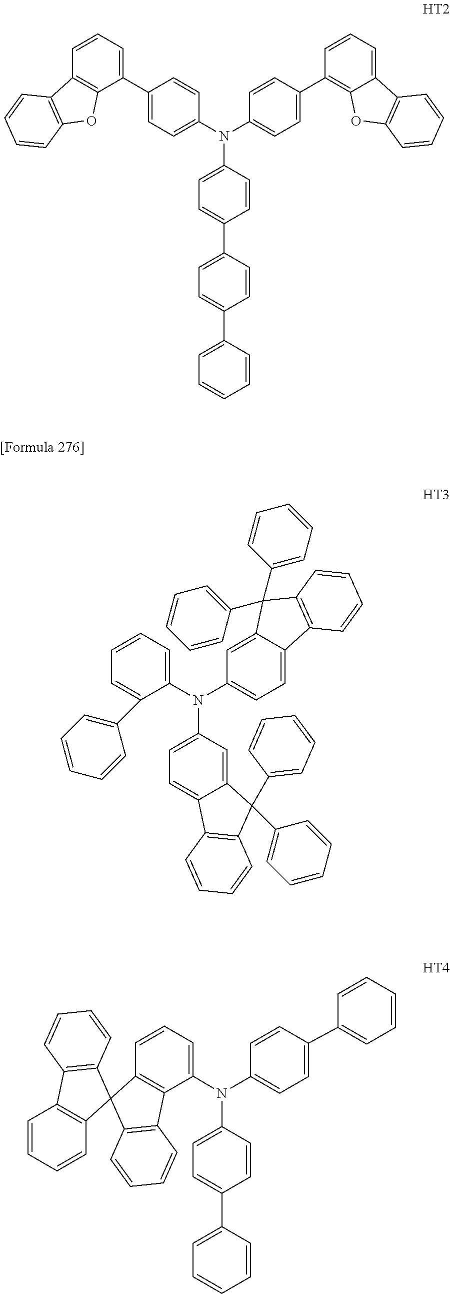 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; c1ccc(-c2ccc(N(c3ccc(-c4ccccc4)cc3)c3cccc4c3-c3ccccc3C43c4ccccc4-c4ccccc43)cc2)cc1]

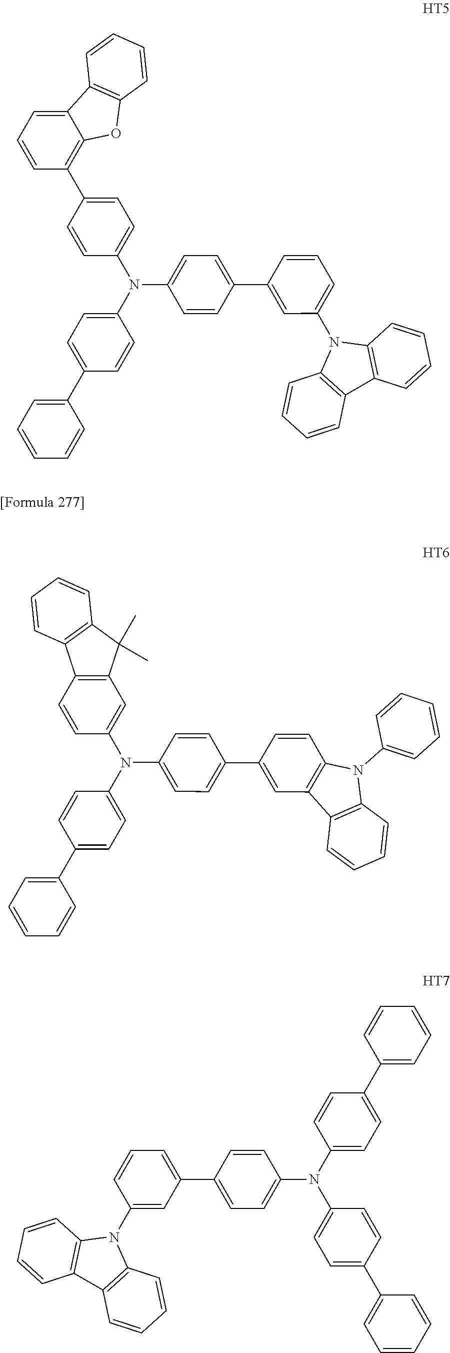 [SMILES: c1ccc(-c2ccc(N(c3ccc(-c4cccc(-n5c6ccccc6c6ccccc65)c4)cc3)c3ccc(-c4cccc5c4oc4ccccc45)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4ccccc4)cc3)c3ccc(-c4cccc(-n5c6ccccc6c6ccccc65)c4)cc3)cc2)cc1]

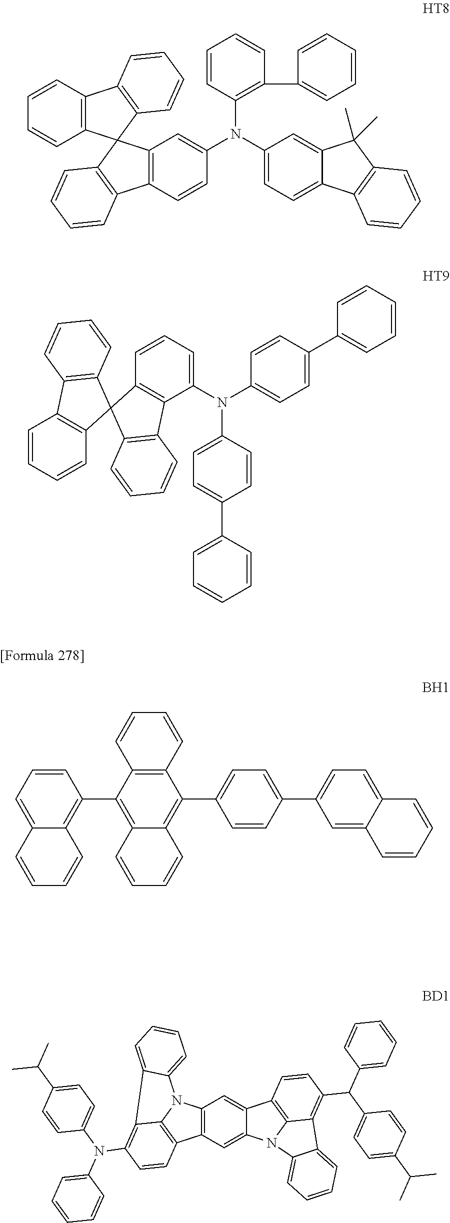

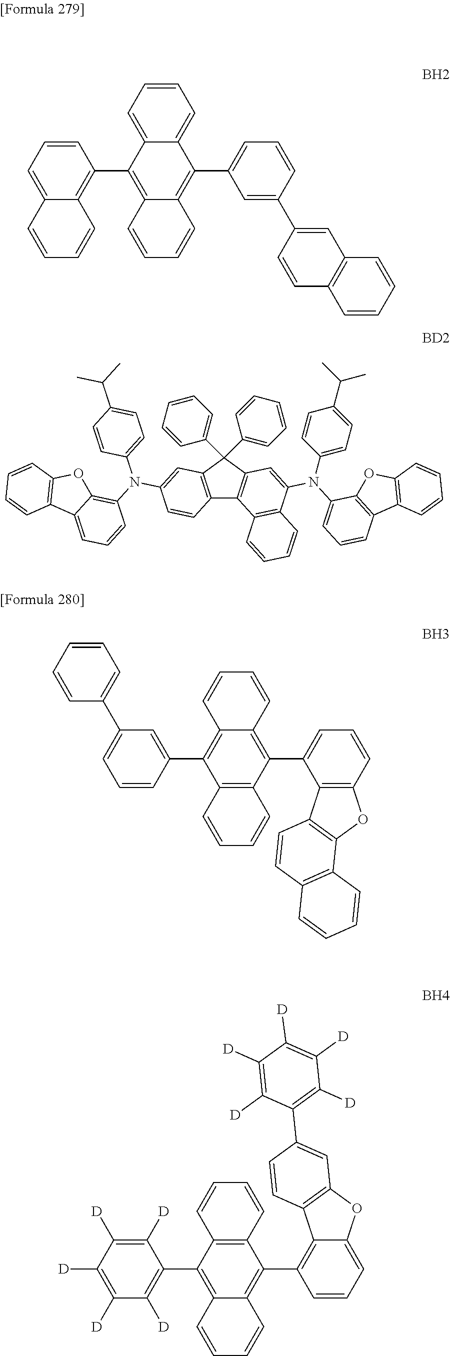

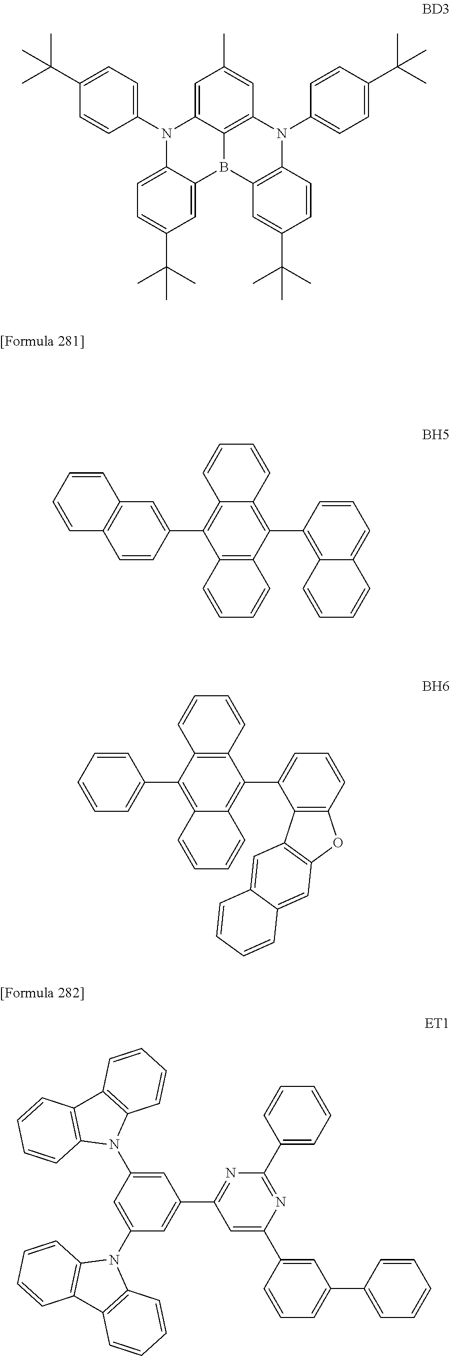

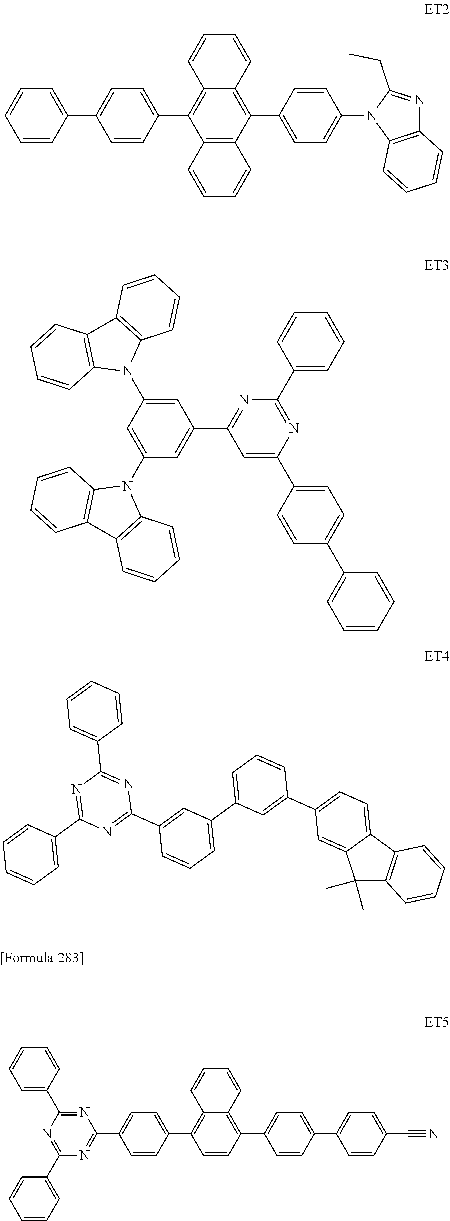 [SMILES: CCc1nc2ccccc2n1-c1ccc(-c2c3ccccc3c(-c3ccc(-c4ccccc4)cc3)c3ccccc23)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; CC1(C)c2ccccc2-c2ccc(-c3cccc(-c4cccc(-c5nc(-c6ccccc6)nc(-c6ccccc6)n5)c4)c3)cc21 ; N#Cc1ccc(-c2ccc(-c3ccc(-c4ccc(-c5nc(-c6ccccc6)nc(-c6ccccc6)n5)cc4)c4ccccc34)cc2)cc1]

### Fabrication of Organic EL Devices 1

Organic EL devices were fabricated as follows and tested.

### Example 1

A 25 mm×75 mm×1.1 mm thick glass substrate with an ITO (Indium Tin Oxide) transparent electrode (anode) (Geomatec Co., Ltd.) was ultrasonic-cleaned in isopropyl alcohol for 5 minutes and then cleaned with UV ozone for 30 minutes. The thickness of the ITO transparent electrode was 130 nm.

The cleaned glass substrate with a transparent electrode line was attached to the substrate holder of a vacuum deposition system. Then, first, a 5-nm thick hole injecting layer was formed by depositing compound HA1 on the surface on the transparent electrode line side to cover the transparent electrode.

Following the formation of the hole injecting layer, an 80-nm thick third hole transporting layer was formed by depositing compound HT1.

Following the formation of the third hole transporting layer, a 10-nm thick second hole transporting layer was formed by depositing compound HT2.

Following the formation of the second hole transporting layer, a 5-nm first hole transporting layer was formed by depositing compound PY1.

A 25-nm thick emitting layer was formed by co-depositing compound BH1 (host material (BH)) and compound BD1 (dopant material (BD)) on the first hole transporting layer in such a manner that the proportion of compound BD1 would be 2% by mass.

A 10-nm thick first electron transporting layer (also referred to as the hole blocking layer) (HBL) was formed by depositing compound ET1 on the emitting layer.

A 15-nm thick second electron transporting layer (ET) was formed by depositing compound ET2 on the first electron transporting layer.

A 1-nm thick electron injecting layer was formed by depositing LiF on the second electron transporting layer.

An 80-nm thick cathode was formed by depositing metal Al on the electron injecting layer.

A brief description of the device structure in Example 1 is as follows.

ITO (130)/HA1 (5)/HT1 (80)/HT2 (10)/PY1 (5)/BH1:BD1 (25, 98%:2%)/ET1 (10)/ET2 (15)/LiF (1)/Al (80)

The number in parentheses indicates the thickness of the layer (unit: nm).

Likewise, the percentages in parentheses (98%:2%) indicate the proportions of the host material (compound BH1) and compound BD1 in the emitting layer (% by mass). The same applies hereinafter.

### Comparative Example 1

The organic EL device of Comparative Example 1 was fabricated in the same way as in Example 1, except that the thickness of the second hole transporting layer was changed to that in Table 1 and that the emitting layer was formed in direct contact with the second hole transporting layer instead of forming the first hole transporting layer.

### Example 2

A 25 mm×75 mm×1.1 mm thick glass substrate with an ITO (Indium Tin Oxide) transparent electrode (anode) (Geomatec Co., Ltd.) was ultrasonic-cleaned in isopropyl alcohol for 5 minutes and then cleaned with UV ozone for 30 minutes. The thickness of the ITO transparent electrode was 130 nm.

The cleaned glass substrate with a transparent electrode line was attached to the substrate holder of a vacuum deposition system. Then, first, a 10-nm thick hole injecting layer was formed by co-depositing compounds HT3 and HA2 on the surface on the transparent electrode line side to cover the transparent electrode. In this hole injecting layer, the proportion of the compound HT3 was 97% by mass, and that of compound HA2 was 3% by mass.

Following the formation of the hole injecting layer, an 80-nm thick third hole transporting layer was formed by depositing compound HT3.

Following the formation of the third hole transporting layer, a 10-nm thick second hole transporting layer was formed by depositing compound HT4.

Following the formation of the second hole transporting layer, a 5-nm first hole transporting layer was formed by depositing compound PY1.

A 20-nm thick emitting layer was formed by co-depositing compound BH2 (host material (BH)) and compound BD2 (dopant material (BD)) on the first hole transporting layer in such a manner that the proportion of compound BD2 would be 4% by mass.

A 10-nm thick first electron transporting layer (also referred to as the hole blocking layer) (HBL) was formed by depositing compound ET1 on the emitting layer.

A 15-nm thick second electron transporting layer (ET) was formed by depositing compound ET2 on the first electron transporting layer.

A 1-nm thick electron injecting layer was formed by depositing LiF on the second electron transporting layer.

An 80-nm thick cathode was formed by depositing metal Al on the electron injecting layer.

A brief description of the device structure in Example 2 is as follows.

ITO (130)/HT3:HA2 (10, 97%:3%)/HT3 (80)/HT4 (10)/PY1 (5)/BH2:BD2 (20, 96%:4%)/ET1 (10)/ET2 (15)/LiF (1)/Al (80)

The number in parentheses indicates the thickness of the layer (unit: nm).

Likewise, a set of percentages in parentheses (97%:3%) indicate the proportions of compounds HT3 and HA2 in the hole injecting layer (% by mass), and another (96%:4%) indicates the proportions of the host material (compound BH2) and compound BD2 in the emitting layer (% by mass). The same applies hereinafter.

### Comparative Example 2

The organic EL device of Comparative Example 2 was fabricated in the same way as in Example 2, except that the emitting layer was formed in direct contact with the second hole transporting layer instead of forming the first hole transporting layer and that the thickness of the emitting layer was changed to that in Table 2.

### Example 3

A 25 mm×75 mm×1.1 mm thick glass substrate with an ITO (Indium Tin Oxide) transparent electrode (anode) (Geomatec Co., Ltd.) was ultrasonic-cleaned in isopropyl alcohol for 5 minutes and then cleaned with UV ozone for 30 minutes. The thickness of the ITO transparent electrode was 130 nm.

The cleaned glass substrate with a transparent electrode line was attached to the substrate holder of a vacuum deposition system. Then, first, a 10-nm thick hole injecting layer was formed by co-depositing compounds HT3 and HA2 on the surface on the transparent electrode line side to cover the transparent electrode. In this hole injecting layer, the proportion of compound HT3 was 97% by mass, and that of compound HA2 was 3% by mass.

Following the formation of the hole injecting layer, an 80-nm thick third hole transporting layer was formed by depositing compound HT3.

Following the formation of the third hole transporting layer, a 10-nm thick second hole transporting layer was formed by depositing compound HT4.

Following the formation of the second hole transporting layer, a 5-nm first hole transporting layer was formed by depositing compound PY1.

A 20-nm thick emitting layer was formed by co-depositing compound BH2 (host material (BH)) and compound BD2 (dopant material (BD)) on the first hole transporting layer in such a manner that the proportion of compound BD2 would be 4% by mass.

A 10-nm thick first electron transporting layer (also referred to as the hole blocking layer) (HBL) was formed by depositing compound ET3 on the emitting layer.

A 15-nm thick second electron transporting layer (ET) was formed by depositing compound ET2 on the first electron transporting layer.

A 1-nm thick electron injecting layer was formed by depositing LiF on the second electron transporting layer.

An 80-nm thick cathode was formed by depositing metal Al on the electron injecting layer.

A brief description of the device structure in Example 3 is as follows.

ITO (130)/HT3:HA2 (10, 97%:3%)/HT3 (80)/HT4 (10)/PY1 (5)/BH2:BD2 (20, 96%:4%)/ET3 (10)/ET2 (15)/LiF (1)/Al (80)

The number in parentheses indicates the thickness of the layer (unit: nm).

Likewise, a set of percentages in parentheses (97%:3%) indicate the proportions of compounds HT3 and HA2 in the hole injecting layer (% by mass), and another (96%:4%) indicates the proportions of the host material (compound BH2) and compound BD2 in the emitting layer (% by mass). The same applies hereinafter.

### Comparative Example 3

The organic EL device of Comparative Example 3 was fabricated in the same way as in Example 3, except that the emitting layer was formed in direct contact with the second hole transporting layer instead of forming the first hole transporting layer, and that the thickness of the emitting layer was changed to that in Table 3.

### Example 4

A 25 mm×75 mm×1.1 mm thick glass substrate with an ITO (Indium Tin Oxide) transparent electrode (anode) (Geomatec Co., Ltd.) was ultrasonic-cleaned in isopropyl alcohol for 5 minutes and then cleaned with UV ozone for 30 minutes. The thickness of the ITO transparent electrode was 130 nm.

The cleaned glass substrate with a transparent electrode line was attached to the substrate holder of a vacuum deposition system. Then, first, a 10-nm thick hole injecting layer was formed by co-depositing compounds HT3 and HA2 on the surface on the transparent electrode line side to cover the transparent electrode. In this hole injecting layer, the proportion of compound HT3 was 97% by mass, and that of compound HA2 was 3% by mass.

Following the formation of the hole injecting layer, an 80-nm thick third hole transporting layer was formed by depositing compound HT3.

Following the formation of the third hole transporting layer, a 10-nm thick second hole transporting layer was formed by depositing compound HT5.

Following the formation of the second hole transporting layer, a 5-nm first hole transporting layer was formed by depositing compound PY1.

A 20-nm thick emitting layer was formed by co-depositing compound BH2 (host material (BH)) and compound BD2 (dopant material (BD)) on the first hole transporting layer in such a manner that the proportion of compound BD2 would be 4% by mass.

A 10-nm thick first electron transporting layer (also referred to as the hole blocking layer) (HBL) was formed by depositing compound ET1 on the emitting layer.

A 15-nm thick second electron transporting layer (ET) was formed by depositing compound ET2 on the first electron transporting layer.

A 1-nm thick electron injecting layer was formed by depositing LiF on the second electron transporting layer.

An 80-nm thick cathode was formed by depositing metal Al on the electron injecting layer.

A brief description of the device structure in Example 4 is as follows.

ITO (130)/HT3:HA2 (10, 97%:3%)/HT3 (80)/HT5 (10)/PY1 (5)/BH2:BD2 (20, 96%:4%)/ET1 (10)/ET2 (15)/LiF (1)/Al (80)

The number in parentheses indicates the thickness of the layer (unit: nm).

Likewise, a set of percentages in parentheses (97%:3%) indicate the proportions of compounds HT3 and HA2 in the hole injecting layer (% by mass), and another (96%:4%) indicates the proportions of the host material (compound BH2) and compound BD2 in the emitting layer (% by mass). The same applies hereinafter.

### Comparative Example 4

The organic EL device of Comparative Example 4 was fabricated in the same way as in Example 4, except that the emitting layer was formed in direct contact with the second hole transporting layer instead of forming the first hole transporting layer, and that the thickness of the emitting layer was changed to that in Table 4.

### Example 5

A 25 mm×75 mm×1.1 mm thick glass substrate with an ITO (Indium Tin Oxide) transparent electrode (anode) (Geomatec Co., Ltd.) was ultrasonic-cleaned in isopropyl alcohol for 5 minutes and then cleaned with UV ozone for 30 minutes. The thickness of the ITO transparent electrode was 130 nm.

The cleaned glass substrate with a transparent electrode line was attached to the substrate holder of a vacuum deposition system. Then, first, a 10-nm thick hole injecting layer was formed by co-depositing compounds HT3 and HA2 on the surface on the transparent electrode line side to cover the transparent electrode. In this hole injecting layer, the proportion of compound HT3 was 97% by mass, and that of compound HA2 was 3% by mass.

Following the formation of the hole injecting layer, an 80-nm thick third hole transporting layer was formed by depositing compound HT3.

Following the formation of the third hole transporting layer, a 10-nm thick second hole transporting layer was formed by depositing compound HT5.

Following the formation of the second hole transporting layer, a 5-nm first hole transporting layer was formed by depositing compound PY1.

A 20-nm thick emitting layer was formed by co-depositing compound BH2 (host material (BH)) and compound BD2 (dopant material (BD)) on the first hole transporting layer in such a manner that the proportion of compound BD2 would be 4% by mass.

A 10-nm thick first electron transporting layer (also referred to as the hole blocking layer) (HBL) was formed by depositing compound ET3 on the emitting layer.

A 15-nm thick second electron transporting layer (ET) was formed by depositing compound ET2 on the first electron transporting layer.

A 1-nm thick electron injecting layer was formed by depositing LiF on the second electron transporting layer.

An 80-nm thick cathode was formed by depositing metal Al on the electron injecting layer.

A brief description of the device structure in Example 5 is as follows.

ITO (130)/HT3:HA2 (10, 97%:3%)/HT3 (80)/HT5 (10)/PY1 (5)/BH2:BD2 (20, 96%:4%)/ET3 (10)/ET2 (15)/LiF (1)/Al (80)

The number in parentheses indicates the thickness of the layer (unit: nm).

Likewise, a set of percentages in parentheses (97%:3%) indicate the proportions of compounds HT3 and HA2 in the hole injecting layer (% by mass), and another (96%:4%) indicates the proportions of the host material (compound BH2) and compound BD2 in the emitting layer (% by mass). The same applies hereinafter.

### Comparative Example 5

The organic EL device of Comparative Example 5 was fabricated in the same way as in Example 5, except that the emitting layer was formed in direct contact with the second hole transporting layer instead of forming the first hole transporting layer and that the thickness of the emitting layer was changed to that in Table 5.

### Comparative Example 6

The organic EL device of Comparative Example 6 was fabricated in the same way as in Example 1, except that instead of forming the third and second hole transporting layers, the first hole transporting layer was formed to the thickness in Table 1 following the formation of the hole injecting layer.

### Comparative Example 7

The organic EL device of Comparative Example 7 was fabricated in the same way as in Example 2, except that instead of forming the third and second hole transporting layers, the first hole transporting layer was formed to the thickness in Table 2 following the formation of the hole injecting layer.

### Comparative Example 8

The organic EL device of Comparative Example 8 was fabricated in the same way as in Example 3, except that instead of forming the third and second hole transporting layers, the first hole transporting layer was formed to the thickness in Table 3 following the formation of the hole injecting layer.

### Testing of the Organic EL Devices

The organic EL devices fabricated in Examples 1 to 17 and Comparative Examples 1 to 22 were tested as follows. The test results are presented in Tables 1 to 13.

### Drive Voltage

A voltage was applied across the cathode and the anode to a current density of 10 mA/cm² and measured (unit: V).

TABLE 1

| | Second hole | | First hole | | | | First electron | | |
|---|---|---|---|---|---|---|---|---|---|
| | transporting layer | | transporting layer | | Emitting layer | | transporting layer | | Drive |
| | Com- | Thickness | Com- | Thickness | | Thickness | | Thickness | voltage |
| | pound | [nm] | pound | [nm] | Compounds | [nm] | Compound | [nm] | [V] |
| Example 1 | HT2 | 10 | PY1 | 5 | BH1 and BD1 | 25 | ET1 | 10 | 4.9 |
| Comparative | HT2 | 15 | None | 0 | BH1 and BD1 | 25 | ET1 | 10 | 5.3 |
| Example 1 | | | | | | | | | |
| Comparative | None | 0 | PY1 | 95 | BH1 and BD1 | 25 | ET1 | 10 | 6.1 |
| Example 6 | | | | | | | | | |

TABLE 2

| | Second hole | | First hole | | | | First electron | | |
|---|---|---|---|---|---|---|---|---|---|
| | transporting layer | | transporting layer | | Emitting layer | | transporting layer | | Drive |
| | Com- | Thickness | Com- | Thickness | | Thickness | | Thickness | voltage |
| | pound | [nm] | pound | [nm] | Compounds | [nm] | Compound | [nm] | [V] |
| Example 2 | HT4 | 10 | PY1 | 5 | BH2 and BD2 | 20 | ET1 | 10 | 4.9 |
| Comparative | HT4 | 10 | None | 0 | BH2 and BD2 | 25 | ET1 | 10 | 5.3 |
| Example 2 | | | | | | | | | |
| Comparative | None | 0 | PY1 | 95 | BH2 and BD2 | 25 | ET1 | 10 | 6.1 |
| Example 7 | | | | | | | | | |

TABLE 3

| | Second hole | | First hole | | | | First electron | | |
|---|---|---|---|---|---|---|---|---|---|
| | transporting layer | | transporting layer | | Emitting layer | | transporting layer | | Drive |
| | Com- | Thickness | Com- | Thickness | | Thickness | | Thickness | voltage |
| | pound | [nm] | pound | [nm] | Compounds | [nm] | Compound | [nm] | [V] |
| Example 3 | HT4 | 10 | PY1 | 5 | BH2 and BD2 | 20 | ET3 | 10 | 5.0 |
| Comparative | HT4 | 10 | None | 0 | BH2 and BD2 | 25 | ET3 | 10 | 5.5 |
| Example 3 | | | | | | | | | |
| Comparative | None | 0 | PY1 | 95 | BH2 and BD2 | 25 | ET3 | 10 | 6.4 |
| Example 8 | | | | | | | | | |

TABLE 4

| | Second hole | | First hole | | | | First electron | | |
|---|---|---|---|---|---|---|---|---|---|
| | transporting layer | | transporting layer | | Emitting layer | | transporting layer | | Drive |
| | Com- | Thickness | Com- | Thickness | | Thickness | | Thickness | voltage |
| | pound | [nm] | pound | [nm] | Compounds | [nm] | Compound | [nm] | [V] |
| Example 4 | HT5 | 10 | PY1 | 5 | BH2 and BD2 | 20 | ET1 | 10 | 5.1 |
| Comparative | HT5 | 10 | None | 0 | BH2 and BD2 | 25 | ET1 | 10 | 5.4 |
| Example 4 | | | | | | | | | |
| Comparative | None | 0 | PY1 | 95 | BH2 and BD2 | 25 | ET1 | 10 | 6.1 |
| Example 7 | | | | | | | | | |

TABLE 5

| | Second hole | | First hole | | | | First electron | | |
|---|---|---|---|---|---|---|---|---|---|
| | transporting layer | | transporting layer | | Emitting layer | | transporting layer | | Drive |
| | Com- | Thickness | Com- | Thickness | | Thickness | | Thickness | voltage |
| | pound | [nm] | pound | [nm] | Compounds | [nm] | Compound | [nm] | [V] |
| Example 5 | HT5 | 10 | PY1 | 5 | BH2 and BD2 | 20 | ET3 | 10 | 5.1 |
| Comparative | HT5 | 10 | None | 0 | BH2 and BD2 | 25 | ET3 | 10 | 5.6 |
| Example 5 | | | | | | | | | |
| Comparative | None | 0 | PY1 | 95 | BH2 and BD2 | 25 | ET3 | 10 | 6.4 |
| Example 8 | | | | | | | | | |

As shown in Tables 1 to 5, the organic EL devices according to Examples 1 to 5 had a first hole transporting layer containing a first compound represented by formula (1) in direct contact with the emitting layer. Their drive voltage was lower than that of the devices according to Comparative Examples 1 to 5, which had a second hole transporting layer containing a material having an amine skeleton in direct contact with the emitting layer. As well as having a first hole transporting layer containing a first compound represented by formula (1) in direct contact with the emitting layer, furthermore, the organic EL devices according to Examples 1 to 5 had a second hole transporting layer containing a compound having an amino group in direct contact with the first hole transporting layer. Their drive voltage was lower than that of the devices according to Comparative Examples 6 to 8, which had the hole injecting layer in direct contact with the first hole transporting layer.

### Fabrication of Organic EL Devices 2

### Example 6

A 25 mm×75 mm×1.1 mm thick glass substrate with an ITO (Indium Tin Oxide) transparent electrode (anode) (Geomatec Co., Ltd.) was ultrasonic-cleaned in isopropyl alcohol for 5 minutes and then cleaned with UV ozone for 30 minutes. The thickness of the ITO transparent electrode was 130 nm.

The cleaned glass substrate with a transparent electrode line was attached to the substrate holder of a vacuum deposition system. Then, first, a 10-nm thick hole injecting layer was formed by co-depositing compounds HT6 and HA2 on the surface on the transparent electrode line side to cover the transparent electrode. In this hole injecting layer, the proportion of the compound HT6 was 97% by mass, and that of compound HA2 was 3% by mass.

Following the formation of the hole injecting layer, an 85-nm thick third hole transporting layer was formed by depositing compound HT6.

Following the formation of the third hole transporting layer, a 2.5-nm thick second hole transporting layer was formed by depositing compound HT7.

Following the formation of the second hole transporting layer, a 2.5-nm first hole transporting layer was formed by depositing compound PY2.

A 20-nm thick emitting layer was formed by co-depositing compound BH3 (host material (BH)) and compound BD3 (dopant material (BD)) on the first hole transporting layer in such a manner that the proportion of compound BD3 would be 2% by mass.

A 5-nm thick first electron transporting layer (also referred to as the hole blocking layer) (HBL) was formed by depositing compound ET4 on the emitting layer.

A 25-nm thick second electron transporting layer (ET) was formed by co-depositing compound ET5 and the compound Liq on the first electron transporting layer (HBL). In this second electron transporting layer (ET), the proportion of compound ET5 was 50% by mass, and that of the compound Liq was 50% by mass. Liq is short for (8-quinolinolato)lithium.

A 1-nm thick electron injecting layer was formed by depositing Liq on the second electron transporting layer.

An 80-nm thick cathode was formed by depositing metal Al on the electron injecting layer.

A brief description of the device structure in Example 6 is as follows.

ITO (130)/HT6:HA2 (10, 97%:3%)/HT6 (85)/HT7 (2.5)/PY2 (2.5)/BH3:BD3 (20, 98%:2%)/ET4 (5)/ET5:Liq (25, 50%:50%)/Liq (1)/Al (80)

The number in parentheses indicates the thickness of the layer (unit: nm).

Likewise, a set of percentages in parentheses (97%:3%) indicate the proportions of compounds HT6 and HA2 in the hole injecting layer (% by mass), another (98%:2%) indicates the proportions of the host material (compound BH3) and compound BD3 in the emitting layer (% by mass), and another (50%:50%) indicates the proportions of compound ET5 and Liq in the second electron transporting layer (ET) (% by mass). The same applies hereinafter.

### Comparative Example 9

The organic EL device of Comparative Example 9 was fabricated in the same way as in Example 6, except that the thickness of the second hole transporting layer was changed to that in Table 6, and that the emitting layer was formed in direct contact with the second hole transporting layer instead of forming the first hole transporting layer.

### Comparative Example 10

The organic EL device of Comparative Example 10 was fabricated in the same way as in Example 6, except that instead of forming the third and second hole transporting layers, the first hole transporting layer was formed to the thickness in Table 6 following the formation of the hole injecting layer.

TABLE 6

| | Third hole | | Second hole | | First hole | | | | |
|---|---|---|---|---|---|---|---|---|---|
| | transporting layer | | transporting layer | | transporting layer | | First emitting layer | | Drive |
| | Com- | Thickness | Com- | Thickness | Com- | Thickness | | Thickness | voltage |
| | pound | [nm] | pound | [nm] | pound | [nm] | Compounds | [nm] | [V] |
| Example 6 | HT6 | 85 | HT7 | 2.5 | PY2 | 2.5 | BH3 and BD3 | 20 | 3.3 |
| Comparative | HT6 | 85 | HT7 | 5 | None | 0 | BH3 and BD3 | 20 | 3.6 |
| Example 9 | | | | | | | | | |
| Comparative | None | 0 | None | 0 | PY2 | 90 | BH3 and BD3 | 20 | 4.8 |
| Example 10 | | | | | | | | | |

### Example 7

The organic EL device of Example 7 was fabricated in the same way as in Example 6, except that in the formation of the first hole transporting layer, the compound for the first hole transporting layer was changed to that in Table 7.

### Comparative Example 11

The organic EL device of Comparative Example 11 was fabricated in the same way as in Comparative Example 10, except that in the formation of the first hole transporting layer, compound PY2, for the first hole transporting layer, was changed to PY3 as in Table 7.

TABLE 7

| | Third hole | | Second hole | | First hole | | | | |
|---|---|---|---|---|---|---|---|---|---|
| | transporting layer | | transporting layer | | transporting layer | | Emitting layer | | Drive |
| | Com- | Thickness | Com- | Thickness | Com- | Thickness | | Thickness | voltage |
| | pound | [nm] | pound | [nm] | pound | [nm] | Compounds | [nm] | [V] |
| Example 7 | HT6 | 85 | HT7 | 2.5 | PY3 | 2.5 | BH3 and BD3 | 20 | 3.4 |
| Comparative | HT6 | 85 | HT7 | 5 | None | 0 | BH3 and BD3 | 20 | 3.6 |
| Example 9 | | | | | | | | | |
| Comparative | None | 0 | None | 0 | PY3 | 90 | BH3 and BD3 | 20 | 4.6 |
| Example 11 | | | | | | | | | |

### Example 8

The organic EL device of Example 8 was fabricated in the same way as in Example 6, except that in the formation of the first hole transporting layer, compound PY2, for the first hole transporting layer, was changed to compound PY4 as in Table 8 and that in the formation of the emitting layer, furthermore, compound BH3, for the emitting layer, was changed to compound BH4 as in Table 8.

### Comparative Example 12

The organic EL device of Comparative Example 12 was fabricated in the same way as in Comparative Example 9, except that in the formation of the emitting layer, compound BH3, for the emitting layer, was changed to compound BH4 as in Table 8.

### Comparative Example 13

The organic EL device of Comparative Example 13 was fabricated in the same way as in Comparative Example 10, except that in the formation of the first hole transporting layer, compound PY2, for the first hole transporting layer, was changed to compound PY4 as in Table 8 and that in the formation of the emitting layer, furthermore, compound BH3, for the emitting layer, was changed to compound BH4 as in Table 8.

TABLE 8

| | Third hole | | Second hole | | First hole | | | | |
|---|---|---|---|---|---|---|---|---|---|
| | transporting layer | | transporting layer | | transporting layer | | Emitting layer | | Drive |
| | Com- | Thickness | Com- | Thickness | Com- | Thickness | | Thickness | voltage |
| | pound | [nm] | pound | [nm] | pound | [nm] | Compounds | [nm] | [V] |
| Example 8 | HT6 | 85 | HT7 | 2.5 | PY4 | 2.5 | BH4 and BD3 | 20 | 3.5 |
| Comparative | HT6 | 85 | HT7 | 5 | None | 0 | BH4 and BD3 | 20 | 3.8 |
| Example 12 | | | | | | | | | |
| Comparative | None | 0 | None | 0 | PY4 | 90 | BH4 and BD3 | 20 | 5.3 |
| Example 13 | | | | | | | | | |

### Example 9

The organic EL device of Example 9 was fabricated in the same way as in Example 8, except that in the formation of the first hole transporting layer, compound PY4, for the first hole transporting layer, was changed to compound PY5 as in Table 9.

### Comparative Example 14

The organic EL device of Comparative Example 14 was fabricated in the same way as in Comparative Example 13, except that in the formation of the first hole transporting layer, compound PY4, for the first hole transporting layer, was changed to compound PY5 as in Table 9.

TABLE 9

| | Third hole | | Second hole | | First hole | | | | |
|---|---|---|---|---|---|---|---|---|---|
| | transporting layer | | transporting layer | | transporting layer | | Emitting layer | | Drive |
| | Com- | Thickness | Com- | Thickness | Com- | Thickness | | Thickness | voltage |
| | pound | [nm] | pound | [nm] | pound | [nm] | Compounds | [nm] | [V] |
| Example 9 | HT6 | 85 | HT7 | 2.5 | PY5 | 2.5 | BH4 and BD3 | 20 | 3.1 |
| Comparative | HT6 | 85 | HT7 | 5 | None | 0 | BH4 and BD3 | 20 | 3.8 |
| Example 12 | | | | | | | | | |
| Comparative | None | 0 | None | 0 | PY5 | 90 | BH4 and BD3 | 20 | 4.4 |
| Example 14 | | | | | | | | | |

### Example 10

A 25 mm×75 mm×1.1 mm thick glass substrate with an ITO (Indium Tin Oxide) transparent electrode (anode) (Geomatec Co., Ltd.) was ultrasonic-cleaned in isopropyl alcohol for 5 minutes and then cleaned with UV ozone for 30 minutes. The thickness of the ITO transparent electrode was 130 nm.

The cleaned glass substrate with a transparent electrode line was attached to the substrate holder of a vacuum deposition system. Then, first, a 10-nm thick hole injecting layer was formed by co-depositing compounds HT6 and HA2 on the surface on the transparent electrode line side to cover the transparent electrode. In this hole injecting layer, the proportion of the compound HT6 was 97% by mass, and that of compound HA2 was 3% by mass.

Following the formation of the hole injecting layer, an 80-nm thick third hole transporting layer was formed by depositing compound HT6.

Following the formation of the third hole transporting layer, a 2.5-nm thick second hole transporting layer was formed by depositing compound HT7.

Following the formation of the second hole transporting layer, a 2.5-nm first hole transporting layer was formed by depositing compound PY2.

A 12.5-nm thick first emitting layer was formed by co-depositing compound PY2 (host material) and compound BD3 (dopant material) on the first hole transporting layer in such a manner that the proportion of compound BD3 would be 2% by mass.

A 12.5-nm thick second emitting layer was formed by co-depositing compound BH3 (host material) and compound BD3 (dopant material) on the first emitting layer in such a manner that the proportion of compound BD3 would be 2% by mass.

A 5-nm thick first electron transporting layer (also referred to as the hole blocking layer) (HBL) was formed by depositing compound ET4 on the second emitting layer.

A 25-nm thick second electron transporting layer (ET) was formed by co-depositing compound ET5 and the compound Liq on the first electron transporting layer (HBL). In this second electron transporting layer (ET), the proportion of compound ET5 was 50% by mass, and that of the compound Liq was 50% by mass.

A 1-nm thick electron injecting layer was formed by depositing Liq on the second electron transporting layer.

An 80-nm thick cathode was formed by depositing metal Al on the electron injecting layer.

A brief description of the device structure in Example 10 is as follows.

ITO (130)/HT6:HA2 (10, 97%:3%)/HT6 (80)/HT7 (2.5)/PY2 (2.5)/PY2:BD3 (12.5, 98%:2%)/BH3:BD3 (12.5, 98%:2%)/ET4 (5)/ET5:Liq (25, 50%:50%)/Liq (1)/Al (80)

The number in parentheses indicates the thickness of the layer (unit: nm).

Likewise, a set of percentages in parentheses (97%:3%) indicate the proportions of compounds HT6 and HA2 in the hole injecting layer (% by mass), other two (98%:2%) indicate the proportions of the host material (compound PY2 or BH3) and compound BD3 in the emitting layers (% by mass), and another (50%:50%) indicates the proportions of compound ET5 and Liq in the second electron transporting layer (ET) (% by mass). The same applies hereinafter.

### Example 11

The organic EL device of Example 11 was fabricated in the same way as in Example 10, except that the thickness of the second hole transporting layer and that of the first hole transporting layer were changed to those in Table 10.

### Comparative Example 15

The organic EL device of Comparative Example 15 was fabricated in the same way as in Example 10, except that the thickness of the second hole transporting layer was changed to that in Table 10 and that the first emitting layer was formed in direct contact with the second hole transporting layer instead of forming the first hole transporting layer.

### Comparative Example 16

The organic EL device of Comparative Example 16 was fabricated in the same way as in Example 10, except that instead of forming the third and second hole transporting layers, the first hole transporting layer was formed to the thickness in Table 10 following the formation of the hole injecting layer.

TABLE 10

| | Third hole | | Second hole | | First hole | | First | | Second | | |
|---|---|---|---|---|---|---|---|---|---|---|---|
| | transporting layer | | transporting layer | | transporting layer | | emitting layer | | emitting layer | | Drive |
| | Com- | Thickness | Com- | Thickness | Com- | Thickness | Com- | Thickness | Com- | Thickness | voltage |
| | pound | [nm] | pound | [nm] | pound | [nm] | pounds | [nm] | pounds | [nm] | [V] |
| Example 10 | HT6 | 80 | HT7 | 2.5 | PY2 | 2.5 | PY2 and | 12.5 | BH3 and | 12.5 | 3.0 |
| | | | | | | | BD3 | | BD3 | | |
| Example 11 | HT6 | 80 | HT7 | 4 | PY2 | 1 | PY2 and | 12.5 | BH3 and | 12.5 | 3.2 |
| | | | | | | | BD3 | | BD3 | | |
| Comparative | HT6 | 80 | HT7 | 5 | None | 0 | PY2 and | 12.5 | BH3 and | 12.5 | 3.5 |
| Example 15 | | | | | | | BD3 | | BD3 | | |
| Comparative | None | 0 | None | 0 | PY2 | 85 | PY2 and | 12.5 | BH3 and | 12.5 | 4.6 |
| Example 16 | | | | | | | BD3 | | BD3 | | |

### Example 12

A 25 mm×75 mm×1.1 mm thick glass substrate with an ITO (Indium Tin Oxide) transparent electrode (anode) (Geomatec Co., Ltd.) was ultrasonic-cleaned in isopropyl alcohol for 5 minutes and then cleaned with UV ozone for 30 minutes. The thickness of the ITO transparent electrode was 130 nm.

The cleaned glass substrate with a transparent electrode line was attached to the substrate holder of a vacuum deposition system. Then, first, a 10-nm thick hole injecting layer was formed by co-depositing compounds HT6 and HA2 on the surface on the transparent electrode line side to cover the transparent electrode. In this hole injecting layer, the proportion of the compound HT6 was 97% by mass, and that of compound HA2 was 3% by mass.

Following the formation of the hole injecting layer, an 80-nm thick third hole transporting layer was formed by depositing compound HT6.

Following the formation of the third hole transporting layer, a 4-nm thick second hole transporting layer was formed by depositing compound HT7.

Following the formation of the second hole transporting layer, a 1-nm first hole transporting layer was formed by depositing compound PY3.

A 10-nm thick first emitting layer was formed by co-depositing compound PY4 (host material) and compound BD3 (dopant material) on the first hole transporting layer in such a manner that the proportion of compound BD3 would be 2% by mass.

A 15-nm thick second emitting layer was formed by co-depositing compound BH4 (host material) and compound BD3 (dopant material) on the first emitting layer in such a manner that the proportion of compound BD3 would be 2% by mass.

A 5-nm thick first electron transporting layer (also referred to as the hole blocking layer) (HBL) was formed by depositing compound ET4 on the second emitting layer.

A 25-nm thick second electron transporting layer (ET) was formed by co-depositing compound ET5 and the compound Liq on the first electron transporting layer (HBL). In this second electron transporting layer (ET), the proportion of compound ET5 was 50% by mass, and that of the compound Liq was 50% by mass.

A 1-nm thick electron injecting layer was formed by depositing Liq on the second electron transporting layer.

An 80-nm thick cathode was formed by depositing metal Al on the electron injecting layer.

A brief description of the device structure in Example 12 is as follows.

ITO (130)/HT6:HA2 (10, 97%:3%)/HT6 (80)/HT7 (4)/PY3 (1)/PY4:BD3 (10, 98%:2%)/BH4:BD3 (15, 98%:2%)/ET4 (5)/ET5:Liq (25, 50%:50%)/Liq (1)/Al (80)

The number in parentheses indicates the thickness of the layer (unit: nm).

Likewise, a set of percentages in parentheses (97%:3%) indicate the proportions of compounds HT6 and HA2 in the hole injecting layer (% by mass), other two (98%:2%) indicate the proportions of the host material (compound PY4 or BH4) and compound BD3 in the emitting layers (% by mass), and another (50%:50%) indicates the proportions of compound ET5 and Liq in the second electron transporting layer (ET) (% by mass). The same applies hereinafter.

### Example 13

The organic EL device of Example 13 was fabricated in the same way as in Example 12, except that the thickness of the second hole transporting layer, that of the first hole transporting layer, and that of the first emitting layer were changed to those in Table 11.

### Comparative Example 17

The organic EL device of Comparative Example 17 was fabricated in the same way as in Example 12, except that the thickness of the second hole transporting layer was changed to that in Table 11 and that the first emitting layer was formed in direct contact with the second hole transporting layer instead of forming the first hole transporting layer.

### Comparative Example 18

The organic EL device of Comparative Example 18 was fabricated in the same way as in Example 12, except for the following. As in Table 11, instead of forming the third hole transporting layer, an 80-nm second hole transporting layer was formed by depositing compound PY2 following the formation of the hole injecting layer. Following the formation of the second hole transporting layer, a 5-nm thick first hole transporting layer was formed by depositing compound PY3.

TABLE 11

| | Third hole | | Second hole | | First hole | | First | | Second | | |
|---|---|---|---|---|---|---|---|---|---|---|---|
| | transporting layer | | transporting layer | | transporting layer | | emitting layer | | emitting layer | | Drive |
| | Com- | Thickness | Com- | Thickness | Com- | Thickness | Com- | Thickness | Com- | Thickness | voltage |
| | pound | [nm] | pound | [nm] | pound | [nm] | pounds | [nm] | pounds | [nm] | [V] |
| Example 12 | HT6 | 80 | HT7 | 4 | PY3 | 1 | PY4 and | 10 | BH4 and | 15 | 3.2 |
| | | | | | | | BD3 | | BD3 | | |
| Example 13 | HT6 | 80 | HT7 | 4.5 | PY3 | 0.5 | PY4 and | 10 | BH4 and | 15 | 3.2 |
| | | | | | | | BD3 | | BD3 | | |
| Comparative | HT6 | 80 | HT7 | 5 | None | 0 | PY4 and | 10 | BH4 and | 15 | 3.7 |
| Example 17 | | | | | | | BD3 | | BD3 | | |
| Comparative | None | 0 | PY2 | 80 | PY3 | 5 | PY4 and | 10 | BH4 and | 15 | 4.9 |
| Example 18 | | | | | | | BD3 | | BD3 | | |

### Example 14

A 25 mm×75 mm×1.1 mm thick glass substrate with an ITO (Indium Tin Oxide) transparent electrode (anode) (Geomatec Co., Ltd.) was ultrasonic-cleaned in isopropyl alcohol for 5 minutes and then cleaned with UV ozone for 30 minutes. The thickness of the ITO transparent electrode was 130 nm.

The cleaned glass substrate with a transparent electrode line was attached to the substrate holder of a vacuum deposition system. Then, first, a 5-nm thick hole injecting layer was formed by depositing compound HA3 on the surface on the transparent electrode line side to cover the transparent electrode.

Following the formation of the hole injecting layer, an 80-nm thick third hole transporting layer was formed by depositing compound HT8.

Following the formation of the third hole transporting layer, a 7.5-nm thick second hole transporting layer was formed by depositing compound HT9.

Following the formation of the second hole transporting layer, a 2.5-nm first hole transporting layer was formed by depositing compound PY6.

A 7.5-nm thick first emitting layer was formed by co-depositing compound PY6 (host material) and compound BD1 (dopant material) on the first hole transporting layer in such a manner that the proportion of compound BD1 would be 2% by mass.

A 17.5-nm thick second emitting layer was formed by co-depositing compound BH1 (host material) and compound BD1 (dopant material) on the first emitting layer in such a manner that the proportion of compound BD1 would be 2% by mass.

A 10-nm thick electron transporting layer (also referred to as the hole blocking layer) (HBL) was formed by depositing compound ET3 on the second emitting layer.

A 1-nm thick electron injecting layer was formed by depositing LiF on the electron transporting layer (HBL).

An 80-nm thick cathode was formed by depositing metal Al on the electron injecting layer.

A brief description of the device structure in Example 14 is as follows.

ITO (130)/HA3 (5)/HT8 (80)/HT9 (7.5)/PY6 (2.5)/PY6:BD1 (7.5, 98%:2%)/BH1:BD1 (17.5, 98%:2%)/ET3 (10)/LiF (1)/Al (80)

The number in parentheses indicates the thickness of the layer (unit: nm).

Likewise, the set of percentages in parentheses (98%:2%) indicates the proportions of the host material (compound PY6 or BH1) and compound BD1 in the first or second emitting layer (% by mass). The same applies hereinafter.

### Example 15

The organic EL device of Example 15 was fabricated in the same way as in Example 14, except that in the formation of the second and first hole transporting layers, the thickness of the second hole transporting layer and that of the first hole transporting layer were changed to those in Table 12.

### Comparative Example 19

The organic EL device of Comparative Example 19 was fabricated in the same way as in Example 14, except that the thickness of the second hole transporting layer was changed to that in Table 12 and that the first emitting layer was formed in direct contact with the second hole transporting layer instead of forming the first hole transporting layer.

### Comparative Example 20

The organic EL device of Comparative Example 20 was fabricated in the same way as in Example 14, except that instead of forming the third and second hole transporting layers, the first hole transporting layer was formed to the thickness in Table 12 following the formation of the hole injecting layer.

TABLE 12

| | Third hole | | Second hole | | First hole | | First | | Second | | |
|---|---|---|---|---|---|---|---|---|---|---|---|
| | transporting layer | | transporting layer | | transporting layer | | emitting layer | | emitting layer | | Drive |
| | Com- | Thickness | Com- | Thickness | Com- | Thickness | Com- | Thickness | Com- | Thickness | voltage |
| | pound | [nm] | pound | [nm] | pound | [nm] | pounds | [nm] | pounds | [nm] | [V] |
| Example 14 | HT8 | 80 | HT9 | 7.5 | PY6 | 2.5 | PY6 and | 7.5 | BH1 and | 17.5 | 3.7 |
| | | | | | | | BD1 | | BD1 | | |
| Example 15 | HT8 | 80 | HT9 | 9 | PY6 | 1 | PY6 and | 7.5 | BH1 and | 17.5 | 3.5 |
| | | | | | | | BD1 | | BD1 | | |
| Comparative | HT8 | 80 | HT9 | 10 | None | 0 | PY6 and | 7.5 | BH1 and | 17.5 | 4.0 |
| Example 19 | | | | | | | BD1 | | BD1 | | |
| Comparative | None | 0 | None | 0 | PY6 | 90 | PY6 and | 7.5 | BH1 and | 17.5 | 5.8 |
| Example 20 | | | | | | | BD1 | | BD1 | | |

### Example 16

A 25 mm×75 mm×1.1 mm thick glass substrate with an ITO (Indium Tin Oxide) transparent electrode (anode) (Geomatec Co., Ltd.) was ultrasonic-cleaned in isopropyl alcohol for 5 minutes and then cleaned with UV ozone for 30 minutes. The thickness of the ITO transparent electrode was 130 nm.

The cleaned glass substrate with a transparent electrode line was attached to the substrate holder of a vacuum deposition system. Then, first, a 5-nm thick hole injecting layer was formed by depositing compound HA3 on the surface on the transparent electrode line side to cover the transparent electrode.

Following the formation of the hole injecting layer, an 80-nm thick third hole transporting layer was formed by depositing compound HT8.

Following the formation of the third hole transporting layer, a 5-nm thick second hole transporting layer was formed by depositing compound HT9.

Following the formation of the second hole transporting layer, a 5-nm first hole transporting layer was formed by depositing compound PY7.

A 12.5-nm thick first emitting layer was formed by co-depositing compound PY7 (host material) and compound BD1 (dopant material) on the first hole transporting layer in such a manner that the proportion of compound BD1 would be 2% by mass.

A 12.5-nm thick second emitting layer was formed by co-depositing compounds BH5 and BH6 (host materials) and compound BD1 (dopant material) on the first emitting layer. In the second emitting layer, the proportion of compound BH5 was 58.8% by mass, that of compound BH6 was 39.2% by mass, and that of compound BD1 was 2% by mass.

A 10-nm thick electron transporting layer (also referred to as the hole blocking layer) (HBL) was formed by depositing compound ET3 on the second emitting layer.

A 1-nm thick electron injecting layer was formed by depositing LiF on the electron transporting layer (HBL).

An 80-nm thick cathode was formed by depositing metal Al on the electron injecting layer.

A brief description of the device structure in Example 16 is as follows.

ITO (130)/HA3 (5)/HT8 (80)/HT9 (5)/PY7 (5)/PY7:BD1 (12.5, 98%:2%)/BH5:BH6:BD1 (12.5, 58.8%:39.2%:2%)/ET3 (10)/LiF (1)/Al (80)

The number in parentheses indicates the thickness of the layer (unit: nm).

Likewise, a set of percentages in parentheses (98%:2%) indicates the proportions of the host material (compound PY7) and compound BD1 in the first emitting layer (% by mass), and another (58.8%:39.2%:2%) indicates the proportions of compounds BH5, BH6, and BD1 in the second emitting layer (% by mass). The same applies hereinafter.

### Example 17

The organic EL device of Example 17 was fabricated in the same way as in Example 16, except that in the formation of the second and first hole transporting layers, the thickness of the second hole transporting layer and that of the first hole transporting layer were changed to those in Table 13.

### Comparative Example 21

The organic EL device of Comparative Example 21 was fabricated in the same way as in Example 16, except that the thickness of the second hole transporting layer was changed to that in Table 13 and that the first emitting layer was formed in direct contact with the second hole transporting layer instead of forming the first hole transporting layer.

### Comparative Example 22

The organic EL device of Comparative Example 22 was fabricated in the same way as in Example 16, except that instead of forming the third and second hole transporting layers, the first hole transporting layer was formed to the thickness in Table 13 following the formation of the hole injecting layer.

TABLE 13

| | Third hole | | Second hole | | First hole | | First | | Second | | |
|---|---|---|---|---|---|---|---|---|---|---|---|
| | transporting layer | | transporting layer | | transporting layer | | emitting layer | | emitting layer | | Drive |
| | Com- | Thickness | Com- | Thickness | Com- | Thickness | Com- | Thickness | Com- | Thickness | voltage |
| | pound | [nm] | pound | [nm] | pound | [nm] | pounds | [nm] | pounds | [nm] | [V] |
| Example 16 | HT8 | 80 | HT9 | 5 | PY7 | 5 | PY7 and | 12.5 | BH5, BH6, | 12.5 | 3.1 |
| | | | | | | | BD1 | | and BD1 | | |
| Example 17 | HT8 | 80 | HT9 | 7.5 | PY7 | 2.5 | PY7 and | 12.5 | BH5, BH6, | 12.5 | 3.1 |
| | | | | | | | BD1 | | and BD1 | | |
| Comparative | HT8 | 80 | HT9 | 10 | None | 0 | PY7 and | 12.5 | BH5, BH6, | 12.5 | 3.4 |
| Example 21 | | | | | | | BD1 | | and BD1 | | |
| Comparative | None | 0 | None | 0 | PY7 | 90 | PY7 and | 12.5 | BH5, BH6, | 12.5 | 4.4 |
| Example 22 | | | | | | | BD1 | | and BD1 | | |

### Testing of Compounds

### Preparation of Toluene Solutions

A toluene solution of compound BD1 was prepared by dissolving compound BD1 in toluene at a concentration of 4.9×10⁻⁶ mol/L.

Toluene solutions of compounds BD2 and BD3 were prepared in the same way as that of compound BD1.

### Measurement of Maximum Fluorescence Peak Wavelength (FL-peak)

Using a fluorescence spectrum analyzer (F-7000 spectrophotofluorometer (Hitachi High-Tech Science Corporation)), the toluene solutions of compounds BD1, BD2, and BD3 were excited at 390 nm, and the maximum fluorescence peak wavelength was measured.

The maximum fluorescence peak wavelength of compound BD1 was 453 nm.

The maximum fluorescence peak wavelength of compound BD2 was 450 nm.

The maximum fluorescence peak wavelength of compound BD3 was 455 nm.

### EXPLANATION OF CODES

1 . . . Organic EL device, 1A . . . organic EL device, 2 . . . substrate, 3 . . . anode, 4 . . . cathode, 5 . . . emitting layer, 6 . . . hole injecting layer, 71 . . . first hole transporting layer, 72 . . . second hole transporting layer, 8 . . . electron transporting layer, 9 . . . electron injecting layer, 10 . . . organic layer, 10A . . . organic layer.

1. An organic electroluminescence device comprising:
an anode;
a cathode;
an emitting layer between the anode and the cathode; and
a first hole transporting layer between the anode and the emitting layer, wherein:
the first hole transporting layer is directly adjacent to the emitting layer;
the first hole transporting layer contains a first compound represented by formula (1) below; and
the first compound has at least one group represented by formula (11) below, 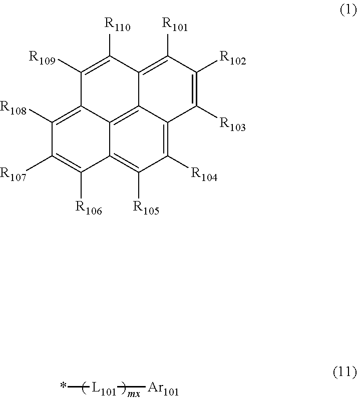
in formula (1),
R₁₀₁ to R₁₁₀ each independently represent: a hydrogen atom; a substituted or unsubstituted alkyl group having 1 to 50 carbon atoms; a substituted or unsubstituted haloalkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a substituted or unsubstituted aralkyl group having 7 to 50 carbon atoms; a group represented by —C(═O)R₉₀₁; a group represented by —COOR₉₀₂; a halogen atom; a cyano group; a nitro group; a substituted or unsubstituted aryl group having 6 to 50 ring carbon atoms; a substituted or unsubstituted heterocyclic group having 5 to 50 ring atoms; or a group represented by formula (11);
at least one of R₁₁₀ to R₁₁₀ is a group represented by formula (11);
when a plurality of groups represented by formula (11) are present, the plurality of groups represented by formula (11) are mutually the same or different;
L₁₀₁ is: a single bond; a substituted or unsubstituted arylene group having 6 to 50 ring carbon atoms; or a substituted or unsubstituted divalent heterocyclic group having 5 to 50 ring atoms;
Ar₁₀₁ is: a substituted or unsubstituted aryl group having 6 to 50 ring carbon atoms; or a substituted or unsubstituted heterocyclic group having 5 to 50 ring atoms;
mx is 0, 1, 2, 3, 4, or 5;
when two or more L₁₀₁s are present, the two or more L₁₀₁s are mutually the same or different;
when two or more Ar₁₀₁s are present, the two or more Ar₁₀₁s are mutually the same or different;
* in formula (11) indicates a position of bonding with a pyrene ring in formula (1);
a substituent for “substituted or unsubstituted” group in the first compound is at least one group selected from the group consisting of: an unsubstituted alkyl group having 1 to 50 carbon atoms; an unsubstituted alkenyl group having 2 to 50 carbon atoms; an unsubstituted alkynyl group having 2 to 50 carbon atoms; an unsubstituted cycloalkyl group having 3 to 50 ring carbon atoms; —Si(R₉₀₁)(R₉₀₂)(R₉₀₃); —O—(R₉₀₄); —S—(R₉₀₅); a halogen atom; a cyano group; a nitro group; an unsubstituted aryl group having 6 to 50 ring carbon atoms; and an unsubstituted heterocyclic group having 5 to 50 ring atoms;
in the first compound, represented by formula (1), R₉₀₁, R₉₀₂, R₉₀₃, R₉₀₄, R₉₀₇, R₈₀₁, and R₈₀₂ each independently represent: a hydrogen atom; a substituted or unsubstituted alkyl group having 1 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms;
when a plurality of R₉₀₁s are present, the plurality of R₉₀₁s are mutually the same or different;
when a plurality of R₉₀₂s are present, the plurality of R₉₀₂s are mutually the same or different;
when a plurality of R₉₀₃s are present, the plurality of R₉₀₃s are mutually the same or different;
when a plurality of R₉₀₄s are present, the plurality of R₉₀₄s are mutually the same or different;
when a plurality of R₉₀₅s are present, the plurality of R₉₀₅s are mutually the same or different;
when a plurality of R₉₀₁s are present, the plurality of R₉₀₁s are mutually the same or different; and
when a plurality of R₈₀₂s are present, the plurality of R₈₀₂s are mutually the same or different.

2. The organic electroluminescence device according to claim 1, further comprising
a second hole transporting layer between the anode and the first hole transporting layer, wherein:
the second hole transporting layer is directly adjacent to the first hole transporting layer; and
the second hole transporting layer contains a compound having an amino group.

3. The organic electroluminescence device according to claim 1, further comprising
a second hole transporting layer between the anode and the first hole transporting layer, wherein:
the second hole transporting layer is directly adjacent to the first hole transporting layer; and
the second hole transporting layer contains a compound represented by formula (B1) below, 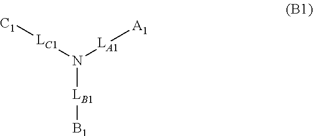
in formula (B1),
L_{A1}, L_{B1}, and L_{C1} each independently represent: a single bond; a substituted or unsubstituted arylene group having 6 to 18 ring carbon atoms; or a substituted or unsubstituted divalent heterocyclic group having 5 to 13 ring atoms;
if L_{A1} and L_{B1} are single bonds, A₁ and B₁ are: bonded together to form a substituted or unsubstituted monocyclic ring; bonded together to form a substituted or unsubstituted fused ring; or not bonded together;
if L_{A1} and L_{C1} are single bonds, A₁ and C₁ are: bonded together to form a substituted or unsubstituted monocyclic ring; bonded together to form a substituted or unsubstituted fused ring; or not bonded together;
if L_{B1} and L_{C1} are single bonds, B₁ and C₁ are: bonded together to form a substituted or unsubstituted monocyclic ring; bonded together to form a substituted or unsubstituted fused ring; or not bonded together;
A₁, B₁, and C₁ not forming the substituted or unsubstituted monocyclic ring and not forming the substituted or unsubstituted fused ring each independently represent: a substituted or unsubstituted aryl group having 6 to 30 ring carbon atoms; a substituted or unsubstituted heterocyclic group having 5 to 30 ring atoms; or a group represented by —Si(R₉₂₁)(R₉₂₂)(R₉₂₃);
R₉₂₁, R₉₂₂, and R₉₂₃ each independently represent a substituted or unsubstituted aryl group having 6 to 30 ring carbon atoms;
when a plurality of R₉₂₁s are present, the plurality of R₉₂₁s are mutually the same or different;
when a plurality of R₉₂₂s are present, the plurality of R₉₂₂s are mutually the same or different; and
when a plurality of R₉₂₃s are present, the plurality of R₉₂₃s are mutually the same or different.

4. The organic electroluminescence device according to claim 1, further comprising
a second hole transporting layer between the anode and the first hole transporting layer, wherein:
the second hole transporting layer is directly adjacent to the first hole transporting layer; and
the second hole transporting layer contains a compound having a carbazolyl group.

5. The organic electroluminescence device according to claim 1, wherein:
a thickness of the first hole transporting layer is 15 nm or less.

6. The organic electroluminescence device according to claim 1, wherein:
the organic electroluminescence device emits light with a maximum peak wavelength in a range from 430 nm to 480 nm when driven.

7. The organic electroluminescence device according to claim 1, wherein:
the emitting layer further contains a second compound that fluoresces; and
the second compound is a compound that exhibits light emission with a maximum peak wavelength in a range from 430 nm to 480 nm.

8. The organic electroluminescence device according to claim 1, wherein:
the emitting layer contains a pyrene derivative.

9. The organic electroluminescence device according to claim 1, wherein:
the emitting layer contains an anthracene derivative.

10. The organic electroluminescence device according to claim 1, wherein:
the emitting layer includes a first emitting layer and a second emitting layer between the first emitting layer and the cathode;
the first emitting layer contains a pyrene derivative; and
the second emitting layer contains an anthracene derivative.

11. The organic electroluminescence device according to claim 10, wherein:
the first and second emitting layers each independently further contain a fluorescent compound; and
the fluorescent compounds contained in the first and second emitting layers are compounds that exhibit light emission with a maximum peak wavelength in a range from 430 nm to 480 nm.

12. The organic electroluminescence device according to claim 1, wherein:
any heterocyclic group in the first compound is a group that contains at least any one of an oxygen or sulfur atom.

13. The organic electroluminescence device according to claim 1, wherein:
the first hole transporting layer contains no compound having an amino group.

14. The organic electroluminescence device according to claim 1, wherein:
the group represented by formula (11) is a group represented by formula (111) below, 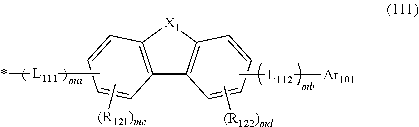
in formula (111),
X₁ is CR₁₂₃R₁₂₄, an oxygen atom, a sulfur atom, or NR₁₂₅;
L₁₁₁ and L₁₁₂ each independently represent: a single bond; a substituted or unsubstituted arylene group having 6 to 50 ring carbon atoms; or a substituted or unsubstituted divalent heterocyclic group having 5 to 50 ring atoms;
ma is 0, 1, 2, 3, or 4;
mb is 0, 1, 2, 3, or 4;
ma+mb is 0, 1, 2, 3, or 4;
Ar₁₀₁ represents the same as Ar₁₀₁ in formula (11);
R₁₂₁, R₁₂₂, R₁₂₃, R₁₂₄, and R₁₂₅ each independently represent: a hydrogen atom; a substituted or unsubstituted alkyl group having 1 to 50 carbon atoms; a substituted or unsubstituted haloalkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a substituted or unsubstituted aralkyl group having 7 to 50 carbon atoms; a group represented by —C(═O)R₉₀₁; a group represented by —COOR₉₀₂; a halogen atom; a cyano group; a nitro group; a substituted or unsubstituted aryl group having 6 to 50 ring carbon atoms; or a substituted or unsubstituted heterocyclic group having 5 to 50 ring atoms;
mc is 3;
the three R₁₂₁s are mutually the same or different;
md is 3; and
the three R₁₂₂s are mutually the same or different.

15. The organic electroluminescence device according to claim 14, wherein:
ma is 0, 1, or 2; and
mb is 0, 1, or 2.

16. The organic electroluminescence device according to claim 1, wherein:
ma is 0 or 1; and
mb is 0 or 1.

17. The organic electroluminescence device according to claim 1, wherein:
Ar₁₀₁ is a substituted or unsubstituted aryl group having 6 to 50 ring carbon atoms.

18. The organic electroluminescence device according to claim 1, wherein:
Ar₁₀₁ is: a substituted or unsubstituted phenyl group; a substituted or unsubstituted naphthyl group; a substituted or unsubstituted biphenyl group; a substituted or unsubstituted terphenyl group; a substituted or unsubstituted pyrenyl group; a substituted or unsubstituted phenanthryl group; or a substituted or unsubstituted fluorenyl group.

19. The organic electroluminescence device according to claim 1, wherein:
the first compound is represented by formula (101) below, 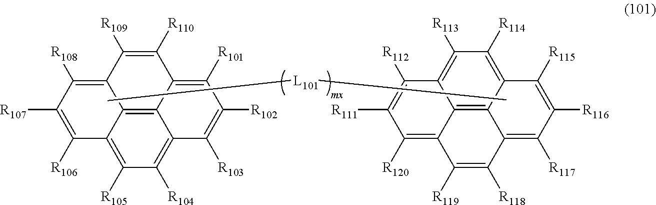
in formula (101),
R₁₀₁ to R₁₂₀ each independently represent: a hydrogen atom; a substituted or unsubstituted alkyl group having 1 to 50 carbon atoms; a substituted or unsubstituted haloalkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a substituted or unsubstituted aralkyl group having 7 to 50 carbon atoms; a group represented by —C(═O)R₉₀₁; a group represented by —COOR₉₀₂; a halogen atom; a cyano group; a nitro group; a substituted or unsubstituted aryl group having 6 to 50 ring carbon atoms; or a substituted or unsubstituted heterocyclic group having 5 to 50 ring atoms;
one of R₁₀₁ to R₁₁₀ indicates a position of bonding with L₁₀₁ and one of R₁₁₁ to R₁₂₀ indicates a position of bonding with L₁₀₁;
L₁₀₁ is: a single bond; a substituted or unsubstituted arylene group having 6 to 50 ring carbon atoms; or a substituted or unsubstituted divalent heterocyclic group having 5 to 50 ring atoms;
mx is 0, 1, 2, 3, 4, or 5; and
when two or more L₁₀₁s are present, the two or more L₁₀₁s are mutually the same or different.

20. The organic electroluminescence device according to claim 1, wherein:
L₁₀₁ is: a single bond; or a substituted or unsubstituted arylene group having 6 to 50 ring carbon atoms.

21. The organic electroluminescence device according to claim 19, wherein:
the first compound is represented by formula (102) below, 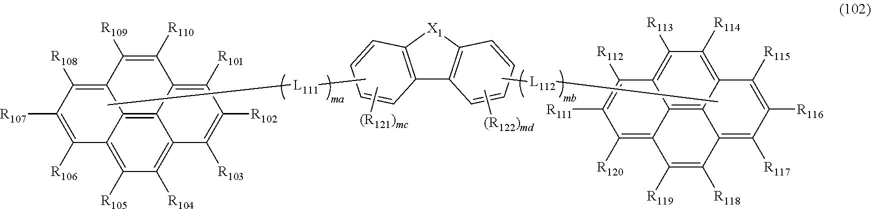
in formula (102),
R₁₀₁ to R₁₂₀ each independently represent the same as R₁₀₁ to R₁₂₀ in formula (101);
one of R₁₀₁ to R₁₁₀ indicates a position of bonding with L₁₁₁ and one of R₁₁₁ to R₁₂₀ indicates a position of bonding with L₁₁₂;
X₁ is CR₁₂₃R₁₂₄, an oxygen atom, a sulfur atom, or NR₁₂₅;
L₁₁₁ and L₁₁₂ each independently represent: a single bond; a substituted or unsubstituted arylene group having 6 to 50 ring carbon atoms; or a substituted or unsubstituted divalent heterocyclic group having 5 to 50 ring atoms;
ma is 0, 1, 2, 3, or 4;
mb is 0, 1, 2, 3, or 4;
ma+mb is 0, 1, 2, 3, or 4;
R₁₂₁, R₁₂₂, R₁₂₃, R₁₂₄, and R₁₂₅ each independently represent: a hydrogen atom; a substituted or unsubstituted alkyl group having 1 to 50 carbon atoms; a substituted or unsubstituted haloalkyl group having 1 to 50 carbon atoms; a substituted or unsubstituted alkenyl group having 2 to 50 carbon atoms; a substituted or unsubstituted alkynyl group having 2 to 50 carbon atoms; a substituted or unsubstituted cycloalkyl group having 3 to 50 ring carbon atoms; a group represented by —Si(R₉₀₁)(R₉₀₂)(R₉₀₃); a group represented by —O—(R₉₀₄); a group represented by —S—(R₉₀₅); a substituted or unsubstituted aralkyl group having 7 to 50 carbon atoms; a group represented by —C(═O)R₉₀₁; a group represented by —COOR₉₀₂; a halogen atom; a cyano group; a nitro group; a substituted or unsubstituted aryl group having 6 to 50 ring carbon atoms; or a substituted or unsubstituted heterocyclic group having 5 to 50 ring atoms;
mc is 3;
the three R₁₂₁s are mutually the same or different;
md is 3; and
the three R₁₂₂s are mutually the same or different.

22. The organic electroluminescence device according to claim 21, wherein:
ma is 0, 1, or 2; and
mb is 0, 1, or 2.

23. The organic electroluminescence device according to claim 21, wherein:
ma is 0 or 1; and
mb is 0 or 1.

24. The organic electroluminescence device according to claim 1, wherein:
two or more of R₁₀₁ to R₁₁₀ are each a group represented by formula (11).

25. The organic electroluminescence device according to claim 24, wherein:
Ar₁₀₁ is a substituted or unsubstituted aryl group having 6 to 50 ring carbon atoms.

26. The organic electroluminescence device according to claim 25, wherein:
Ar₁₀₁ is not a substituted or unsubstituted pyrenyl group;
L₁₀₁ is not a substituted or unsubstituted pyrenylene group; and
any substituted or unsubstituted aryl group having 6 to 50 ring carbon atoms as R₁₀₁ to R₁₁₀ not being the group represented by formula (11) is not a substituted or unsubstituted pyrenyl group.

27. The organic electroluminescence device according to claim 1, wherein:
R₁₀₁ to R₁₁₀ not being the group represented by formula (11) each independently represent: a hydrogen atom; a substituted or unsubstituted alkyl group having 1 to 50 carbon atoms; a substituted or unsubstituted cycloalkyl group having 3 to 50 ring carbon atoms; a substituted or unsubstituted aryl group having 6 to 50 ring carbon atoms; or a substituted or unsubstituted heterocyclic group having 5 to 50 ring atoms.

28. The organic electroluminescence device according to claim 1, wherein:
R₁₀₁ to R₁₁₀ not being the group represented by formula (11) each independently represent: a hydrogen atom; a substituted or unsubstituted alkyl group having 1 to 50 carbon atoms; or a substituted or unsubstituted cycloalkyl group having 3 to 50 ring carbon atoms.

29. The organic electroluminescence device according to claim 1, wherein:
R₁₀₁ to R₁₁₀ not being the group represented by formula (11) are each a hydrogen atom.

30. The organic electroluminescence device according to claim 1, wherein:
the first hole transporting layer consists of the first compound.

31. The organic electroluminescence device according to claim 1, wherein:
in the first compound, all groups described as “substituted or unsubstituted” are “unsubstituted” groups.

32. The organic electroluminescence device according to claim 1, further comprising
an electron transporting layer between the cathode and the emitting layer.

33. An electronic device comprising the organic electroluminescence device according to claim 1.
